(19) United States
(12) Patent Application Publication
(10) Pub. No.: US 2023/0217826 A1
(43) Pub. Date: Jul. 6, 2023

(54) LIGHT EMITTING ELEMENT AND POLYCYCLIC COMPOUND FOR THE SAME

(71) Applicant: Samsung Display Co., Ltd., Yongin-si (KR)

(72) Inventors: Hirokazu KUWABARA, Yokohama (JP); Ryuhei FURUE, Yokohama (JP); Yuma AOKI, Yokohama (JP); Yuuki MIYAZAKI, Yokohama (JP)

(21) Appl. No.: 18/149,487

(22) Filed: Jan. 3, 2023

(30) Foreign Application Priority Data
Jan. 3, 2022 (KR) 10-2022-0000560

(51) Int. Cl. H10K 85/60; H10K 50/15; H10K 50/16; H10K 50/11; H10K 85/40; H10K 85/30; C07F 5/02

(52) U.S. Cl. CPC H10K 85/658; H10K 50/15; H10K 50/16; H10K 50/11; H10K 85/657; H10K 85/6572; H10K 85/6574; H10K 85/654; H10K 85/40; H10K 85/346; C07F 5/027; C07B 2200/05

(57) ABSTRACT

A light emitting element includes a first electrode, a second electrode, and an emission layer between the first electrode and the second electrode and includes a compound represented by Formula 1 below, thereby exhibiting a long service life characteristic.

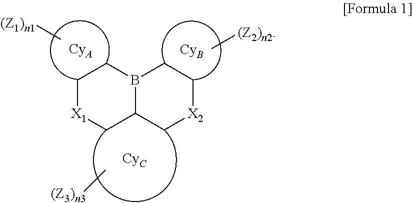

### CROSS-REFERENCE TO RELATED APPLICATION

This application claims priority to and the benefit of Korean Patent Application No. 10-2022-0000560, filed on Jan. 3, 2022, the entire content of which is hereby incorporated by reference.

### BACKGROUND

### 1. Field

The present disclosure herein relates to a polycyclic compound and a light emitting element including the same, and for example, to a light emitting element including a novel polycyclic compound in an emission layer.

### 2. Description of the Related Art

Recently, the development of an organic electroluminescence display device as an image display device is being actively conducted. The organic electroluminescence display device includes a so-called self-luminescent light emitting element in which holes and electrons injected from a first electrode and a second electrode recombine in an emission layer, and thus a luminescent material of the emission layer emits light to implement display (e.g., to display an image).

In the application of a light emitting element to a display device, there is a desire (e.g., a demand) for a light emitting element relatively having low driving voltage, high luminous efficiency, and/or a long service life (e.g., long lifespan), and the development on materials for a light emitting element capable of stably attaining such characteristics is being continuously pursued (e.g., required).

### SUMMARY

Aspects according to embodiments of the present disclosure are directed toward a light emitting element exhibiting a long service life characteristic.

Aspects according to embodiments of the present disclosure are also directed toward a polycyclic compound, which is a material for a light emitting element having a long service life characteristic.

According to an embodiment of the present disclosure, a polycyclic compound is represented by Formula 1:

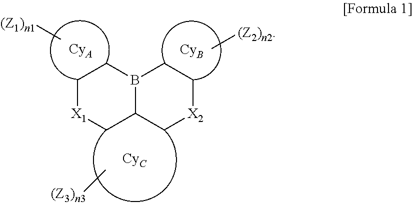

In Formula 1, Cy_{A}, Cy_{B}, and Cy_{C} are each independently an aryl ring (e.g., aryl group) having 6 to 30 ring-forming carbon atoms, or a heteroaryl ring (e.g., heteroaryl group) having 2 to 30 ring-forming carbon atoms, X₁ and X₂ are each independently O, S, or NR₁, and R₁ is a substituted or unsubstituted aryl group having 6 to 30 ring-forming carbon atoms, or a substituted or unsubstituted heteroaryl group having 5 to 30 ring-forming carbon atoms.

n1, n2, and n3 are integers satisfying the conditions of 0≤n1≤(the number of ring-forming carbon atoms of Cy_{A}-2), 0≤n2≤(the number of ring-forming carbon atoms of Cy_{B}-2), 0≤n3≤(the number of ring-forming carbon atoms of Cy_{C}-2), respectively, (n1+n2+n3)≥1, at least one from among Z₁, Z₂, and Z₃ being a nitrogen-containing polycyclic group having at least eight ring-forming carbon atoms and containing at least two bridgehead carbon atoms, or a substituent including the nitrogen-containing polycyclic group, and any remainder from among Z₁, Z₂, and Z₃ being each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In an embodiment, the polycyclic compound represented by Formula 1 may be represented by Formula 1-1 or Formula 1-2:

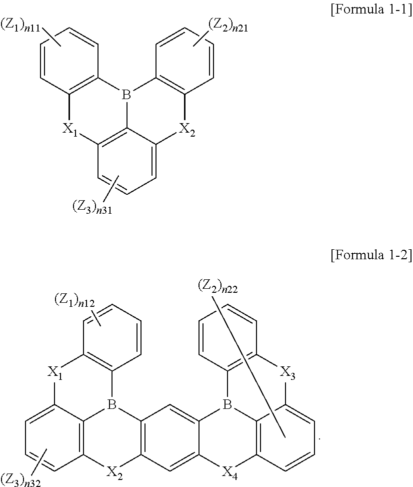

In Formula 1-1, n11 and n21 are each independently an integer of 0 to 4, n31 is an integer of 0 to 3, and n11+n21+n31 is 1 or greater. In Formula 1-2, X₃ and X₄ are each independently O, S, or NR₁, n12 is an integer of 0 to 4, n22 is an integer of 0 to 7, n32 is an integer of 0 to 3, and n12+n22+n32 is 1 or greater, and in Formula 1-1 and Formula 1-2, X₁, X₂, R₁, Z₁, Z₂, and Z₃ are the same as respectively defined in Formula 1.

In an embodiment, the polycyclic compound represented by Formula 1-1 above may be represented by Formula 1-1a:

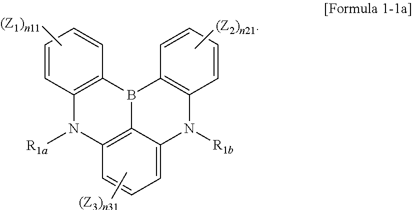

In Formula 1-1a, R₁ₐ and R_{1b} are each independently a substituted or unsubstituted aryl group having 6 to 30 ring-forming carbon atoms, or a substituted or unsubstituted heteroaryl group having 5 to 30 ring-forming carbon atoms, Z₁, Z₂, and Z₃ are the same as defined in Formula 1, and n11, n21, and n31 are the same as defined in Formula 1-1.

In an embodiment, the polycyclic compound represented by Formula 1-1 above may be represented by any one from among Formula 1-1 b to Formula 1-1e:

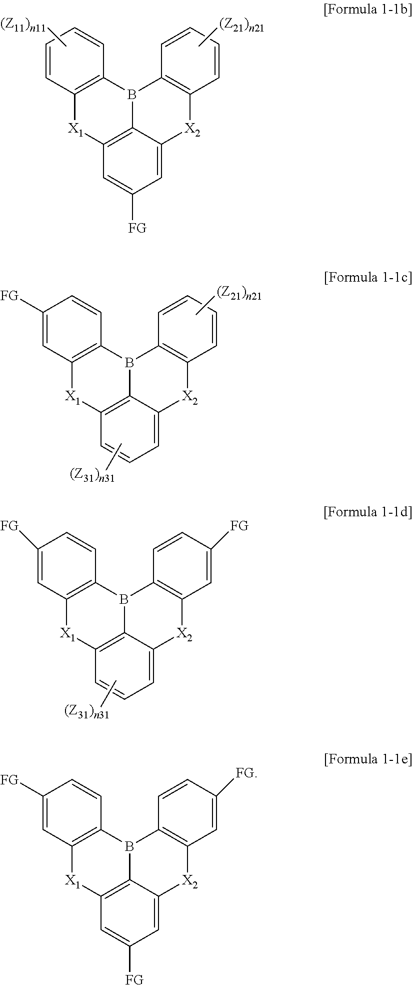

In Formula 1-1b to Formula 1-1e, FG is the nitrogen-containing polycyclic group or a substituent including the nitrogen-containing polycyclic group, and Z₁₁, Z₂₁, and Z₃₁ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. n11 and n21 are each independently an integer of 0 to 4, n31 is an integer of 0 to 3, and X₁ and X₂ are the same as defined in Formula 1.

In an embodiment, FG may include azaadamantane.

In an embodiment, the polycyclic compound represented by Formula 1-2 above may be represented by Formula 1-2a or Formula 1-2b:

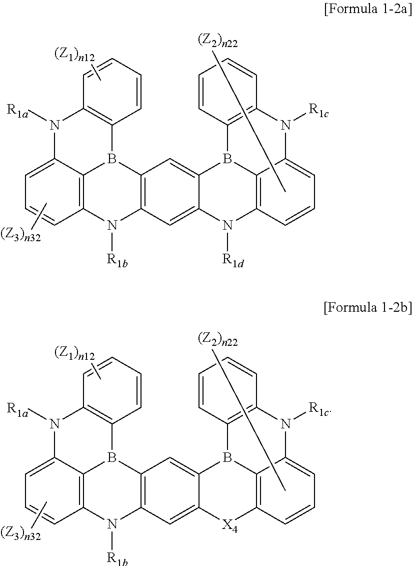

In Formula 1-2a and Formula 1-2b, R₁ₐ, R_{1b}, R_{1c}, and R_{1d} are each independently a substituted or unsubstituted aryl group having 6 to 30 ring-forming carbon atoms, or a substituted or unsubstituted heteroaryl group having 5 to 30 ring-forming carbon atoms, Z₁, Z₂, and Z₃ are the same as defined in Formula 1, and X₄, n12, n22, and n32 are the same as respectively defined in Formula 1-2.

In an embodiment, the polycyclic compound represented by Formula 1-2 above may be represented by Formula 1-2c or Formula 1-2d:

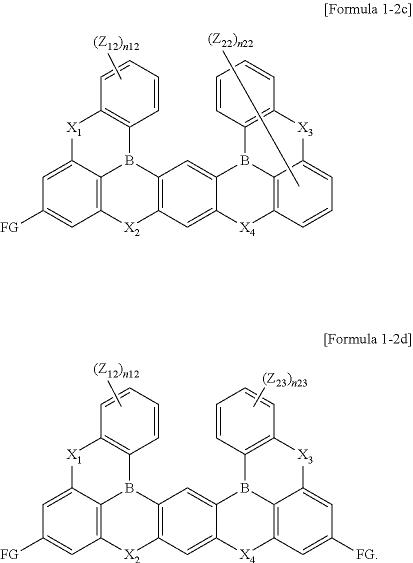

In Formula 1-2c and Formula 1-2d, FG is the nitrogen-containing polycyclic group or a substituent including the nitrogen-containing polycyclic group, and Z₁₂, Z₂₂, and Z₂₃ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. n12 and n23 are each independently an integer of 0 to 4, n22 is an integer of 0 to 7, X₁ and X₂ are the same as defined in Formula 1, and X₃ and X₄ are the same as defined in Formula 1-2.

In an embodiment, FG may include azaadamantane.

In an embodiment, the nitrogen-containing polycyclic group may be represented by any one from among Formulae 2-1 to 2-4:

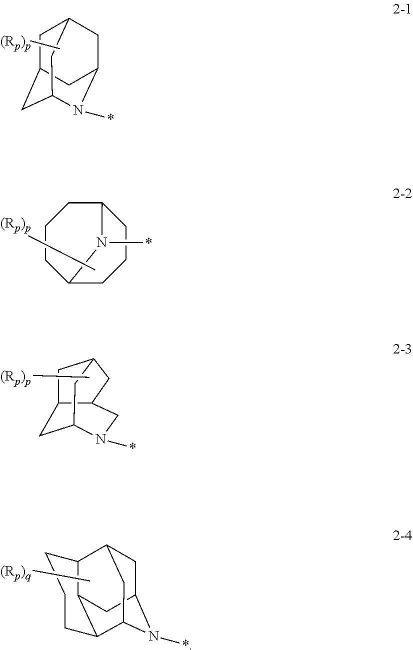

In Formulae 2-1 to 2-4, Rₚ is a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 5 to 30 ring-forming carbon atoms, p is an integer of 0 to 14, and q is an integer of 0 to 18.

In an embodiment, at least one from among Z₁, Z₂, and Z₃ may be represented by any one from among Formulae 2-1 to 2-4 and 2-1a to 2-4a:

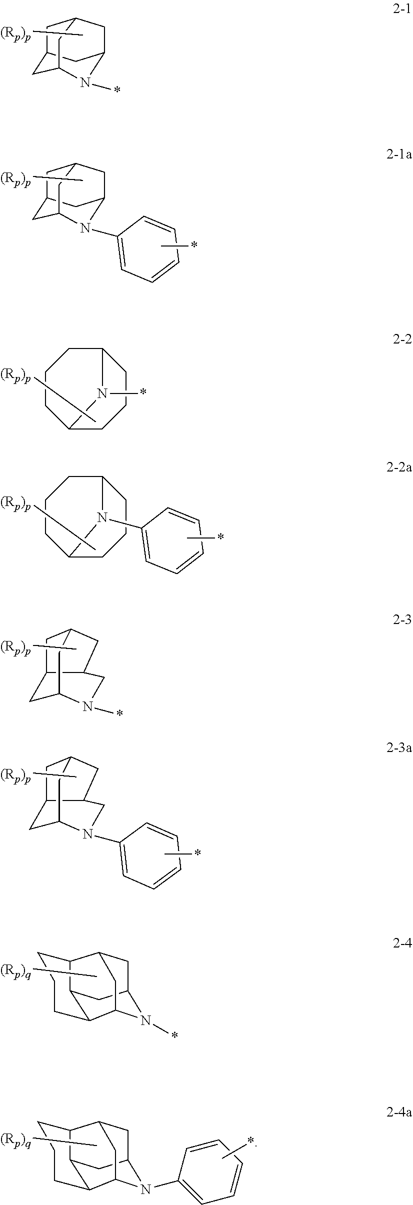

In Formulae 2-1 to 2-4 and 2-1a to 2-4a above, Rₚ is a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 5 to 30 ring-forming carbon atoms, p is an integer of 0 to 14, and q is an integer of 0 to 18.

In an embodiment, at least one from among R₁, Z₁, Z₂, and Z₃ in Formula 1 may include a deuterium atom, or a substituent containing a deuterium atom.

In an embodiment of the present disclosure, a light emitting element includes: a first electrode; a second electrode on the first electrode; and an emission layer between the first electrode and the second electrode, wherein the emission layer includes a first compound that is the above-described polycyclic compound according to an embodiment, and at least one of a second compound represented by Formula HT-1, a third compound represented by Formula ET-1, or a fourth compound represented by Formula M-b:

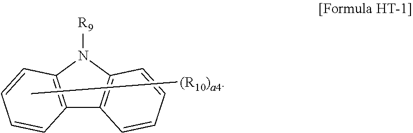

In Formula HT-1, a4 is an integer of 0 to 8, and R₉ and R₁₀ are each independently a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms.

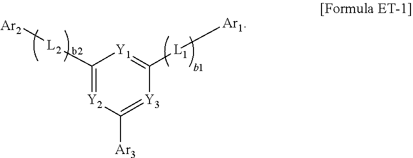

In Formula ET-1, at least one from among Y₁ to Y₃ may be N, and any remainder from among Y₁ to Y₃ may be each independently CRₐ, Rₐ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, b1 to b3 are each independently an integer of 0 to 10, L₁ to L₃ are each independently a direct linkage, a substituted or unsubstituted arylene group having 6 to 30 ring-forming carbon atoms, or a substituted or unsubstituted heteroarylene group having 2 to 30 ring-forming carbon atoms, and Ar₁ to Ar₃ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

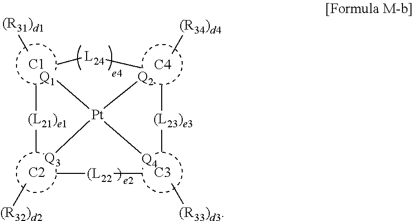

In Formula M-b above, Q₁ to Q₄ are each independently C or N, and C1 to C4 are each independently a substituted or unsubstituted hydrocarbon ring group having 5 to 30 ring-forming carbon atoms, or a substituted or unsubstituted heterocyclic group having 2 to 30 ring-forming carbon atoms, and e1 to e4 are each independently 0 or 1. L₂₁ to L₂₄ are each independently a direct linkage,

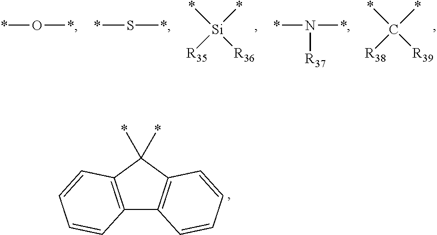

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. d1 to d4 are each independently an integer of 0 to 4, and R₃₁ to R₃₉ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In an embodiment, the emission layer may include the first compound, the second compound, and the third compound.

In an embodiment, the emission layer may include the first compound, the second compound, the third compound, and the fourth compound.

In an embodiment of the present disclosure, a light emitting element includes: a first electrode; a second electrode disposed on the first electrode; and at least one functional layer between the first electrode and the second electrode and includes the above-described polycyclic compound according to an embodiment.

In an embodiment, the at least one functional layer may include an emission layer, a hole transport region between the first electrode and the emission layer, and an electron transport region between the emission layer and the second electrode, and the emission layer may include the polycyclic compound.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure.

In the drawings:

FIG. 1 is a plan view illustrating a display device according to an embodiment of the present disclosure;

FIG. 2 is a cross-sectional view of a display device according to an embodiment of the present disclosure;

FIG. 3 is a cross-sectional view schematically illustrating a light emitting element according to an embodiment of the present disclosure;

FIG. 4 is a cross-sectional view schematically illustrating a light emitting element according to an embodiment of the present disclosure;

FIG. 5 is a cross-sectional view schematically illustrating a light emitting element according to an embodiment of the present disclosure;

FIG. 6 is a cross-sectional view schematically illustrating a light emitting element according to an embodiment of the present disclosure;

FIG. 7 is a cross-sectional view of a display device according to an embodiment of the present disclosure;

FIG. 8 is a cross-sectional view of a display device according to an embodiment of the present disclosure;

FIG. 9 is a cross-sectional view illustrating a display device according to an embodiment of the present disclosure; and

FIG. 10 is a cross-sectional view illustrating a display device according to an embodiment of the present disclosure.

### DETAILED DESCRIPTION

The subject matter of the present disclosure may be modified in many alternate forms, and thus specific embodiments will be shown in the drawings and described in more detail. It should be understood, however, that it is not intended to limit the subject matter of the present disclosure to the particular forms disclosed, but rather, is intended to cover all modifications, equivalents, and alternatives falling within the spirit and scope of the present disclosure, and equivalents thereof.

When explaining each of the drawings, like reference numerals are used for referring to like elements. In the accompanying drawings, the dimensions of each structure may be exaggeratingly illustrated for clarity of the present disclosure. It will be understood that, although the terms “first”, “second”, etc. may be used herein to describe various components, these components should not be limited by these terms. These terms are only used to distinguish one component from another. For example, a first component could be termed a second component, and, similarly, a second component could be termed (e.g., referred to as) a first component, without departing from the scope of the present disclosure. As used herein, the singular forms, “a,” “an,” and “the” are intended to include the plural forms as well, unless the context clearly indicates otherwise.

In the present disclosure, it will be understood that the terms “include,” “have” etc., specify the presence of a feature, a fixed number, a step, an operation, an element, a component, or a combination thereof disclosed in the specification, but do not exclude the possibility of presence or addition of one or more other features, fixed numbers, steps, operations, elements, components, or any combination thereof.

In the present disclosure, when a part such as a layer, a film, a region, or a plate is referred to as being “on” or “above” another part, it can be directly on the other part, or an intervening part may also be present. In contrast, when a part such as a layer, a film, a region, or a plate is referred to as being “under” or “below” another part, it can be directly under the other part, or one or more intervening parts may also be present. In addition, it will be understood that when a part is referred to as being “on” another part, it can be disposed above the other part, or disposed under the other part as well.

In the specification, the term “substituted or unsubstituted” may refer to a functional group that is substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. In some embodiments, each of the substituents described above may be substituted or unsubstituted. For example, a biphenyl group may be interpreted as an aryl group or a phenyl group substituted with a phenyl group.

In the specification, the phrase “bonded to an adjacent group to form a ring” may indicate that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle.

The hydrocarbon ring and the heterocycle may be monocyclic or polycyclic. In some embodiments, the rings formed by adjacent groups being bonded to each other may be connected to another ring to form a spiro structure.

In the specification, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In addition, two methyl groups in 4,5-dimethylphenanthrene may be interpreted as “adjacent groups” to each other.

In the specification, examples of the halogen atom may include a fluorine atom, a chlorine atom, a bromine atom, or an iodine atom.

In the specification, the alkyl group may be a linear, branched or cyclic alkyl group. The number of carbon atoms in the alkyl group may be 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but the embodiment of the present disclosure is not limited thereto.

In the specification, an alkenyl group refers to a hydrocarbon group including at least one carbon-carbon double bond in the middle and/or at a terminal end of an alkyl group having 2 or more carbon atoms. The alkenyl group may be a linear chain or a branched chain. The carbon number is not specifically limited, but may be 2 to 30, 2 to 20 or 2 to 10. Examples of the alkenyl group may include a vinyl group, a 1-butenyl group, a 1-pentenyl group, a 1,3-butadienyl aryl group, a styrenyl group, a styrylvinyl group, etc., without limitation.

In the specification, an alkynyl group refers to a hydrocarbon group including at least one carbon-carbon triple bond in the middle and/or at a terminal end of an alkyl group having 2 or more carbon atoms. The alkynyl group may be a linear chain or a branched chain. The carbon number is not specifically limited, but may be 2 to 30, 2 to 20 or 2 to 10. Particular examples of the alkynyl group may include an ethynyl group, a propynyl group, etc., without limitation.

The term “hydrocarbon ring group” as used herein may refer to any functional group or substituent derived from an aliphatic hydrocarbon ring. The hydrocarbon ring group may be a saturated hydrocarbon ring group having 5 to 20 ring-forming carbon atoms.

In the specification, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but the embodiment of the present disclosure is not limited thereto.

In the specification, the fluorenyl group may be substituted, and two substituents may be bonded to each other to form a spiro structure. Examples of cases where the fluorenyl group is substituted may be as follows. However, the embodiment of the present disclosure is not limited thereto.

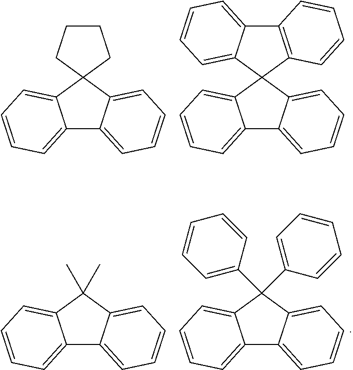

The term “heterocyclic group” as used herein may refer to any functional group or substituent derived from a ring including at least one of B, O, N, P, Si, or Se as a ring-forming heteroatom. The heterocyclic group may include an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the heterocyclic group may include at least one of B, O, N, P, Si, or S as a ring-forming heteroatom. When the heterocyclic group includes two or more heteroatoms, the two or more heteroatoms may be the same as or different from each other. The heterocyclic group may be a monocyclic heterocyclic group or a polycyclic heterocyclic group, and may include a heteroaryl group. The number of ring-forming carbon atoms in the heterocyclic group may be 2 to 30, 2 to 20, or 2 to 10.

In the specification, the aliphatic heterocyclic group may include one or more among B, O, N, P, Si, and S as a ring-forming heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but the embodiment of the present disclosure is not limited thereto.

The term “heteroaryl group” as used herein may include at least one of B, O, N, P, Si, or S as a ring-forming heteroatom. When the heteroaryl group contains two or more heteroatoms, the two or more heteroatoms may be the same as or different from each other. The heteroaryl group may be a monocyclic heteroaryl group or a polycyclic heteroaryl group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a triazole group, a pyridine group, a bipyridine group, a pyrimidine group, a triazine group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but the embodiment of the present disclosure is not limited thereto.

In the specification, the above description of the aryl group may be applied to an arylene group except that the arylene group is a divalent group. The above description of the heteroaryl group may be applied to a heteroarylene group except that the heteroarylene group is a divalent group.

In the specification, the boryl group includes an alkyl boryl group and an aryl boryl group. Examples of the boryl group may include a dimethylboryl group, a diethylboryl group, a t-butylmethylboryl group, a diphenylboryl group, a phenylboryl group, etc., but the embodiment of the present disclosure is not limited thereto. For example, the alkyl group in the alkyl boryl group may be the same as the examples of the alkyl group described above, and the aryl group in the aryl boryl group may be the same as the examples of the aryl group described above.

In the specification, a silyl group includes an alkyl silyl group and an aryl silyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc. However, an embodiment of the present disclosure is not limited thereto.

In the specification, the number of ring-forming carbon atoms in the carbonyl group is not specifically limited, but may be 1 to 40, 1 to 30, or 1 to 20. For example, the carbonyl group may have the following structures, but the embodiment of the present disclosure is not limited thereto:

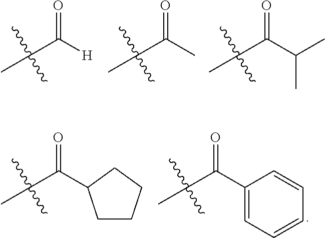

In the specification, the number of carbon atoms in the sulfinyl group and the sulfonyl group is not particularly limited, but may be 1 to 30. The sulfinyl group may include an alkyl sulfinyl group and an aryl sulfinyl group. The sulfonyl group may include an alkyl sulfonyl group and an aryl sulfonyl group.

In the specification, a thio group may include an alkylthio group and an arylthio group. The thio group may refer to that a sulfur atom is bonded to the alkyl group or the aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but the embodiment of the present disclosure is not limited thereto.

In the specification, an oxy group may refer to that an oxygen atom is bonded to the alkyl group or the aryl group as defined above. The oxy group may include an alkoxy group and an aryl oxy group. The alkoxy group may be a linear chain, a branched chain or a ring chain. The number of carbon atoms in the alkoxy group is not specifically limited, but may be, for example, 1 to 20 or 1 to 10. Examples of the oxy group may include a methoxy group, an ethoxy group, an n-propoxy, isopropoxy group, a butoxy group, a pentyloxy group, a hexyloxy group, an octyloxy group, a nonyloxy group, a decyloxy group, a benzyloxy group, etc., but the embodiment of the present disclosure is not limited thereto.

In the specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, etc., but the embodiment of the present disclosure is not limited thereto.

In the specification, the alkyl group among an alkylthio group, an alkylsulfoxy group, an alkylaryl group, an alkylamino group, an alkyl boron group, an alkyl silyl group, and an alkyl amine group may be the same as the examples of the alkyl group described above.

In the specification, the aryl group among an aryloxy group, an arylthio group, an arylsulfoxy group, an arylamino group, an arylboron group, an arylsilyl group, an arylamine group may be the same as the examples of the aryl group described above.

In the specification, a direct linkage may refer to a single bond.

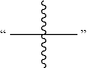

and “—*” each refer to a position to be connected.

Hereinafter, embodiments of the present disclosure will be described with reference to the accompanying drawings.

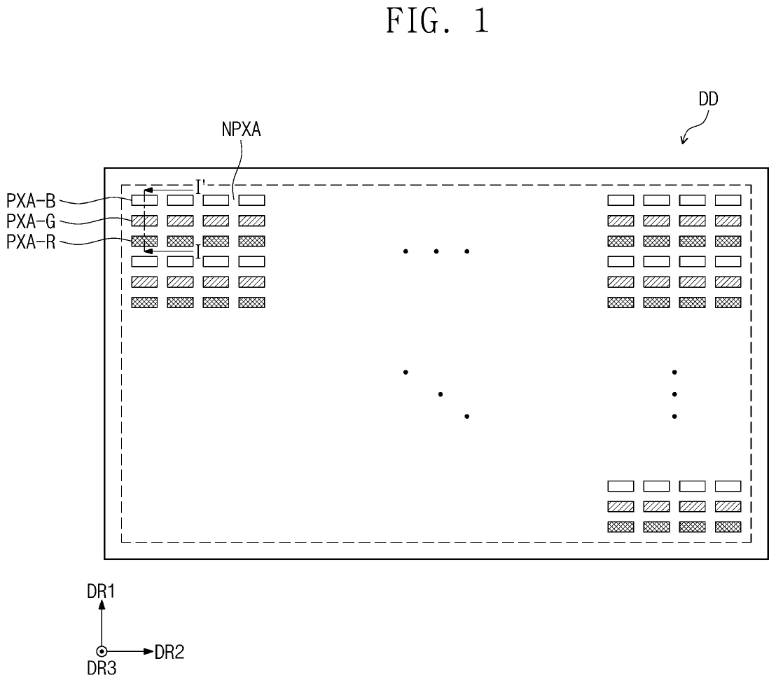

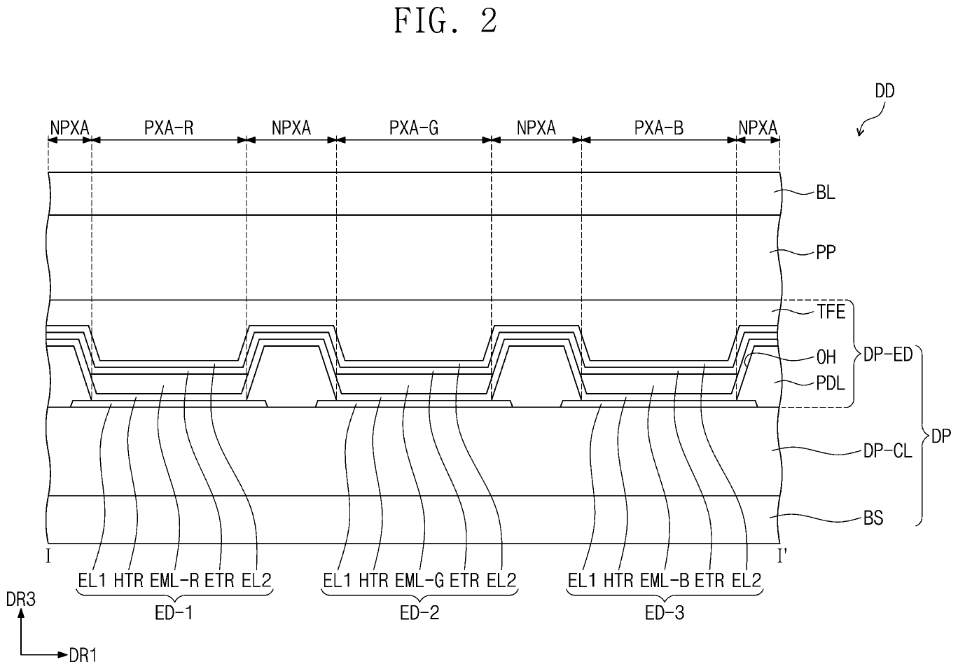

FIG. 1 is a plan view illustrating an embodiment of a display device DD. FIG. 2 is a cross-sectional view of the display device DD of the embodiment. FIG. 2 is a cross-sectional view illustrating a part taken along the line I-I′ of FIG. 1.

The display device DD may include a display panel DP and an optical layer PP disposed on the display panel DP. The display panel DP includes light emitting elements ED-1, ED-2, and ED-3. The display device DD may include a plurality of light emitting elements ED-1, ED-2, and ED-3. The optical layer PP may be disposed on the display panel DP to control reflected light in the display panel DP due to external light. The optical layer PP may include, for example, a polarization layer and/or a color filter layer. In some embodiments, unlike the configuration illustrated in the drawing, the optical layer PP may not be provided in the display device DD of an embodiment.

A base substrate BL may be disposed on the optical layer PP. The base substrate BL may be a member which provides a base surface on which the optical layer PP is disposed. The base substrate BL may be a glass substrate, a metal substrate, a plastic substrate, etc. However, the embodiment of the present disclosure is not limited thereto, and the base substrate BL may be an inorganic layer, an organic layer, or a composite material layer. In some embodiments, unlike the configuration illustrated, in an embodiment, the base substrate BL may not be provided.

The display device DD according to an embodiment may further include a filling layer. The filling layer may be disposed between a display element layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display element layer DP-ED. The display element layer DP-ED may include a pixel definition layer PDL, the light emitting elements ED-1, ED-2, and ED-3 disposed between portions of the pixel definition layer PDL, and an encapsulation layer TFE disposed on the light emitting elements ED-1, ED-2, and ED-3.

The base layer BS may be a member which provides a base surface on which the display element layer DP-ED is disposed. The base layer BS may be a glass substrate, a metal substrate, a plastic substrate, etc. However, the embodiment of the present disclosure is not limited thereto, and the base layer BS may be an inorganic layer, an organic layer, or a composite material layer.

In an embodiment, the circuit layer DP-CL is disposed on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting elements ED-1, ED-2, and ED-3 of the display element layer DP-ED.

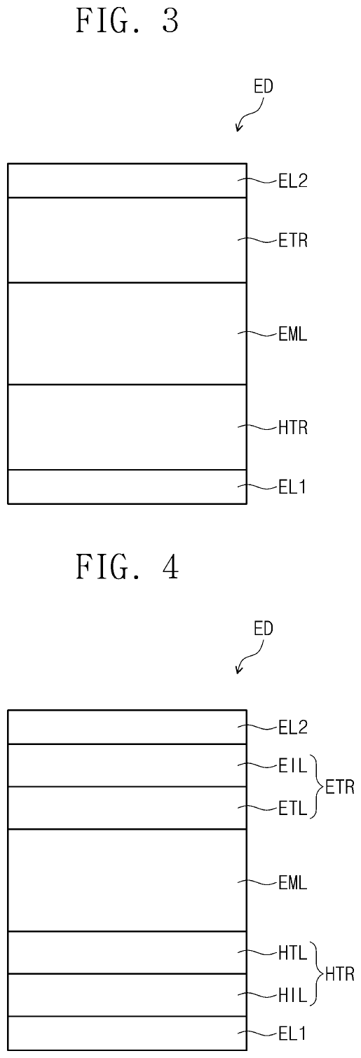

Each of the light emitting elements ED-1, ED-2, and ED-3 may have a structure of a light emitting element ED of an embodiment according to FIGS. 3 to 6, which will be described in more detail later. Each of the light emitting elements ED-1, ED-2 and ED-3 may include a first electrode EL1, a hole transport region HTR, at least one emission layer from among emission layers EML-R, EML-G and EML-B (e.g., a corresponding one of the emission layer EML-R, the emission layer EML-G, or the emission layer EML-B), an electron transport region ETR, and a second electrode EL2.

FIG. 2 illustrates an embodiment in which the emission layers EML-R, EML-G, and EML-B of the light emitting elements ED-1, ED-2, and ED-3 are disposed in openings OH defined in the pixel definition layer PDL, and the hole transport region HTR, the electron transport region ETR, and the second electrode EL2 are provided as a common layer in the entire light emitting elements ED-1, ED-2, and ED-3. However, the embodiment of the present disclosure is not limited thereto, and unlike the configuration illustrated in FIG. 2, the hole transport region HTR and the electron transport region ETR in an embodiment may be provided by being patterned inside the openings OH defined in the pixel definition layer PDL. For example, the hole transport region HTR, the emission layers EML-R, EML-G, and EML-B, and the electron transport region ETR of the light emitting elements ED-1, ED-2, and ED-3 in an embodiment may be provided by being patterned through an inkjet printing method.

The encapsulation layer TFE may cover the light emitting elements ED-1, ED-2 and ED-3. The encapsulation layer TFE may seal the display element layer DP-ED. The encapsulation layer TFE may be a thin film encapsulation layer. The encapsulation layer TFE may be formed as one layer or by laminating a plurality of layers. The encapsulation layer TFE includes at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film protects the display element layer DP-ED from moisture/oxygen, and the encapsulation-organic film protects the display element layer DP-ED from foreign substances such as dust particles. The encapsulation-inorganic film may include silicon nitride, silicon oxynitride, silicon oxide, titanium oxide, aluminum oxide, and/or the like, but the embodiment of the present disclosure is not particularly limited thereto. The encapsulation-organic film may include an acrylic-based compound, an epoxy-based compound, and/or the like. The encapsulation-organic film may include a photopolymerizable organic material, but the embodiment of the present disclosure is not particularly limited thereto.

The encapsulation layer TFE may be disposed on the second electrode EL2 and may be disposed to fill the opening OH.

Referring to FIGS. 1 and 2, the display device DD may include a non-light emitting region NPXA and light emitting regions PXA-R, PXA-G and PXA-B. The light emitting regions PXA-R, PXA-G and PXA-B may be regions in which lights generated by the respective light emitting elements ED-1, ED-2 and ED-3 are emitted. The light emitting regions PXA-R, PXA-G, and PXA-B may be spaced apart from each other on a plane (e.g., in a plan view).

Each of the light emitting regions PXA-R, PXA-G, and PXA-B may be a region divided by the pixel definition layer PDL. The non-light emitting regions NPXA may be regions between the adjacent light emitting regions PXA-R, PXA-G, and PXA-B, which correspond to portions of the pixel definition layer PDL. In some embodiments, in the specification, the light emitting regions PXA-R, PXA-G, and PXA-B may respectively correspond to pixels. The pixel definition layer PDL may divide (e.g., separate) the light emitting elements ED-1, ED-2, and ED-3. The emission layers EML-R, EML-G and EML-B of the light emitting elements ED-1, ED-2 and ED-3 may be disposed in openings OH defined in the pixel definition layer PDL and separated from each other.

The light emitting regions PXA-R, PXA-G and PXA-B may be divided into a plurality of groups according to the color of light generated from the light emitting elements ED-1, ED-2 and ED-3. In the display device DD of an embodiment shown in FIGS. 1 and 2, three light emitting regions PXA-R, PXA-G, and PXA-B which emit red light, green light, and blue light, respectively are illustrated. For example, the display device DD of an embodiment may include the red light emitting region PXA-R, the green light emitting region PXA-G, and the blue light emitting region PXA-B that are separated from each other.

In the display device DD according to an embodiment, the plurality of light emitting elements ED-1, ED-2 and ED-3 may be to emit lights (e.g., light beams) having wavelengths different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, the embodiment of the present disclosure is not limited thereto, and the first to third light emitting elements ED-1, ED-2, and ED-3 may be to emit lights (e.g., light beams) in substantially the same wavelength range or at least one light emitting element may be to emit a light (e.g., light beam) in a wavelength range different from the others. For example, the first to third light emitting elements ED-1, ED-2, and ED-3 may all emit blue lights.

The light emitting regions PXA-R, PXA-G, and PXA-B in the display device DD according to an embodiment may be arranged in a stripe form. Referring to FIG. 1, the plurality of red light emitting regions PXA-R may be arranged with each other along a second directional axis DR2, the plurality of green light emitting regions PXA-G may be arranged with each other along the second directional axis DR2, and the plurality of blue light emitting regions PXA-B may be arranged with each other along the second directional axis DR2. In some embodiments, the red light emitting region PXA-R, the green light emitting region PXA-G, and the blue light emitting region PXA-B may be alternately arranged in this stated order along a first directional axis DR1.

FIGS. 1 and 2 illustrate that all the light emitting regions PXA-R, PXA-G, and PXA-B have similar area, but the embodiment of the present disclosure is not limited thereto. Thus, the light emitting regions PXA-R, PXA-G, and PXA-B may have different areas from each other according to the wavelength range of the emitted light. In this case, the areas of the light emitting regions PXA-R, PXA-G, and PXA-B may refer to areas when viewed on a plane defined by the first directional axis DR1 and the second directional axis DR2 (e.g., in a plan view).

In some embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of the display quality desired or required in the display device DD. For example, the arrangement form of the light emitting regions PXA-R, PXA-G, and PXA-B may be a PENTILE® arrangement form (e.g., an RGBG matrix, RGBG structure, or RGBG matrix structure) or a Diamond Pixel arrangement form. PENTILE® and Diamond Pixel™ are trademarks of Samsung Display Co., Ltd.

In some embodiments, the areas of the light emitting regions PXA-R, PXA-G, and PXA-B may be different from each other. For example, in an embodiment, the area of the green light emitting region PXA-G may be smaller than that of the blue light emitting region PXA-B, but the embodiment of the present disclosure is not limited thereto.

In the display device DD according to an embodiment illustrated in FIG. 2, at least one from among the first to third light emitting elements ED-1, ED-2, and ED-3 may include a polycyclic compound of an embodiment, which will be described in more detail below.

Hereinafter, FIGS. 3 to 6 are cross-sectional views schematically illustrating light emitting elements according to embodiments. The light emitting elements ED according to each embodiment may include a first electrode EL1, a second electrode EL2 facing the first electrode EL1, and at least one functional layer disposed between the first electrode EL1 and the second electrode EL2. The light emitting element ED of an embodiment may include a polycyclic compound of an embodiment, which will be described in more detail below, in at least one functional layer. In some embodiments, the polycyclic compound of an embodiment may be referred to as a first compound herein.

Each of the light emitting elements ED may include, as the at least one functional layer, a hole transport region HTR, an emission layer EML, and an electron transport region ETR that are sequentially stacked. Referring to FIG. 3, the light emitting element ED of an embodiment may include a first electrode EL1, a hole transport region HTR, an emission layer EML, an electron transport region ETR, and a second electrode EL2 that are sequentially stacked. In some embodiments, the light emitting element ED of an embodiment may include the polycyclic compound of an embodiment, which will be described in more detail below, in the emission layer EML.

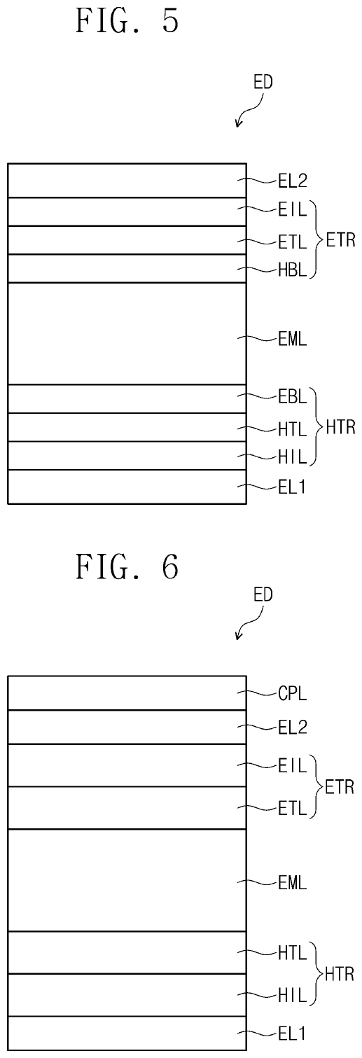

Compared with FIG. 3, FIG. 4 illustrates a cross-sectional view of a light emitting element ED of an embodiment, in which a hole transport region HTR includes a hole injection layer HIL and a hole transport layer HTL, and an electron transport region ETR includes an electron injection layer EIL and an electron transport layer ETL. In addition, compared with FIG. 3, FIG. 5 illustrates a cross-sectional view of a light emitting element ED of an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared with FIG. 4, FIG. 6 illustrates a cross-sectional view of a light emitting element ED of an embodiment further including a capping layer CPL disposed on the second electrode EL2.

In an embodiment, the emission layer EML may include the first compound that includes a core part containing a boron atom as a ring-forming atom, and includes at least one nitrogen-containing polycyclic group which is substituted at the core part, contains at least two bridgehead carbon atoms, and has at least eight ring-forming carbon atoms. In some embodiments, the emission layer EML may include at least one of a second compound, a third compound, or a fourth compound. The second compound may include a substituted or unsubstituted carbazole group. The third compound may include a hexagonal ring containing at least one nitrogen atom as a ring-forming atom. The fourth compound may be a platinum-containing compound.

In the light emitting element ED according to an embodiment, the first electrode EU has conductivity (e.g., is a conductor). The first electrode EL1 may be formed of a metal material, a metal alloy, or a conductive compound. The first electrode EU may be an anode or a cathode. However, the embodiment of the present disclosure is not limited thereto. In some embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, Zn, a compound of two or more thereof, a mixture of two or more thereof, or an oxide thereof.

When the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EU is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In some embodiments, the first electrode EL1 may have a multilayer structure including a reflective film or a transflective film formed of the above-described materials, and a transparent conductive film formed of ITO, IZO, ZnO, ITZO, etc. For example, the first electrode EU may have a three-layer structure of ITO/Ag/ITO, but the embodiment of the present disclosure is not limited thereto. In some embodiments, the embodiment of the present disclosure is not limited thereto, and the first electrode EU may include one or more of the above-described metal materials, combinations of at least two metal materials of the above-described metal materials, one or more of oxides of the above-described metal materials, and/or the like. The thickness of the first electrode EL1 may be from about 700 Å to about 10,000 Å. For example, the thickness of the first electrode EU may be from about 1,000 Å to about 3,000 Å.

The hole transport region HTR is provided on the first electrode EL1. The hole transport region HTR may have a single layer formed of a single material, a single layer formed of a plurality of different materials, or a multilayer structure including a plurality of layers formed of a plurality of different materials.

The hole transport region HTR may include at least one of the hole injection layer HIL, the hole transport layer HTL, or the electron blocking layer EBL. In some embodiments, the hole transport region HTR may include a plurality of stacked hole transport layers HTL.

In some embodiments, the hole transport region HTR may have a single layer structure of the hole injection layer HIL or the hole transport layer HTL, or may have a single layer structure formed of a hole injection material and a hole transport material. In an embodiment, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, or a hole transport layer HTL/buffer layer are stacked in the respective stated order from the first electrode EL1, but the embodiment of the present disclosure is not limited thereto.

The thickness of the hole transport region HTR may be, for example, from about 50 Å to about 15,000 Å. The hole transport region HTR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR in the light emitting element ED of an embodiment may include a compound represented by Formula H-1:

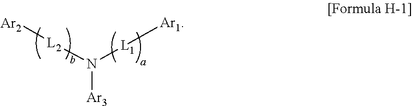

In Formula H-1 above, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In some embodiments, when a or b is an integer of 2 or greater, a plurality of L₁'s and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₃ may be a substituted or unsubstituted aryl group having 6 to 30 ring-forming carbon atoms.

The compound represented by Formula H-1 above may be a monoamine compound (e.g., a compound including a single amine group). In some embodiments, the compound represented by Formula H-1 above may be a diamine compound in which at least one from among Ar₁ to Ar₃ includes the amine group as a substituent. In some embodiments, the compound represented by Formula H-1 above may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be any one of the compounds of Compound Group H below. However, the compounds listed in Compound Group H below are examples, and the compounds represented by Formula H-1 are not limited to those represented by Compound Group H below:

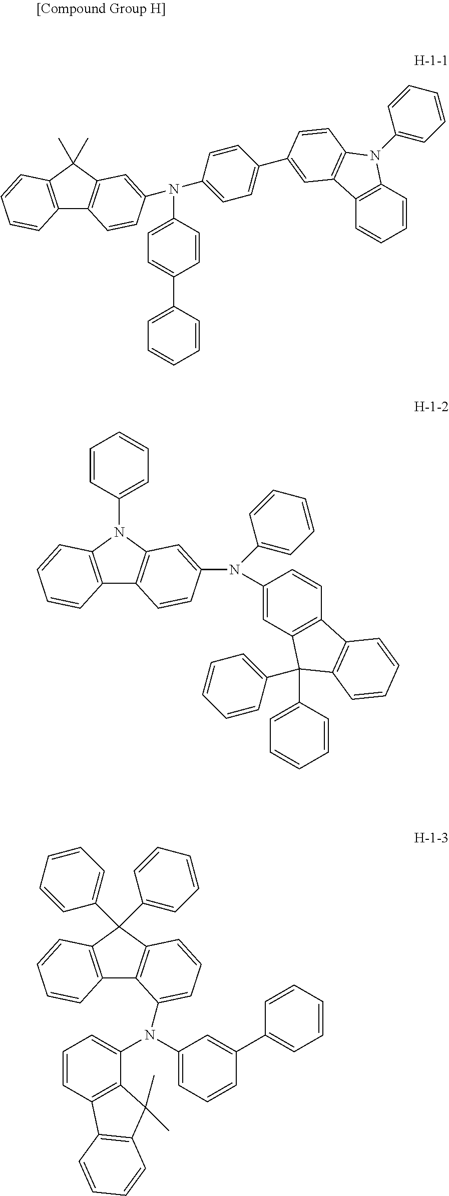 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

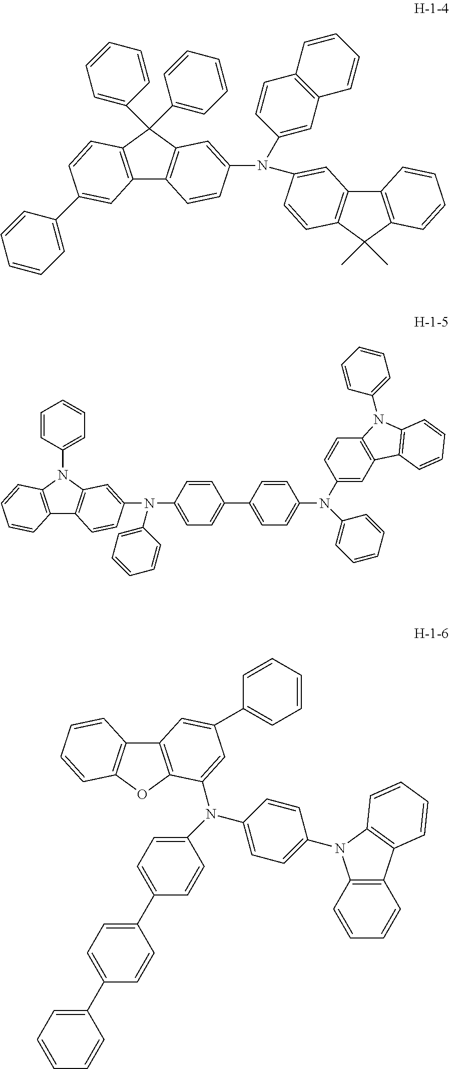 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

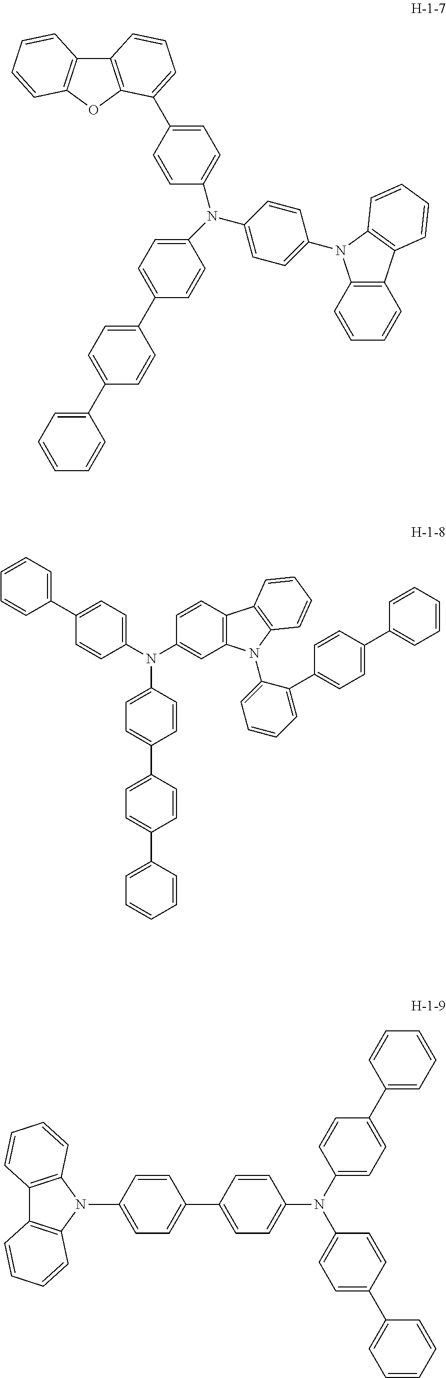 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

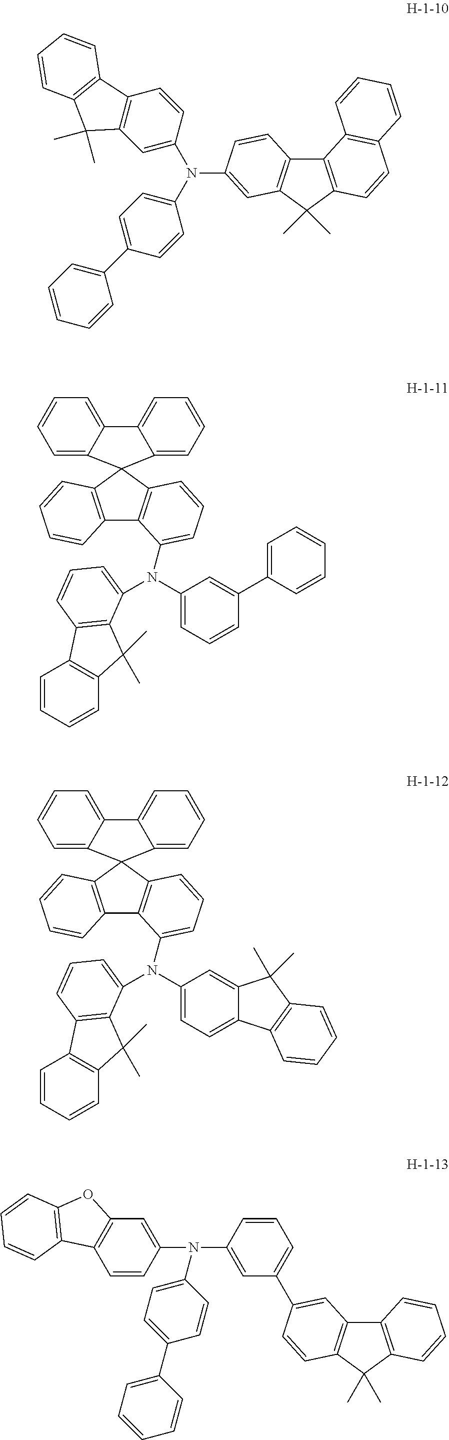 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

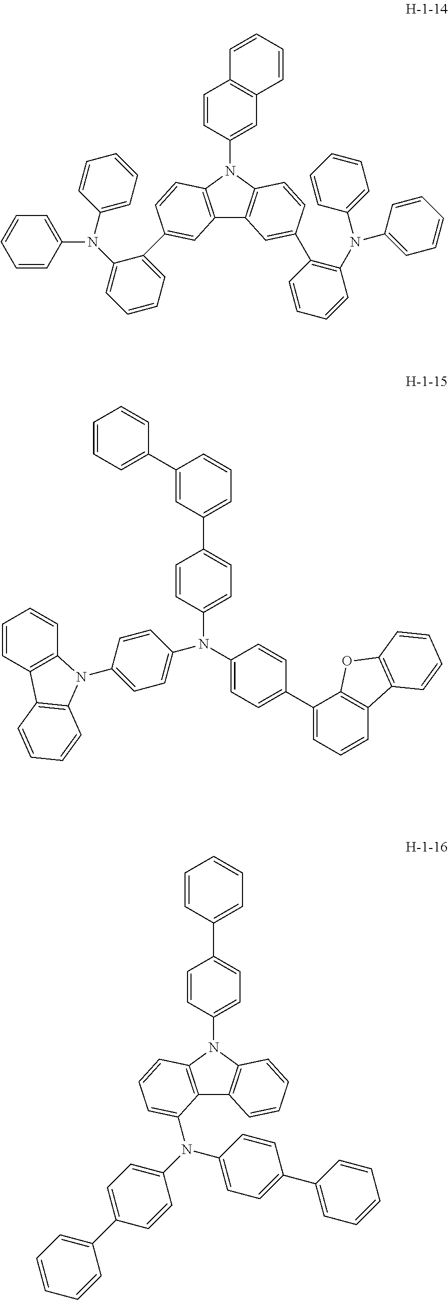 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

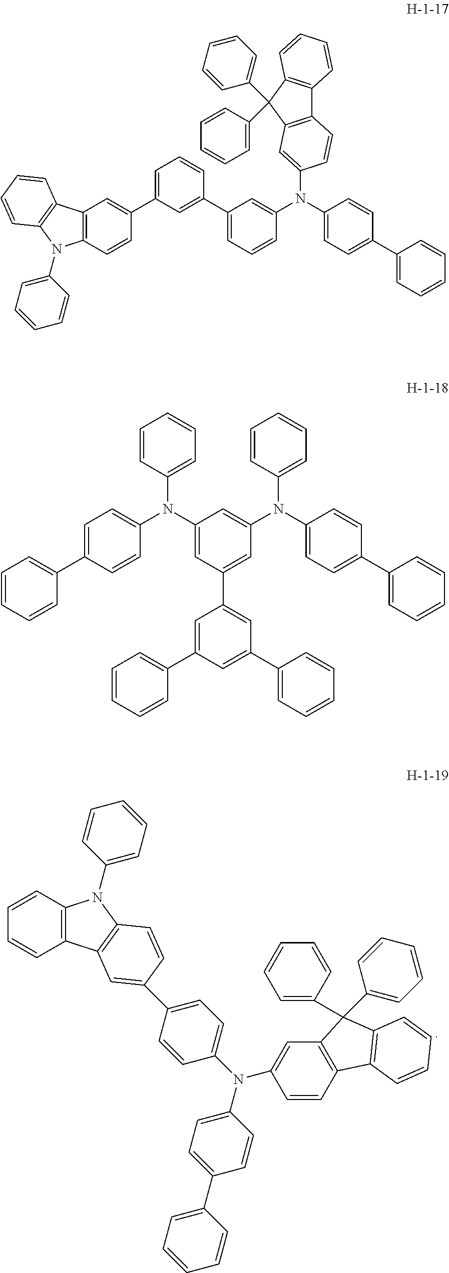 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may further include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris[N(1-naphthyl)-N-phenylamino]-triphenylamine (1-TNATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB or NPD of α-NPD), triphenylamine-containing polyetherketone (TPAPEK), 4-isopropyl-4′-methyldiphenyliodonium [tetrakis(pentafluorophenyl)borate], dipyrazino[2,3-f:2′,3′-h]quinoxaline-2,3,6,7,10,11-hexacarbonitrile (HATCN), etc.

The hole transport region HTR may include a carbazole-based derivative such as N-phenyl carbazole and/or polyvinyl carbazole, a fluorene-based derivative, a triphenyl amine-based derivative such as 4,4′,4″-tris(N-carbazolyl)triphenylamine (TCTA), N,N′-bis(3-methylphenyl)-N,N′-diphenyl-[1,1′-biphenyl]-4,4′-diamine (TPD), N,N′-di(naphthalene-1-yl)-N,N′-diphenyl-benzidine (NPB), 4,4′-cyclohexylidene bis[N,N-bis(4-methylphenyl)benzenamine] (TAPC), 4,4′-bis[N, N′-(3-tolyl)amino]-3,3′-dimethylbiphenyl (HMTPD), 1,3-bis(N-carbazolyl)benzene (mCP), etc.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region HTR in at least one of a hole injection layer HIL, a hole transport layer HTL, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, when the hole transport region HTR includes the electron blocking layer EBL, the electron blocking layer EBL may have a thickness of about 10 Å to about 1,000 Å. When the thicknesses of the hole transport region HTR, the hole injection layer HIL, the hole transport layer HTL and the electron blocking layer EBL satisfy the above-described ranges, satisfactory hole transport properties may be achieved without a substantial increase in driving voltage.

The hole transport region HTR may further include a charge generating material to increase conductivity in addition to the above-described materials. The charge generating material may be dispersed uniformly or non-uniformly in the hole transport region HTR. The charge generating material may be, for example, a p-dopant. The p-dopant may include at least one of a halogenated metal (e.g., metal halide) compound, a quinone derivative, a metal oxide, or a cyano group-containing compound, but the embodiment of the present disclosure is not limited thereto. For example, the p-dopant may include a metal halide compound such as CuI and/or RbI, a quinone derivative such as tetracyanoquinodimethane (TCNQ) and/or 2,3,5,6-tetrafluoro-7,7,8,8-tetracyanoquinodimethane (F4-TCNQ), a metal oxide such as tungsten oxide and/or molybdenum oxide, a cyano group-containing compound such as dipyrazino[2,3-f:2′,3′-h] quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but the embodiment of the present disclosure is not limited thereto.

As described above, the hole transport region HTR may further include at least one of the buffer layer or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be contained in the hole transport region HTR may be utilized as a material to be contained in the buffer layer. The electron blocking layer EBL is a layer that serves to prevent or reduce the electron injection from the electron transport region ETR to the hole transport region HTR.

The emission layer EML is provided on the hole transport region HTR. The emission layer EML may have a thickness of, for example, about 100 Å to about 1,000 Å or about 100 Å to about 300 Å. The emission layer EML may have a single layer formed of a single material, a single layer formed of a plurality of different materials, or a multilayer structure having a plurality of layers formed of a plurality of different materials.

In an embodiment, the emission layer EML may include the first compound represented by Formula 1. The first compound corresponds to the polycyclic compound of an embodiment.

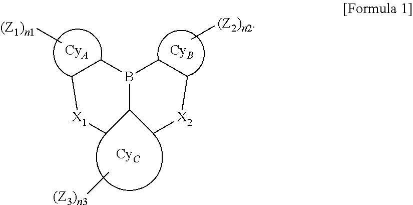

In Formula 1, Cy_{A}, Cy_{B}, and Cy_{C} may each independently be an aryl ring (e.g., aryl group) having 6 to 30 ring-forming carbon atoms, or a heteroaryl ring (e.g., heteroaryl group) having 2 to 30 ring-forming carbon atoms. In an embodiment, Cy_{A}, Cy_{B}, and Cy_{C} may all be the same or at least one may be different from the rest.

For example, Cy_{A}, Cy_{B}, and Cy_{C} may all be aryl rings, or Cy_{C} may be an aryl ring, and one from among Cy_{A} and Cy_{B} may be a heteroaryl ring. For example, Cy_{A}, Cy_{B}, and Cy_{C} may all be benzene rings, or Cy_{C} may be a benzene ring, and one from among Cy_{A} and Cy_{B} may be a heteroaryl ring containing a boron atom (B). However, the embodiment of the present disclosure is not limited thereto.

In Formula 1, X₁ and X₂ may each independently be O, S, or NR₁, and R₁ may be a substituted or unsubstituted aryl group having 6 to 30 ring-forming carbon atoms, or a substituted or unsubstituted heteroaryl group having 5 to 30 ring-forming carbon atoms. For example, both (e.g., simultaneously) X₁ and X₂ may be represented by NR₁, or one from among X₁ and X₂ may be NR₁, and the other may be O or S.

In Formula 1, n1, n2, and n3 may each be an integer of 0 or greater, and n1+n2+n3 may be 1 or greater. For example, at least one from among n1, n2, and n3 may be 1 or greater. In an embodiment, the conditions of 0≤n1≤(the number of ring-forming carbon atoms of Cy_{A}-2), 0≤n2≤(the number of ring-forming carbon atoms of Cy_{B}-2), 0≤n3≤(the number of ring-forming carbon atoms of Cy_{C}-2) may be satisfied.

For example, n1 may be an integer of 0 or greater, and may have the maximum value in which 2 is subtracted from the number of ring-forming carbon atoms of Cy_{A}. For example, when Cy_{A} is a benzene ring, n1 may be an integer of 0 to 4. When n1 is 0, Cy_{A} may be unsubstituted. In some embodiments, when n is 2 or greater, a plurality Z₁'s may all be the same or at least one may be different from the rest.

The above description of n1 may be equally applied to the definitions of n2 and n3. n2 may be an integer of 0 or greater, and may have the maximum value in which 2 is subtracted from the number of ring-forming carbon atoms of Cy_{B}. In some embodiments, n3 may be an integer of 0 or greater, and may have the maximum value in which 2 is subtracted from the number of ring-forming carbon atoms of Cy_{C}.

In the polycyclic compound represented by Formula 1 of an embodiment, at least one of Z₁, Z₂, or Z₃ may be a nitrogen-containing polycyclic group having at least eight ring-forming carbon atoms and containing at least two bridgehead carbon atoms, or a substituent including the nitrogen-containing polycyclic group, and the rest may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

For example, the polycyclic compound of an embodiment may include at least one nitrogen-containing polycyclic group having at least eight ring-forming carbon atoms and containing at least two bridgehead carbon atoms. The term “bridgehead carbon” as used herein refers to a carbon atom shared by at least two rings. For example, in Formula A, C^{D} and C^{E} correspond to the bridgehead carbon. In Formula A, the carbon atoms represented by C^{D} and C^{E} correspond to the carbon atom that two rings share.

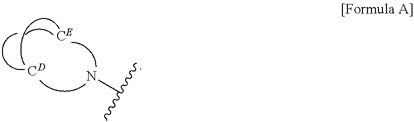 [SMILES: "CE" ; "CD" ; *N]

In some embodiments, in the polycyclic compound of an embodiment, the nitrogen-containing polycyclic group may be a derivative of an aliphatic hydrocarbon ring containing at least two bridgehead carbon atoms, and may contain one nitrogen atom as a ring-forming atom.

In the polycyclic compound of an embodiment, at least one of a plurality of Z₁'s, a plurality of Z₂'s, or a plurality of Z₃'s may be a nitrogen-containing polycyclic group having at least eight ring-forming carbon atoms and containing at least two bridgehead carbon atoms, or a substituent including the nitrogen-containing polycyclic group. For example, the polycyclic compound of an embodiment may include one nitrogen-containing polycyclic group, two nitrogen-containing polycyclic groups, or three nitrogen-containing polycyclic groups.

The polycyclic compound of an embodiment may have a compound structure which has a core part represented by Formula B that is a fused ring containing a boron atom (B), and in which at least one of Cy_{A}, Cy_{B}, or Cy_{C} of the core part is substituted with the nitrogen-containing polycyclic group.

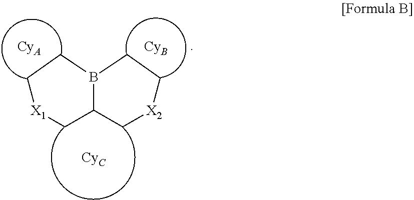

The nitrogen-containing polycyclic group may function as a donor part in the polycyclic compound of an embodiment, and when the nitrogen-containing polycyclic group corresponding to a derivative derived from an aliphatic hydrocarbon ring group is utilized as an emission layer material, a light emission wavelength may be shortened as compared with a carbazole group or a diphenylamine group utilized as a related art donor part. In some embodiments, the nitrogen-containing polycyclic group in an embodiment has a bulky structure having at least eight ring-forming carbon atoms, and thus may have a greater steric shielding effect that protects the compound molecule, thereby contributing to a long service life of the light emitting element.

In an embodiment, the polycyclic compound represented by Formula 1 may be represented by Formula 1-1 or Formula 1-2:

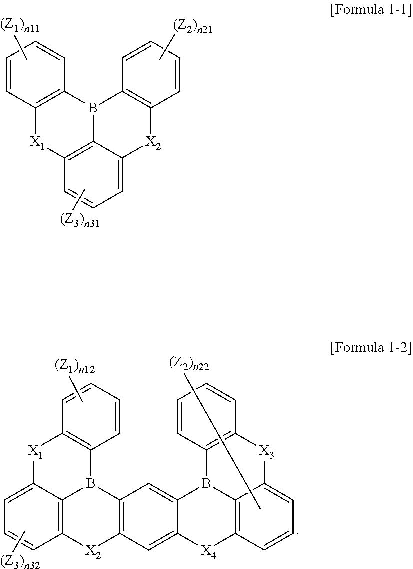

Referring to Formula 1-1 and Formula 1-2, the polycyclic compound of an embodiment may include, as a core part, a pentacyclic fused ring containing one boron atom, or a nonacyclic fused ring containing two boron atoms.

In Formula 1-1, n11 and n21 may each independently be an integer of 0 to 4, n31 may be an integer of 0 to 3, and n11+n21+n31 may be 1 or greater. In Formula 1-1, X₁, X₂, Z₁, Z₂, and Z₃ may respectively be the same as described in connection with Formula 1. For example, in the polycyclic compound represented by Formula 1-1 of an embodiment, at least one of Z₁, Z₂, or Z₃ may include a nitrogen-containing polycyclic group having at least eight ring-forming carbon atoms and containing at least two bridgehead carbon atoms.

In some embodiments, in Formula 1-2, X₃ and X₄ may each independently be O, S, or NR₁, and R₁ may be a substituted or unsubstituted aryl group having 6 to 30 ring-forming carbon atoms, or a substituted or unsubstituted heteroaryl group having 5 to 30 ring-forming carbon atoms.

n12 may be an integer of 0 to 4, n22 may be an integer of 0 to 7, n32 may be an integer of 0 to 3, and n12+n22+n32 may be 1 or greater. In Formula 1-2, X₁, X₂, Z₁, Z₂, and Z₃ may respectively be the same as described in connection with Formula 1. For example, in the polycyclic compound represented by Formula 1-2 of an embodiment, at least one of Z₁, Z₂, or Z₃ may include a nitrogen-containing polycyclic group having at least eight ring-forming carbon atoms and containing at least two bridgehead carbon atoms.

In some embodiments, the polycyclic compound represented by Formula 1-1 may be represented by Formula 1-1a:

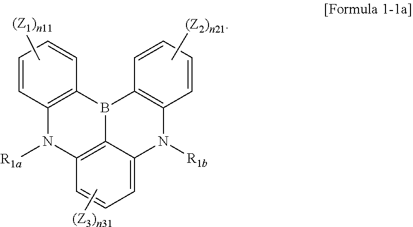

In Formula 1-1a, R₁ₐ and R_{1b} may each independently be a substituted or unsubstituted aryl group having 6 to 30 ring-forming carbon atoms, or a substituted or unsubstituted heteroaryl group having 5 to 30 ring-forming carbon atoms. n11 and n21 may each independently be an integer of 0 to 4, n31 may be an integer of 0 to 3, and n11+n21+n31 may be 1 or greater. In Formula 1-1a, Z₁, Z₂, and Z₃ may be the same as described in connection with Formula 1. For example, in the polycyclic compound represented by Formula 1-1a of an embodiment, at least one of Z₁, Z₂, or Z₃ may include a nitrogen-containing polycyclic group having at least eight ring-forming carbon atoms and containing at least two bridgehead carbon atoms.

The polycyclic compound represented by Formula 1-1 may be represented by any one from among Formula 1-1 b to Formula 1-1e:

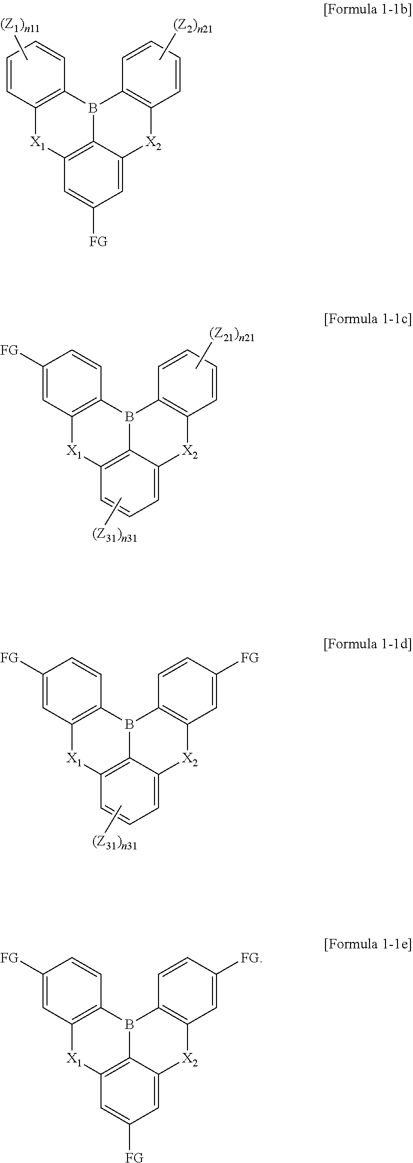

In Formula 1-b to Formula 1-1e, FG may be a nitrogen-containing polycyclic group having at least eight ring-forming carbon atoms and containing at least two bridgehead carbon atoms, or a substituent including the nitrogen-containing polycyclic group. In an embodiment, FG may include azaadamantane. For example, FG may be a substituted or unsubstituted azaadamantyl group, or a substituent including an azaadamantyl group.

In Formula 1-1b to Formula 1-1e, Z₁₁, Z₂₁, and Z₃₁ may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

n11 and n21 may each independently be an integer of 0 to 4, and n31 may be an integer of 0 to 3.

In some embodiments, in Formula 1-1 b to Formula 1-1e, X₁ and X₂ may be the same as described in connection with Formula 1.

The polycyclic compound represented by Formula 1-2 as described above may be represented by Formula 1-2a or Formula 1-2b:

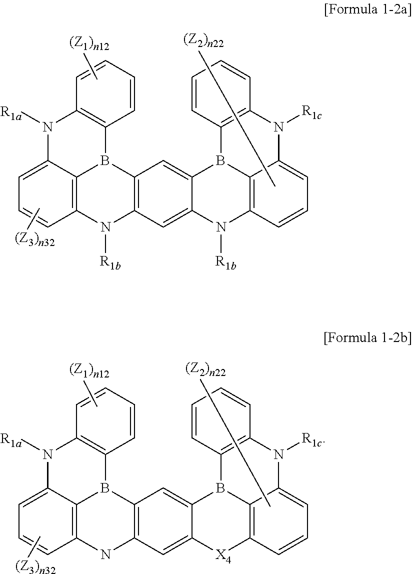

In Formula 1-2a and Formula 1-2b, R₁ₐ, R_{1b}, R_{1c}, and R_{1d} may each independently be a substituted or unsubstituted aryl group having 6 to 30 ring-forming carbon atoms, or a substituted or unsubstituted heteroaryl group having 5 to 30 ring-forming carbon atoms.

X₄ may be O, S, or NR₁, and R₁ may be a substituted or unsubstituted aryl group having 6 to 30 ring-forming carbon atoms, or a substituted or unsubstituted heteroaryl group having 5 to 30 ring-forming carbon atoms.

In Formula 1-2a and Formula 1-2b, n12 may be an integer of 0 to 4, n22 may be an integer of 0 to 7, n32 may be an integer of 0 to 3, and n12+n22+n32 may be 1 or greater. Z₁, Z₂, and Z₃ may be the same as described in connection with Formula 1. For example, in the polycyclic compound represented by Formula 1-2a or Formula 1-2b of an embodiment, at least one of Z₁, Z₂, or Z₃ may include a nitrogen-containing polycyclic group having at least eight ring-forming carbon atoms and containing at least two bridgehead carbon atoms.

The polycyclic compound represented by Formula 1-2 may be represented by Formula 1-2c or Formula 1-2d:

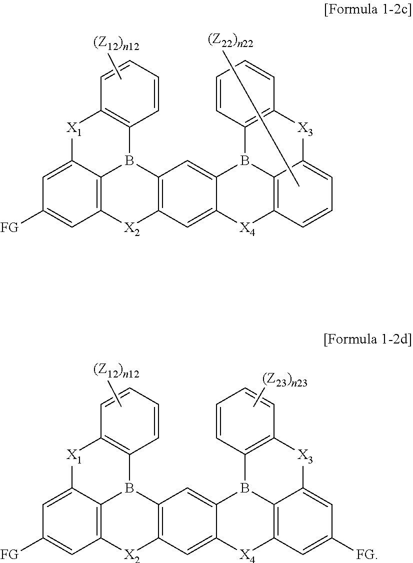

In Formula 1-2c and Formula 1-2d, FG may be a nitrogen-containing polycyclic group having at least eight ring-forming carbon atoms and containing at least two bridgehead carbon atoms, or a substituent including the nitrogen-containing polycyclic group. In an embodiment, in Formula 1-2c and Formula 1-2d, FG may include azaadamantane. For example, FG may be a substituted or unsubstituted azaadamantyl group, or a substituent including an azaadamantyl group.

In Formula 1-2c and Formula 1-2d, Z₁₂, Z₂₂, and Z₂₃ may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

n12 and n23 may each independently be an integer of 0 to 4, and n22 may be an integer of 0 to 7.

In some embodiments, in Formula 1-2c and Formula 1-2d, X₁ and X₂ may be the same as described in connection with Formula 1. X₃ and X₄ may be the same as described in connection with Formula 1-2.

In the polycyclic compound represented by Formula 1 of an embodiment, the nirogen-containing polycyclic group may be represented by any one from among Formulae 2-1 to 2-4:

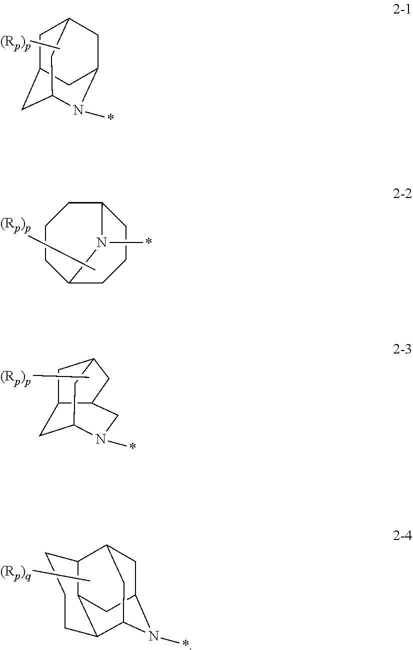

In Formulae 2-1 to 2-4 above, Rₚ may be a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 5 to 30 ring-forming carbon atoms.

In an embodiment, p may be an integer of 0 to 14, and q may be an integer of 0 to 18. For example, in the polycyclic compound of an embodiment, p may be 0. In some embodiments, q may be 0. However, the embodiment of the present disclosure is not limited thereto.

In the polycyclic compound represented by Formula 1 of an embodiment, at least one of Z₁, Z₂, or Z₃ may be represented by any one from among Formulae 2-1 to 2-4 and 2-1a to 2-4a. In some embodiments, in Formulae 1-1 b to 1-1e, Formula 1-2c, and Formula 1-2d as described above, FG may be represented by any one from among Formulae 2-1 to 2-4 and 2-1a to 2-4a:

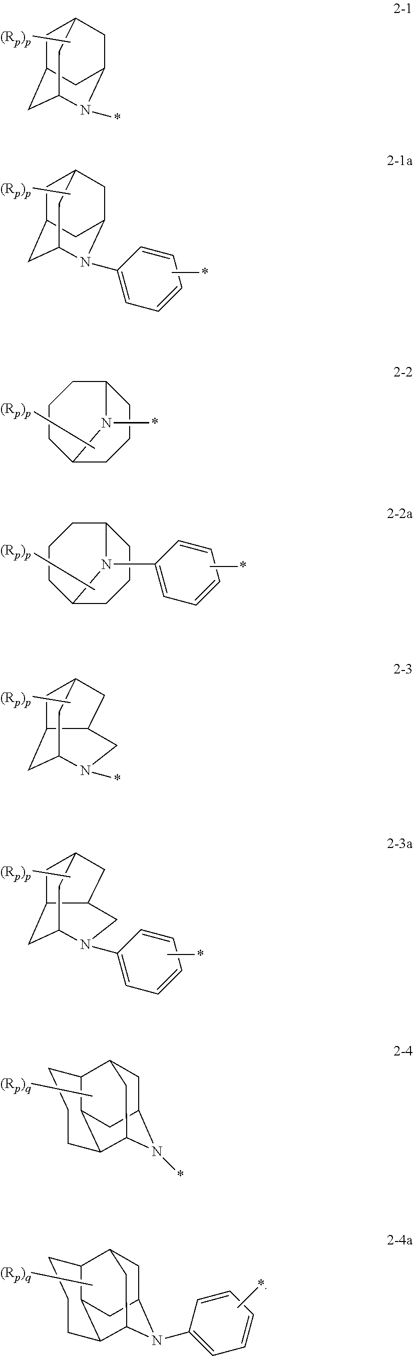

In Formulae 2-1 to 2-4 and 2-1a to 2-4a above, Rₚ may be a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 5 to 30 ring-forming carbon atoms.

In an embodiment, p may be an integer of 0 to 14, and q may be an integer of 0 to 18. For example, in the polycyclic compound of an embodiment, p may be 0. In some embodiments, q may be 0. However, the embodiment of the present disclosure is not limited thereto.

In some embodiments, the polycyclic compound of an embodiment may include at least one deuterium atom as a substituent. In an embodiment, at least one of R₁, Z₁, Z₂, or Z₃ in Formula 1 may include a deuterium atom, or a substituent containing a deuterium atom.

The polycyclic compound of an embodiment may be any one of the compounds in Compound Group 1. The light emitting element ED of an embodiment may include any one from among the compounds of Compound Group 1. D in Compound Group 1 is a deuterium atom.

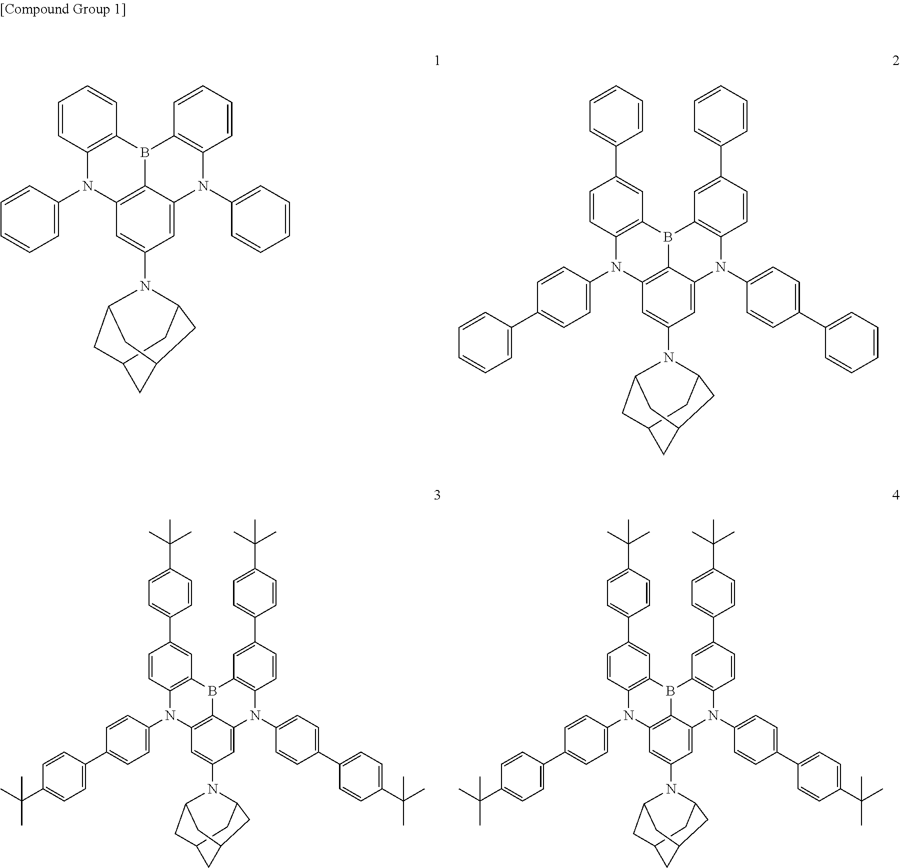

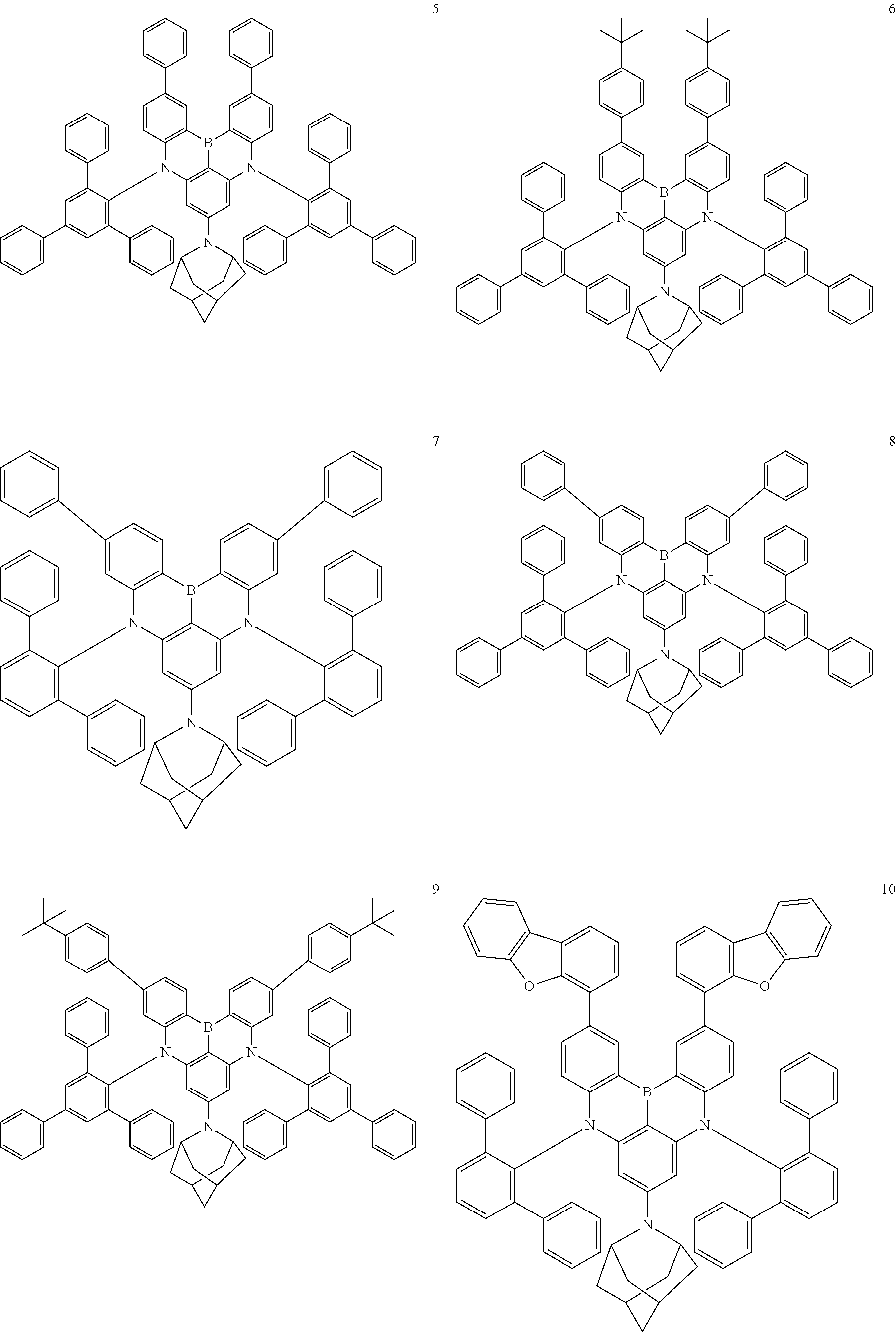

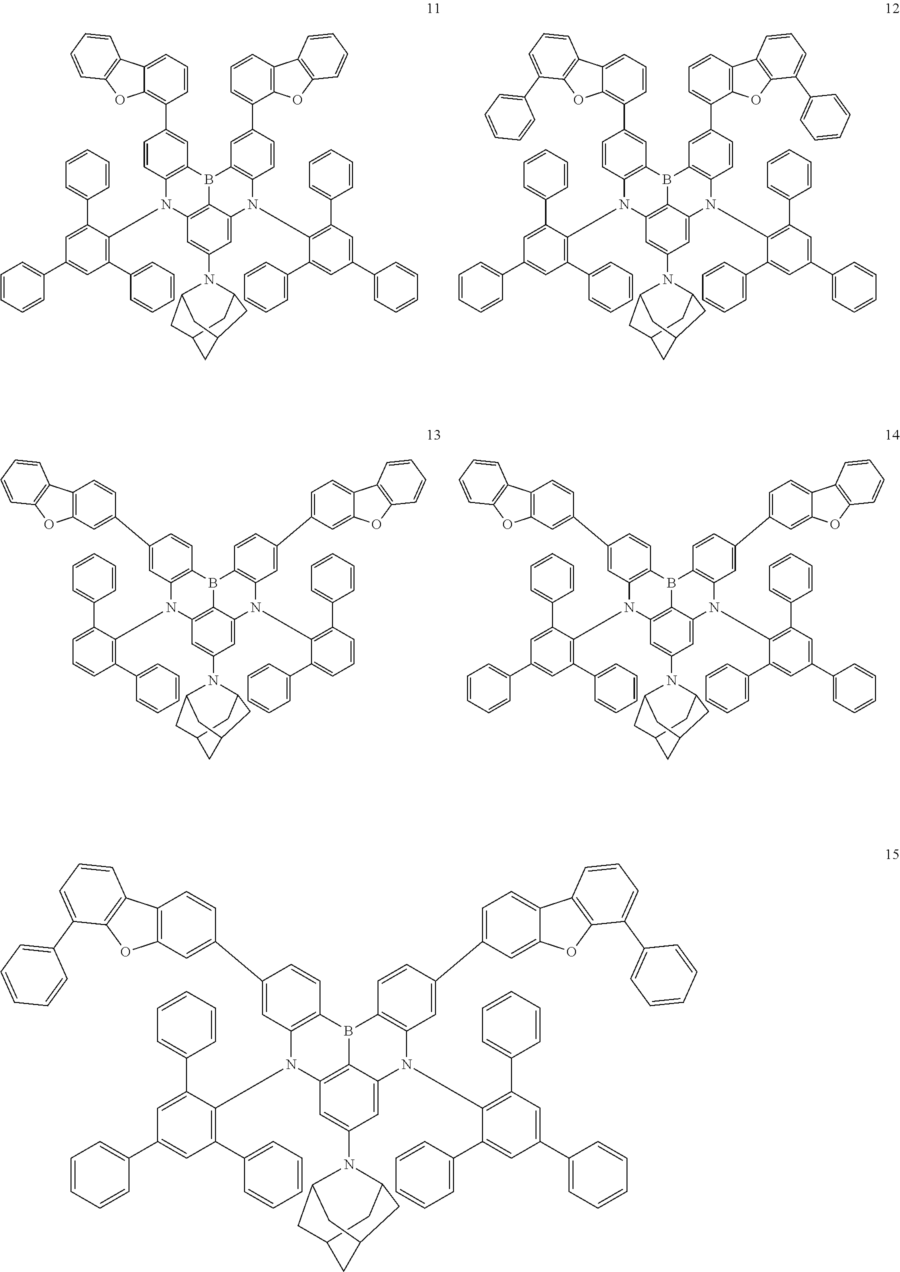

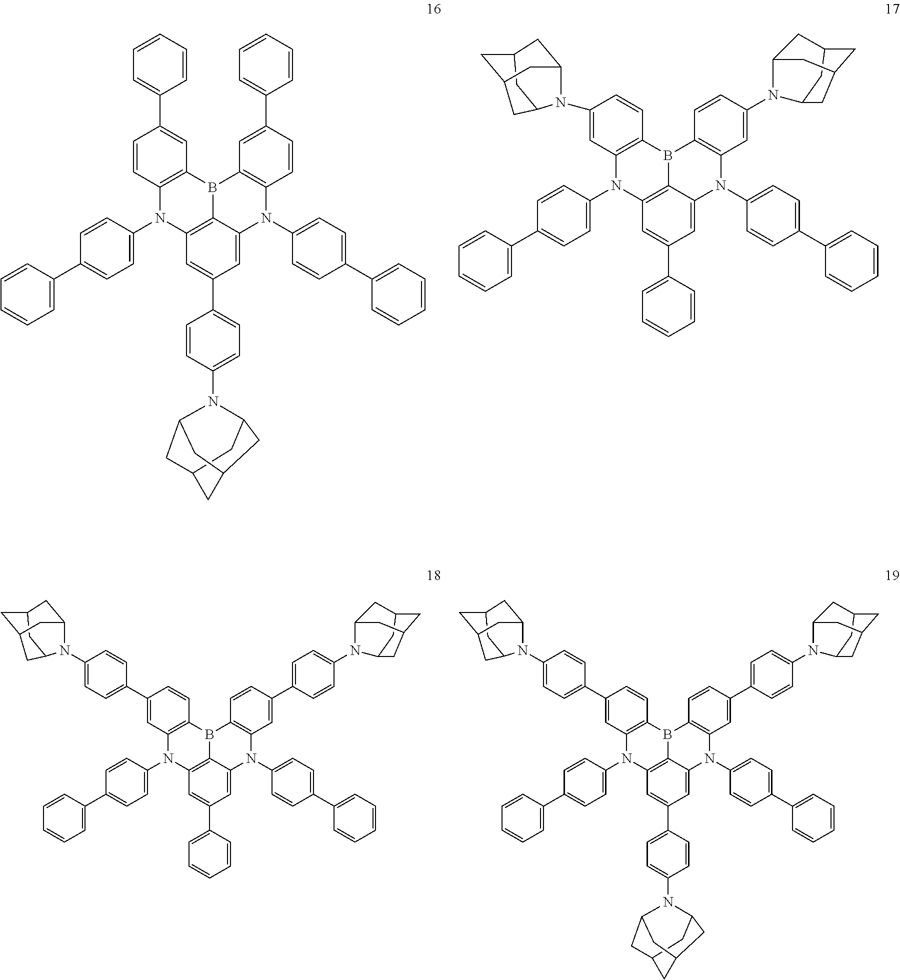

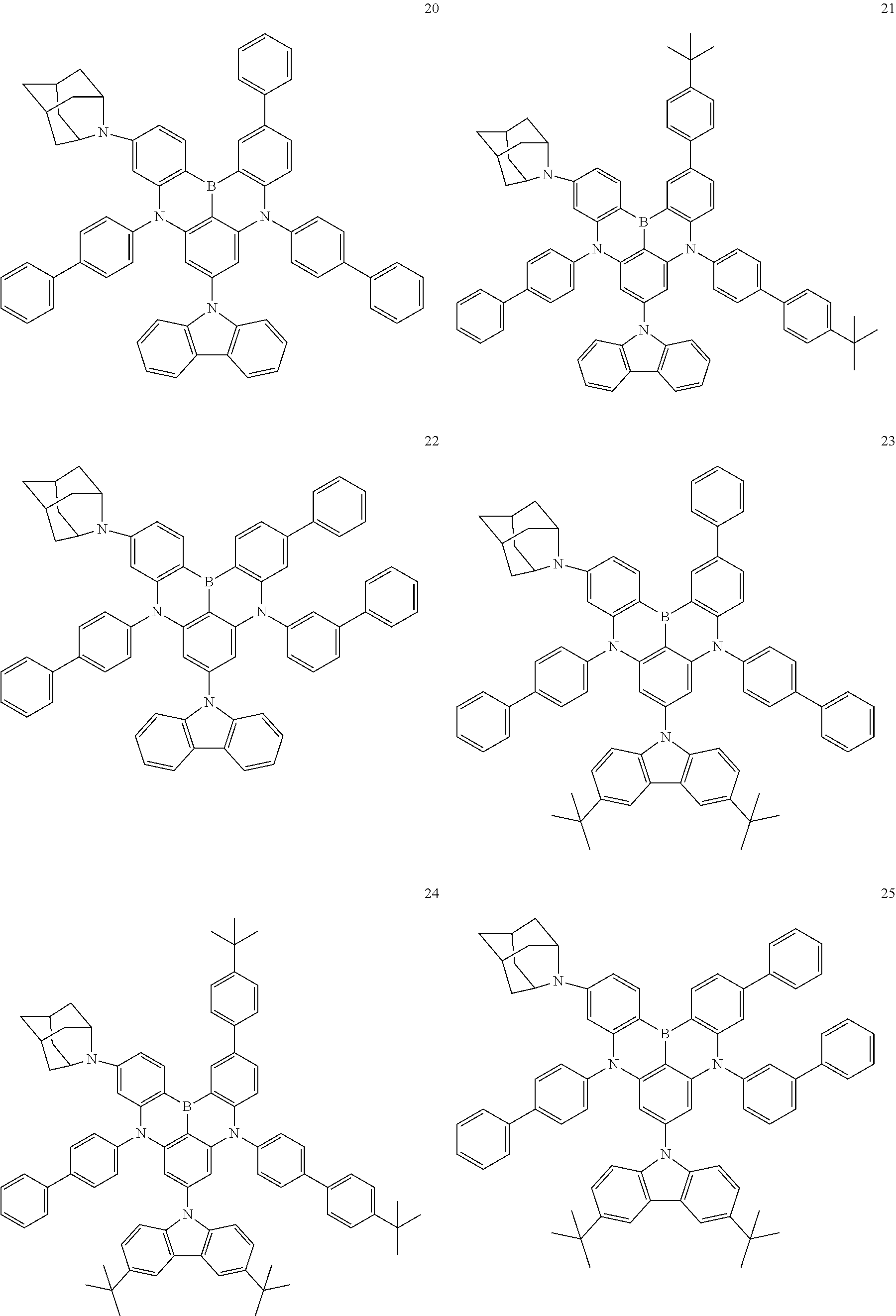

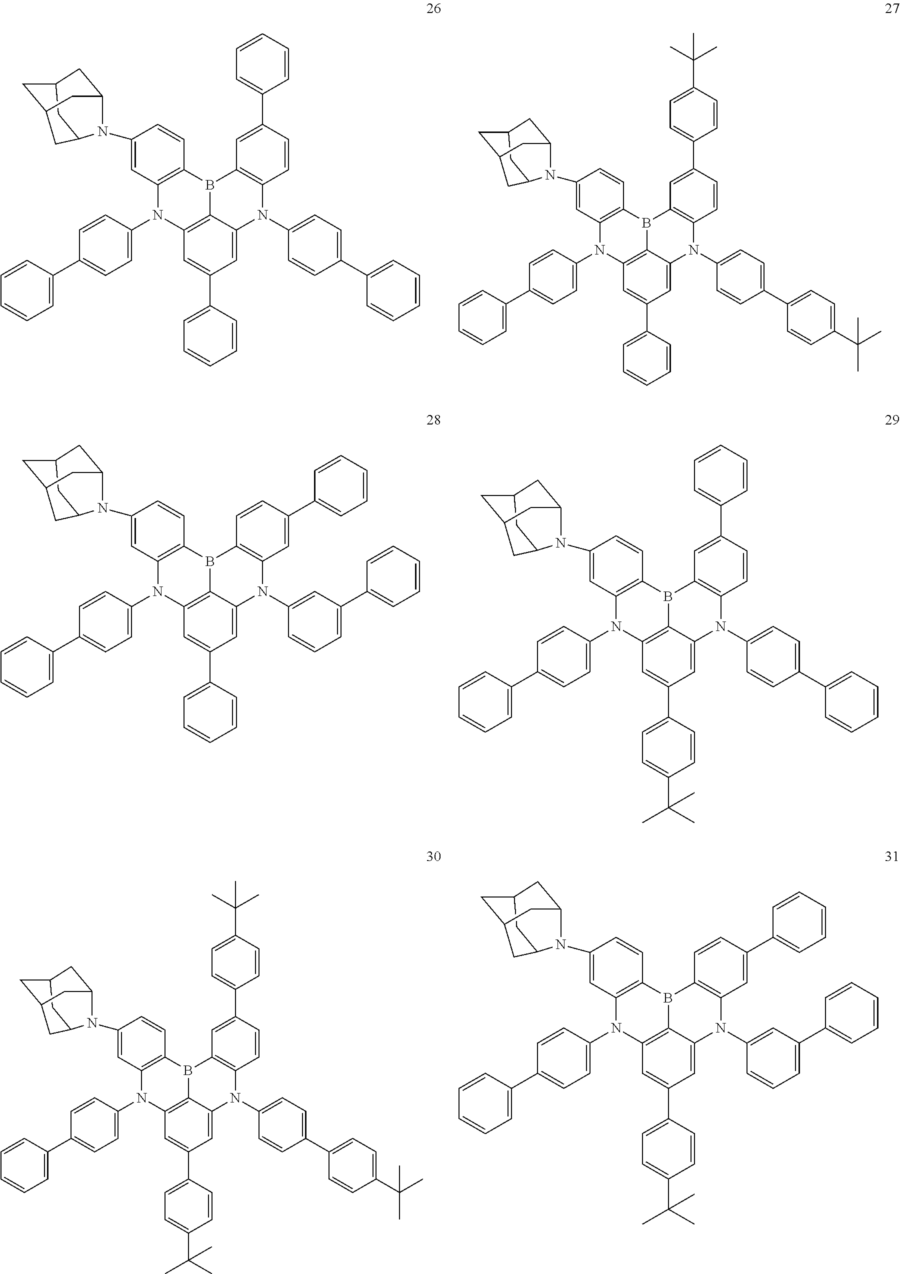

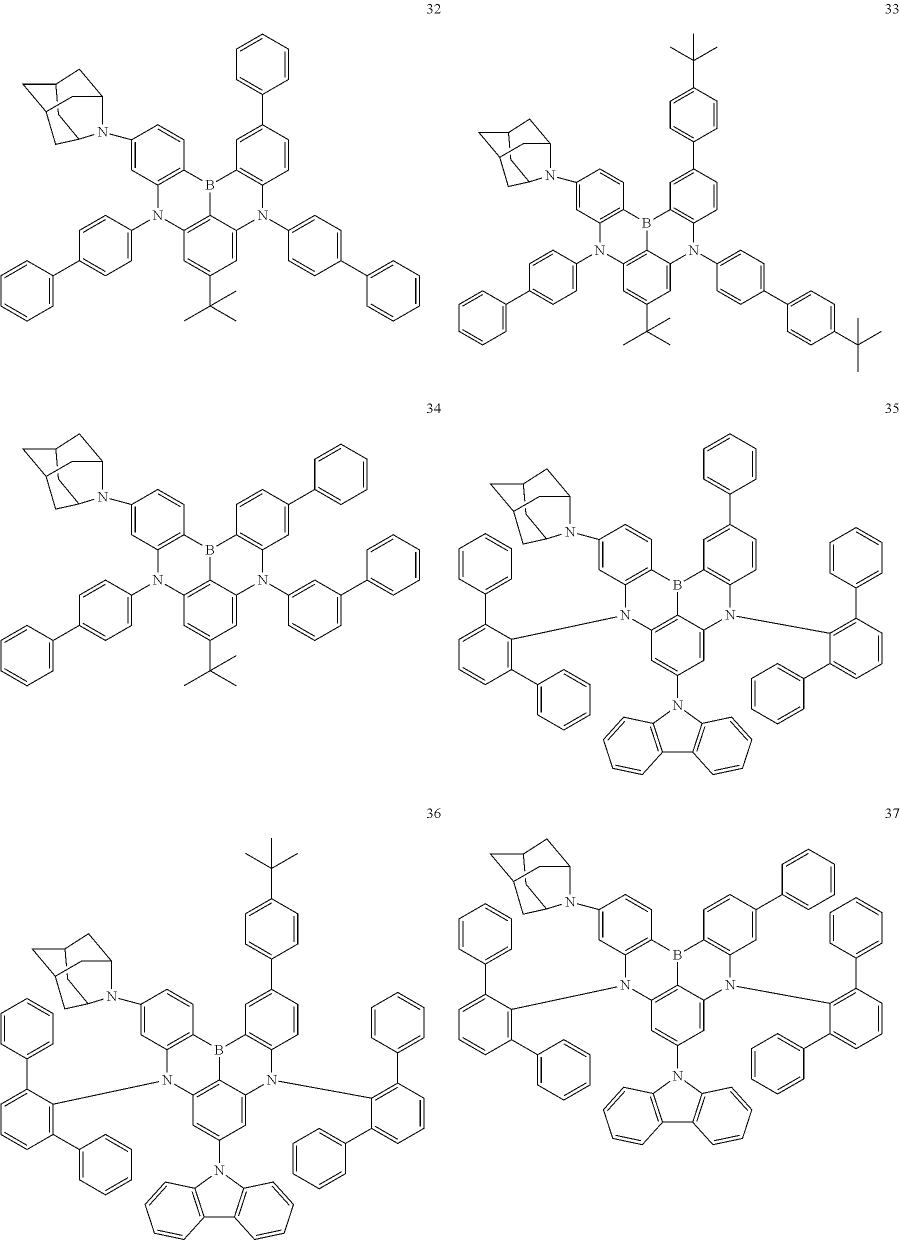

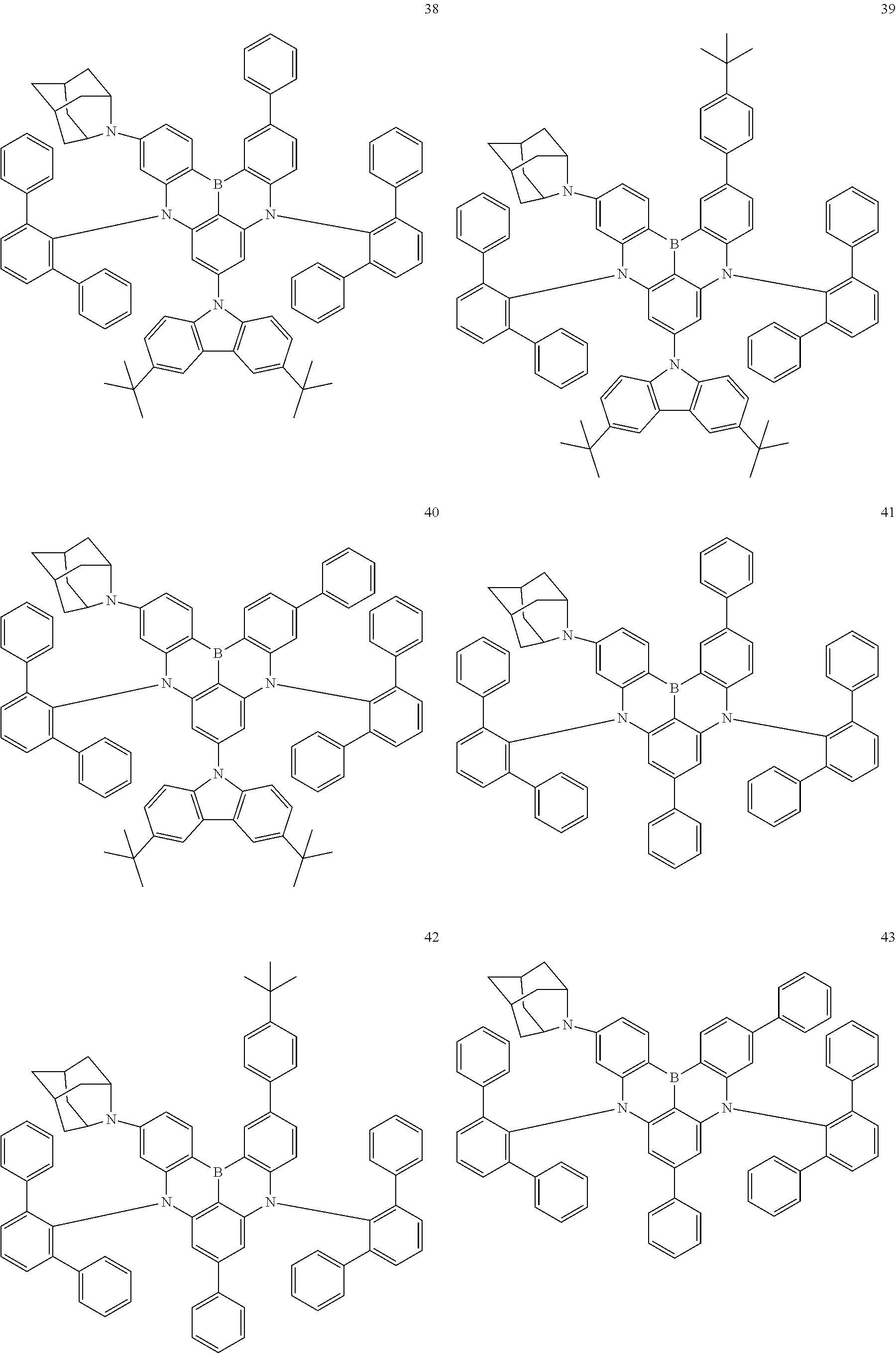

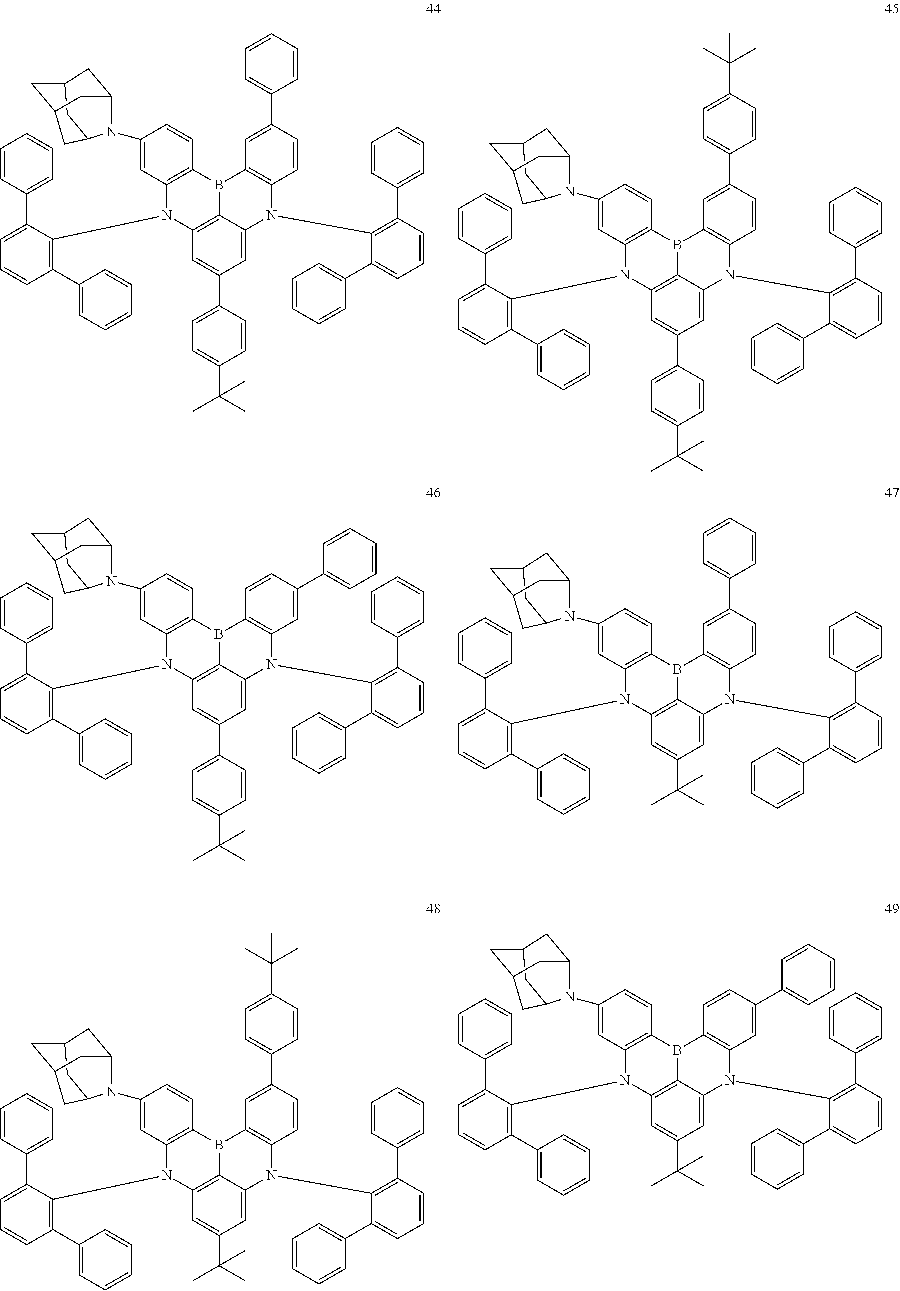

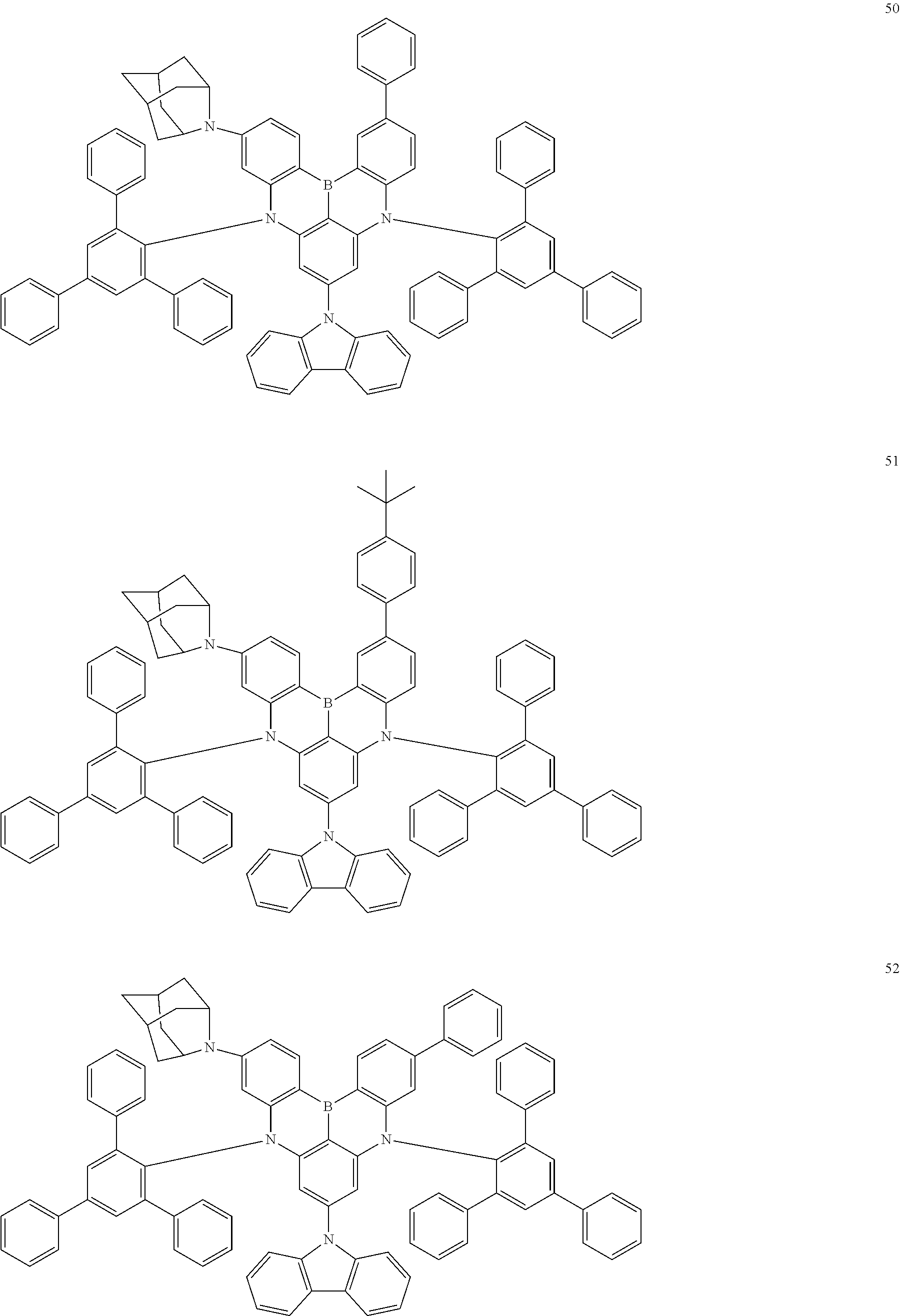

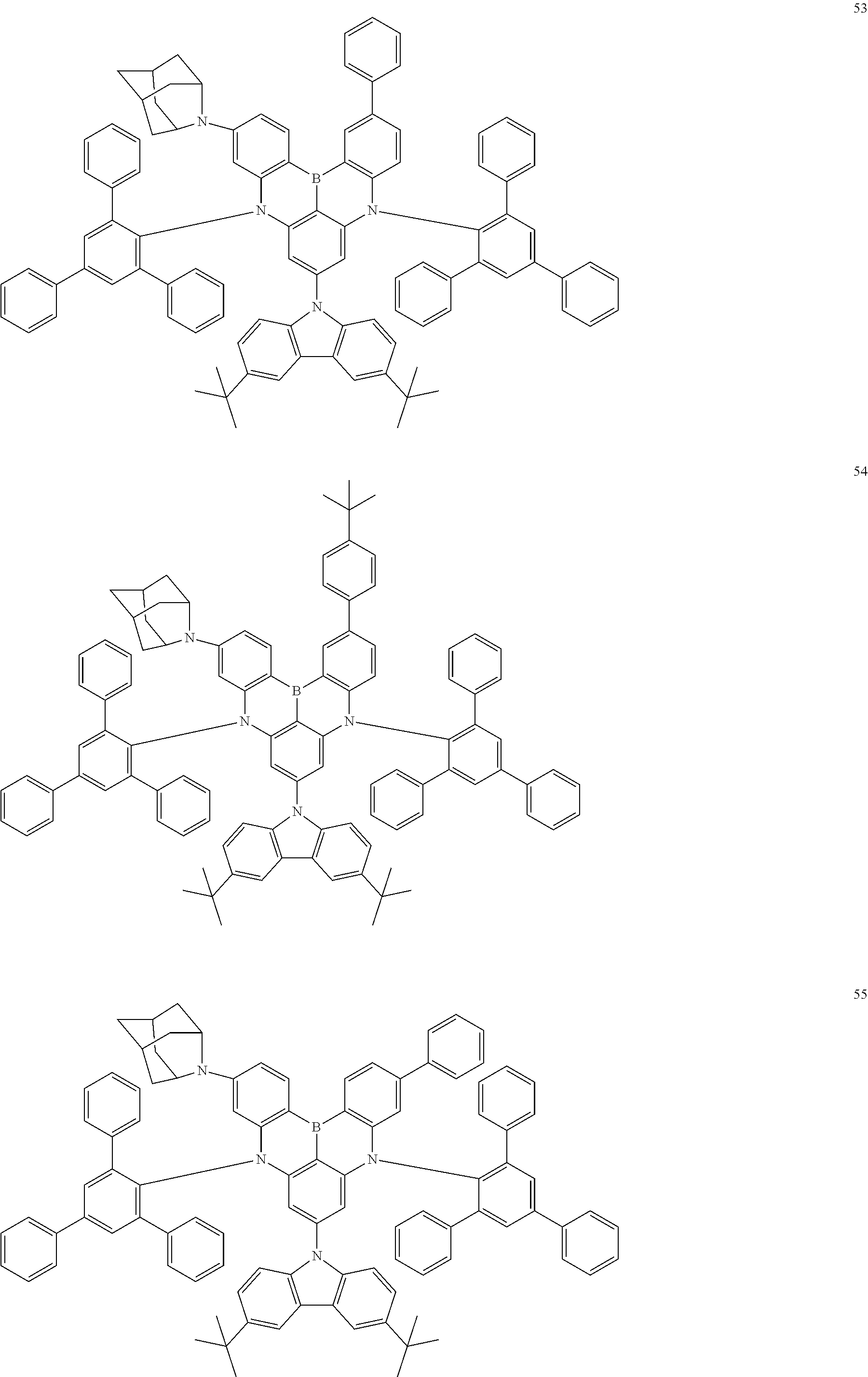

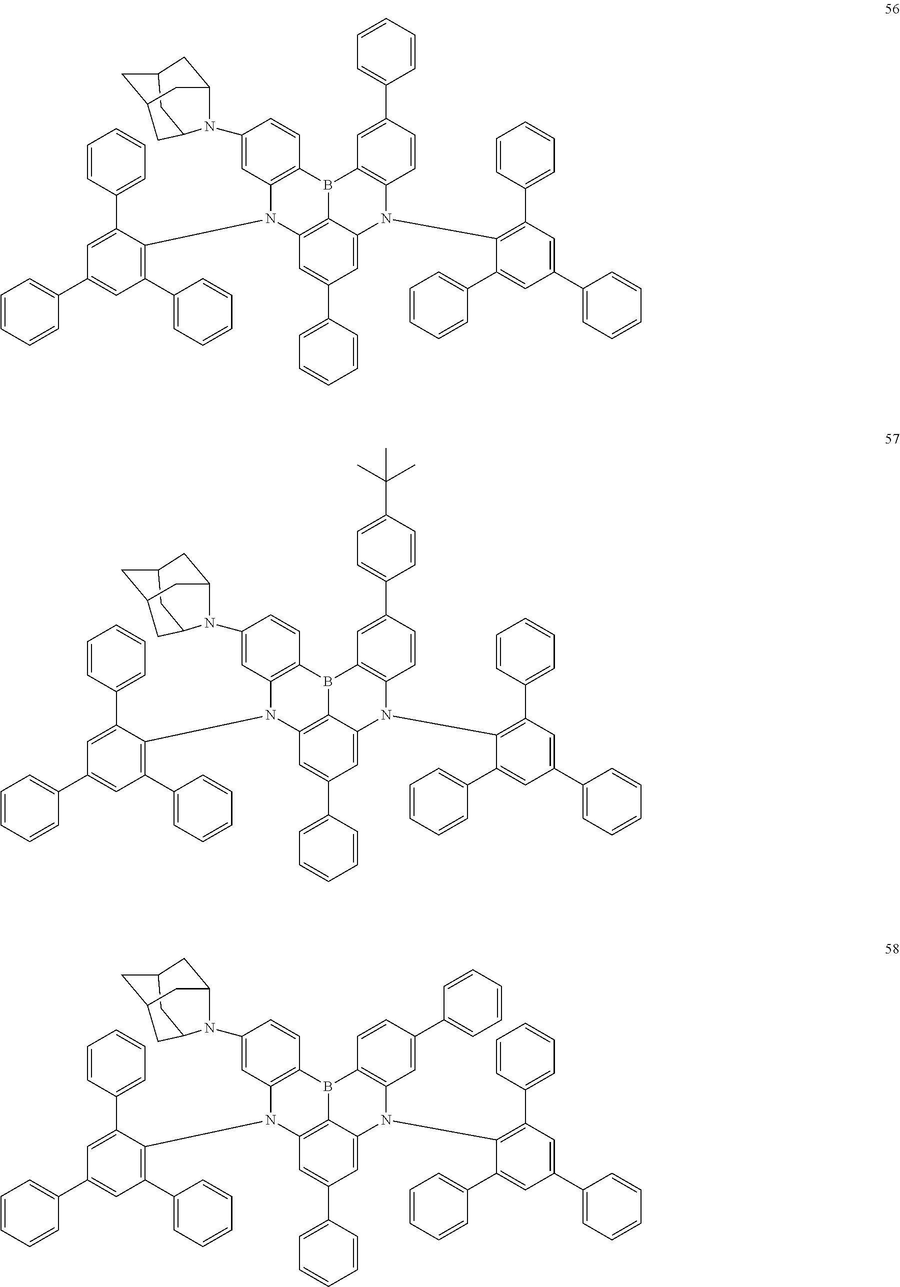 [SMILES: c1ccc(-c2ccc3c(c2)B2c4ccc(N5C6CC7CC(C6)CC5C7)cc4N(c4c(-c5ccccc5)cc(-c5ccccc5)cc4-c4ccccc4)c4cc(-c5ccccc5)cc(c42)N3c2c(-c3ccccc3)cc(-c3ccccc3)cc2-c2ccccc2)cc1 ; CC(C)(C)c1ccc(-c2ccc3c(c2)B2c4ccc(N5C6CC7CC(C6)CC5C7)cc4N(c4c(-c5ccccc5)cc(-c5ccccc5)cc4-c4ccccc4)c4cc(-c5ccccc5)cc(c42)N3c2c(-c3ccccc3)cc(-c3ccccc3)cc2-c2ccccc2)cc1 ; c1ccc(-c2cc(-c3ccccc3)c(N3c4cc(-c5ccccc5)ccc4B4c5ccc(N6C7CC8CC(C7)CC6C8)cc5N(c5c(-c6ccccc6)cc(-c6ccccc6)cc5-c5ccccc5)c5cc(-c6ccccc6)cc3c54)c(-c3ccccc3)c2)cc1]

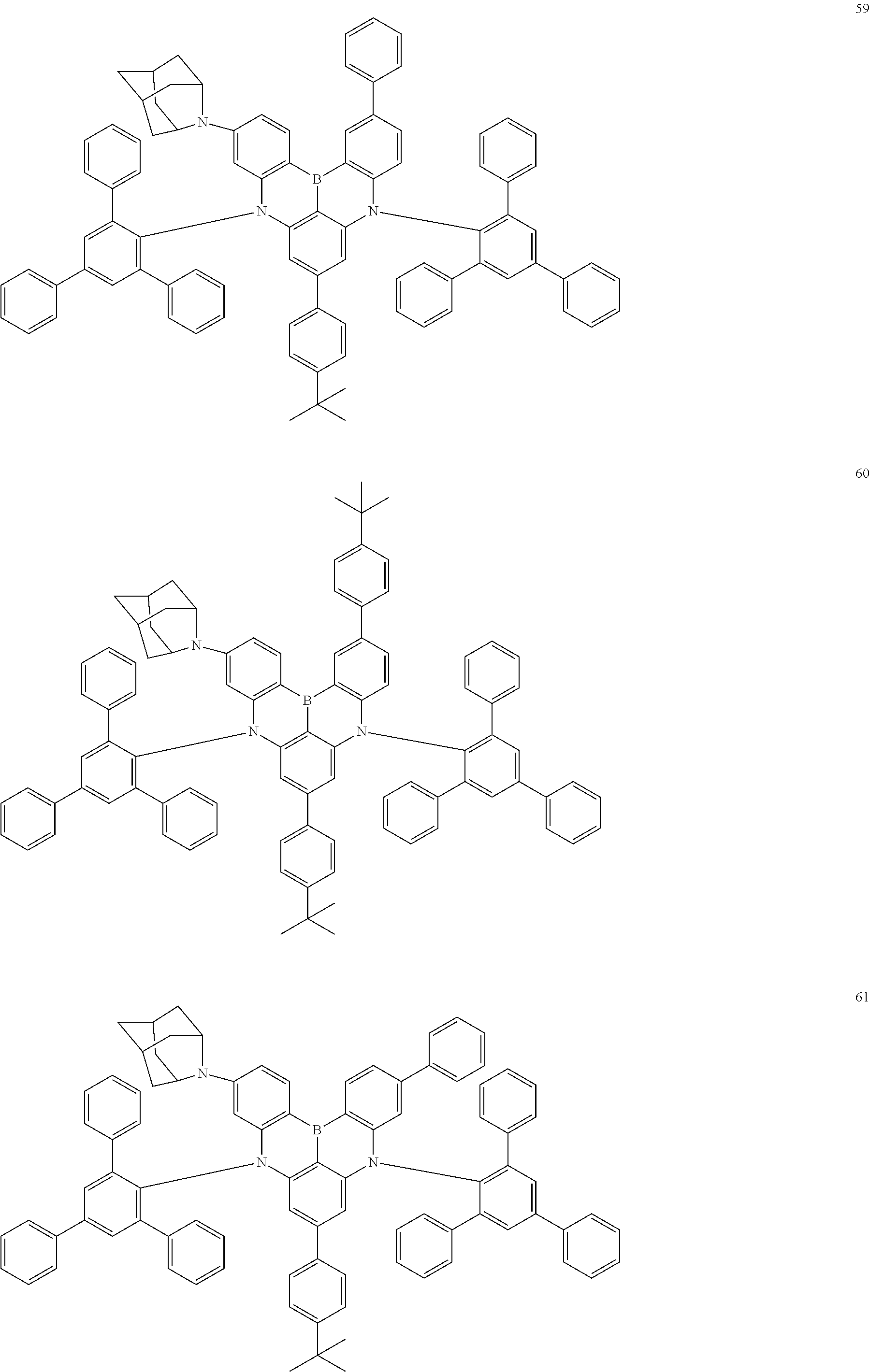

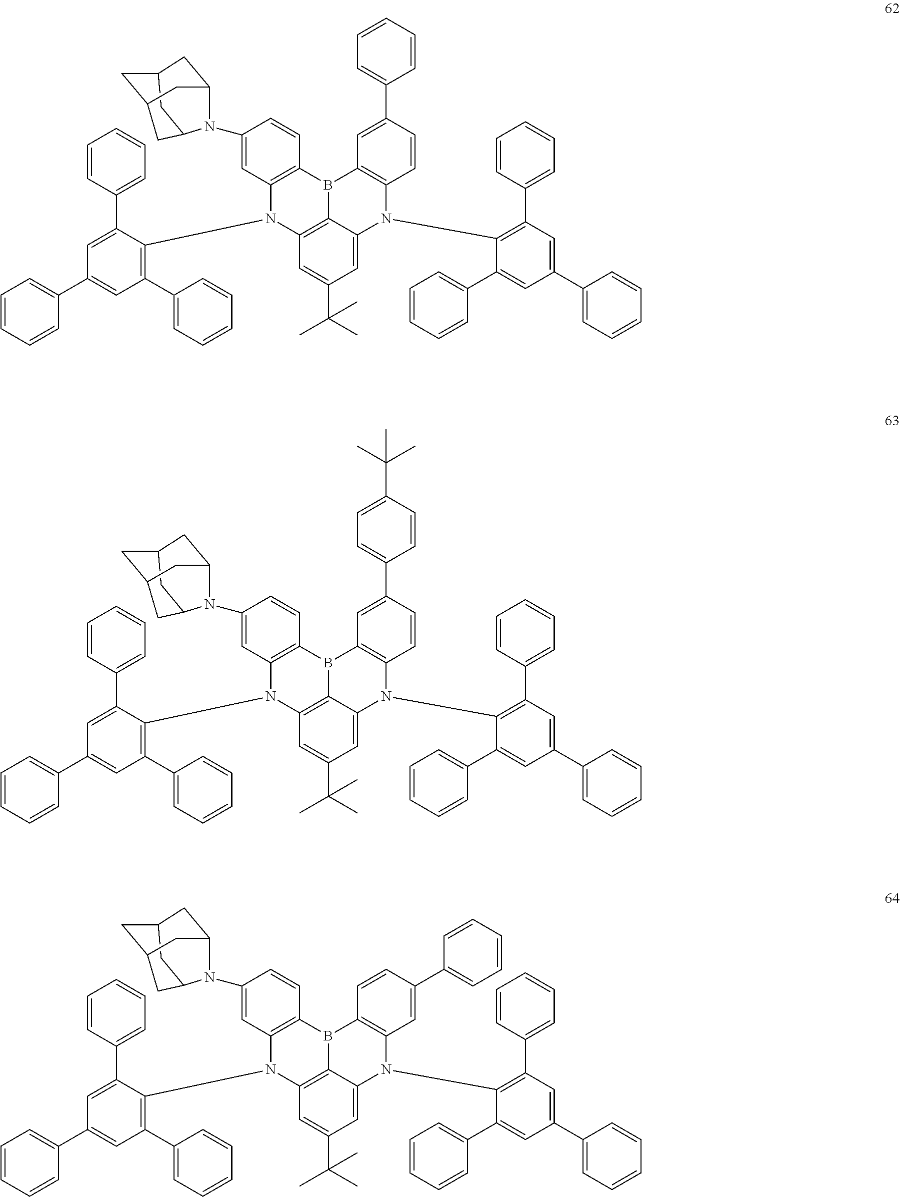 [SMILES: CC(C)(C)c1cc2c3c(c1)N(c1c(-c4ccccc4)cc(-c4ccccc4)cc1-c1ccccc1)c1cc(N4C5CC6CC(C5)CC4C6)ccc1B3c1cc(-c3ccccc3)ccc1N2c1c(-c2ccccc2)cc(-c2ccccc2)cc1-c1ccccc1 ; CC(C)(C)c1ccc(-c2ccc3c(c2)B2c4ccc(N5C6CC7CC(C6)CC5C7)cc4N(c4c(-c5ccccc5)cc(-c5ccccc5)cc4-c4ccccc4)c4cc(C(C)(C)C)cc(c42)N3c2c(-c3ccccc3)cc(-c3ccccc3)cc2-c2ccccc2)cc1 ; CC(C)(C)c1cc2c3c(c1)N(c1c(-c4ccccc4)cc(-c4ccccc4)cc1-c1ccccc1)c1cc(N4C5CC6CC(C5)CC4C6)ccc1B3c1ccc(-c3ccccc3)cc1N2c1c(-c2ccccc2)cc(-c2ccccc2)cc1-c1ccccc1]

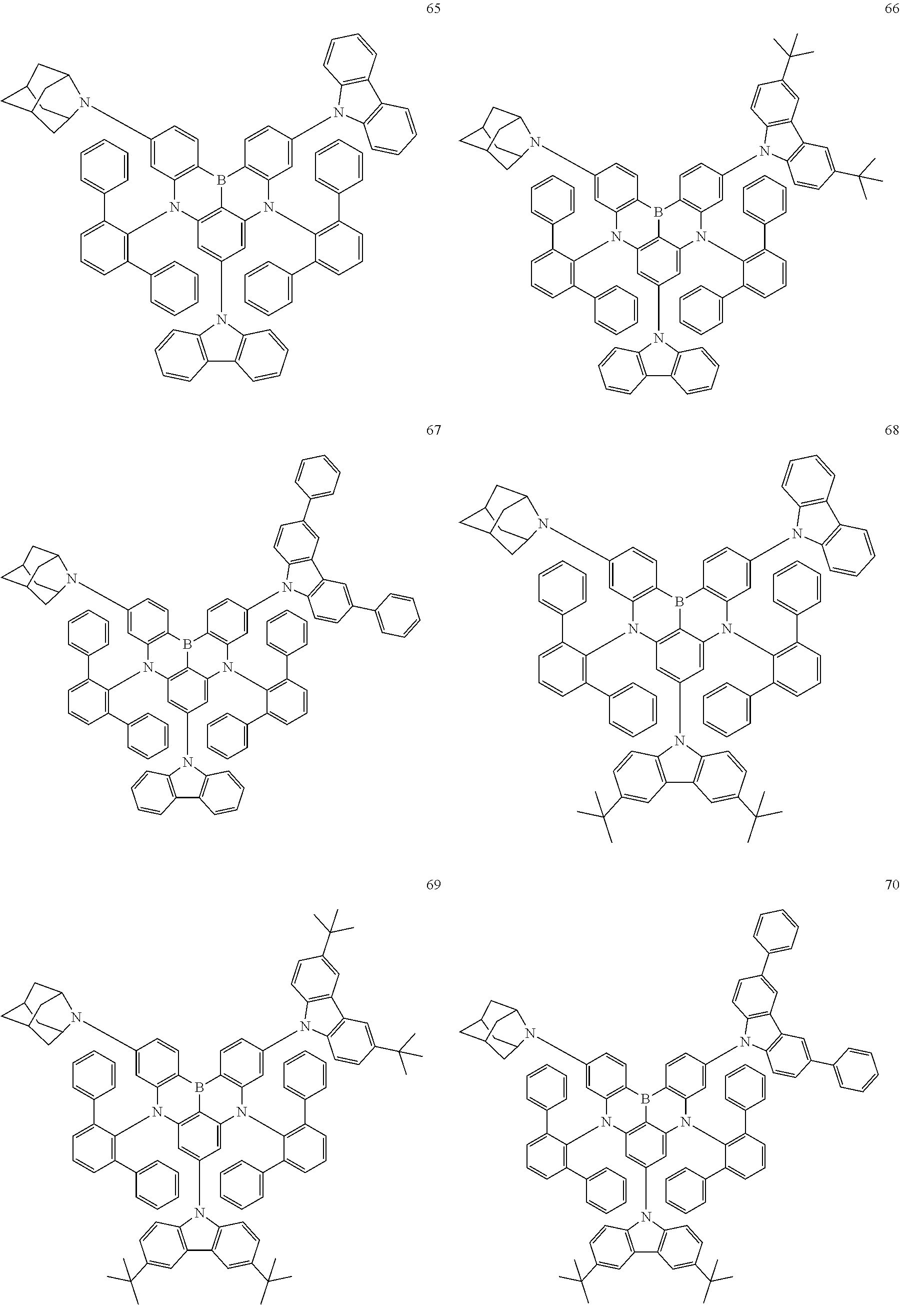

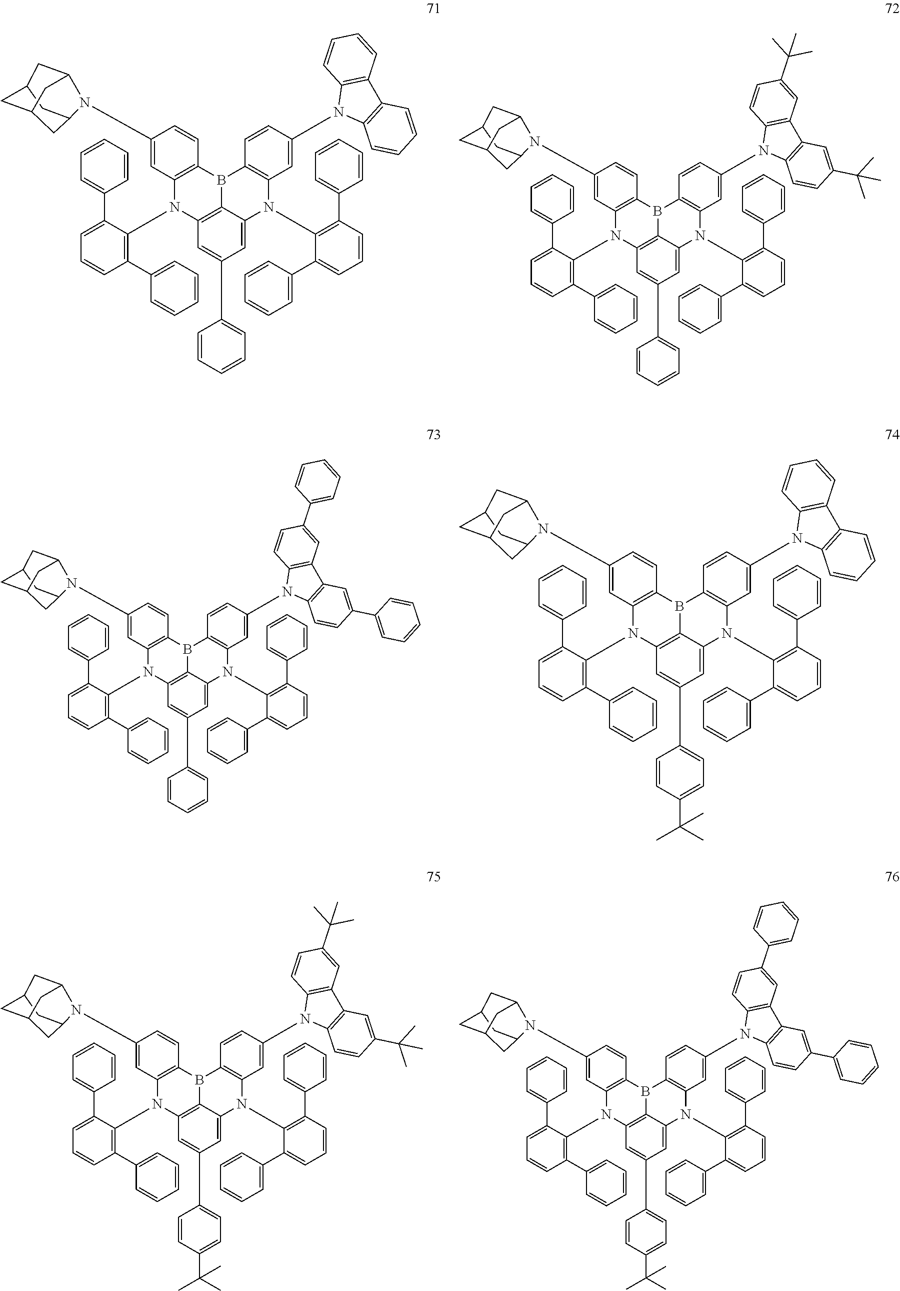

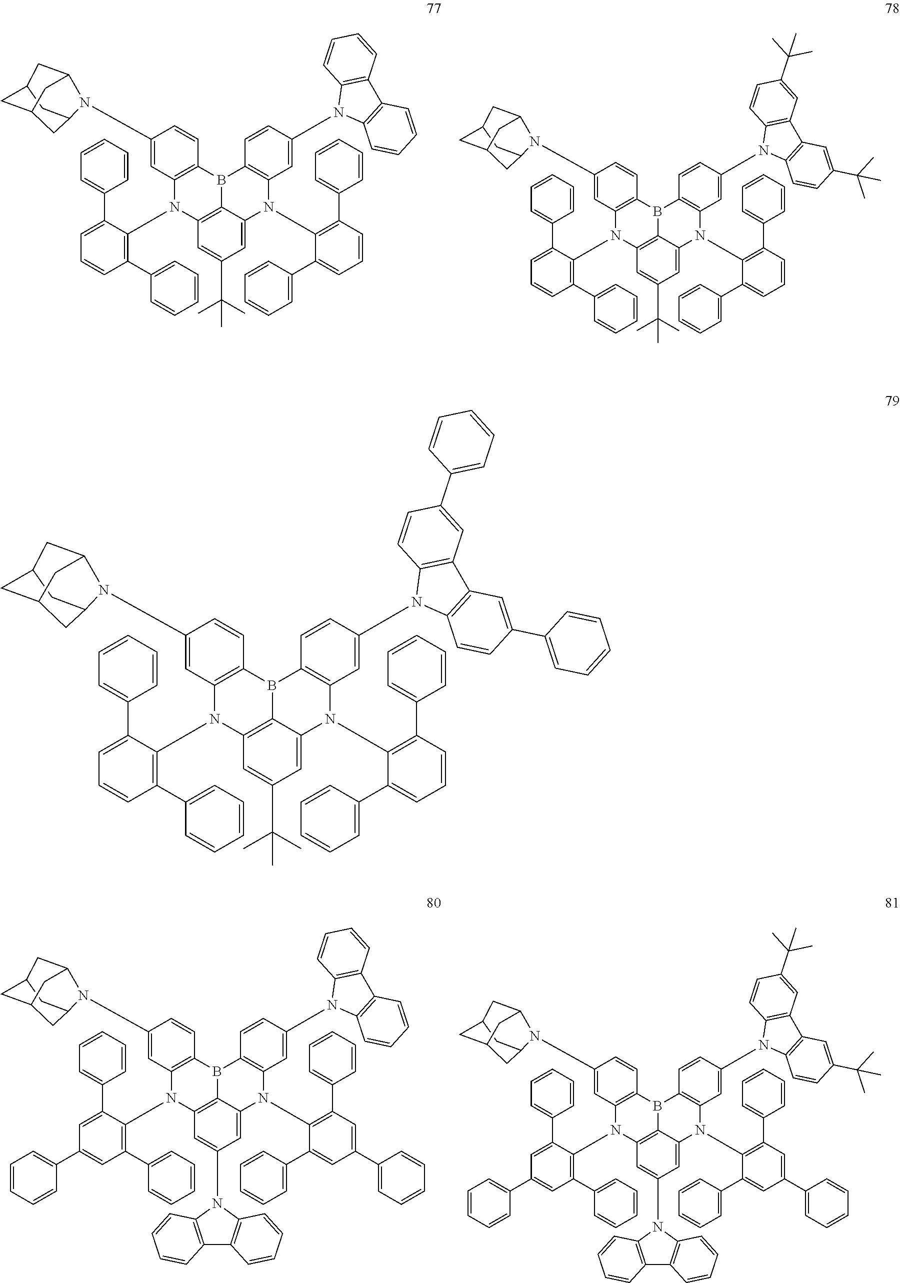

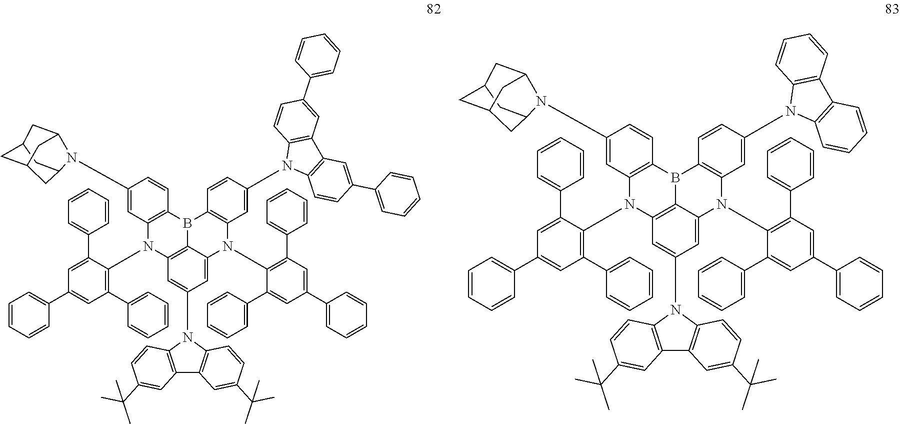 [SMILES: CC(C)(C)c1ccc2c(c1)c1cc(C(C)(C)C)ccc1n2-c1cc2c3c(c1)N(c1c(-c4ccccc4)cc(-c4ccccc4)cc1-c1ccccc1)c1cc(-n4c5ccc(-c6ccccc6)cc5c5cc(-c6ccccc6)ccc54)ccc1B3c1ccc(N3C4CC5CC(C4)CC3C5)cc1N2c1c(-c2ccccc2)cc(-c2ccccc2)cc1-c1ccccc1 ; CC(C)(C)c1ccc2c(c1)c1cc(C(C)(C)C)ccc1n2-c1cc2c3c(c1)N(c1c(-c4ccccc4)cc(-c4ccccc4)cc1-c1ccccc1)c1cc(-n4c5ccccc5c5ccccc54)ccc1B3c1ccc(N3C4CC5CC(C4)CC3C5)cc1N2c1c(-c2ccccc2)cc(-c2ccccc2)cc1-c1ccccc1]

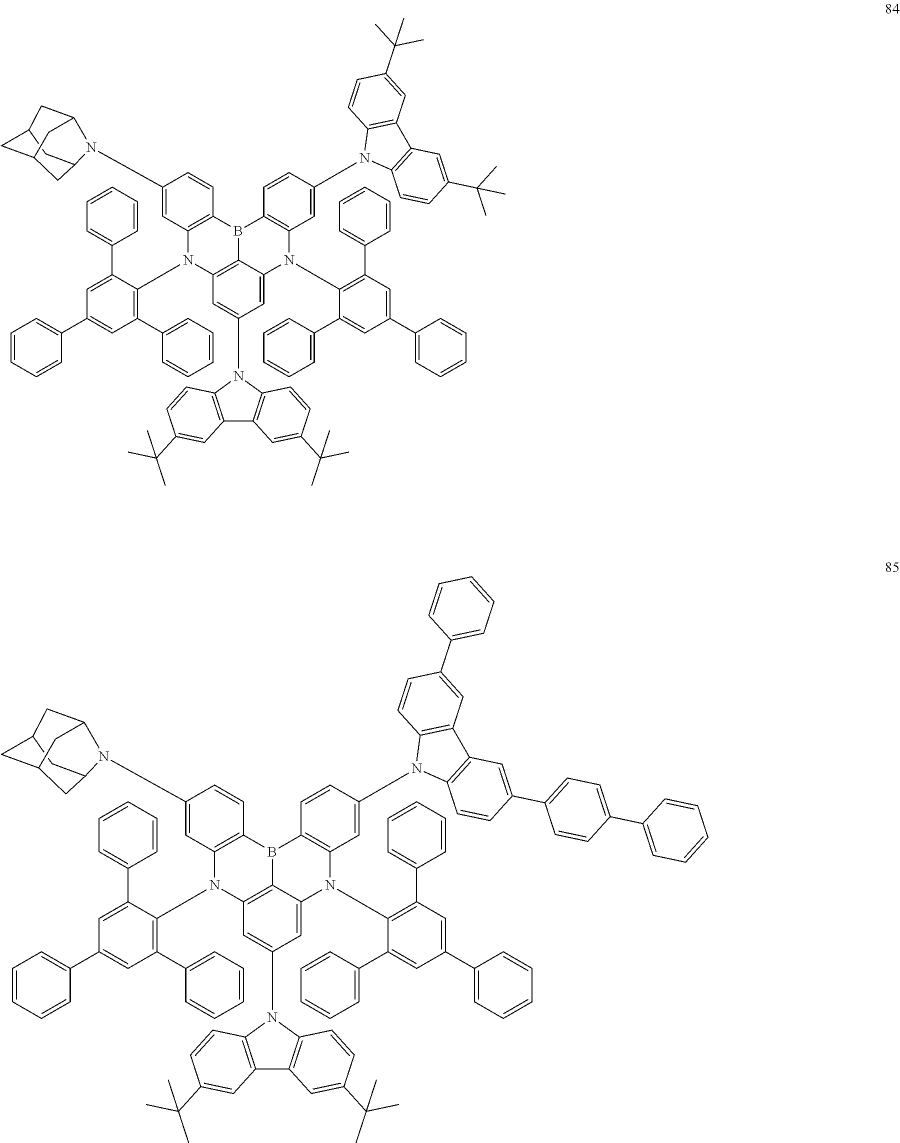 [SMILES: CC(C)(C)c1ccc2c(c1)c1cc(C(C)(C)C)ccc1n2-c1ccc2c(c1)N(c1c(-c3ccccc3)cc(-c3ccccc3)cc1-c1ccccc1)c1cc(-n3c4ccc(C(C)(C)C)cc4c4cc(C(C)(C)C)ccc43)cc3c1B2c1ccc(N2C4CC5CC(C4)CC2C5)cc1N3c1c(-c2ccccc2)cc(-c2ccccc2)cc1-c1ccccc1 ; CC(C)(C)c1ccc2c(c1)c1cc(C(C)(C)C)ccc1n2-c1cc2c3c(c1)N(c1c(-c4ccccc4)cc(-c4ccccc4)cc1-c1ccccc1)c1cc(-n4c5ccc(-c6ccccc6)cc5c5cc(-c6ccc(-c7ccccc7)cc6)ccc54)ccc1B3c1ccc(N3C4CC5CC(C4)CC3C5)cc1N2c1c(-c2ccccc2)cc(-c2ccccc2)cc1-c1ccccc1]

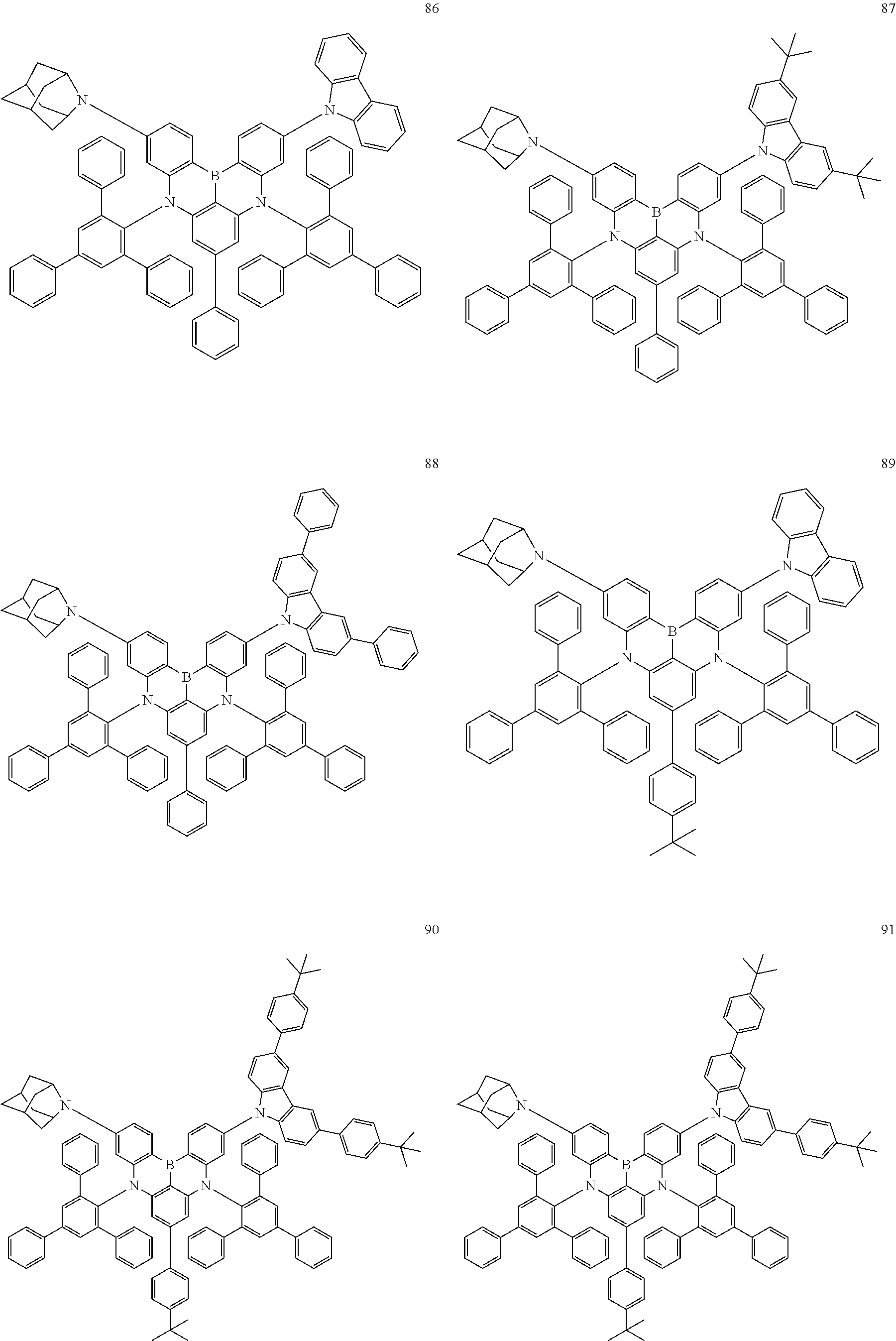

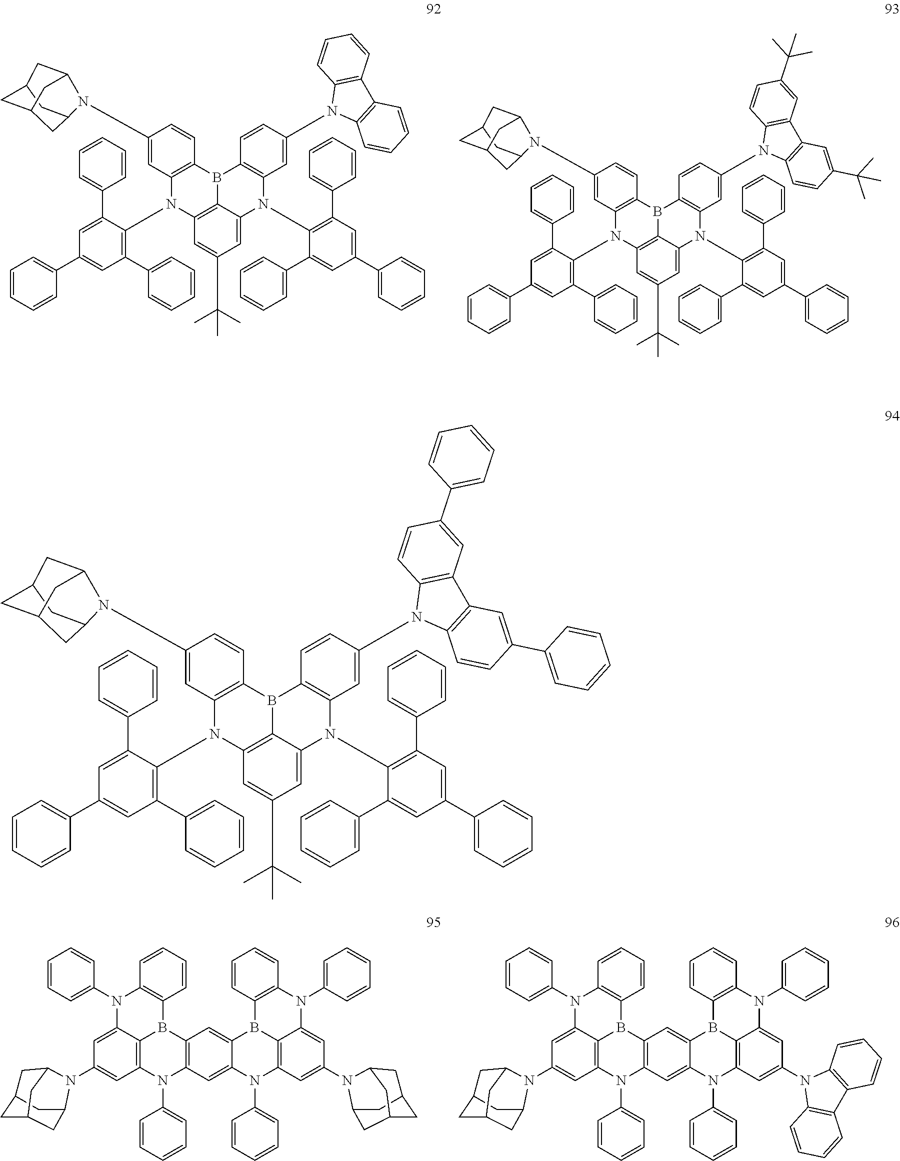

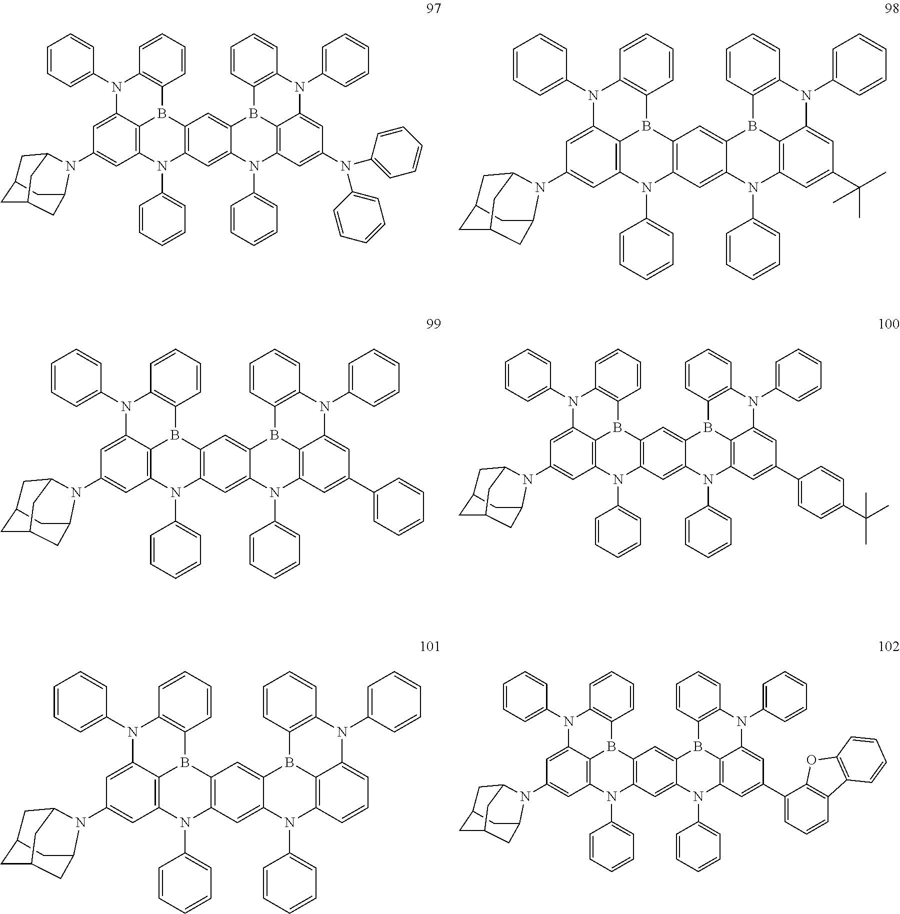

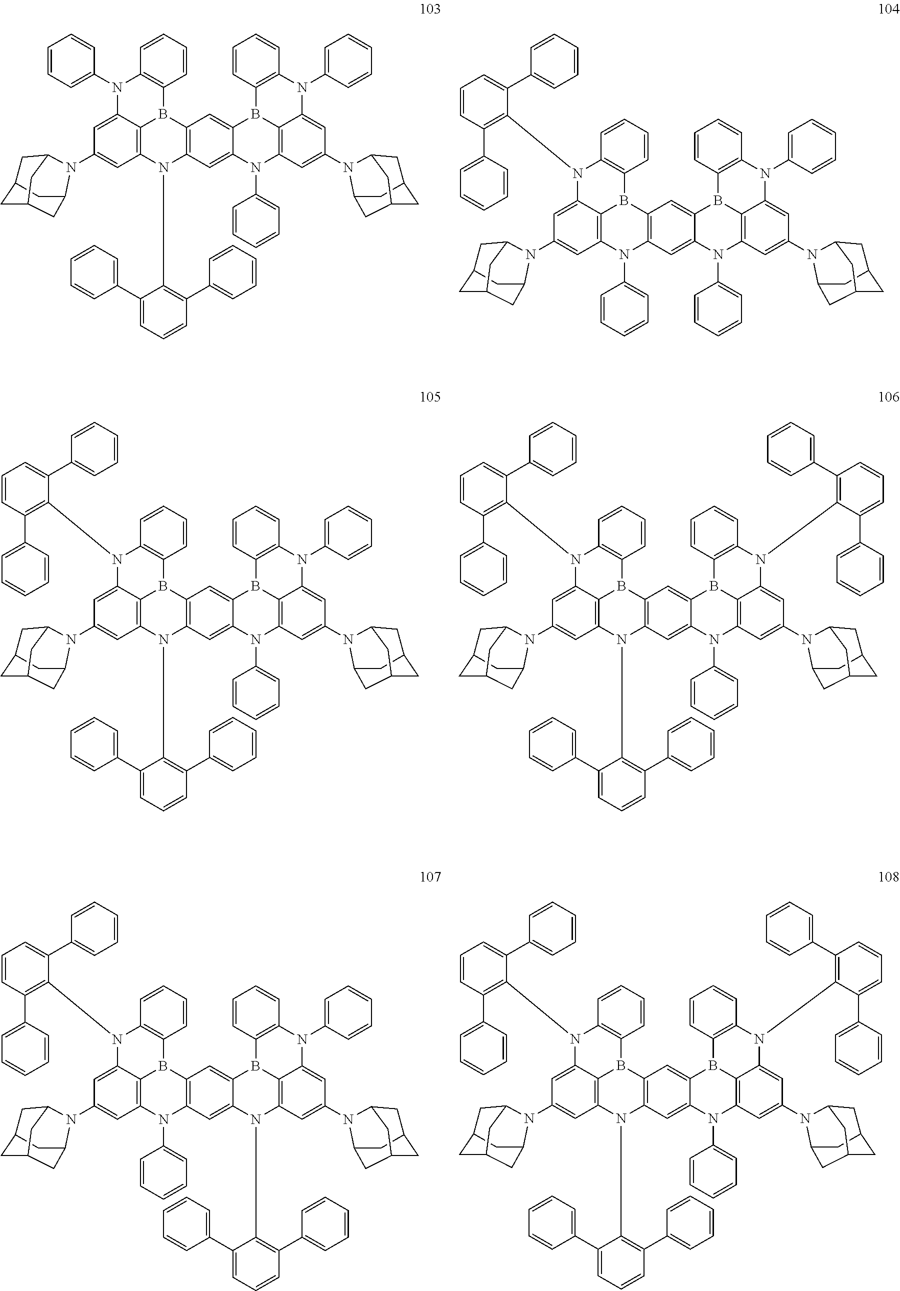

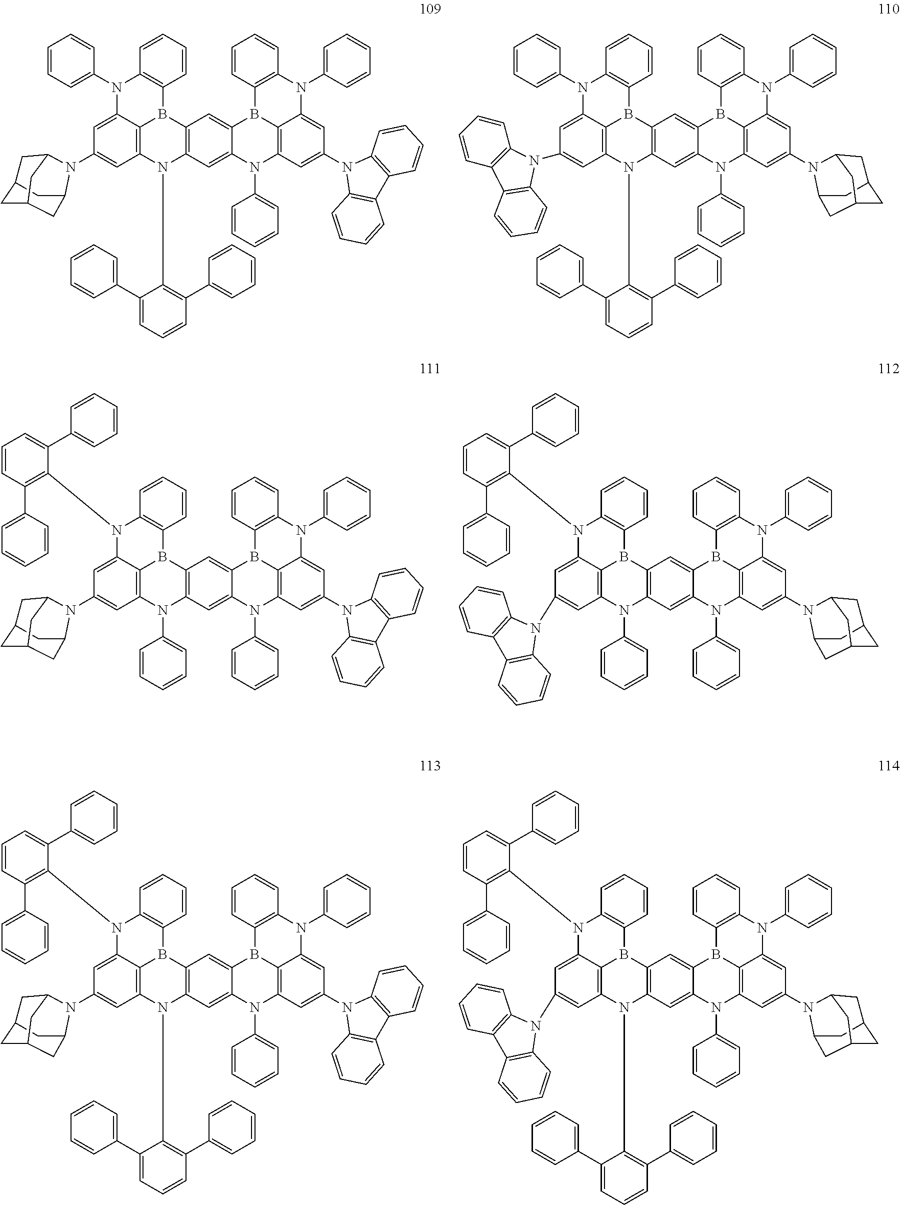

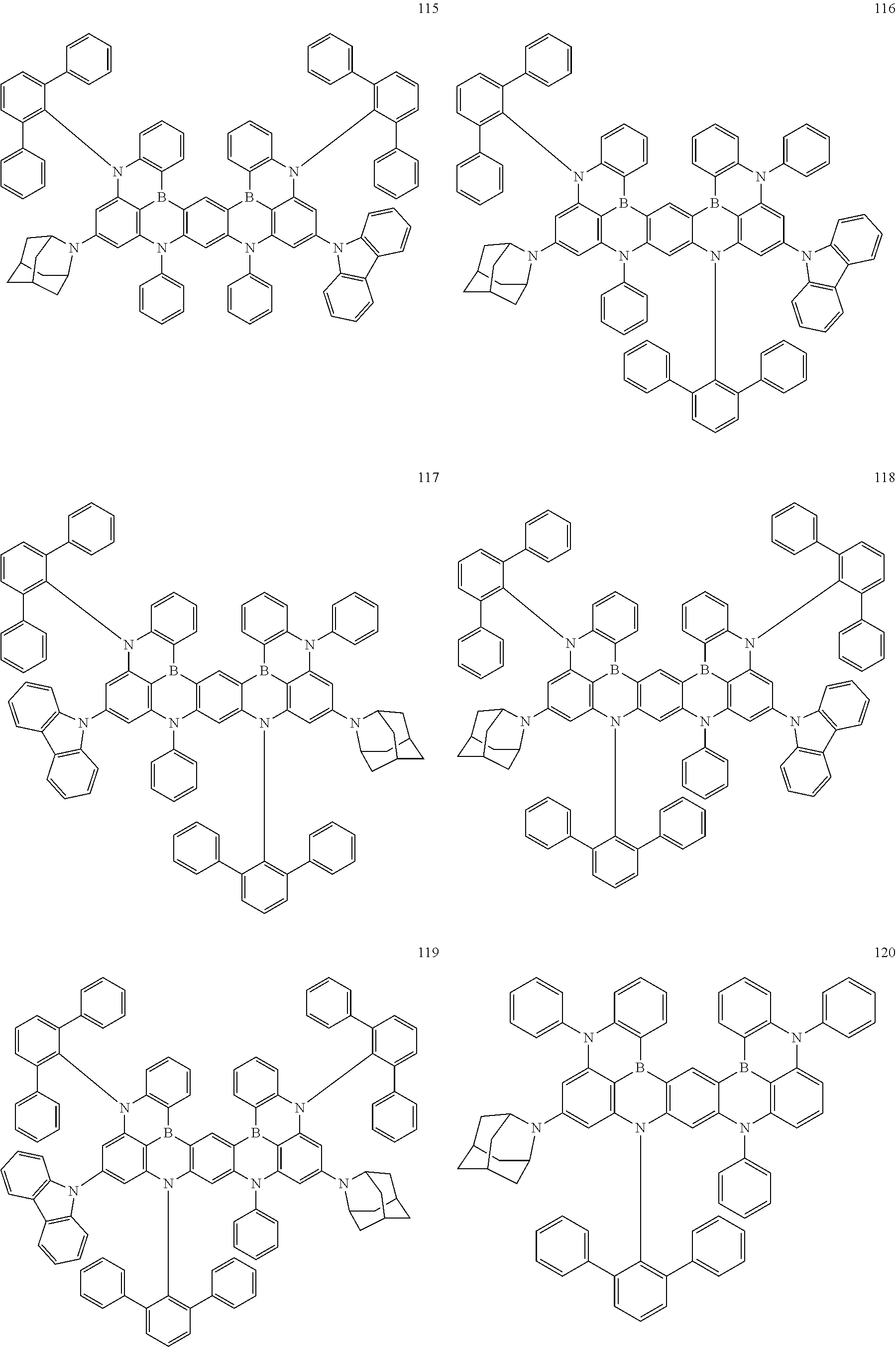

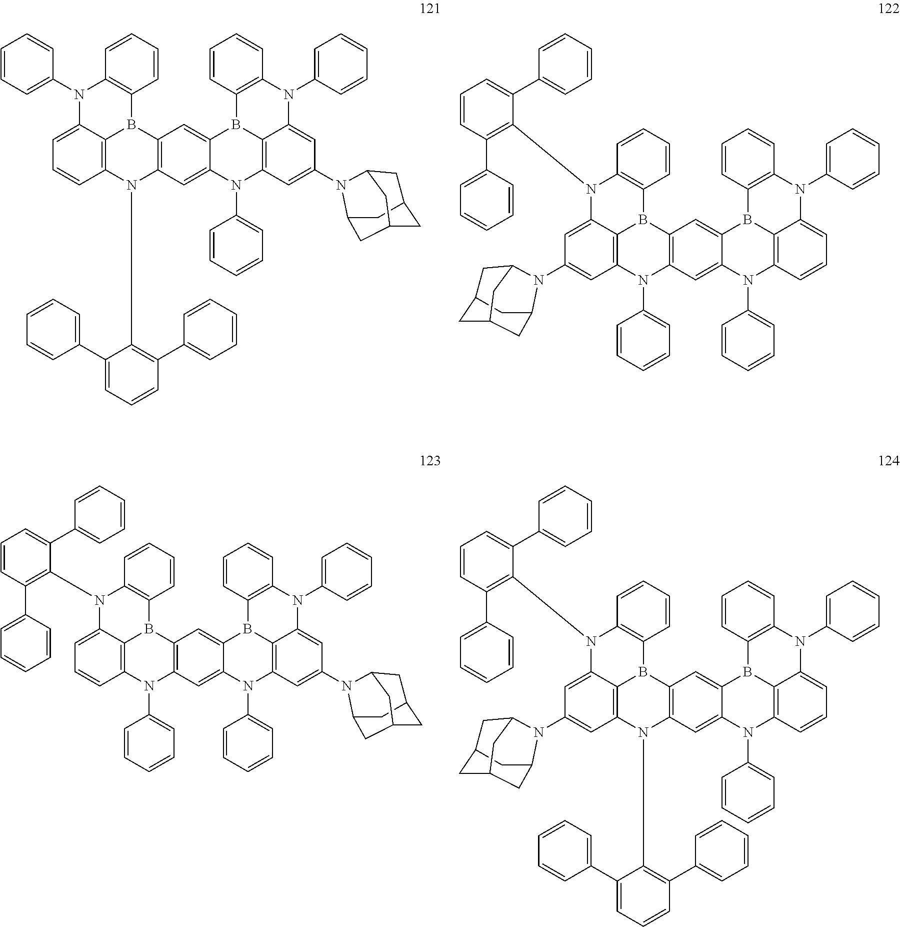

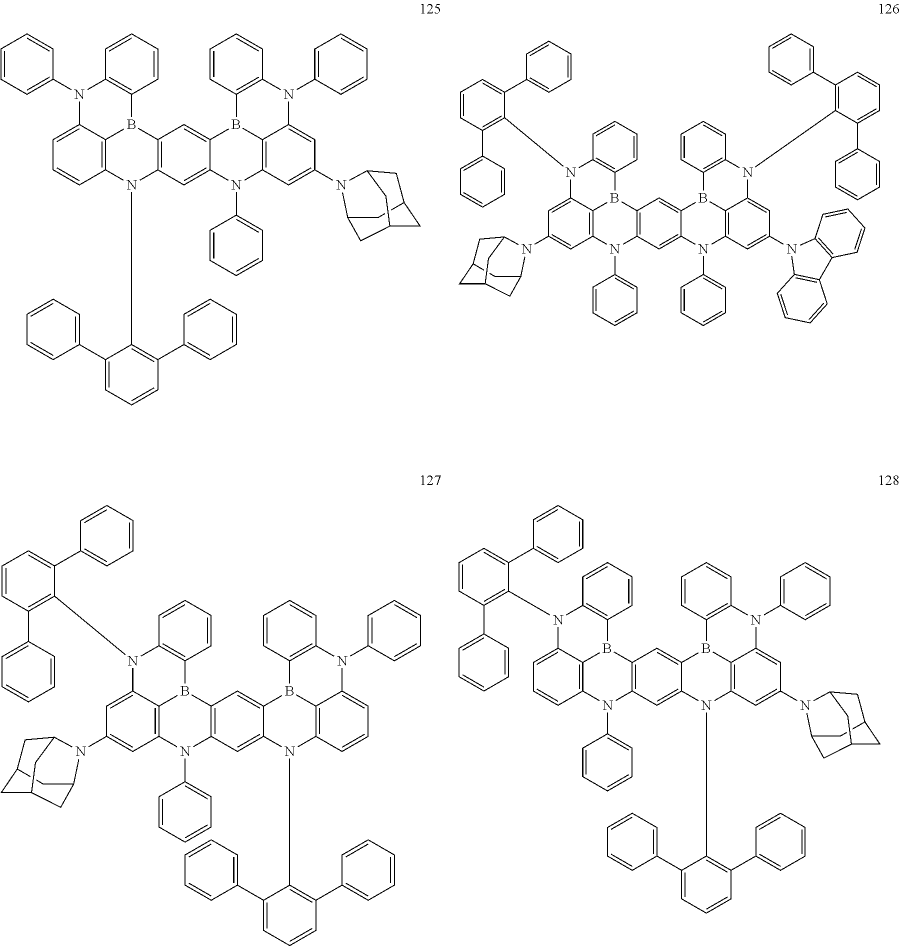

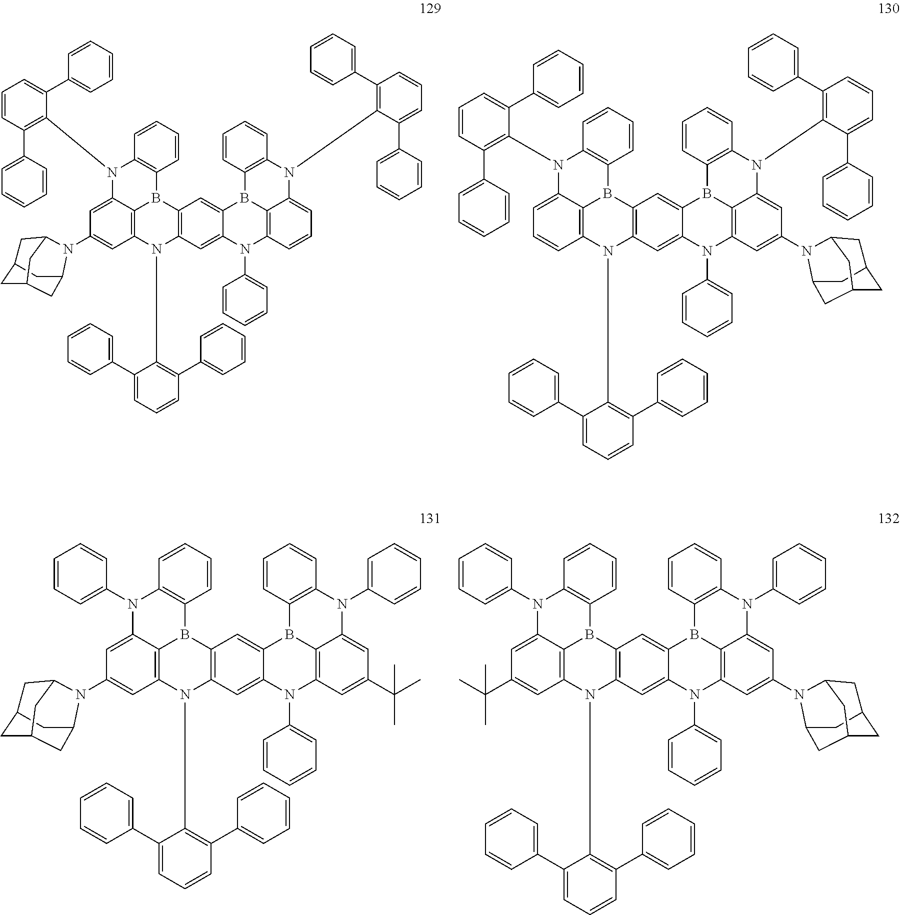

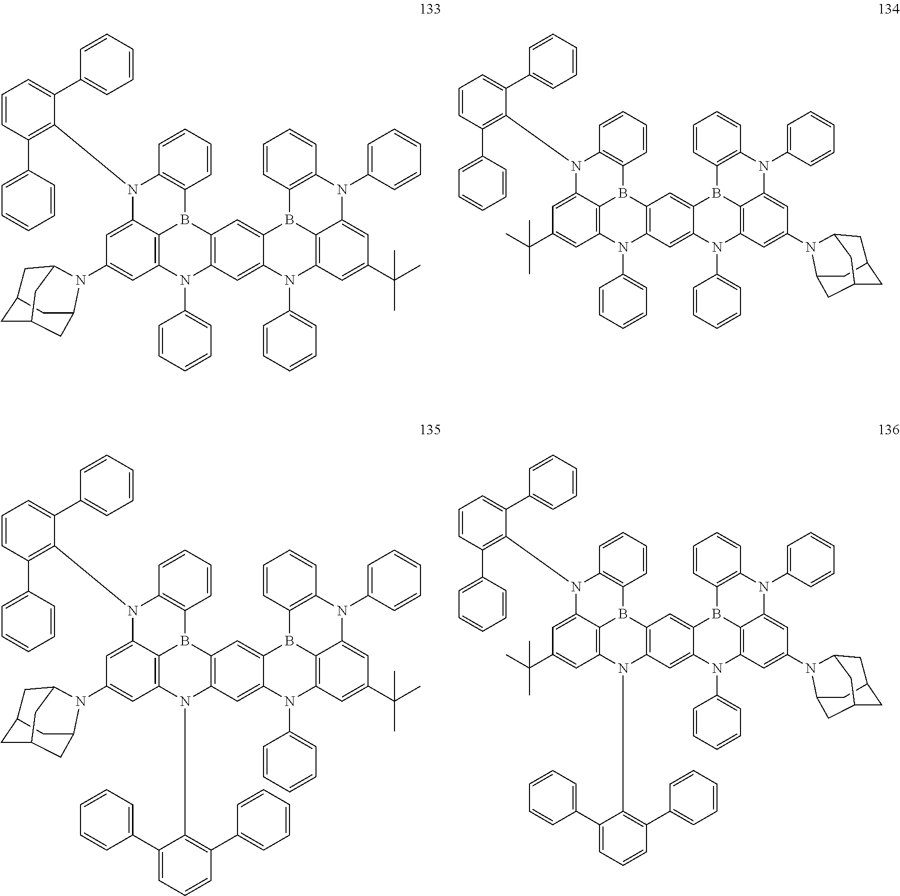

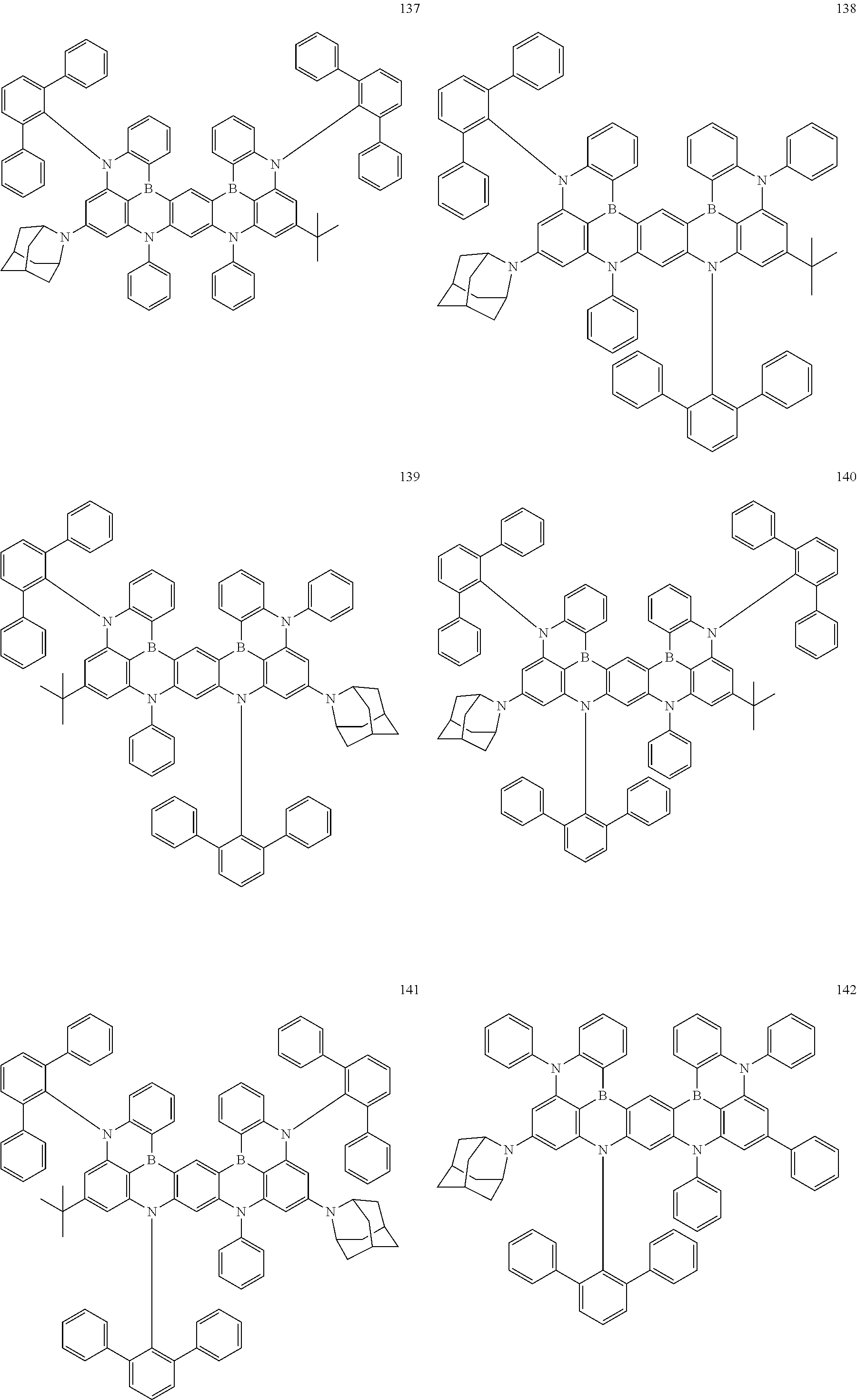

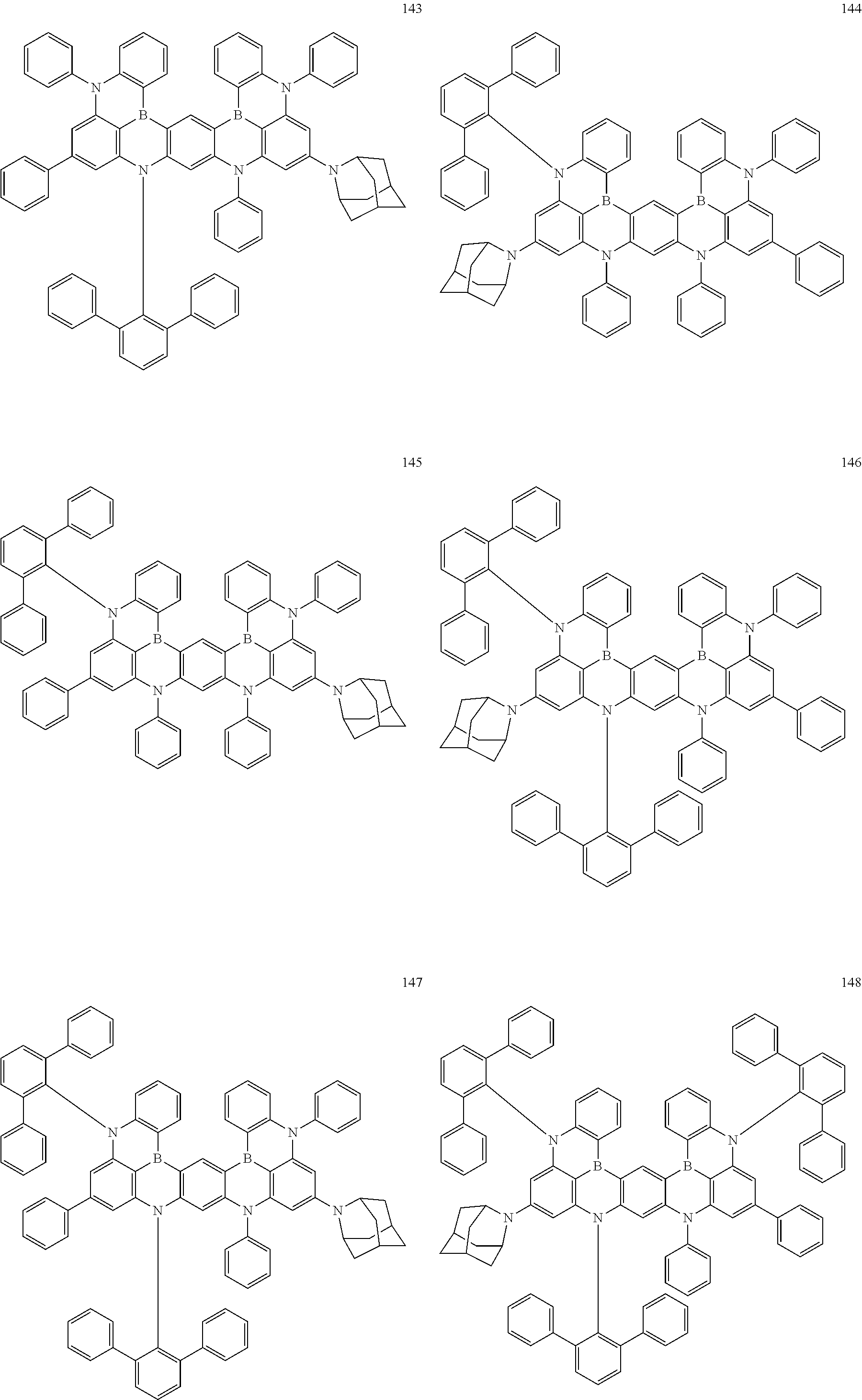

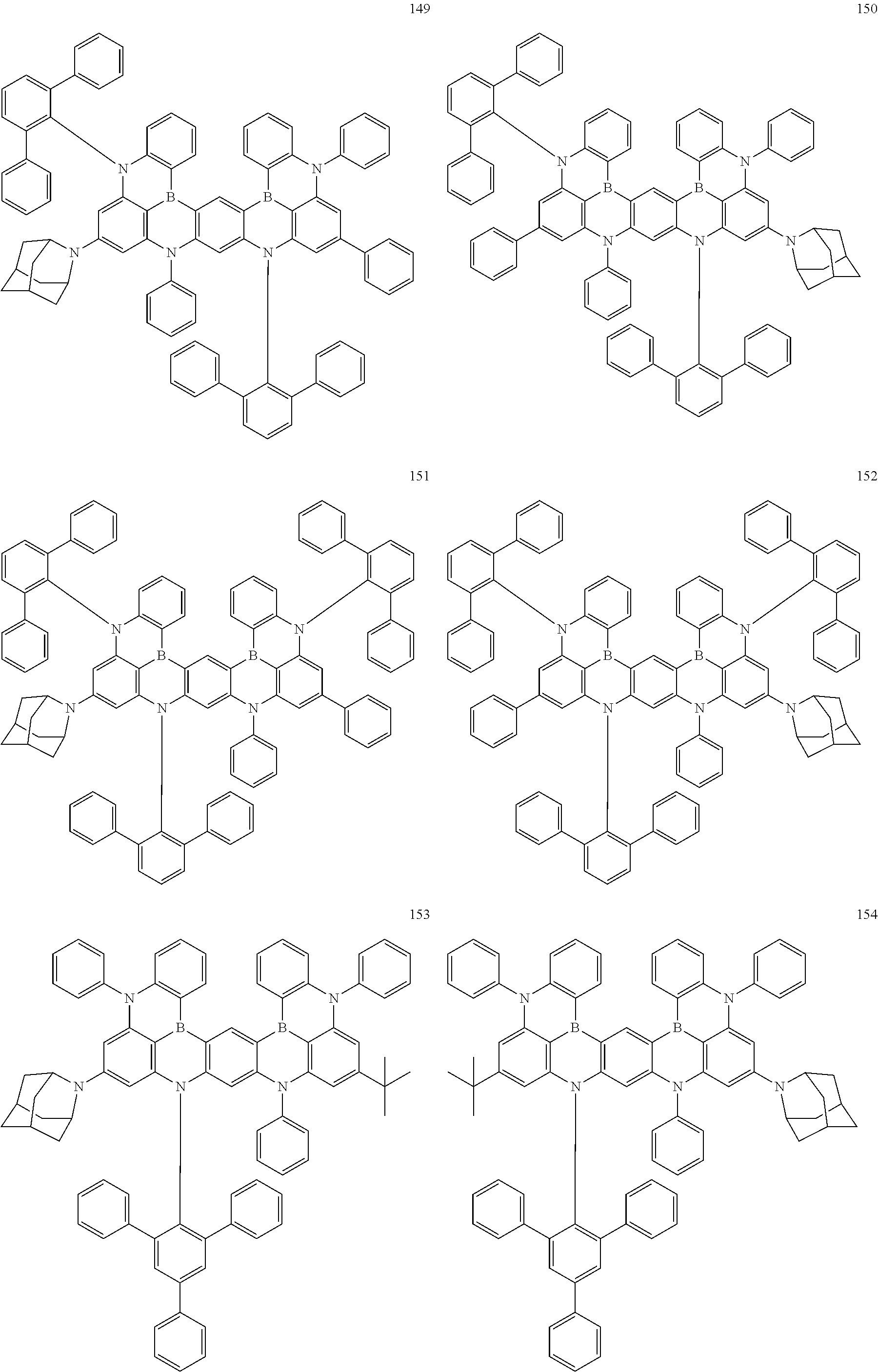

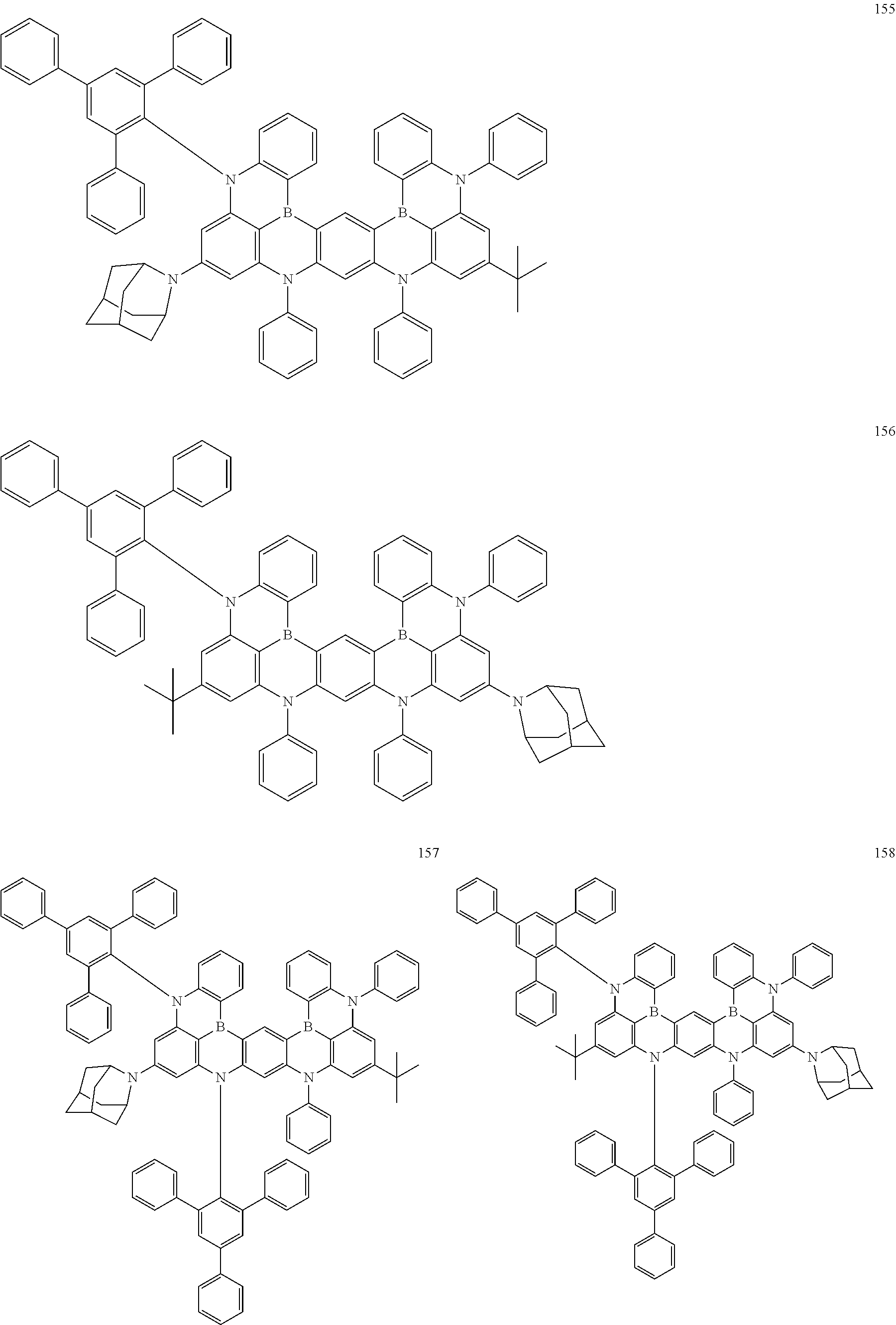

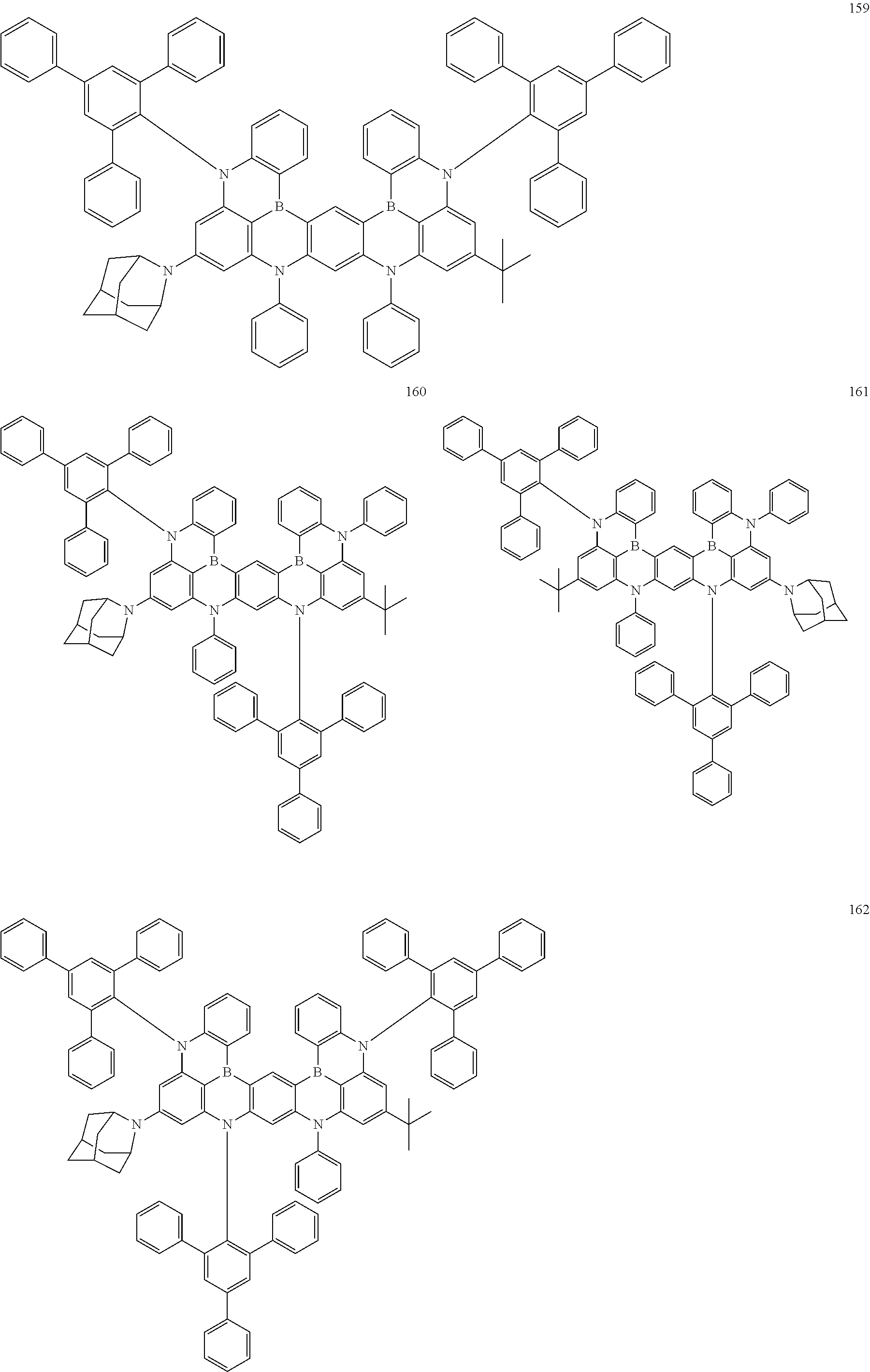

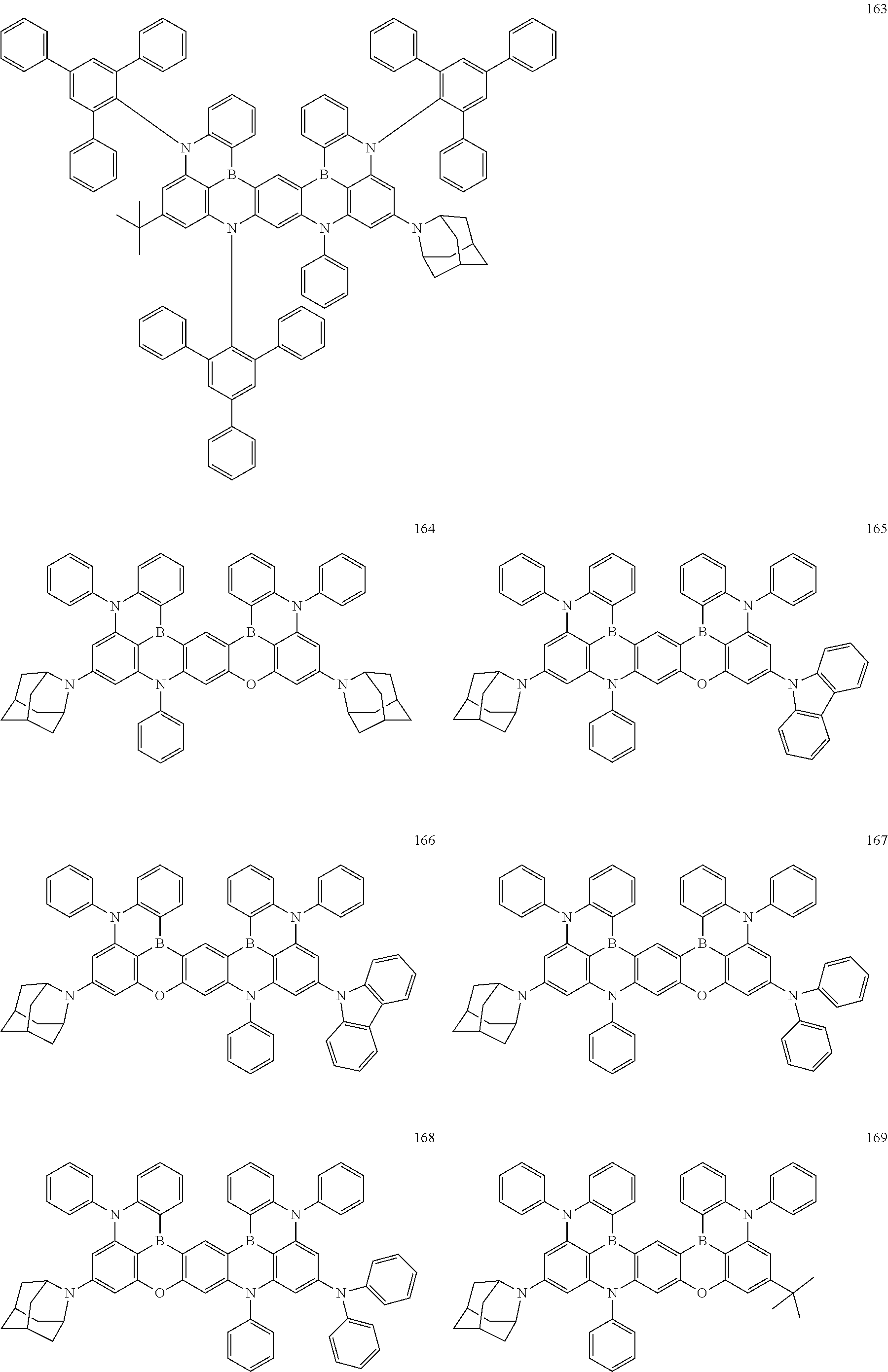

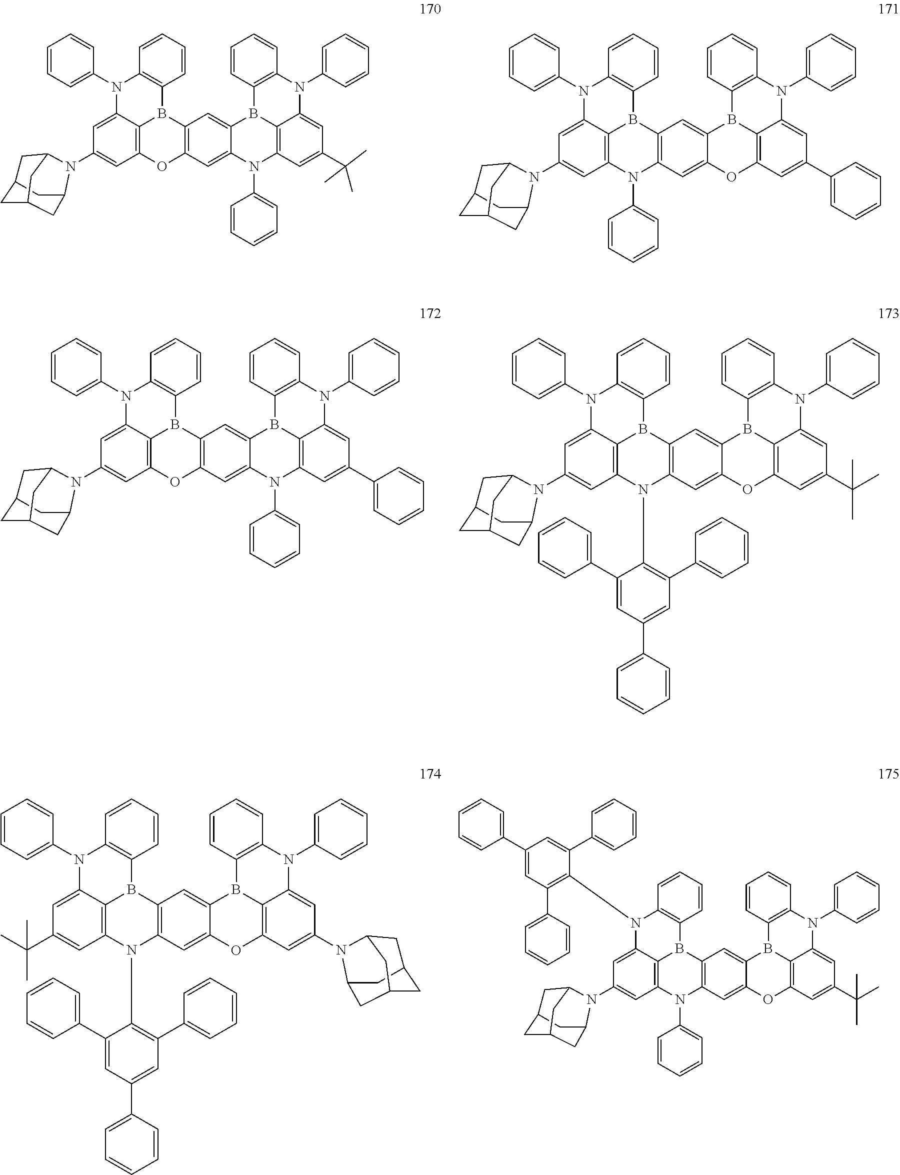

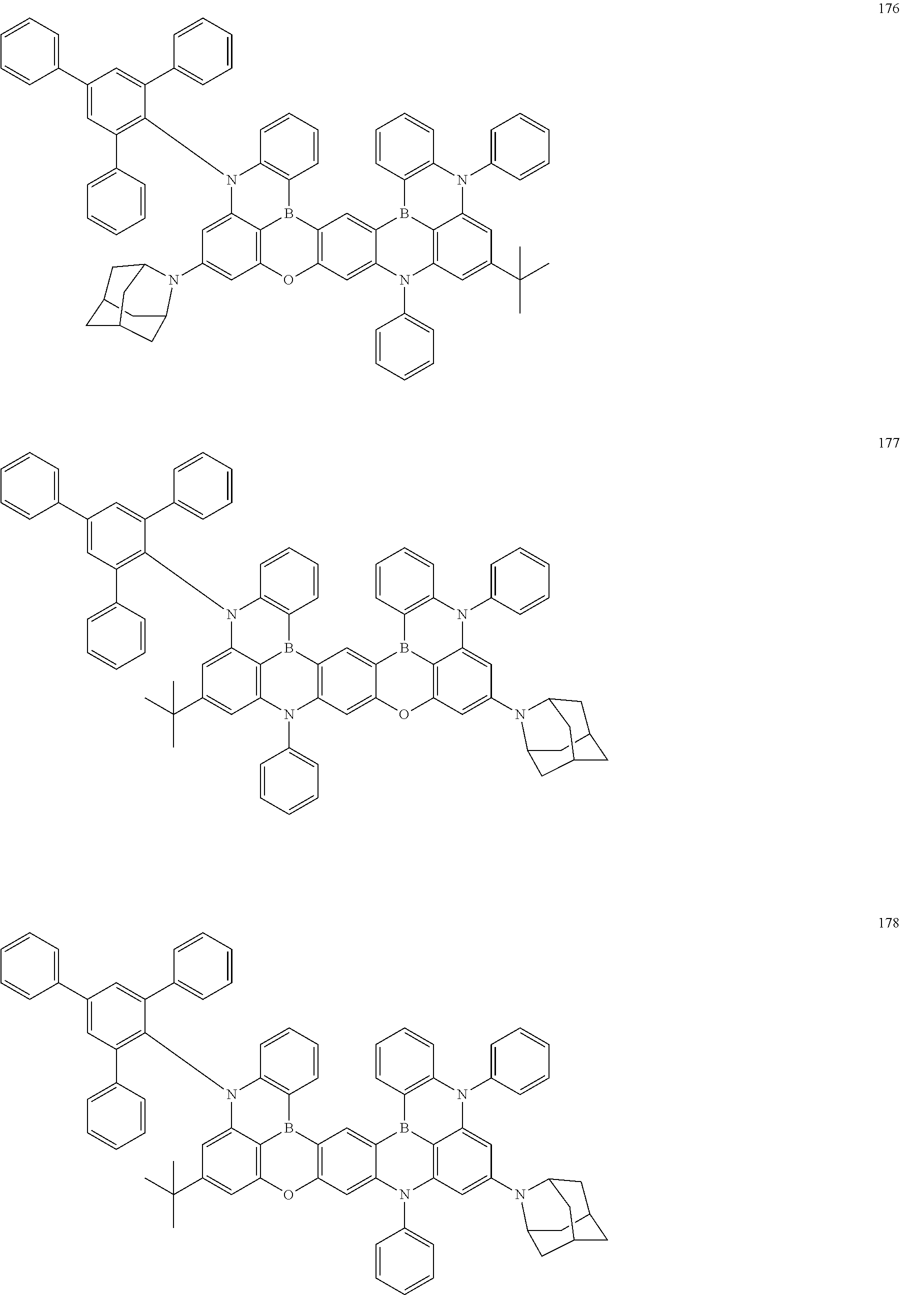 [SMILES: CC(C)(C)c1cc2c3c(c1)N(c1ccccc1)c1cc4c(cc1B3c1ccccc1N2c1ccccc1)B1c2ccccc2N(c2c(-c3ccccc3)cc(-c3ccccc3)cc2-c2ccccc2)c2cc(N3C5CC6CC(C5)CC3C6)cc(c21)O4 ; CC(C)(C)c1cc2c3c(c1)N(c1c(-c4ccccc4)cc(-c4ccccc4)cc1-c1ccccc1)c1ccccc1B3c1cc3c(cc1N2c1ccccc1)Oc1cc(N2C4CC5CC(C4)CC2C5)cc2c1B3c1ccccc1N2c1ccccc1 ; CC(C)(C)c1cc2c3c(c1)N(c1c(-c4ccccc4)cc(-c4ccccc4)cc1-c1ccccc1)c1ccccc1B3c1cc3c(cc1O2)N(c1ccccc1)c1cc(N2C4CC5CC(C4)CC2C5)cc2c1B3c1ccccc1N2c1ccccc1]

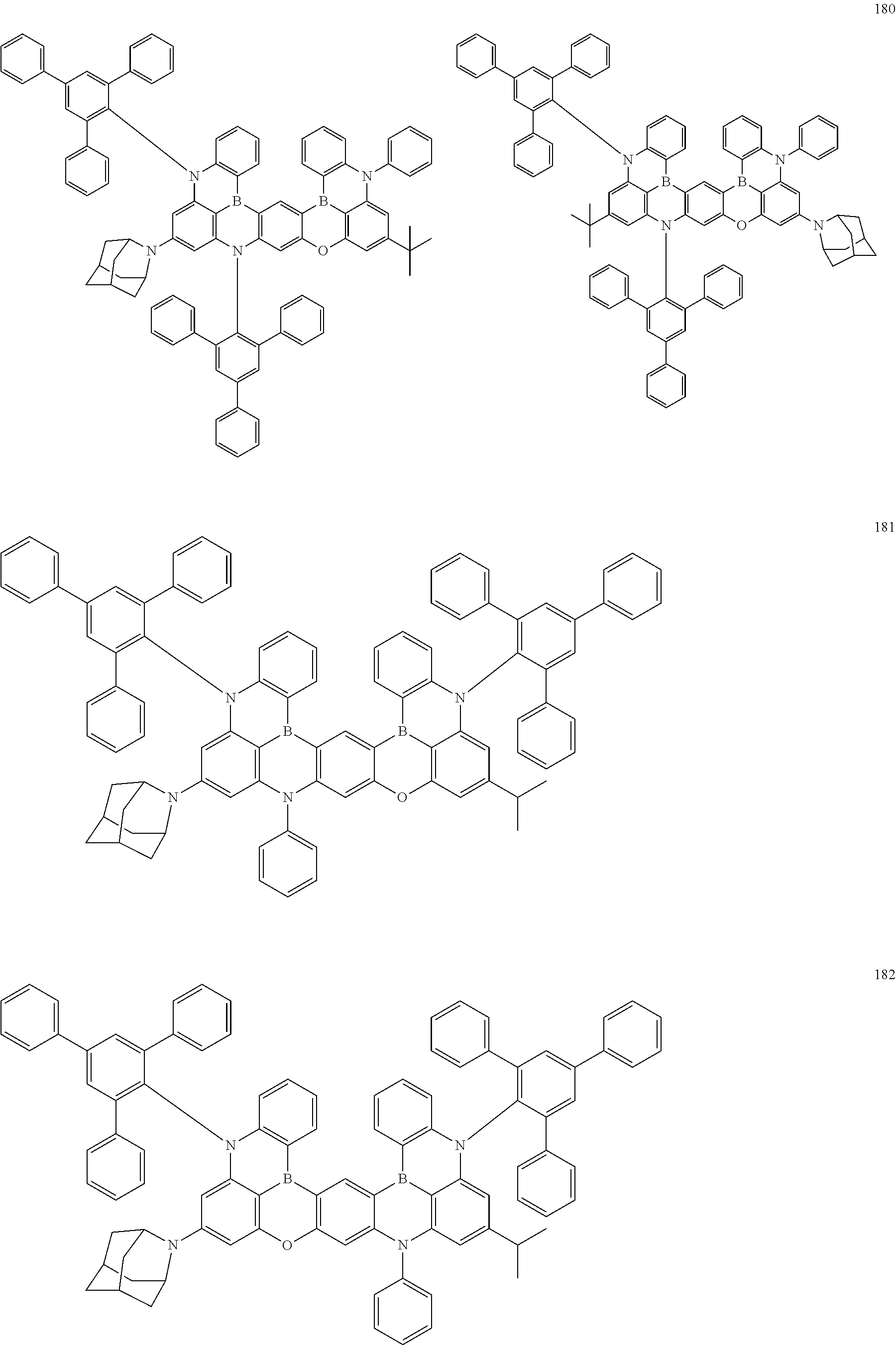

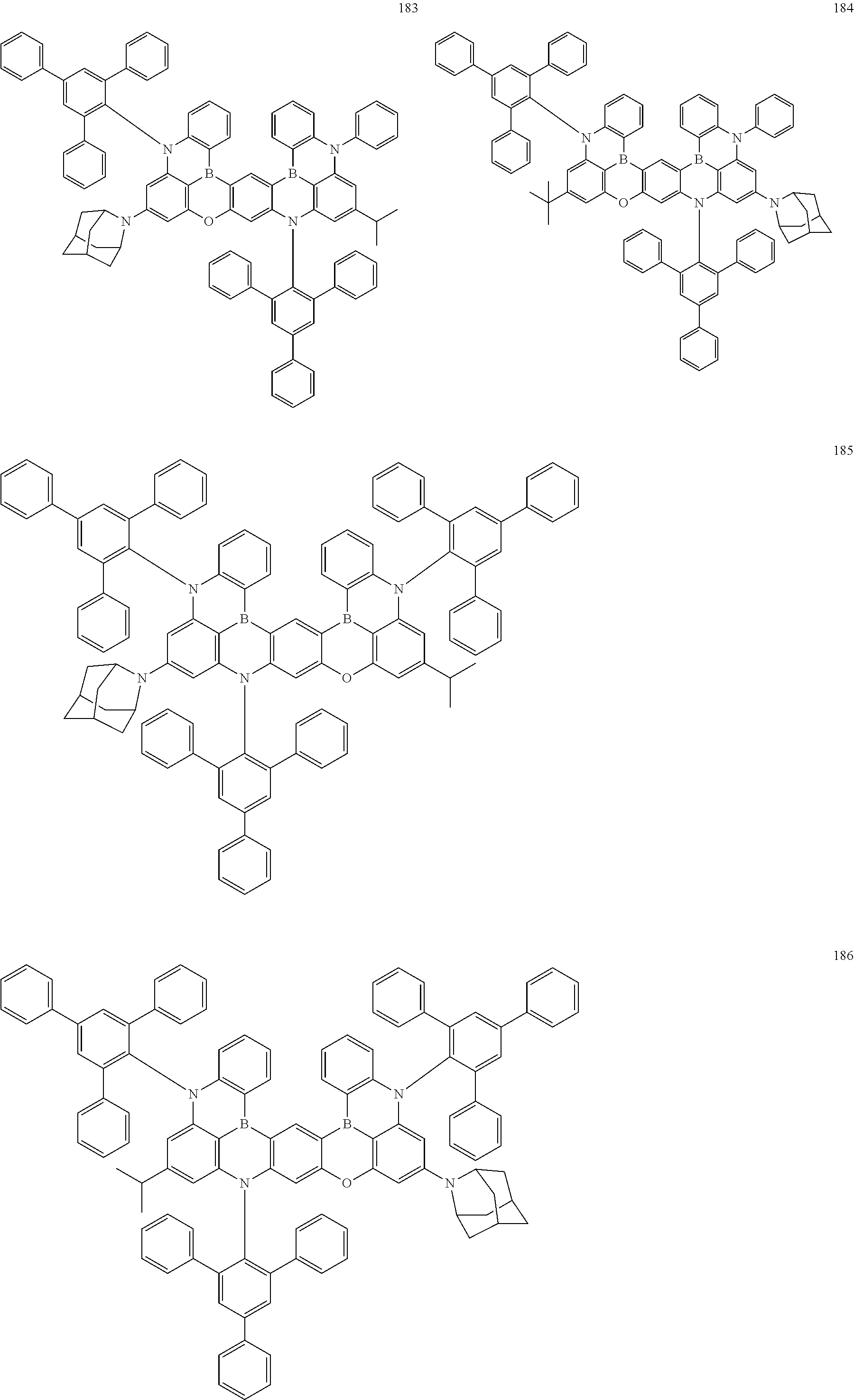

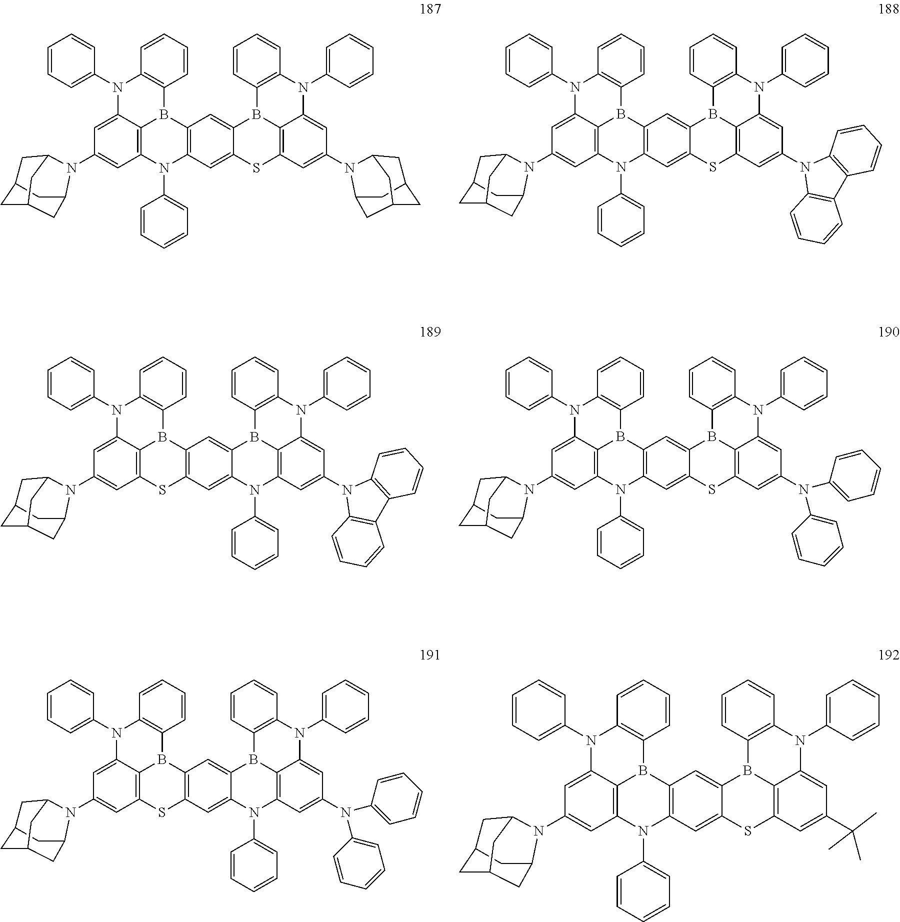

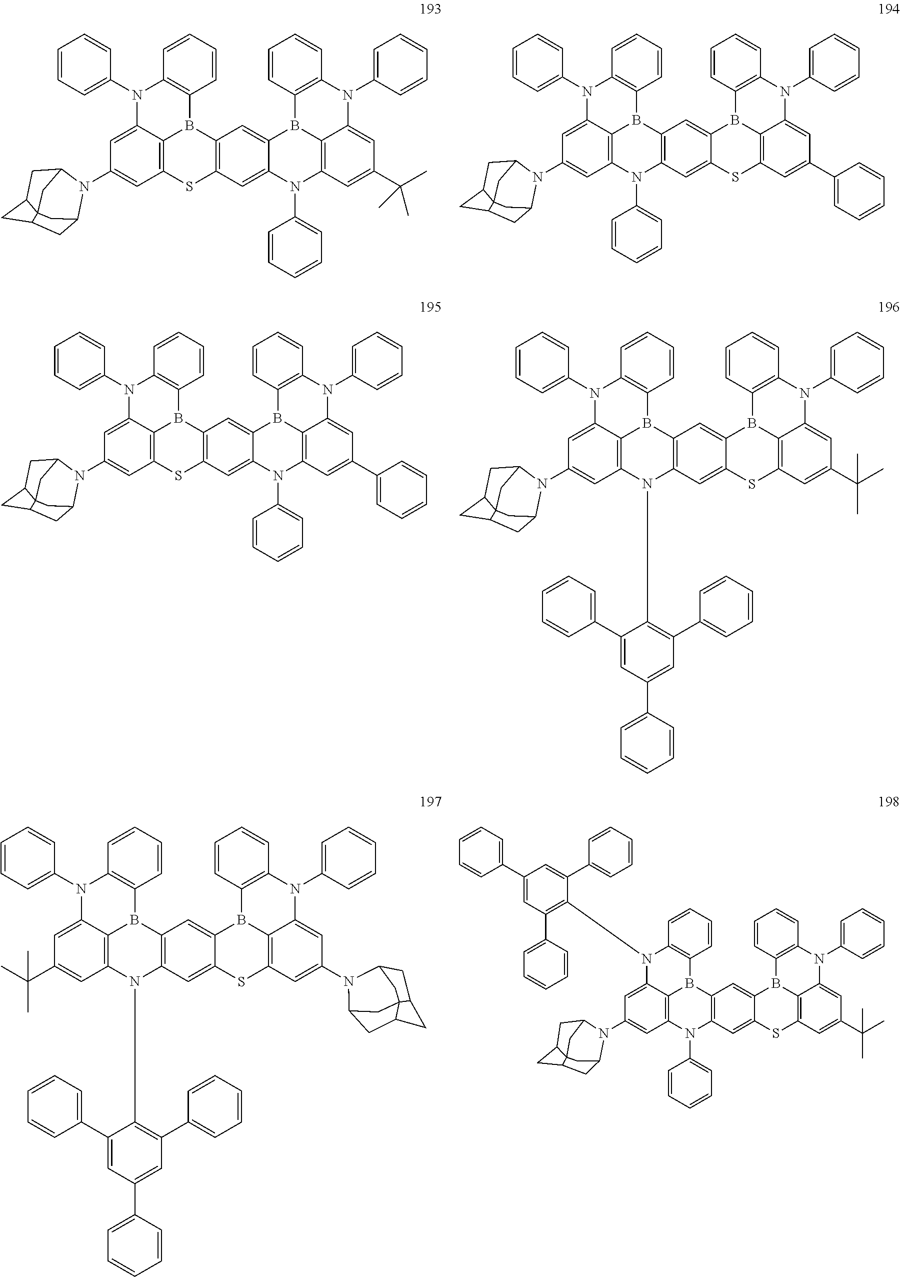

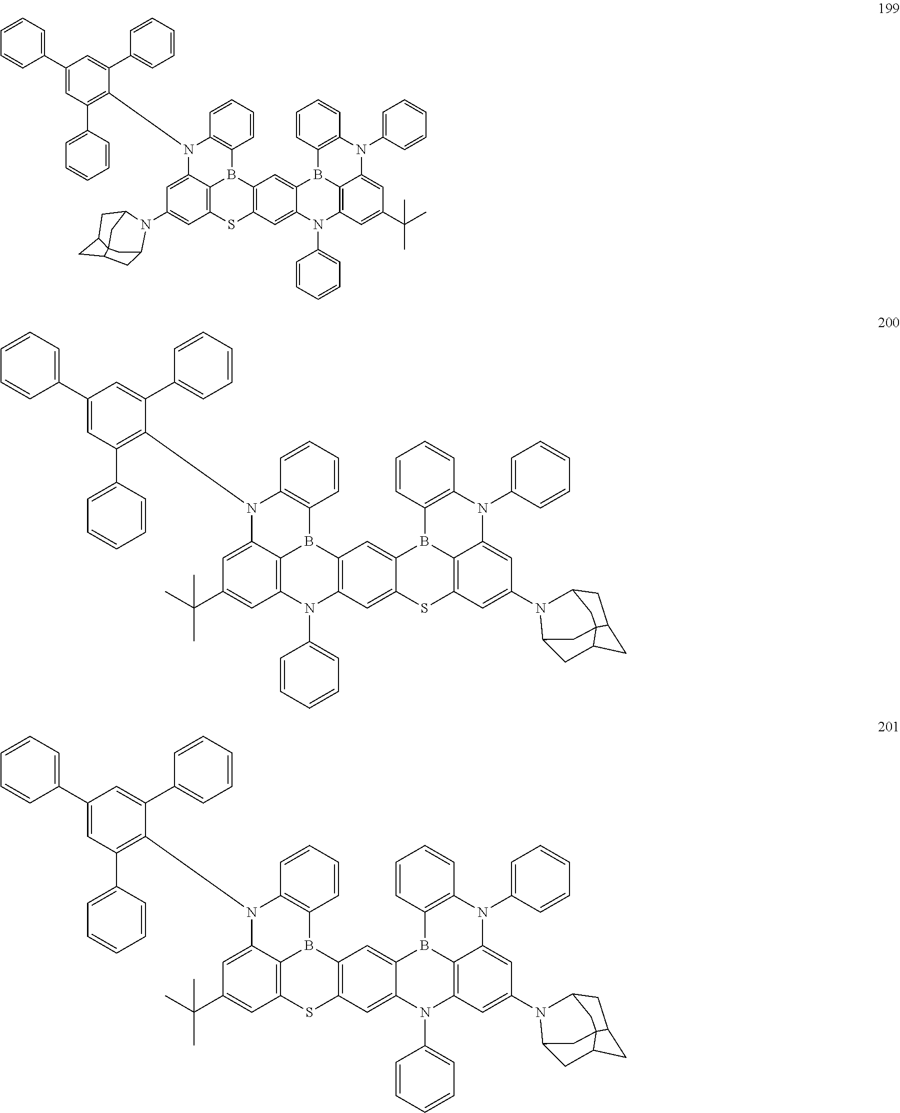 [SMILES: CC(C)(C)c1cc2c3c(c1)N(c1ccccc1)c1cc4c(cc1B3c1ccccc1N2c1ccccc1)B1c2ccccc2N(c2c(-c3ccccc3)cc(-c3ccccc3)cc2-c2ccccc2)c2cc(N3C5CC6CC7CC3CC67C5)cc(c21)S4 ; CC(C)(C)c1cc2c3c(c1)N(c1c(-c4ccccc4)cc(-c4ccccc4)cc1-c1ccccc1)c1ccccc1B3c1cc3c(cc1N2c1ccccc1)Sc1cc(N2C4CC5CC6CC2CC56C4)cc2c1B3c1ccccc1N2c1ccccc1 ; CC(C)(C)c1cc2c3c(c1)N(c1c(-c4ccccc4)cc(-c4ccccc4)cc1-c1ccccc1)c1ccccc1B3c1cc3c(cc1S2)N(c1ccccc1)c1cc(N2C4CC5CC6CC2CC56C4)cc2c1B3c1ccccc1N2c1ccccc1]

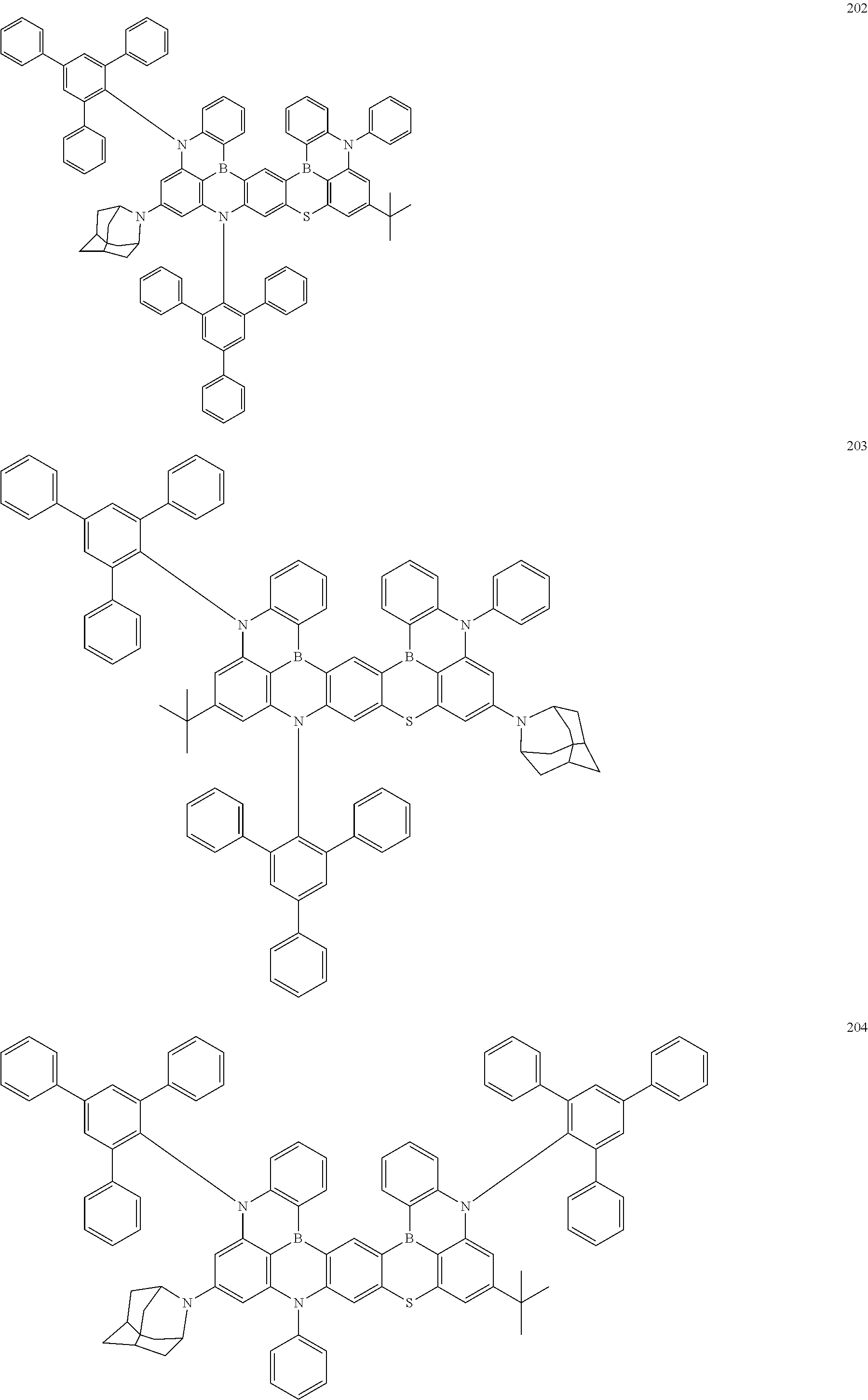

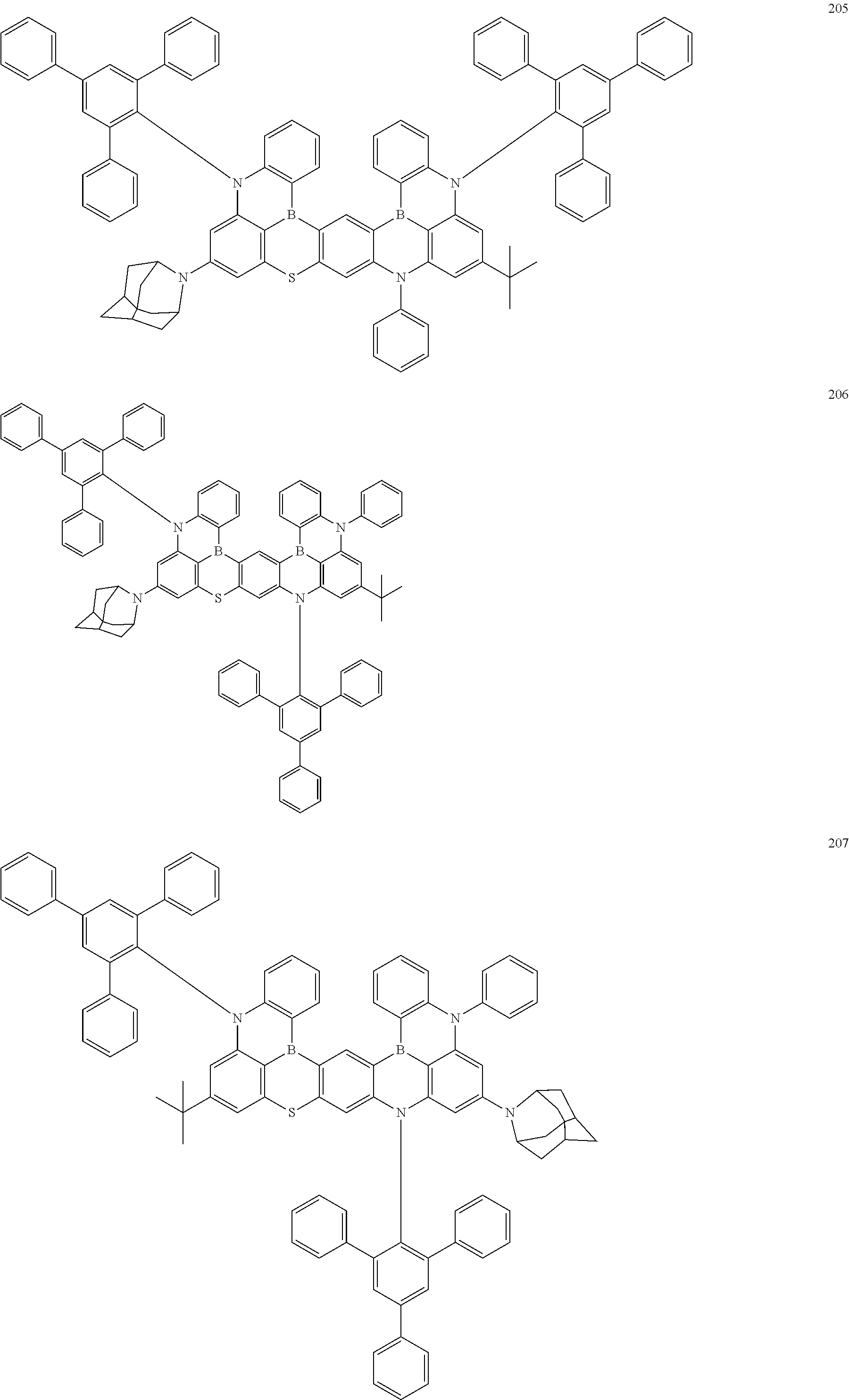

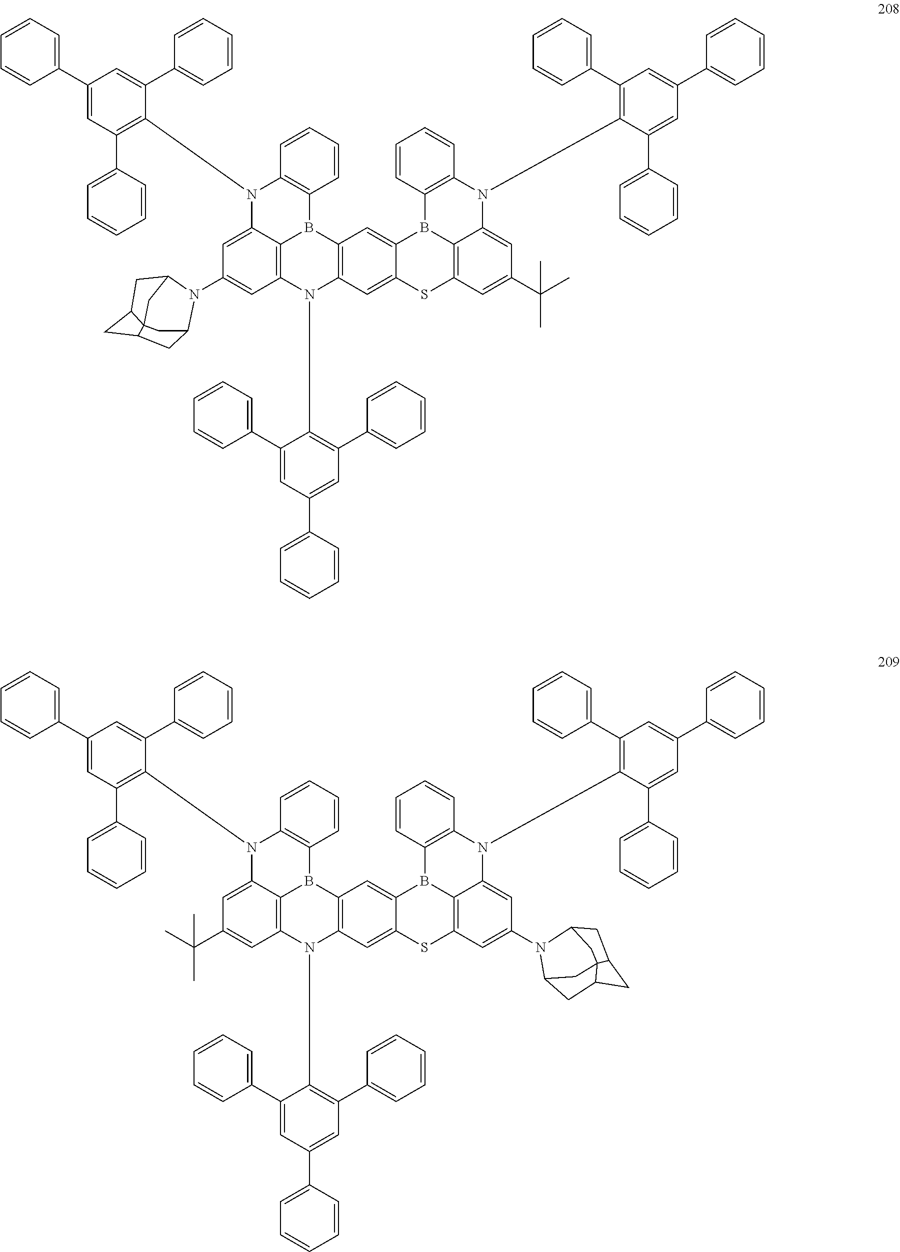 [SMILES: CC(C)(C)c1cc2c3c(c1)N(c1c(-c4ccccc4)cc(-c4ccccc4)cc1-c1ccccc1)c1ccccc1B3c1cc3c(cc1S2)N(c1c(-c2ccccc2)cc(-c2ccccc2)cc1-c1ccccc1)c1cc(N2C4CC5CC6CC2CC56C4)cc2c1B3c1ccccc1N2c1c(-c2ccccc2)cc(-c2ccccc2)cc1-c1ccccc1 ; CC(C)(C)c1cc2c3c(c1)N(c1c(-c4ccccc4)cc(-c4ccccc4)cc1-c1ccccc1)c1cc4c(cc1B3c1ccccc1N2c1c(-c2ccccc2)cc(-c2ccccc2)cc1-c1ccccc1)B1c2ccccc2N(c2c(-c3ccccc3)cc(-c3ccccc3)cc2-c2ccccc2)c2cc(N3C5CC6CC7CC3CC67C5)cc(c21)S4]

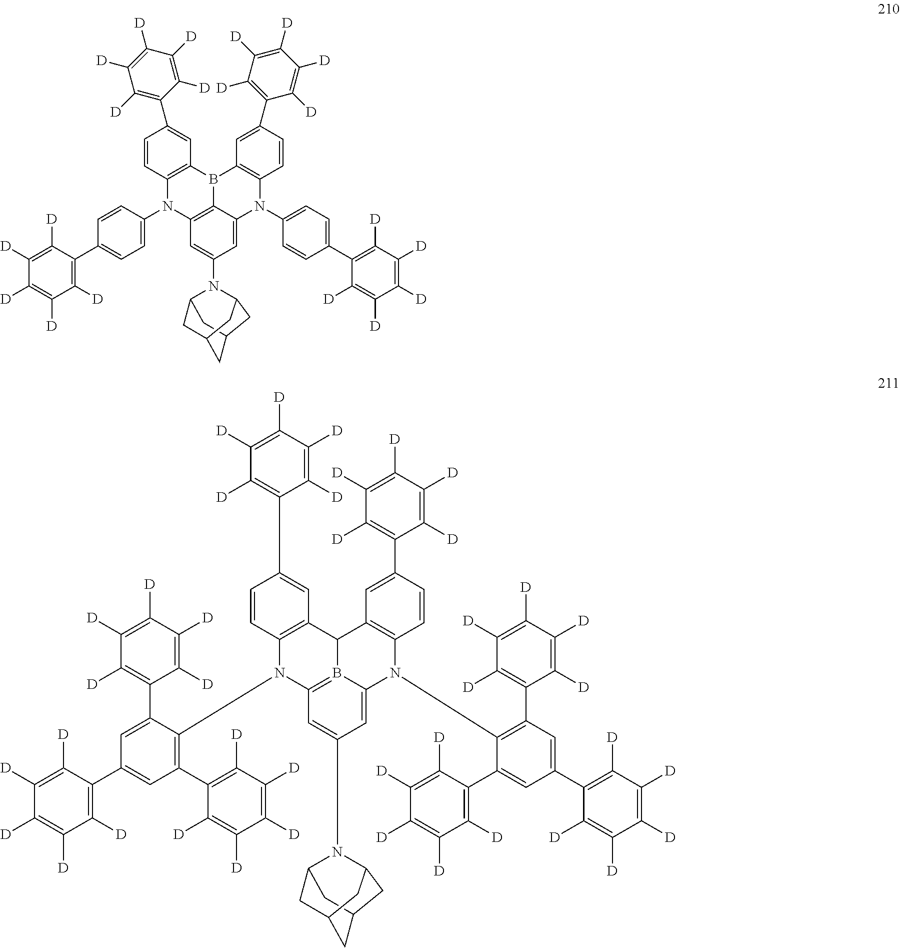

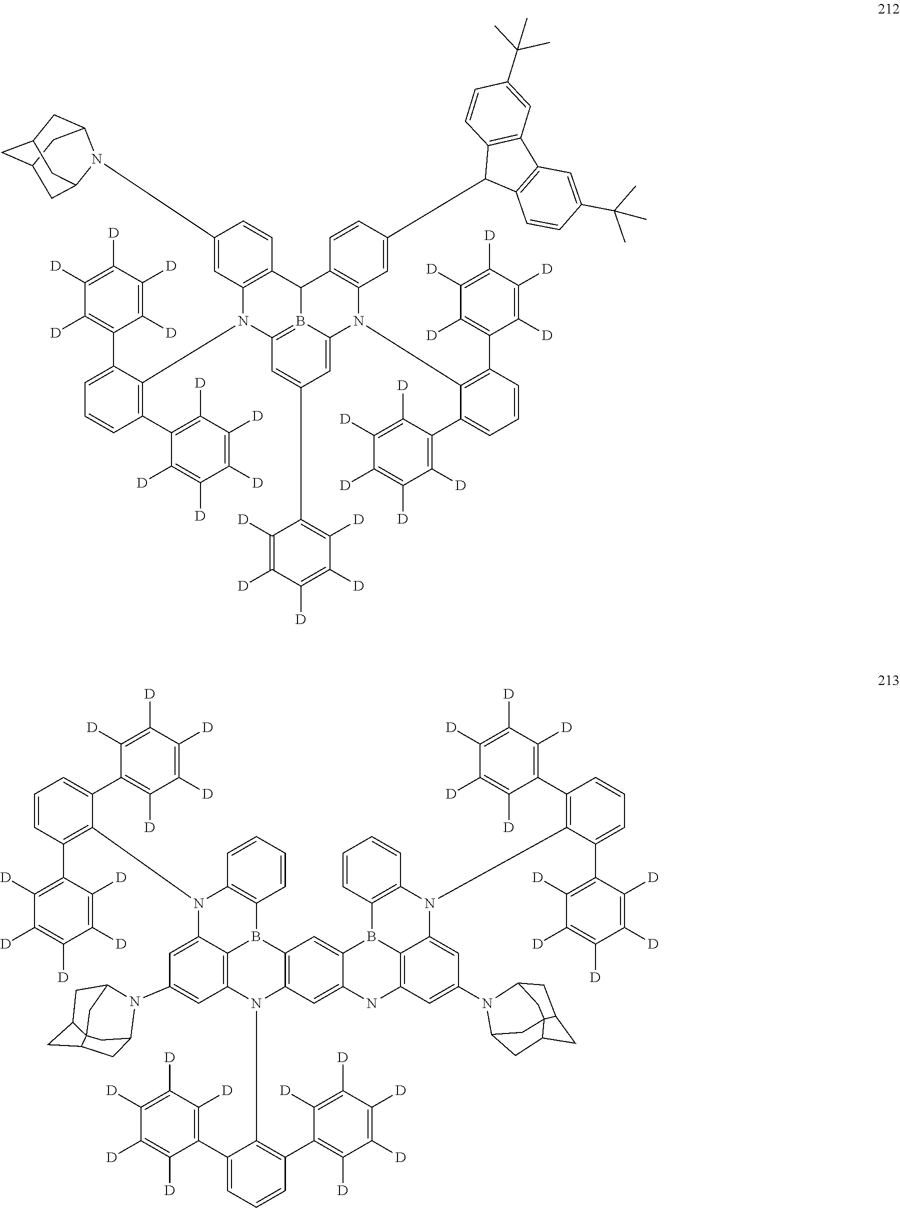

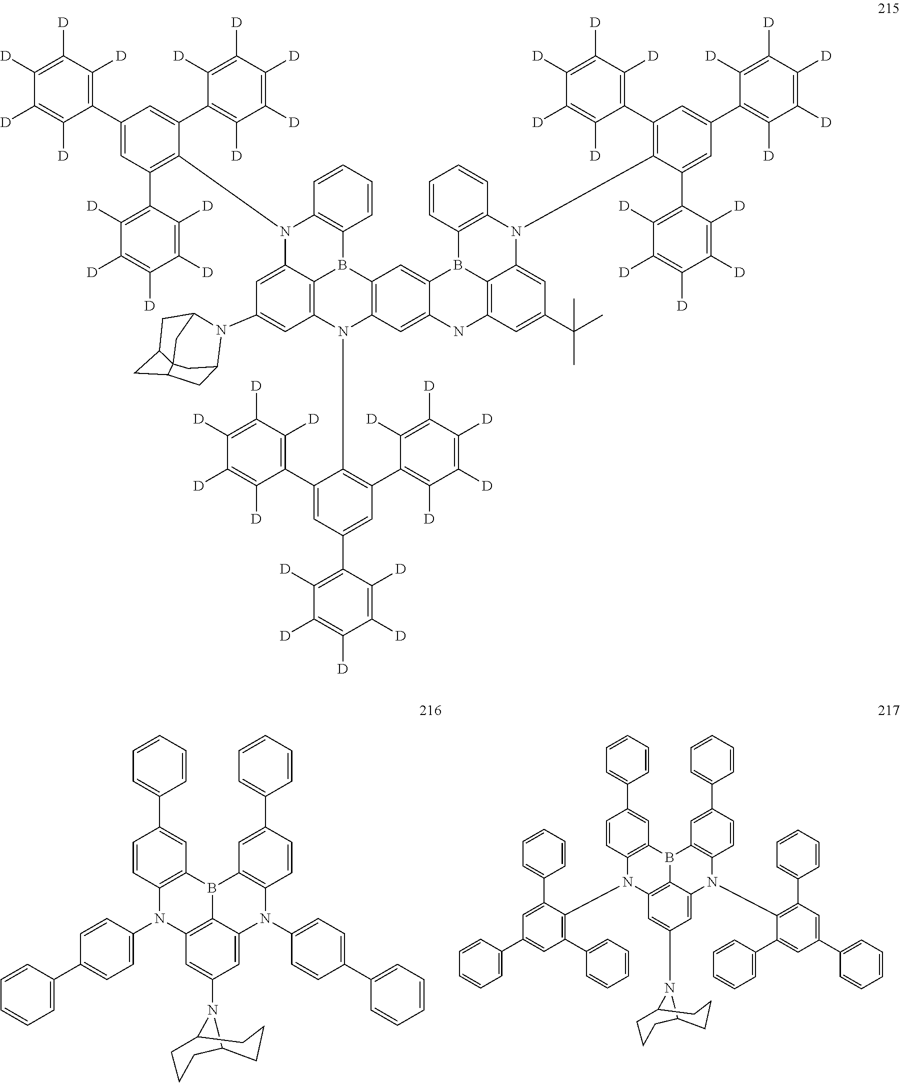

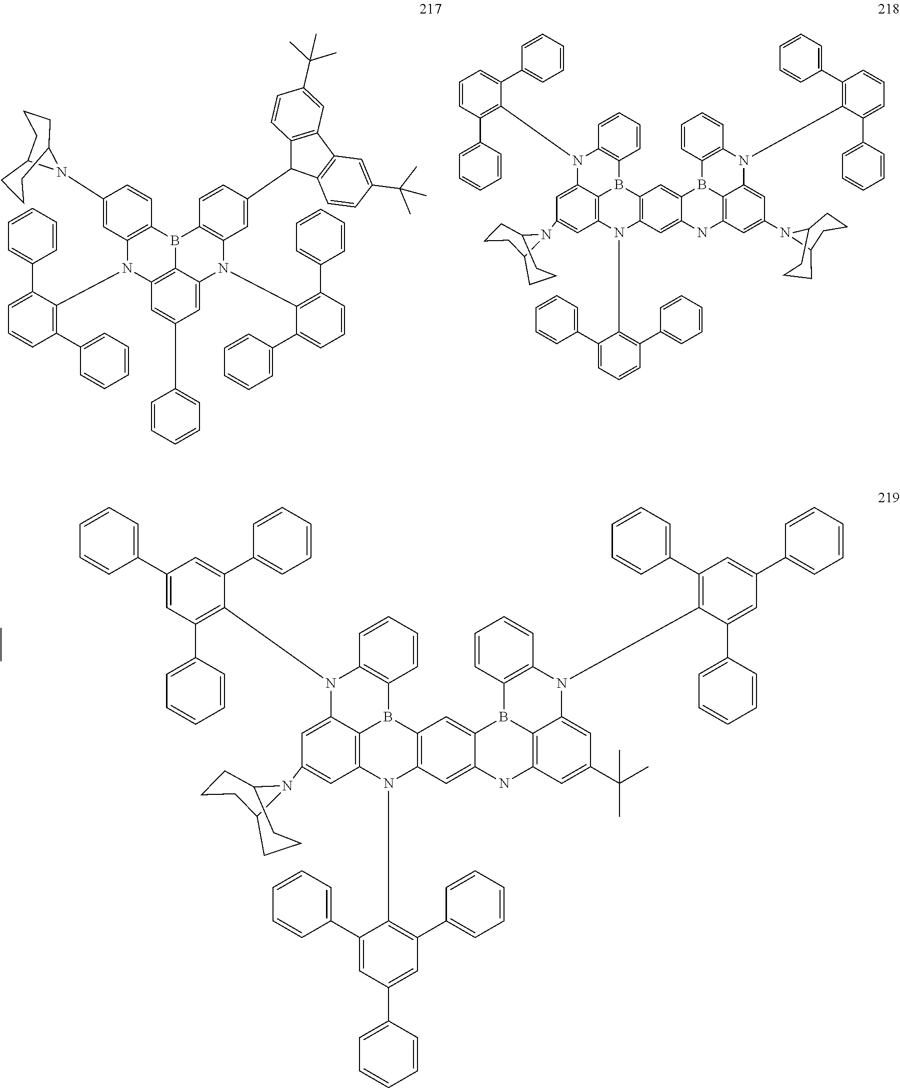

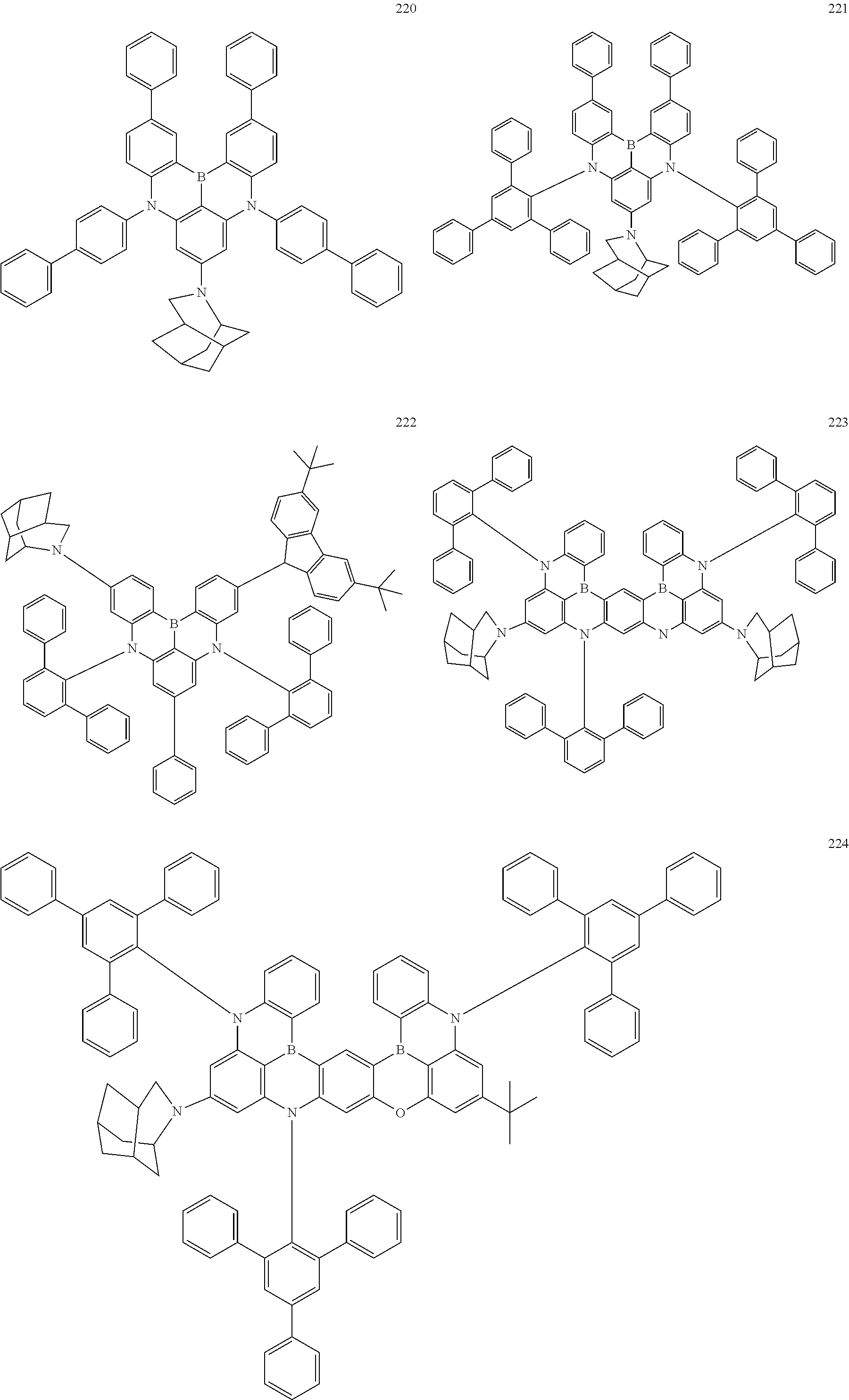

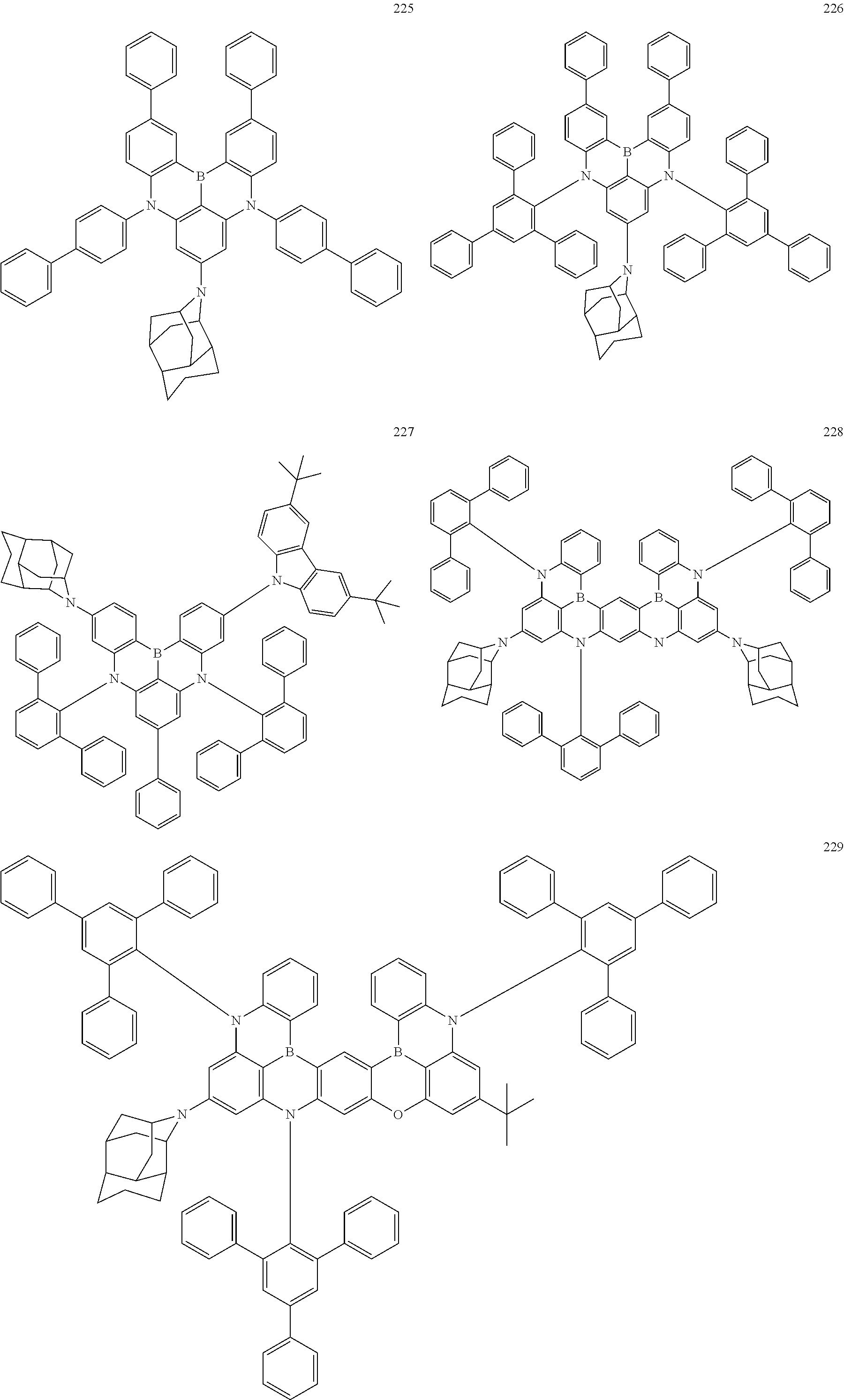

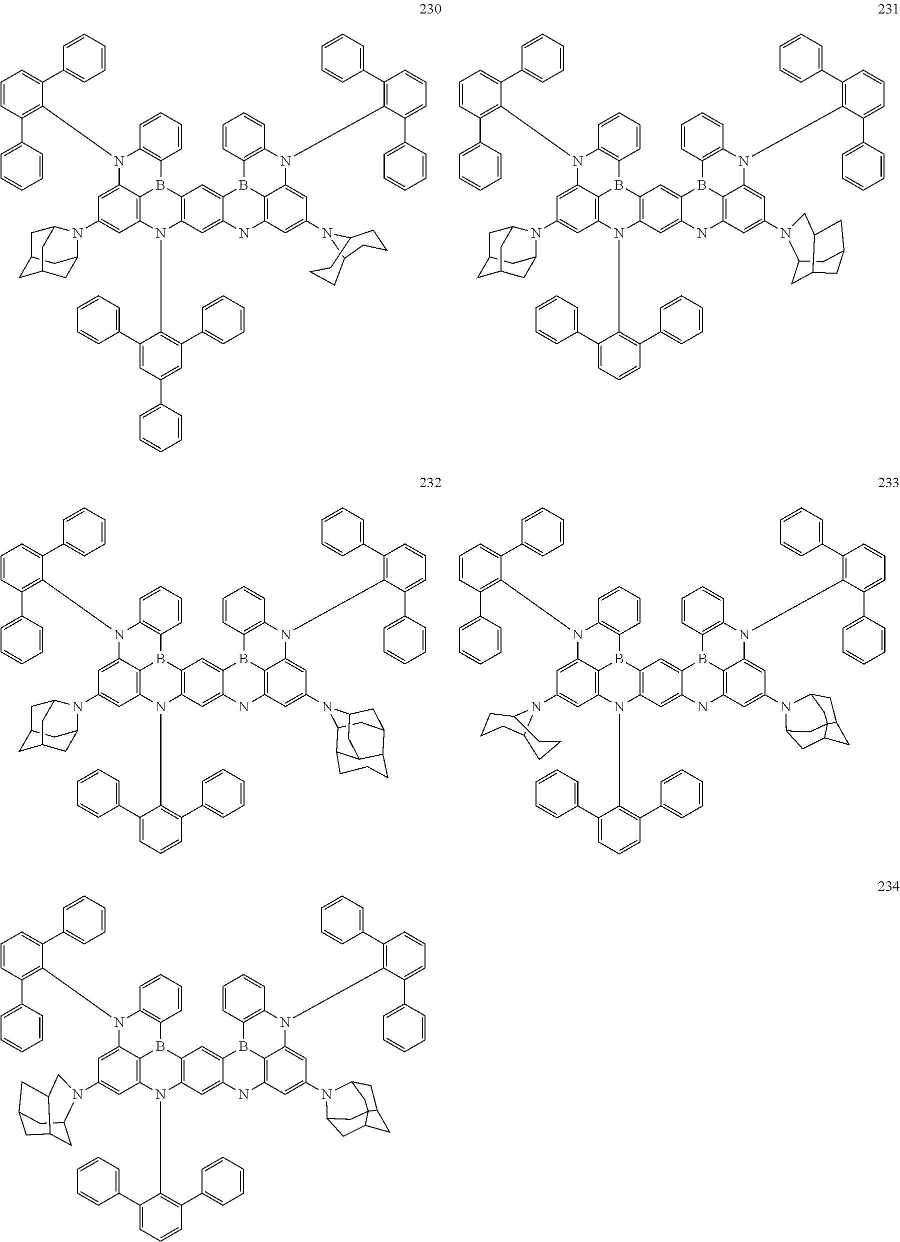

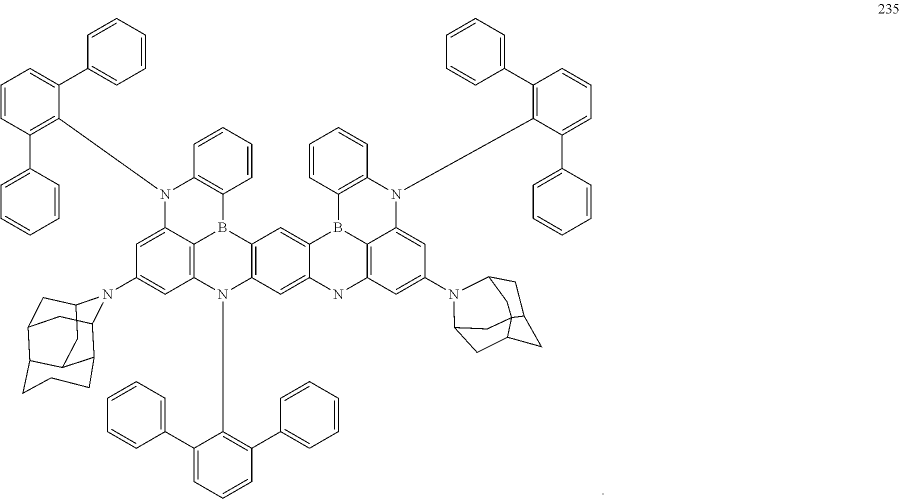 [SMILES: c1ccc(-c2cccc(-c3ccccc3)c2N2c3ccccc3B3c4cc5c(cc4Nc4cc(N6C7CC8CC9CC6CC89C7)cc2c43)N(c2c(-c3ccccc3)cccc2-c2ccccc2)c2cc(N3C4CC6CC3C3CCCC6C3C4)cc3c2B5c2ccccc2N3c2c(-c3ccccc3)cccc2-c2ccccc2)cc1]

The polycyclic compound of an embodiment may include a ring part of a fused ring containing a boron atom as a ring-forming atom, and a nitrogen-containing polycyclic group having at least eight ring-forming carbon atoms and containing at least two bridgehead carbon atoms, which has a relatively large number of ring-forming carbon atoms, and thus may have a steric shielding effect, thereby exhibiting stable compound characteristics. In addition, the polycyclic compound of an embodiment may be utilized as a material for the light emitting element, thereby improving service life characteristics of the light emitting element.

In some embodiments, the polycyclic compound of an embodiment may be included in the emission layer EML. The polycyclic compound of an embodiment may be included as a dopant material in the emission layer EML. The polycyclic compound of an embodiment may be a thermally activated delayed fluorescence material. The polycyclic compound of an embodiment may be utilized as a thermally activated delayed fluorescence dopant. For example, in the light emitting element ED of an embodiment, the emission layer EML may include, as a thermally activated delayed fluorescence dopant, one or more of the polycyclic compounds represented by Compound Group 1 as described above. However, usage of the polycyclic compound of an embodiment is not limited thereto.

The polycyclic compound of an embodiment may be to emit blue light, and have a maximum emission wavelength around 460 nm. In some embodiments, the polycyclic compound of an embodiment may be to emit pure blue light having a maximum emission wavelength around 460 nm.

In an embodiment, the emission layer EML may include the first compound represented by Formula 1, and at least one of the second compound represented by Formula HT-1, the third compound represented by Formula ET-1, or the fourth compound represented by Formula M-b.

For example, the second compound in an embodiment may be utilized as a hole transport host material of the emission layer EML.

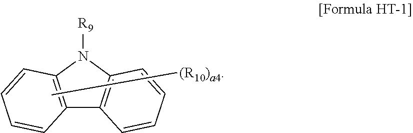

In Formula HT-1, a4 may be an integer of 0 to 8. When a4 is an integer of 2 or greater, a plurality of R₁₀'s may be the same as each other or at least one may be different from the others. R₉ and R₁₀ may each independently be a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms. For example, R₉ may be a substituted phenyl group, an unsubstituted dibenzofuran group, or a substituted fluorenyl group. For example, R₁₀ may be a substituted or unsubstituted carbazole group.

The second compound may be any one of the compounds in Compound Group 2. The light emitting element ED of an embodiment may include any of the compounds of Compound Group 2:

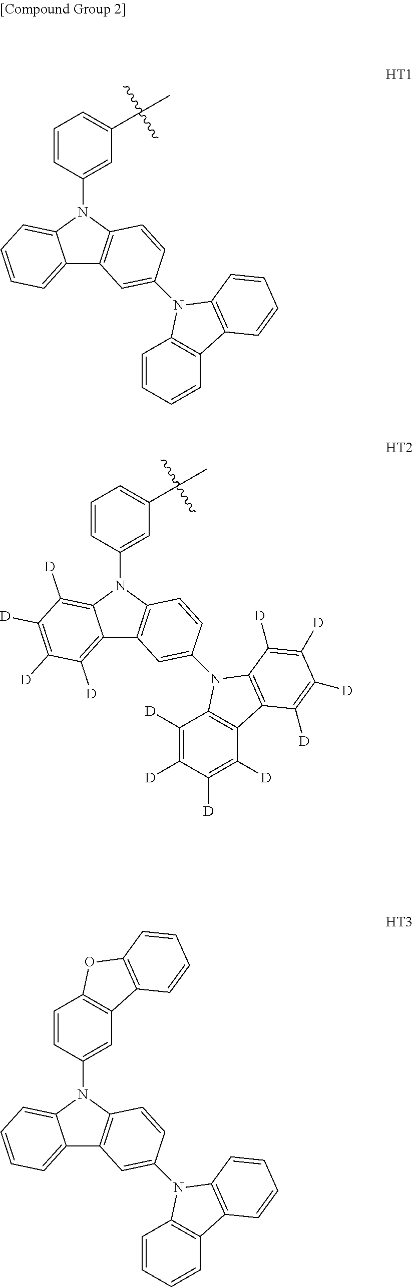 [SMILES: *c1cccc(-n2c3ccccc3c3cc(-n4c5ccccc5c5ccccc54)ccc32)c1 ; *c1cccc(-n2c3ccc(-n4c5c([2H])c([2H])c([2H])c([2H])c5c5c([2H])c([2H])c([2H])c([2H])c54)cc3c3c([2H])c([2H])c([2H])c([2H])c32)c1 ; c1ccc2c(c1)oc1ccc(-n3c4ccccc4c4cc(-n5c6ccccc6c6ccccc65)ccc43)cc12]

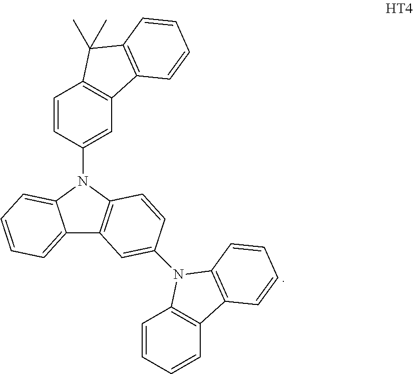 [SMILES: CC1(C)c2ccccc2-c2cc(-n3c4ccccc4c4cc(-n5c6ccccc6c6ccccc65)ccc43)ccc21]

In an embodiment, the emission layer EML may include the third compound represented by Formula ET-1. For example, the third compound may be utilized as an electron transport host material of the emission layer EML.

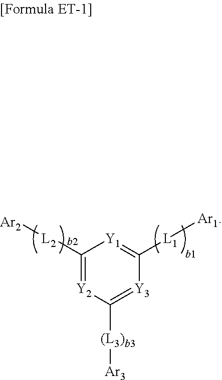

In Formula ET-1, at least one from among Y₁ to Y₃ may be N, and any remainder from among Y₁ to Y₃ may each independently be CRₐ, and Rₐ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

b1 to b3 may each independently be an integer of 0 to 10. L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms.

Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₁ to Ar₃ may each independently be a substituted or unsubstituted phenyl group, or a substituted or unsubstituted carbazole group.

The third compound may be any one of the compounds in Compound Group 3. The light emitting element ED of an embodiment may include any of the compounds of Compound Group 3:

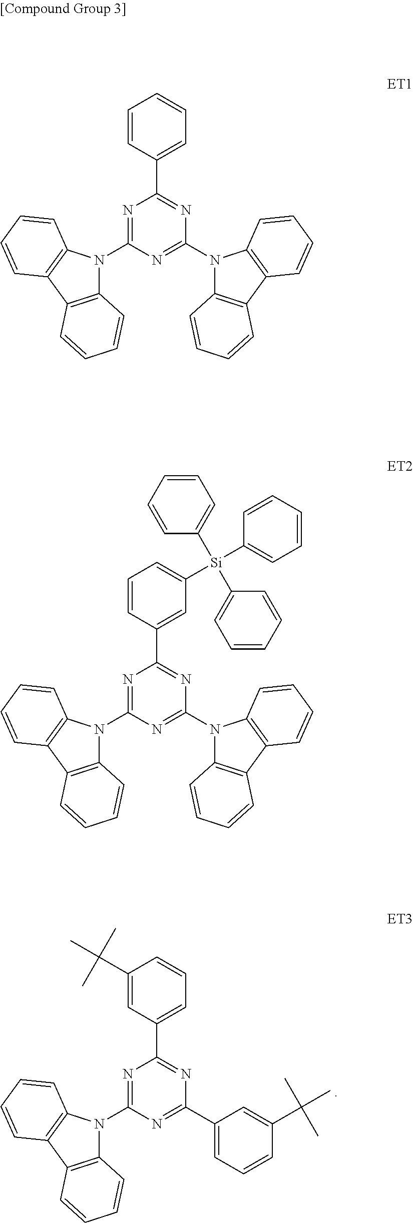 [SMILES: c1ccc(-c2nc(-n3c4ccccc4c4ccccc43)nc(-n3c4ccccc4c4ccccc43)n2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; CC(C)(C)c1cccc(-c2nc(-c3cccc(C(C)(C)C)c3)nc(-n3c4ccccc4c4ccccc43)n2)c1]

For example, the emission layer EML may include the second compound and the third compound, and the second compound and the third compound may form an exciplex. In the emission layer EML, an exciplex may be formed by the hole transport host and the electron transport host. In this case, a triplet energy of the exciplex formed by the hole transport host and the electron transport host may correspond to the difference between a lowest unoccupied molecular orbital (LUMO) energy level of the electron transport host and a highest occupied molecular orbital (HOMO) energy level of the hole transport host.

For example, the absolute value of the triplet energy (T1) of the exciplex formed by the hole transport host and the electron transport host may be about 2.4 eV to about 3.0 eV. In some embodiments, the triplet energy of the exciplex may be a value smaller than an energy gap of each host material. The exciplex may have a tirplet energy of about 3.0 eV or less, which is an energy gap between the hole transport host and the electron transport host.

In an embodiment, the emission layer EML may include the fourth compound represented by Formula M-b. For example, the fourth compound may be utilized as a phosphorescent sensitizer of the emission layer EML. The energy may be transferred from the fourth compound to the first compound, thereby emitting light.

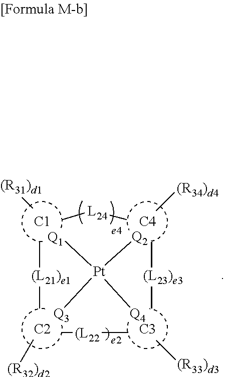

In Formula M-b, Q₁ to Q₄ may each independently be carbon (C) or nitrogen (N), and C1 to C4 may each independently be a substituted or unsubstituted hydrocarbon ring group having 5 to 30 ring-forming carbon atoms, or a substituted or unsubstituted heterocyclic group having 2 to 30 ring-forming carbon atoms.

e1 to e4 may each independently be 0 or 1, and L₂₁ to L₂₄ may each independently be a direct linkage,

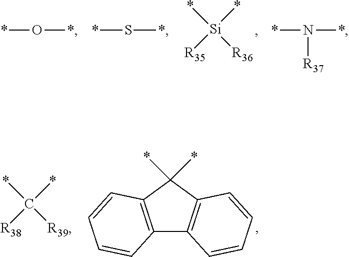

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms.

d1 to d4 may each independently be an integer of 0 to 4. When d1 is an integer of 2 or more, a plurality of R₃₁'s may be the same as each other or at least one may be different from the others. When d2 is an integer of 2 or more, a plurality of R₃₂'s may be the same as each other or at least one may be different from the others. When d3 is an integer of 2 or more, a plurality of R₃₃'s may be the same as each other or at least one may be different from the others. When d4 is an integer of 2 or more, a plurality of R₃₄'s may be the same as each other or at least one may be different from the others.

R₃₁ to R₃₉ may each independently be a hydrogen atom, a deuterium atom, a halogen atom, a cyano group, a substituted or unsubstituted amine group, a substituted or unsubstituted divalent alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

The fourth compound may be any one of the compounds in Compound Group 4. The light emitting element ED of an embodiment may include any of the compounds of Compound Group 4:

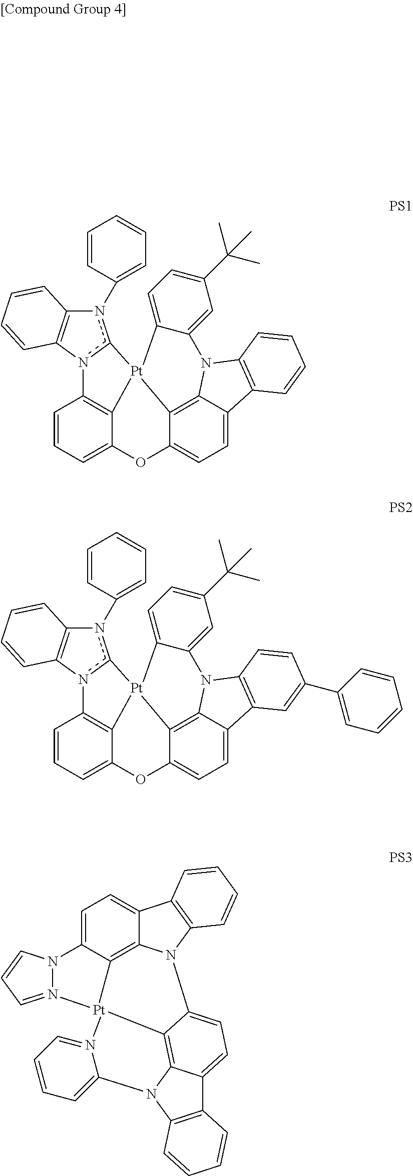

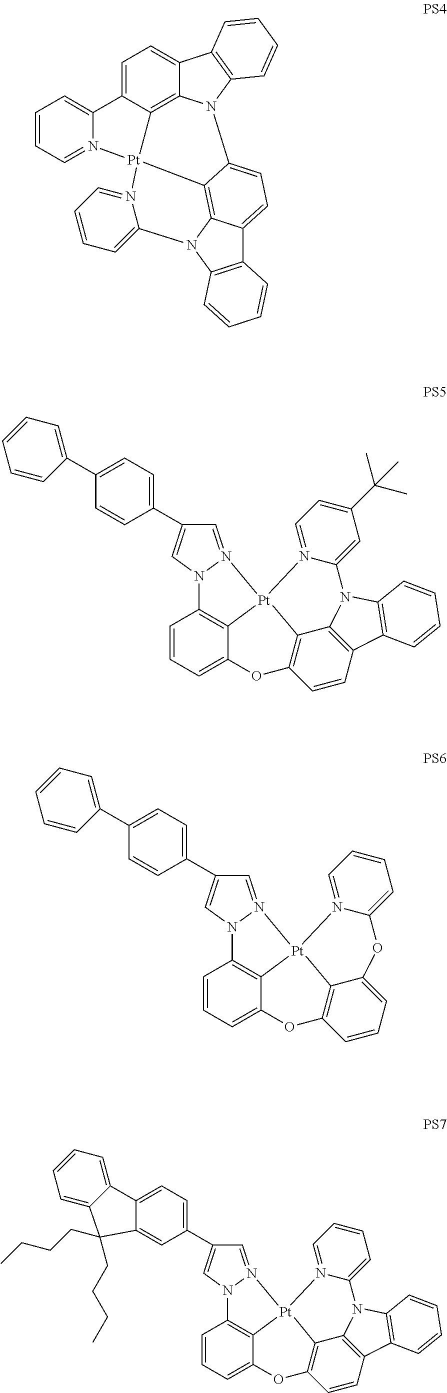

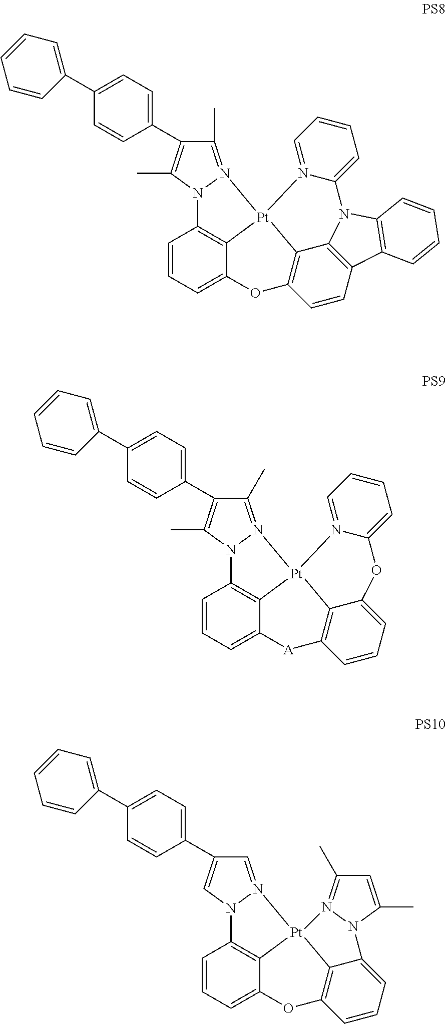

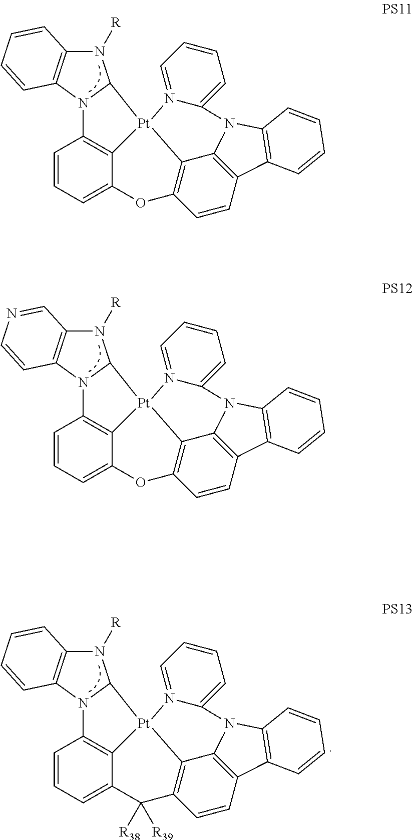

In the compounds of Compound Group 4, R, R₃₈, and R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

The emission layer EML of an embodiment may include the first compound, and at least one of the second to fourth compounds. For example, the emission layer EML may include the first compound, the second compound, and the third compound.

In the emission layer EML, the second compound and the third compound may form an exciplex, and the energy may be transferred from the exciplex to the first compound, thereby emitting light.

In some embodiments, the emission layer EML may include the first compound, the second compound, the third compound, and the fourth compound. In the emission layer EML, the second compound and the third compound may form an exciplex, and the energy may be transferred from the exciplex to the fourth compound and the first compound, thereby emitting light. In some embodiments, the fourth compound may be referred to as a phosphorescent sensitizer. The fourth compound may be to emit phosphorescence or may transfer energy to the first compound as an auxiliary dopant. However, these functions of the compounds are provided as an example, and the embodiment of the present disclosure is not limited thereto.

In some embodiments, the emission layer EML may further include a suitable material for the emission layer besides the first to fourth compounds presented above. In the light emitting element ED of an embodiment, the emission layer EML may further include an anthracene derivative, a pyrene derivative, a fluoranthene derivative, a chrysene derivative, a dehydrobenzanthracene derivative, a triphenylene derivative, and/or the like. For example, the emission layer EML may further include an anthracene derivative and/or a pyrene derivative.

In each light emitting element ED of embodiments illustrated in FIGS. 3 to 6, the emission layer EML may include a compound represented by Formula E-1. The compound represented by Formula E-1 may be utilized as a fluorescent host material.

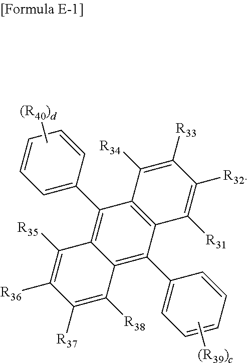

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. In some embodiments, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may each independently be an integer of 0 to 5.

The compound represented by Formula E-1 may be any of Compound E1 to Compound E19:

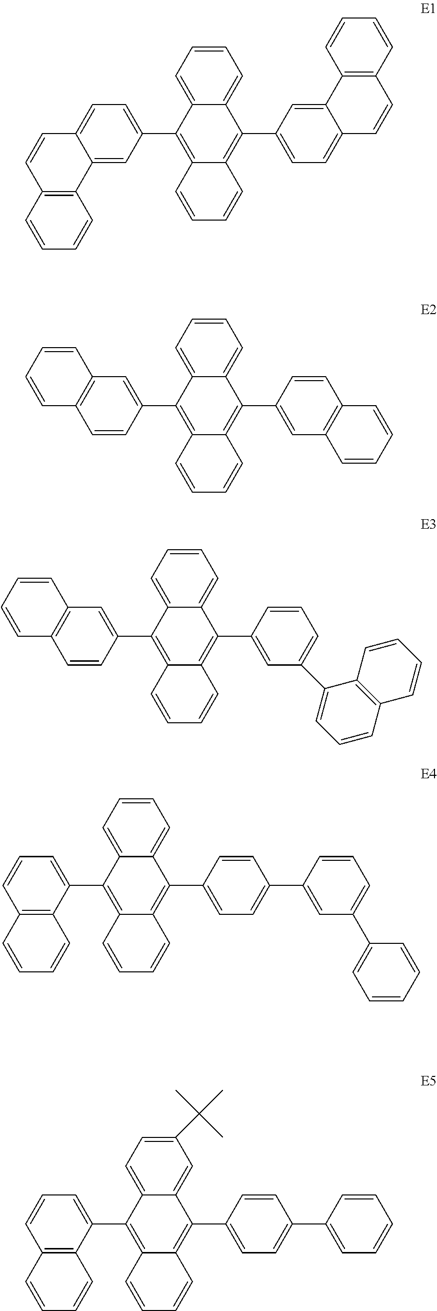

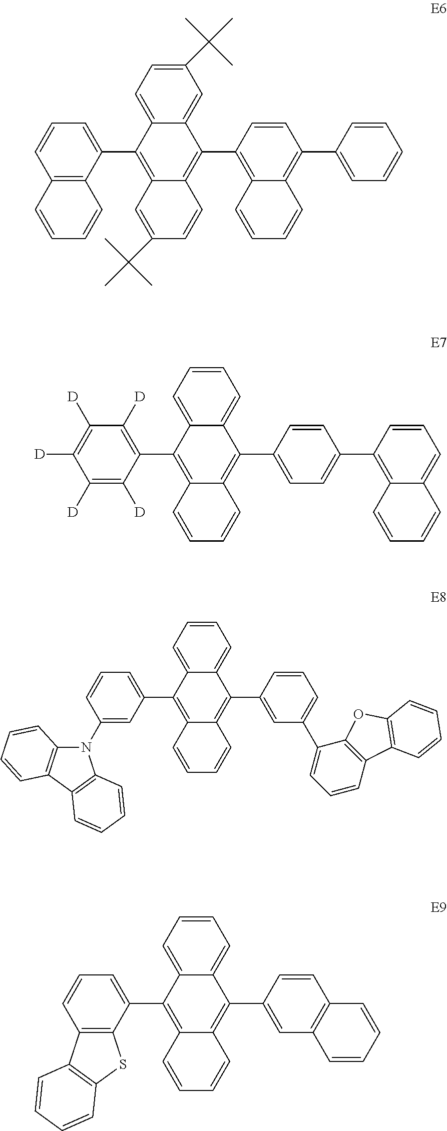

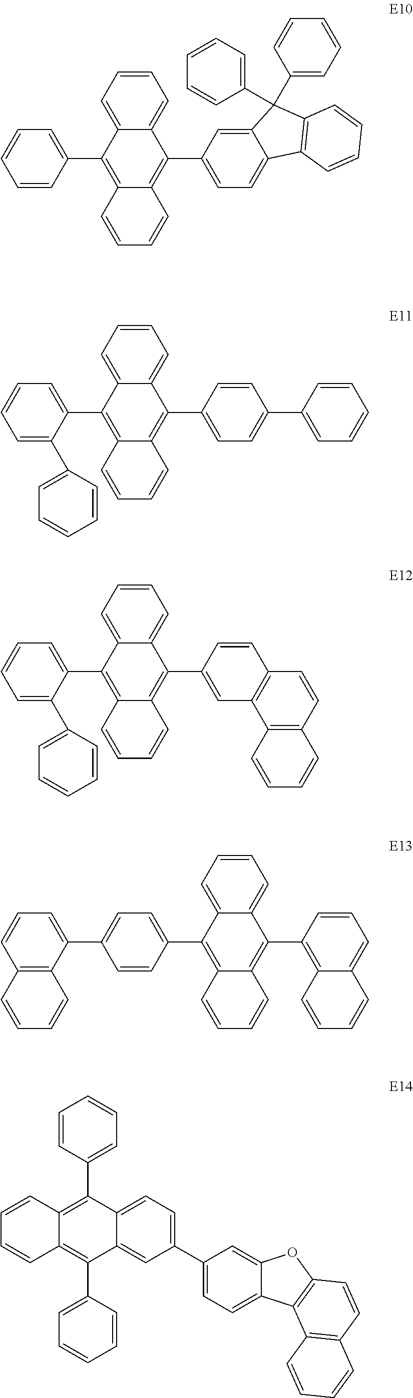

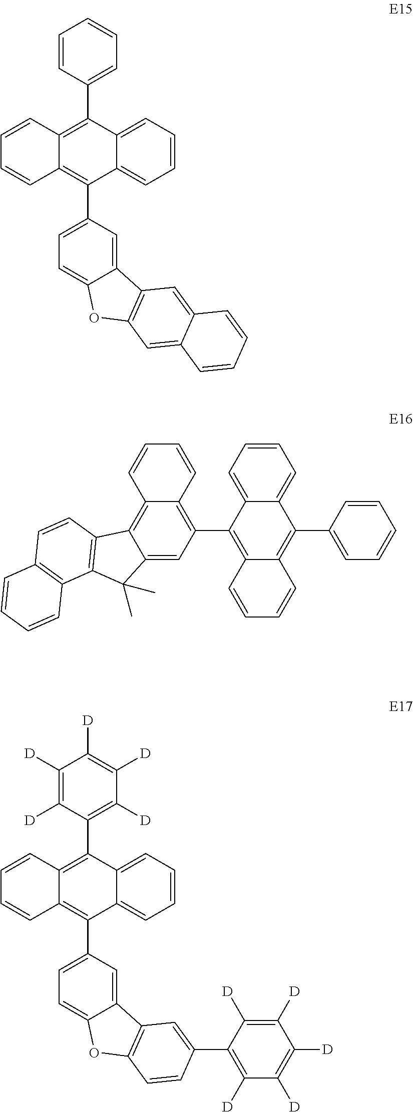

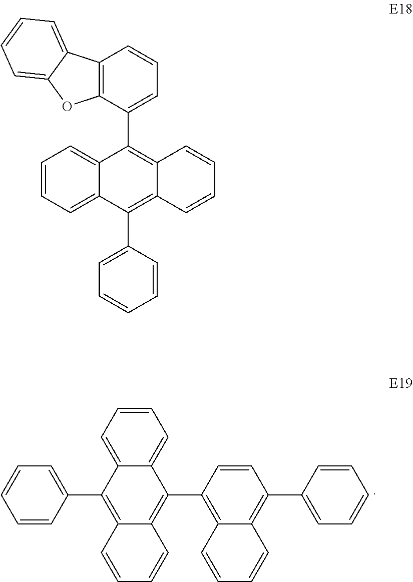

In an embodiment, the emission layer EML may include a compound represented by Formula E-2a or Formula E-2b. The compound represented by Formula E-2a or Formula E-2b may be utilized as a phosphorescent host material.

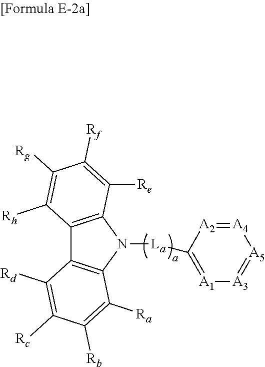

In Formula E-2a, a may be an integer of 0 to 10, and Lₐ may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a is an integer of 2 or more, a plurality of Lₐ's may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may each independently be N or CR. Rₐ to R may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. Rₐ to Rᵢ may be bonded to an adjacent group to form a hydrocarbon ring or a heterocycle containing N, O, S, etc. as a ring-forming atom.

In some embodiments, in Formula E-2a, two or three selected from among A₁ to A₅ may be N, and the remainder (e.g., the rest) may be CR.

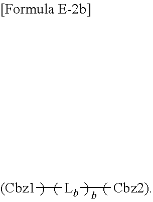

In Formula E-2b, Cbz1 and Cbz2 may each independently be an unsubstituted carbazole group, or a carbazole group substituted with an aryl group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, b may be an integer of 0 to 10, and when b is an integer of 2 or more, a plurality of L_{b}'s may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be any one of the compounds of Compound Group E-2. However, the compounds listed in Compound Group E-2 are provided as examples, and the compound represented by Formula E-2a or Formula E-2b is not limited to those represented in Compound Group E-2.

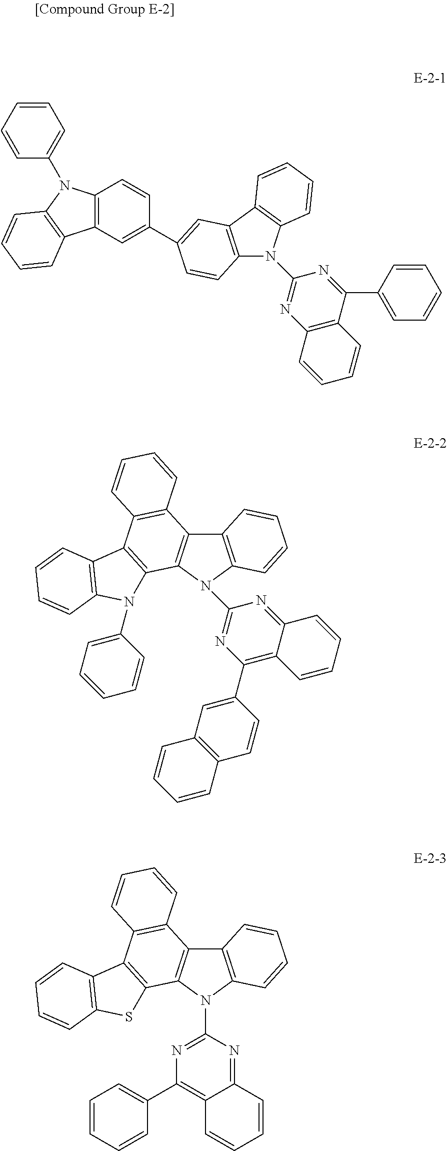 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

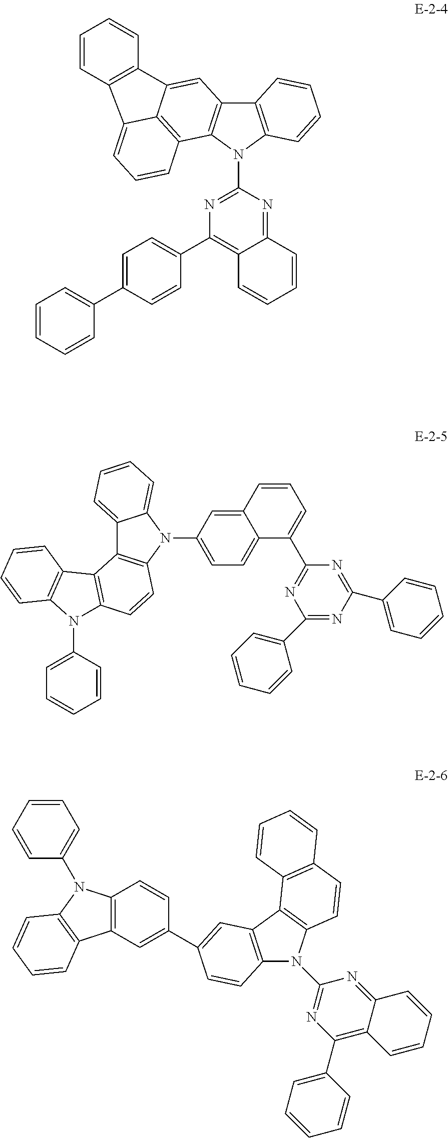 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

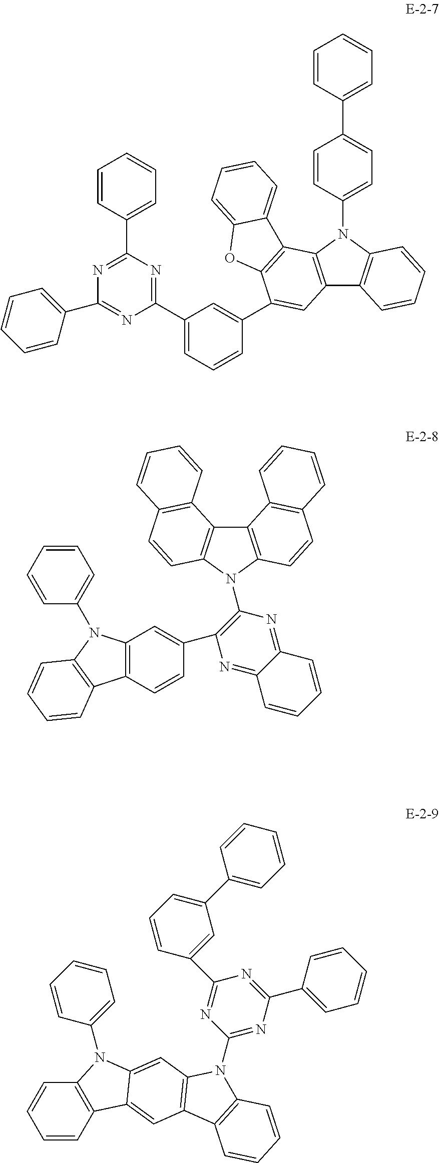 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

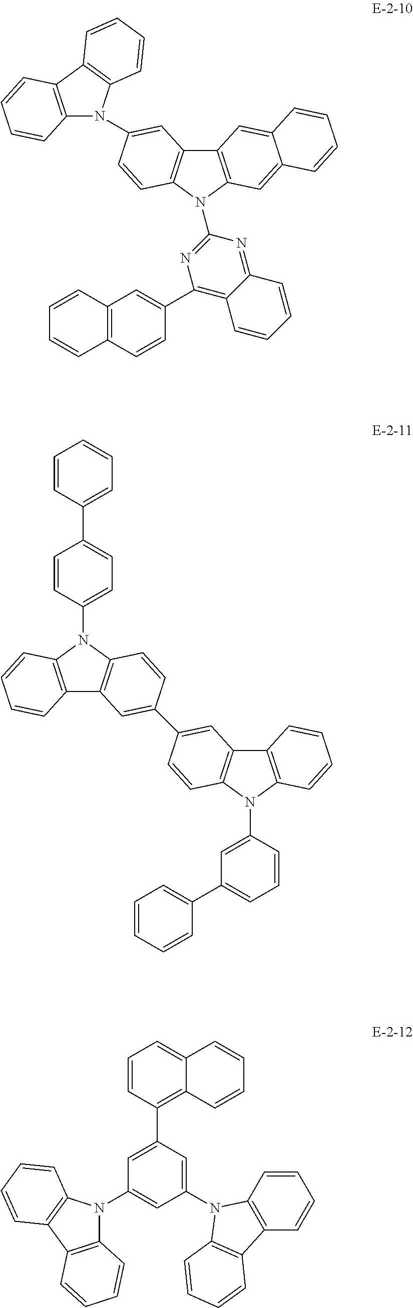 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

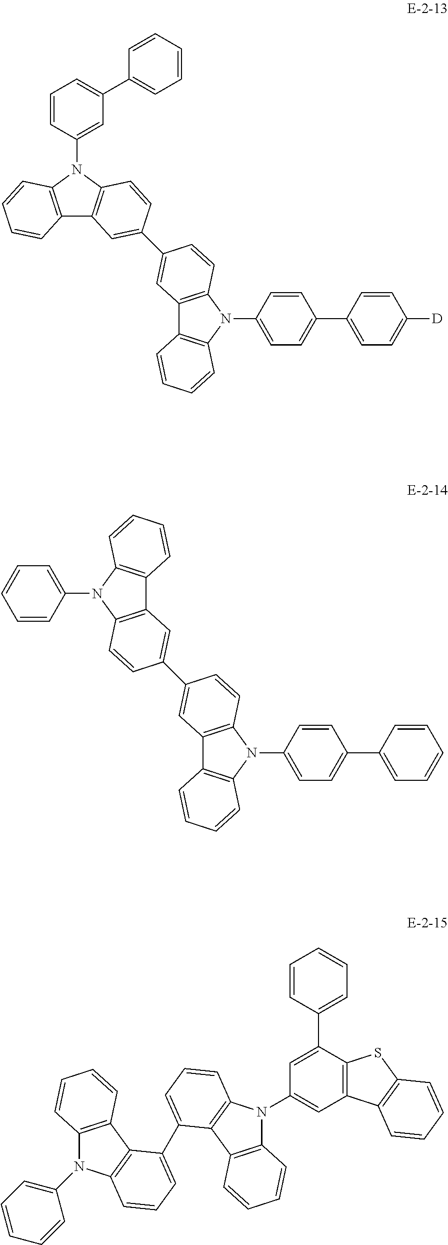 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

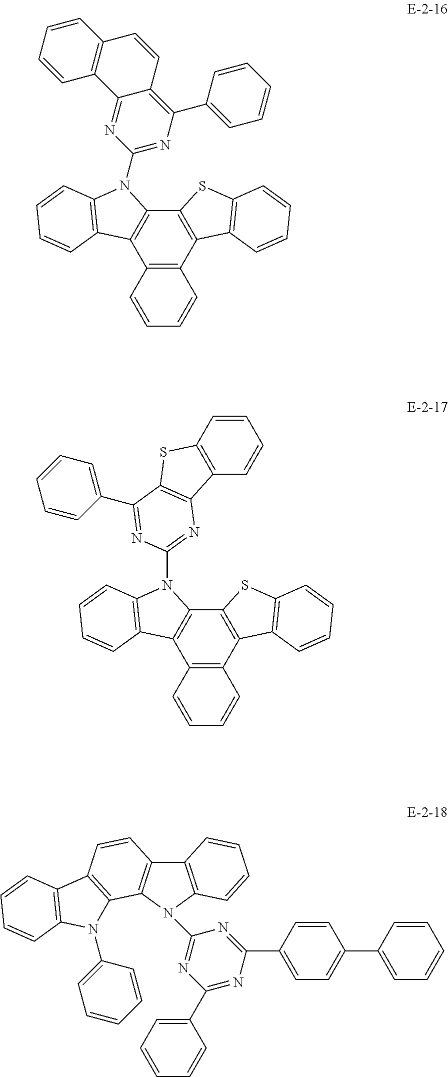 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

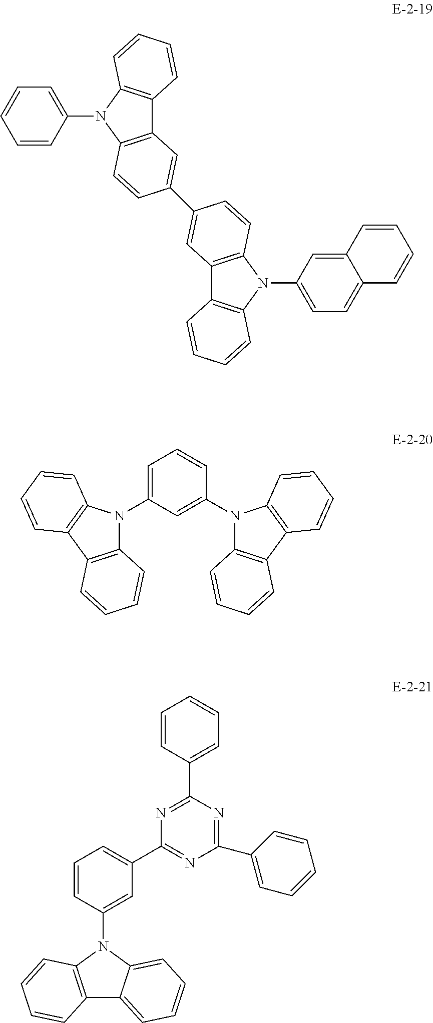 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1]

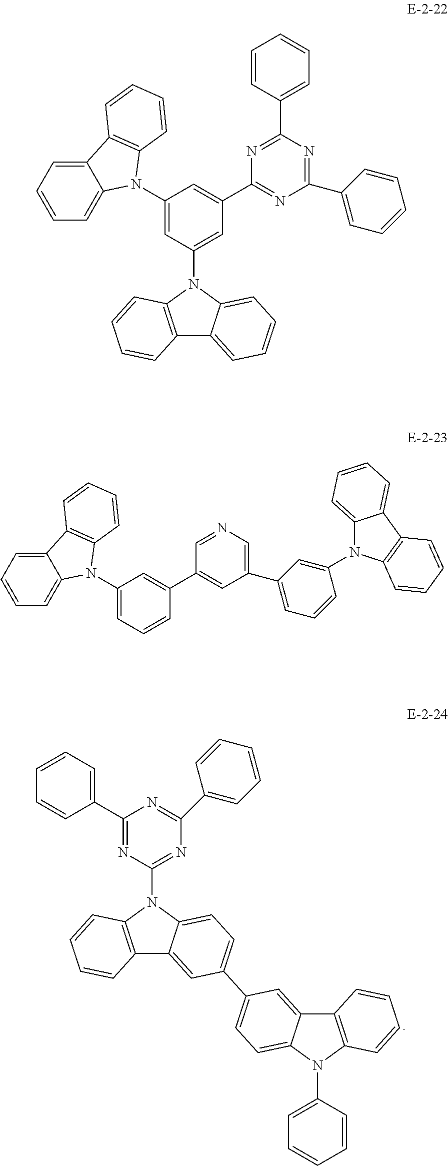 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a general material suitable in the art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 3,3′-di(9H-carbazol-9-yl)-1,1′-biphenyl (mCBP), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, the embodiment of the present disclosure is not limited thereto, for example, tris(8-hydroxyquinolino)aluminum (Alq₃), 9,10-di(naphthalene-2-yl)anthracene (ADN), 2-tert-butyl-9,10-di(naphth yl)anthracene (TBADN), distyrylarylene (DSA), 4,4′-bis(9-carbazolyl)-2,2′-dimethylbiphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be utilized as a host material.

The emission layer EML may include the compound represented by Formula M-a. The compound represented by Formula M-a may be utilized as a phosphorescent dopant material. In some embodiments, the compound represented by Formula M-a in an embodiment may be utilized as an auxiliary dopant material.

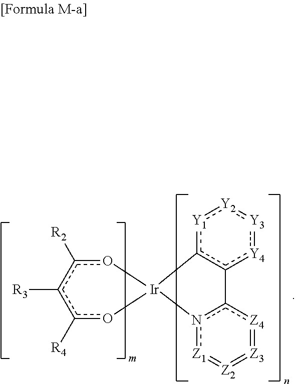

In Formula M-a above, Y₁ to Y₄ and Z₁ to Z₄ may each independently be CR₁ or N, and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. In Formula M-a, m may be 0 or 1, and n may be 2 or 3. In Formula M-a, when m is 0, n is 3, and when m is 1, n is 2.

The compound represented by Formula M-a may be r any of Compound M-a1 to Compound M-a25. However, Compounds M-a1 to M-a25 are examples, and the compound represented by Formula M-a is not limited to those represented by Compounds M-a1 to M-a25.

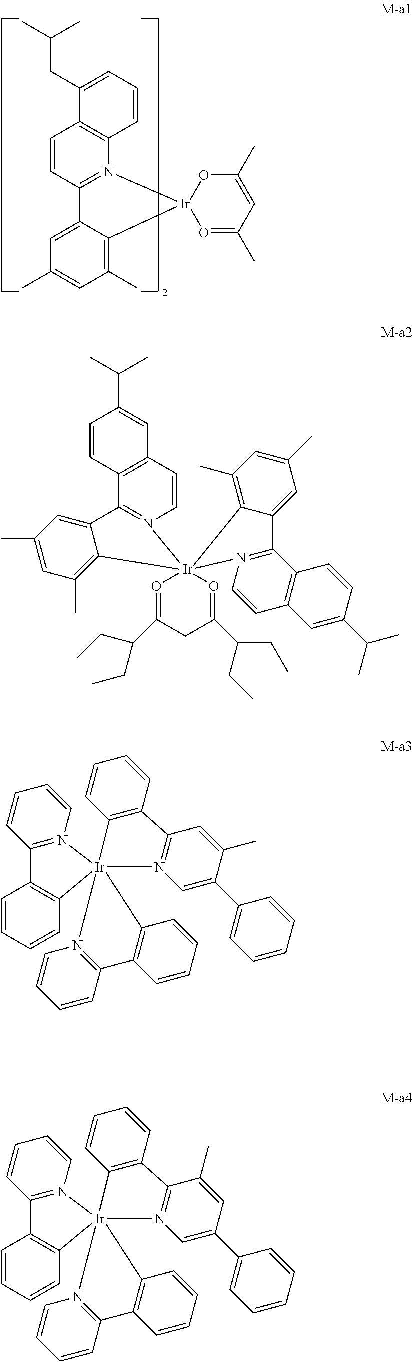

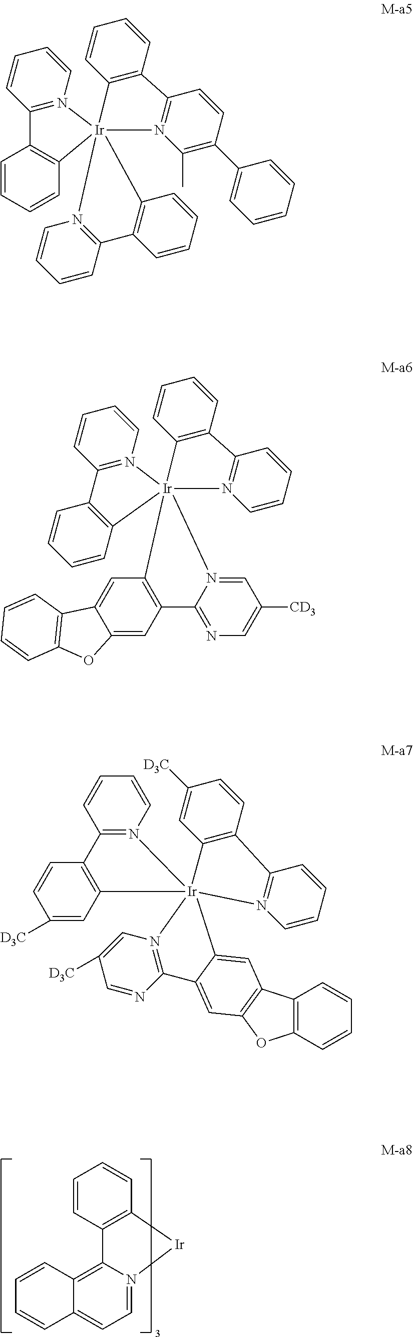

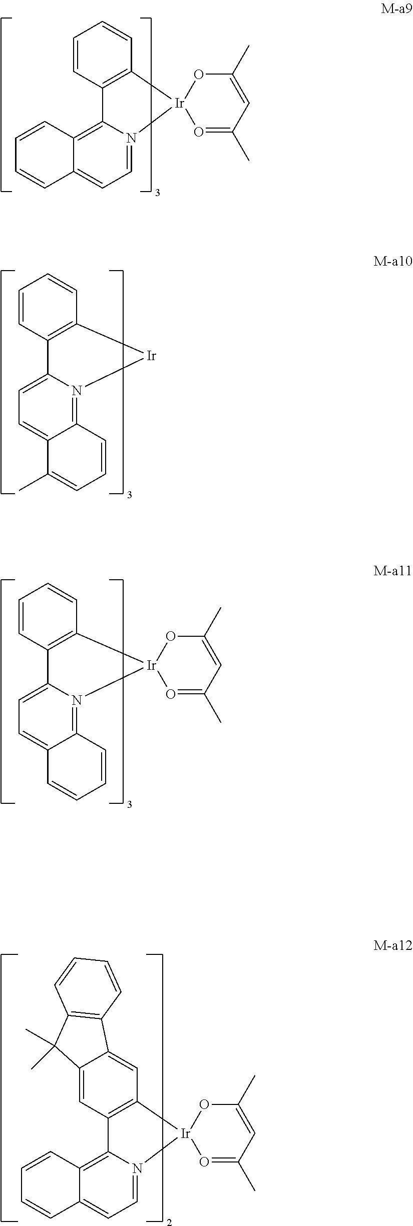

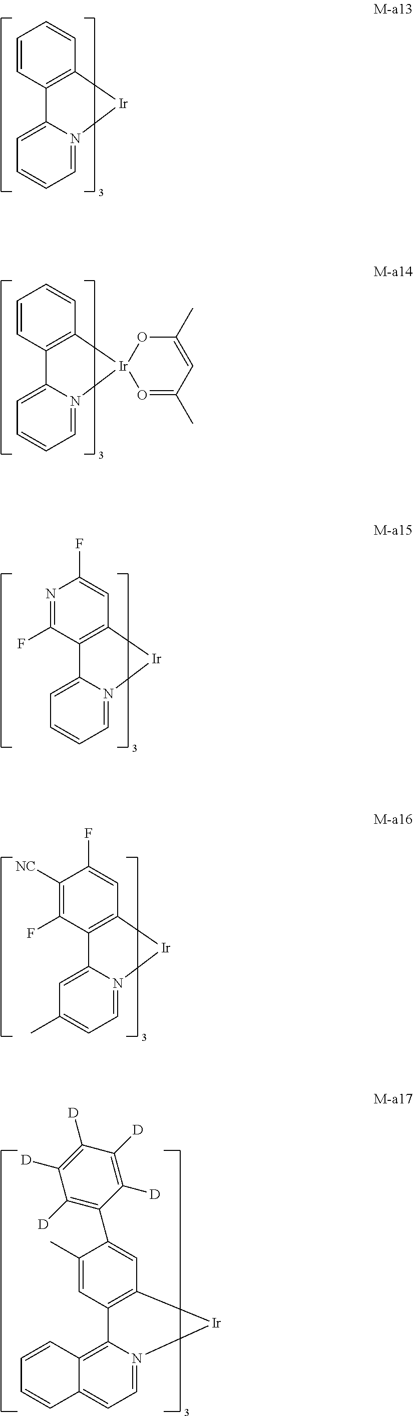

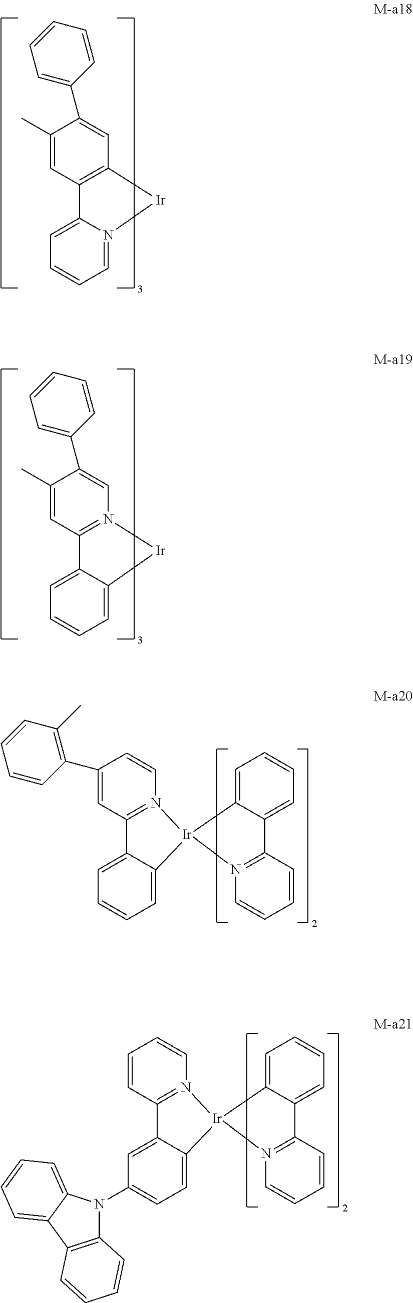

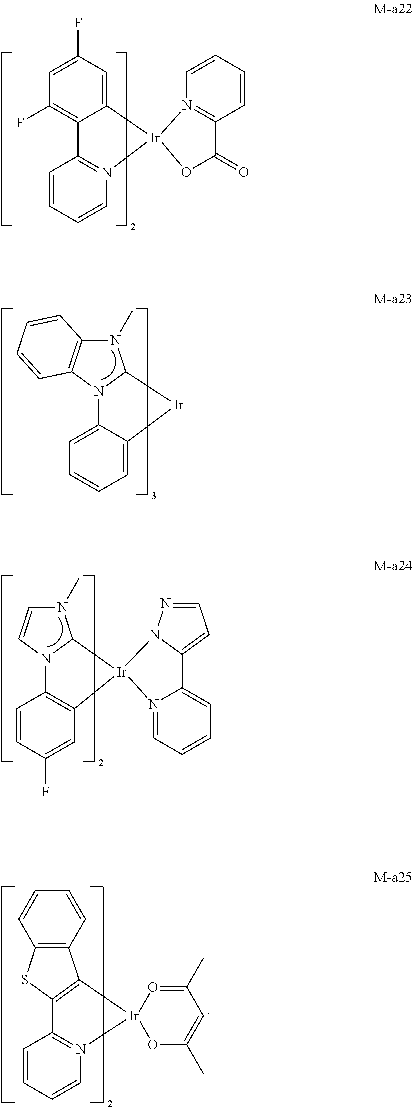

Compound M-a1 and Compound M-a2 may be utilized as a red dopant material, and Compound M-a3 to Compound M-a7 may be utilized as a green dopant material.

The emission layer EML may further include a compound represented by any one from among Formula F-a to Formula F-c. The compound represented by Formula F-a or Formula F-c may be utilized as a fluorescence dopant material.

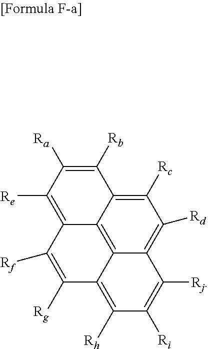

In Formula F-a above, two selected from among Rₐ to R may each independently be substituted with *—NAr₁Ar₂. The others (e.g., the rest of Rₐ to Rⱼ), which are not substituted with *—NAr₁Ar₂, among Rₐ to Rⱼ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In *—NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

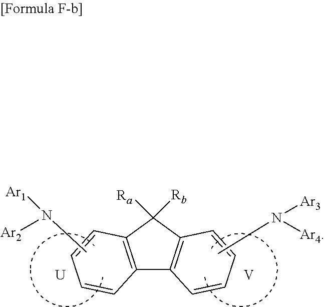

In Formula F-b above, Rₐ and Rb may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may each independently be 0 or 1. For example, in Formula F-b, when the number of U or V is 1, one ring indicated by U or V forms a condensed ring at the designated part (e.g., a portion indicated by U or V), and when the number of U or V is 0, a ring indicated by U or V does not exist. For example, when the number of U is 0 and the number of V is 1, or when the number of U is 1 and the number of V is 0, the fused ring having a fluorene core in Formula F-b may be a cyclic compound having four rings. In some embodiments, when each number of U and V is 0, the fused ring in Formula F-b may be a cyclic compound having three rings. In some embodiments, when each number of U and V is 1, the fused ring having a fluorene core in Formula F-b may be a cyclic compound having five rings.

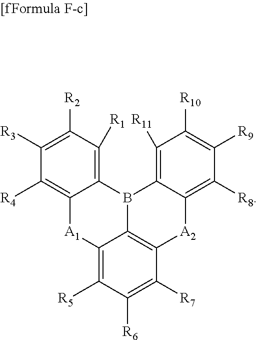

In Formula F-c, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In Formula F-c, A₁ and A₂ may each independently be bonded to substituents of an adjacent ring to form a condensed ring. For example, when A₁ and A₂ may each independently be NRₘ, A₁ may be bonded to R₄ or R₅ to form a ring. In some embodiments, A₂ may be bonded to R₇ or R₈ to form a ring.

In an embodiment, the emission layer EML may include, as a suitable dopant material, a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N,N-diphenylamino)pyrene), etc.

In an embodiment, when a plurality of emission layers EML are included, at least one emission layer EML may include a suitable phosphorescence dopant material. For example, a metal complex containing iridium (Ir), platinum (Pt), osmium (Os), gold (Au), titanium (Ti), zirconium (Zr), hafnium (Hf), europium (Eu), terbium (Tb), and/or thulium (Tm) may be utilized as a phosphorescent dopant. For example, iridium(III) bis(4,6-difluorophenylpyridinato-N,C2′)picolinate (Flrpic), bis(2,4-difluorophenylpyridinato)-tetrakis(1-pyrazolyl)borate (Fir₆), and/or platinum octaethyl porphyrin (PtOEP) may be utilized as a phosphorescent dopant. However, the embodiment of the present disclosure is not limited thereto.

In some embodiments, at least one emission layer EML may include a quantum dot material. The core of the quantum dot may be selected from a Group II-VI compound, a Group III-VI compound, a Group compound, a Group III-V compound, a Group III-II-V compound, a Group IV-VI compound, a Group IV element, a Group IV compound, or a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-VI compound may include a binary compound such as In₂S₃ and/or In₂Se₃, a ternary compound such as InGaS₃ and/or InGaSe₃, or any combination thereof.

The Group compound may be selected from a ternary compound selected from the group consisting of AgInS, AgInS₂, CuInS, CuInS₂, AgGaS₂, CuGaS₂ CuGaO₂, AgGaO₂, AgAlO₂, and a mixture thereof, and a quaternary compound such as AgInGaS₂ and/or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In some embodiments, the Group III-V compound may further include a Group II metal. For example, InZnP, etc. may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

In this case, the binary compound, the ternary compound, and/or the quaternary compound may be present in a particle with a substantially uniform concentration distribution, or may be present in substantially the same particle with a partially different concentration distribution. In some embodiments, the quantum dot may have a core/shell structure in which one quantum dot is around (e.g., surrounds) another quantum dot. The core/shell structure may have a concentration gradient in which the concentration of elements present in the shell decreases toward the center of core.

In some embodiments, the quantum dot may have the above-described core/shell structure including a core containing nanocrystals and a shell around (e.g., surrounding) the core. The shell of the quantum dot may serve as a protection layer to prevent or reduce the chemical deformation of the core so as to maintain semiconductor properties, and/or as a charging layer to impart electrophoresis properties to the quantum dot. The shell may be a single layer or a multilayer. An example of the shell of the quantum dot may include a metal or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, and/or a ternary compound such as MgAl₂O₄, CoFe₂O₄, NiFe₂O₄, and/or CoMn₂O₄, but the present disclosure is not limited thereto.

In some embodiments, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but the embodiment of the present disclosure is not limited thereto.

The quantum dot may have a full width of half maximum (FWHM) of a light emitting wavelength spectrum of about 45 nm or less, about 40 nm or less, or about 30 nm or less, and color purity or color reproducibility may be improved in the above ranges. In some embodiments, light emitted through such a quantum dot is emitted in all directions, and thus a wide viewing angle may be obtained (e.g., improved).

In some embodiments, although the form of the quantum dot is not particularly limited as long as it is a form commonly utilized in the art, for example, the quantum dot in the form of spherical, pyramidal, multi-arm, or cubic nanoparticles, nanotubes, nanowires, nanofibers, nanoplate particles, etc. may be utilized.

The quantum dot may control the color of emitted light according to the particle size thereof. Accordingly, the quantum dot may have one or more suitable light emission colors such as blue, red, and/or green.

In each of the light emitting elements ED of embodiments illustrated in FIGS. 3 to 6, the electron transport region ETR is provided on the emission layer EML. The electron transport region ETR may include at least one of the hole blocking layer HBL, the electron transport layer ETL, or the electron injection layer EIL, but the embodiment of the present disclosure is not limited thereto.

The electron transport region ETR may have a single layer formed of a single material, a single layer formed of a plurality of different materials, or a multilayer structure including a plurality of layers formed of a plurality of different materials.

For example, the electron transport region ETR may have a single layer structure of the electron injection layer EIL or the electron transport layer ETL, and may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL, an electron transport layer ETL/buffer layer/electron injection layer EIL are stacked in the respective stated order from the emission layer EML, but the embodiment of the present disclosure is not limited thereto. The electron transport region ETR may have a thickness, for example, from about 1,000 Å to about 1,500 Å.

The electron transport region ETR may be formed by utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-1:

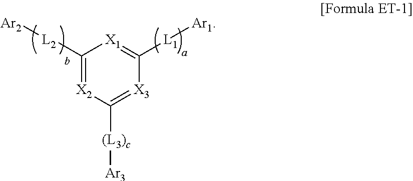

In Formula ET-1, at least one from among X₁ to X₃ may be N, and any remainder (e.g., the rest) may be CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₂ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer of 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a to c are each an integer of 2 or more, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, the embodiment of the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol yl)phenyl)-9,10-dinaphthylanthracene, 1,3,5-tri(1-phenyl-1H-benzo[d]imidazol yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), diphenyl(4-(triphenylsilyl)phenyl)phosphine oxide (TSPO1), or a mixture thereof.

The electron transport region ETR may include at least one of Compound ET1 to Compound ET36:

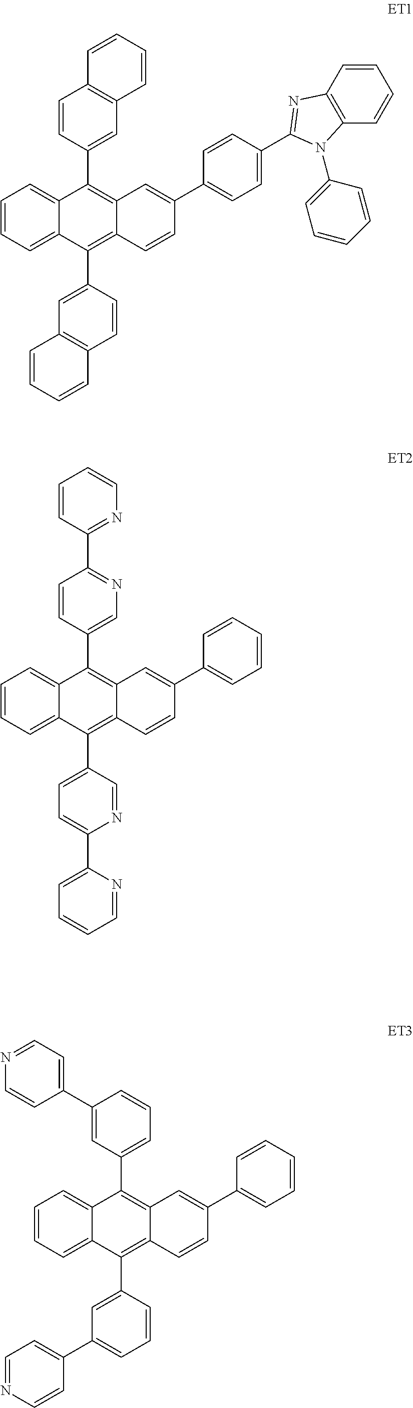 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

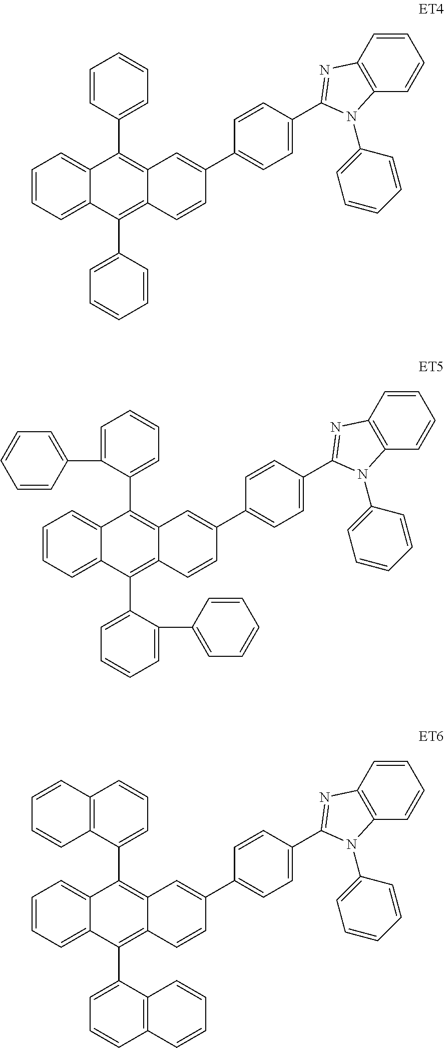 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

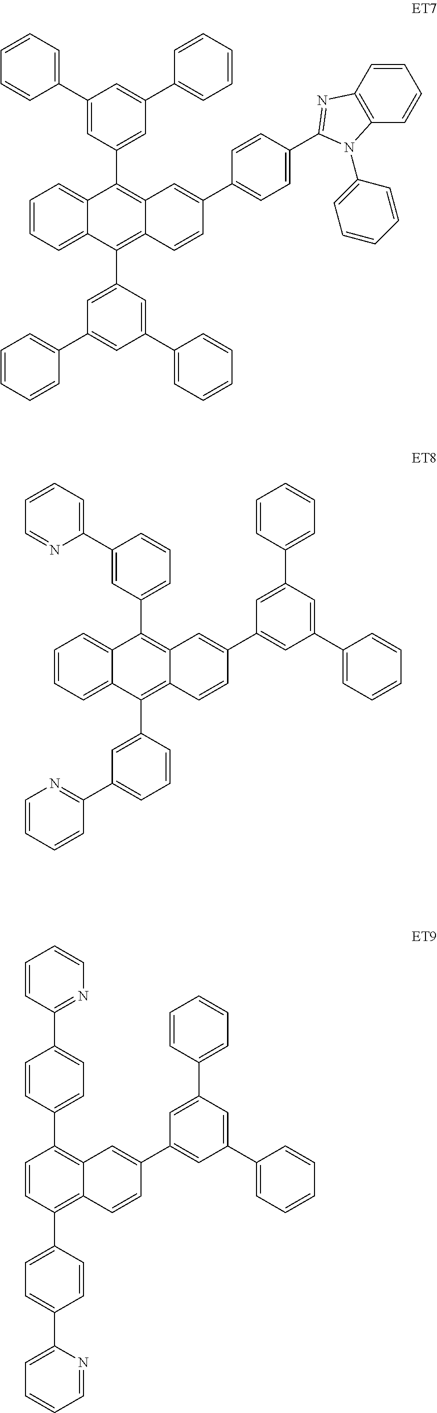 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)ccc(-c5ccc(-c6ccccn6)cc5)c4c3)c2)cc1]

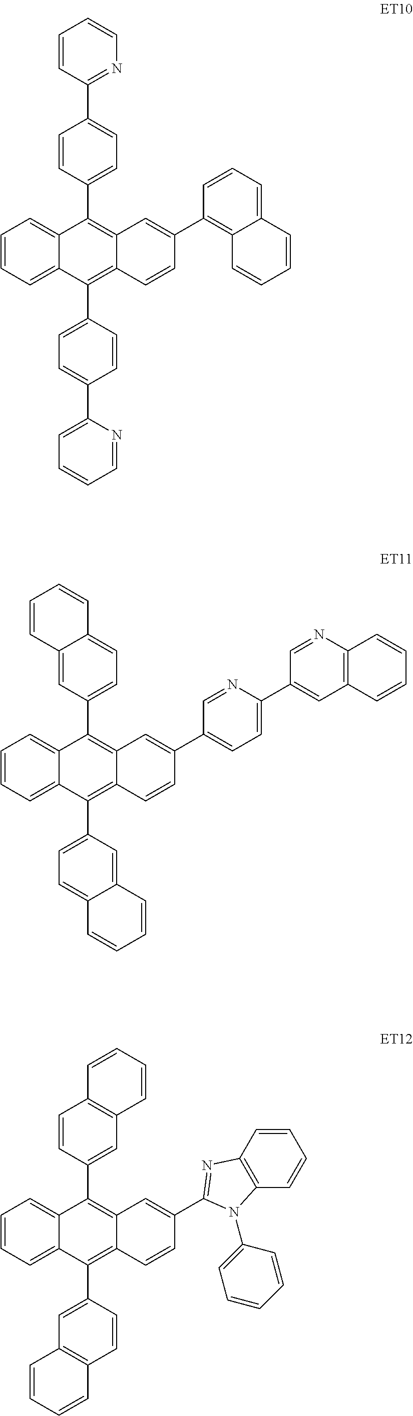 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

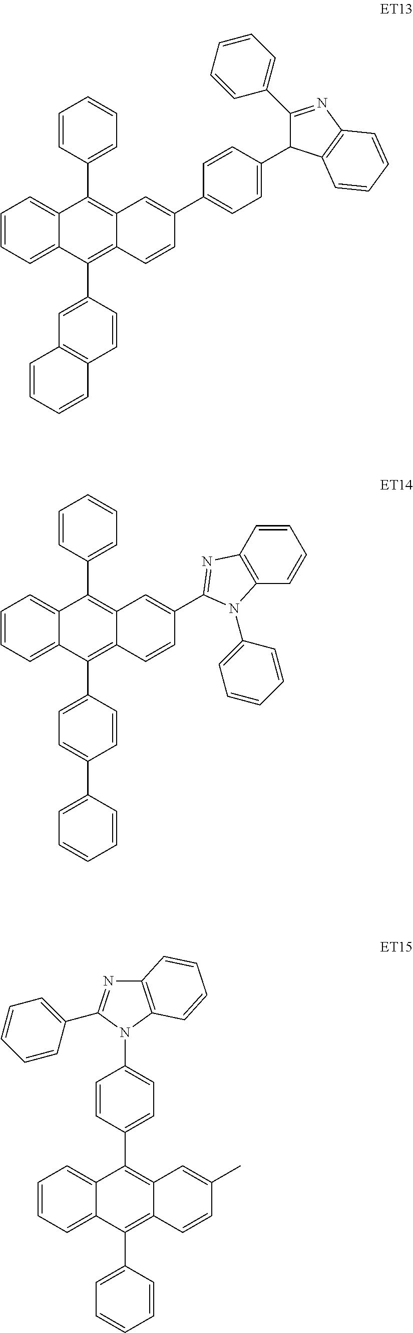 [SMILES: c1ccc(C2=Nc3ccccc3C2c2ccc(-c3ccc4c(-c5ccc6ccccc6c5)c5ccccc5c(-c5ccccc5)c4c3)cc2)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

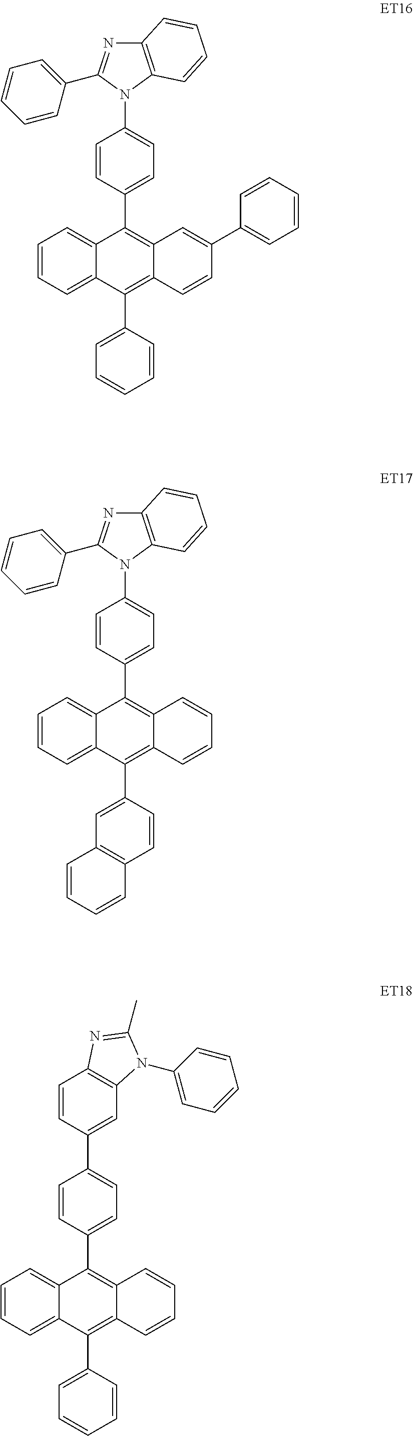 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

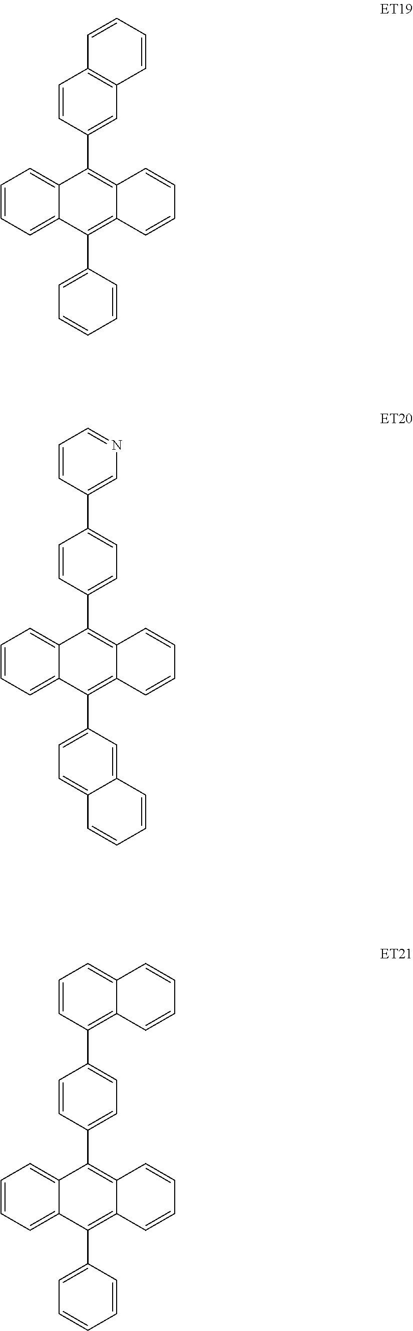

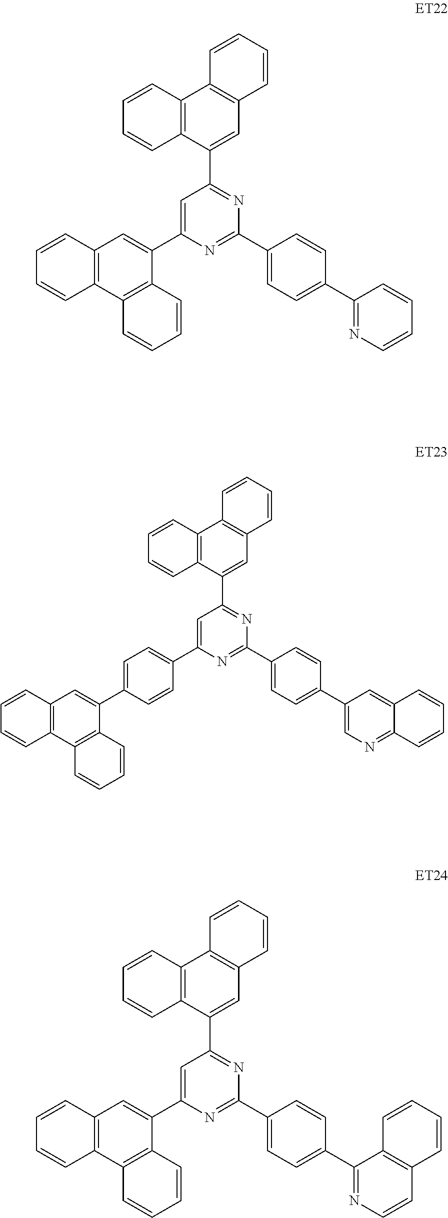 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

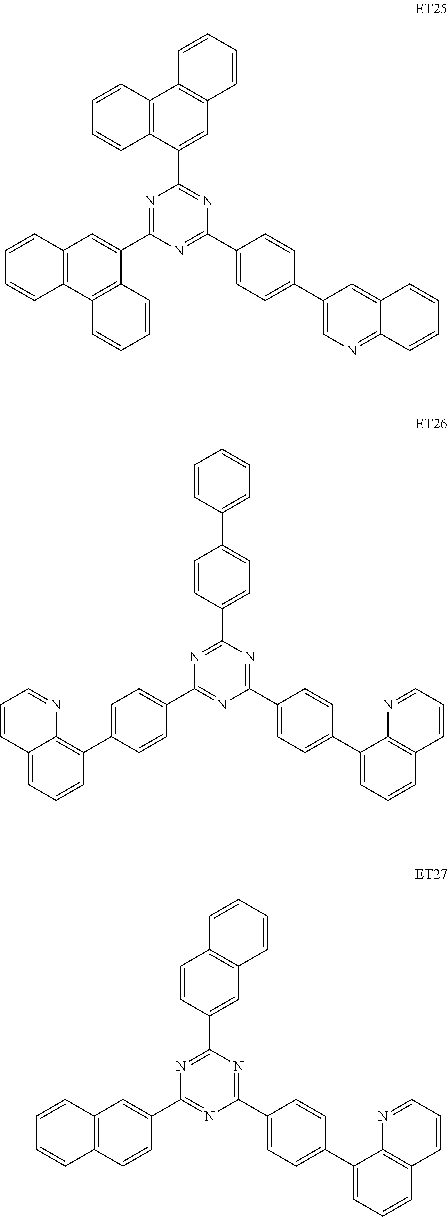 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

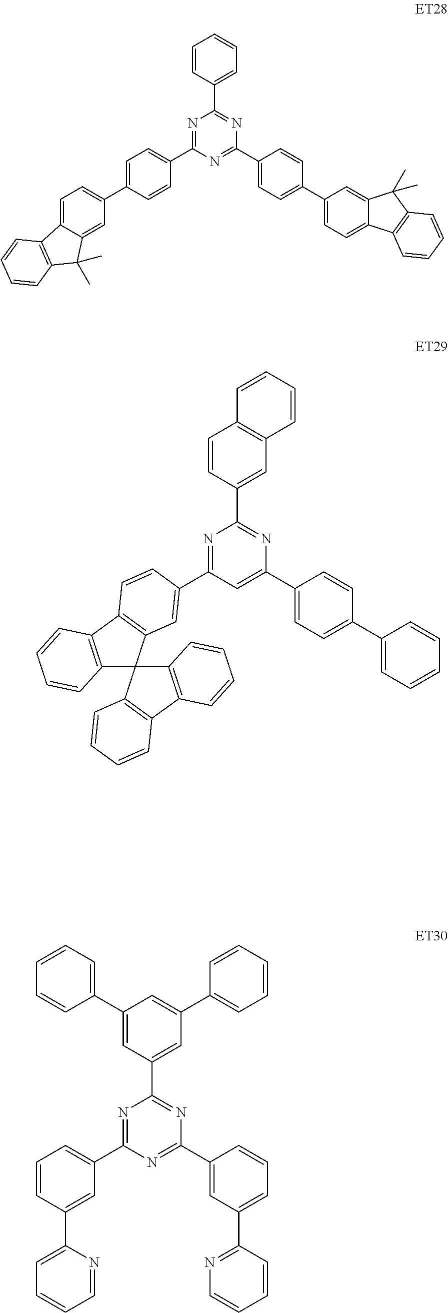 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

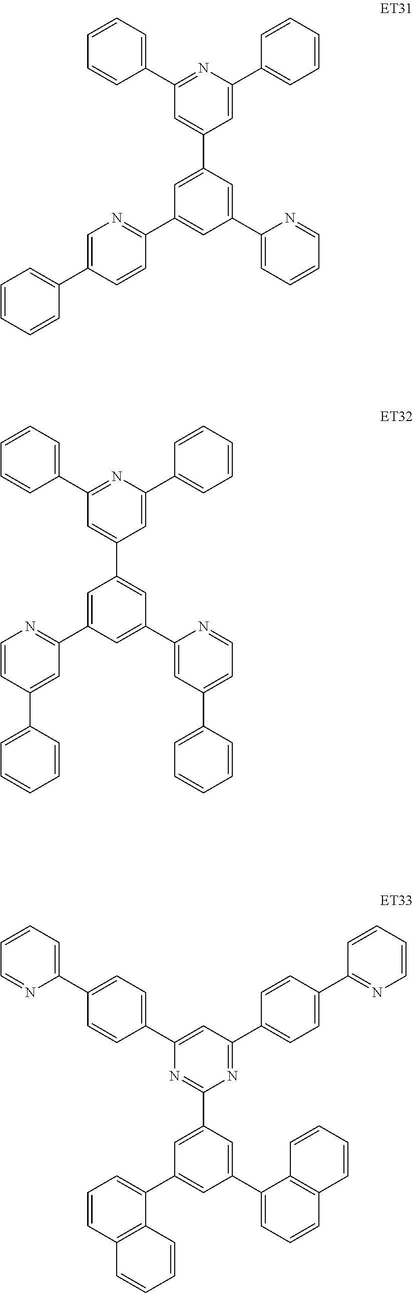 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

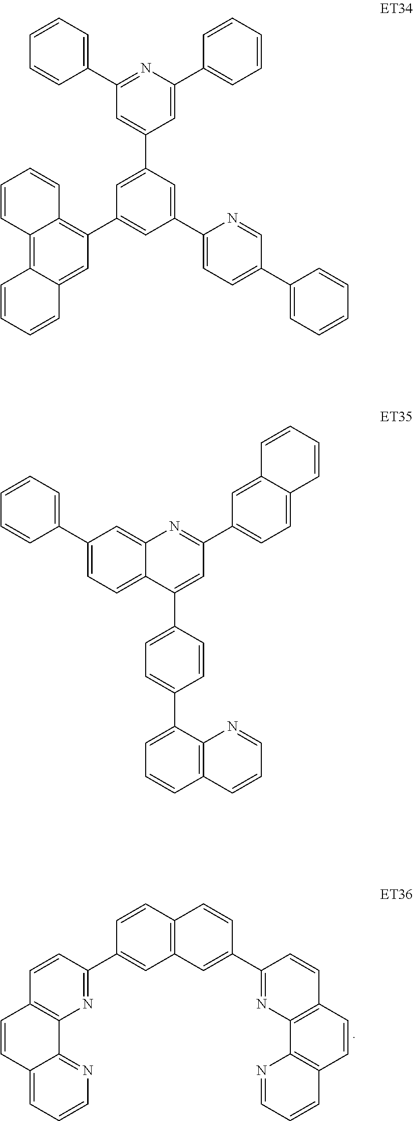 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In some embodiments, the electron transport regions ETR may include a metal halide such as LiF, NaCl, CsF, RbCl, RbI, CuI, and/or KI, a lanthanide metal such as Yb, and/or a co-deposited material of the metal halide and the lanthanide metal. For example, the electron transport region ETR may include KI:Yb, RbI:Yb, LiF:Yb, etc. as a co-deposited material. In some embodiments, the electron transport region ETR may be formed utilizing a metal oxide such as Li₂O and/or BaO, 8-hydroxyl-lithium quinolate (Liq), etc., but the embodiment of the present disclosure is not limited thereto. The electron transport region ETR may also be formed of a mixture material of an electron transport material and an insulating organometallic salt. The organometallic salt may be a material having an energy band gap of about 4 eV or more. For example, the organometallic salt may include, for example, a metal acetate, a metal benzoate, a metal acetoacetate, a metal acetylacetonate, and/or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but the embodiment of the present disclosure is not limited thereto.

The electron transport region ETR may include the above-described compounds of the electron transport region ETR in at least one of the electron injection layer EIL, the electron transport layer ETL, or the hole blocking layer HBL.

When the electron transport region ETR includes the electron transport layer ETL, the electron transport layer ETL may have a thickness of about 100 Å to about 1,000 Å, for example, about 150 Å to about 500 Å. When the thickness of the electron transport layer ETL satisfies the aforementioned ranges, satisfactory electron transport characteristics may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. When the thickness of the electron injection layer EIL satisfies the above-described ranges, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but the embodiment of the present disclosure is not limited thereto. For example, when the first electrode EL1 is an anode, the second electrode EL2 may be a cathode, and when the first electrode EL1 is a cathode, the second electrode EL2 may be an anode. The second electrode EL2 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more thereof, a mixture of two or more thereof, or an oxide thereof.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, Yb, W, a compound or mixture thereof (e.g., AgMg, AgYb, and/or MgYb). In some embodiments, the second electrode EL2 may have a multilayer structure including a reflective film or a transflective film formed of the above-described materials, and a transparent conductive film formed of ITO, IZO, ZnO, ITZO, etc. For example, the second electrode EL2 may include one or more of the above-described metal materials, combinations of two or more metal materials of the above-described metal materials, oxides of the above-described metal materials, and/or the like.

In some embodiments, the second electrode EL2 may be connected with an auxiliary electrode. When the second electrode EL2 is connected with the auxiliary electrode, the resistance of the second electrode EL2 may be decreased.

In some embodiments, a capping layer CPL may further be disposed on the second electrode EL2 of the light emitting element ED of an embodiment. The capping layer CPL may include a multilayer or a single layer.

In an embodiment, the capping layer CPL may be an organic layer or an inorganic layer. For example, when the capping layer CPL contains an inorganic material, the inorganic material may include an alkali metal compound (for example, LiF), an alkaline earth metal compound (for example, MgF₂), SiON, SiNₓ, SiO_{y}, etc.

For example, when the capping layer CPL contains an organic material, the organic material may include α-NPD, NPB, TPD, m-MTDATA, Alq₃, CuPc, N4,N4, N4′, N4′-tetra(biphenyl-4-yl)biphenyl-4,4′-diamine (TPD15), 4,4′,4″-tris(carbazol sol-9-yl)triphenylamine (TCTA), etc., or may include an epoxy resin, and/or an acrylate such as a methacrylate. However, the embodiment of the present disclosure is not limited thereto, and the capping layer CPL may include at least one of Compounds P1 to P5:

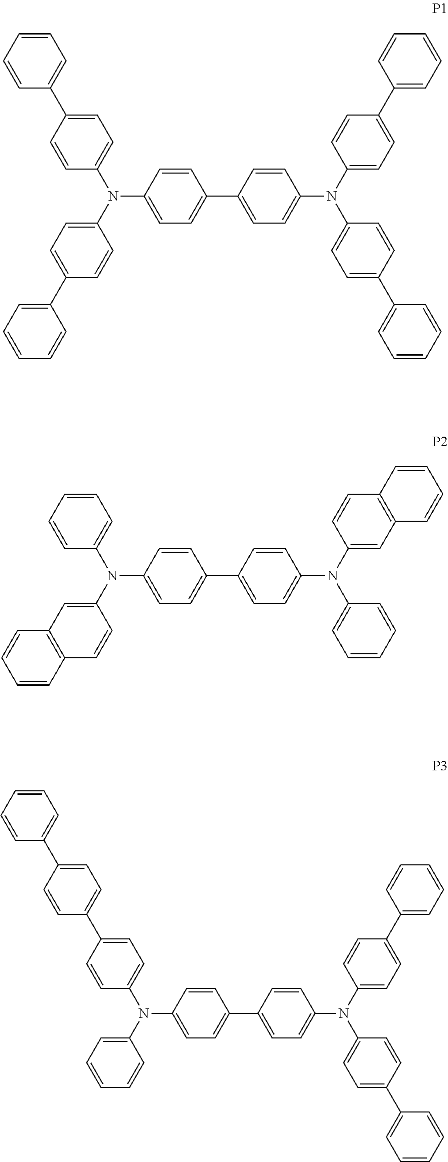 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

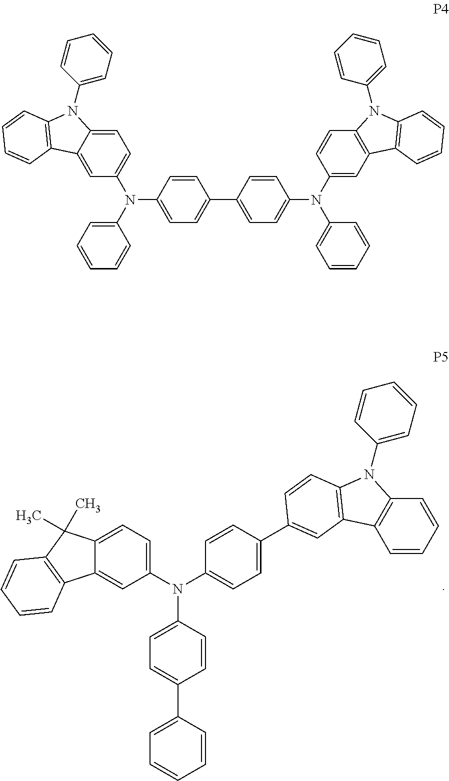 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or greater. For example, the refractive index of the capping layer CPL may be about 1.6 or greater with respect to light in a wavelength range of about 550 nm to about 660 nm.

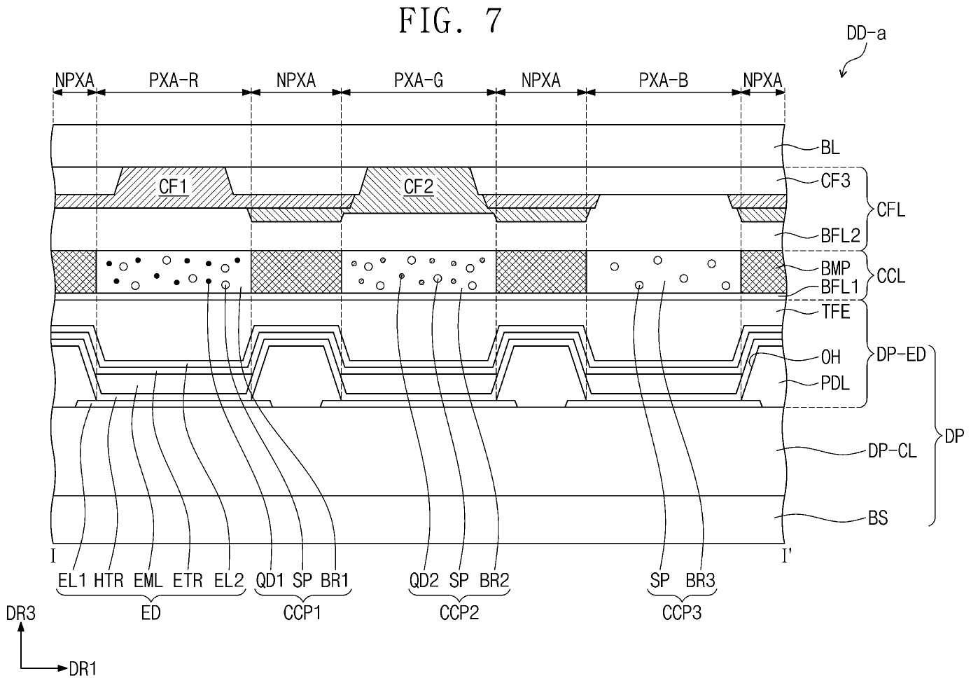

Each of FIGS. 7 to 10 is a cross-sectional view of a display device according to an embodiment of the present disclosure. Hereinafter, in describing the display devices of embodiments with reference to FIGS. 7 to 10, the duplicated features which have been described in FIGS. 1 to 6 are not described again, but their differences will be mainly described.

Referring to FIG. 7, the display device DD-a according to an embodiment may include a display panel DP including a display element layer DP-ED, a light control layer CCL disposed on the display panel DP, and a color filter layer CFL.

In an embodiment illustrated in FIG. 7, the display panel DP may include a base layer BS, a circuit layer DP-CL provided on the base layer BS, and the display element layer DP-ED, and the display element layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In some embodiments, the structures of the light emitting elements of FIGS. 3 to 6 as described above may be equally applied to the structure of the light emitting element ED illustrated in FIG. 7.

The emission layer EML of the light emitting element ED included in the display device DD-a according to an embodiment may include the above-described polycyclic compound of an embodiment.

Referring to FIG. 7, the emission layer EML may be disposed in an opening OH defined in a pixel definition layer PDL. For example, the emission layer EML which is divided by the pixel definition layer PDL and provided corresponding to each light emitting regions PXA-R, PXA-G, and PXA-B may be to emit light in substantially the same wavelength range. In the display device DD-a of an embodiment, the emission layer EML may be to emit blue light. In some embodiments, unlike the configuration illustrated, the emission layer EML may be provided as a common layer in the entire light emitting regions PXA-R, PXA-G, and PXA-B.

The light control layer CCL may be disposed on the display panel DP. The light control layer CCL may include a light conversion body. The light conversion body may be a quantum dot, a phosphor, and/or the like. The light conversion body may be to convert the wavelength of received light and emit the resulting light by converting the wavelength thereof. For example, the light control layer CCL may a layer containing the quantum dot or a layer containing the phosphor.

The light control layer CCL may include a plurality of light control parts CCP1, CCP2 and CCP3. The light control parts CCP1, CCP2, and CCP3 may be spaced apart from each other.

Referring to FIG. 7, divided patterns BMP may be disposed between the light control parts CCP1, CCP2 and CCP3 which are spaced apart from each other, but the embodiment of the present disclosure is not limited thereto. FIG. 7 illustrates that the divided patterns BMP do not overlap the light control parts CCP1, CCP2 and CCP3, but in some embodiments, at least a portion of the edges of the light control parts CCP1, CCP2 and CCP3 may overlap the divided patterns BMP.

The light control layer CCL may include a first light control part CCP1 containing a first quantum dot QD1 which converts a first color light provided from the light emitting element ED into a second color light, a second light control part CCP2 containing a second quantum dot QD2 which converts the first color light into a third color light, and a third light control part CCP3 which transmits the first color light.

In an embodiment, the first light control part CCP1 may provide red light that is the second color light, and the second light control part CCP2 may provide green light that is the third color light. The third light control part CCP3 may provide blue light by transmitting the blue light that is the first color light provided from the light emitting element ED. For example, the first quantum dot QD1 may be a red quantum dot, and the second quantum dot QD2 may be a green quantum dot. Quantum dots QD1 and QD2 may be the same as described above.

In some embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but may include the scatterer SP.

The scatterer SP may be inorganic particles. For example, the scatterer SP may include at least one of TiO₂, ZnO, Al₂O₃, SiO₂, or hollow sphere silica. The scatterer SP may include any one from among TiO₂, ZnO, Al₂O₃, SiO₂, and hollow sphere silica, or may be a mixture of two or more materials selected from among TiO₂, ZnO, Al₂O₃, SiO₂, and hollow sphere silica.

The first light control part CCP1, the second light control part CCP2, and the third light control part CCP3 each may include a corresponding one of the base resins BR1, BR2, and BR3 in which the quantum dots QD1 and/or QD2 and/or the scatterer SP are dispersed. In an embodiment, the first light control part CCP1 may include the first quantum dot QD1 and the scatterer SP dispersed in the first base resin BR1, the second light control part CCP2 may include the second quantum dot QD2 and the scatterer SP dispersed in the second base resin BR2, and the third light control part CCP3 may include the scatterer SP dispersed in the third base resin BR3. The base resins BR1, BR2, and BR3 are media in which the quantum dots QD1 and QD2 and the scatterer SP are dispersed, and may be formed of one or more suitable resin compositions, which may be generally referred to as a binder. For example, the base resins BR1, BR2, and BR3 may each independently be one or more of acrylic-based resins, urethane-based resins, silicone-based resins, epoxy-based resins, etc. The base resins BR1, BR2, and BR3 may each be transparent resins. In an embodiment, the first base resin BR1, the second base resin BR2, and the third base resin BR3 may each be the same as or different from each other.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may be disposed on the light control parts CCP1, CCP2, and CCP3 to block or reduce exposure of the light control parts CCP1, CCP2 and CCP3 from moisture/oxygen. In some embodiments, the barrier layer BFL1 may cover the light control parts CCP1, CCP2, and CCP3. In some embodiments, the barrier layer BFL2 may be provided between the light control parts CCP1, CCP2, and CCP3 and the color filter layer CFL (e.g., along the thickness direction).

The barrier layers BFL1 and BFL2 may include at least one inorganic layer. For example, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. In some embodiments, the barrier layers BFL1 and BFL2 may further include an organic film. The barrier layers BFL1 and BFL2 may be formed of a single layer or a plurality of layers.

In the display device DD-a of an embodiment, the color filter layer CFL may be disposed on the light control layer CCL. For example, the color filter layer CFL may be directly disposed on the light control layer CCL. In this case, the barrier layer BFL2 may not be provided.

The color filter layer CFL may include filters CF1, CF2, and CF3. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment and/or dye. The first filter CF1 may include a red pigment and/or dye, the second filter CF2 may include a green pigment and/or dye, and the third filter CF3 may include a blue pigment and/or dye. The embodiment of the present disclosure is not limited thereto, and the third filter CF3 may not include (e.g., may exclude) any pigment or dye. The third filter CF3 may include a polymeric photosensitive resin and may not include (e.g., may exclude) any pigment or dye. The third filter CF3 may be transparent. The third filter CF3 may be formed of a transparent photosensitive resin.

Furthermore, in an embodiment, the first filter CF1 and the second filter CF2 may each be a yellow filter. The first filter CF1 and the second filter CF2 may not be separated but be provided as one filter. The first to third filters CF1, CF2, and CF3 may be disposed corresponding to the red light emitting region PXA-R, the green light emitting region PXA-G, and the blue light emitting region PXA-B, respectively.

In some embodiments, although not shown, the color filter layer CFL may include a light shielding part. The color filter layer CFL may include a light shielding part disposed to overlap at the boundaries of neighboring filters CF1, CF2, and CF3. The light shielding part may be a black matrix. The light shielding part may include an organic light shielding material and/or an inorganic light shielding material containing a black pigment and/or dye. The light shielding part may separate boundaries between the adjacent filters CF1, CF2, and CF3. In some embodiments, the light shielding part may be formed of a blue filter.

A base substrate BL may be disposed on the color filter layer CFL. The base substrate BL may be a member which provides a base surface in which the color filter layer CFL, the light control layer CCL, and/or the like are disposed. The base substrate BL may be a glass substrate, a metal substrate, a plastic substrate, etc. However, the embodiment of the present disclosure is not limited thereto, and the base substrate BL may be an inorganic layer, an organic layer, or a composite material layer (e.g., a composite material layer including an inorganic material and an organic material). In some embodiments, unlike the configuration illustrated, the base substrate BL may not be provided.

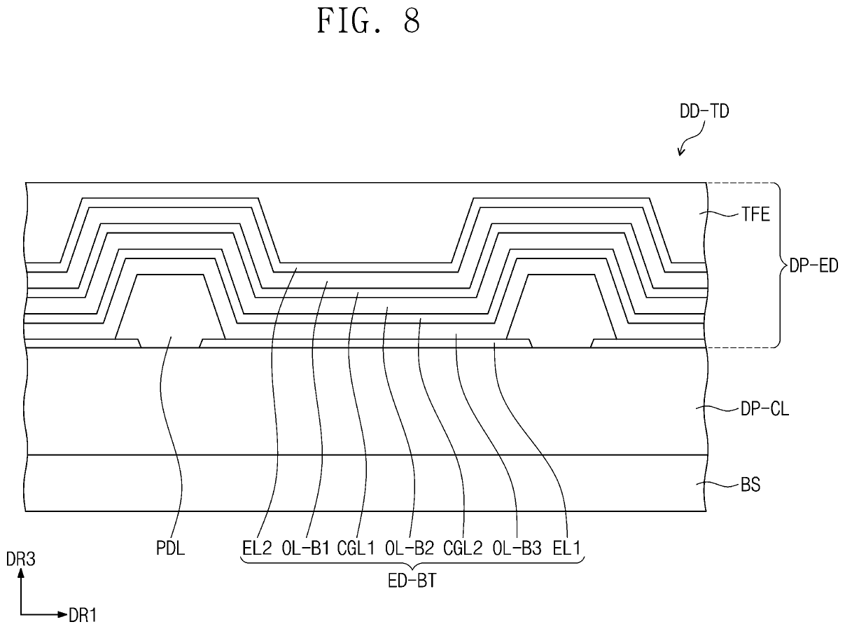

FIG. 8 is a cross-sectional view illustrating a portion of a display device according to an embodiment of the present disclosure. FIG. 8 illustrates a cross-sectional view of a part corresponding to the display panel DP of FIG. 7. In the display device DD-TD of an embodiment, the light emitting element ED-BT may include a plurality of light emitting structures OL-B1, OL-B2, and OL-B3. The light emitting element ED-BT may include a first electrode EL1 and a second electrode EL2 which face each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 7) and a hole transport region HTR and an electron transport region ETR disposed with the emission layer EML (FIG. 7) located therebetween.

For example, the light emitting element ED-BT included in the display device DD-TD of an embodiment may be a light emitting element having a tandem structure and including a plurality of emission layers EML.

In an embodiment illustrated in FIG. 8, lights (e.g., light beams) respectively emitted from the light emitting structures OL-B1, OL-B2, and OL-B3 may all be blue lights. However, the embodiment of the present disclosure is not limited thereto, and the lights (e.g., light beams) respectively emitted from the light emitting structures OL-B1, OL-B2, and OL-B3 may have wavelength ranges different from each other. For example, the light emitting element ED-BT including the plurality of light emitting structures OL-B1, OL-B2, and OL-B3 which emit lights (e.g., light beams) having wavelength ranges different from each other may be to emit white light.

Charge generation layers CGL1 and CGL2 may be respectively disposed between two of the neighboring light emitting structures OL-B1, OL-B2, and OL-B3. The charge generation layers CGL1 and CGL2 may include a p-type or kind charge generation layer (e.g., a P-charge generation layer) and/or an n-type or kind charge generation layer (e.g., a N-charge generation layer).

At least one from among the light emitting structures OL-B1, OL-B2, and OL-B3 included in the display device DD-TD of an embodiment may include the above-described polycyclic compound of an embodiment. For example, at least one from among the plurality of emission layers included in the light emitting element ED-BT may include the polycyclic compound of an embodiment.

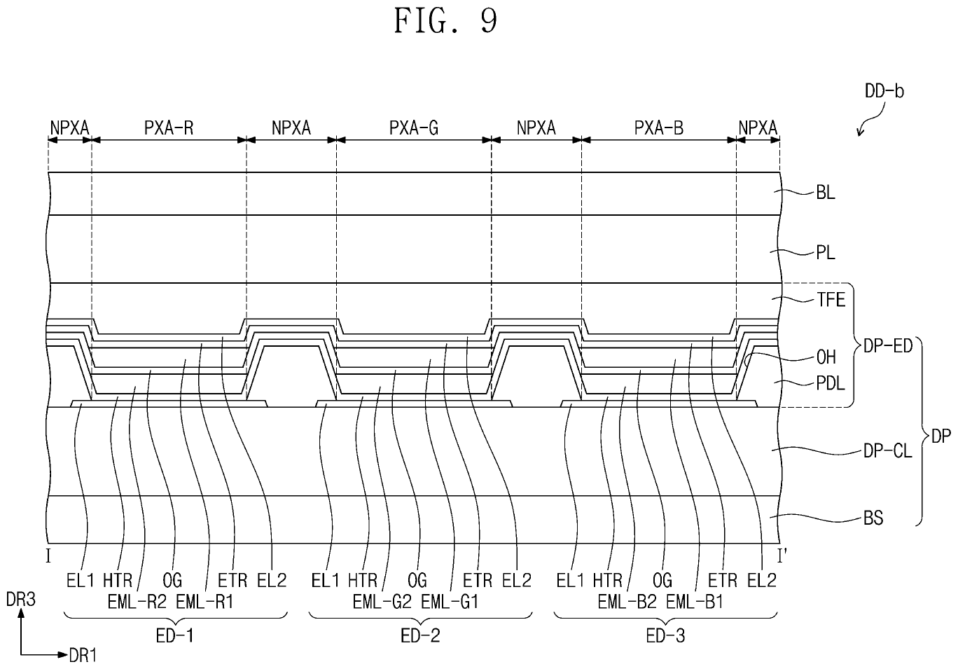

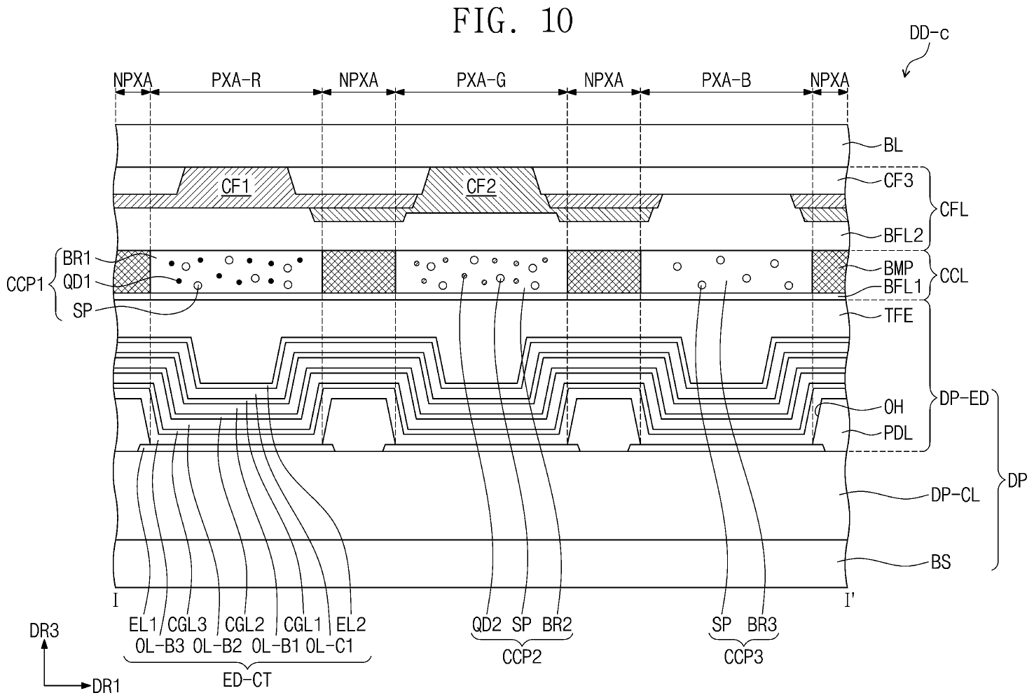

Referring to FIG. 9, the display device DD-b according to an embodiment may include light emitting elements ED-1, ED-2, and ED-3 in each of which two emission layers are stacked. Compared with the display device DD of an embodiment illustrated in FIG. 2, the embodiment illustrated in FIG. 9 is different in that the first to third light emitting elements ED-1, ED-2, and ED-3 each include two emission layers stacked in the thickness direction. In each of the first to third light emitting elements ED-1, ED-2, and ED-3, the two emission layers may be to emit lights in substantially the same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. In addition, the third light emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. For example, the emission auxiliary part OG may include an electron transport region, a charge generation layer, and a hole transport region that are sequentially stacked in the stated order. The emission auxiliary part OG may be provided as a common layer in the whole (e.g., all) of the first to third light emitting elements ED-1, ED-2, and ED-3. However, the embodiment of the present disclosure is not limited thereto, and the emission auxiliary part OG may be provided by being patterned within the openings OH defined in the pixel definition layer PDL.

The first red emission layer EML-R1, the first green emission layer EML-G1, and the first blue emission layer EML-B1 may be disposed between the electron transport region ETR and the emission auxiliary part OG. The second red emission layer EML-R2, the second green emission layer EML-G2, and the second blue emission layer EML-B2 may be disposed between the emission auxiliary part OG and the hole transport region HTR.

For example, the first light emitting element ED-1 may include the first electrode EL1, the hole transport region HTR, the second red emission layer EML-R2, the emission auxiliary part OG, the first red emission layer EML-R1, the electron transport region ETR, and the second electrode EL2 that are sequentially stacked in the stated order. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked in the stated order. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked in the stated order.

In some embodiments, an optical auxiliary layer PL may be disposed on the display element layer DP-ED. The optical auxiliary layer PL may include a polarizing layer. The optical auxiliary layer PL may be disposed on the display panel DP and control reflected light in the display panel DP due to external light. Unlike the configuration illustrated, the optical auxiliary layer PL in the display device according to an embodiment may not be provided.

At least one emission layer included in the display device DD-b of an embodiment illustrated in FIG. 9 may include the above-described polycyclic compound of an embodiment. For example, in an embodiment, at least one of the first blue emission layer EML-B1 or the second blue emission layer EML-B2 may include the polycyclic compound of an embodiment.

Unlike FIGS. 8 and 9, FIG. 10 illustrates that a display device DD-c includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are sequentially stacked in the stated order in the thickness direction between the first electrode EL1 and the second electrode EL2. Charge generation layers CGL1, CGL2, and CGL3 may respectively be disposed between the first to fourth light emitting structures OL-B1, OL-B2, OL-B3, and OL-C1. Among the four light emitting structures, the first to third light emitting structures OL-B1, OL-B2, and OL-B3 may be to emit blue lights, and the fourth light emitting structure OL-C1 may be to emit green light. However, the embodiment of the present disclosure is not limited thereto, and the first to fourth light emitting structures OL-B1, OL-B2, OL-B3, and OL-C1 may be to emit lights (e.g., light beams) in different wavelength regions.

The charge generation layers CGL1, CGL2, and CGL3 disposed between adjacent light emitting structures OL-B1, OL-B2, OL-B3, and OL-C1 may each include a p-type or kind charge generation layer and/or an n-type or kind charge generation layer.

At least one from among the light emitting structures OL-B1, OL-B2, OL-B3, and OL-C1 included in the display device DD-c of an embodiment may include the above-described polycyclic compound of an embodiment. For example, in an embodiment, at least one from among the first to third light emitting elements OL-B1, OL-B2, and OL-B3 may include the described-above polycyclic compound of an embodiment.

The light emitting element ED according to an embodiment of the present disclosure may include the above-described polycyclic compound of an embodiment in at least one functional layer disposed between the first electrode EL1 and the second electrode EL2, thereby exhibiting an improved service life characteristic. For example, the polycyclic compound according to an embodiment may be included in the emission layer EML of the light emitting element ED of an embodiment, and the light emitting element of an embodiment may exhibit a long service life characteristic.

The above-described polycyclic compound of an embodiment includes the nitrogen-containing polycyclic group having at least eight ring-forming carbon atoms, which has a steric shielding effect, to have high stability, thereby exhibiting an increased service life characteristic. In addition, the polycyclic compound of an embodiment includes a fused ring containing a boron atom and the nitrogen-containing polycyclic group serving as a donor part, and thus may be utilized as a thermally activated delayed fluorescence dopant material, thereby increasing the luminous efficiency.

Hereinafter, with reference to Examples and Comparative Examples, a polycyclic compound according to an embodiment of the present disclosure and a light emitting element of an embodiment of the present disclosure will be described in more detail. In addition, Examples described below are only illustrations to assist the understanding of the present disclosure, and the scope of the present disclosure is not limited thereto.

### EXAMPLES

### 1. Synthesis of Polycyclic Compound

First, a synthetic method of the polycyclic compound according to the current embodiment will be described in more detail by illustrating synthetic methods of Compounds 2, 5, 72, 108, 185, 215, 216, 217, 221, 226, and 235. In addition, in the following descriptions, the synthetic methods of the polycyclic compounds are provided as examples, but the synthetic method according to an embodiment of the present disclosure is not limited to these Examples.

### (1) Synthesis of Compound 2

Polycyclic Compound 2 according to an example may be synthesized by, for example, the steps (acts) shown in Reaction Scheme 1:

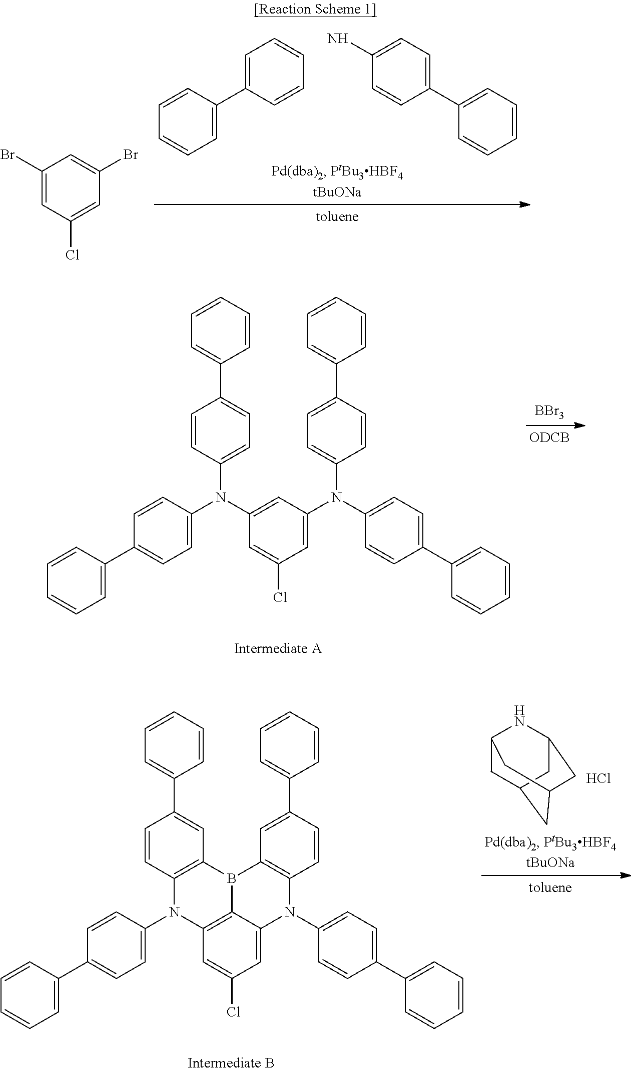

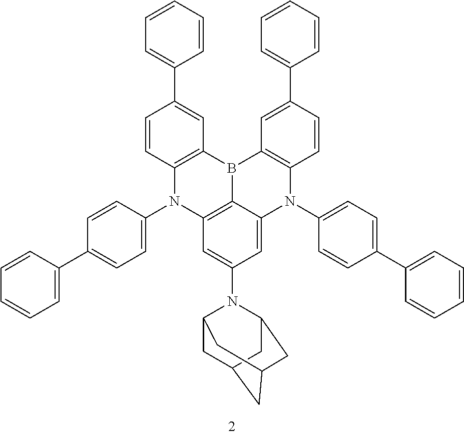 [SMILES: c1ccc(-c2ccc(N3c4ccc(-c5ccccc5)cc4B4c5cc(-c6ccccc6)ccc5N(c5ccc(-c6ccccc6)cc5)c5cc(N6C7CC8CC(C7)CC6C8)cc3c54)cc2)cc1]

### Synthesis of Intermediate A

In a flask in an argon (Ar) atmosphere, 1,3-dibromo-5-chlorobenzene (7.0 g, 25.9 mmol), bis(4-biphenylyl)amine (16.6 g, 51.8 mmol), Pd(dba)₂ (1.49 g, 2.59 mmol), P^{t}Bu₃·HBF₄ (1.50 g, 5.18 mmol), and tBuONa (5.72 g, 59.6 mmol) were added to 130 mL of toluene, and the resulting mixture was heated and stirred at about 80° C. for about 2 hours. Water was added to the reactant, and the resultant mixture was subjected to celite filtering and then liquid separation to concentrate an organic layer. Then, the concentrated organic layer was purified by silica gel column chromatography to obtain Intermediate A (17.1 g, yield 88%).

By measuring FAB-MS, a mass number of m/z=751 was observed by molecular ion peak, thereby identifying Intermediate A.

### Synthesis of Intermediate B

In a flask in an Ar atmosphere, Intermediate A (15.0 g, 20.0 mmol) was dissolved in 1,2-dichlorobenzene (ODCB, 200 mL), BBr₃ (12.5 g, 49.9 mmol) was added thereto, and the resulting mixture was heated and stirred at about 170° C. for about 10 hours. Then, the resulting mixture was cooled to room temperature, N,N-diisopropylethylamine (30.9 g, 240 mmol) and water were added thereto, and the resultant mixture was subjected to celite filtering and then liquid separation to concentrate an organic layer. The concentrated organic layer was purified by silica gel column chromatography to obtain Intermediate Compound B (5.30 g, yield 35%). By measuring FAB-MS, a mass number of m/z=759 was observed by molecular ion peak, thereby identifying Intermediate B.

### Synthesis of Compound 2

In a flask in an Ar atmosphere, Intermediate B (4.50 g, 5.93 mmol), 2-azaadamantane hydrochloride (2.48 g, 7.71 mmol), Pd(dba)₂ (341 mg, 0.590 mmol), P^{t}Bu₃·HBF₄ (344 mg, 1.19 mmol), and tBuONa (1.31 g, 13.6 mmol) were added to 100 mL of toluene, and the resulting mixture was heated and stirred at about 80° C. for about 2 hours. Then, water was added to the reactant, and the resultant mixture was subjected to celite filtering and then liquid separation to concentrate an organic layer. The concentrated organic layer was purified by silica gel column chromatography to obtain Compound 2 (4.33 g, yield 85%). By measuring FAB-MS, a mass number of m/z=859 was observed by molecular ion peak, thereby identifying Compound 2. Thereafter, the obtained Compound 2 was subjected to sublimation purification (340° C., 2.5×10⁻³ Pa) and was utilized to evaluate a device.

### (2) Synthesis of Compound 5

Polycyclic Compound 5 according to an example may be synthesized by, for example, the steps (acts) shown in Reaction Scheme 2:

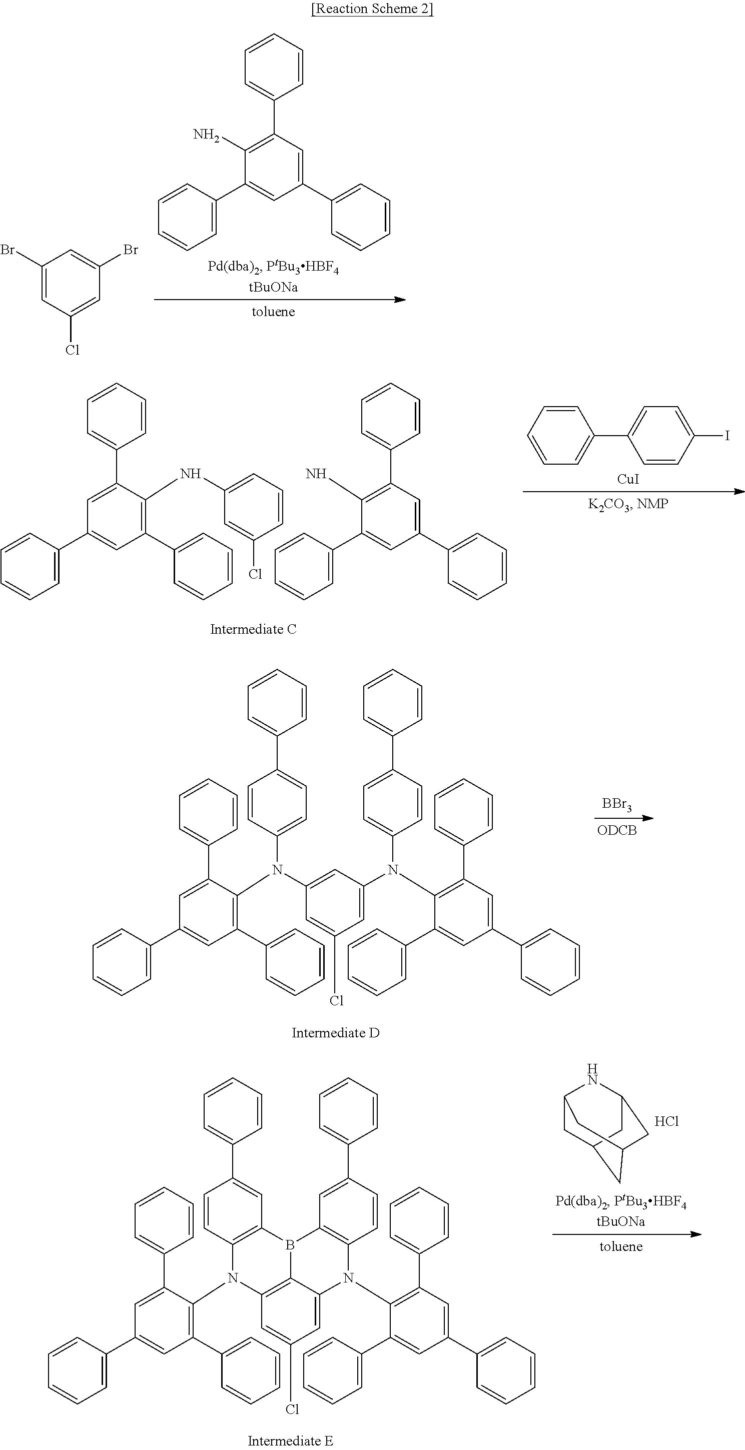

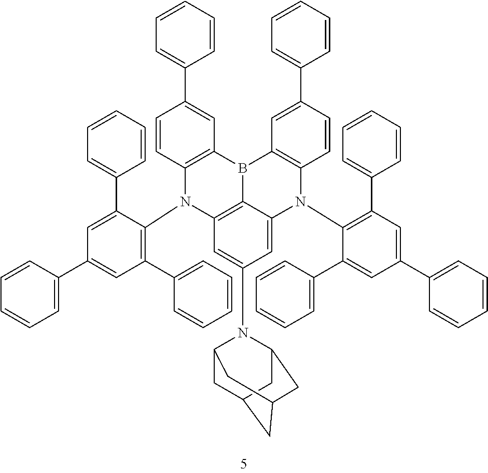 [SMILES: c1ccc(-c2ccc3c(c2)B2c4cc(-c5ccccc5)ccc4N(c4c(-c5ccccc5)cc(-c5ccccc5)cc4-c4ccccc4)c4cc(N5C6CC7CC(C6)CC5C7)cc(c42)N3c2c(-c3ccccc3)cc(-c3ccccc3)cc2-c2ccccc2)cc1]

### Synthesis of Intermediate C

In a flask in an Ar atmosphere, 1,3-dibromo-5-chlorobenzene (8.0 g, 35.4 mmol), 2,4,6-triphenylaniline (19.0 g, 59.2 mmol), Pd(dba)₂ (1.70 g, 2.96 mmol), P^{t}Bu₃·HBF₄ (1.72 g, 5.92 mmol), and tBuONa (6.54 g, 68.1 mmol) were added to 150 mL of toluene, and the resulting mixture was heated and stirred at about 80° C. for about 2 hours. Then, water was added to the reactant, and the resultant mixture was subjected to celite filtering and then liquid separation to concentrate an organic layer. The concentrated organic layer was purified by silica gel column chromatography to obtain Intermediate C (19.3 g, yield 87%). By measuring FAB-MS, a mass number of m/z=751 was observed by molecular ion peak, thereby identifying Intermediate C.

### Synthesis of Intermediate D

In a flask in an Ar atmosphere, 1-methyl-2-pyrrolidone (NMP, 150 mL) was added to Intermediate C (14.0 g, 17.5 mmol), 4-iodobiphenyl (62.5 g, 262 mmol), CuI (6.99 g, 36.7 mmol), and K₂CO₃ (19.3 g, 140 mmol), and the resulting mixture was heated for 24 hours while the exterior temperature is maintained at about 215° C. Then, the resulting mixture was diluted with CH₂Cl₂, water was added thereto, and the resultant mixture was subjected to celite filtering and then liquid separation to concentrate an organic layer. The concentrated organic layer was purified by silica gel column chromatography to obtain Intermediate D (18.5 g, yield 70%). By measuring FAB-MS, a mass number of m/z=1055 was observed by molecular ion peak, thereby identifying Intermediate D.

### Synthesis of Intermediate E

In a flask in an Ar atmosphere, Intermediate D (17.0 g, 16.1 mmol) was dissolved in 1,2-dichlorobenzene (ODCB, 200 mL), BBr₃ (10.1 g, 40.3 mmol) was added thereto, and the resulting mixture was heated and stirred at about 170° C. for about 10 hours. The resulting mixture was cooled to room temperature, N,N-diisopropylethylamine (24.9 g, 193 mmol) and water were added thereto, and the resultant mixture was subjected to celite filtering and then liquid separation to concentrate an organic layer. The concentrated organic layer was purified by silica gel column chromatography to obtain Intermediate E (5.48 g, yield 32%). By measuring FAB-MS, a mass number of m/z=1063 was observed by molecular ion peak, thereby identifying Intermediate E.

### Synthesis of Compound 5

In a flask in an Ar atmosphere, Intermediate E (4.50 g, 4.23 mmol), 2-azaadamantane hydrochloride (0.955 g, 5.50 mmol), Pd(dba)₂ (243 mg, 0.42 mmol), P^{t}Bu₃·HBF₄ (246 mg, 0.85 mmol), and tBuONa (0.935 g, 9.73 mmol) were added to 50 mL of toluene, and the resulting mixture was heated and stirred at about 80° C. for about 2 hours. Water was added to the reactant, and the resultant mixture was subjected to celite filtering and then liquid separation to concentrate an organic layer. The concentrated organic layer was purified by silica gel column chromatography to obtain Compound 5 (3.94 g, yield 80%). By measuring FAB-MS, a mass number of m/z=1164 was observed by molecular ion peak, thereby identifying Compound 5. Thereafter, the obtained Compound 5 was subjected to sublimation purification (380° C., 2.7×10⁻³ Pa) and was utilized to evaluate a device.

### (3) Synthesis of Compound 72

Polycyclic Compound 72 according to an example may be synthesized by, for example, the steps (acts) shown in Reaction Scheme 3:

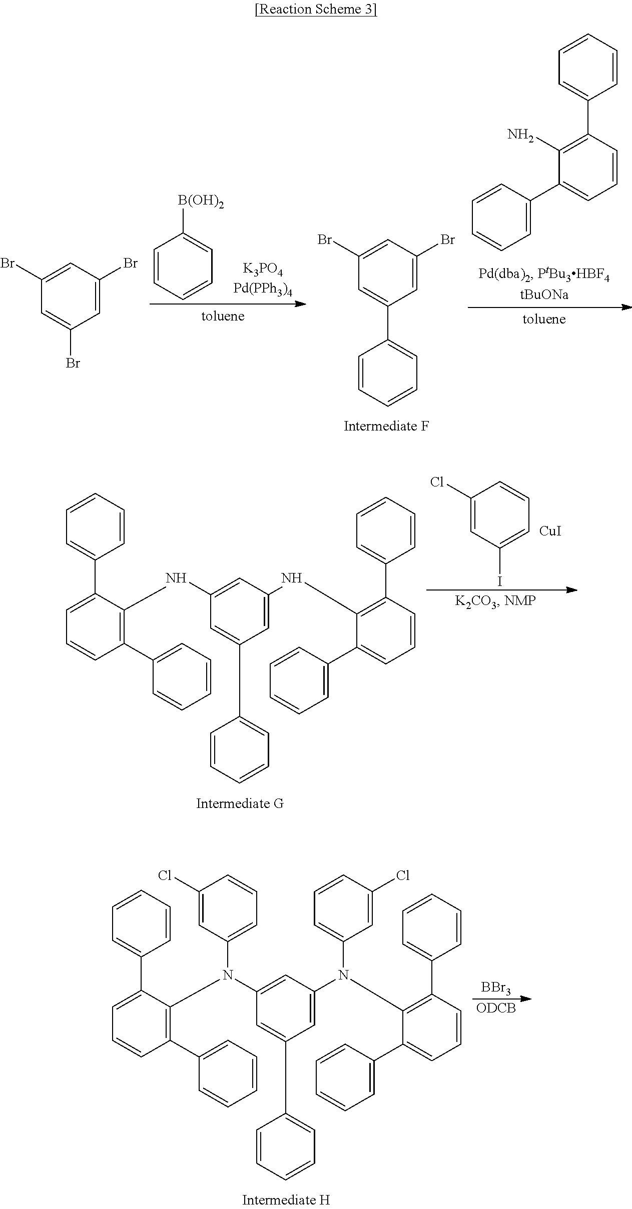

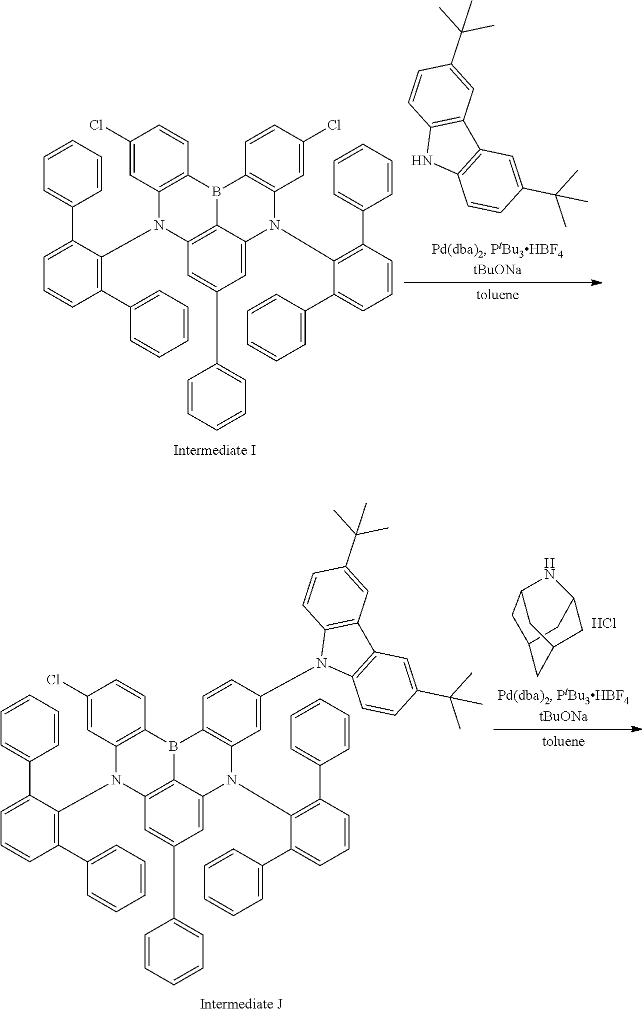

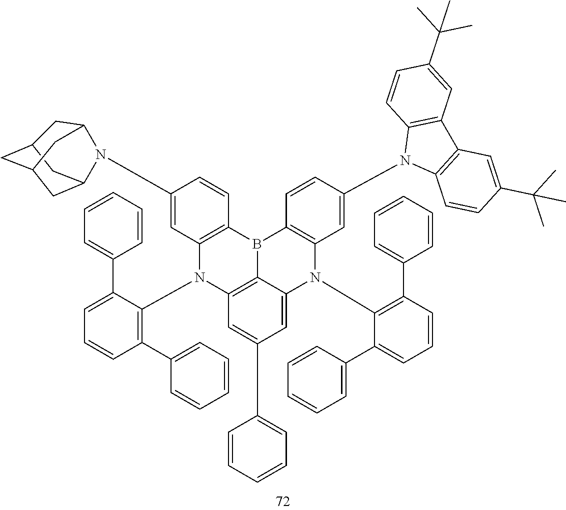 [SMILES: CC(C)(C)c1ccc2c(c1)c1cc(C(C)(C)C)ccc1n2-c1ccc2c(c1)N(c1c(-c3ccccc3)cccc1-c1ccccc1)c1cc(-c3ccccc3)cc3c1B2c1ccc(N2C4CC5CC(C4)CC2C5)cc1N3c1c(-c2ccccc2)cccc1-c1ccccc1]

### Synthesis of Intermediate F

In a flask in an Ar atmosphere, 1,3,5-tribromobenzene (15.0 g, 47.7 mmol), phenylboronic acid (8.71 g, 71.5 mmol), Pd(PPh₃)₄ (5.51 g, 4.77 mmol), and K₃PO₄ (20.2 g, 95.2 mmol) were added to 100 mL of Toluene, and the resulting mixture was reacted at about 80° C. for about 6 hours. Then, the resulting mixture was cooled and water was added thereto, and the resultant mixture was subjected to celite filtering and then liquid separation to concentrate an organic layer. The concentrated organic layer was purified by silica gel column chromatography to obtain Intermediate F (11.2 g, yield 75%). By measuring FAB-MS, a mass number of m/z=312 was observed by molecular ion peak, thereby identifying Intermediate F.

### Synthesis of Intermediate G

In a flask in an Ar atmosphere, Intermediate F (10.0 g, 32.1 mmol), 2,6-diphenylaniline (16.1 g, 65.7 mmol), Pd(dba)₂ (1.84 g, 3.21 mmol), P^{t}Bu₃·HBF₄ (1.85 g, 6.41 mmol), and tBuONa (7.08 g, 73.7 mmol) were added to 160 mL of toluene, and the resulting mixture was heated and stirred at about 80° C. for about 2 hours. Then, water was added to the reactant, and the resultant mixture was subjected to celite filtering and then liquid separation to concentrate an organic layer. The concentrated organic layer was purified by silica gel column chromatography to obtain Intermediate G (16.8 g, yield 82%). By measuring FAB-MS, a mass number of m/z=640 was observed by molecular ion peak, thereby identifying Intermediate G.

### Synthesis of Intermediate H

In a flask in an Ar atmosphere, about 10 mL of toluene was added to Intermediate G (14.0 g, 21.9 mmol), 3-chloro-1-iodebenzen (78.1 g, 327 mmol), CuI (8.74 g, 45.9 mmol), and K₂CO₃ (24.2 g, 175 mmol), and the resulting mixture was heated for 24 hours while the exterior temperature is maintained at about 215° C. Then, the resulting mixture was diluted with CH₂Cl₂, water was added thereto, and the resultant mixture was subjected to celite filtering and then liquid separation to concentrate an organic layer. The concentrated organic layer was purified by silica gel column chromatography to obtain Intermediate H (13.9 g, yield 74%). By measuring FAB-MS, a mass number of m/z=861 was observed by molecular ion peak, thereby identifying Intermediate H.

### Synthesis of Intermediate I

In a flask in an Ar atmosphere, Intermediate H (12.0 g, 13.9 mmol) was dissolved in 1,2-dichlorobenzene (ODCB, 140 mL), BBr₃ (8.8 g, 34.8 mmol) was added thereto, and the resulting mixture was heated and stirred at about 170° C. for about 10 hours. The resulting mixture was cooled to room temperature, N,N-diisopropylethylamine (21.6 g, 167 mmol) and water were added thereto, and the resultant mixture was subjected to celite filtering and then liquid separation to concentrate an organic layer. The concentrated organic layer was purified by silica gel column chromatography to obtain Intermediate I (3.03 g, yield 25%). By measuring FAB-MS, a mass number of m/z=869 was observed by molecular ion peak, thereby identifying Intermediate I.

### Synthesis of Intermediate J

In a flask in an Ar atmosphere, Intermediate I (2.80 g, 3.22 mmol), 3,6-Di-tert-butylcarbazole (1.17 g, 4.19 mmol), Pd(dba)₂ (185 mg, 0.32 mmol), P^{t}Bu₃·HBF₄ (187 mg, 0.64 mmol), and tBuONa (712 mg, 7.40 mmol) were added to 25 mL of toluene, and the resulting mixture was heated and stirred at about 80° C. for about 2 hours. Then, water was added to the reactant, and the resultant mixture was subjected to celite filtering and then liquid separation to concentrate an organic layer. The concentrated organic layer was purified by silica gel column chromatography to obtain Intermediate J (3.22 g, yield 90%). By measuring FAB-MS, a mass number of m/z=1112 was observed by molecular ion peak, thereby identifying Intermediate J.

### Synthesis of Compound 72

In a flask in an Ar atmosphere, Intermediate J (3.00 g, 2.70 mmol), 2-azaadamantane hydrochloride (609 mg, 3.51 mmol), Pd(dba)₂ (155 mg, 0.27 mmol), P^{t}Bu₃·HBF₄ (157 mg, 0.54 mmol), and tBuONa (596 mg, 6.2 mmol) were added to 25 mL of toluene, and the resulting mixture was heated and stirred at about 80° C. for about 2 hours. Then, water was added to the reactant, and the resultant mixture was subjected to celite filtering and then liquid separation to concentrate an organic layer. The concentrated organic layer was purified by silica gel column chromatography to obtain Compound 72 (2.87 g, yield 88%). By measuring FAB-MS, a mass number of m/z=1213 was observed by molecular ion peak, thereby identifying Compound 72. The obtained Compound 72 was subjected to sublimation purification (350° C., 2.1×10⁻³ Pa) and was utilized to evaluate a device.

### (4) Synthesis of Compound 108

Polycyclic Compound 108 according to an example may be synthesized by, for example, the steps (acts) shown in Reaction Scheme 4:

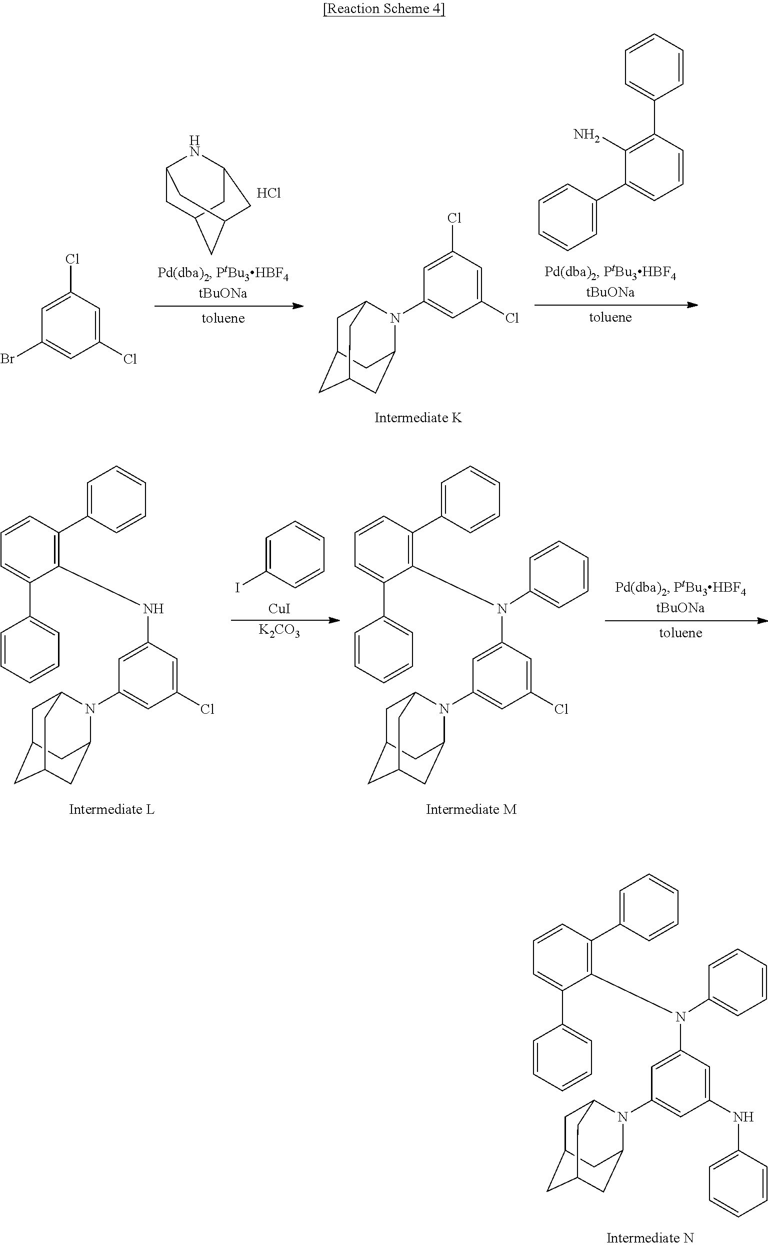

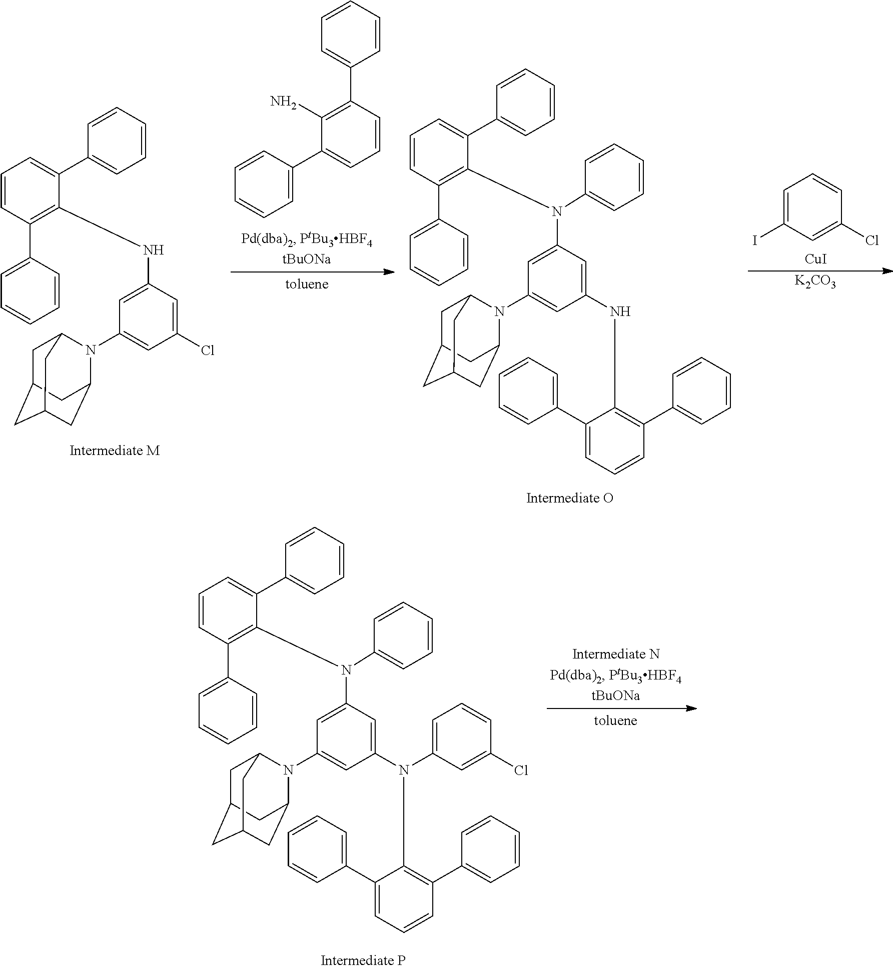

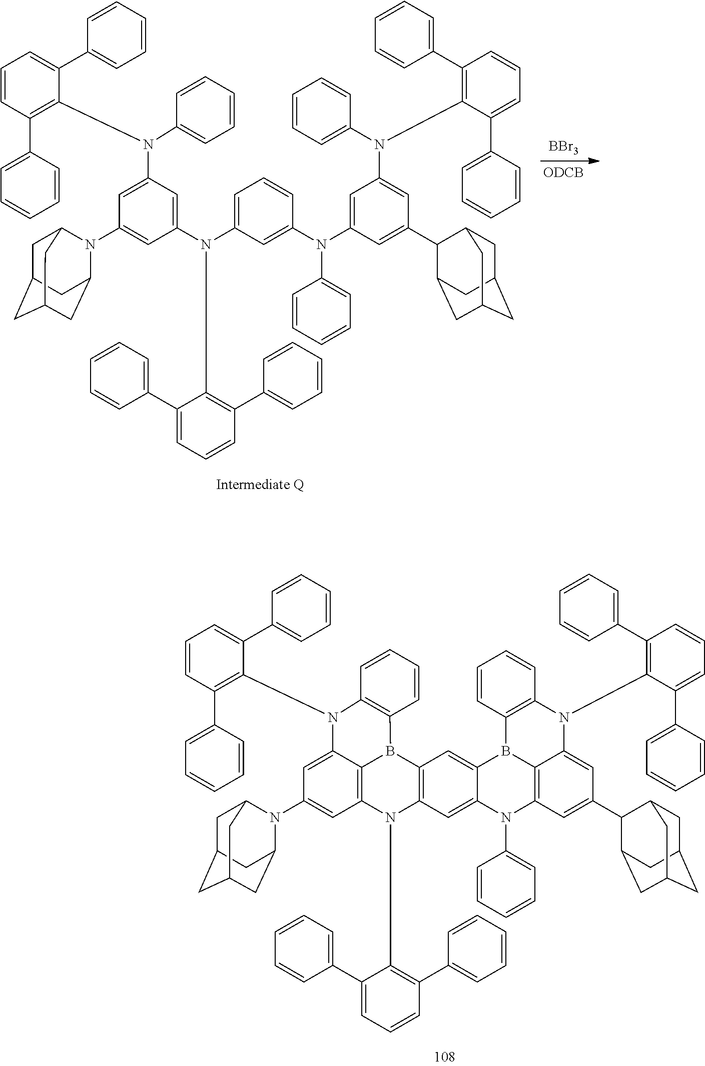

### Synthesis of Intermediate K

In a flask in an Ar atmosphere, 1-bromo-3,5-dichlorobenzene (15.0 g, 66.4 mmol), 2-azaadamantane hydrochloride (15.0 g, 86.3 mmol), Pd(dba)₂ (3.81 g, 6.64 mmol), P^{t}Bu₃·HBF₄ (3.85 g, 13.3 mmol), and tBuONa (14.7 g, 153 mmol) were added to 330 mL of toluene, and the resulting mixture was heated and stirred at about 80° C. for about 2 hours. Then, water was added to the reactant, and the resultant mixture was subjected to celite filtering and then liquid separation to concentrate an organic layer. The concentrated organic layer was purified by silica gel column chromatography to obtain Intermediate K (13.5 g, yield 72%). By measuring FAB-MS, a mass number of m/z=282 was observed by molecular ion peak, thereby identifying Intermediate K.

### Synthesis of Intermediate L

In a flask in an Ar atmosphere, Intermediate K (12.0 g, 42.5 mmol), 2,6-diphenylaniline (13.56 g, 55.3 mmol), Pd(dba)₂ (2.45 g, 4.25 mmol), P^{t}Bu₃·HBF₄ (2.47 g, 8.50 mmol), and tBuONa (9.40 g, 97.8 mmol) were added to 250 mL of toluene, and the resulting mixture was heated and stirred at about 80° C. for about 2 hours. Then, water was added to the reactant, and the resultant mixture was subjected to celite filtering and then liquid separation to concentrate an organic layer. The concentrated organic layer was purified by silica gel column chromatography to obtain Intermediate L (15.5 g, yield 74%). By measuring FAB-MS, a mass number of m/z=491 was observed by molecular ion peak, thereby identifying Intermediate L.

### Synthesis of Intermediate M

In a flask in an Ar atmosphere, about 10 mL of toluene was added to Intermediate L (15.0 g, 30.5 mmol), iodebenzen (204.01 g, 93.5 mmol), CuI (12.2 g, 64.1 mmol), and K₂CO₃ (33.8 g, 244 mmol), and the resulting mixture was heated for 24 hours while the exterior temperature is maintained at about 215° C. The mixture was diluted with CH₂Cl₂, water was added thereto, and the resultant mixture was subjected to celite filtering and then liquid separation to concentrate an organic layer. The concentrated organic layer was purified by silica gel column chromatography to obtain Intermediate M (10.4 g, yield 60%). By measuring FAB-MS, a mass number of m/z=567 was observed by molecular ion peak, thereby identifying Intermediate M.

### Synthesis of Intermediate N

In a flask in an Ar atmosphere, Intermediate M (10.0 g, 17.6 mmol), aniline (2.13 g, 22.9 mmol), Pd(dba)₂ (1.01 g, 1.76 mmol), P^{t}Bu₃·HBF₄ (1.02 g, 3.53 mmol), and tBuONa (3.90 g, 40.6 mmol) were added to 90 mL of toluene, and the resulting mixture was heated and stirred at about 80° C. for about 2 hours. Then, water was added to the reactant, and the resultant mixture was subjected to celite filtering and then liquid separation to concentrate an organic layer. The concentrated organic layer was purified by silica gel column chromatography to obtain Intermediate N (9.34 g, yield 85%). By measuring FAB-MS, a mass number of m/z=623 was observed by molecular ion peak, thereby identifying Intermediate N.

### Synthesis of Intermediate 0

In a flask in an Ar atmosphere, Intermediate M (10.0 g, 17.6 mmol), 2,6-diphenylaniline (5.62 g, 22.9 mmol), Pd(dba)₂ (1.01 g, 1.76 mmol), P^{t}Bu₃·HBF₄ (1.02 g, 3.53 mmol), and tBuONa (3.90 g, 40.6 mmol) were added to 90 mL of toluene, and the resulting mixture was heated and stirred at about 80° C. for about 2 hours. Then, water was added to the reactant, and the resultant mixture was subjected to celite filtering and then liquid separation to concentrate an organic layer. The concentrated organic layer was purified by silica gel column chromatography to obtain Intermediate O (12.0 g, yield 88%). By measuring FAB-MS, a mass number of m/z=776 was observed by molecular ion peak, thereby identifying Intermediate 0.

### Synthesis of Intermediate P

In a flask in an Ar atmosphere, about 10 mL of toluene was added to Intermediate 0 (11.0 g, 14.2 mmol), 3-chloro-1-iodebenzen (50.7 g, 213 mmol), CuI (5.67 g, 29.8 mmol), and K₂CO₃ (15.7 g, 113 mmol), and the resulting mixture was heated for 24 hours while the exterior temperature is maintained at about 215° C. Then, the resulting mixture was diluted with CH₂Cl₂, water was added thereto, and the resultant mixture was subjected to celite filtering and then liquid separation to concentrate an organic layer. The concentrated organic layer was purified by silica gel column chromatography to obtain Intermediate P (7.67 g, yield 61%). By measuring FAB-MS, a mass number of m/z=886 was observed by molecular ion peak, thereby identifying Intermediate P.

### Synthesis of Intermediate Q

In a flask in an Ar atmosphere, Intermediate P (7.0 g, 7.90 mmol), Intermediate N (5.17 g, 8.29 mmol), Pd(dba)₂ (454 mg, 0.79 mmol), P^{t}Bu₃·HBF₄ (458 mg, 1.58 mmol), and tBuONa (1.75 g, 18.2 mmol) were added to 50 mL of toluene, and the resulting mixture was heated and stirred at about 80° C. for about 2 hours. Then, water was added to the reactant, and the resultant mixture was subjected to celite filtering and then liquid separation to concentrate an organic layer. The concentrated organic layer was purified by silica gel column chromatography to obtain Intermediate Q (9.08 g, yield 78%). By measuring FAB-MS, a mass number of m/z=1473 was observed by molecular ion peak, thereby identifying Intermediate Q.

### Synthesis of Compound 108

In a flask in an Ar atmosphere, Intermediate Q (8.80 g, 5.97 mmol) was dissolved in 1,2-dichlorobenzene (ODCB, 100 mL), BBr₃ (3.74 g, 14.9 mmol) was added thereto, and the resulting mixture was heated and stirred at about 170° C. for about 10 hours. The resulting mixture was cooled to room temperature, N,N-diisopropylethylamine (9.24 g, 71.6 mmol) and water were added thereto, and the resultant mixture was subjected to celite filtering and then liquid separation to concentrate an organic layer. The concentrated organic layer was purified by silica gel column chromatography to obtain Compound 108 (1.96 g, yield 22%). By measuring FAB-MS, a mass number of m/z=1489 was observed by molecular ion peak, thereby identifying Compound 108. The obtained Compound 108 was subjected to sublimation purification (400° C., 2.1×10⁻³ Pa) and was utilized to evaluate a device.

### (5) Synthesis of Compound 185

Polycyclic Compound 185 according to an example may be synthesized by, for example, the steps (acts) shown in Reaction Scheme 5:

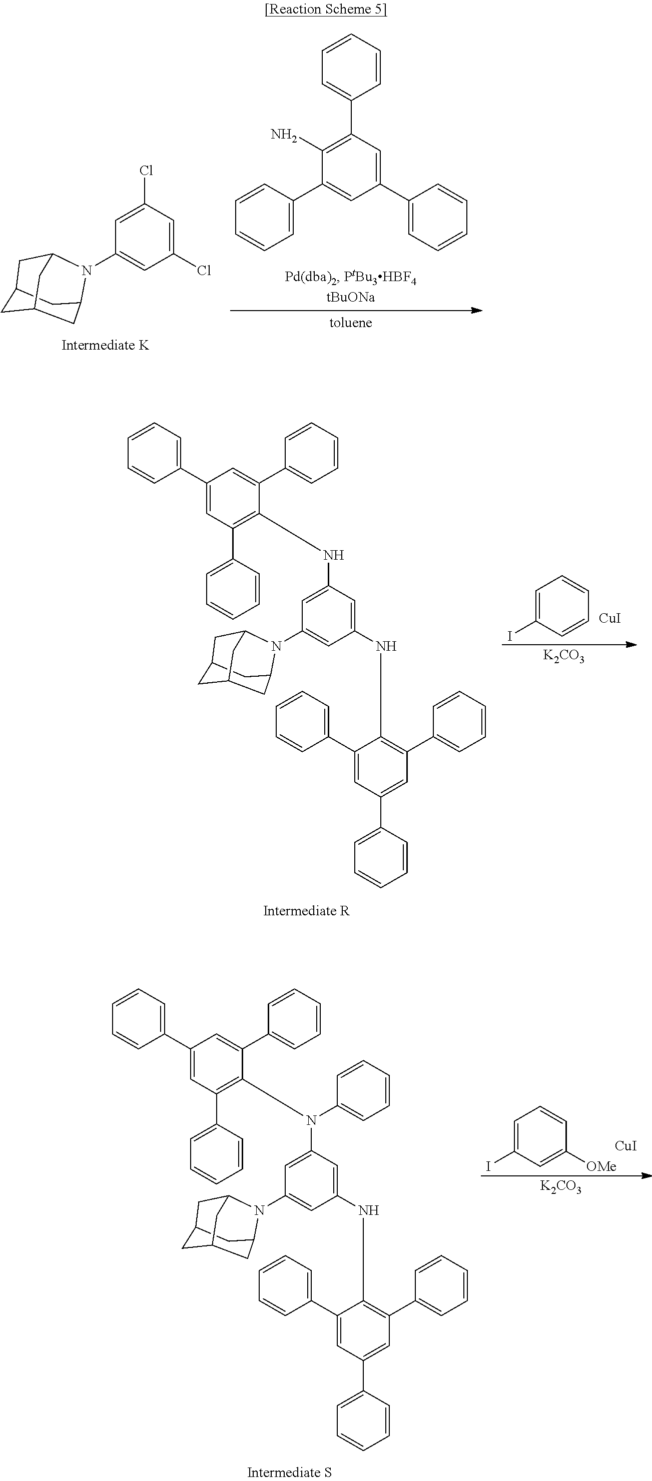

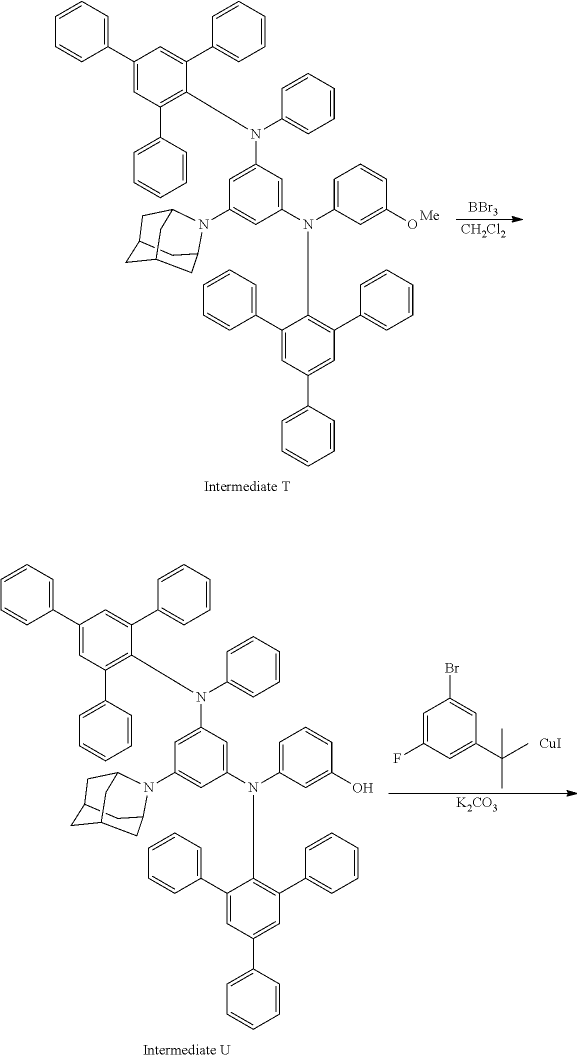

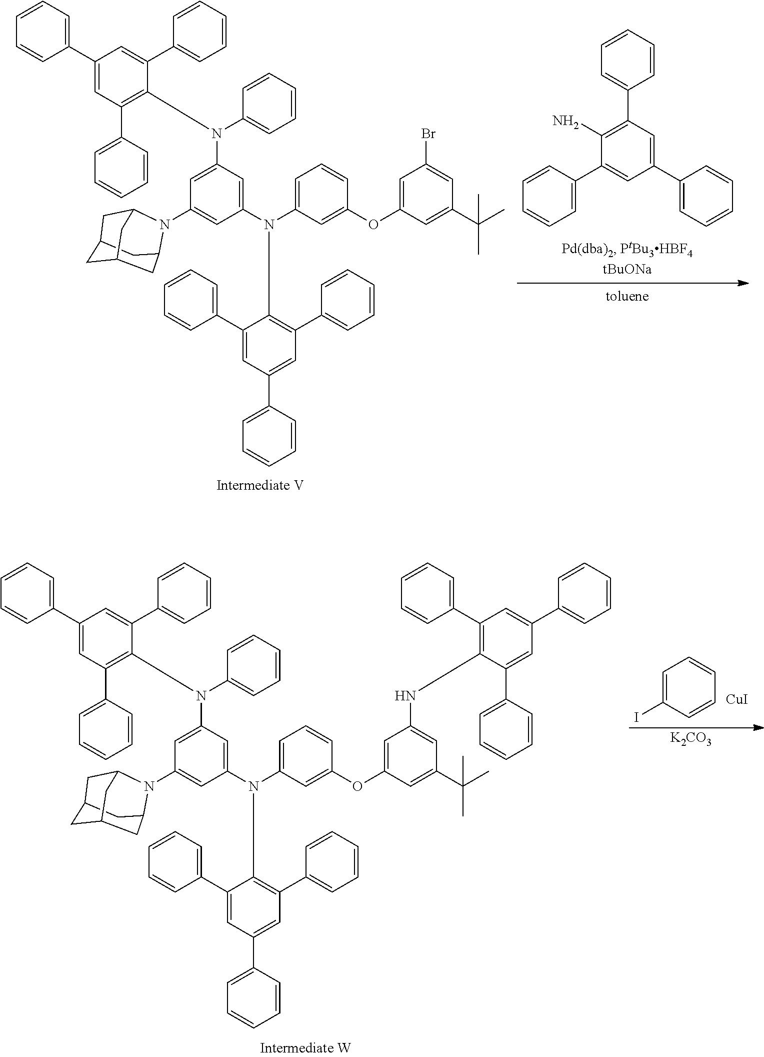

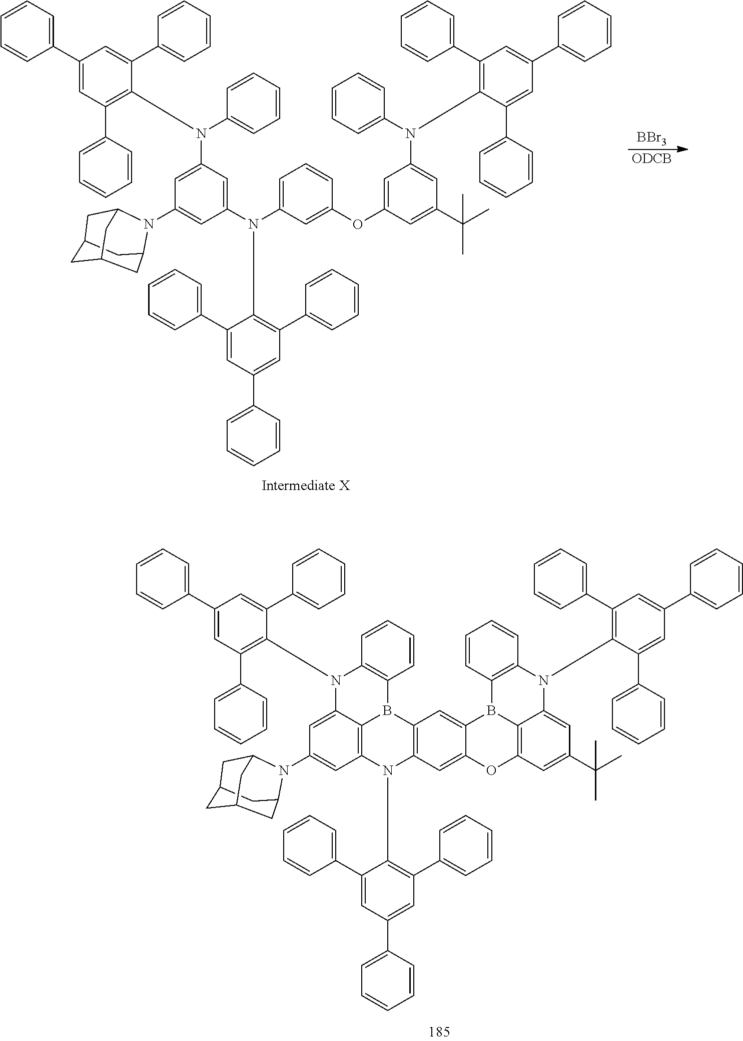 [SMILES: CC(C)(C)c1cc(Oc2cccc(N(c3cc(N(c4ccccc4)c4c(-c5ccccc5)cc(-c5ccccc5)cc4-c4ccccc4)cc(N4C5CC6CC(C5)CC4C6)c3)c3c(-c4ccccc4)cc(-c4ccccc4)cc3-c3ccccc3)c2)cc(N(c2ccccc2)c2c(-c3ccccc3)cc(-c3ccccc3)cc2-c2ccccc2)c1 ; "ODCB" ; "BBr3" ; CC(C)(C)c1cc2c3c(c1)N(c1c(-c4ccccc4)cc(-c4ccccc4)cc1-c1ccccc1)c1ccccc1B3c1cc3c(cc1O2)N(c1c(-c2ccccc2)cc(-c2ccccc2)cc1-c1ccccc1)c1cc(N2C4CC5CC(C4)CC2C5)cc2c1B3c1ccccc1N2c1c(-c2ccccc2)cc(-c2ccccc2)cc1-c1ccccc1]

### Synthesis of Intermediate R

In a flask in an Ar atmosphere, Intermediate K (8.0 g, 28.35 mmol), 2,4,6-triphenylaniline (18.7 g, 58.1 mmol), Pd(dba)₂ (1.63 g, 2.83 mmol), P^{t}Bu₃·HBF₄ (1.64 g, 5.67 mmol), and tBuONa (6.27 g, 65.2 mmol) were added to 150 mL of toluene, and the resulting mixture was heated and stirred at about 80° C. for about 2 hours. Then, water was added to the reactant, and the resultant mixture was subjected to celite filtering and then liquid separation to concentrate an organic layer. The concentrated organic layer was purified by silica gel column chromatography to obtain Intermediate R (26.3 g, yield 87%). By measuring FAB-MS, a mass number of m/z=852 was observed by molecular ion peak, thereby identifying Intermediate R.

### Synthesis of Intermediate S

In a flask in an Ar atmosphere, about 10 mL of toluene was added to Intermediate R (26.0 g, 30.5 mmol), iodebenzen (93.4 g, 458 mmol), CuI (12.2 g, 64.1 mmol), and K₂CO₃ (33.7 g, 244 mmol), and the resulting mixture was heated for 24 hours while the exterior temperature is maintained at about 215° C. The mixture was diluted with CH₂Cl₂, water was added thereto, and the resultant mixture was subjected to celite filtering and then liquid separation to concentrate an organic layer. The concentrated organic layer was purified by silica gel column chromatography to obtain Intermediate S (14.2 g, yield 50%). By measuring FAB-MS, a mass number of m/z=928 was observed by molecular ion peak, thereby identifying Intermediate S.

### Synthesis of Intermediate T

In a flask in an Ar atmosphere, about 10 mL of toluene was added to Intermediate S (14.0 g, 15.1 mmol), 3-methoxy-1-iodebenzen (52.9 g, 226 mmol), CuI (6.03 g, 31.7 mmol), and K₂CO₃ (16.7 g, 121 mmol), and the resulting mixture was heated for 24 hours while the exterior temperature is maintained at about 215° C. The mixture was diluted with CH₂Cl₂, water was added thereto, and the resultant mixture was subjected to celite filtering and then liquid separation to concentrate an organic layer. The concentrated organic layer was purified by silica gel column chromatography to obtain Intermediate T (15.6 g, yield 70%). By measuring FAB-MS, a mass number of m/z=1034 was observed by molecular ion peak, thereby identifying Intermediate T.

### Synthesis of Intermediate U

In an argon atmosphere flask, Intermediate T (15.0 g, 14.5 mmol) was dissolved in CH₂Cl₂ (200 mL) and BBr₃ (9.08 g, 36.3 mmol) was added thereto at about 0° C. Then, the resulting mixture was heated to room temperature and stirred for about 24 hour. The reactant was cooled to about 0° C., 100 mL of water was added thereto, and the resultant mixture was stirred for about 1 hour, and then was subjected to celite filtering and then liquid separation to concentrate an organic layer. The concentrated organic layer was purified by silica gel column chromatography to obtain Intermediate U (11.8 g, yield 80%). By measuring FAB-MS, a mass number of m/z=1020 was observed by molecular ion peak, thereby identifying Intermediate U.

### Synthesis of Intermediate V

In a flask in an Ar atmosphere, Intermediate U (11.0 g, 10.8 mmol), 1-bromo-3-(tert-butyl)-5-fluorobenzene (2.99 g, 129 mmol), and 1-methyl-2-pyrrolidone (NMP, 150 mL) were added and maintained at about 0° C., and then 60% NaH (0.86 g, 21.6 mmol) was added thereto, and the resulting mixture was stirred for about 30 minutes and then stirred at about 100° C. for about 6 hours. Then, water and toluene were added thereto, and the resultant mixture was stirred for about 1 hour, and subjected to celite filtering and then liquid separation to concentrate an organic layer. The concentrated organic layer was purified by silica gel column chromatography to obtain Intermediate V (9.96 g, yield 75%). By measuring FAB-MS, a mass number of m/z=1231 was observed by molecular ion peak, thereby identifying Intermediate V.

### Synthesis of Intermediate W

In a flask in an Ar atmosphere, Intermediate V (9.0 g, 7.31 mmol), 2,4,6-diphenylaniline (2.47 g, 7.67 mmol), Pd(dba)₂ (0.42 g, 0.73 mmol), P^{t}Bu₃·HBF₄ (0.42 g, 1.46 mmol), and tBuONa (1.62 g, 16.8 mmol) were added to 50 mL of toluene, and the resulting mixture was heated and stirred at about 80° C. for about 2 hours. Then, water was added to the reactant, and the resultant mixture was subjected to celite filtering and then liquid separation to concentrate an organic layer. The concentrated organic layer was purified by silica gel column chromatography to obtain Intermediate W (9.14 g, yield 85%). By measuring FAB-MS, a mass number of m/z=1471 was observed by molecular ion peak, thereby identifying Intermediate W.

### Synthesis of Intermediate X

In a flask in an Ar atmosphere, about 10 mL of toluene was added to Intermediate X (9.0 g, 6.11 mmol), iodebenzen (18.7 g, 91.7 mmol), CuI (2.44 g, 12.8 mmol), and K₂CO₃ (6.76 g, 48.9 mmol), and the resulting mixture was heated for 24 hours while the exterior temperature is maintained at about 215° C. The mixture was diluted with CH₂Cl₂, water was added thereto, and the resultant mixture was subjected to celite filtering and then liquid separation to concentrate an organic layer. The concentrated organic layer was purified by silica gel column chromatography to obtain Intermediate X (6.15 g, yield 65%). By measuring FAB-MS, a mass number of m/z=1548 was observed by molecular ion peak, thereby identifying Intermediate X.

### Synthesis of Compound 185

In a flask in an Ar atmosphere, Intermediate X (6.0 g, 3.88 mmol) was dissolved in 1,2-dichlorobenzene (ODCB, 50 mL), BBr₃ (2.42 g, 9.69 mmol) was added thereto, and the resulting mixture was heated and stirred at about 170° C. for about 10 hours. Then, the resulting mixture was cooled to room temperature, N,N-diisopropylethylamine (6.0 g, 46.5 mmol) and water were added thereto, and the resultant mixture was subjected to celite filtering and then liquid separation to concentrate an organic layer. The concentrated organic layer was purified by silica gel column chromatography to obtain Compound 185 (1.27 g, yield 21%). By measuring FAB-MS, a mass number of m/z=1563 was observed by molecular ion peak, thereby identifying Compound 185. The obtained Compound 185 was subjected to sublimation purification (390° C., 2.3×10⁻³ Pa) and was utilized to evaluate a device.

### (6) Synthesis of Compound 215

Polycyclic Compound 215 according to an example may be synthesized by, for example, the steps (acts) shown in Reaction Scheme 6:

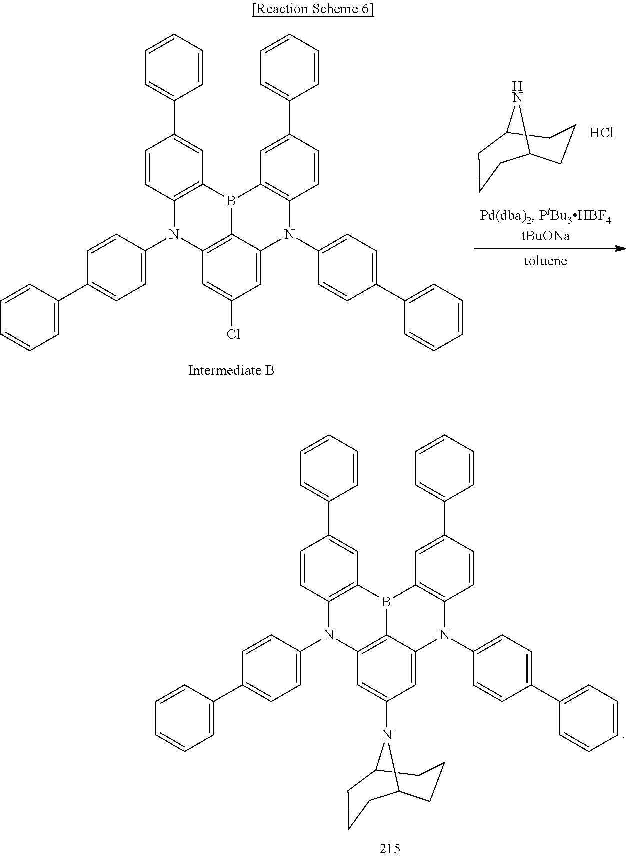 [SMILES: Clc1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1 ; C1CC2CCCC(C1)N2 ; Cl ; c1ccc(-c2ccc(N3c4ccc(-c5ccccc5)cc4B4c5cc(-c6ccccc6)ccc5N(c5ccc(-c6ccccc6)cc5)c5cc(N6C7CCCC6CCC7)cc3c54)cc2)cc1]

In a flask in an Ar atmosphere, Intermediate B (2.0 g, 22.63 mmol), 9-azabicyclo[3.3.1]nonane hydrochloride (1.06 g, 6.59 mmol), Pd(dba)₂ (152 mg, 0.26 mmol), P^{t}Bu₃·HBF₄ (153 mg, 0.53 mmol), and tBuONa (1.52 g, 15.8 mmol) were added to 50 mL of toluene, and the resulting mixture was heated and stirred at about 80° C. for about 2 hours. Water was added to the reactant, and the resultant mixture was subjected to celite filtering and then liquid separation to concentrate an organic layer. The concentrated organic layer was purified by silica gel column chromatography to obtain Compound 215 (1.72 g, yield 77%). By measuring FAB-MS, a mass number of m/z=847 was observed by molecular ion peak, thereby identifying Compound 215. The obtained Compound 215 was subjected to sublimation purification (320° C., 2.4×10⁻³ Pa) and was utilized to evaluate a device.

### (7) Synthesis of Compound 216

Polycyclic Compound 216 according to an example may be synthesized by, for example, the steps (acts) shown in Reaction Scheme 7:

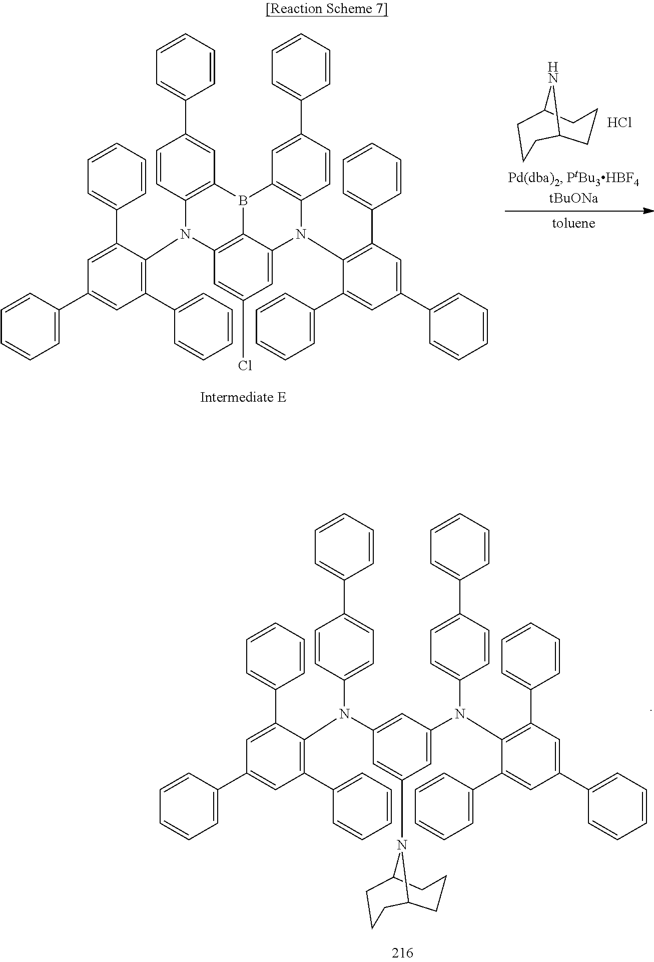 [SMILES: Clc1cc2c3c(c1)N(c1c(-c4ccccc4)cc(-c4ccccc4)cc1-c1ccccc1)c1ccc(-c4ccccc4)cc1B3c1cc(-c3ccccc3)ccc1N2c1c(-c2ccccc2)cc(-c2ccccc2)cc1-c1ccccc1 ; C1CC2CCCC(C1)N2 ; Cl ; c1ccc(-c2ccc(N(c3cc(N(c4ccc(-c5ccccc5)cc4)c4c(-c5ccccc5)cc(-c5ccccc5)cc4-c4ccccc4)cc(N4C5CCCC4CCC5)c3)c3c(-c4ccccc4)cc(-c4ccccc4)cc3-c3ccccc3)cc2)cc1]

In a flask in an Ar atmosphere, Intermediate E (3.0 g, 2.82 mmol), 9-azabicyclo[3.3.1]nonane hydrochloride (0.954 g, 5.92 mmol), Pd(dba)₂ (162 mg, 0.28 mmol), P^{t}Bu₃·HBF₄ (164 mg, 0.56 mmol), and tBuONa (0.895 g, 9.31 mmol) were added to 50 mL of toluene, and the resulting mixture was heated and stirred at about 80° C. for about 2 hours. Then, water was added to the reactant, and the resultant mixture was subjected to celite filtering and then liquid separation to concentrate an organic layer. The concentrated organic layer was purified by silica gel column chromatography to obtain Compound 216 (2.27 g, yield 70%). By measuring FAB-MS, a mass number of m/z=1152 was observed by molecular ion peak, thereby identifying Compound 216. The obtained Compound 216 was subjected to sublimation purification (330° C., 2.6×10⁻³ Pa) and was utilized to evaluate a device.

### (8) Synthesis of Compound 217

Polycyclic Compound 217 according to an example may be synthesized by, for example, the steps (acts) shown in Reaction Scheme 8:

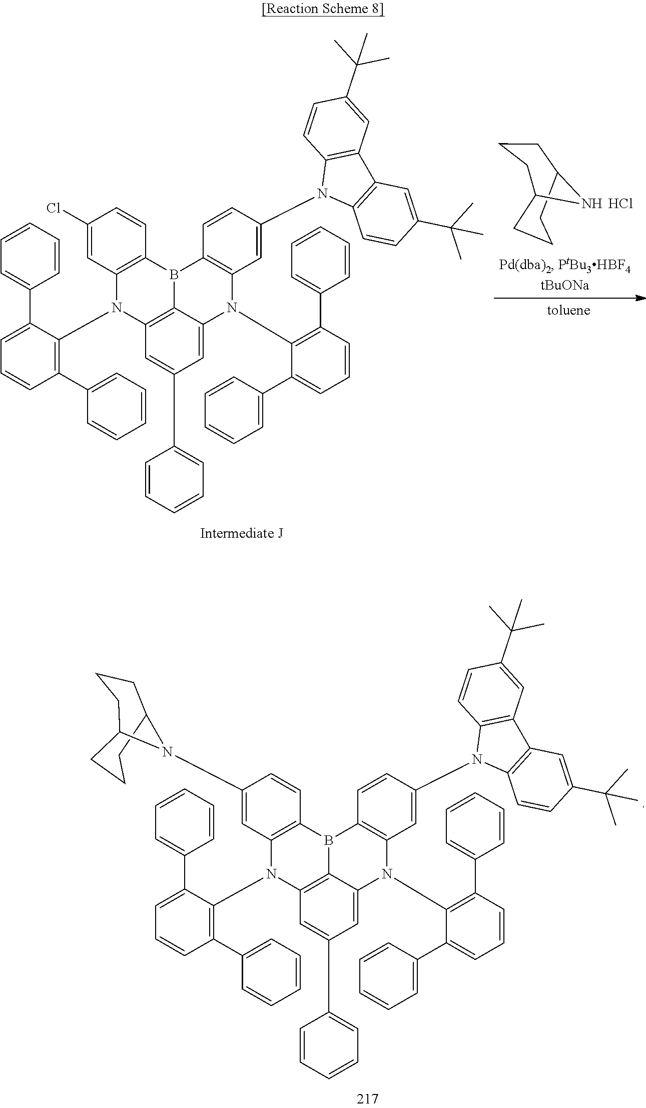

In a flask in an Ar atmosphere, Intermediate J (3.0 g, 2.70 mmol), 9-azabicyclo[3.3.1]nonane hydrochloride (0.915 g, 5.66 mmol), Pd(dba)₂ (155 mg, 0.27 mmol), P^{t}Bu₃·HBF₄ (156 mg, 0.54 mmol), and tBuONa (0.855 g, 8.90 mmol) were added to 50 mL of toluene, and the resulting mixture was heated and stirred at about 80° C. for about 2 hours. Then, water was added to the reactant, and the resultant mixture was subjected to celite filtering and then liquid separation to concentrate an organic layer. The concentrated organic layer was purified by silica gel column chromatography to obtain Compound 217 (2.01 g, yield 62%). By measuring FAB-MS, a mass number of m/z=1201 was observed by molecular ion peak, thereby identifying Compound 217. The obtained Compound 217 was subjected to sublimation purification (370° C., 3.0×10⁻³ Pa) and was utilized to evaluate a device.

### (9) Synthesis of Compound 221

Polycyclic Compound 221 according to an example may be synthesized by, for example, the steps (acts) shown in Reaction Scheme 9:

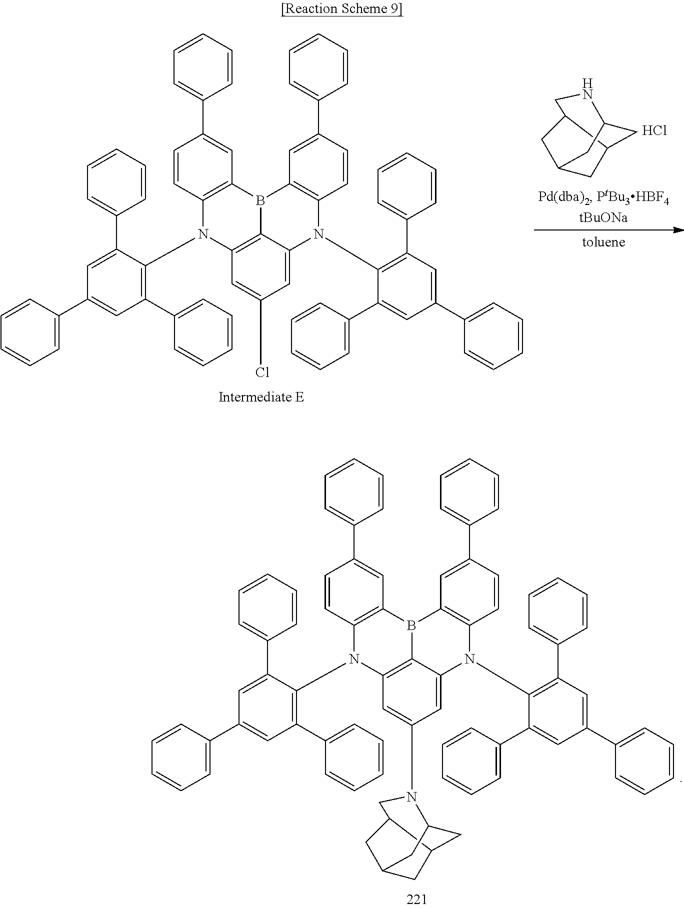 [SMILES: Clc1cc2c3c(c1)N(c1c(-c4ccccc4)cc(-c4ccccc4)cc1-c1ccccc1)c1ccc(-c4ccccc4)cc1B3c1cc(-c3ccccc3)ccc1N2c1c(-c2ccccc2)cc(-c2ccccc2)cc1-c1ccccc1 ; C1C2CC3CNC1CC3C2 ; Cl ; c1ccc(-c2ccc3c(c2)B2c4cc(-c5ccccc5)ccc4N(c4c(-c5ccccc5)cc(-c5ccccc5)cc4-c4ccccc4)c4cc(N5CC6CC7CC6CC5C7)cc(c42)N3c2c(-c3ccccc3)cc(-c3ccccc3)cc2-c2ccccc2)cc1]

In a flask in an Ar atmosphere, Intermediate E (3.0 g, 2.82 mmol), rac-(1S,5R)-6-azabicyclo[3.2.1]octane hydrochloride (1.03 g, 5.92 mmol), Pd(dba)₂ (162 mg, 0.28 mmol), P^{t}Bu₃·HBF₄ (164 mg, 0.56 mmol), and tBuONa (0.895 g, 9.31 mmol) were added to 50 mL of toluene, and the resulting mixture was heated and stirred at about 80° C. for about 2 hours. Then, water was added to the reactant, and the resultant mixture was subjected to celite filtering and then liquid separation to concentrate an organic layer. The concentrated organic layer was purified by silica gel column chromatography to obtain Compound 221 (2.13 g, yield 65%). By measuring FAB-MS, a mass number of m/z=1164 was observed by molecular ion peak, thereby identifying Compound 221. The obtained Compound 221 was subjected to sublimation purification (340° C., 2.8×10⁻³ Pa) and was utilized to evaluate a device.

### (10) Synthesis of Compound 226

Polycyclic Compound 226 according to an example may be synthesized by, for example, the steps (acts) shown in Reaction Scheme 10:

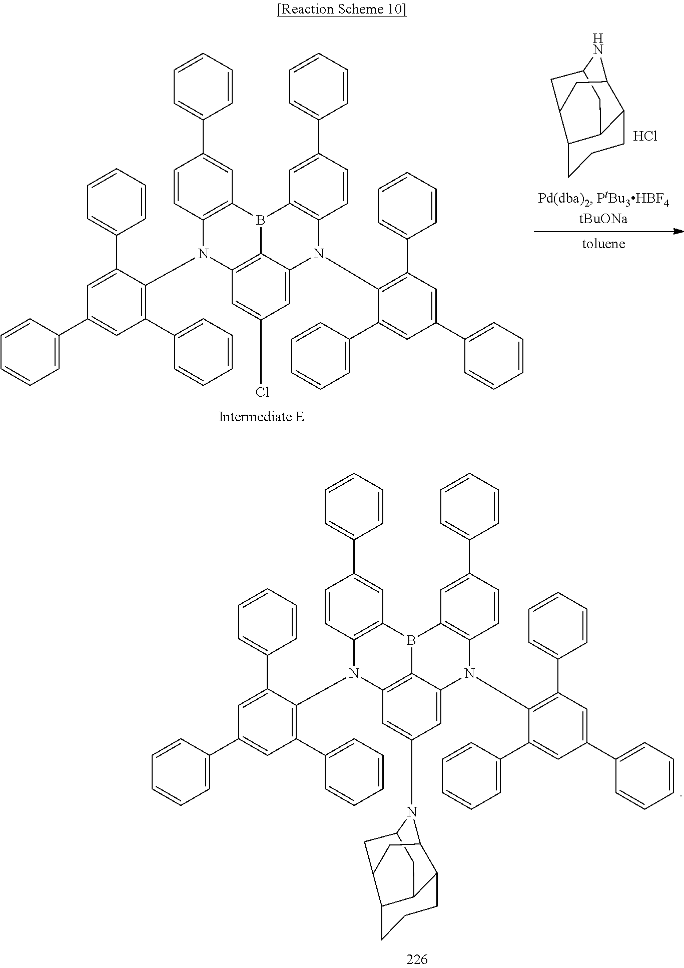 [SMILES: Clc1cc2c3c(c1)N(c1c(-c4ccccc4)cc(-c4ccccc4)cc1-c1ccccc1)c1ccc(-c4ccccc4)cc1B3c1cc(-c3ccccc3)ccc1N2c1c(-c2ccccc2)cc(-c2ccccc2)cc1-c1ccccc1 ; C1CC2C3CC4CC2C(C1)C(C3)N4 ; Cl ; c1ccc(-c2ccc3c(c2)B2c4cc(-c5ccccc5)ccc4N(c4c(-c5ccccc5)cc(-c5ccccc5)cc4-c4ccccc4)c4cc(N5C6CC7CC5C5CCCC7C5C6)cc(c42)N3c2c(-c3ccccc3)cc(-c3ccccc3)cc2-c2ccccc2)cc1]

In a flask in an Ar atmosphere, Intermediate E (3.0 g, 2.82 mmol), (2S,4S,4aR,8R,8aS,10R)-decahydro-2,8,4-(epiminoethane[1,1,2]triyl)naphthalene hydrochloride (1.27 g, 5.92 mmol), Pd(dba)₂ (162 mg, 0.28 mmol), P^{t}Bu₃·HBF₄ (164 mg, 0.56 mmol), and tBuONa (0.895 g, 9.31 mmol) were added to 50 mL of toluene, and the resulting mixture was heated and stirred at about 80° C. for about 2 hours. Then, water was added to the reactant, and the resultant mixture was subjected to celite filtering and then liquid separation to concentrate an organic layer. The concentrated organic layer was purified by silica gel column chromatography to obtain Compound 226 (2.72 g, yield 80%). By measuring FAB-MS, a mass number of m/z=1204 was observed by molecular ion peak, thereby identifying Compound 226. The obtained Compound 226 was subjected to sublimation purification (330° C., 2.5×10⁻³ Pa) and was utilized to evaluate a device.

### (11) Synthesis of Compound 235

Polycyclic Compound 235 according to an example may be synthesized by, for example, the steps (acts) shown in Reaction Scheme 11:

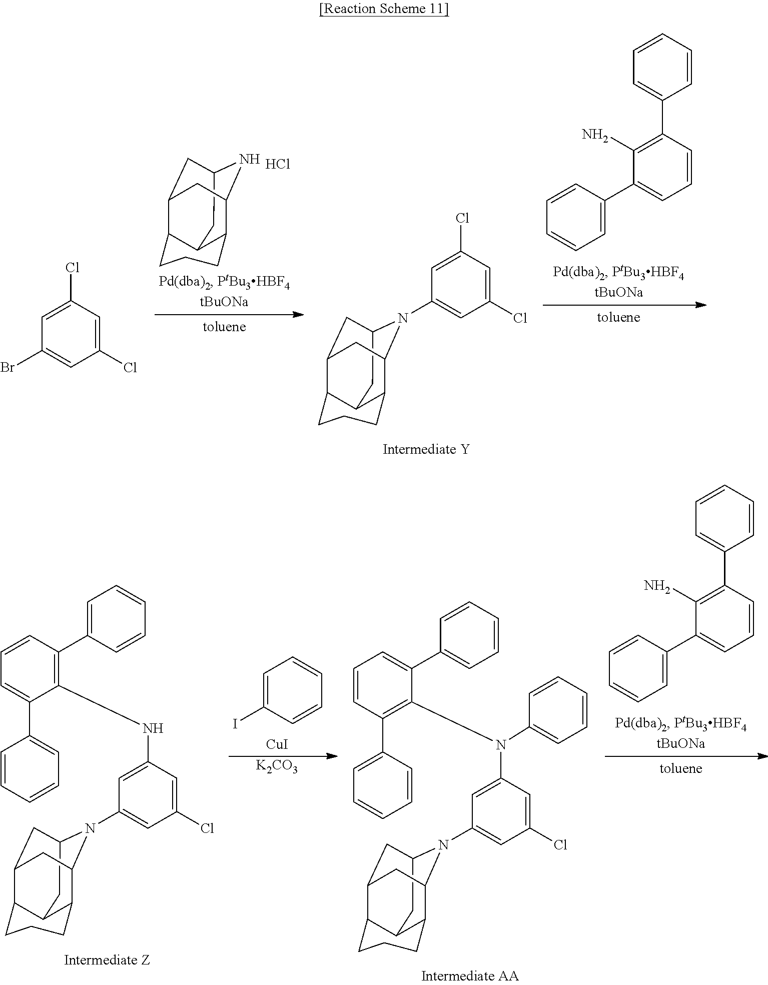

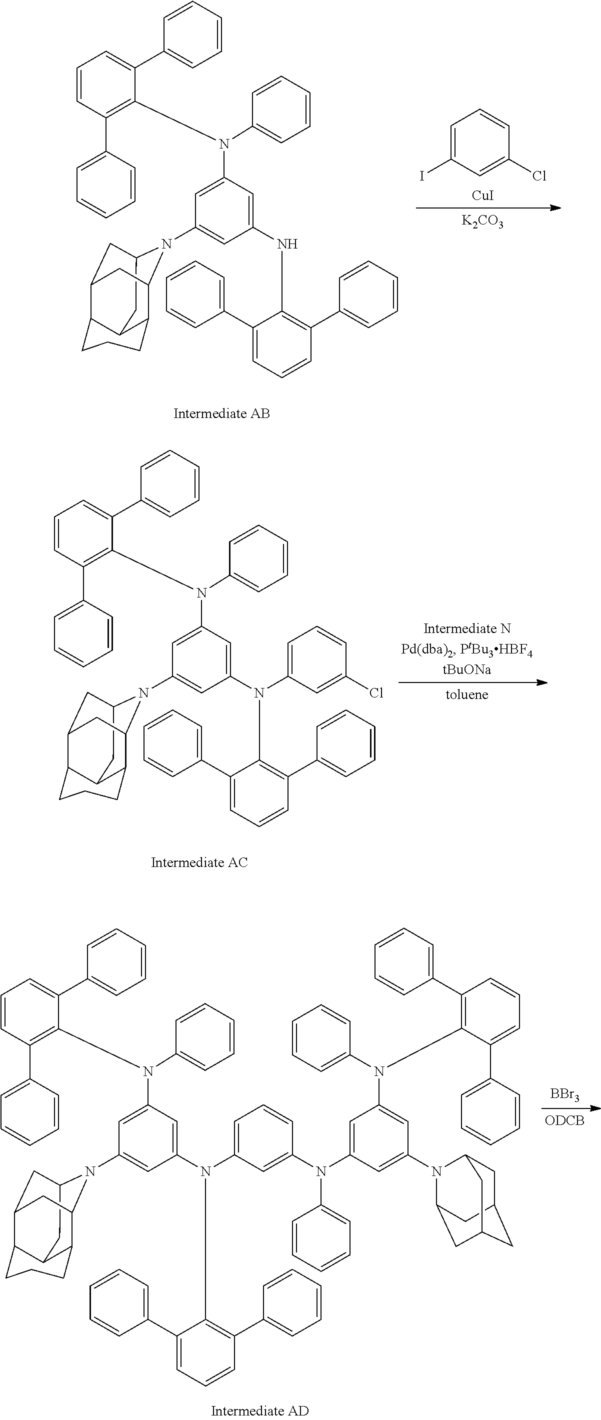

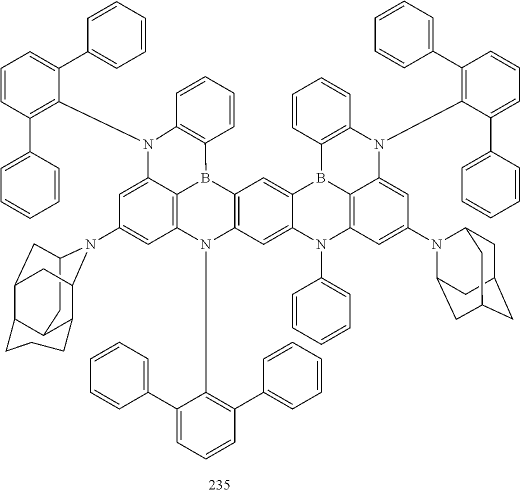 [SMILES: c1ccc(-c2cccc(-c3ccccc3)c2N2c3ccccc3B3c4cc5c(cc4N(c4ccccc4)c4cc(N6C7CC8CC(C7)CC6C8)cc2c43)N(c2c(-c3ccccc3)cccc2-c2ccccc2)c2cc(N3C4CC6CC3C3CCCC6C3C4)cc3c2B5c2ccccc2N3c2c(-c3ccccc3)cccc2-c2ccccc2)cc1]

### Synthesis of Intermediate Y

In a flask in an Ar atmosphere, 1-bromo-3,5-dichlorobenzene (15.0 g, 66.4 mmol), (2S,4S,4aR,8R,8aS,10R)-decahydro-2,8,4-(epiminoethane[1,1,2]triyl)naphthalene hydrochloride (15.0 g, 86.3 mmol), Pd(dba)₂ (3.81 g, 6.64 mmol), P^{t}Bu₃·HBF₄ (3.85 g, 13.3 mmol), and tBuONa (14.7 g, 153 mmol) were added to 330 mL of toluene, and the resulting mixture was heated and stirred at about 80° C. for about 2 hours. Then, water was added to the reactant, and the resultant mixture was subjected to celite filtering and then liquid separation to concentrate an organic layer. The concentrated organic layer was purified by silica gel column chromatography to obtain Intermediate Y (15.0 g, yield 70%). By measuring FAB-MS, a mass number of m/z=322 was observed by molecular ion peak, thereby identifying Intermediate Y.

### Synthesis of Intermediate Z

In a flask in an Ar atmosphere, Intermediate Y (13.7 g, 42.5 mmol), 2,6-diphenylaniline (13.56 g, 55.3 mmol), Pd(dba)₂ (2.45 g, 4.25 mmol), P^{t}Bu₃·HBF₄ (2.47 g, 8.50 mmol), and tBuONa (9.40 g, 97.8 mmol) were added to 250 mL of toluene, and the resulting mixture was heated and stirred at about 80° C. for about 2 hours. Then, water was added to the reactant, and the resultant mixture was subjected to celite filtering and then liquid separation to concentrate an organic layer. The concentrated organic layer was purified by silica gel column chromatography to obtain Intermediate Z (17.2 g, yield 76%). By measuring FAB-MS, a mass number of m/z=531 was observed by molecular ion peak, thereby identifying Intermediate Z.

### Synthesis of Intermediate AA

In a flask in an Ar atmosphere, about 10 mL of toluene was added to Intermediate Z (16.2 g, 30.5 mmol), iodebenzen (204.01 g, 93.5 mmol), CuI (12.2 g, 64.1 mmol), and K₂CO₃ (33.8 g, 244 mmol), and the resulting mixture was heated for 24 hours while the exterior temperature is maintained at about 215° C. The mixture was diluted with CH₂Cl₂, water was added thereto, and the resultant mixture was subjected to celite filtering and then liquid separation to concentrate an organic layer. The concentrated organic layer was purified by silica gel column chromatography to obtain Intermediate AA (12.0 g, yield 65%). By measuring FAB-MS, a mass number of m/z=607 was observed by molecular ion peak, thereby identifying Intermediate AA.

### Synthesis of Intermediate AB

In a flask in an Ar atmosphere, Intermediate AA (10.7 g, 17.6 mmol), 2,6-diphenylaniline (5.61 g, 22.9 mmol), Pd(dba)₂ (1.01 g, 1.76 mmol), P^{t}Bu₃·HBF₄ (1.02 g, 3.53 mmol), and tBuONa (3.90 g, 40.6 mmol) were added to 90 mL of toluene, and the resulting mixture was heated and stirred at about 80° C. for about 2 hours. Water was added to the reactant, and the resultant mixture was subjected to celite filtering and then liquid separation to concentrate an organic layer. The concentrated organic layer was purified by silica gel column chromatography to obtain Intermediate AB (12.2 g, yield 85%). By measuring FAB-MS, a mass number of m/z=816 was observed by molecular ion peak, thereby identifying Intermediate AB.

### Synthesis of Intermediate AC

In a flask in an Ar atmosphere, about 10 mL of toluene was added to Intermediate AB (11.6 g, 14.2 mmol), 3-chloro-1-iodebenzen (50.7 g, 213 mmol), CuI (5.67 g, 29.8 mmol), and K₂CO₃ (15.7 g, 113 mmol), and the resulting mixture was heated for 24 hours while the exterior temperature is maintained at about 215° C. The mixture was diluted with CH₂Cl₂, water was added thereto, and the resultant mixture was subjected to celite filtering and then liquid separation to concentrate an organic layer. The concentrated organic layer was purified by silica gel column chromatography to obtain Intermediate AC (8.30 g, yield 63%). By measuring FAB-MS, a mass number of m/z=926 was observed by molecular ion peak, thereby identifying Intermediate AC.

### Synthesis of Intermediate AD

In a flask in an Ar atmosphere, Intermediate AC (7.3 g, 7.90 mmol), Intermediate N (5.17 g, 8.29 mmol), Pd(dba)₂ (454 mg, 0.79 mmol), P^{t}Bu₃·HBF₄ (458 mg, 1.58 mmol), and tBuONa (1.75 g, 18.2 mmol) were added to 50 mL of toluene, and the resulting mixture was heated and stirred at about 80° C. for about 2 hours. Then, water was added to the reactant, and the resultant mixture was subjected to celite filtering and then liquid separation to concentrate an organic layer. The concentrated organic layer was purified by silica gel column chromatography to obtain Intermediate AD (8.97 g, yield 75%). By measuring FAB-MS, a mass number of m/z=1514 was observed by molecular ion peak, thereby identifying Intermediate AD.

### Synthesis of Compound 235

In a flask in an Ar atmosphere, Intermediate AD (8.50 g, 5.61 mmol) was dissolved in 1,2-dichlorobenzene (ODCB, 100 mL), BBr₃ (3.52 g, 14.0 mmol) was added thereto, and the resulting mixture was heated and stirred at about 170° C. for about 10 hours. The resulting mixture was cooled to room temperature, N,N-diisopropylethylamine (8.69 g, 67.4 mmol) and water were added thereto, and the resultant mixture was subjected to celite filtering and then liquid separation to concentrate an organic layer. The concentrated organic layer was purified by silica gel column chromatography to obtain Compound 235 (1.54 g, yield 18%). By measuring FAB-MS, a mass number of m/z=1529 was observed by molecular ion peak, thereby identifying Compound 235. The obtained Compound 235 was subjected to sublimation purification (405° C., 2.2×10⁻³ Pa) and was utilized to evaluate a device.

### 2. Manufacture and Evaluation of Light Emitting Element

Evaluation of the light emitting elements including compounds of Examples and Comparative Examples was performed as follows. The method for manufacturing the light emitting element for the evaluation of the element is described below.

### (1) Manufacture of Light Emitting Elements

A glass substrate on which a 150 nm-thick ITO had been patterned was ultrasonically washed by utilizing isopropyl alcohol and pure water for about 5 minutes each. After being ultrasonically washed, the glass substrate was irradiated with UV rays for about 30 minutes and treated with ozone. Then, HAT-CN was deposited to a thickness of about 10 nm, α-NPD was deposited to a thickness of about 80 nm, and mCP was deposited to a thickness of about 5 nm in this stated order to form a hole transport region.

Next, a respective Example Compound or Comparative Example Compound and mCBP were co-deposited to form a 20 nm-thick emission layer. Example Compound or Comparative Example Compound and mCBP were co-deposited in a weight ratio of about 1:99. In the manufacture of the light emitting element, Example Compound or Comparative Example Compound was utilized as a dopant material.

Then, TPBi was deposited to a thickness of about 30 nm and LiF was deposited to a thickness of about 0.5 nm in this stated order to form an electron transport region.

Next, Al was deposited to form a 100 nm-thick second electrode.

In these examples, the hole transport region, the emission layer, the electron transport region, and the second electrode were formed utilizing a vacuum deposition apparatus.

Example Compounds and Comparative Example Compounds utilized to manufacture the light emitting elements are as follows:

### Example Compounds

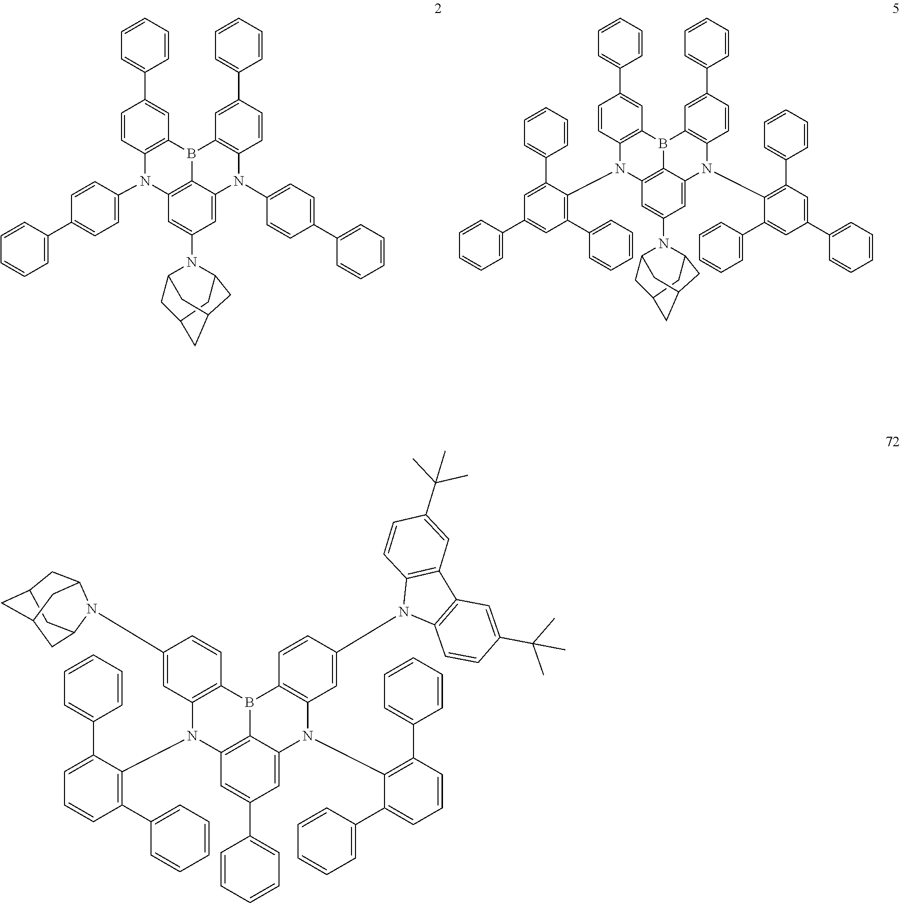 [SMILES: c1ccc(-c2ccc(N3c4ccc(-c5ccccc5)cc4B4c5cc(-c6ccccc6)ccc5N(c5ccc(-c6ccccc6)cc5)c5cc(N6C7CC8CC(C7)CC6C8)cc3c54)cc2)cc1 ; c1ccc(-c2ccc3c(c2)B2c4cc(-c5ccccc5)ccc4N(c4c(-c5ccccc5)cc(-c5ccccc5)cc4-c4ccccc4)c4cc(N5C6CC7CC(C6)CC5C7)cc(c42)N3c2c(-c3ccccc3)cc(-c3ccccc3)cc2-c2ccccc2)cc1 ; CC(C)(C)c1ccc2c(c1)c1cc(C(C)(C)C)ccc1n2-c1ccc2c(c1)N(c1c(-c3ccccc3)cccc1-c1ccccc1)c1cc(-c3ccccc3)cc3c1B2c1ccc(N2C4CC5CC(C4)CC2C5)cc1N3c1c(-c2ccccc2)cccc1-c1ccccc1]

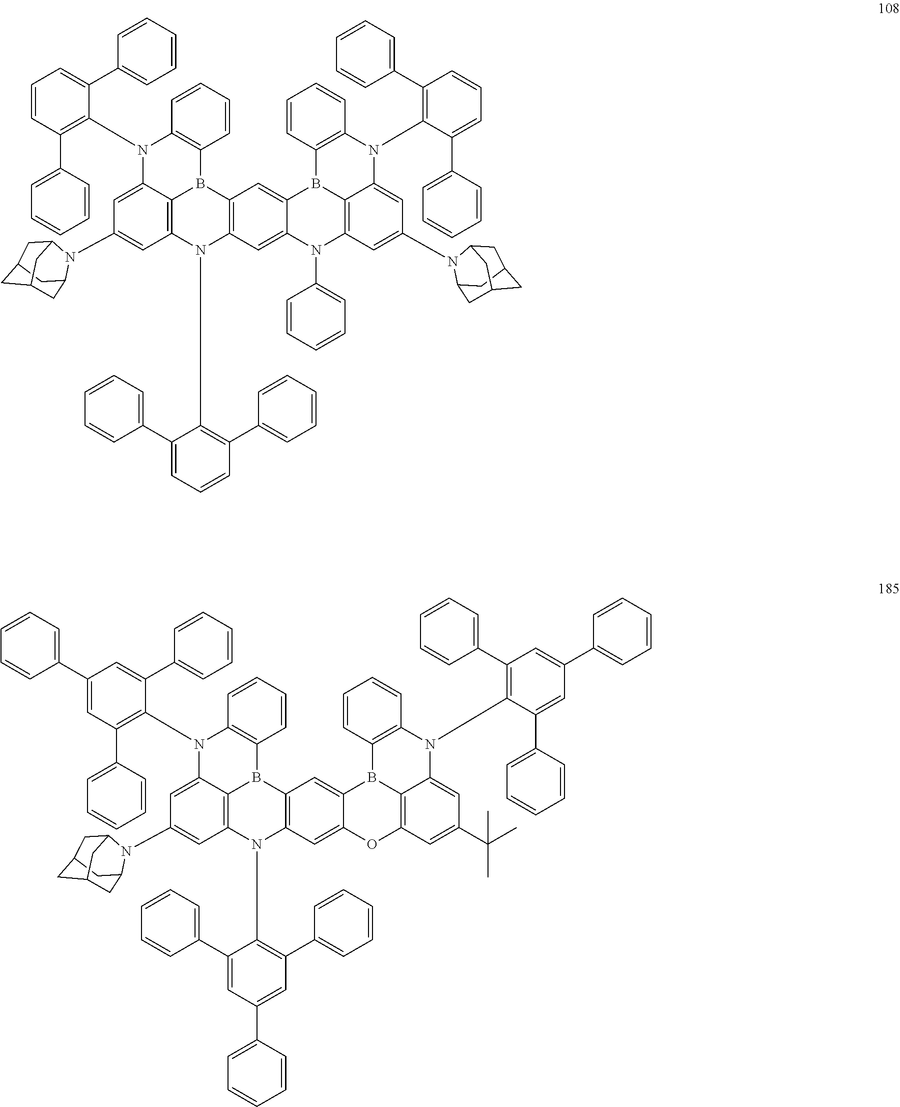 [SMILES: c1ccc(-c2cccc(-c3ccccc3)c2N2c3ccccc3B3c4cc5c(cc4N(c4ccccc4)c4cc(N6C7CC8CC(C7)CC6C8)cc2c43)N(c2c(-c3ccccc3)cccc2-c2ccccc2)c2cc(N3C4CC6CC(C4)CC3C6)cc3c2B5c2ccccc2N3c2c(-c3ccccc3)cccc2-c2ccccc2)cc1 ; CC(C)(C)c1cc2c3c(c1)N(c1c(-c4ccccc4)cc(-c4ccccc4)cc1-c1ccccc1)c1ccccc1B3c1cc3c(cc1O2)N(c1c(-c2ccccc2)cc(-c2ccccc2)cc1-c1ccccc1)c1cc(N2C4CC5CC(C4)CC2C5)cc2c1B3c1ccccc1N2c1c(-c2ccccc2)cc(-c2ccccc2)cc1-c1ccccc1]

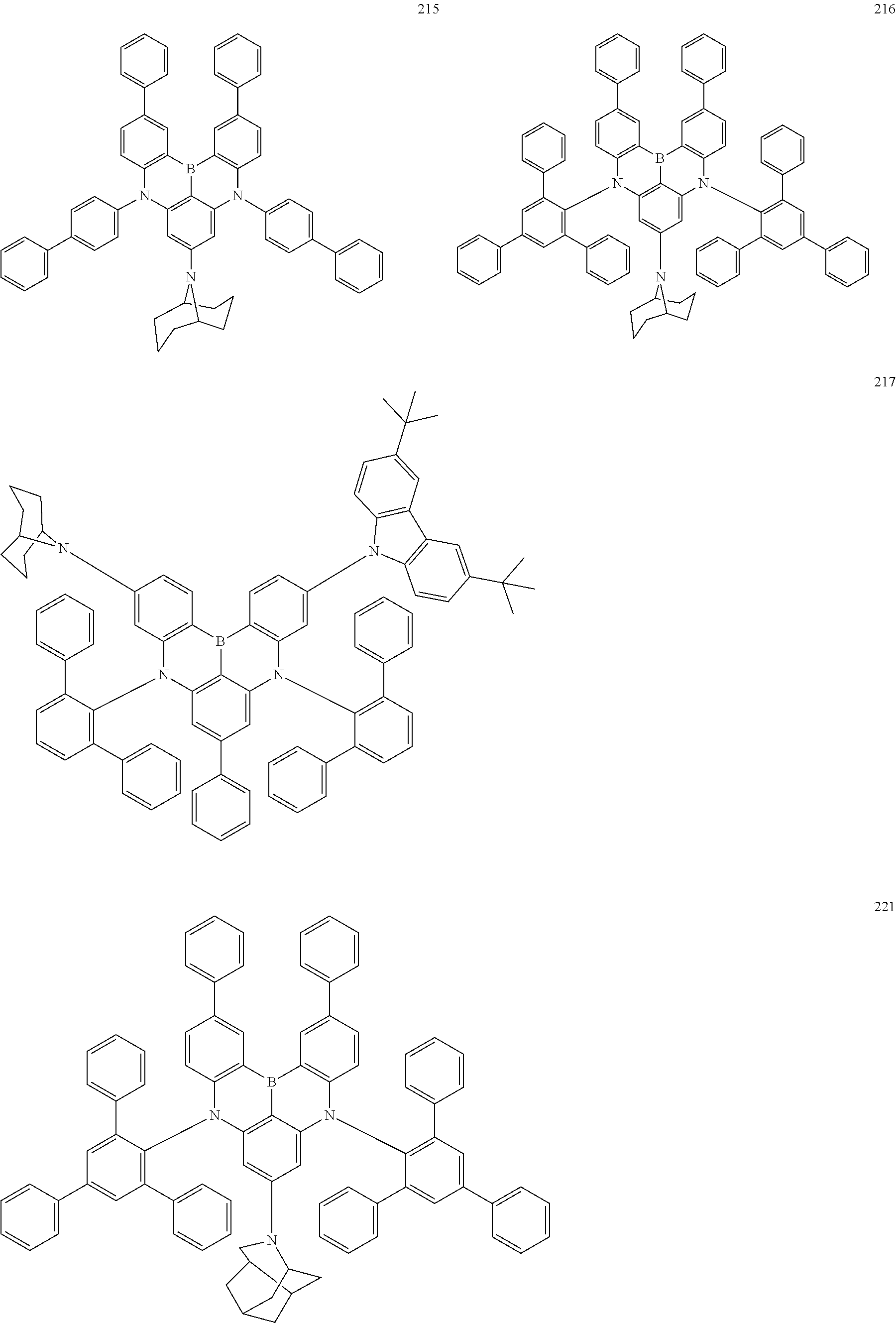

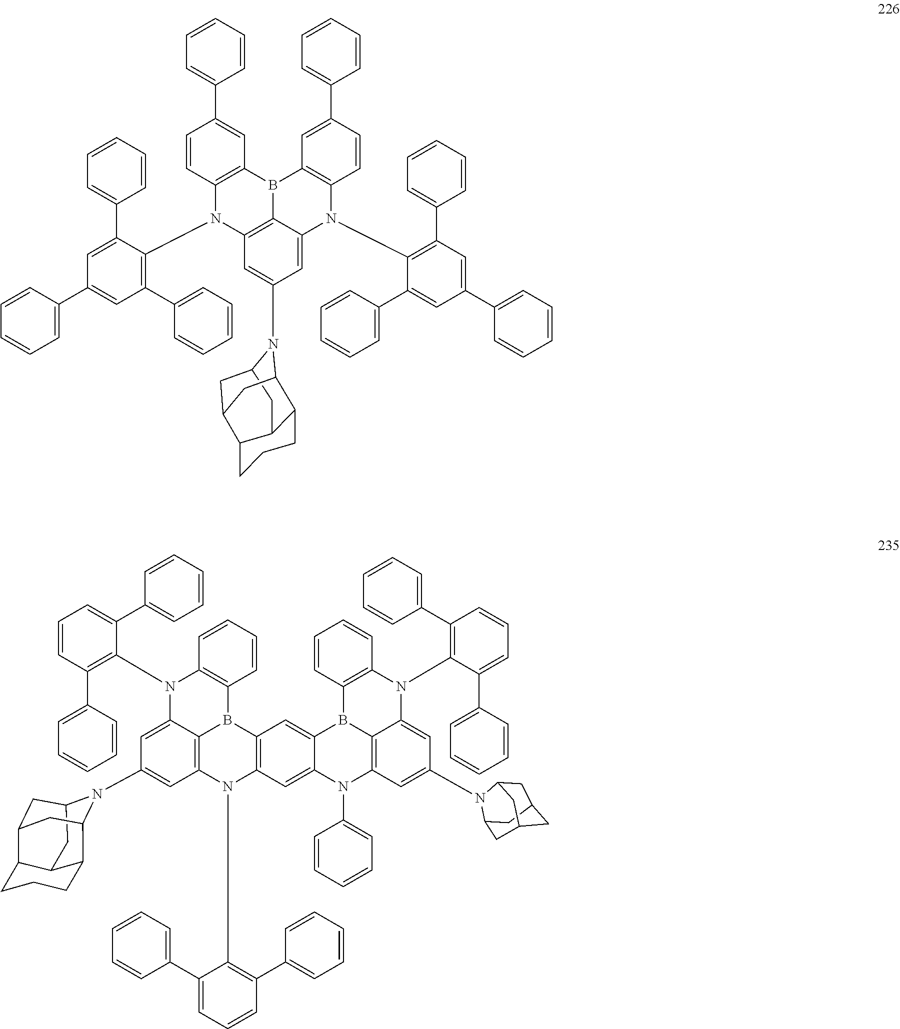 [SMILES: c1ccc(-c2ccc3c(c2)B2c4cc(-c5ccccc5)ccc4N(c4c(-c5ccccc5)cc(-c5ccccc5)cc4-c4ccccc4)c4cc(N5C6CC7CC5C5CCCC7C5C6)cc(c42)N3c2c(-c3ccccc3)cc(-c3ccccc3)cc2-c2ccccc2)cc1 ; c1ccc(-c2cccc(-c3ccccc3)c2N2c3ccccc3B3c4cc5c(cc4N(c4ccccc4)c4cc(N6C7CC8CC(C7)CC6C8)cc2c43)N(c2c(-c3ccccc3)cccc2-c2ccccc2)c2cc(N3C4CC6CC3C3CCCC6C3C4)cc3c2B5c2ccccc2N3c2c(-c3ccccc3)cccc2-c2ccccc2)cc1]

### Comparative Example Compounds

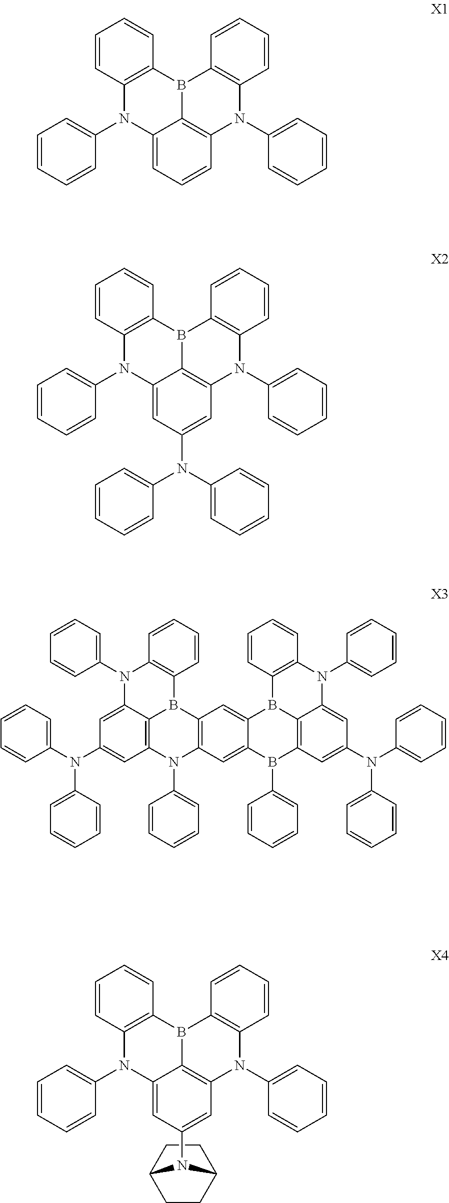 [SMILES: c1ccc(N2c3ccccc3B3c4ccccc4N(c4ccccc4)c4cccc2c43)cc1 ; c1ccc(N(c2ccccc2)c2cc3c4c(c2)N(c2ccccc2)c2ccccc2B4c2ccccc2N3c2ccccc2)cc1 ; c1ccc(B2c3cc4c(cc3B3c5ccccc5N(c5ccccc5)c5cc(N(c6ccccc6)c6ccccc6)cc2c53)B2c3ccccc3N(c3ccccc3)c3cc(N(c5ccccc5)c5ccccc5)cc(c32)N4c2ccccc2)cc1 ; c1ccc(N2c3ccccc3B3c4ccccc4N(c4ccccc4)c4cc(N5[C@H]6CC[C@@H]5CC6)cc2c43)cc1]

### (2) Evaluation of Light Emitting Elements

Evaluation results of the light emitting elements of Examples 1 to 11, and Comparative Examples 1 to 4 are listed in Table 1. A maximum emission wavelength (λₘₐₓ), a delayed fluorescence service life, roll-off, and a half service life (LT50) in each of the manufactured light emitting elements are listed in comparison in Table 1.

In the evaluation results of Examples and Comparative Examples listed in Table 1, the roll-off value is obtained by [[(external quantum efficiency at 1 cd/m²)−(external quantum efficiency at 1000 cd/m²)]/(external quantum efficiency at 1 cd/m²)]×100%. In addition, the half service life is the time taken for the brightness to reduce to 50% from an initial brightness of 100 cd/m². The half service life is shown as a ratio relative to the result of Comparative Example 3.

TABLE 1

| | | | Delayed | | |
|---|---|---|---|---|---|
| | | | fluorescence | | |
| | | λₘₐₓ | service life | Roll-off | |
| Division | Dopant Material | (nm) | (μs) | (%) | LT50 |
| Example 1 | Compound 2 | 458 | 10 | 13.6 | 2.1 |
| Example 2 | Compound 5 | 460 | 8.0 | 12.0 | 6.3 |
| Example 3 | Compound 72 | 459 | 7.0 | 21.0 | 4.2 |
| Example 4 | Compound 108 | 458 | 2.1 | 8.0 | 7.6 |
| Example 5 | Compound 185 | 459 | 3.2 | 10.0 | 5.2 |
| Example 6 | Compound 215 | 458 | 10.1 | 13.5 | 2.1 |
| Example 7 | Compound 216 | 460 | 8.0 | 12.0 | 6.3 |
| Example 8 | Compound 221 | 460 | 8.1 | 11.9 | 6.2 |
| Example 9 | Compound 226 | 460 | 8.0 | 12.0 | 6.2 |
| Example 10 | Compound 217 | 459 | 7.1 | 20.9 | 4.1 |
| Example 11 | Compound 235 | 459 | 3.2 | 9.9 | 5.2 |
| Comparative | Comparative | 457 | 130 | 33.2 | 0.3 |
| Example 1 | Example | | | | |
| | Compound X1 | | | | |
| Comparative | Comparative | 446 | 11.2 | 30.5 | 0.2 |
| Example 2 | Example | | | | |
| | Compound X2 | | | | |
| Comparative | Comparative | 467 | 5.5 | 13.5 | 1 |
| Example 3 | Example | | | | |
| | Compound X3 | | | | |
| Comparative | Comparative | 452 | 65 | 45.3 | 0.28 |
| Example 4 | Example | | | | |
| | Compound X4 | | | | |

Referring to the results of Table 1, Examples 1 to 11 of the present disclosure exhibited longer service life characteristics compared with Comparative Examples 1 to 4. It may be confirmed that the light emitting elements of Examples including, as an emission layer material, the polycyclic compound that includes the nitrogen-containing polycyclic group having at least eight ring-forming carbon atoms and containing at least two bridgehead carbon atoms exhibit longer service life characteristics compared with the light emitting elements of Comparative Examples including, as an emission layer material, Comparative Example Compounds that do not include the nitrogen-containing polycyclic group.

Referring to the evaluation results of Table 1, the maximum emission wavelength (λₘₐₓ) in each of Examples 1 to 11 is about 460 nm, which exhibited color purity close to pure blue compared with Comparative Examples. In addition, all of Examples 1 to 11 exhibited improved characteristics in the half service life compared with Comparative Examples 1 to 4.

When Examples 1 to 3, including Example Compounds containing one boron atom (B) in the polycyclic compound, are compared with Comparative Examples 1, 2, and 4, it may be seen that Examples 1 to 3 including an azaadamantyl group as the nitrogen-containing polycyclic group exhibited shorter delayed fluorescence service lives and smaller roll-off values. In addition, accordingly, it is confirmed that Examples 1 to 3 exhibited the results of significantly improved half service life compared with Comparative Examples 1, 2, and 4.

The light emitting element of Example 6 utilizing Example Compound 215, in which the azaadamantyl group that is a donor part of Compound 2 of Example 1 is altered to another type or kind of donor part, also exhibited the delayed fluorescence service life, roll-off characteristics, and half service life characteristics similar to Example 1. The light emitting elements of Examples 7, 8, and 9 utilizing Example Compounds 216, 221, and 226, in which the azaadamantyl group that is a donor part of Compound 5 of Example 2 is altered to another type or kind of donor part, also exhibited the delayed fluorescence service life, roll-off characteristics, and half service life characteristics similar to Example 2. In addition, the light emitting element of Example 10 utilizing Compound 217, in which the azaadamantyl group that is a donor part of Compound 72 of Example 3 is altered to another type or kind of donor part, also exhibited the delayed fluorescence service life, roll-off characteristics, and half service life characteristics similar to Example 3. Accordingly, from these results of Examples, it is confirmed that when the part corresponding to a donor part includes any one from among the following constituents may exhibit characteristics of the light emitting element similar to the results of other Examples:

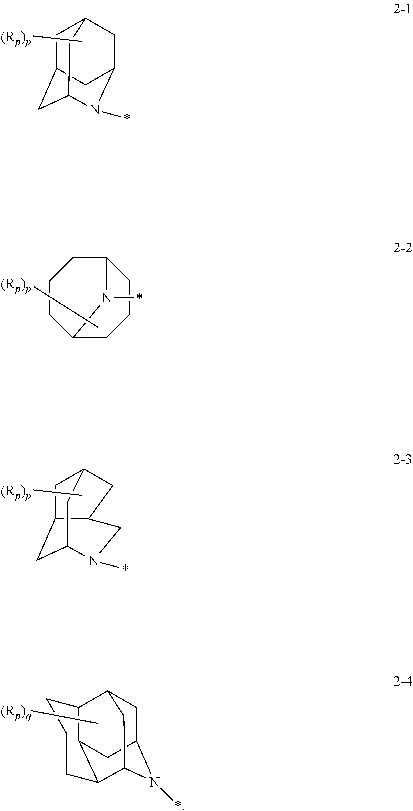

For example, when Example 1 including Example Compound 2 is compared with Comparative Example 4 including Comparative Example Compound X4, which has a similar compound structure to Example Compound 2, it may be confirmed that Example 1 having an azaadamantyl group in the part corresponding to a donor part has a significant improvement in the service life compared with Comparative Example 4. This is thought to be because Example Compound 2 is different from Comparative Example Compound X4 in that Example Compound 2 includes a bulky substituent such as an azaadamantyl group in the donor part. For example, it is believed that because Example Compounds include the nitrogen-containing polycyclic group having at least eight ring-forming carbon atoms and containing at least two bridgehead carbon atoms, which has a relatively large number of ring-forming carbon atoms, and thus have a greater steric shielding effect that protects the compound molecule, the stability of the compounds is increased, and the effect of improving the service lives of the light emitting elements including Example Compounds is exhibited.

In addition, when Examples 4 and 5 including Example Compounds containing two boron atoms (B) in the polycyclic compound are compared with Comparative Example 3, it may be seen that Examples 4 and 5 including an azaadamantyl group as the nitrogen-containing polycyclic group exhibited shorter delayed fluorescence service lives and smaller roll-off values. In addition, accordingly, it is confirmed that Examples 4 and 5 exhibited the results of significantly improved half service life compared with Comparative Example 3. For example, it is believed that because Example Compounds utilized in Examples 4 and 5 include the nitrogen-containing polycyclic group having at least eight ring-forming carbon atoms and containing at least two bridgehead carbon atoms, which has a relatively large number of ring-forming carbon atoms, and thus have a greater steric shielding effect that protects the compound molecule, the stability of the compounds is increased, and the effect of improving the service lives of the light emitting elements including Example Compounds is exhibited. In addition, the light emitting element of Example 11 utilizing Example Compound 235, in which the azaadamantyl group that is a donor part of Compound 108 of Example 4 is altered to another type or kind of donor part, also exhibited the delayed fluorescence service life, roll-off characteristics, and half service life characteristics similar to Example 4.

The polycyclic compound according to embodiments of the present disclosure has a structure that includes a core part of a fused ring containing a boron atom as a ring-forming atom, and further includes at least one nitrogen-containing polycyclic group which is substituted at the core part, contains at least two bridgehead carbon atoms, and has at least eight ring-forming carbon atoms, and thus the effect of improving the stability of the whole compound may be exhibited due to the steric structure of the nitrogen-containing polycyclic group. In addition, the light emitting element including the polycyclic compound may exhibit a long service life characteristic.

The light emitting element of an embodiment may include the polycyclic compound of an embodiment in the emission layer, thereby exhibiting a long service life characteristic.

The polycyclic compound of an embodiment may include the nitrogen-containing polycyclic group having a suitable or great steric shielding effect, thereby contributing to improving the service life of the light emitting element.

As used herein, the term “and/or” includes any and all combinations of one or more of the associated listed items. Throughout the disclosure, the expression “at least one of a, b or c”, “at least one selected from a, b, and c”, “at least one selected from the group consisting of a, b, and c”, “at least one from among a, b, and c”, etc., indicates only a, only b, only c, both (e.g., simultaneously) a and b, both (e.g., simultaneously) a and c, both (e.g., simultaneously) b and c, all of a, b, and c, or variations thereof.

The use of “may” when describing embodiments of the present disclosure refers to “one or more embodiments of the present disclosure”.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the present disclosure has been described with reference to a preferred embodiment of the present disclosure, it will be understood that the present disclosure should not be limited to these preferred embodiments but one or more suitable changes and modifications can be made by those skilled in the art without departing from the spirit and scope of the present disclosure.

Accordingly, the technical scope of the present disclosure is not intended to be limited to the contents set forth in the detailed description of the specification, but is intended to be defined by the appended claims, and equivalents thereof.

What is claimed is:

1. A light emitting element comprising:
a first electrode;
a second electrode on the first electrode; and
an emission layer between the first electrode and the second electrode,
wherein the emission layer comprises:
a first compound represented by Formula 1; and
at least one of a second compound represented by Formula HT-1, a third compound represented by Formula ET-1, or a fourth compound represented by Formula M-b: 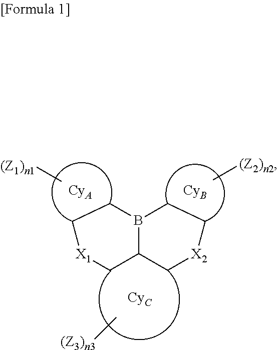
wherein, in Formula 1,
Cy_{A}, Cy_{B}, and Cy_{C} are each independently an aryl group having 6 to 30 ring-forming carbon atoms, or a heteroaryl group having 2 to 30 ring-forming carbon atoms,
X₁ and X₂ are each independently O, S, or NR₁,
R₁ is a substituted or unsubstituted aryl group having 6 to 30 ring-forming carbon atoms, or a substituted or unsubstituted heteroaryl group having 5 to 30 ring-forming carbon atoms,
n1, n2, and n3 are integers satisfying conditions of 0≤n1≤(the number of ring-forming carbon atoms of Cy_{A}-2), 0≤n2≤(the number of ring-forming carbon atoms of Cy_{B}-2), and 0≤n3≤(the number of ring-forming carbon atoms of Cy_{C}-2), respectively, and
(n1+n2+n3)≥1,
at least one from among Z₁, Z₂, and Z₃ being a nitrogen-containing polycyclic group having at least eight ring-forming carbon atoms and comprising at least two bridgehead carbon atoms, or a substituent comprising the nitrogen-containing polycyclic group, and any remainder from among Z₁, Z₂, and Z₃ being each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; 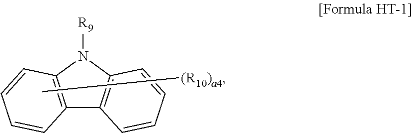
wherein, in Formula HT-1,
a4 is an integer of 0 to 8, and
R₉ and R₁₀ are each independently a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms; 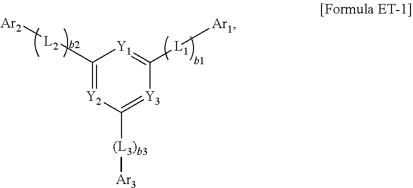
wherein, in Formula ET-1,
at least one from among Y₁ to Y₃ being N, and any remainder from among Y₁ to Y₃ being each independently CRₐ,
Rₐ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
b1 to b3 are each independently an integer of 0 to 10,
L₁ to L₃ are each independently a direct linkage, a substituted or unsubstituted arylene group having 6 to 30 ring-forming carbon atoms, or a substituted or unsubstituted heteroarylene group having 2 to 30 ring-forming carbon atoms, and
Ar₁ to Ar₂ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and 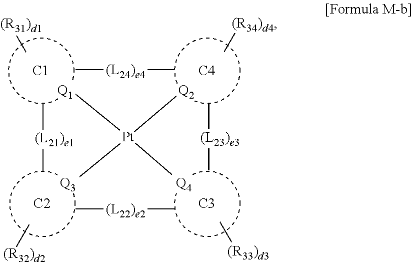
wherein, in Formula M-b,
Q₁ to Q₄ are each independently C or N,
C1 to C4 are each independently a substituted or unsubstituted hydrocarbon ring group having 5 to 30 ring-forming carbon atoms, or a substituted or unsubstituted heteroaryl group having 2 to 30 ring-forming carbon atoms,
e1 to e4 are each independently 0 or 1,
L₂₁ to L₂₄ are each independently a direct linkage, 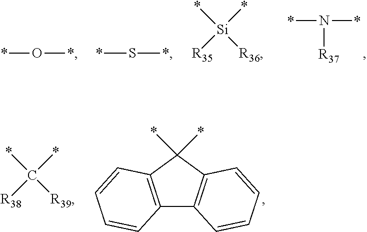
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
d1 to d4 are each independently an integer of 0 to 4, and
R₃₁ to R₃₉ are each independently a hydrogen atom, a deuterium atom, a halogen atom, a cyano group, a substituted or unsubstituted amine group, a substituted or unsubstituted divalent alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

2. The light emitting element of claim 1, wherein the first compound represented by Formula 1 is represented by Formula 1-1 or Formula 1-2: 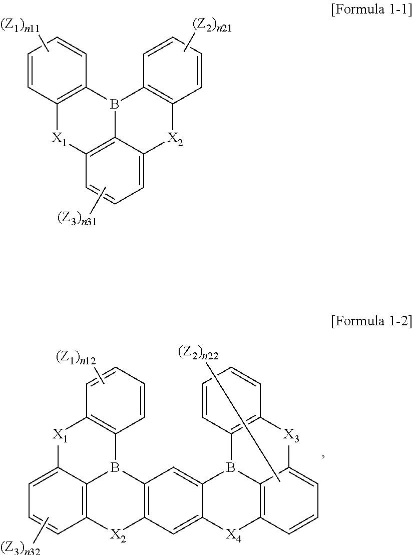
wherein, in Formula 1-1,
n11 and n21 are each independently an integer of 0 to 4,
n31 is an integer of 0 to 3,
a sum of n11, n21, and n31 is 1 or greater, and
wherein, in Formula 1-2,
X₃ and X₄ are each independently O, S, or NR₁,
n12 is an integer of 0 to 4,
n22 is an integer of 0 to 7,
n32 is an integer of 0 to 3,
a sum of n12, n22, and n32 is 1 or greater, and
in Formula 1-1 and Formula 1-2, X₁, X₂, R₁, Z₁, Z₂, and Z₃ are the same as respectively defined in Formula 1.

3. The light emitting element of claim 2, wherein the first compound represented by Formula 1-1 is represented by Formula 1-1a: 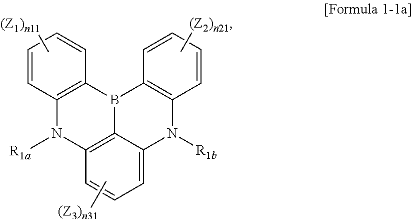
wherein, in Formula 1-1a,
R₁ₐ and R_{1b} are each independently a substituted or unsubstituted aryl group having 6 to 30 ring-forming carbon atoms, or a substituted or unsubstituted heteroaryl group having 5 to 30 ring-forming carbon atoms,
Z₁, Z₂, and Z₃ are the same as defined in Formula 1, and
n11, n21, and n31 are the same as respectively defined in Formula 1-1.

4. The light emitting element of claim 2, wherein the first compound represented by Formula 1-1 is represented by any one from among Formula 1-1b to Formula 1-1e: 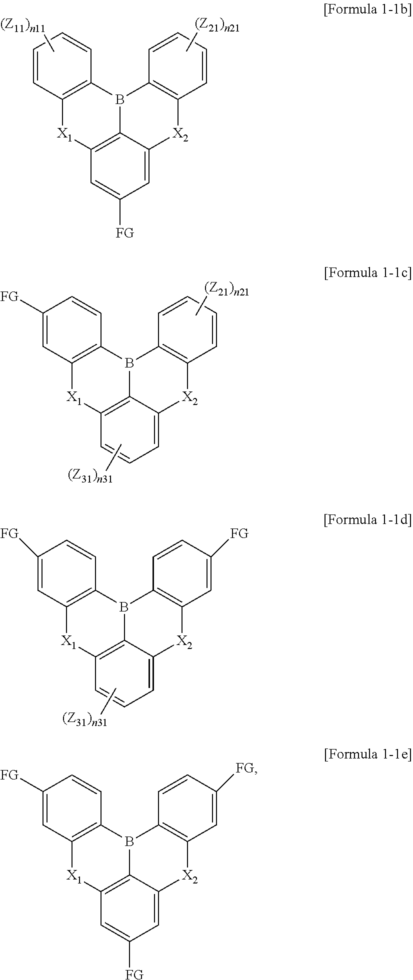
wherein, in Formula 1-1b to Formula 1-1e,
FG is the nitrogen-containing polycyclic group, or a substituent comprising the nitrogen-containing polycyclic group,
Z₂₁, and Z₃₁ are each independently a hydrogen atom, a deuterium atom, a halogen atom, a substituted or unsubstituted alkyl group having 1 to 20 carbon group, a substituted or unsubstituted aryl group having 6 to 30 ring-forming carbon atoms, or a substituted or unsubstituted heteroaryl group having 2 to 30 ring-forming carbon atoms,
n11 and n21 are each independently an integer of 0 to 4,
n31 is an integer of 0 to 3, and
X₁ and X₂ are the same as defined in Formula 1.

5. The light emitting element of claim 2, wherein the first compound represented by Formula 1-2 is represented by Formula 1-2a or Formula 1-2b: 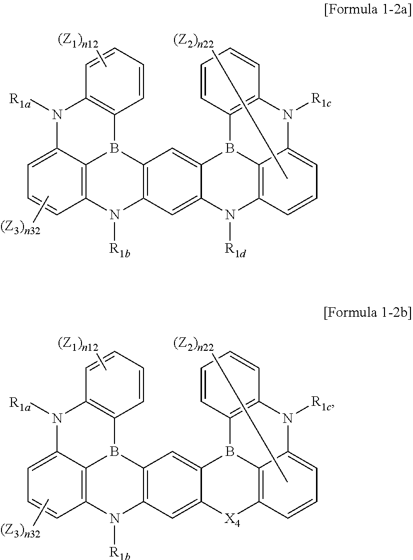
wherein, in Formula 1-2a and Formula 1-2b,
R₁ₐ, R_{1b}, R_{1c}, and R_{1d} are each independently a substituted or unsubstituted aryl group having 6 to 30 ring-forming carbon atoms, or a substituted or unsubstituted heteroaryl group having 5 to 30 ring-forming carbon atoms,
Z₁, Z₂, and Z₃ are the same as defined in Formula 1, and
X₄, n12, n22, and n32 are the same as respectively defined in Formula 1-2.

6. The light emitting element of claim 2, wherein the first compound represented by Formula 1-2 is represented by Formula 1-2c or Formula 1-2d: 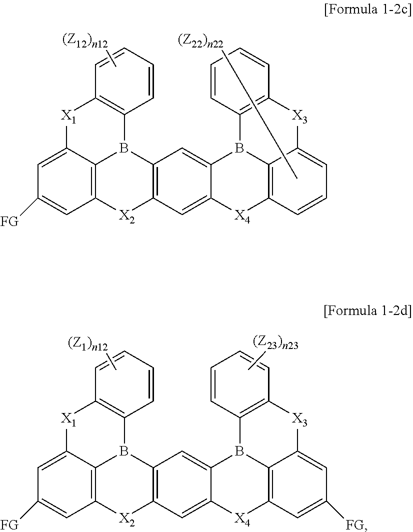
wherein, in Formula 1-2c and Formula 1-2d,
FG is the nitrogen-containing polycyclic group, or a substituent comprising the nitrogen-containing polycyclic group,
Z₁₂, Z₂₂, and Z₂₃ are each independently a hydrogen atom, a deuterium atom, a halogen atom, a substituted or unsubstituted alkyl group having 1 to 20 carbon group, a substituted or unsubstituted aryl group having 6 to 30 ring-forming carbon atoms, or a substituted or unsubstituted heteroaryl group having 2 to 30 ring-forming carbon atoms,
n12 and n23 are each independently an integer of 0 to 4,
n22 is an integer of 0 to 7, and
X₁ and X₂ are the same as defined in Formula 1, and X₃ and X₄ are the same as defined in Formula 1-2.

7. The light emitting element of claim 1, wherein the nitrogen-containing polycyclic group is represented by any one from among Formulae 2-1 to 2-4: 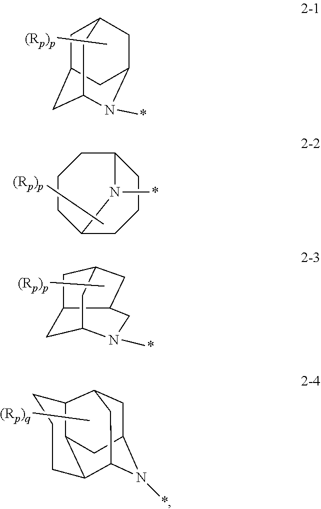
wherein, in Formulae 2-1 to 2-4, Rₚ is a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 5 to 30 ring-forming carbon atoms,
p is an integer of 0 to 14, and
q is an integer of 0 to 18.

8. The light emitting element of claim 1, wherein at least one from among Z₁, Z₂, and Z₃ is represented by any one from among Formulae 2-1 to 2-4 and 2-1a to 2-4a: 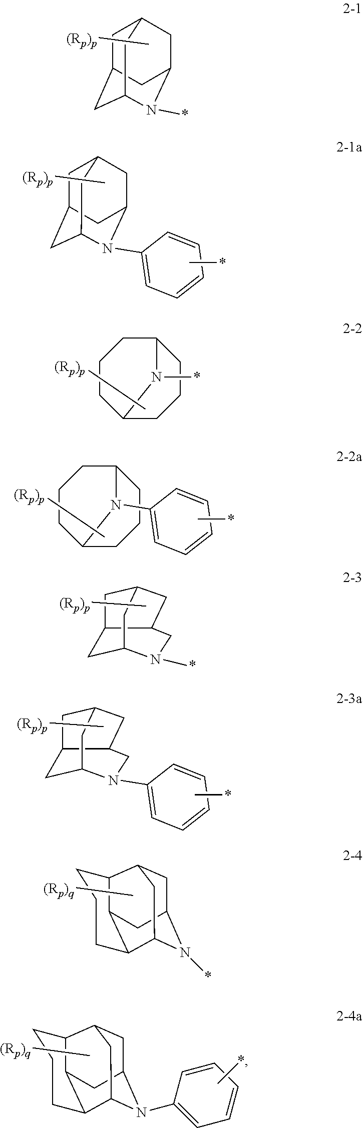
wherein, in 2-1 to 2-4 and 2-1a to 2-4a, Rₚ is a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 5 to 30 ring-forming carbon atoms,
p is an integer of 0 to 14, and
q is an integer of 0 to 18.

9. The light emitting element of claim 1, wherein at least one from among Z₂, and Z₃ in Formula 1 comprises a deuterium atom, or a substituent containing a deuterium atom.

10. The light emitting element of claim 1, wherein the emission layer comprises the first compound, the second compound, and the third compound.

11. The light emitting element of claim 1, wherein the emission layer comprises the first compound, the second compound, the third compound, and the fourth compound.

12. The light emitting element of claim 1, wherein the first compound is any one from among compounds of Compound Group 1: 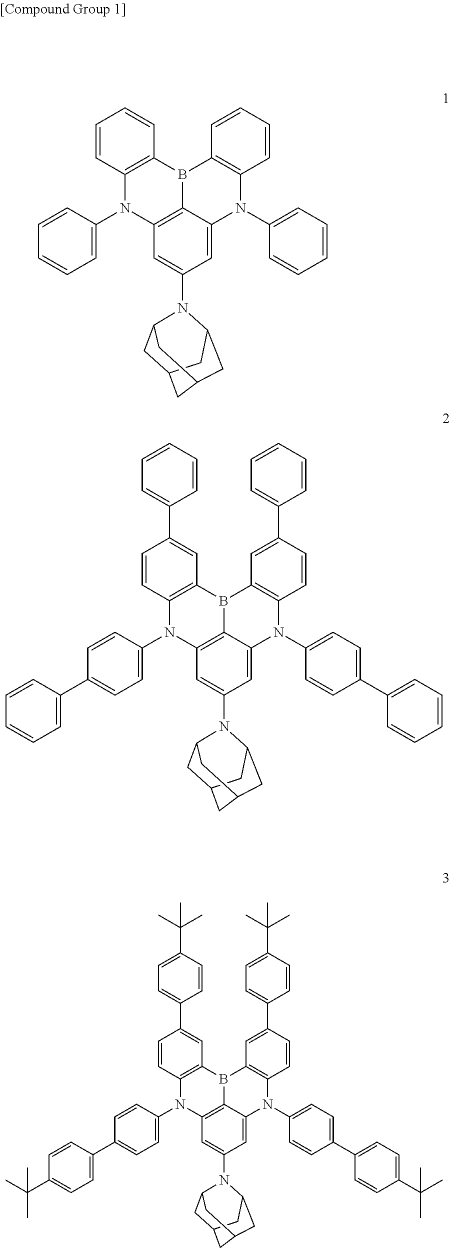 [SMILES: c1ccc(N2c3ccccc3B3c4ccccc4N(c4ccccc4)c4cc(N5C6CC7CC(C6)CC5C7)cc2c43)cc1 ; c1ccc(-c2ccc(N3c4ccc(-c5ccccc5)cc4B4c5cc(-c6ccccc6)ccc5N(c5ccc(-c6ccccc6)cc5)c5cc(N6C7CC8CC(C7)CC6C8)cc3c54)cc2)cc1 ; CC(C)(C)c1ccc(-c2ccc(N3c4ccc(-c5ccc(C(C)(C)C)cc5)cc4B4c5cc(-c6ccc(C(C)(C)C)cc6)ccc5N(c5ccc(-c6ccc(C(C)(C)C)cc6)cc5)c5cc(N6C7CC8CC(C7)CC6C8)cc3c54)cc2)cc1] 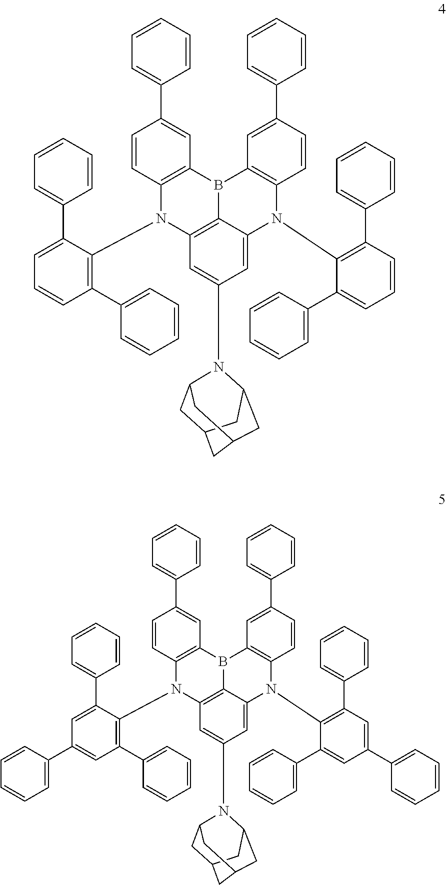 [SMILES: c1ccc(-c2ccc3c(c2)B2c4cc(-c5ccccc5)ccc4N(c4c(-c5ccccc5)cccc4-c4ccccc4)c4cc(N5C6CC7CC(C6)CC5C7)cc(c42)N3c2c(-c3ccccc3)cccc2-c2ccccc2)cc1 ; c1ccc(-c2ccc3c(c2)B2c4cc(-c5ccccc5)ccc4N(c4c(-c5ccccc5)cc(-c5ccccc5)cc4-c4ccccc4)c4cc(N5C6CC7CC(C6)CC5C7)cc(c42)N3c2c(-c3ccccc3)cc(-c3ccccc3)cc2-c2ccccc2)cc1] 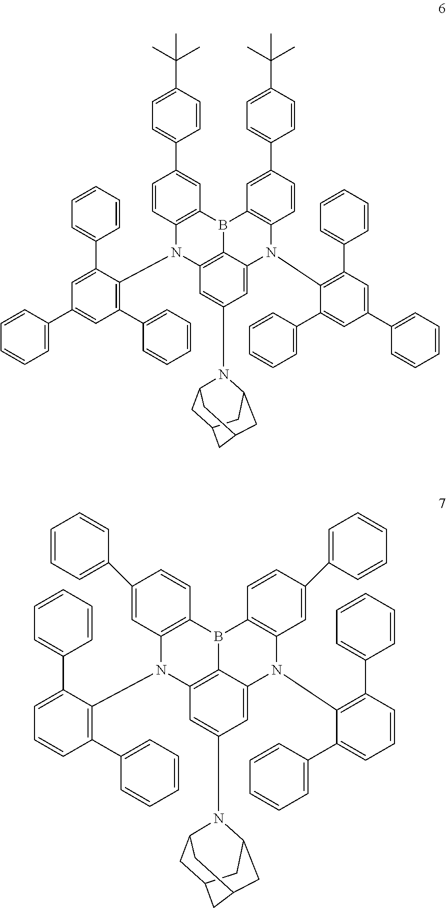 [SMILES: CC(C)(C)c1ccc(-c2ccc3c(c2)B2c4cc(-c5ccc(C(C)(C)C)cc5)ccc4N(c4c(-c5ccccc5)cc(-c5ccccc5)cc4-c4ccccc4)c4cc(N5C6CC7CC(C6)CC5C7)cc(c42)N3c2c(-c3ccccc3)cc(-c3ccccc3)cc2-c2ccccc2)cc1 ; c1ccc(-c2ccc3c(c2)N(c2c(-c4ccccc4)cccc2-c2ccccc2)c2cc(N4C5CC6CC(C5)CC4C6)cc4c2B3c2ccc(-c3ccccc3)cc2N4c2c(-c3ccccc3)cccc2-c2ccccc2)cc1] 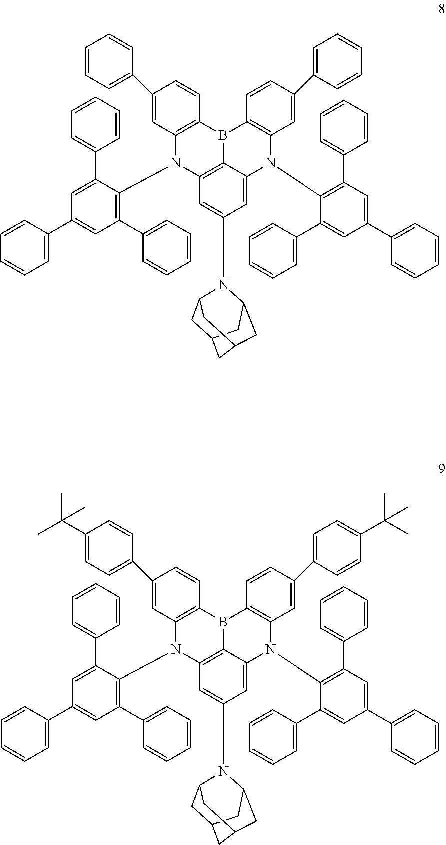 [SMILES: c1ccc(-c2cc(-c3ccccc3)c(N3c4cc(-c5ccccc5)ccc4B4c5ccc(-c6ccccc6)cc5N(c5c(-c6ccccc6)cc(-c6ccccc6)cc5-c5ccccc5)c5cc(N6C7CC8CC(C7)CC6C8)cc3c54)c(-c3ccccc3)c2)cc1 ; CC(C)(C)c1ccc(-c2ccc3c(c2)N(c2c(-c4ccccc4)cc(-c4ccccc4)cc2-c2ccccc2)c2cc(N4C5CC6CC(C5)CC4C6)cc4c2B3c2ccc(-c3ccc(C(C)(C)C)cc3)cc2N4c2c(-c3ccccc3)cc(-c3ccccc3)cc2-c2ccccc2)cc1] 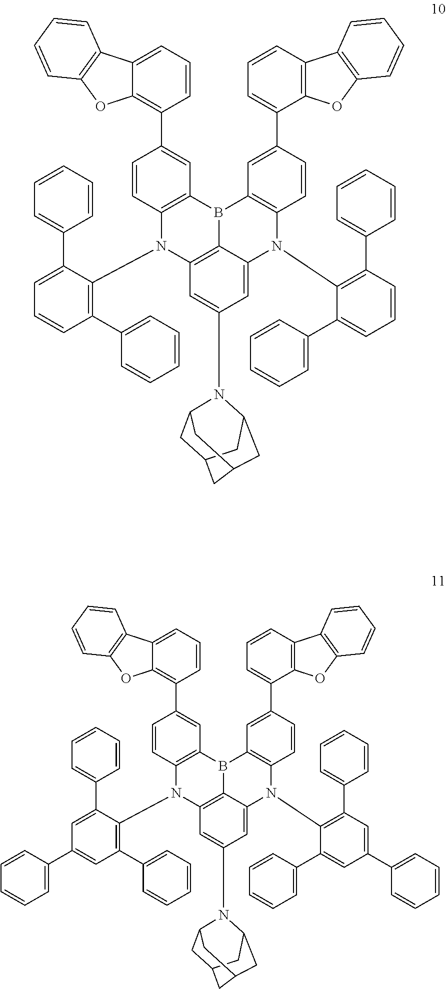 [SMILES: c1ccc(-c2cccc(-c3ccccc3)c2N2c3ccc(-c4cccc5c4oc4ccccc45)cc3B3c4cc(-c5cccc6c5oc5ccccc56)ccc4N(c4c(-c5ccccc5)cccc4-c4ccccc4)c4cc(N5C6CC7CC(C6)CC5C7)cc2c43)cc1 ; c1ccc(-c2cc(-c3ccccc3)c(N3c4ccc(-c5cccc6c5oc5ccccc56)cc4B4c5cc(-c6cccc7c6oc6ccccc67)ccc5N(c5c(-c6ccccc6)cc(-c6ccccc6)cc5-c5ccccc5)c5cc(N6C7CC8CC(C7)CC6C8)cc3c54)c(-c3ccccc3)c2)cc1] 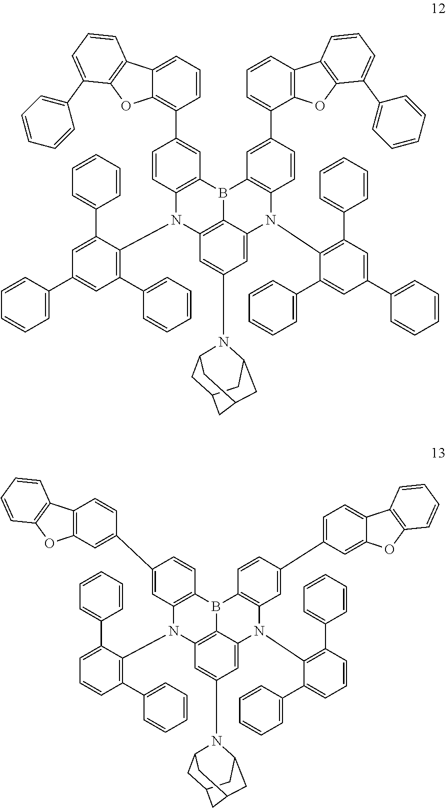 [SMILES: c1ccc(-c2cc(-c3ccccc3)c(N3c4ccc(-c5cccc6c5oc5c(-c7ccccc7)cccc56)cc4B4c5cc(-c6cccc7c6oc6c(-c8ccccc8)cccc67)ccc5N(c5c(-c6ccccc6)cc(-c6ccccc6)cc5-c5ccccc5)c5cc(N6C7CC8CC(C7)CC6C8)cc3c54)c(-c3ccccc3)c2)cc1 ; c1ccc(-c2cccc(-c3ccccc3)c2N2c3cc(-c4ccc5c(c4)oc4ccccc45)ccc3B3c4ccc(-c5ccc6c(c5)oc5ccccc56)cc4N(c4c(-c5ccccc5)cccc4-c4ccccc4)c4cc(N5C6CC7CC(C6)CC5C7)cc2c43)cc1] 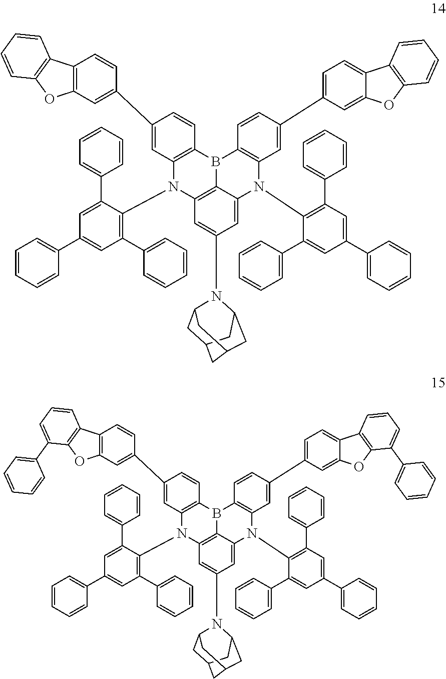 [SMILES: c1ccc(-c2cc(-c3ccccc3)c(N3c4cc(-c5ccc6c(c5)oc5ccccc56)ccc4B4c5ccc(-c6ccc7c(c6)oc6ccccc67)cc5N(c5c(-c6ccccc6)cc(-c6ccccc6)cc5-c5ccccc5)c5cc(N6C7CC8CC(C7)CC6C8)cc3c54)c(-c3ccccc3)c2)cc1 ; c1ccc(-c2cc(-c3ccccc3)c(N3c4cc(-c5ccc6c(c5)oc5c(-c7ccccc7)cccc56)ccc4B4c5ccc(-c6ccc7c(c6)oc6c(-c8ccccc8)cccc67)cc5N(c5c(-c6ccccc6)cc(-c6ccccc6)cc5-c5ccccc5)c5cc(N6C7CC8CC(C7)CC6C8)cc3c54)c(-c3ccccc3)c2)cc1] 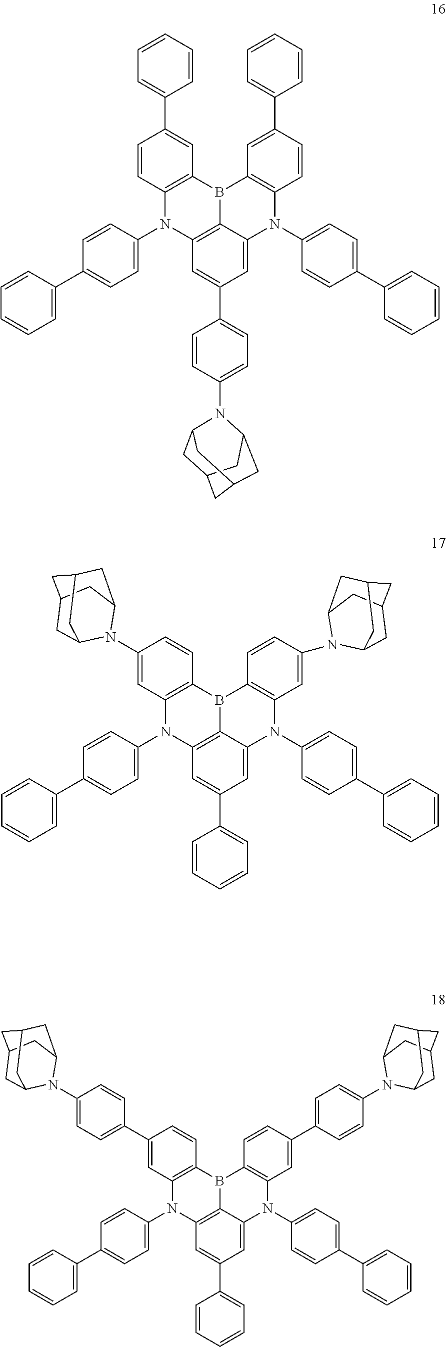 [SMILES: c1ccc(-c2ccc(N3c4ccc(-c5ccccc5)cc4B4c5cc(-c6ccccc6)ccc5N(c5ccc(-c6ccccc6)cc5)c5cc(-c6ccc(N7C8CC9CC(C8)CC7C9)cc6)cc3c54)cc2)cc1 ; c1ccc(-c2ccc(N3c4cc(N5C6CC7CC(C6)CC5C7)ccc4B4c5ccc(N6C7CC8CC(C7)CC6C8)cc5N(c5ccc(-c6ccccc6)cc5)c5cc(-c6ccccc6)cc3c54)cc2)cc1 ; c1ccc(-c2ccc(N3c4cc(-c5ccc(N6C7CC8CC(C7)CC6C8)cc5)ccc4B4c5ccc(-c6ccc(N7C8CC9CC(C8)CC7C9)cc6)cc5N(c5ccc(-c6ccccc6)cc5)c5cc(-c6ccccc6)cc3c54)cc2)cc1] 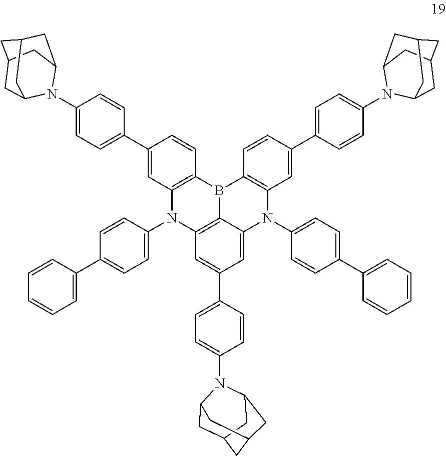 [SMILES: c1ccc(-c2ccc(N3c4cc(-c5ccc(N6C7CC8CC(C7)CC6C8)cc5)ccc4B4c5ccc(-c6ccc(N7C8CC9CC(C8)CC7C9)cc6)cc5N(c5ccc(-c6ccccc6)cc5)c5cc(-c6ccc(N7C8CC9CC(C8)CC7C9)cc6)cc3c54)cc2)cc1] 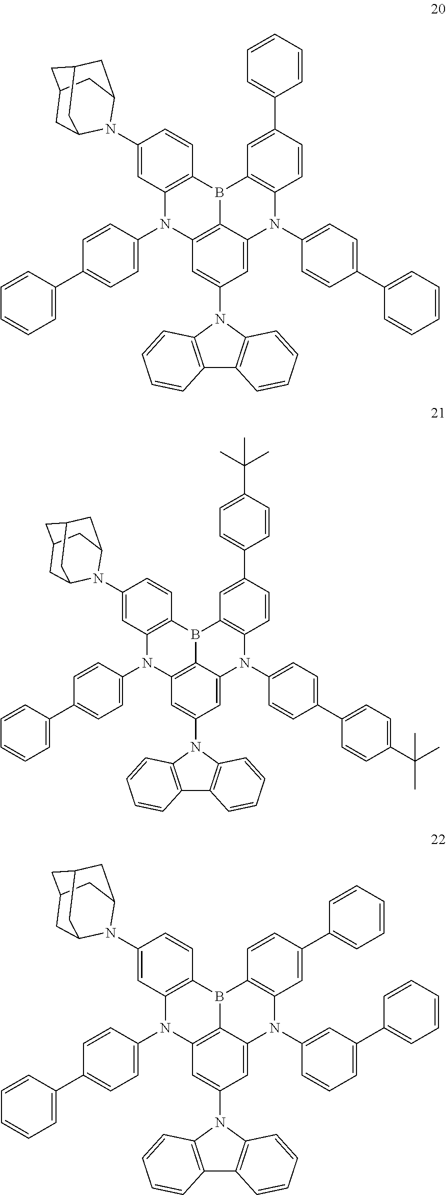 [SMILES: c1ccc(-c2ccc(N3c4ccc(-c5ccccc5)cc4B4c5ccc(N6C7CC8CC(C7)CC6C8)cc5N(c5ccc(-c6ccccc6)cc5)c5cc(-n6c7ccccc7c7ccccc76)cc3c54)cc2)cc1 ; CC(C)(C)c1ccc(-c2ccc(N3c4ccc(-c5ccc(C(C)(C)C)cc5)cc4B4c5ccc(N6C7CC8CC(C7)CC6C8)cc5N(c5ccc(-c6ccccc6)cc5)c5cc(-n6c7ccccc7c7ccccc76)cc3c54)cc2)cc1 ; c1ccc(-c2ccc(N3c4cc(N5C6CC7CC(C6)CC5C7)ccc4B4c5ccc(-c6ccccc6)cc5N(c5cccc(-c6ccccc6)c5)c5cc(-n6c7ccccc7c7ccccc76)cc3c54)cc2)cc1] 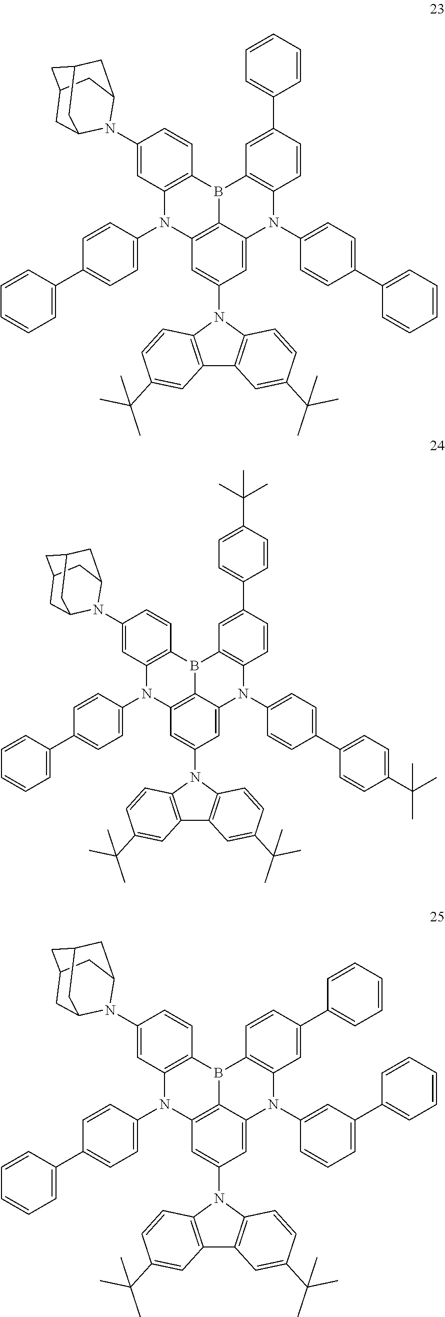 [SMILES: CC(C)(C)c1ccc2c(c1)c1cc(C(C)(C)C)ccc1n2-c1cc2c3c(c1)N(c1ccc(-c4ccccc4)cc1)c1cc(N4C5CC6CC(C5)CC4C6)ccc1B3c1cc(-c3ccccc3)ccc1N2c1ccc(-c2ccccc2)cc1 ; CC(C)(C)c1ccc(-c2ccc(N3c4ccc(-c5ccc(C(C)(C)C)cc5)cc4B4c5ccc(N6C7CC8CC(C7)CC6C8)cc5N(c5ccc(-c6ccccc6)cc5)c5cc(-n6c7ccc(C(C)(C)C)cc7c7cc(C(C)(C)C)ccc76)cc3c54)cc2)cc1 ; CC(C)(C)c1ccc2c(c1)c1cc(C(C)(C)C)ccc1n2-c1cc2c3c(c1)N(c1ccc(-c4ccccc4)cc1)c1cc(N4C5CC6CC(C5)CC4C6)ccc1B3c1ccc(-c3ccccc3)cc1N2c1cccc(-c2ccccc2)c1] 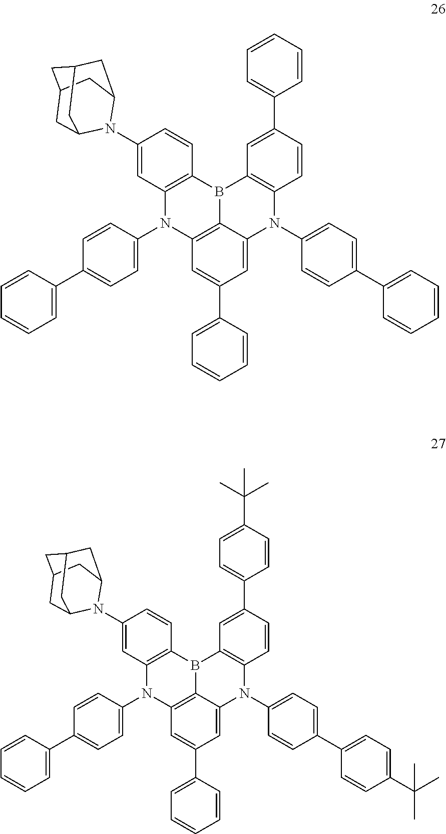 [SMILES: c1ccc(-c2ccc(N3c4ccc(-c5ccccc5)cc4B4c5ccc(N6C7CC8CC(C7)CC6C8)cc5N(c5ccc(-c6ccccc6)cc5)c5cc(-c6ccccc6)cc3c54)cc2)cc1 ; CC(C)(C)c1ccc(-c2ccc(N3c4ccc(-c5ccc(C(C)(C)C)cc5)cc4B4c5ccc(N6C7CC8CC(C7)CC6C8)cc5N(c5ccc(-c6ccccc6)cc5)c5cc(-c6ccccc6)cc3c54)cc2)cc1] 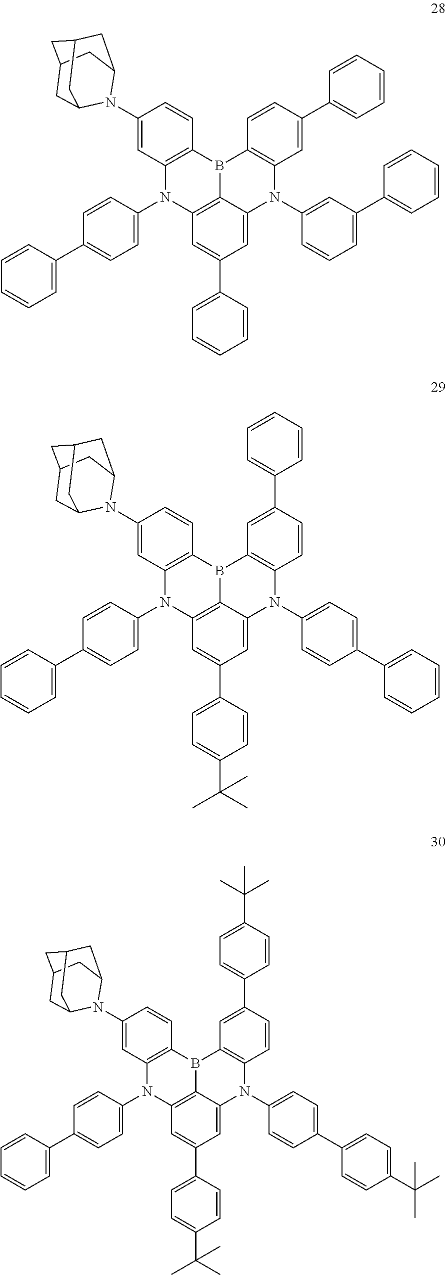 [SMILES: c1ccc(-c2ccc(N3c4cc(N5C6CC7CC(C6)CC5C7)ccc4B4c5ccc(-c6ccccc6)cc5N(c5cccc(-c6ccccc6)c5)c5cc(-c6ccccc6)cc3c54)cc2)cc1 ; CC(C)(C)c1ccc(-c2cc3c4c(c2)N(c2ccc(-c5ccccc5)cc2)c2cc(N5C6CC7CC(C6)CC5C7)ccc2B4c2cc(-c4ccccc4)ccc2N3c2ccc(-c3ccccc3)cc2)cc1 ; CC(C)(C)c1ccc(-c2ccc(N3c4ccc(-c5ccc(C(C)(C)C)cc5)cc4B4c5ccc(N6C7CC8CC(C7)CC6C8)cc5N(c5ccc(-c6ccccc6)cc5)c5cc(-c6ccc(C(C)(C)C)cc6)cc3c54)cc2)cc1] 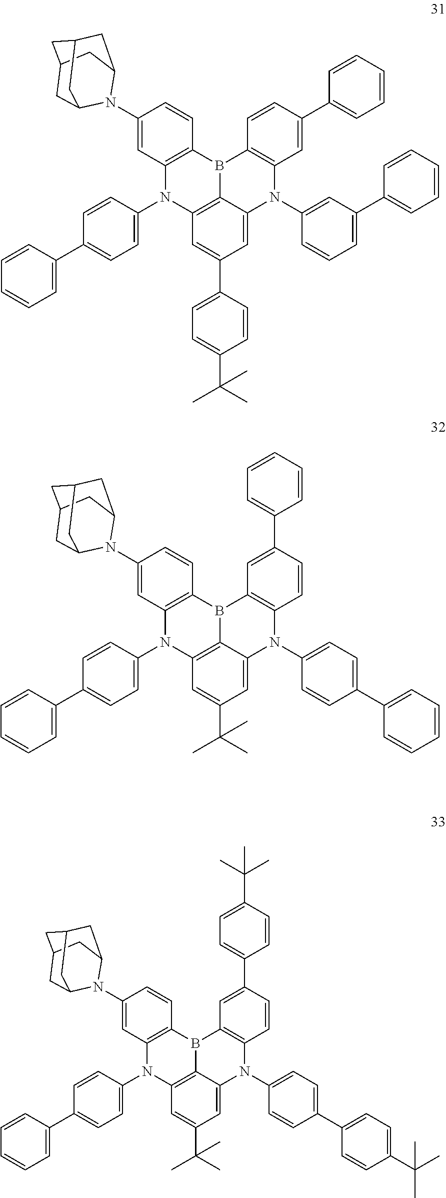 [SMILES: CC(C)(C)c1ccc(-c2cc3c4c(c2)N(c2ccc(-c5ccccc5)cc2)c2cc(N5C6CC7CC(C6)CC5C7)ccc2B4c2ccc(-c4ccccc4)cc2N3c2cccc(-c3ccccc3)c2)cc1 ; CC(C)(C)c1cc2c3c(c1)N(c1ccc(-c4ccccc4)cc1)c1cc(N4C5CC6CC(C5)CC4C6)ccc1B3c1cc(-c3ccccc3)ccc1N2c1ccc(-c2ccccc2)cc1 ; CC(C)(C)c1ccc(-c2ccc(N3c4ccc(-c5ccc(C(C)(C)C)cc5)cc4B4c5ccc(N6C7CC8CC(C7)CC6C8)cc5N(c5ccc(-c6ccccc6)cc5)c5cc(C(C)(C)C)cc3c54)cc2)cc1] 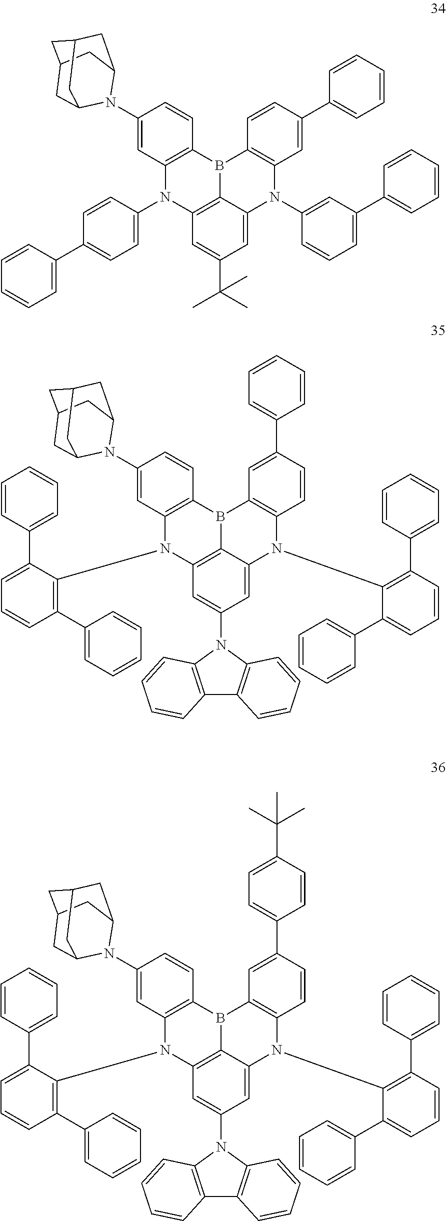 [SMILES: CC(C)(C)c1cc2c3c(c1)N(c1ccc(-c4ccccc4)cc1)c1cc(N4C5CC6CC(C5)CC4C6)ccc1B3c1ccc(-c3ccccc3)cc1N2c1cccc(-c2ccccc2)c1 ; c1ccc(-c2ccc3c(c2)B2c4ccc(N5C6CC7CC(C6)CC5C7)cc4N(c4c(-c5ccccc5)cccc4-c4ccccc4)c4cc(-n5c6ccccc6c6ccccc65)cc(c42)N3c2c(-c3ccccc3)cccc2-c2ccccc2)cc1 ; CC(C)(C)c1ccc(-c2ccc3c(c2)B2c4ccc(N5C6CC7CC(C6)CC5C7)cc4N(c4c(-c5ccccc5)cccc4-c4ccccc4)c4cc(-n5c6ccccc6c6ccccc65)cc(c42)N3c2c(-c3ccccc3)cccc2-c2ccccc2)cc1] 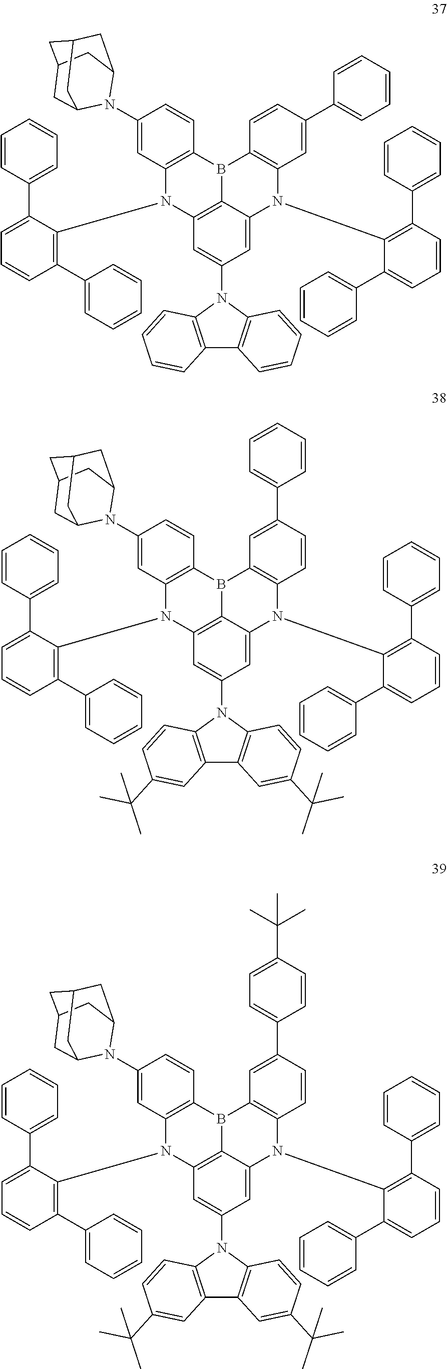 [SMILES: c1ccc(-c2ccc3c(c2)N(c2c(-c4ccccc4)cccc2-c2ccccc2)c2cc(-n4c5ccccc5c5ccccc54)cc4c2B3c2ccc(N3C5CC6CC(C5)CC3C6)cc2N4c2c(-c3ccccc3)cccc2-c2ccccc2)cc1 ; CC(C)(C)c1ccc2c(c1)c1cc(C(C)(C)C)ccc1n2-c1cc2c3c(c1)N(c1c(-c4ccccc4)cccc1-c1ccccc1)c1cc(N4C5CC6CC(C5)CC4C6)ccc1B3c1cc(-c3ccccc3)ccc1N2c1c(-c2ccccc2)cccc1-c1ccccc1 ; CC(C)(C)c1ccc(-c2ccc3c(c2)B2c4ccc(N5C6CC7CC(C6)CC5C7)cc4N(c4c(-c5ccccc5)cccc4-c4ccccc4)c4cc(-n5c6ccc(C(C)(C)C)cc6c6cc(C(C)(C)C)ccc65)cc(c42)N3c2c(-c3ccccc3)cccc2-c2ccccc2)cc1] 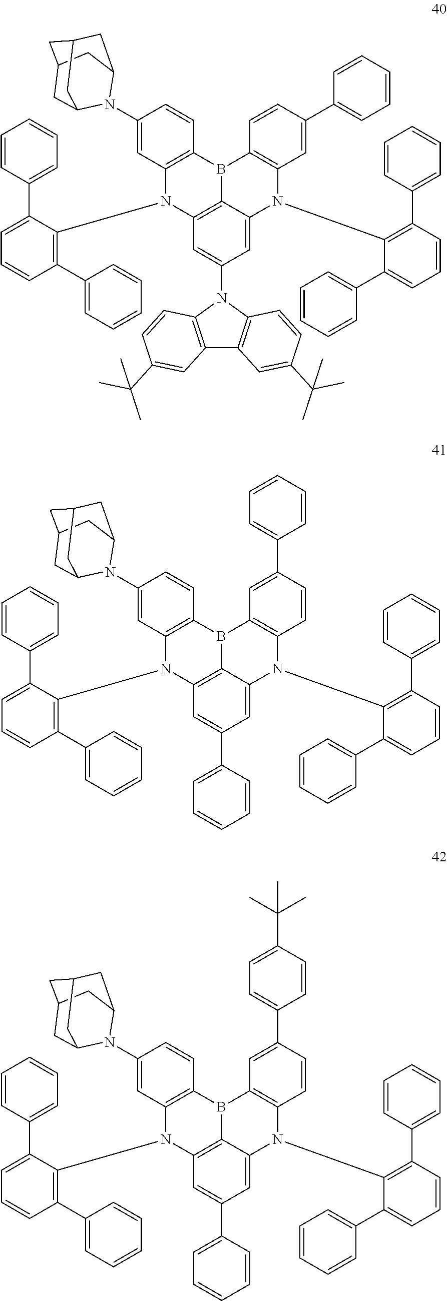 [SMILES: CC(C)(C)c1ccc2c(c1)c1cc(C(C)(C)C)ccc1n2-c1cc2c3c(c1)N(c1c(-c4ccccc4)cccc1-c1ccccc1)c1cc(N4C5CC6CC(C5)CC4C6)ccc1B3c1ccc(-c3ccccc3)cc1N2c1c(-c2ccccc2)cccc1-c1ccccc1 ; c1ccc(-c2ccc3c(c2)B2c4ccc(N5C6CC7CC(C6)CC5C7)cc4N(c4c(-c5ccccc5)cccc4-c4ccccc4)c4cc(-c5ccccc5)cc(c42)N3c2c(-c3ccccc3)cccc2-c2ccccc2)cc1 ; CC(C)(C)c1ccc(-c2ccc3c(c2)B2c4ccc(N5C6CC7CC(C6)CC5C7)cc4N(c4c(-c5ccccc5)cccc4-c4ccccc4)c4cc(-c5ccccc5)cc(c42)N3c2c(-c3ccccc3)cccc2-c2ccccc2)cc1] 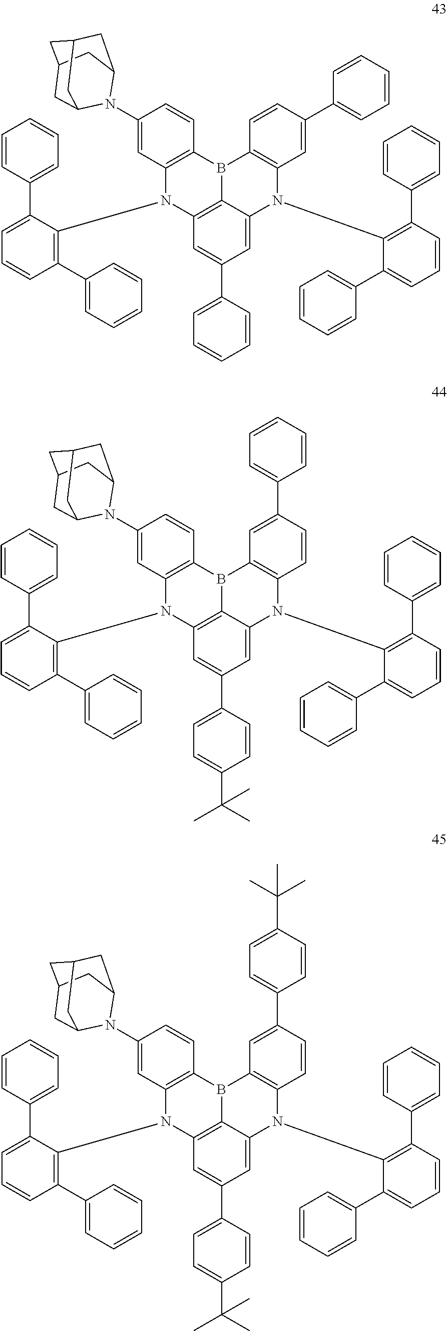 [SMILES: c1ccc(-c2ccc3c(c2)N(c2c(-c4ccccc4)cccc2-c2ccccc2)c2cc(-c4ccccc4)cc4c2B3c2ccc(N3C5CC6CC(C5)CC3C6)cc2N4c2c(-c3ccccc3)cccc2-c2ccccc2)cc1 ; CC(C)(C)c1ccc(-c2cc3c4c(c2)N(c2c(-c5ccccc5)cccc2-c2ccccc2)c2cc(N5C6CC7CC(C6)CC5C7)ccc2B4c2cc(-c4ccccc4)ccc2N3c2c(-c3ccccc3)cccc2-c2ccccc2)cc1 ; CC(C)(C)c1ccc(-c2ccc3c(c2)B2c4ccc(N5C6CC7CC(C6)CC5C7)cc4N(c4c(-c5ccccc5)cccc4-c4ccccc4)c4cc(-c5ccc(C(C)(C)C)cc5)cc(c42)N3c2c(-c3ccccc3)cccc2-c2ccccc2)cc1] 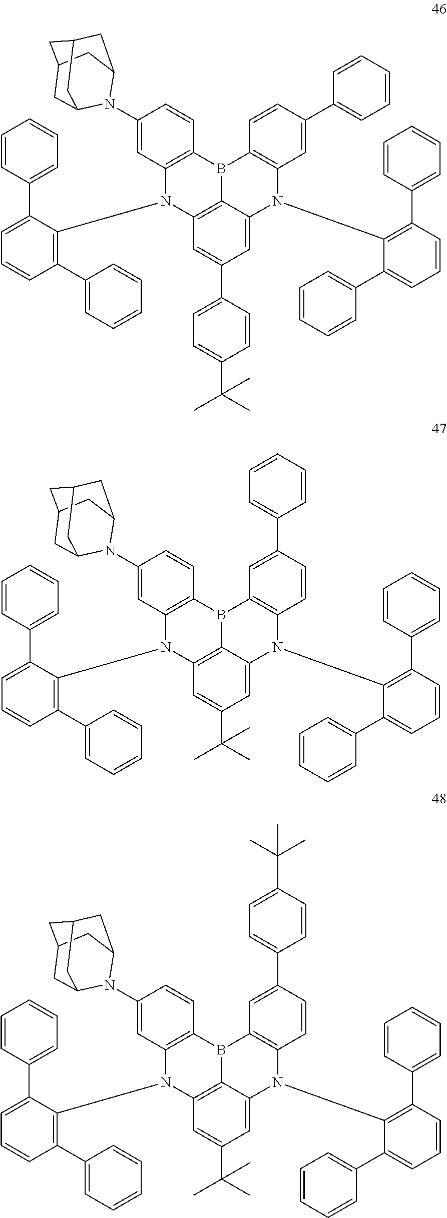 [SMILES: CC(C)(C)c1ccc(-c2cc3c4c(c2)N(c2c(-c5ccccc5)cccc2-c2ccccc2)c2cc(N5C6CC7CC(C6)CC5C7)ccc2B4c2ccc(-c4ccccc4)cc2N3c2c(-c3ccccc3)cccc2-c2ccccc2)cc1 ; CC(C)(C)c1cc2c3c(c1)N(c1c(-c4ccccc4)cccc1-c1ccccc1)c1cc(N4C5CC6CC(C5)CC4C6)ccc1B3c1cc(-c3ccccc3)ccc1N2c1c(-c2ccccc2)cccc1-c1ccccc1 ; CC(C)(C)c1ccc(-c2ccc3c(c2)B2c4ccc(N5C6CC7CC(C6)CC5C7)cc4N(c4c(-c5ccccc5)cccc4-c4ccccc4)c4cc(C(C)(C)C)cc(c42)N3c2c(-c3ccccc3)cccc2-c2ccccc2)cc1] 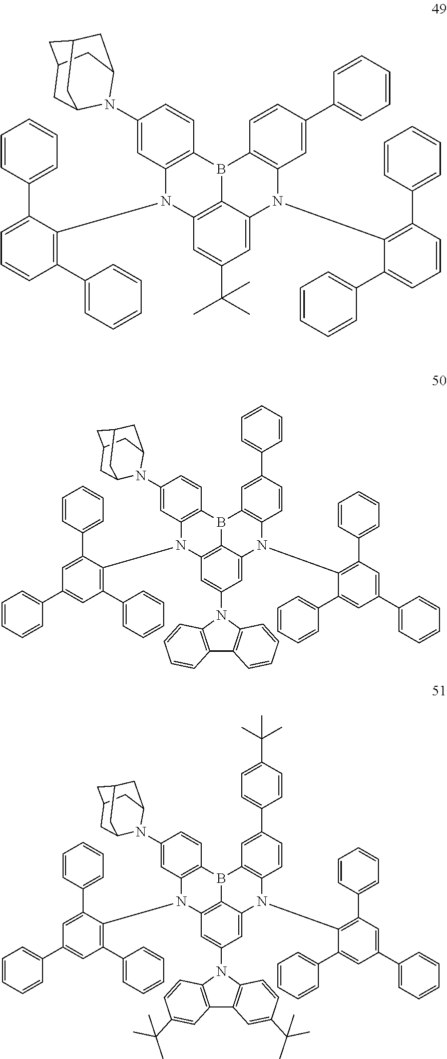 [SMILES: CC(C)(C)c1cc2c3c(c1)N(c1c(-c4ccccc4)cccc1-c1ccccc1)c1cc(N4C5CC6CC(C5)CC4C6)ccc1B3c1ccc(-c3ccccc3)cc1N2c1c(-c2ccccc2)cccc1-c1ccccc1 ; c1ccc(-c2ccc3c(c2)B2c4ccc(N5C6CC7CC(C6)CC5C7)cc4N(c4c(-c5ccccc5)cc(-c5ccccc5)cc4-c4ccccc4)c4cc(-n5c6ccccc6c6ccccc65)cc(c42)N3c2c(-c3ccccc3)cc(-c3ccccc3)cc2-c2ccccc2)cc1 ; CC(C)(C)c1ccc(-c2ccc3c(c2)B2c4ccc(N5C6CC7CC(C6)CC5C7)cc4N(c4c(-c5ccccc5)cc(-c5ccccc5)cc4-c4ccccc4)c4cc(-n5c6ccc(C(C)(C)C)cc6c6cc(C(C)(C)C)ccc65)cc(c42)N3c2c(-c3ccccc3)cc(-c3ccccc3)cc2-c2ccccc2)cc1] 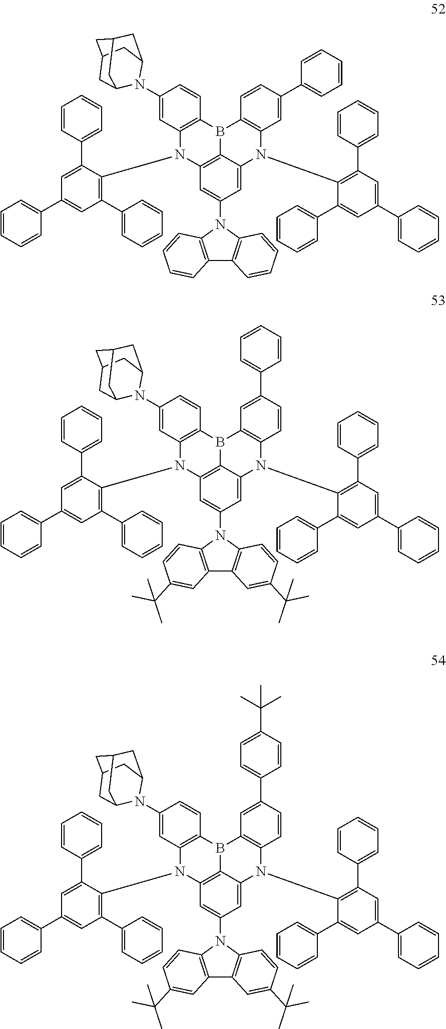 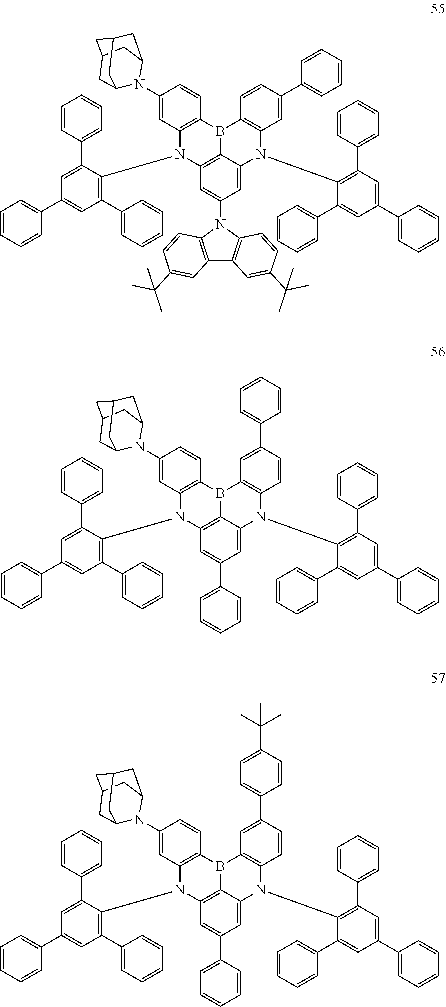 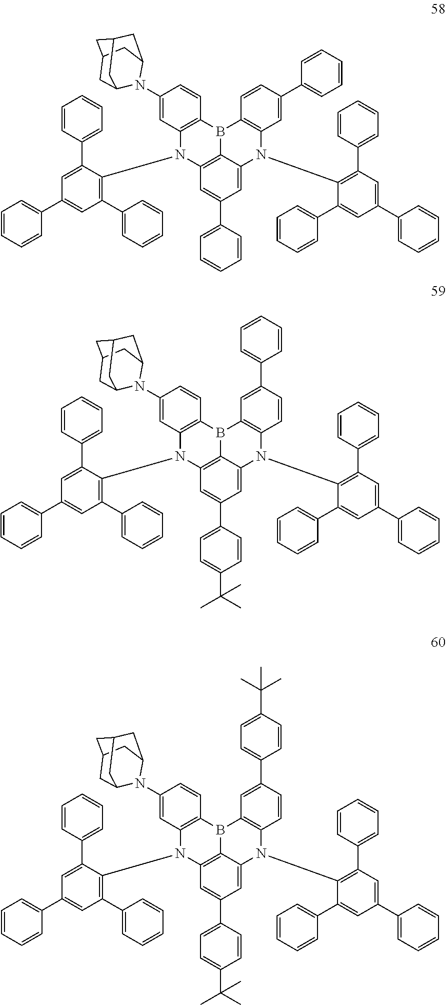 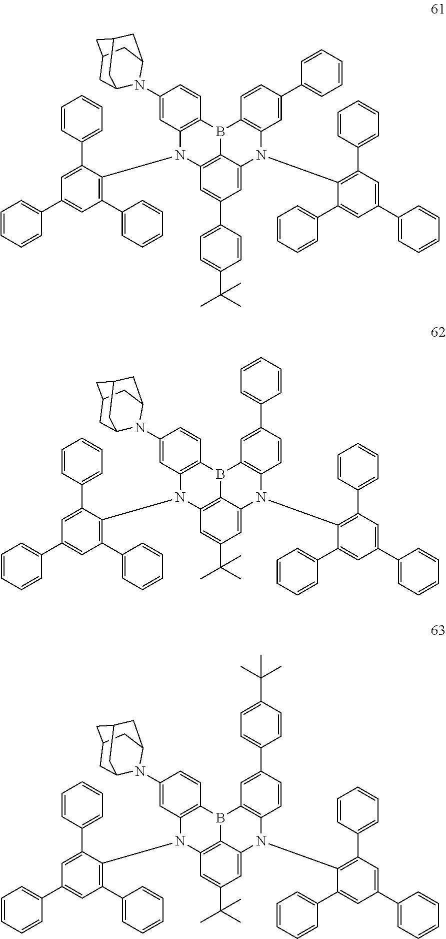 [SMILES: CC(C)(C)c1ccc(-c2cc3c4c(c2)N(c2c(-c5ccccc5)cc(-c5ccccc5)cc2-c2ccccc2)c2cc(N5C6CC7CC(C6)CC5C7)ccc2B4c2ccc(-c4ccccc4)cc2N3c2c(-c3ccccc3)cc(-c3ccccc3)cc2-c2ccccc2)cc1 ; CC(C)(C)c1cc2c3c(c1)N(c1c(-c4ccccc4)cc(-c4ccccc4)cc1-c1ccccc1)c1cc(N4C5CC6CC(C5)CC4C6)ccc1B3c1cc(-c3ccccc3)ccc1N2c1c(-c2ccccc2)cc(-c2ccccc2)cc1-c1ccccc1 ; CC(C)(C)c1ccc(-c2ccc3c(c2)B2c4ccc(N5C6CC7CC(C6)CC5C7)cc4N(c4c(-c5ccccc5)cc(-c5ccccc5)cc4-c4ccccc4)c4cc(C(C)(C)C)cc(c42)N3c2c(-c3ccccc3)cc(-c3ccccc3)cc2-c2ccccc2)cc1] 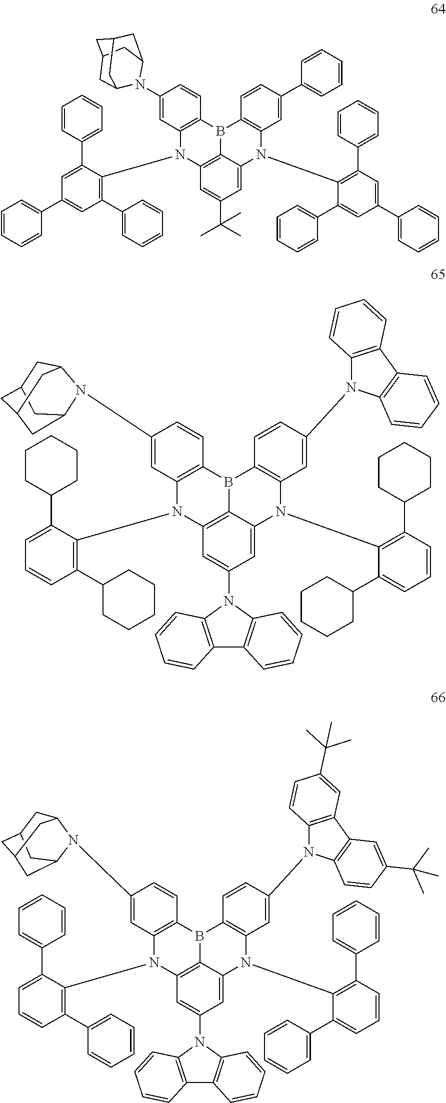 [SMILES: CC(C)(C)c1cc2c3c(c1)N(c1c(-c4ccccc4)cc(-c4ccccc4)cc1-c1ccccc1)c1cc(N4C5CC6CC(C5)CC4C6)ccc1B3c1ccc(-c3ccccc3)cc1N2c1c(-c2ccccc2)cc(-c2ccccc2)cc1-c1ccccc1 ; c1cc(C2CCCCC2)c(N2c3cc(N4C5CC6CC(C5)CC4C6)ccc3B3c4ccc(-n5c6ccccc6c6ccccc65)cc4N(c4c(C5CCCCC5)cccc4C4CCCCC4)c4cc(-n5c6ccccc6c6ccccc65)cc2c43)c(C2CCCCC2)c1 ; CC(C)(C)c1ccc2c(c1)c1cc(C(C)(C)C)ccc1n2-c1ccc2c(c1)N(c1c(-c3ccccc3)cccc1-c1ccccc1)c1cc(-n3c4ccccc4c4ccccc43)cc3c1B2c1ccc(N2C4CC5CC(C4)CC2C5)cc1N3c1c(-c2ccccc2)cccc1-c1ccccc1] 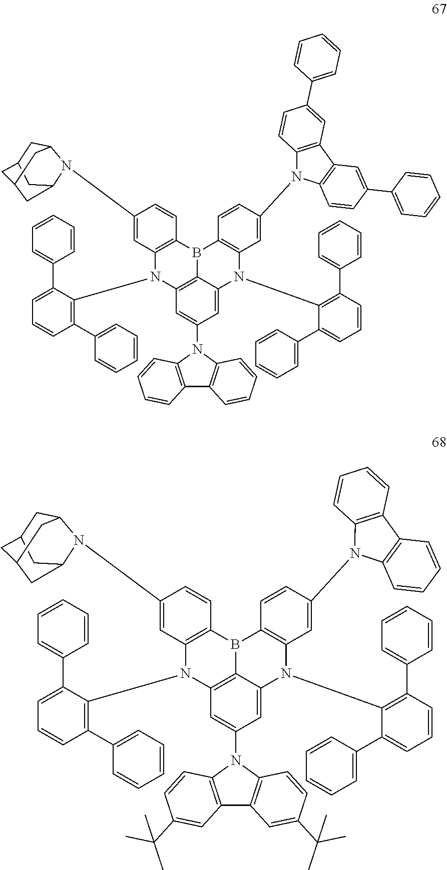 [SMILES: c1ccc(-c2ccc3c(c2)c2cc(-c4ccccc4)ccc2n3-c2ccc3c(c2)N(c2c(-c4ccccc4)cccc2-c2ccccc2)c2cc(-n4c5ccccc5c5ccccc54)cc4c2B3c2ccc(N3C5CC6CC(C5)CC3C6)cc2N4c2c(-c3ccccc3)cccc2-c2ccccc2)cc1 ; CC(C)(C)c1ccc2c(c1)c1cc(C(C)(C)C)ccc1n2-c1cc2c3c(c1)N(c1c(-c4ccccc4)cccc1-c1ccccc1)c1cc(-n4c5ccccc5c5ccccc54)ccc1B3c1ccc(N3C4CC5CC(C4)CC3C5)cc1N2c1c(-c2ccccc2)cccc1-c1ccccc1] 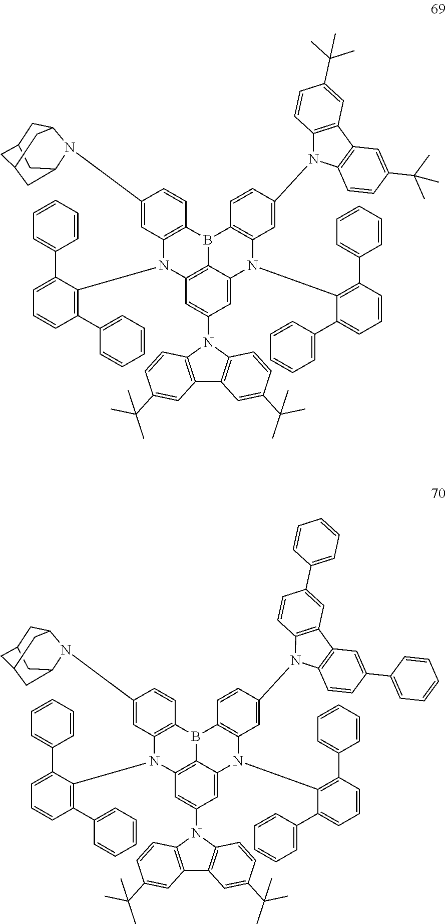 [SMILES: CC(C)(C)c1ccc2c(c1)c1cc(C(C)(C)C)ccc1n2-c1ccc2c(c1)N(c1c(-c3ccccc3)cccc1-c1ccccc1)c1cc(-n3c4ccc(C(C)(C)C)cc4c4cc(C(C)(C)C)ccc43)cc3c1B2c1ccc(N2C4CC5CC(C4)CC2C5)cc1N3c1c(-c2ccccc2)cccc1-c1ccccc1 ; CC(C)(C)c1ccc2c(c1)c1cc(C(C)(C)C)ccc1n2-c1cc2c3c(c1)N(c1c(-c4ccccc4)cccc1-c1ccccc1)c1cc(-n4c5ccc(-c6ccccc6)cc5c5cc(-c6ccccc6)ccc54)ccc1B3c1ccc(N3C4CC5CC(C4)CC3C5)cc1N2c1c(-c2ccccc2)cccc1-c1ccccc1] 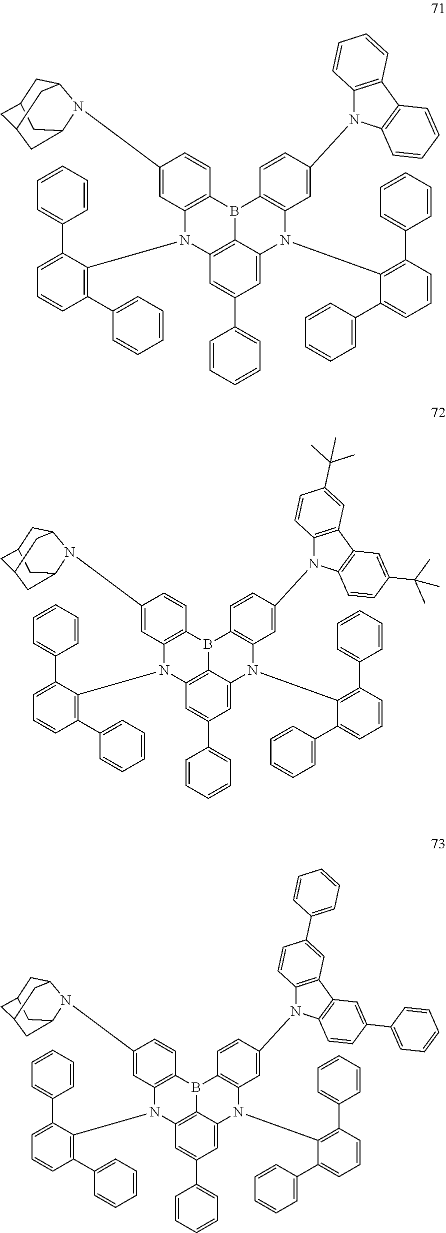 [SMILES: c1ccc(-c2cc3c4c(c2)N(c2c(-c5ccccc5)cccc2-c2ccccc2)c2cc(-n5c6ccccc6c6ccccc65)ccc2B4c2ccc(N4C5CC6CC(C5)CC4C6)cc2N3c2c(-c3ccccc3)cccc2-c2ccccc2)cc1 ; CC(C)(C)c1ccc2c(c1)c1cc(C(C)(C)C)ccc1n2-c1ccc2c(c1)N(c1c(-c3ccccc3)cccc1-c1ccccc1)c1cc(-c3ccccc3)cc3c1B2c1ccc(N2C4CC5CC(C4)CC2C5)cc1N3c1c(-c2ccccc2)cccc1-c1ccccc1 ; c1ccc(-c2cc3c4c(c2)N(c2c(-c5ccccc5)cccc2-c2ccccc2)c2cc(-n5c6ccc(-c7ccccc7)cc6c6cc(-c7ccccc7)ccc65)ccc2B4c2ccc(N4C5CC6CC(C5)CC4C6)cc2N3c2c(-c3ccccc3)cccc2-c2ccccc2)cc1] 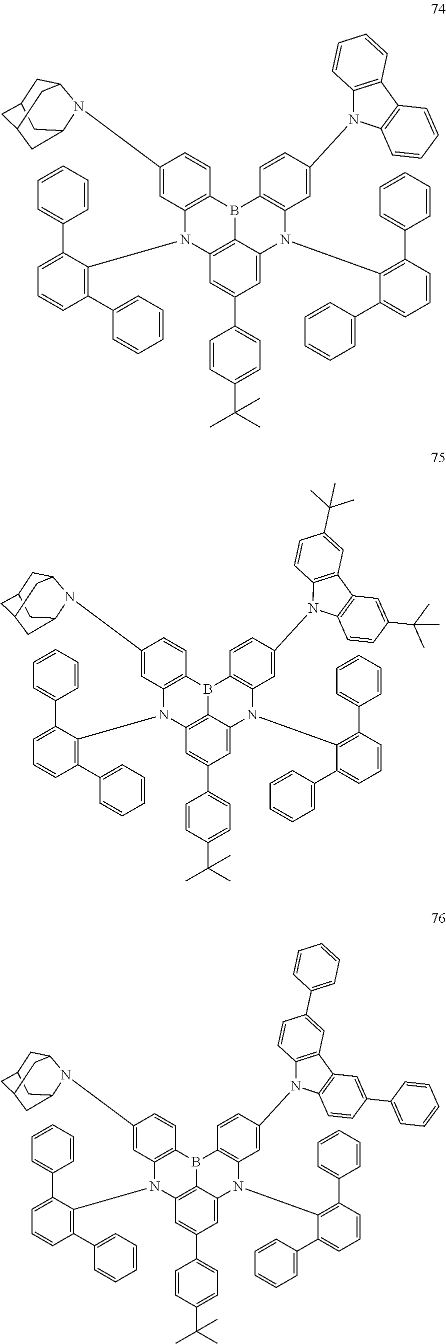 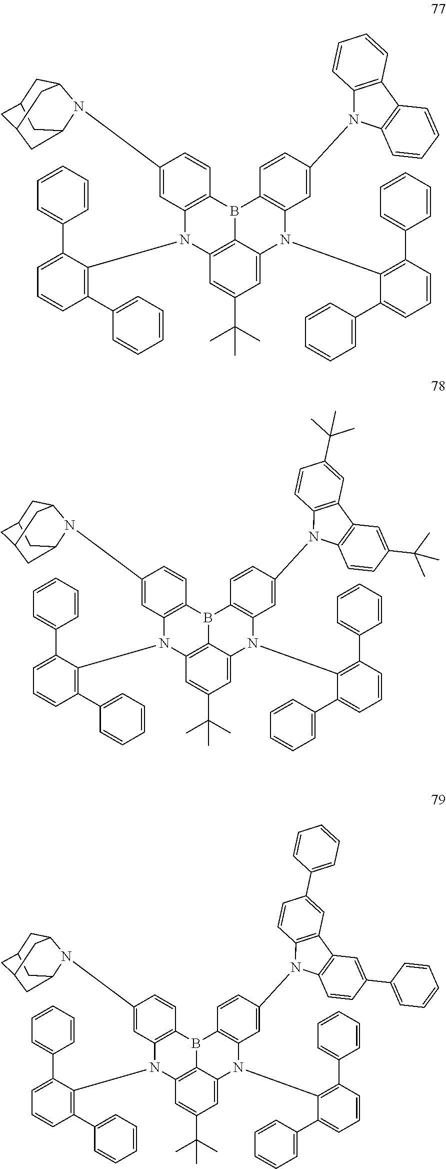 [SMILES: CC(C)(C)c1cc2c3c(c1)N(c1c(-c4ccccc4)cccc1-c1ccccc1)c1cc(-n4c5ccccc5c5ccccc54)ccc1B3c1ccc(N3C4CC5CC(C4)CC3C5)cc1N2c1c(-c2ccccc2)cccc1-c1ccccc1 ; CC(C)(C)c1cc2c3c(c1)N(c1c(-c4ccccc4)cccc1-c1ccccc1)c1cc(-n4c5ccc(C(C)(C)C)cc5c5cc(C(C)(C)C)ccc54)ccc1B3c1ccc(N3C4CC5CC(C4)CC3C5)cc1N2c1c(-c2ccccc2)cccc1-c1ccccc1 ; CC(C)(C)c1cc2c3c(c1)N(c1c(-c4ccccc4)cccc1-c1ccccc1)c1cc(-n4c5ccc(-c6ccccc6)cc5c5cc(-c6ccccc6)ccc54)ccc1B3c1ccc(N3C4CC5CC(C4)CC3C5)cc1N2c1c(-c2ccccc2)cccc1-c1ccccc1] 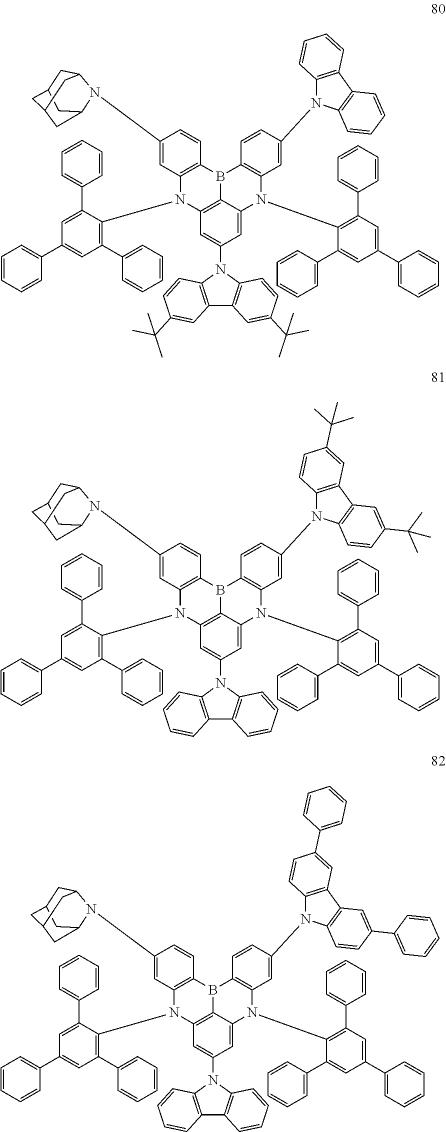 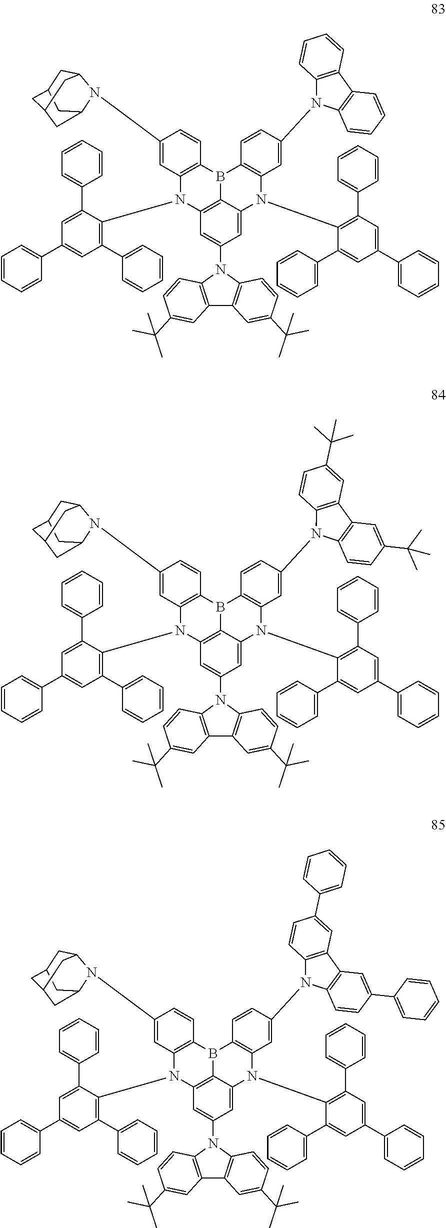 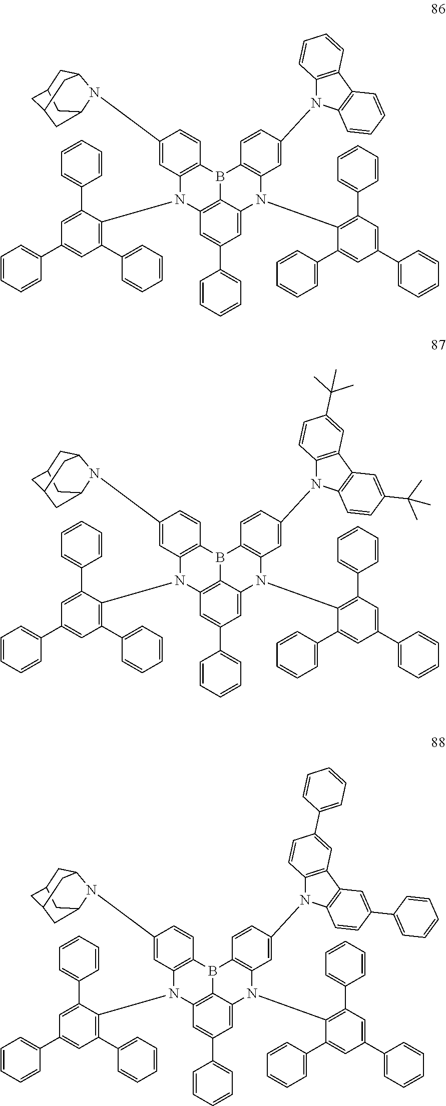 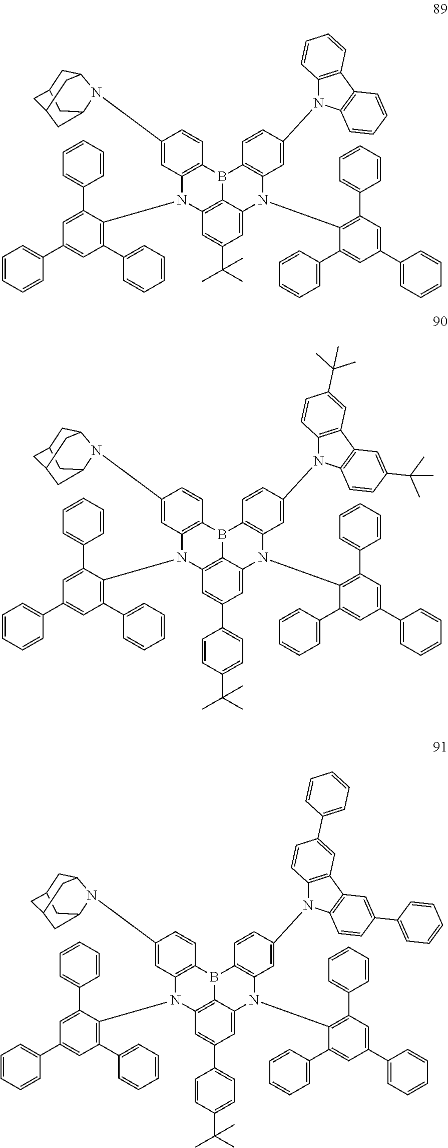 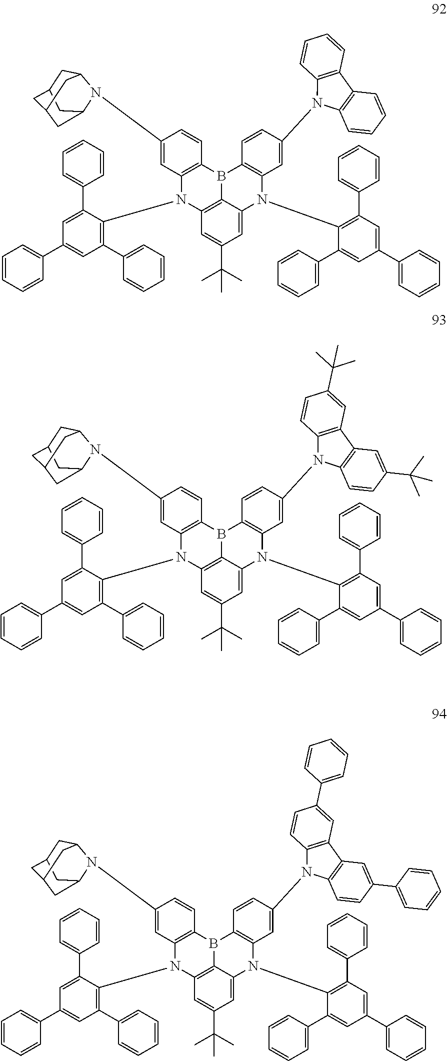 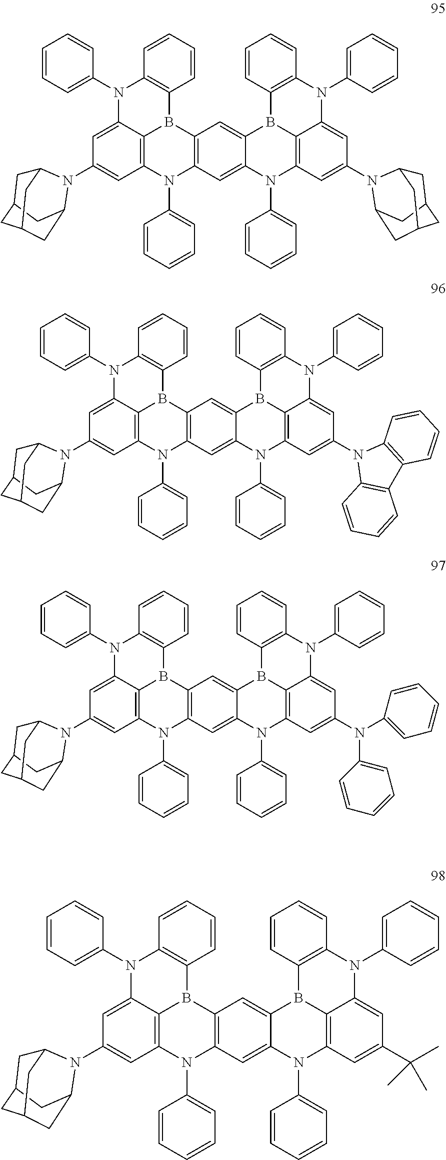 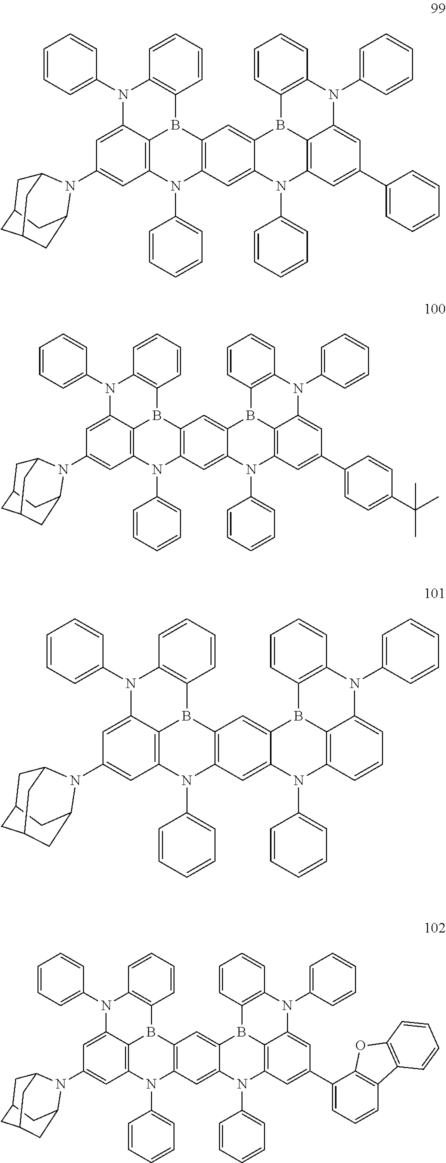 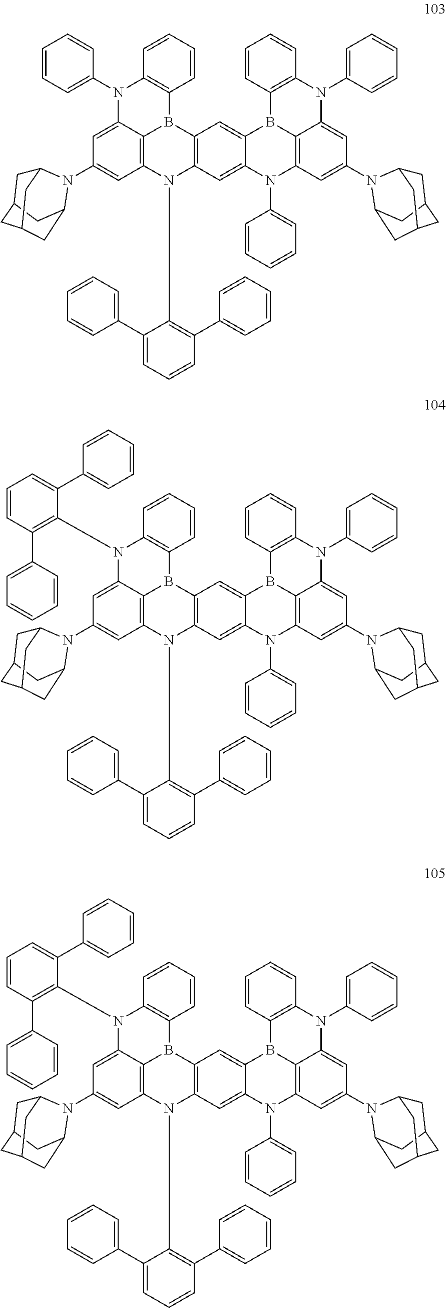 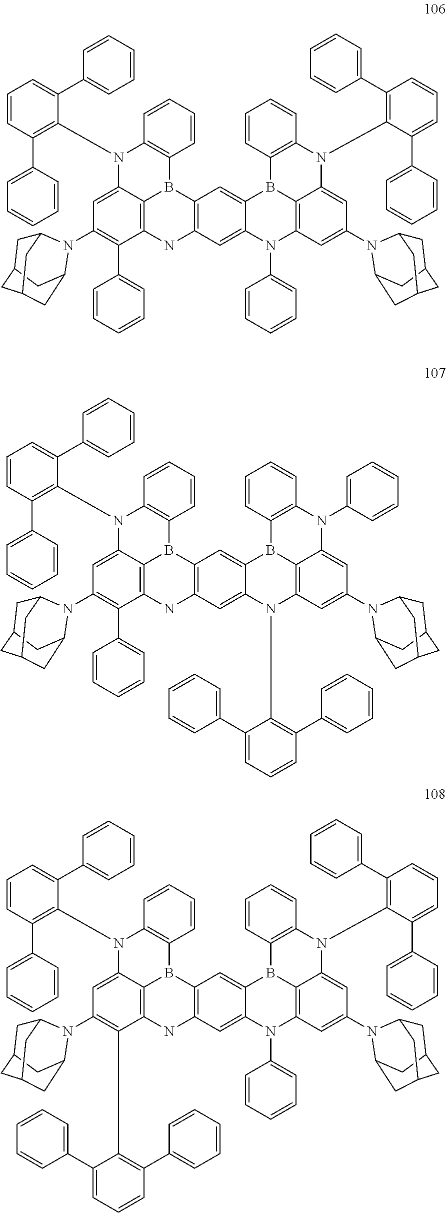 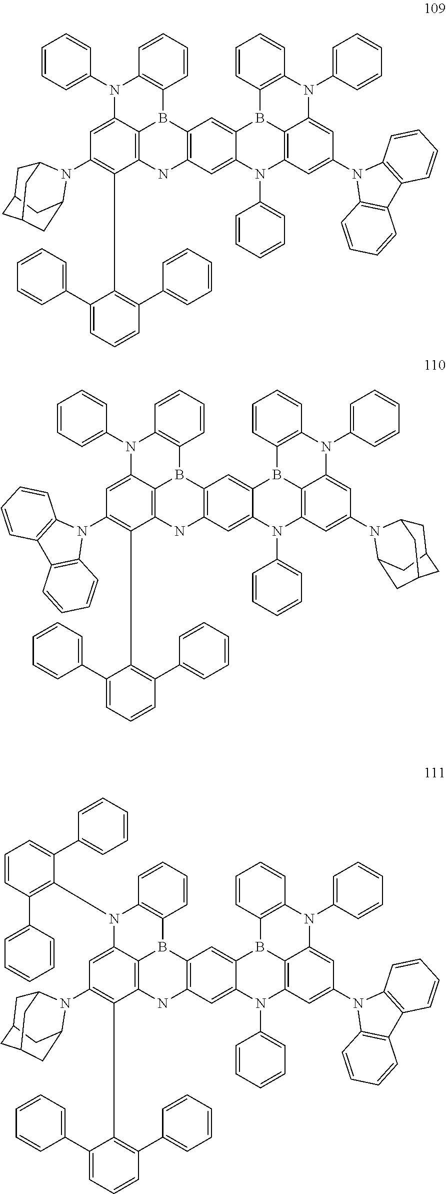 [SMILES: c1ccc(-c2cccc(-c3ccccc3)c2-c2c(N3C4CC5CC(C4)CC3C5)cc3c4c2Nc2cc5c(cc2B4c2ccccc2N3c2ccccc2)B2c3ccccc3N(c3ccccc3)c3cc(-n4c6ccccc6c6ccccc64)cc(c32)N5c2ccccc2)cc1 ; c1ccc(-c2cccc(-c3ccccc3)c2-c2c(-n3c4ccccc4c4ccccc43)cc3c4c2Nc2cc5c(cc2B4c2ccccc2N3c2ccccc2)B2c3ccccc3N(c3ccccc3)c3cc(N4C6CC7CC(C6)CC4C7)cc(c32)N5c2ccccc2)cc1 ; c1ccc(-c2cccc(-c3ccccc3)c2-c2c(N3C4CC5CC(C4)CC3C5)cc3c4c2Nc2cc5c(cc2B4c2ccccc2N3c2c(-c3ccccc3)cccc2-c2ccccc2)B2c3ccccc3N(c3ccccc3)c3cc(-n4c6ccccc6c6ccccc64)cc(c32)N5c2ccccc2)cc1] 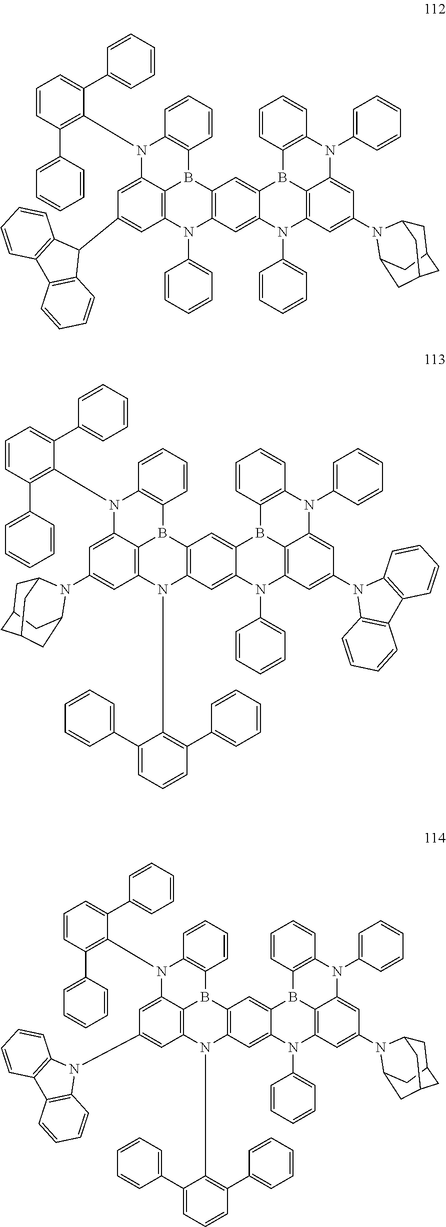 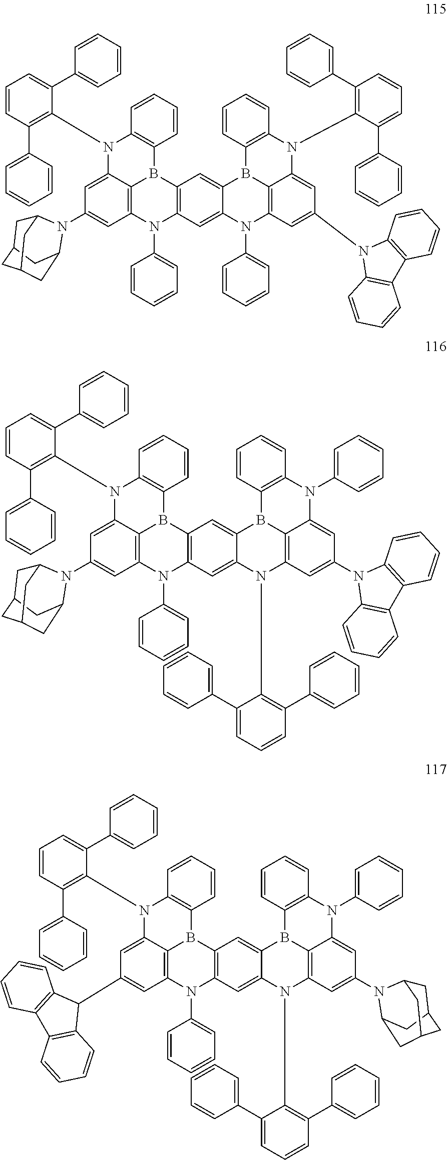 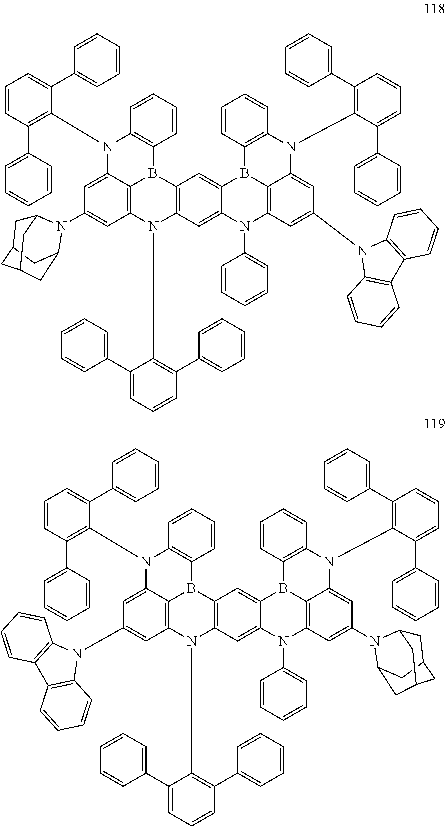 [SMILES: c1ccc(-c2cccc(-c3ccccc3)c2N2c3ccccc3B3c4cc5c(cc4N(c4ccccc4)c4cc(-n6c7ccccc7c7ccccc76)cc2c43)N(c2c(-c3ccccc3)cccc2-c2ccccc2)c2cc(N3C4CC6CC(C4)CC3C6)cc3c2B5c2ccccc2N3c2c(-c3ccccc3)cccc2-c2ccccc2)cc1 ; c1ccc(-c2cccc(-c3ccccc3)c2N2c3ccccc3B3c4cc5c(cc4N(c4ccccc4)c4cc(N6C7CC8CC(C7)CC6C8)cc2c43)N(c2c(-c3ccccc3)cccc2-c2ccccc2)c2cc(-n3c4ccccc4c4ccccc43)cc3c2B5c2ccccc2N3c2c(-c3ccccc3)cccc2-c2ccccc2)cc1] 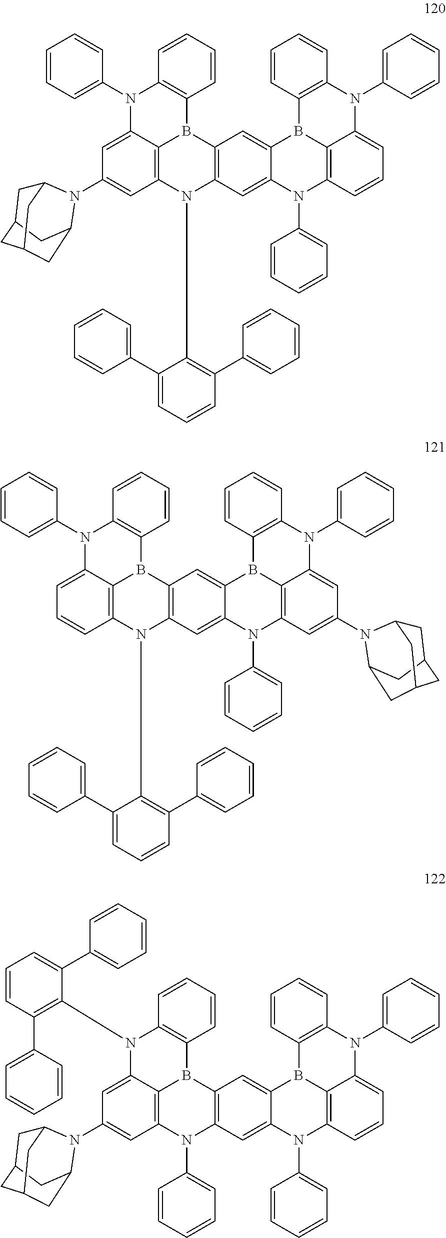 [SMILES: c1ccc(-c2cccc(-c3ccccc3)c2N2c3cc4c(cc3B3c5ccccc5N(c5ccccc5)c5cc(N6C7CC8CC(C7)CC6C8)cc2c53)B2c3ccccc3N(c3ccccc3)c3cccc(c32)N4c2ccccc2)cc1 ; c1ccc(-c2cccc(-c3ccccc3)c2N2c3cc4c(cc3B3c5ccccc5N(c5ccccc5)c5cccc2c53)B2c3ccccc3N(c3ccccc3)c3cc(N5C6CC7CC(C6)CC5C7)cc(c32)N4c2ccccc2)cc1 ; c1ccc(-c2cccc(-c3ccccc3)c2N2c3ccccc3B3c4cc5c(cc4N(c4ccccc4)c4cc(N6C7CC8CC(C7)CC6C8)cc2c43)N(c2ccccc2)c2cccc3c2B5c2ccccc2N3c2ccccc2)cc1] 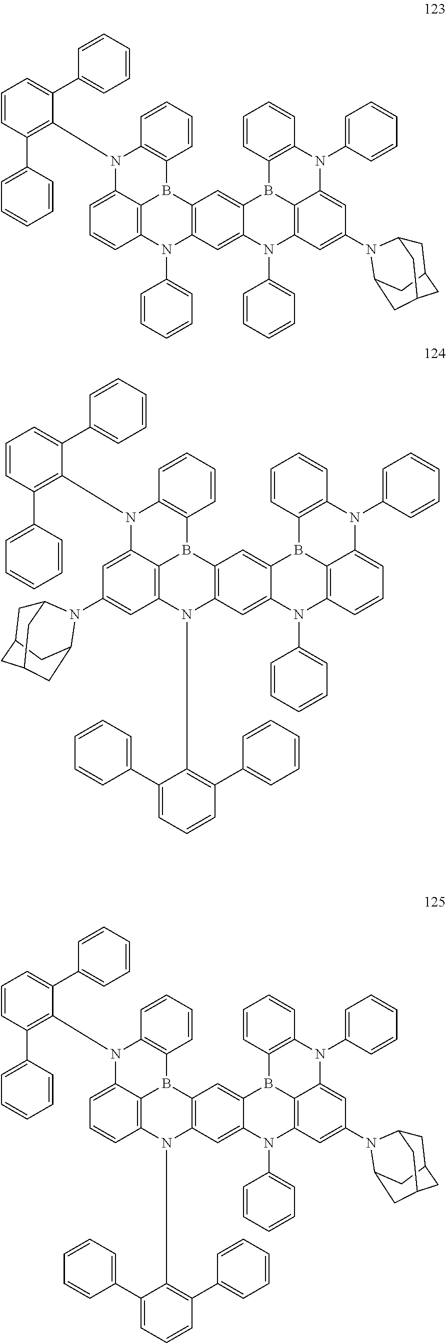 [SMILES: c1ccc(-c2cccc(-c3ccccc3)c2N2c3ccccc3B3c4cc5c(cc4N(c4ccccc4)c4cccc2c43)N(c2ccccc2)c2cc(N3C4CC6CC(C4)CC3C6)cc3c2B5c2ccccc2N3c2ccccc2)cc1 ; c1ccc(-c2cccc(-c3ccccc3)c2N2c3ccccc3B3c4cc5c(cc4N(c4c(-c6ccccc6)cccc4-c4ccccc4)c4cc(N6C7CC8CC(C7)CC6C8)cc2c43)N(c2ccccc2)c2cccc3c2B5c2ccccc2N3c2ccccc2)cc1 ; c1ccc(-c2cccc(-c3ccccc3)c2N2c3ccccc3B3c4cc5c(cc4N(c4c(-c6ccccc6)cccc4-c4ccccc4)c4cccc2c43)N(c2ccccc2)c2cc(N3C4CC6CC(C4)CC3C6)cc3c2B5c2ccccc2N3c2ccccc2)cc1] 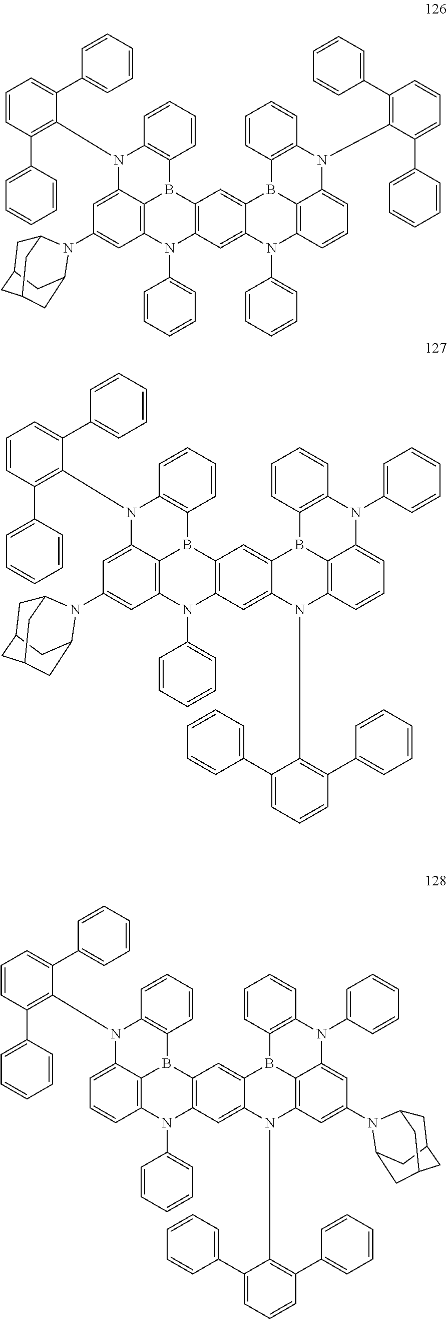 [SMILES: c1ccc(-c2cccc(-c3ccccc3)c2N2c3ccccc3B3c4cc5c(cc4N(c4ccccc4)c4cccc2c43)N(c2ccccc2)c2cc(N3C4CC6CC(C4)CC3C6)cc3c2B5c2ccccc2N3c2c(-c3ccccc3)cccc2-c2ccccc2)cc1 ; c1ccc(-c2cccc(-c3ccccc3)c2N2c3cc4c(cc3B3c5ccccc5N(c5ccccc5)c5cccc2c53)B2c3ccccc3N(c3c(-c5ccccc5)cccc3-c3ccccc3)c3cc(N5C6CC7CC(C6)CC5C7)cc(c32)N4c2ccccc2)cc1 ; c1ccc(-c2cccc(-c3ccccc3)c2N2c3ccccc3B3c4cc5c(cc4N(c4ccccc4)c4cccc2c43)N(c2c(-c3ccccc3)cccc2-c2ccccc2)c2cc(N3C4CC6CC(C4)CC3C6)cc3c2B5c2ccccc2N3c2ccccc2)cc1] 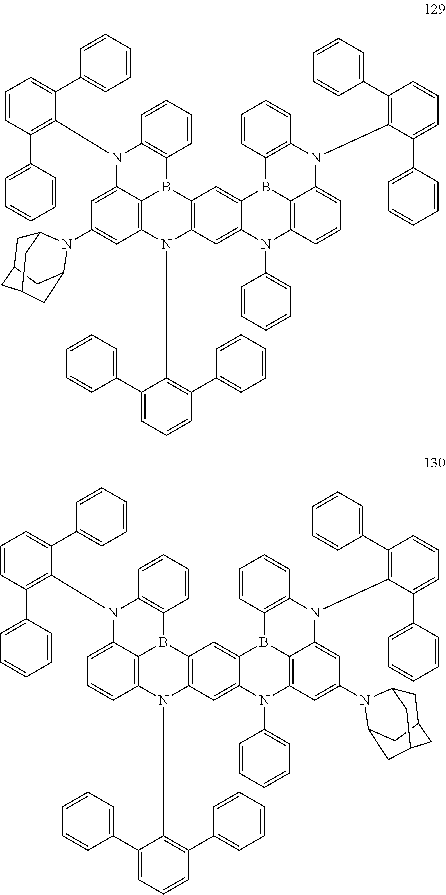 [SMILES: c1ccc(-c2cccc(-c3ccccc3)c2N2c3ccccc3B3c4cc5c(cc4N(c4ccccc4)c4cccc2c43)N(c2c(-c3ccccc3)cccc2-c2ccccc2)c2cc(N3C4CC6CC(C4)CC3C6)cc3c2B5c2ccccc2N3c2c(-c3ccccc3)cccc2-c2ccccc2)cc1 ; c1ccc(-c2cccc(-c3ccccc3)c2N2c3ccccc3B3c4cc5c(cc4N(c4ccccc4)c4cc(N6C7CC8CC(C7)CC6C8)cc2c43)N(c2c(-c3ccccc3)cccc2-c2ccccc2)c2cccc3c2B5c2ccccc2N3c2c(-c3ccccc3)cccc2-c2ccccc2)cc1] 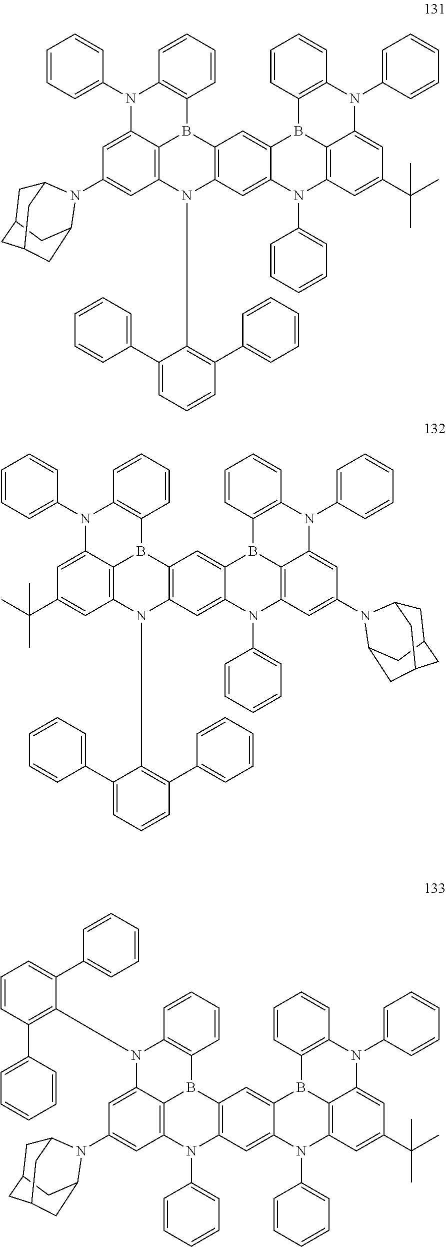 [SMILES: CC(C)(C)c1cc2c3c(c1)N(c1ccccc1)c1cc4c(cc1B3c1ccccc1N2c1ccccc1)B1c2ccccc2N(c2ccccc2)c2cc(N3C5CC6CC(C5)CC3C6)cc(c21)N4c1c(-c2ccccc2)cccc1-c1ccccc1 ; CC(C)(C)c1cc2c3c(c1)N(c1c(-c4ccccc4)cccc1-c1ccccc1)c1cc4c(cc1B3c1ccccc1N2c1ccccc1)B1c2ccccc2N(c2ccccc2)c2cc(N3C5CC6CC(C5)CC3C6)cc(c21)N4c1ccccc1 ; CC(C)(C)c1cc2c3c(c1)N(c1ccccc1)c1cc4c(cc1B3c1ccccc1N2c1ccccc1)B1c2ccccc2N(c2c(-c3ccccc3)cccc2-c2ccccc2)c2cc(N3C5CC6CC(C5)CC3C6)cc(c21)N4c1ccccc1] 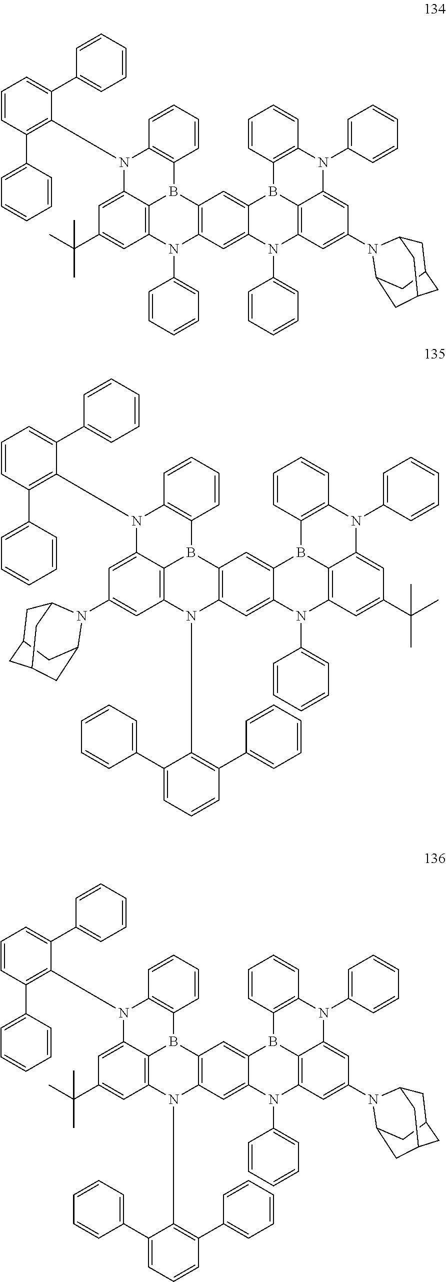 [SMILES: CC(C)(C)c1cc2c3c(c1)N(c1c(-c4ccccc4)cccc1-c1ccccc1)c1ccccc1B3c1cc3c(cc1N2c1ccccc1)N(c1ccccc1)c1cc(N2C4CC5CC(C4)CC2C5)cc2c1B3c1ccccc1N2c1ccccc1 ; CC(C)(C)c1cc2c3c(c1)N(c1ccccc1)c1cc4c(cc1B3c1ccccc1N2c1ccccc1)B1c2ccccc2N(c2c(-c3ccccc3)cccc2-c2ccccc2)c2cc(N3C5CC6CC(C5)CC3C6)cc(c21)N4c1c(-c2ccccc2)cccc1-c1ccccc1 ; CC(C)(C)c1cc2c3c(c1)N(c1c(-c4ccccc4)cccc1-c1ccccc1)c1cc4c(cc1B3c1ccccc1N2c1c(-c2ccccc2)cccc1-c1ccccc1)B1c2ccccc2N(c2ccccc2)c2cc(N3C5CC6CC(C5)CC3C6)cc(c21)N4c1ccccc1] 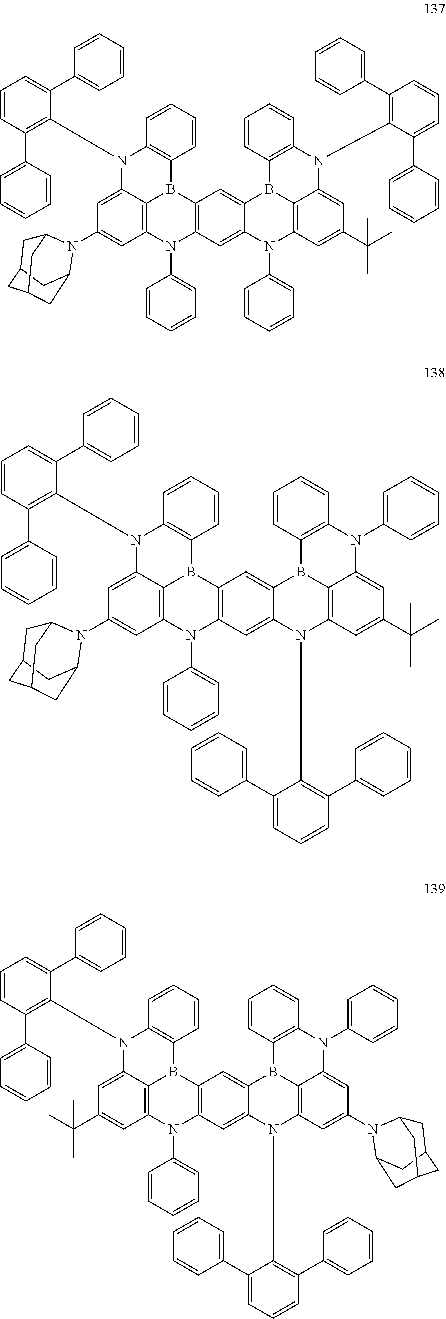 [SMILES: CC(C)(C)c1cc2c3c(c1)N(c1c(-c4ccccc4)cccc1-c1ccccc1)c1ccccc1B3c1cc3c(cc1N2c1ccccc1)N(c1ccccc1)c1cc(N2C4CC5CC(C4)CC2C5)cc2c1B3c1ccccc1N2c1c(-c2ccccc2)cccc1-c1ccccc1 ; CC(C)(C)c1cc2c3c(c1)N(c1c(-c4ccccc4)cccc1-c1ccccc1)c1cc4c(cc1B3c1ccccc1N2c1ccccc1)B1c2ccccc2N(c2c(-c3ccccc3)cccc2-c2ccccc2)c2cc(N3C5CC6CC(C5)CC3C6)cc(c21)N4c1ccccc1 ; CC(C)(C)c1cc2c3c(c1)N(c1c(-c4ccccc4)cccc1-c1ccccc1)c1ccccc1B3c1cc3c(cc1N2c1ccccc1)N(c1c(-c2ccccc2)cccc1-c1ccccc1)c1cc(N2C4CC5CC(C4)CC2C5)cc2c1B3c1ccccc1N2c1ccccc1] 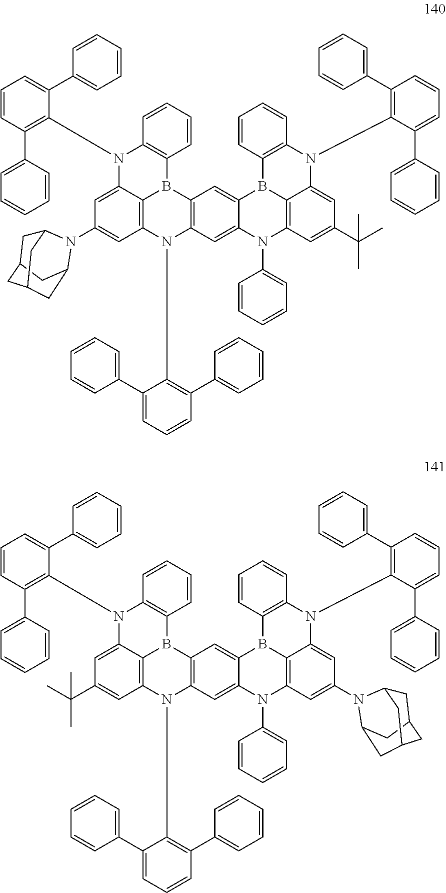 [SMILES: CC(C)(C)c1cc2c3c(c1)N(c1c(-c4ccccc4)cccc1-c1ccccc1)c1ccccc1B3c1cc3c(cc1N2c1ccccc1)N(c1c(-c2ccccc2)cccc1-c1ccccc1)c1cc(N2C4CC5CC(C4)CC2C5)cc2c1B3c1ccccc1N2c1c(-c2ccccc2)cccc1-c1ccccc1 ; CC(C)(C)c1cc2c3c(c1)N(c1c(-c4ccccc4)cccc1-c1ccccc1)c1cc4c(cc1B3c1ccccc1N2c1c(-c2ccccc2)cccc1-c1ccccc1)B1c2ccccc2N(c2c(-c3ccccc3)cccc2-c2ccccc2)c2cc(N3C5CC6CC(C5)CC3C6)cc(c21)N4c1ccccc1] 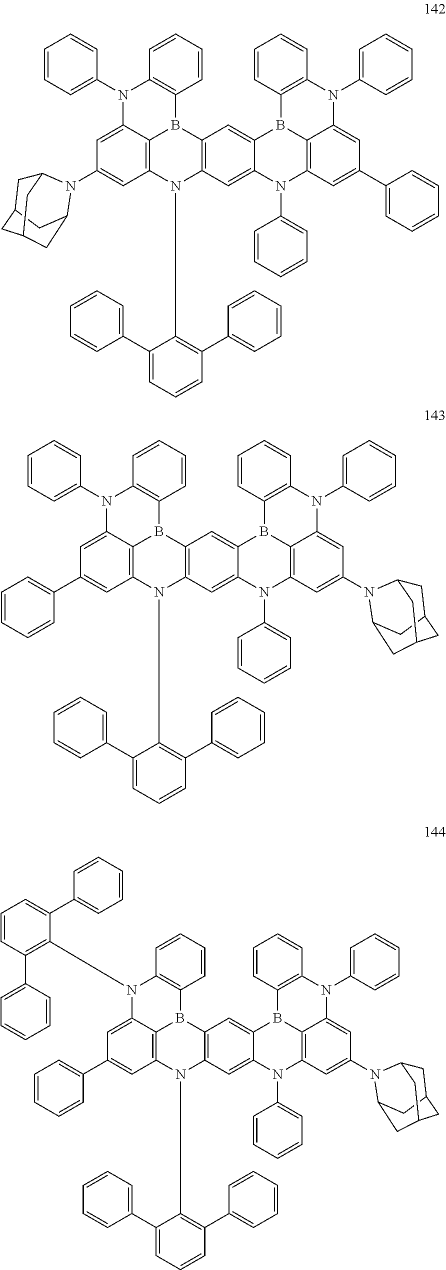 [SMILES: c1ccc(-c2cc3c4c(c2)N(c2ccccc2)c2cc5c(cc2B4c2ccccc2N3c2ccccc2)B2c3ccccc3N(c3ccccc3)c3cc(N4C6CC7CC(C6)CC4C7)cc(c32)N5c2c(-c3ccccc3)cccc2-c2ccccc2)cc1 ; c1ccc(-c2cc3c4c(c2)N(c2c(-c5ccccc5)cccc2-c2ccccc2)c2cc5c(cc2B4c2ccccc2N3c2ccccc2)B2c3ccccc3N(c3ccccc3)c3cc(N4C6CC7CC(C6)CC4C7)cc(c32)N5c2ccccc2)cc1 ; c1ccc(-c2cc3c4c(c2)N(c2c(-c5ccccc5)cccc2-c2ccccc2)c2cc5c(cc2B4c2ccccc2N3c2c(-c3ccccc3)cccc2-c2ccccc2)B2c3ccccc3N(c3ccccc3)c3cc(N4C6CC7CC(C6)CC4C7)cc(c32)N5c2ccccc2)cc1] 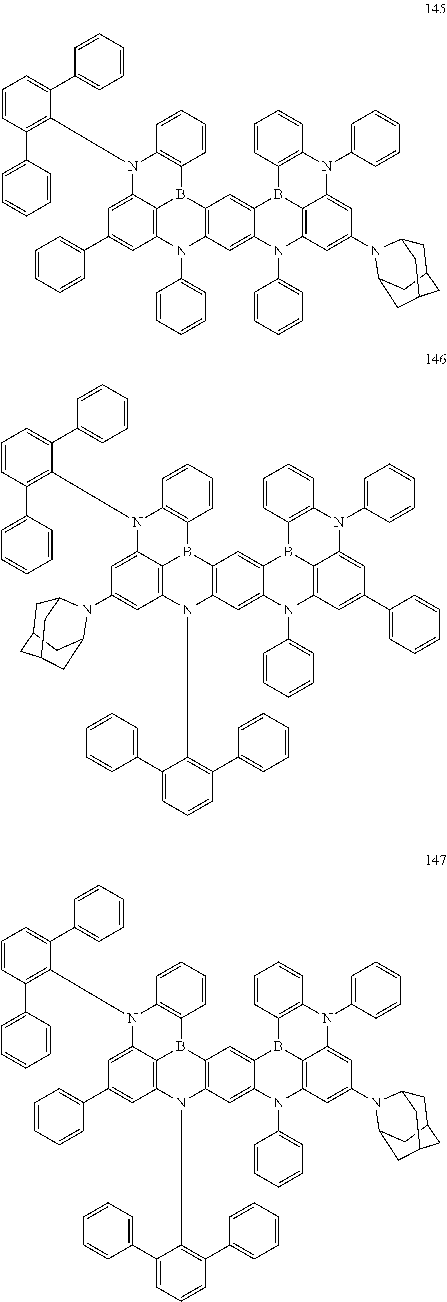 [SMILES: c1ccc(-c2cc3c4c(c2)N(c2c(-c5ccccc5)cccc2-c2ccccc2)c2ccccc2B4c2cc4c(cc2N3c2ccccc2)N(c2ccccc2)c2cc(N3C5CC6CC(C5)CC3C6)cc3c2B4c2ccccc2N3c2ccccc2)cc1 ; c1ccc(-c2cc3c4c(c2)N(c2ccccc2)c2cc5c(cc2B4c2ccccc2N3c2ccccc2)B2c3ccccc3N(c3c(-c4ccccc4)cccc3-c3ccccc3)c3cc(N4C6CC7CC(C6)CC4C7)cc(c32)N5c2c(-c3ccccc3)cccc2-c2ccccc2)cc1 ; c1ccc(-c2cc3c4c(c2)N(c2c(-c5ccccc5)cccc2-c2ccccc2)c2cc5c(cc2B4c2ccccc2N3c2c(-c3ccccc3)cccc2-c2ccccc2)B2c3ccccc3N(c3ccccc3)c3cc(N4C6CC7CC(C6)CC4C7)cc(c32)N5c2ccccc2)cc1] 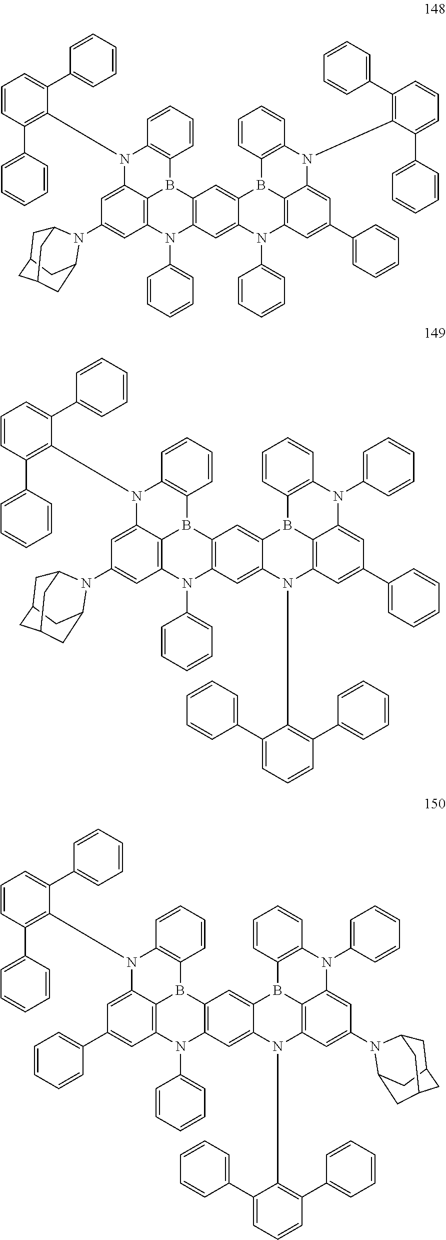 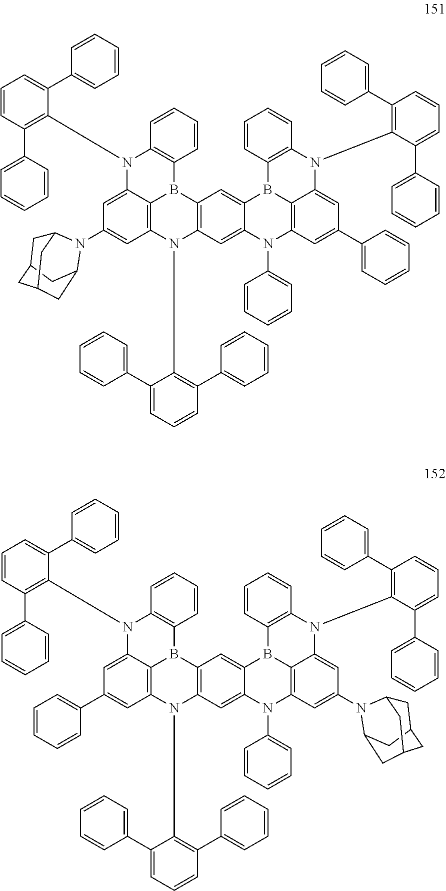 [SMILES: c1ccc(-c2cc3c4c(c2)N(c2c(-c5ccccc5)cccc2-c2ccccc2)c2ccccc2B4c2cc4c(cc2N3c2ccccc2)N(c2c(-c3ccccc3)cccc2-c2ccccc2)c2cc(N3C5CC6CC(C5)CC3C6)cc3c2B4c2ccccc2N3c2c(-c3ccccc3)cccc2-c2ccccc2)cc1 ; c1ccc(-c2cc3c4c(c2)N(c2c(-c5ccccc5)cccc2-c2ccccc2)c2cc5c(cc2B4c2ccccc2N3c2c(-c3ccccc3)cccc2-c2ccccc2)B2c3ccccc3N(c3c(-c4ccccc4)cccc3-c3ccccc3)c3cc(N4C6CC7CC(C6)CC4C7)cc(c32)N5c2ccccc2)cc1] 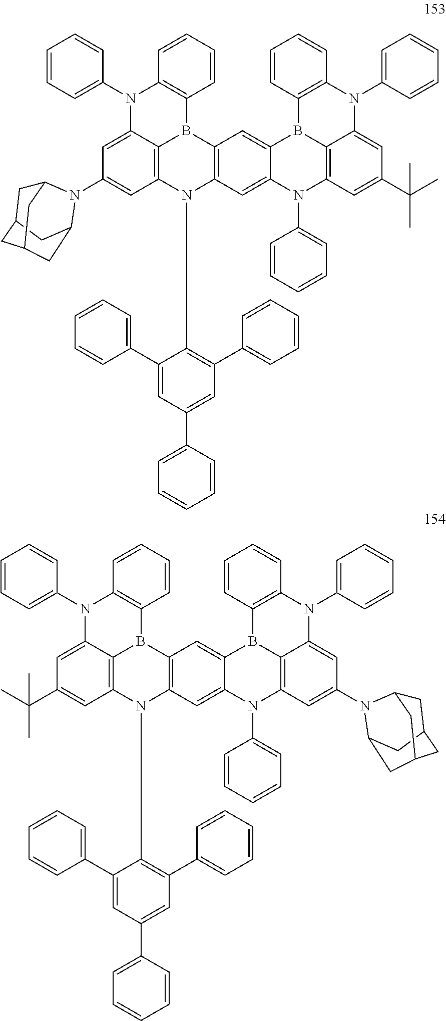 [SMILES: CC(C)(C)c1cc2c3c(c1)N(c1ccccc1)c1cc4c(cc1B3c1ccccc1N2c1ccccc1)B1c2ccccc2N(c2ccccc2)c2cc(N3C5CC6CC(C5)CC3C6)cc(c21)N4c1c(-c2ccccc2)cc(-c2ccccc2)cc1-c1ccccc1 ; CC(C)(C)c1cc2c3c(c1)N(c1c(-c4ccccc4)cc(-c4ccccc4)cc1-c1ccccc1)c1cc4c(cc1B3c1ccccc1N2c1ccccc1)B1c2ccccc2N(c2ccccc2)c2cc(N3C5CC6CC(C5)CC3C6)cc(c21)N4c1ccccc1] 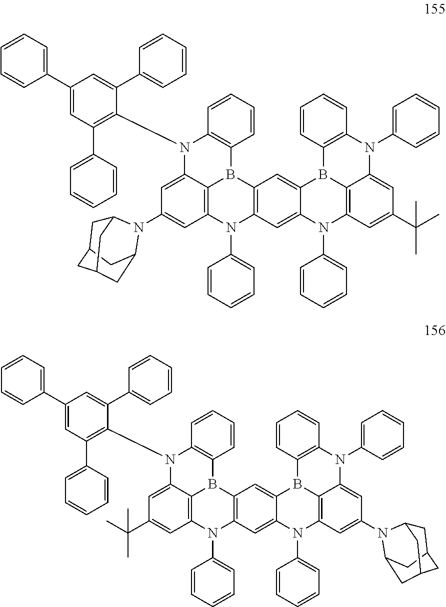 [SMILES: CC(C)(C)c1cc2c3c(c1)N(c1ccccc1)c1cc4c(cc1B3c1ccccc1N2c1ccccc1)B1c2ccccc2N(c2c(-c3ccccc3)cc(-c3ccccc3)cc2-c2ccccc2)c2cc(N3C5CC6CC(C5)CC3C6)cc(c21)N4c1ccccc1 ; CC(C)(C)c1cc2c3c(c1)N(c1c(-c4ccccc4)cc(-c4ccccc4)cc1-c1ccccc1)c1ccccc1B3c1cc3c(cc1N2c1ccccc1)N(c1ccccc1)c1cc(N2C4CC5CC(C4)CC2C5)cc2c1B3c1ccccc1N2c1ccccc1] 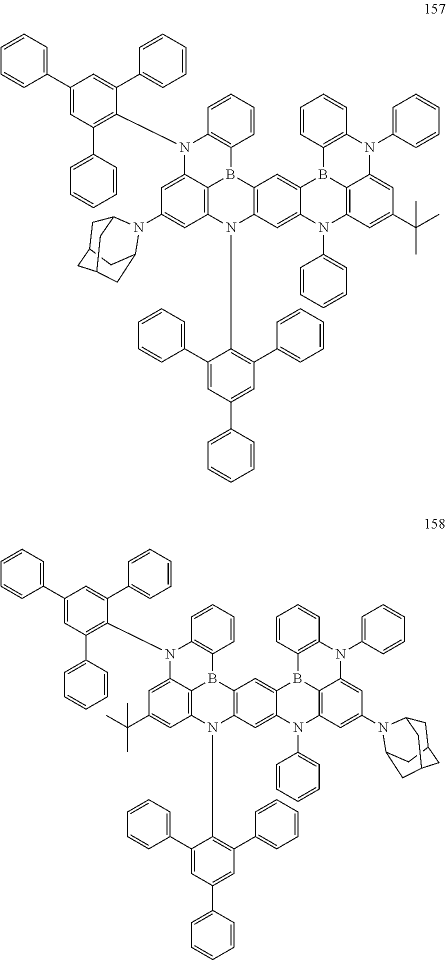 [SMILES: CC(C)(C)c1cc2c3c(c1)N(c1ccccc1)c1cc4c(cc1B3c1ccccc1N2c1ccccc1)B1c2ccccc2N(c2c(-c3ccccc3)cc(-c3ccccc3)cc2-c2ccccc2)c2cc(N3C5CC6CC(C5)CC3C6)cc(c21)N4c1c(-c2ccccc2)cc(-c2ccccc2)cc1-c1ccccc1 ; CC(C)(C)c1cc2c3c(c1)N(c1c(-c4ccccc4)cc(-c4ccccc4)cc1-c1ccccc1)c1cc4c(cc1B3c1ccccc1N2c1c(-c2ccccc2)cc(-c2ccccc2)cc1-c1ccccc1)B1c2ccccc2N(c2ccccc2)c2cc(N3C5CC6CC(C5)CC3C6)cc(c21)N4c1ccccc1] 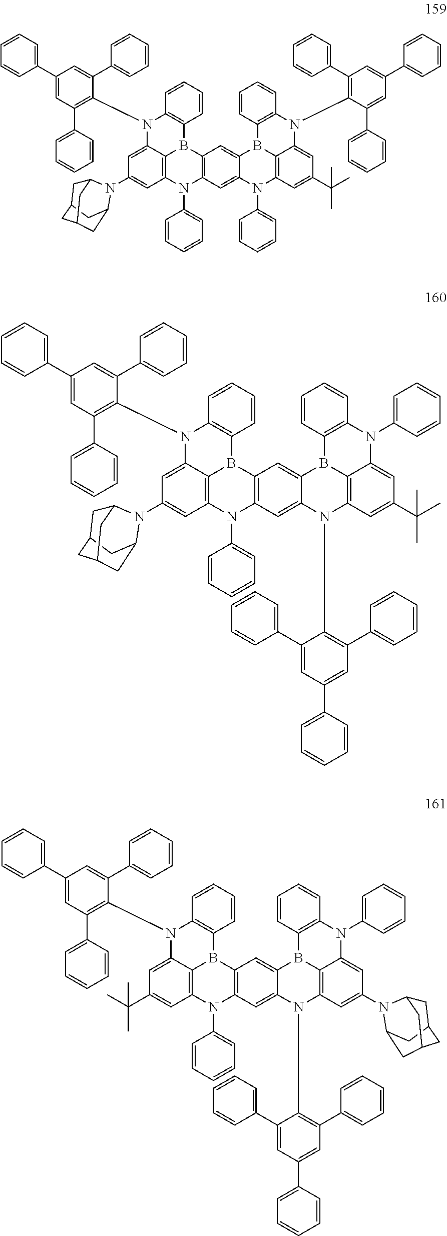 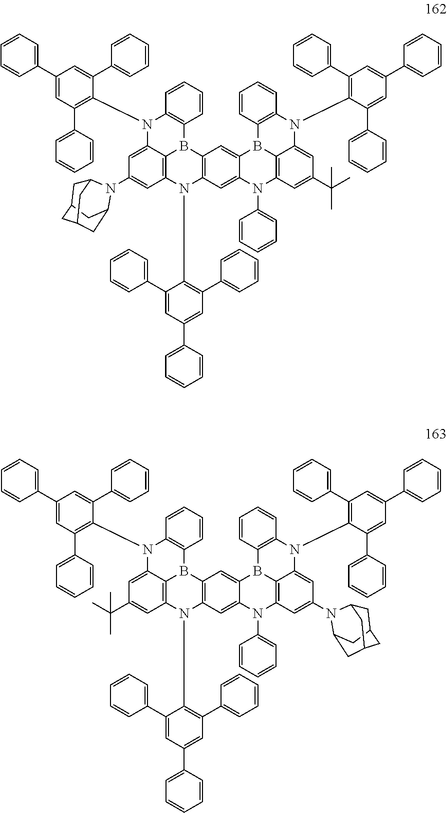 [SMILES: CC(C)(C)c1cc2c3c(c1)N(c1c(-c4ccccc4)cc(-c4ccccc4)cc1-c1ccccc1)c1ccccc1B3c1cc3c(cc1N2c1ccccc1)N(c1c(-c2ccccc2)cc(-c2ccccc2)cc1-c1ccccc1)c1cc(N2C4CC5CC(C4)CC2C5)cc2c1B3c1ccccc1N2c1c(-c2ccccc2)cc(-c2ccccc2)cc1-c1ccccc1 ; CC(C)(C)c1cc2c3c(c1)N(c1c(-c4ccccc4)cc(-c4ccccc4)cc1-c1ccccc1)c1cc4c(cc1B3c1ccccc1N2c1c(-c2ccccc2)cc(-c2ccccc2)cc1-c1ccccc1)B1c2ccccc2N(c2c(-c3ccccc3)cc(-c3ccccc3)cc2-c2ccccc2)c2cc(N3C5CC6CC(C5)CC3C6)cc(c21)N4c1ccccc1] 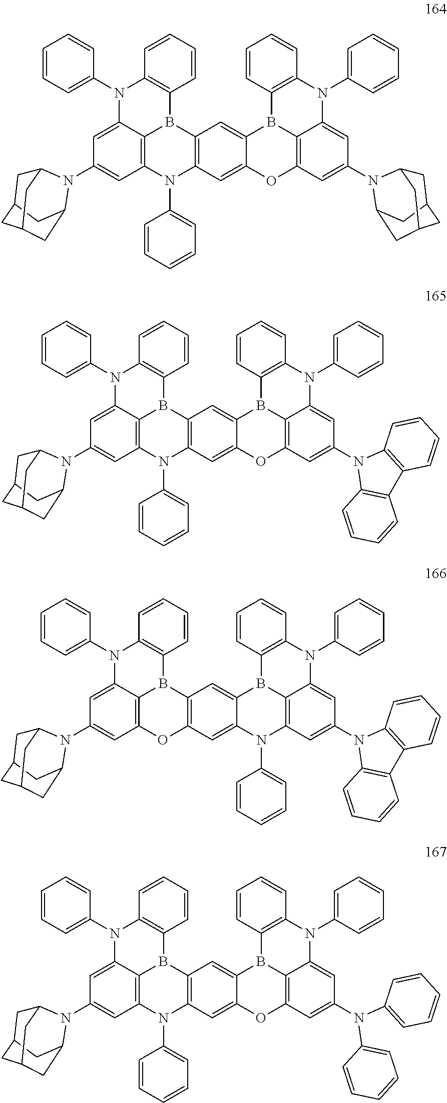 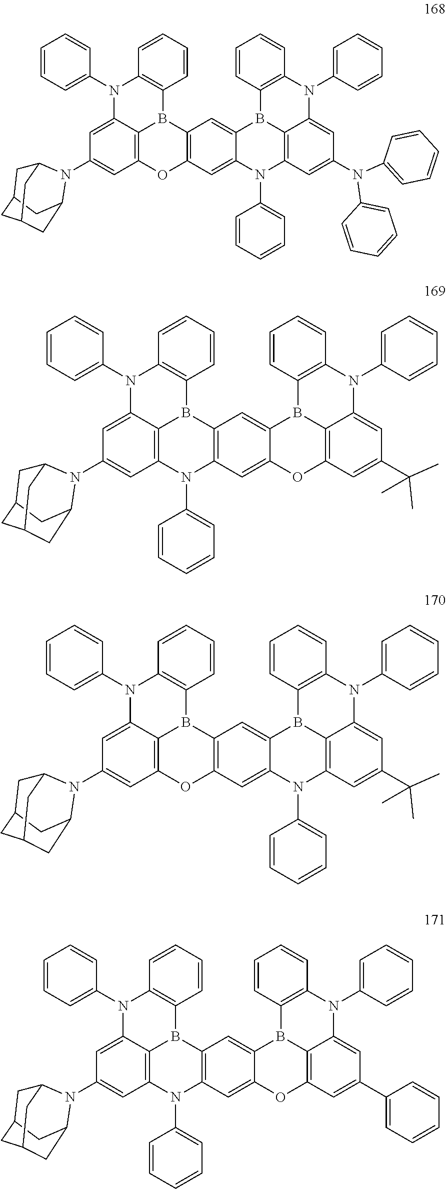 [SMILES: c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N4C6CC7CC(C6)CC4C7)cc(c32)O5)cc1 ; CC(C)(C)c1cc2c3c(c1)N(c1ccccc1)c1ccccc1B3c1cc3c(cc1O2)N(c1ccccc1)c1cc(N2C4CC5CC(C4)CC2C5)cc2c1B3c1ccccc1N2c1ccccc1 ; CC(C)(C)c1cc2c3c(c1)N(c1ccccc1)c1cc4c(cc1B3c1ccccc1N2c1ccccc1)B1c2ccccc2N(c2ccccc2)c2cc(N3C5CC6CC(C5)CC3C6)cc(c21)O4 ; c1ccc(-c2cc3c4c(c2)N(c2ccccc2)c2ccccc2B4c2cc4c(cc2O3)N(c2ccccc2)c2cc(N3C5CC6CC(C5)CC3C6)cc3c2B4c2ccccc2N3c2ccccc2)cc1] 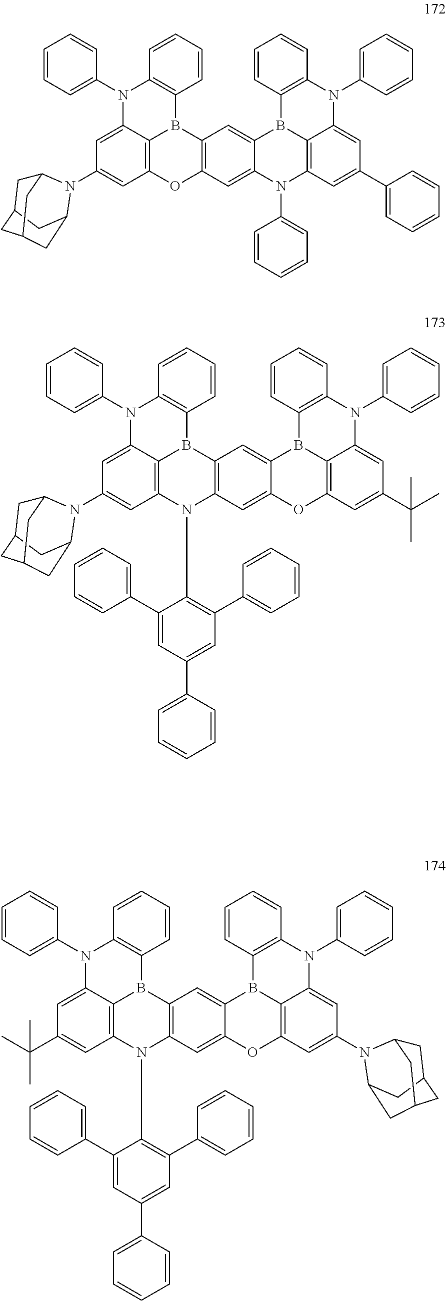 [SMILES: c1ccc(-c2cc3c4c(c2)N(c2ccccc2)c2cc5c(cc2B4c2ccccc2N3c2ccccc2)B2c3ccccc3N(c3ccccc3)c3cc(N4C6CC7CC(C6)CC4C7)cc(c32)O5)cc1 ; CC(C)(C)c1cc2c3c(c1)N(c1ccccc1)c1ccccc1B3c1cc3c(cc1O2)N(c1c(-c2ccccc2)cc(-c2ccccc2)cc1-c1ccccc1)c1cc(N2C4CC5CC(C4)CC2C5)cc2c1B3c1ccccc1N2c1ccccc1 ; CC(C)(C)c1cc2c3c(c1)N(c1c(-c4ccccc4)cc(-c4ccccc4)cc1-c1ccccc1)c1cc4c(cc1B3c1ccccc1N2c1ccccc1)B1c2ccccc2N(c2ccccc2)c2cc(N3C5CC6CC(C5)CC3C6)cc(c21)O4] 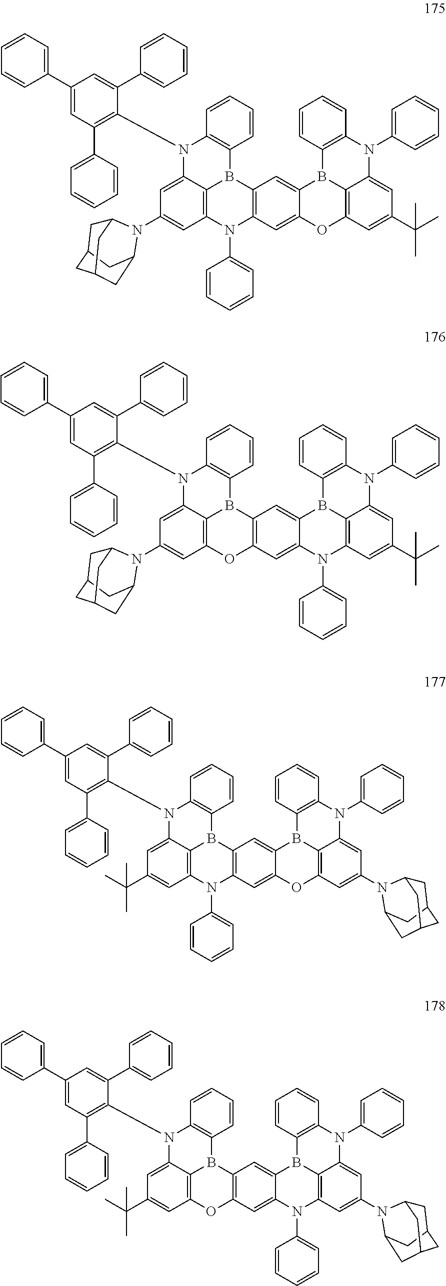 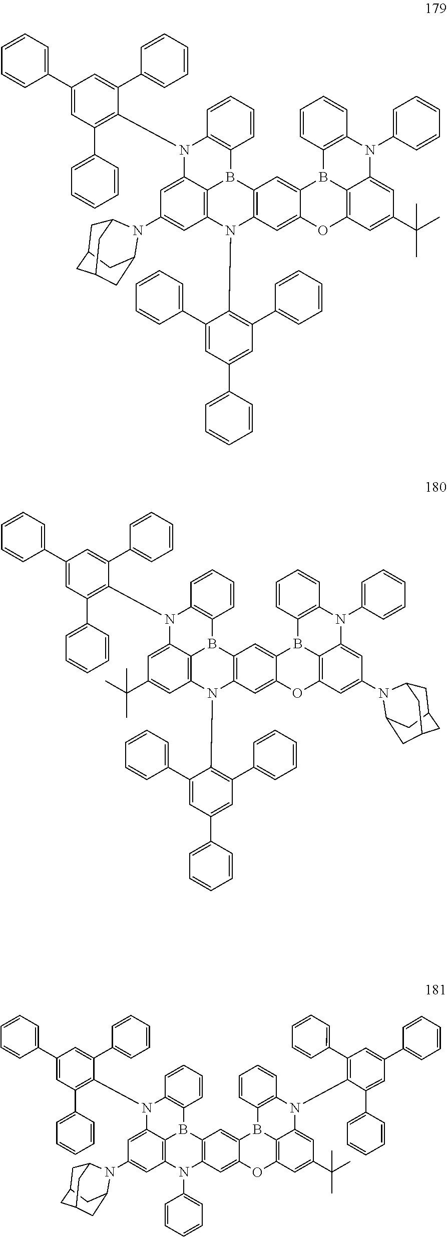 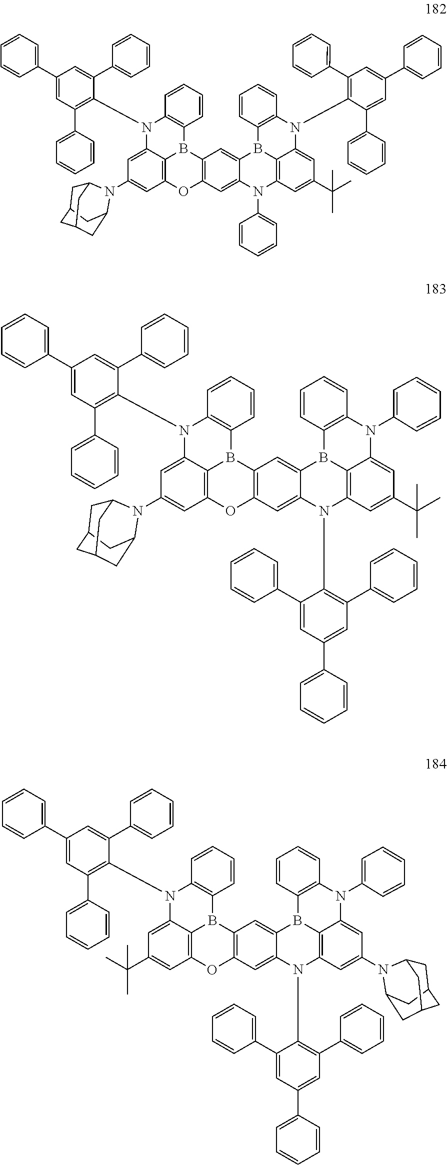 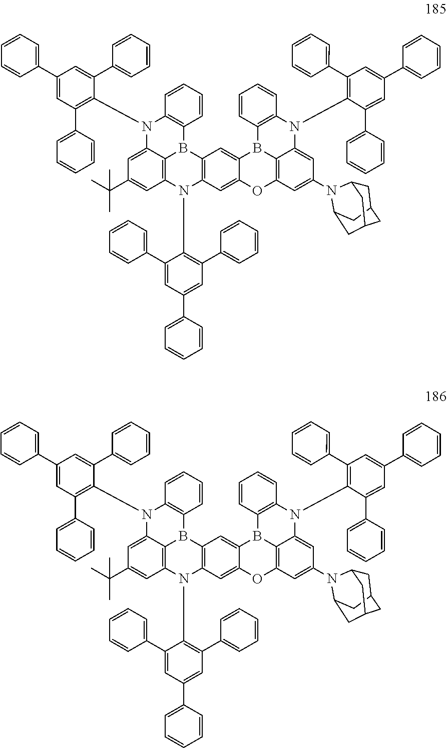 [SMILES: CC(C)(C)c1cc2c3c(c1)N(c1c(-c4ccccc4)cc(-c4ccccc4)cc1-c1ccccc1)c1cc4c(cc1B3c1ccccc1N2c1c(-c2ccccc2)cc(-c2ccccc2)cc1-c1ccccc1)B1c2ccccc2N(c2c(-c3ccccc3)cc(-c3ccccc3)cc2-c2ccccc2)c2cc(N3C5CC6CC(C5)CC3C6)cc(c21)O4 ; CC(C)(C)c1cc2c3c(c1)N(c1c(-c4ccccc4)cc(-c4ccccc4)cc1-c1ccccc1)c1cc4c(cc1B3c1ccccc1N2c1c(-c2ccccc2)cc(-c2ccccc2)cc1-c1ccccc1)B1c2ccccc2N(c2c(-c3ccccc3)cc(-c3ccccc3)cc2-c2ccccc2)c2cc(N3C5CC6CC(C5)CC3C6)cc(c21)O4] 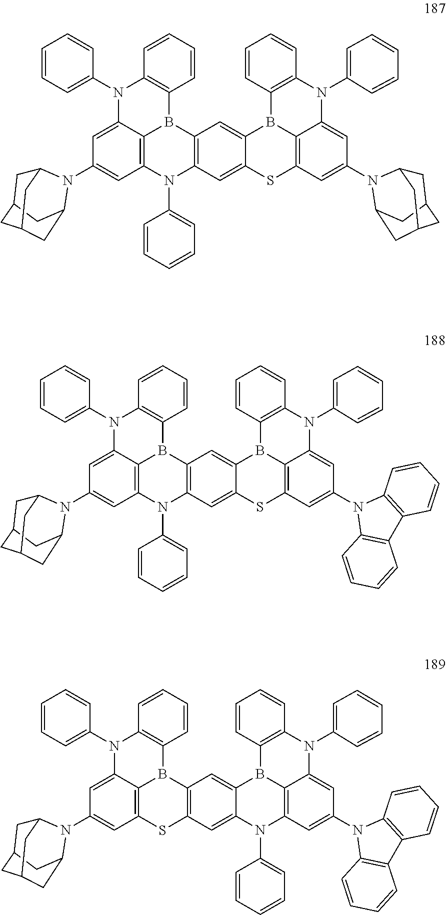 [SMILES: c1ccc(N2c3ccccc3B3c4cc5c(cc4Sc4cc(N6C7CC8CC(C7)CC6C8)cc2c43)N(c2ccccc2)c2cc(N3C4CC6CC(C4)CC3C6)cc3c2B5c2ccccc2N3c2ccccc2)cc1 ; c1ccc(N2c3ccccc3B3c4cc5c(cc4Sc4cc(-n6c7ccccc7c7ccccc76)cc2c43)N(c2ccccc2)c2cc(N3C4CC6CC(C4)CC3C6)cc3c2B5c2ccccc2N3c2ccccc2)cc1 ; c1ccc(N2c3ccccc3B3c4cc5c(cc4Sc4cc(N6C7CC8CC(C7)CC6C8)cc2c43)N(c2ccccc2)c2cc(-n3c4ccccc4c4ccccc43)cc3c2B5c2ccccc2N3c2ccccc2)cc1] 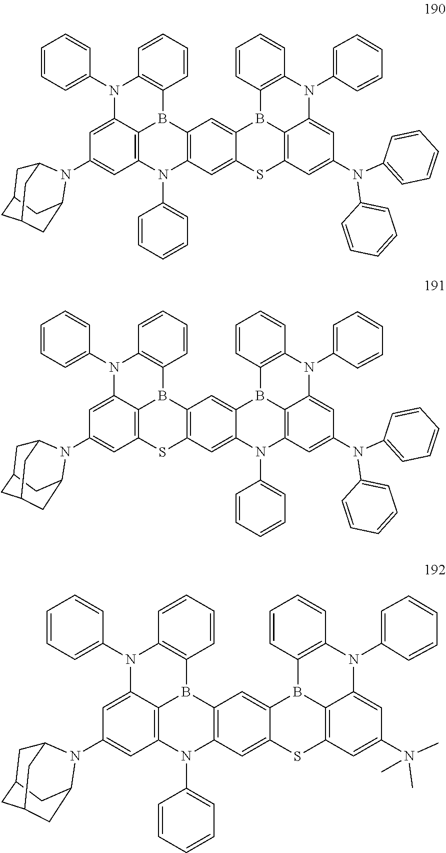 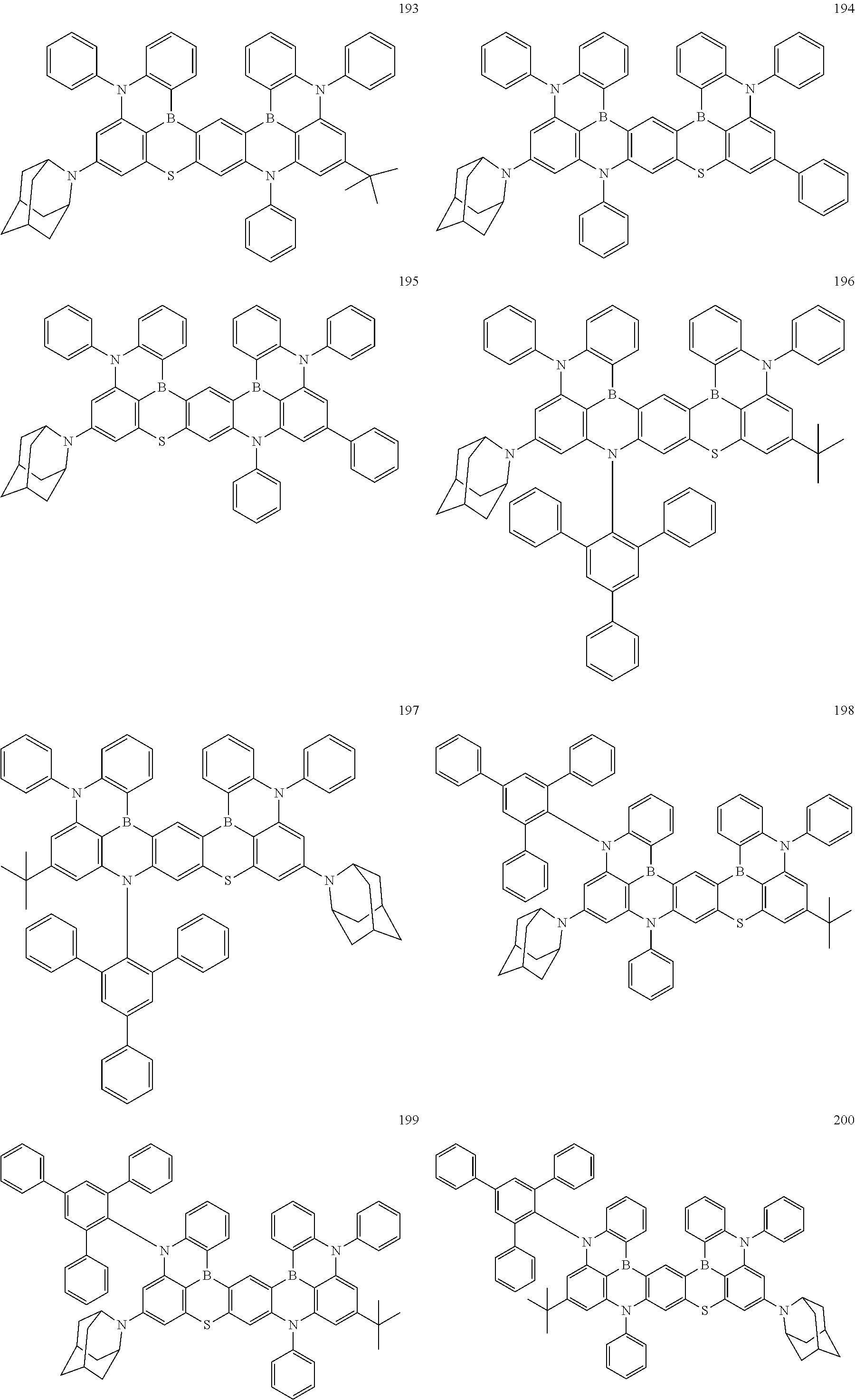 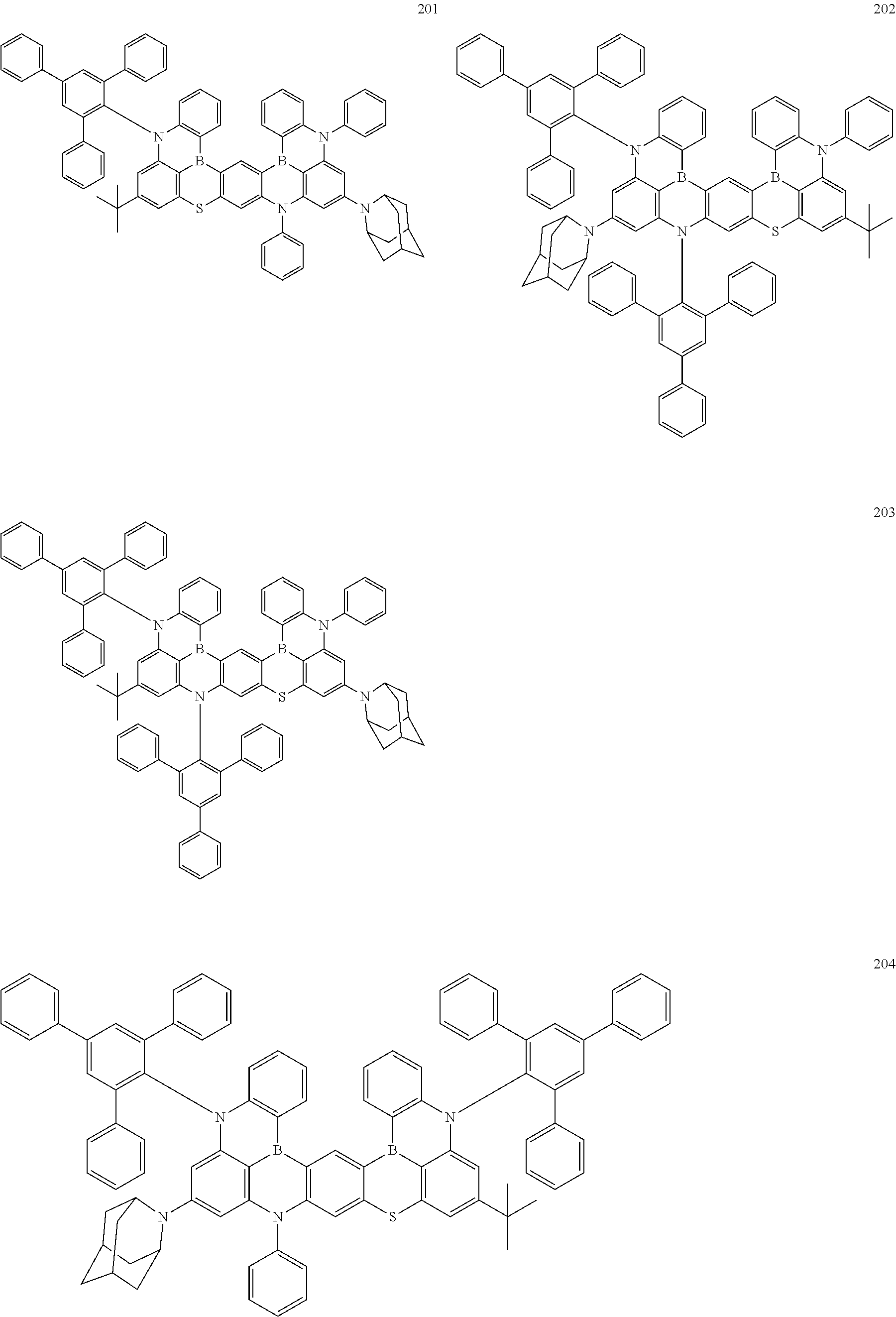 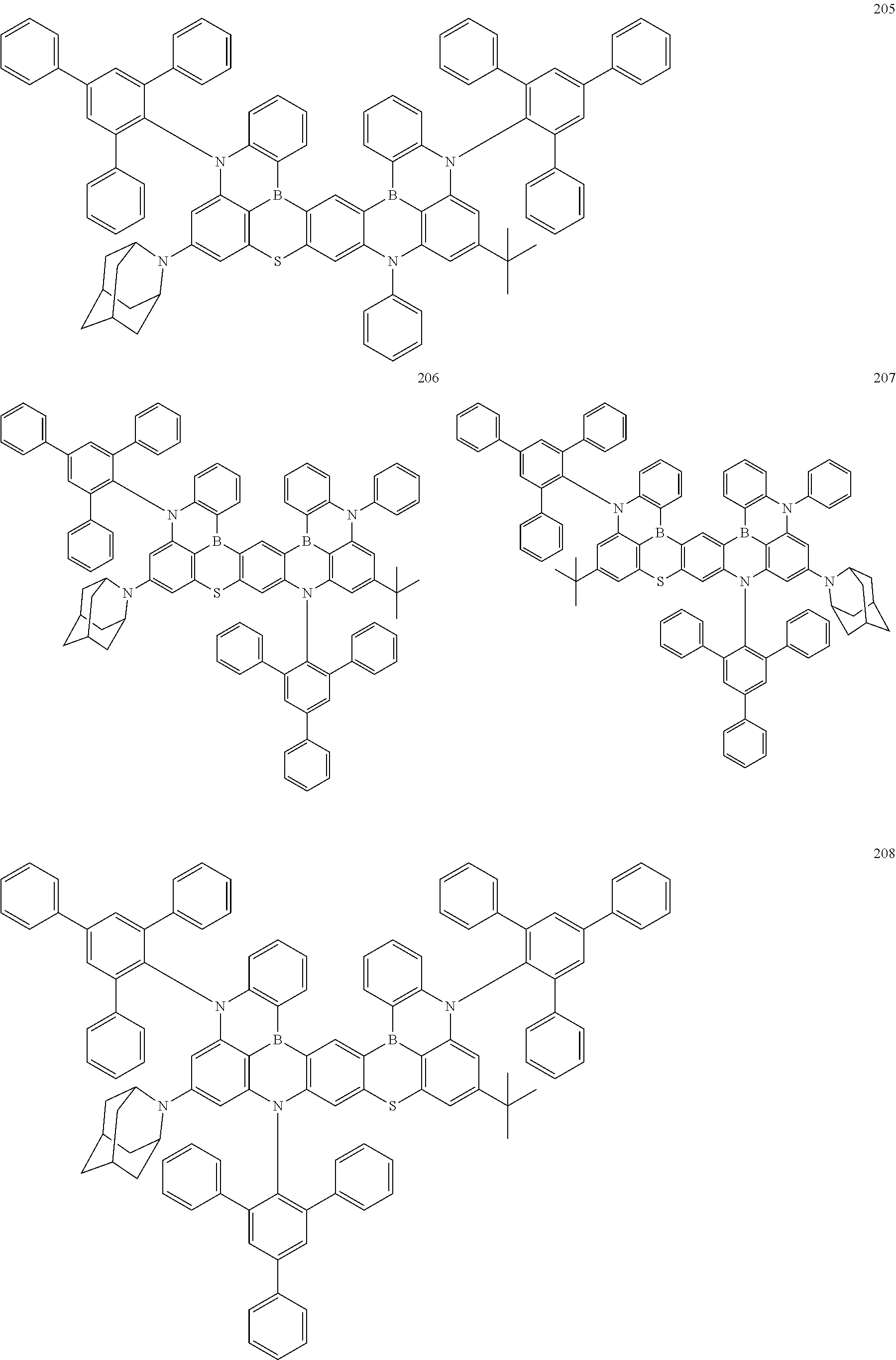 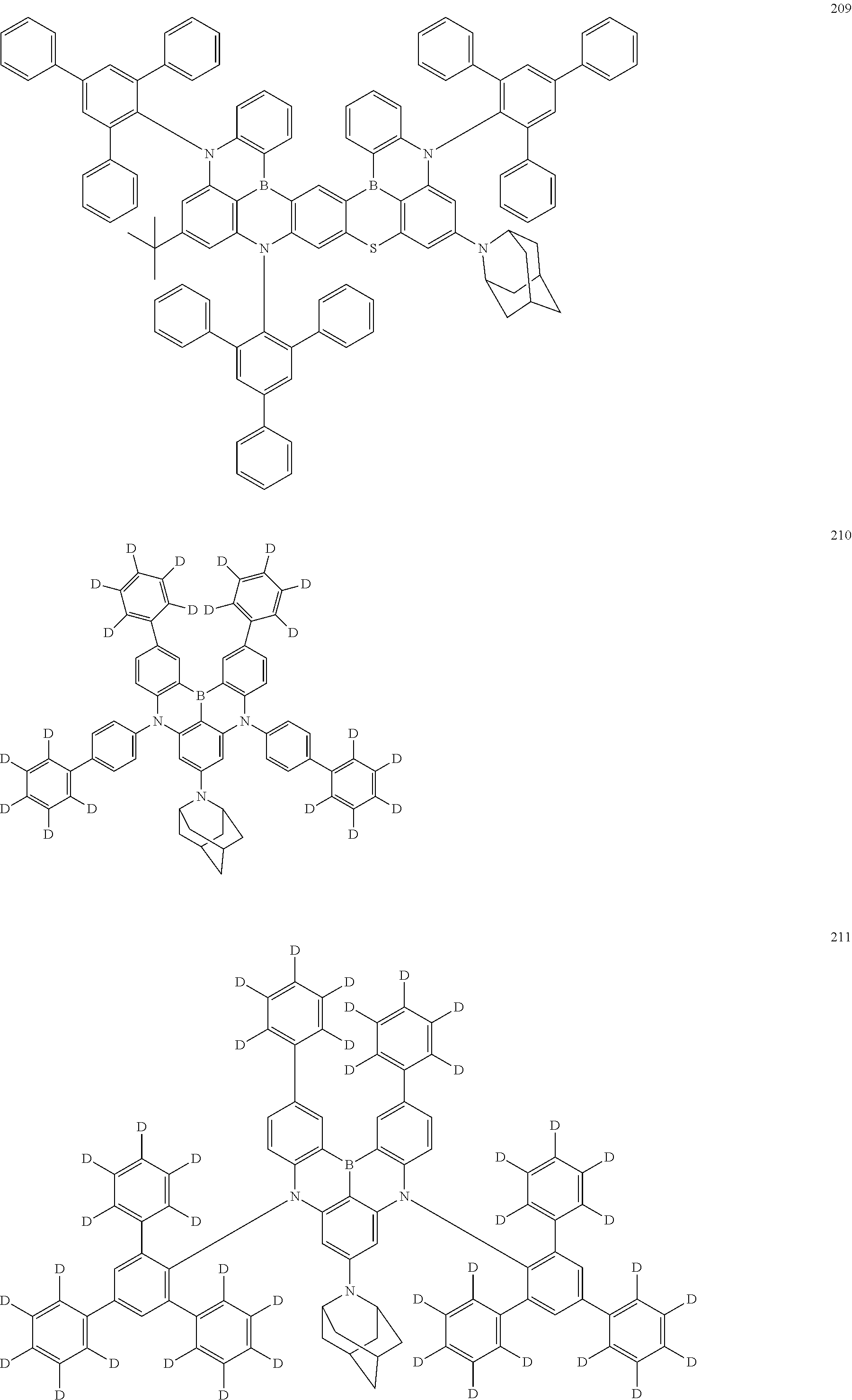 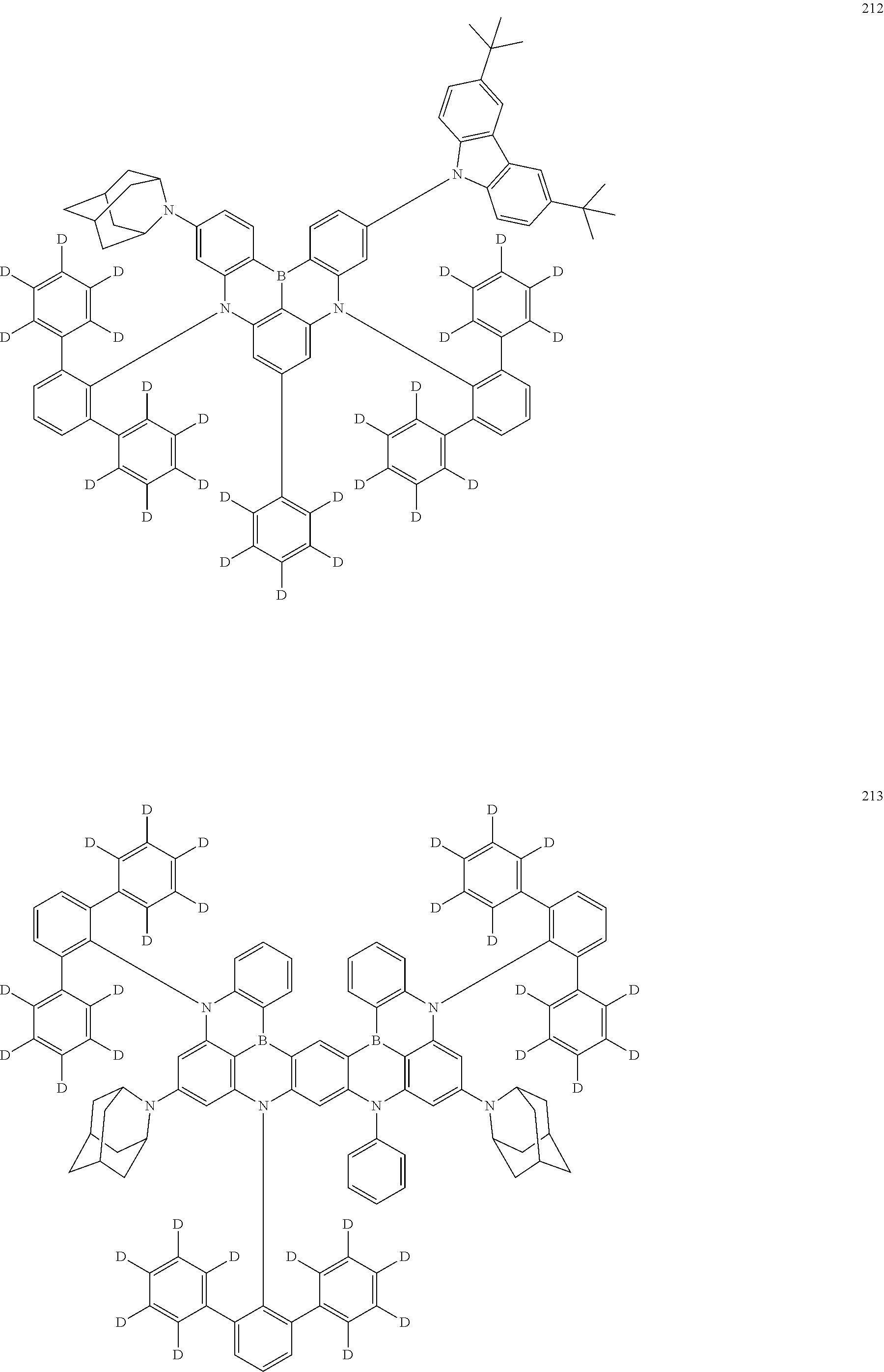 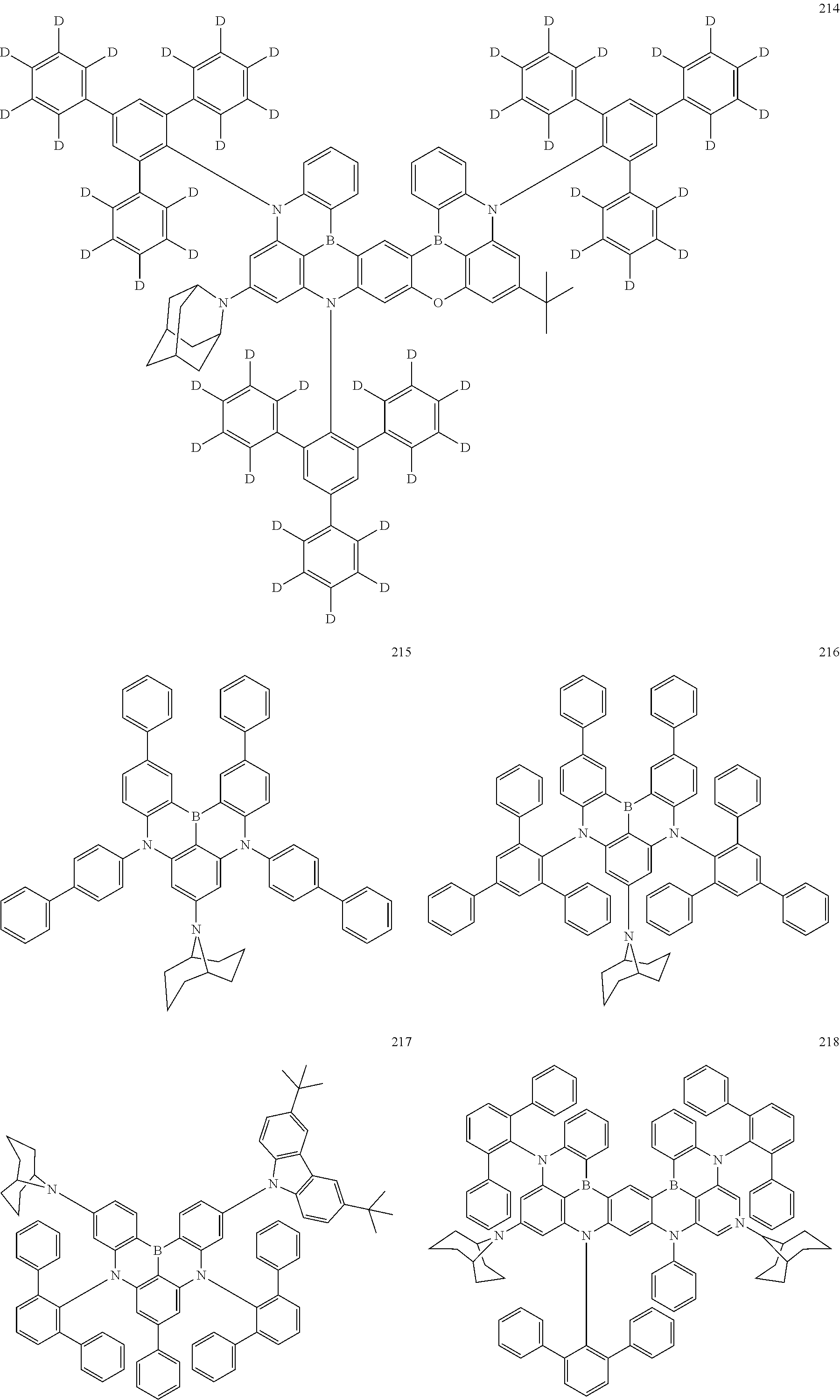 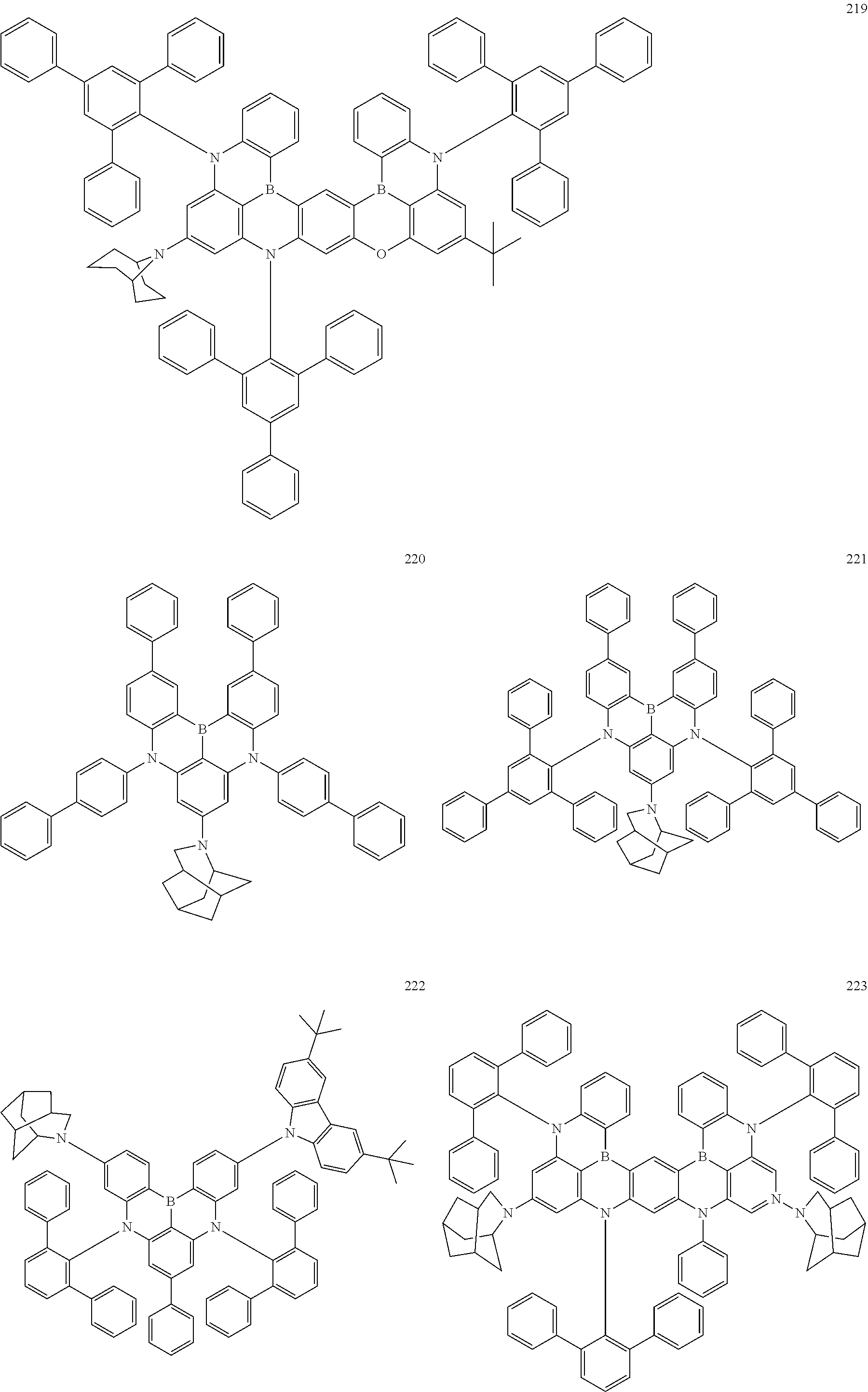 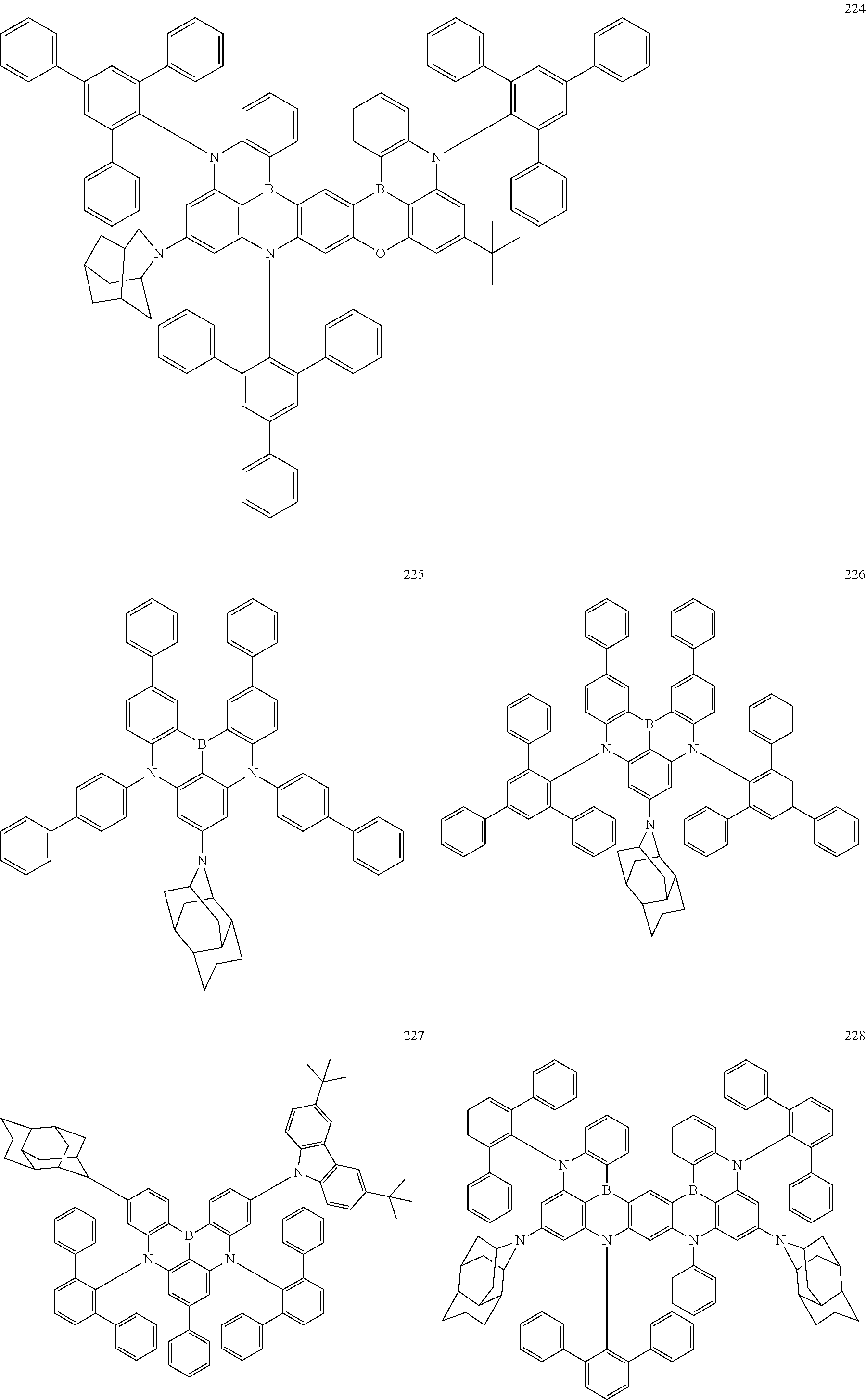 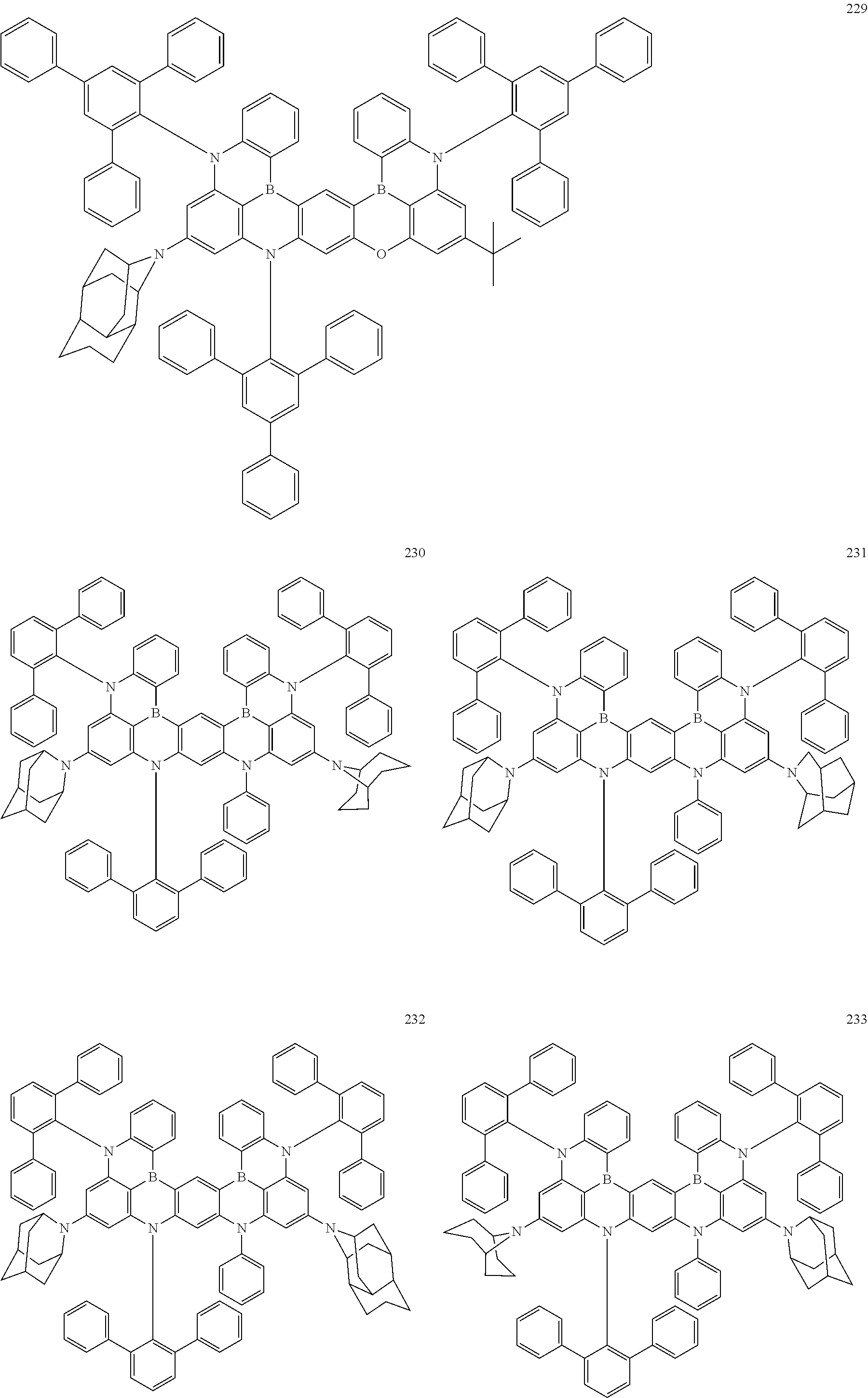 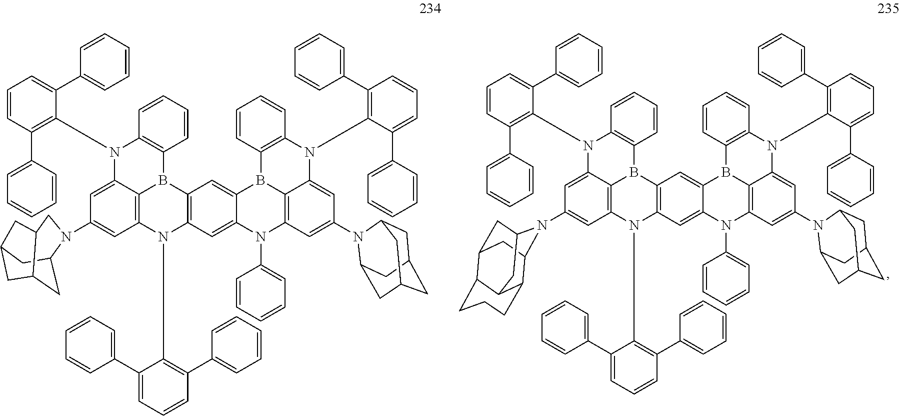
wherein D in Compound Group 1 represents a deuterium atom.

13. The light emitting element of claim 1, wherein the second compound is any one from among compounds of Compound Group 2, the third compound is any one from among compounds of Compound Group 3, and the fourth compound is any one from among compounds of Compound Group 4: 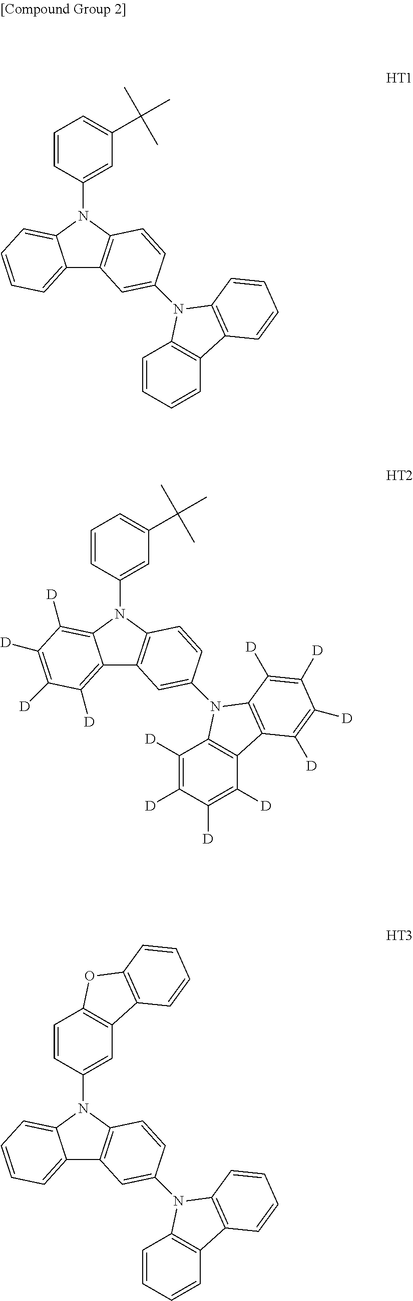 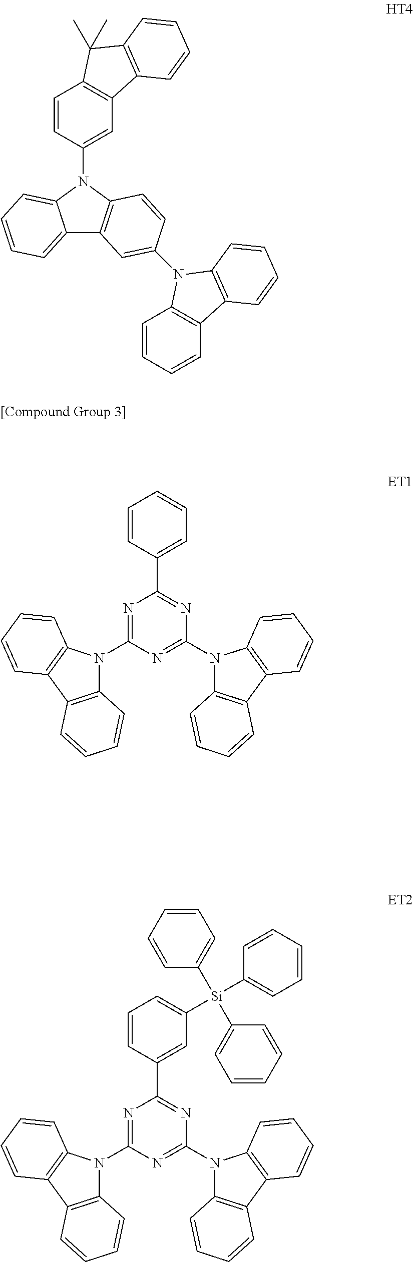 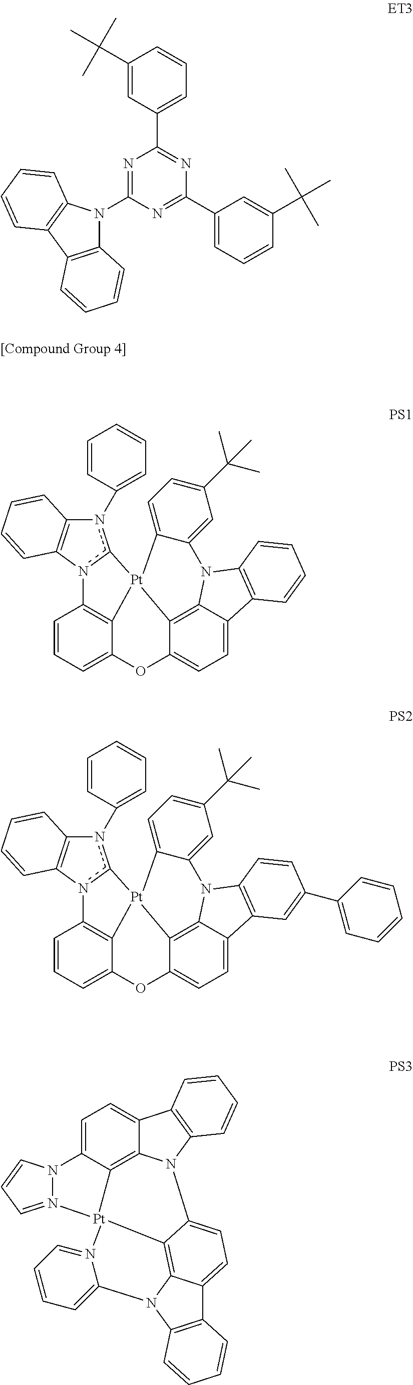 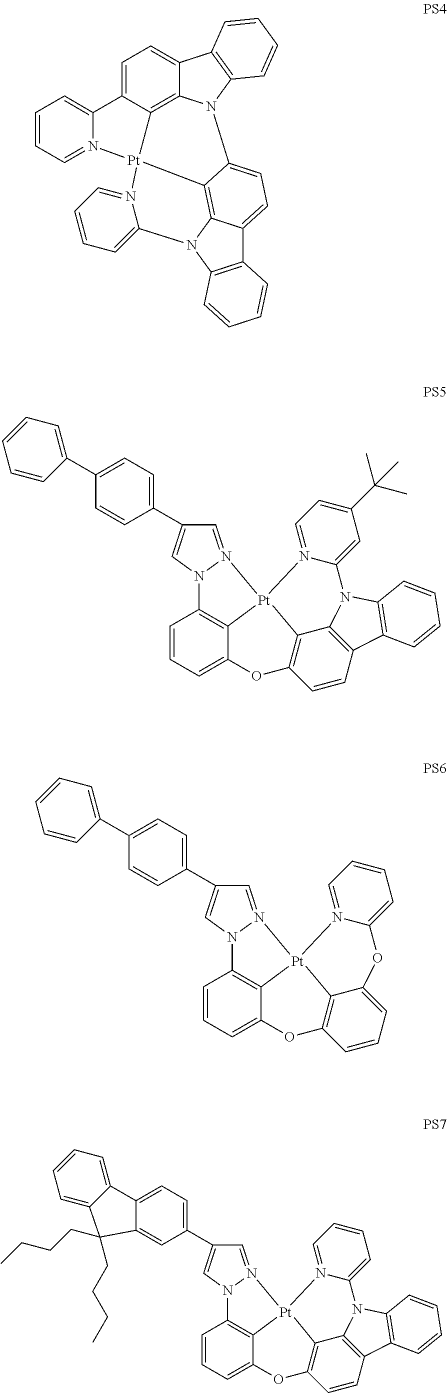 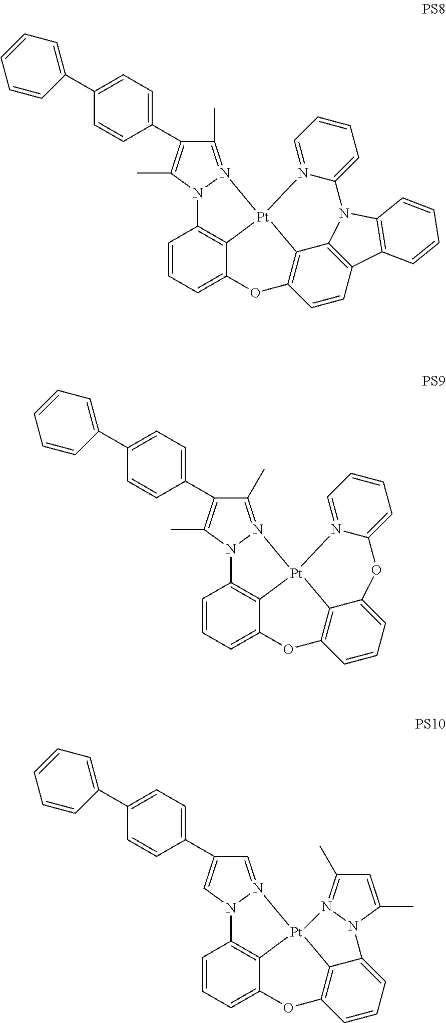 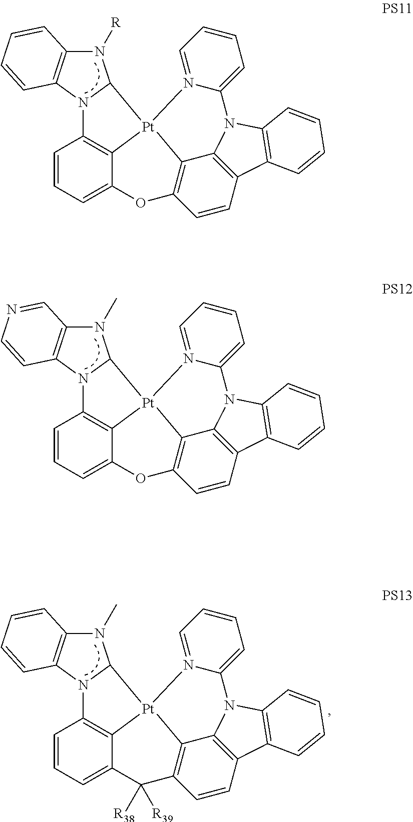
wherein, in Compound Group 4, R, R₃₈, and R₃₉ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

14. A light emitting element comprising:
a first electrode;
a second electrode on the first electrode; and
at least one functional layer between the first electrode and the second electrode and comprising a polycyclic compound represented by Formula 1: 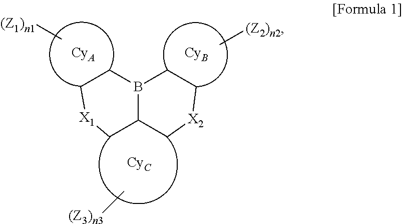
wherein, in Formula 1,
Cy_{A}, Cy_{B}, and Cy_{C} are each independently an aryl group having 6 to 30 ring-forming carbon atoms, or a heteroaryl group having 2 to 30 ring-forming carbon atoms,
X₁ and X₂ are each independently O, S, or NR₁,
R₁ is a substituted or unsubstituted aryl group having 6 to 30 ring-forming carbon atoms, or a substituted or unsubstituted heteroaryl group having 5 to 30 ring-forming carbon atoms,
n1, n2, and n3 are integers satisfying conditions of 0≤n1≤(the number of ring-forming carbon atoms of Cy_{A}-2), 0≤n2≤(the number of ring-forming carbon atoms of Cy_{B}-2), 0≤n3≤(the number of ring-forming carbon atoms of Cy_{C}-2), respectively, and
(n1+n2+n3)≥1,
at least one from among Z₁, Z₂, and Z₃ being a nitrogen-containing polycyclic group having at least eight ring-forming carbon atoms and comprising at least two bridgehead carbon atoms, or a substituent comprising the nitrogen-containing polycyclic group, and any remainder from among Z₁, Z₂, and Z₃ being each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

15. The light emitting element of claim 14, wherein the at least one functional layer comprises an emission layer, a hole transport region between the first electrode and the emission layer, and an electron transport region between the emission layer and the second electrode, and
the emission layer comprises the polycyclic compound.

16. The light emitting element of claim 14, wherein the polycyclic compound represented by Formula 1 is represented by Formula 1-1a, Formula 1-2a, or Formula 1-2b: 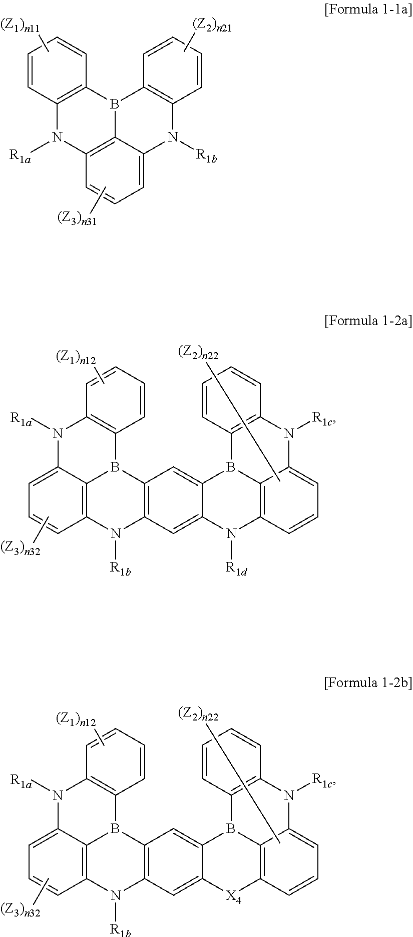
wherein, in Formula 1-2b,
X₄ is O, S, or NR₁, and
R₁ is the same as defined in Formula 1,
in Formula 1-1a, Formula 1-2a, and Formula 1-2b,
R₁ₐ to R_{1d} are each independently a substituted or unsubstituted aryl group having 6 to 30 ring-forming carbon atoms, or a substituted or unsubstituted heteroaryl group having 5 to 30 ring-forming carbon atoms,
n11, n21 and n12 are each independently an integer of 0 to 4,
n31 and n32 are each independently an integer of 0 to 3,
n22 is an integer of 0 to 7,
a sum of n11, n21, and n31 is 1 or greater,
a sum of n12, n22, and n32 is 1 or greater, and
Z₁, Z₂, and Z₃ are the same as defined in Formula 1.

17. The light emitting element of claim 14, wherein the nitrogen-containing polycyclic group is represented by any one from among Formulae 2-1 to 2-4: 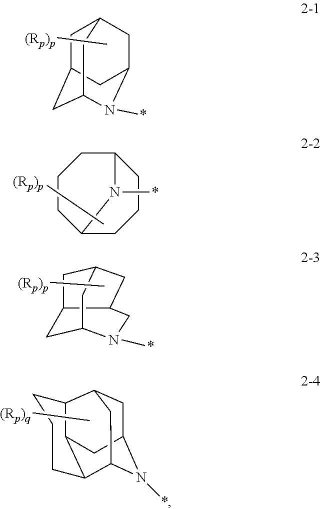
wherein, in Formulae 2-1 to 2-4, Rₚ is a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 5 to 30 ring-forming carbon atoms,
p is an integer of 0 to 14, and
q is an integer of 0 to 18.

18. A polycyclic compound represented by Formula 1: 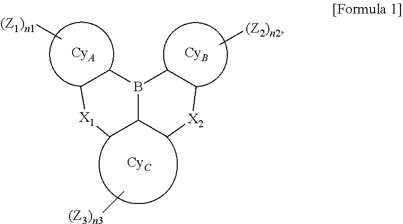
wherein, in Formula 1,
Cy_{A}, Cy_{B}, and Cy_{C} are each independently an aryl group having 6 to 30 ring-forming carbon atoms, or a heteroaryl group having 2 to 30 ring-forming carbon atoms,
X₁ and X₂ are each independently O, S, or NR₁,
R₁ is a substituted or unsubstituted aryl group having 6 to 30 ring-forming carbon atoms, or a substituted or unsubstituted heteroaryl group having 5 to 30 ring-forming carbon atoms,
n1, n2, and n3 are integers satisfying conditions of 0≤n1≤(the number of ring-forming carbon atoms of Cy_{A}-2), 0≤n2≤(the number of ring-forming carbon atoms of Cy_{B}-2), 0≤n3≤(the number of ring-forming carbon atoms of Cy_{C}-2), respectively, and
(n1+n2+n3)≥1,
at least one from among Z₁, Z₂, and Z₃ being a nitrogen-containing polycyclic group having at least eight ring-forming carbon atoms and comprising at least two bridgehead carbon atoms, or a substituent comprising the nitrogen-containing polycyclic group, and any remainder from among Z₁, Z₂, and Z₃ being each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

19. The polycyclic compound of claim 18, wherein the polycyclic compound represented by Formula 1 is represented by Formula 1-1 or Formula 1-2: 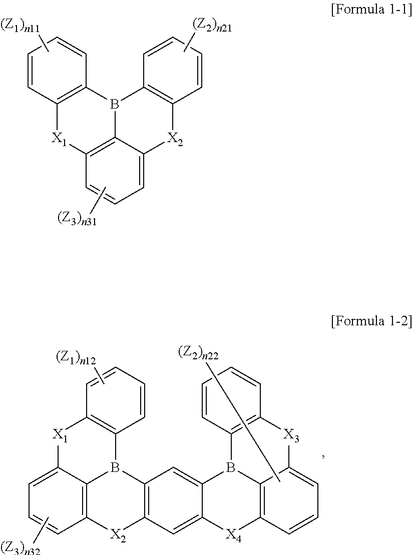
wherein, in Formula 1-1,
n11 and n21 are each independently an integer of 0 to 4,
n31 is an integer of 0 to 3, and
a sum of n11, n21, and n31 is 1 or greater,
in Formula 1-2,
X₃ and X₄ are each independently O, S, or NR₁,
n12 is an integer of 0 to 4,
n22 is an integer of 0 to 7,
n32 is an integer of 0 to 3, and
a sum of n12, n22, and n32 is 1 or greater, and
in Formula 1-1 and Formula 1-2, X₁, X₂, R₁, Z₁, Z₂, and Z₃ are the same as respectively defined in Formula 1.

20. The polycyclic compound of claim 19, wherein the polycyclic compound represented by Formula 1-1 is represented by Formula 1-1a: 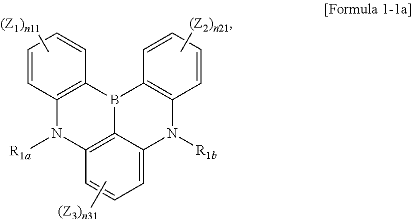
wherein, in Formula 1-1a,
R₁ₐ and R_{1b} are each independently a substituted or unsubstituted aryl group having 6 to 30 ring-forming carbon atoms, or a substituted or unsubstituted heteroaryl group having 5 to 30 ring-forming carbon atoms,
Z₁, Z₂, and Z₃ are the same as defined in Formula 1, and
n11, n21, and n31 are the same as defined in Formula 1-1.

21. The polycyclic compound of claim 19, wherein the polycyclic compound represented by Formula 1-1 is represented by any one from among Formula 1-1b to Formula 1-1e: 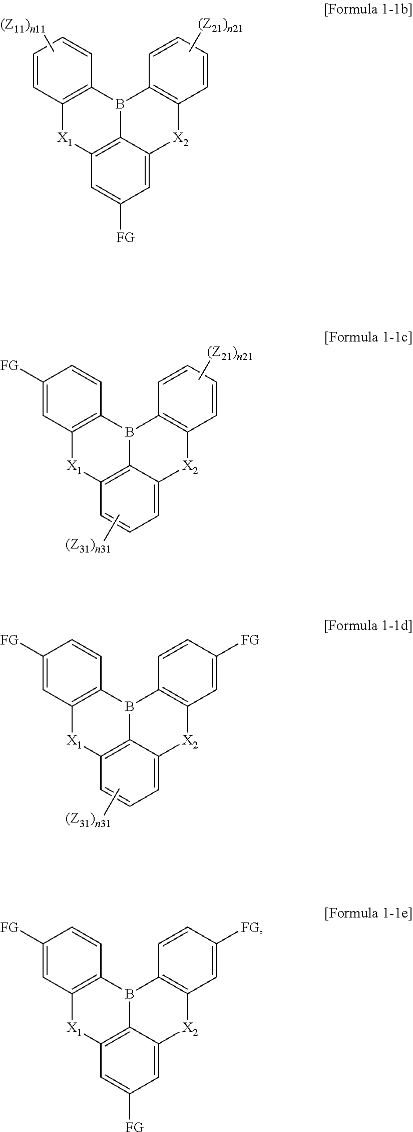
wherein, in Formula 1-1b to Formula 1-1e,
FG is the nitrogen-containing polycyclic group, or a substituent comprising the nitrogen-containing polycyclic group,
Z₁₁, Z₂₁, and Z₃₁ are each independently a hydrogen atom, a deuterium atom, a halogen atom, a substituted or unsubstituted alkyl group having 1 to 20 carbon group, a substituted or unsubstituted aryl group having 6 to 30 ring-forming carbon atoms, or a substituted or unsubstituted heteroaryl group having 2 to 30 ring-forming carbon atoms, n11 and n21 are each independently an integer of 0 to 4,
n31 is an integer of 0 to 3, and
X₁ and X₂ are the same as defined in Formula 1.

22. The polycyclic compound of claim 21, wherein FG comprises azaadamantane.

23. The polycyclic compound of claim 19, wherein the polycyclic compound represented by Formula 1-2 is represented by Formula 1-2a or Formula 1-2b: 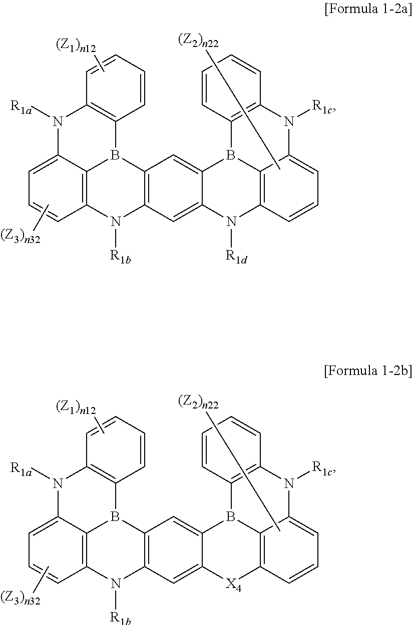
wherein, in Formula 1-2a and Formula 1-2b,
R₁ₐ, R_{1b}, R_{1c}, and R_{1d} are each independently a substituted or unsubstituted aryl group having 6 to 30 ring-forming carbon atoms, or a substituted or unsubstituted heteroaryl group having 5 to 30 ring-forming carbon atoms,
Z₁, Z₂, and Z₃ are the same as defined in Formula 1, and
X₄, n12, n22, and n32 are the same as respectively defined in Formula 1-2.

24. The polycyclic compound of claim 19, wherein the polycyclic compound represented by Formula 1-2 is represented by Formula 1-2c or Formula 1-2d: 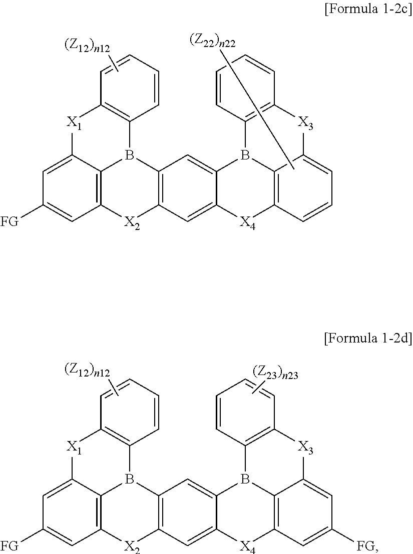
wherein, in Formula 1-2c and Formula 1-2d,
FG is the nitrogen-containing polycyclic group, or a substituent comprising the nitrogen-containing polycyclic group,
Z₁₂, Z₂₂, and Z₂₃ are each independently a hydrogen atom, a deuterium atom, a halogen atom, a substituted or unsubstituted alkyl group having 1 to 20 carbon group, a substituted or unsubstituted aryl group having 6 to 30 ring-forming carbon atoms, or a substituted or unsubstituted heteroaryl group having 2 to 30 ring-forming carbon atoms,
n12 and n23 are each independently an integer of 0 to 4,
n22 is an integer of 0 to 7, and
X₁ and X₂ are the same as defined in Formula 1, and X₃ and X₄ are the same as defined in Formula 1-2.

25. The polycyclic compound of claim 24, wherein FG comprises azaadamantane.

26. The polycyclic compound of claim 18, wherein the nitrogen-containing polycyclic compound is represented by any one from among Formulae 2-1 to 2-4: 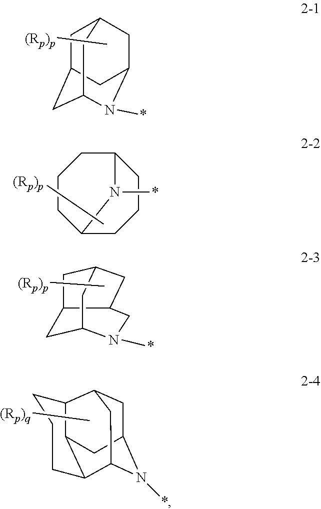
wherein, in Formulae 2-1 to 2-4, Rₚ is a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 5 to 30 ring-forming carbon atoms,
p is an integer of 0 to 14, and
q is an integer of 0 to 18.

27. The polycyclic compound of claim 18, wherein at least one from among Z₁, Z₂, and Z₃ is represented by any one from among Formulae 2-1 to 2-4 and 2-1a to 2-4a: 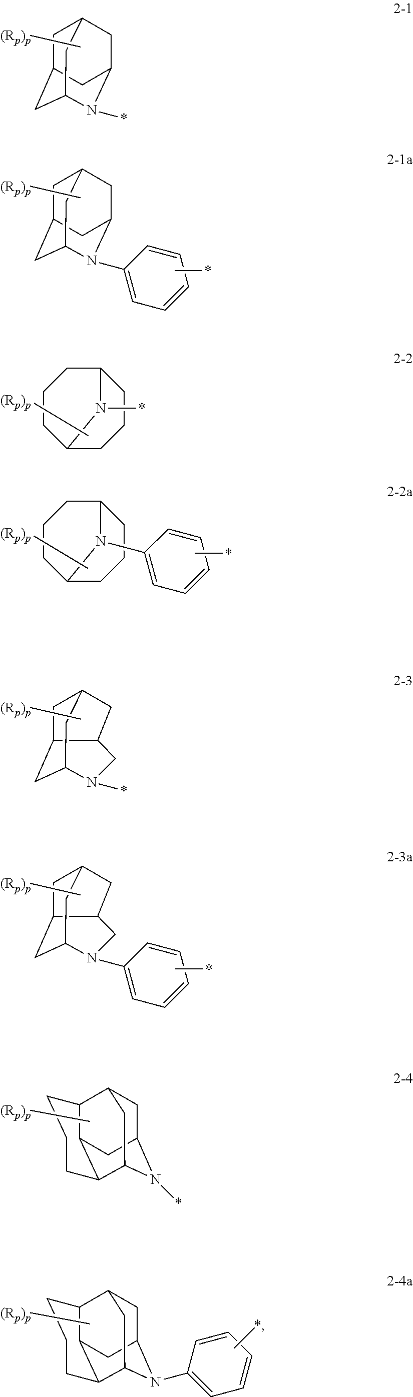
wherein, in Formulae 2-1 to 2-4 and 2-1a to 2-4a,
Rₚ is a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 5 to 30 ring-forming carbon atoms,
p is an integer of 0 to 14, and
q is an integer of 0 to 18.

28. The polycyclic compound of claim 18, wherein at least one from among R₁, Z₁, Z₂, and Z₃ in Formula 1 comprises a deuterium atom, or a substituent containing a deuterium atom.

29. The polycyclic compound of claim 18, wherein the polycyclic compound represented by Formula 1 is any one from among compounds of Compound Group 1: 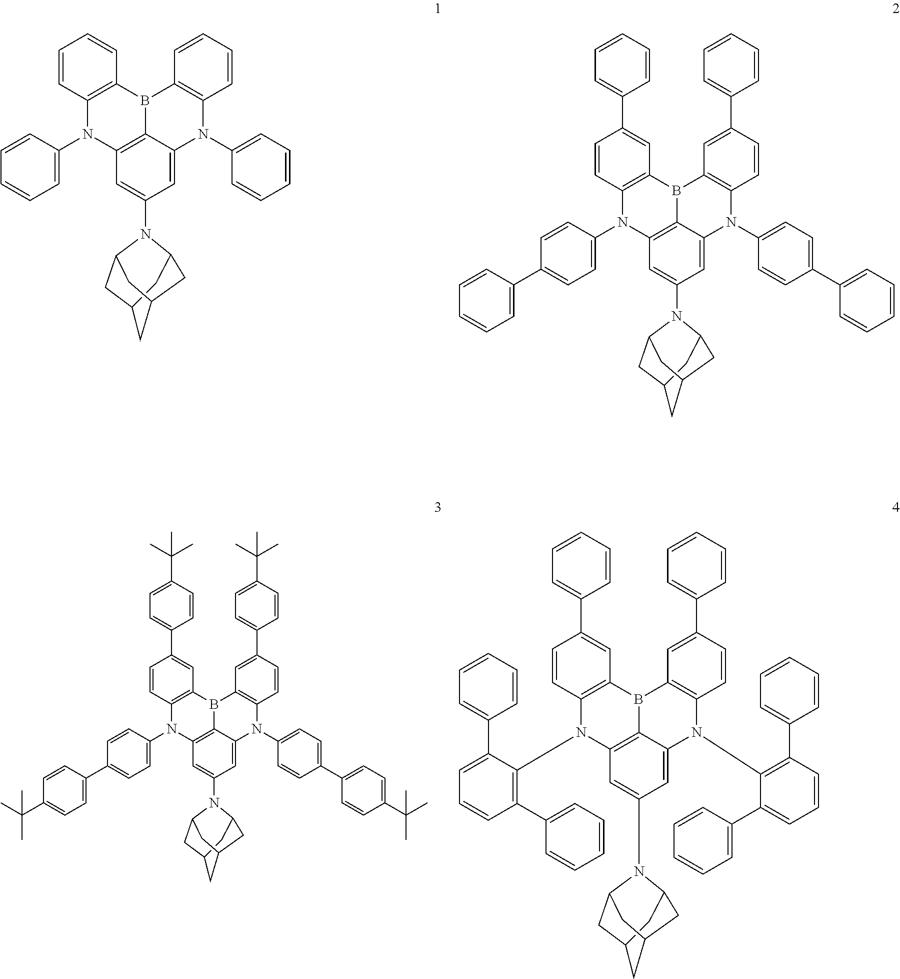 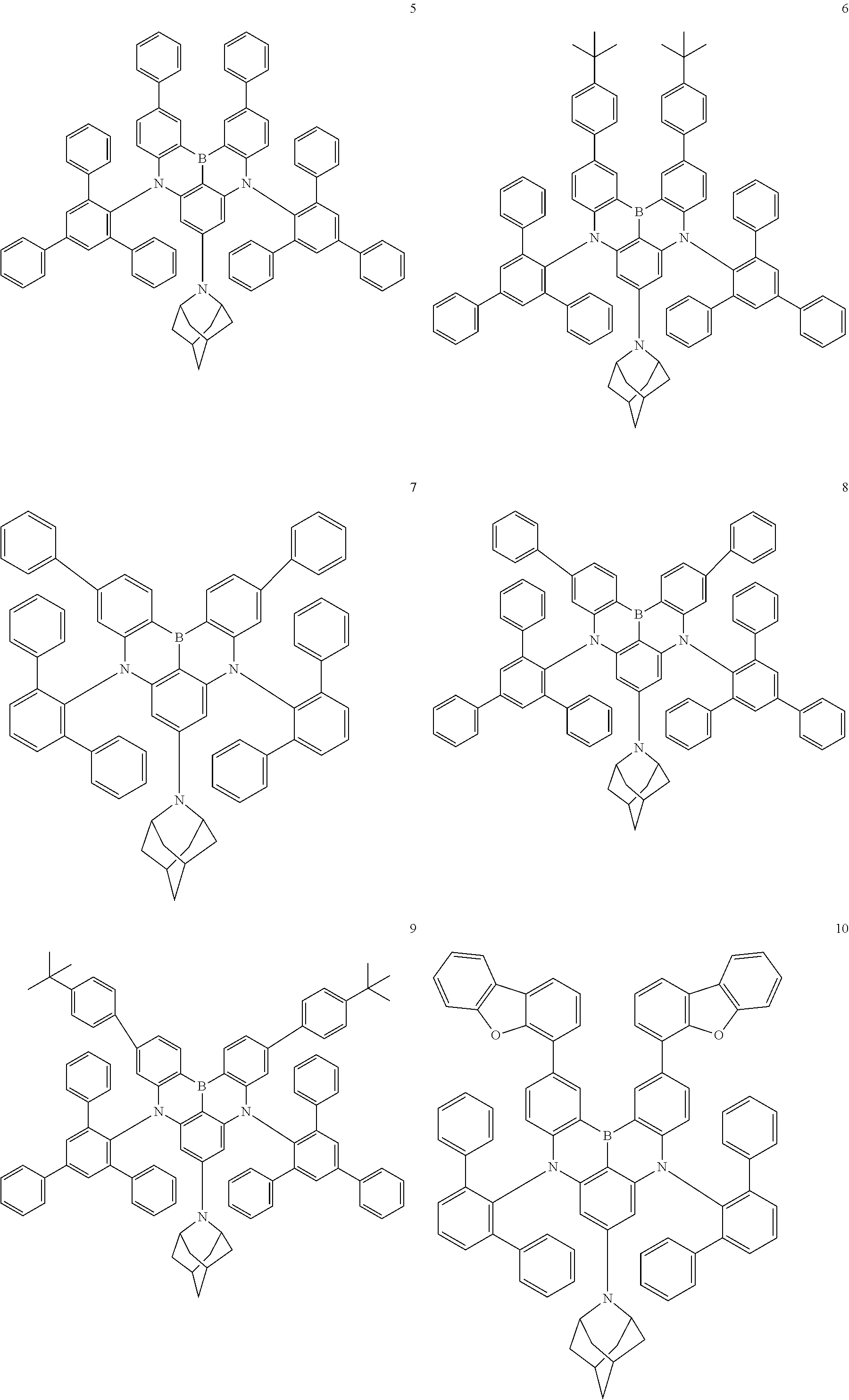 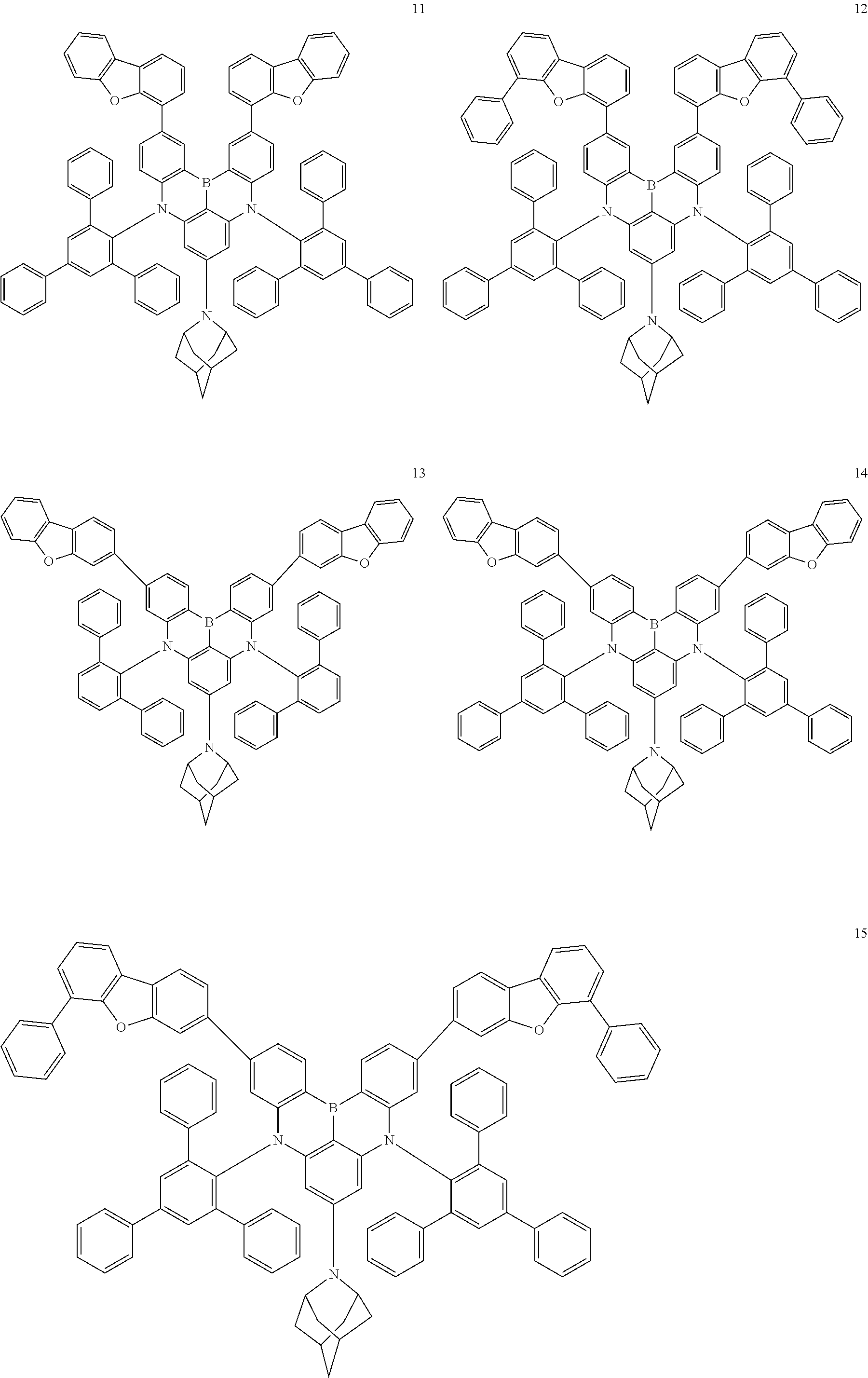 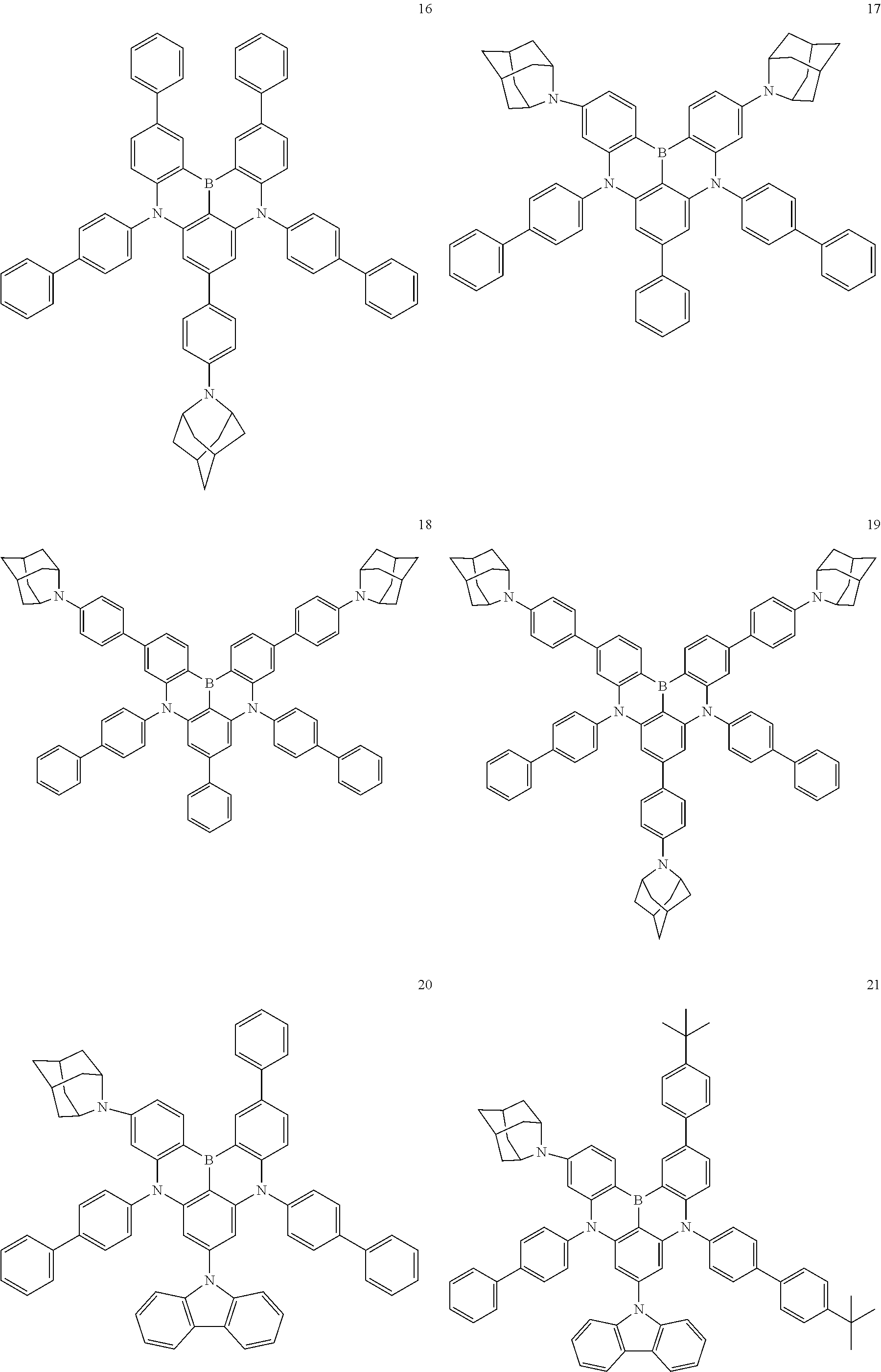 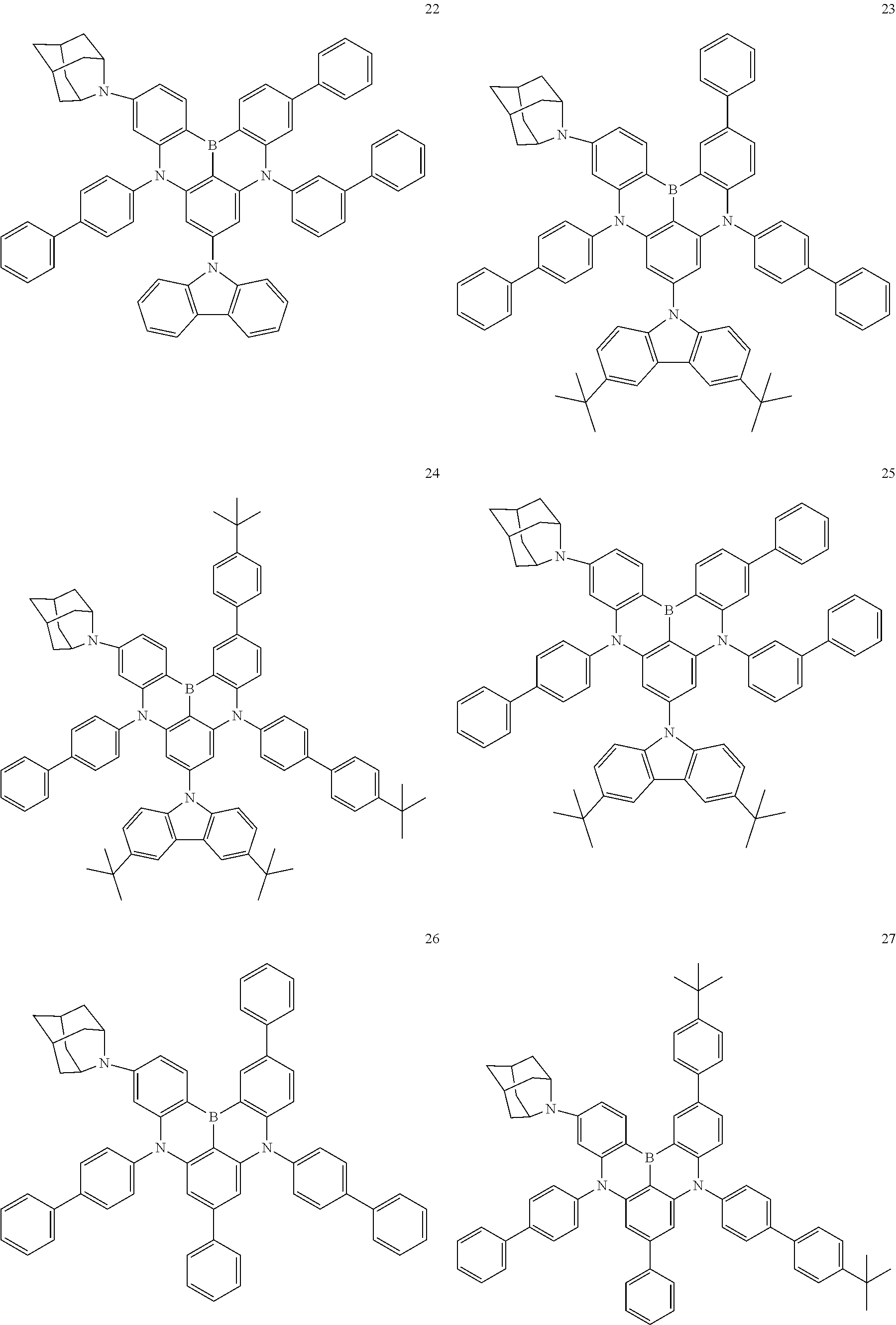 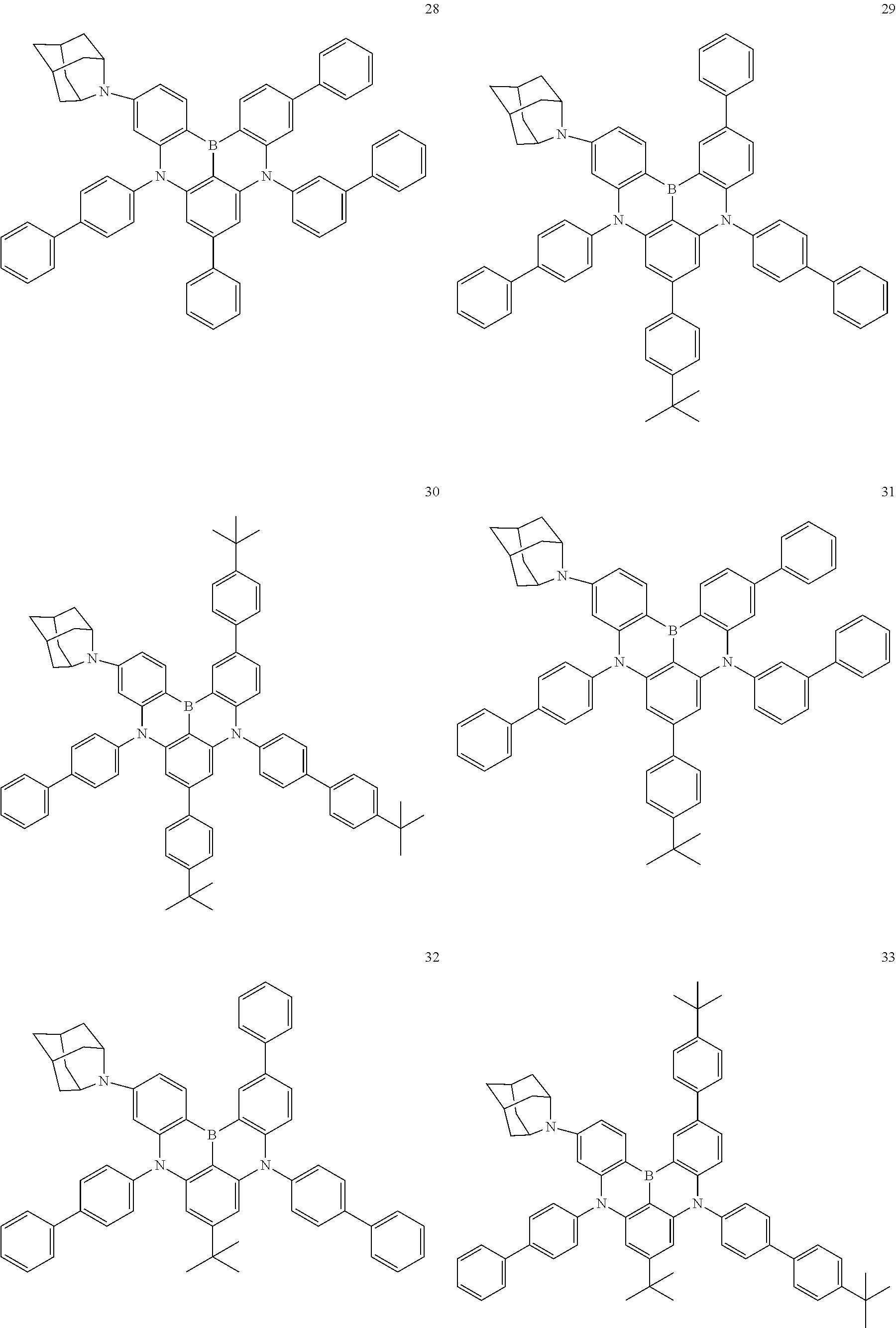 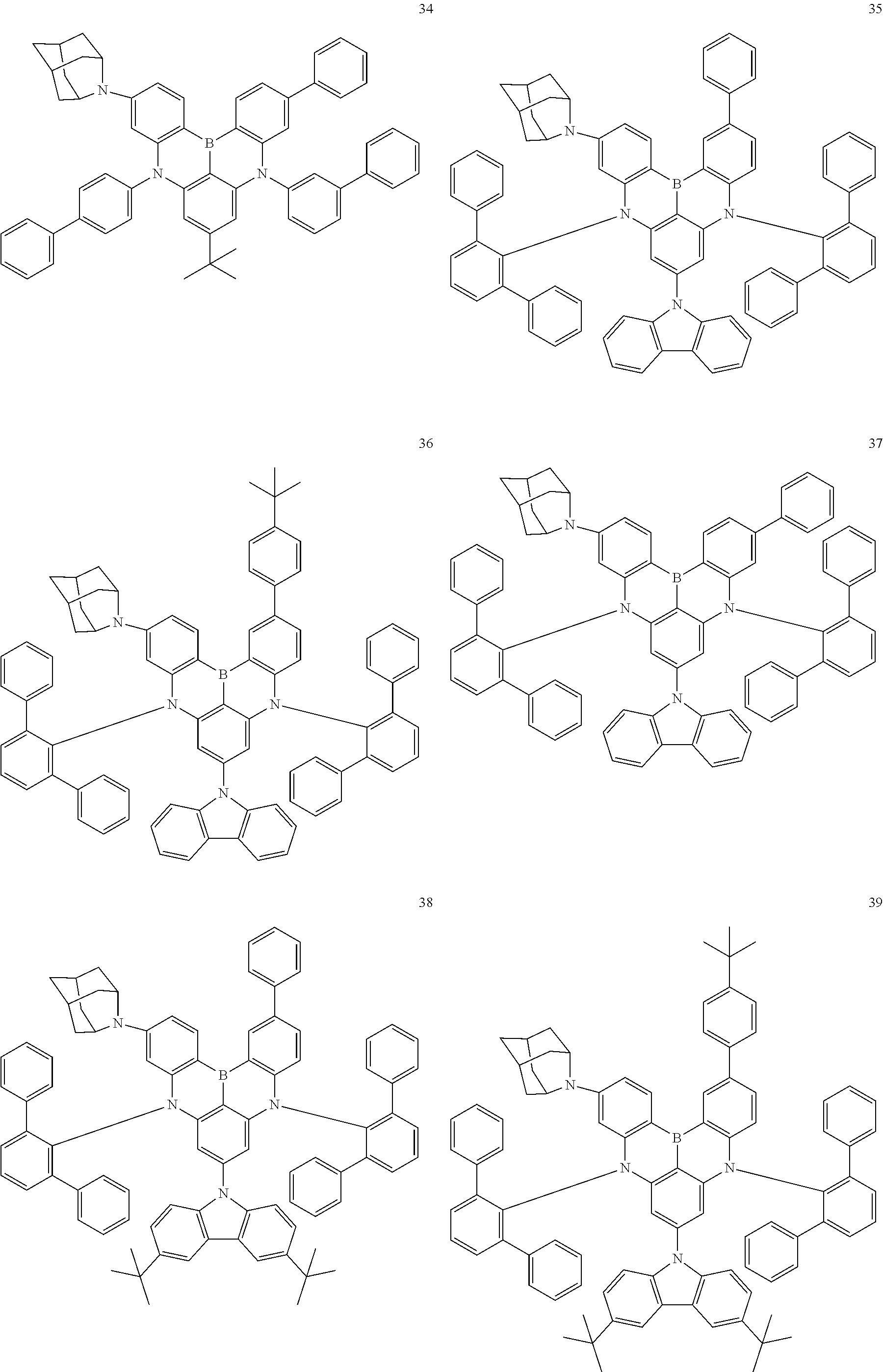 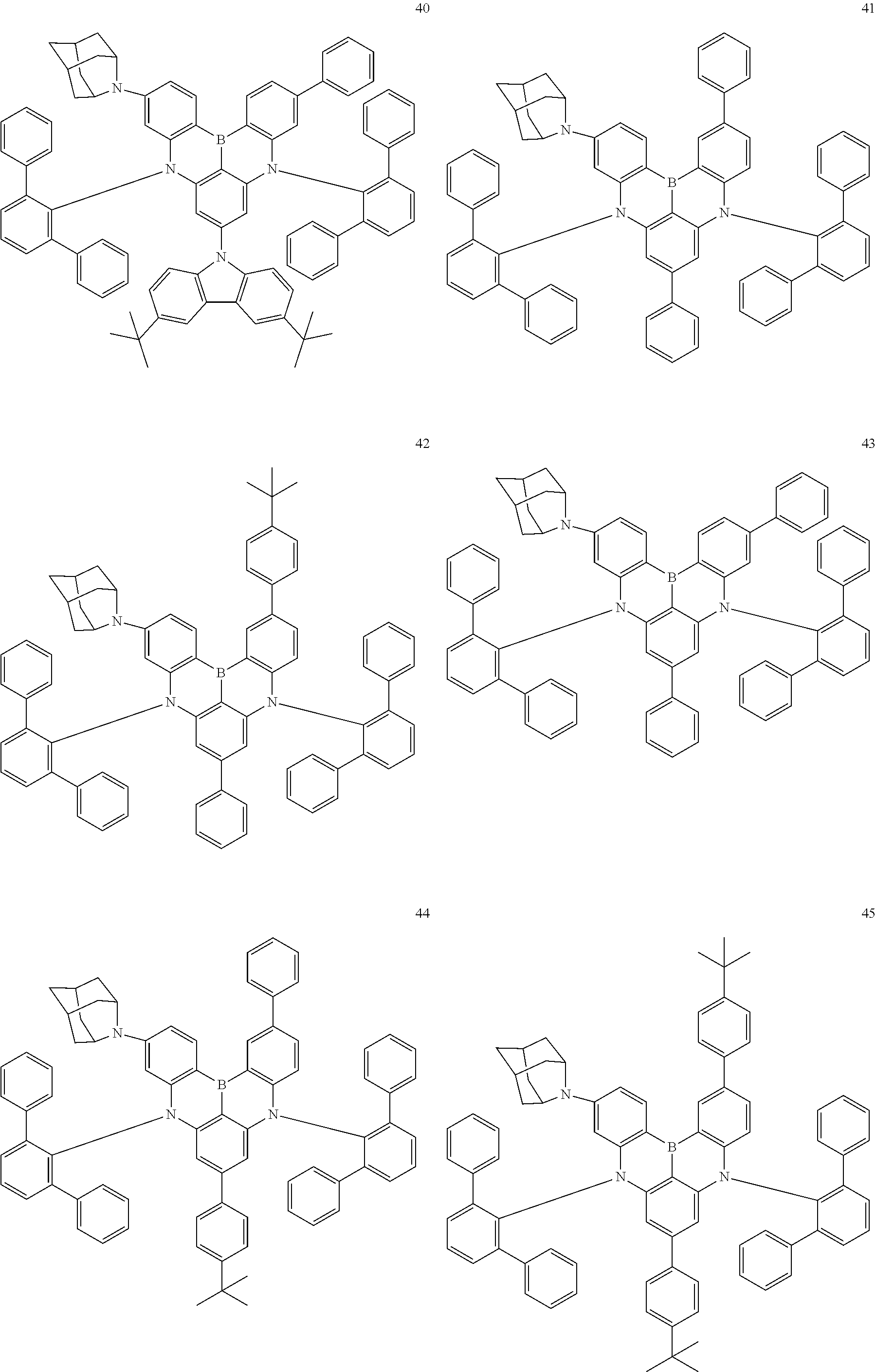 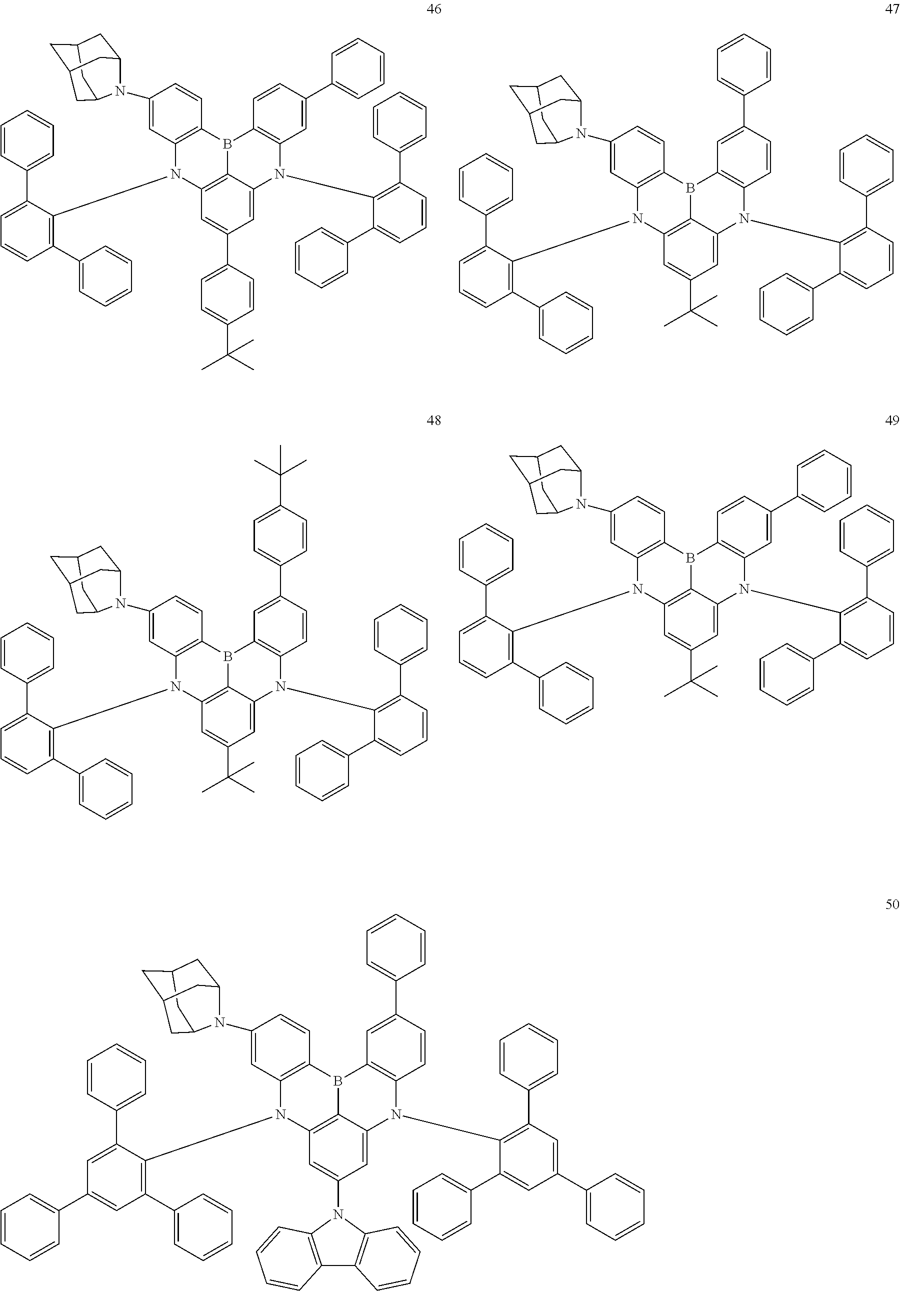 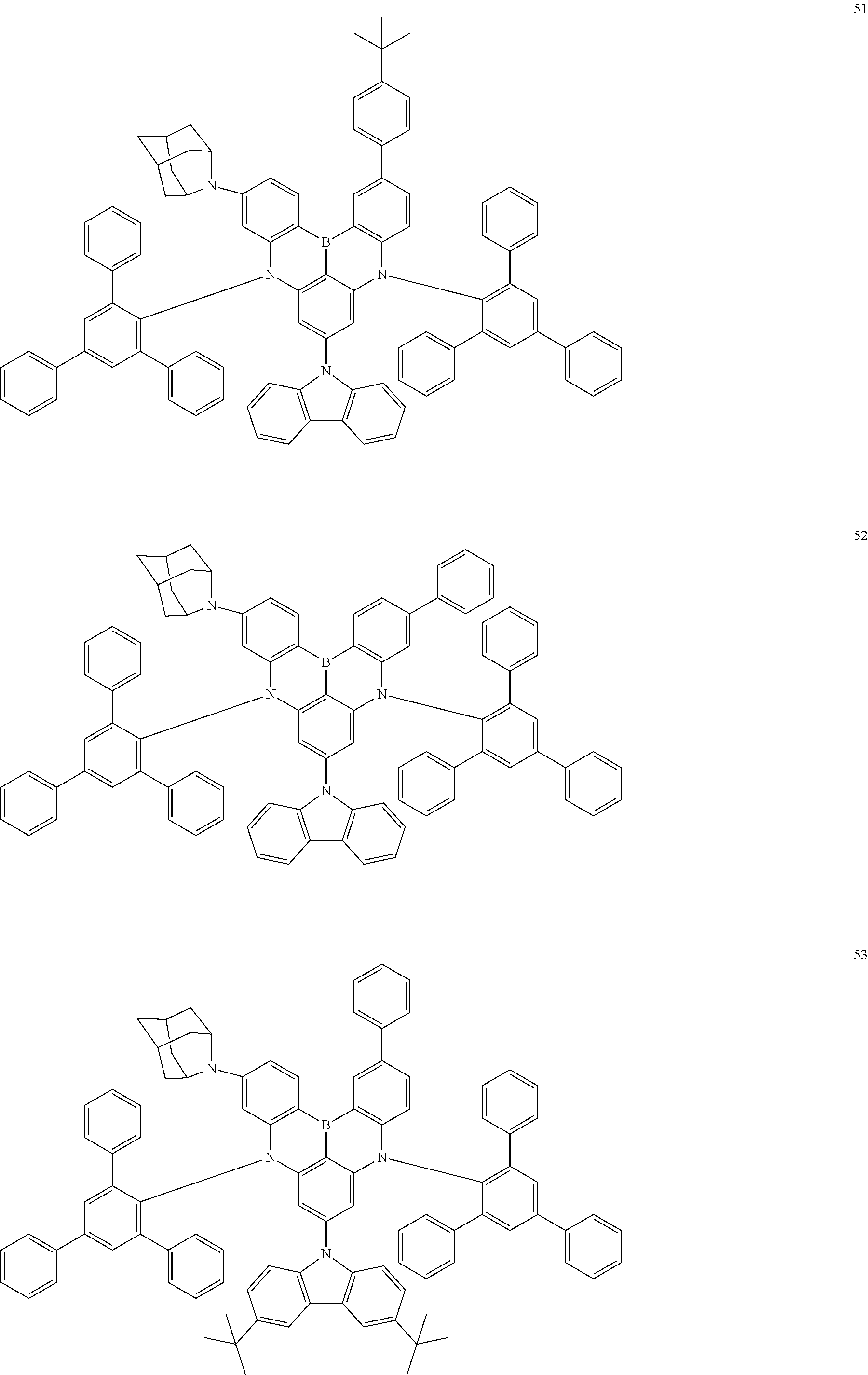 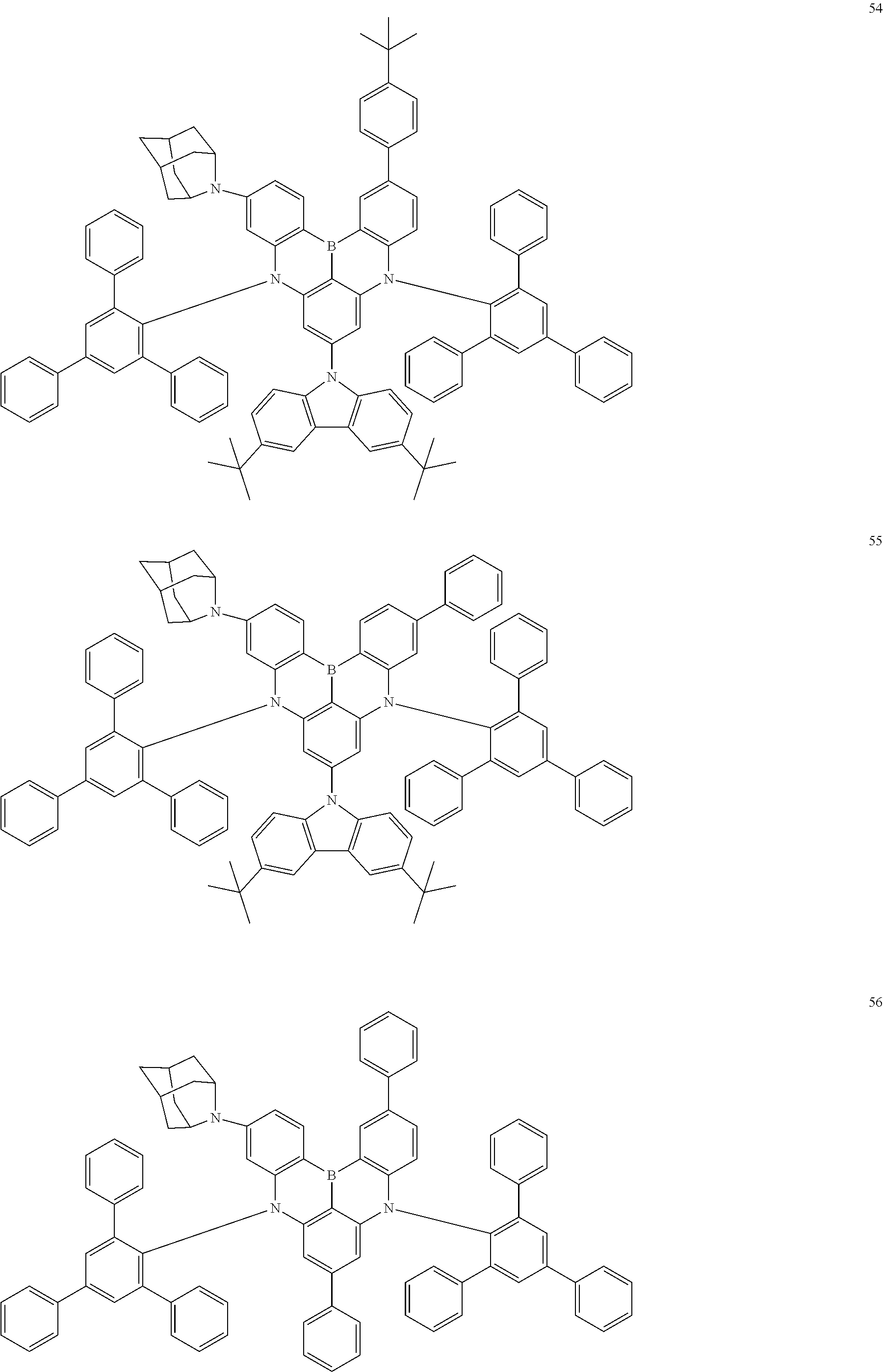 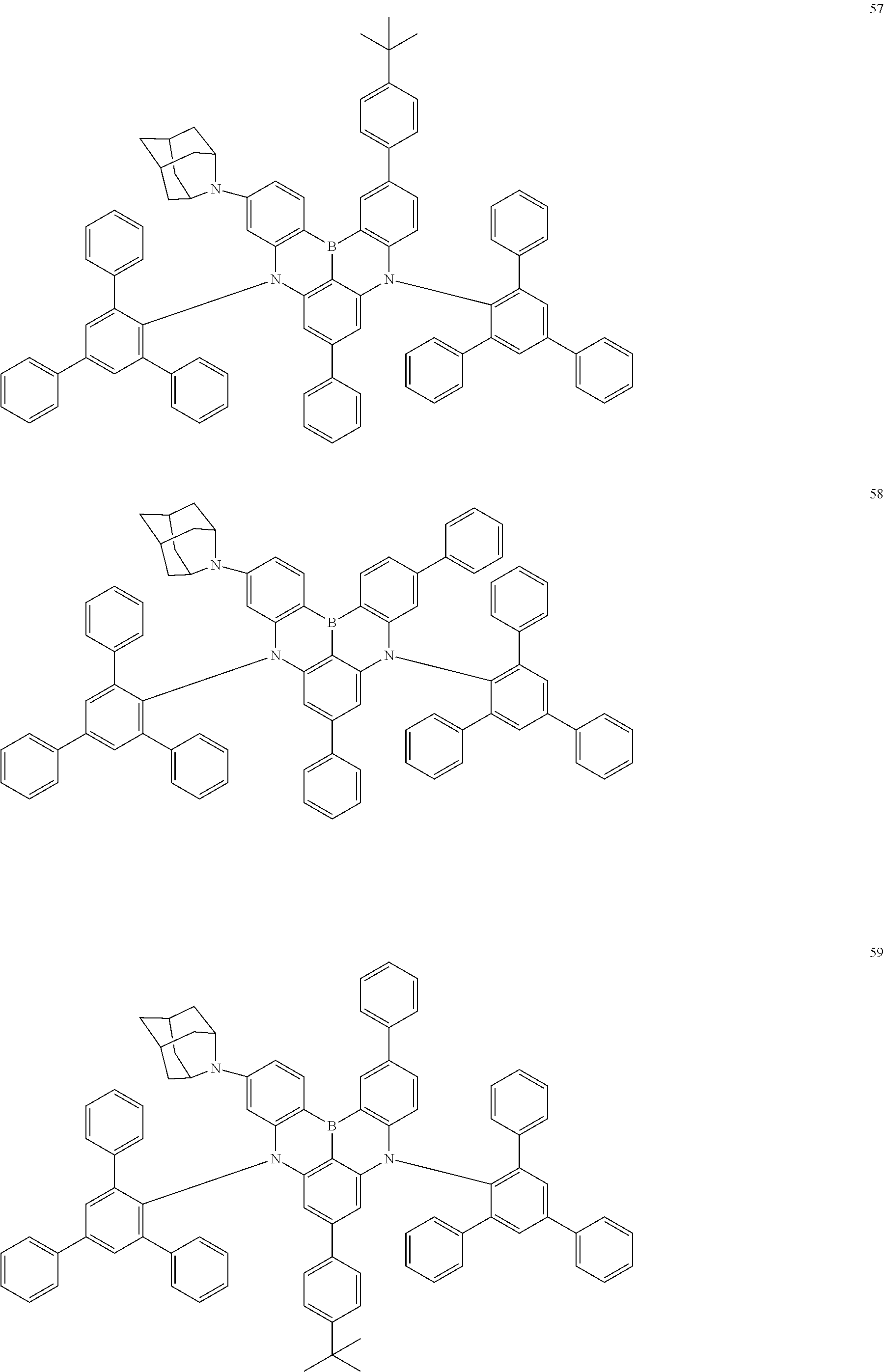 [SMILES: CC(C)(C)c1ccc(-c2ccc3c(c2)B2c4ccc(N5C6CC7CC(C6)CC5C7)cc4N(c4c(-c5ccccc5)cc(-c5ccccc5)cc4-c4ccccc4)c4cc(-c5ccccc5)cc(c42)N3c2c(-c3ccccc3)cc(-c3ccccc3)cc2-c2ccccc2)cc1 ; c1ccc(-c2cc(-c3ccccc3)c(N3c4cc(-c5ccccc5)ccc4B4c5ccc(N6C7CC8CC(C7)CC6C8)cc5N(c5c(-c6ccccc6)cc(-c6ccccc6)cc5-c5ccccc5)c5cc(-c6ccccc6)cc3c54)c(-c3ccccc3)c2)cc1 ; CC(C)(C)c1ccc(-c2cc3c4c(c2)N(c2c(-c5ccccc5)cc(-c5ccccc5)cc2-c2ccccc2)c2cc(N5C6CC7CC(C6)CC5C7)ccc2B4c2cc(-c4ccccc4)ccc2N3c2c(-c3ccccc3)cc(-c3ccccc3)cc2-c2ccccc2)cc1] 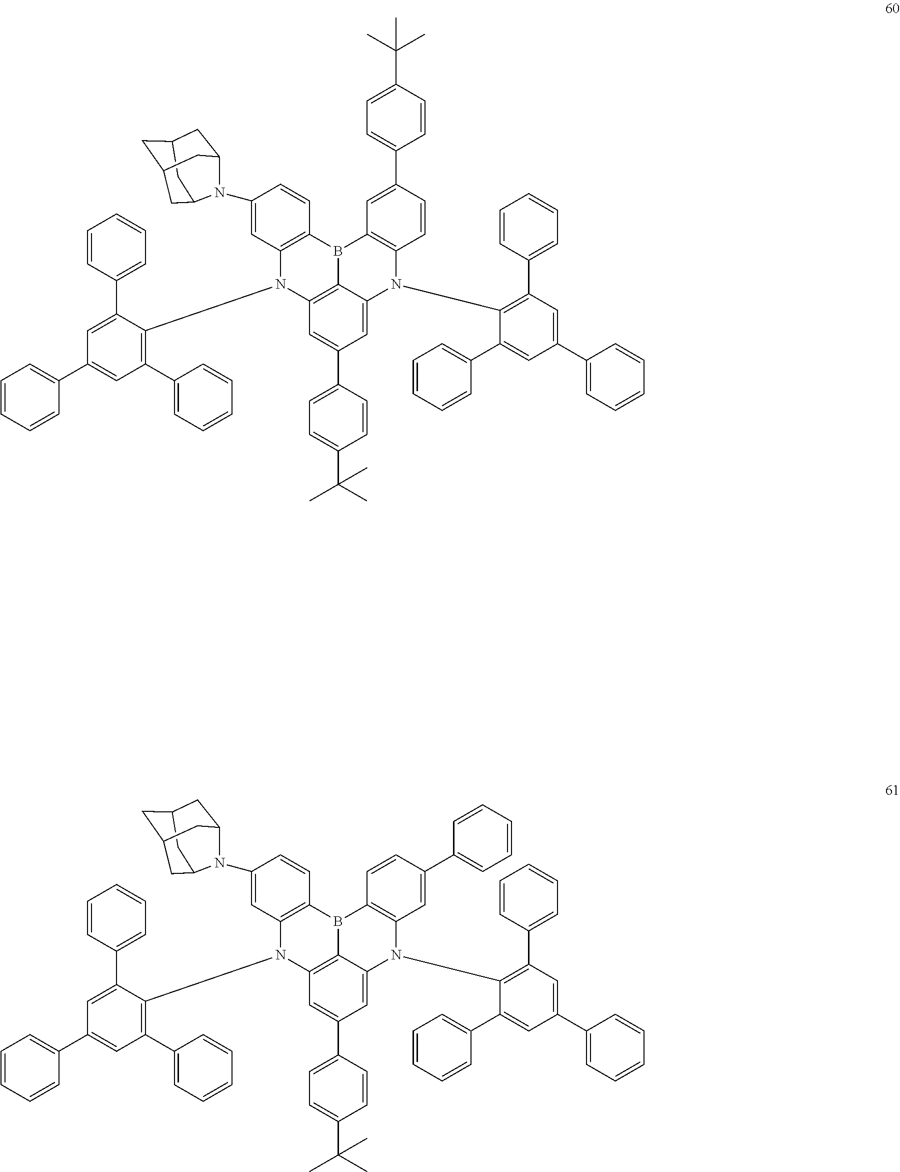 [SMILES: CC(C)(C)c1ccc(-c2ccc3c(c2)B2c4ccc(N5C6CC7CC(C6)CC5C7)cc4N(c4c(-c5ccccc5)cc(-c5ccccc5)cc4-c4ccccc4)c4cc(-c5ccc(C(C)(C)C)cc5)cc(c42)N3c2c(-c3ccccc3)cc(-c3ccccc3)cc2-c2ccccc2)cc1 ; CC(C)(C)c1ccc(-c2cc3c4c(c2)N(c2c(-c5ccccc5)cc(-c5ccccc5)cc2-c2ccccc2)c2cc(N5C6CC7CC(C6)CC5C7)ccc2B4c2ccc(-c4ccccc4)cc2N3c2c(-c3ccccc3)cc(-c3ccccc3)cc2-c2ccccc2)cc1] 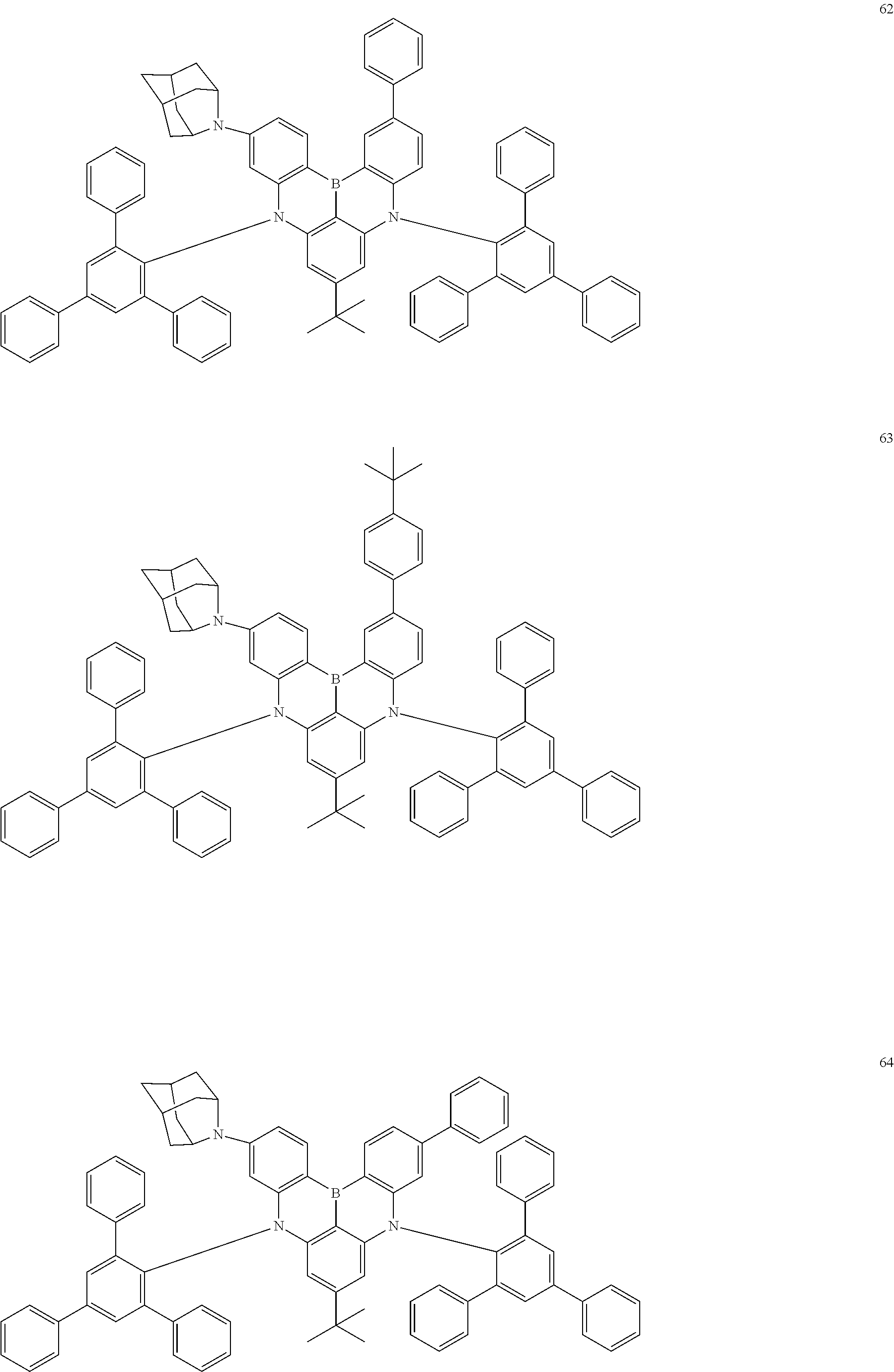 [SMILES: CC(C)(C)c1cc2c3c(c1)N(c1c(-c4ccccc4)cc(-c4ccccc4)cc1-c1ccccc1)c1cc(N4C5CC6CC(C5)CC4C6)ccc1B3c1cc(-c3ccccc3)ccc1N2c1c(-c2ccccc2)cc(-c2ccccc2)cc1-c1ccccc1 ; CC(C)(C)c1ccc(-c2ccc3c(c2)B2c4ccc(N5C6CC7CC(C6)CC5C7)cc4N(c4c(-c5ccccc5)cc(-c5ccccc5)cc4-c4ccccc4)c4cc(C(C)(C)C)cc(c42)N3c2c(-c3ccccc3)cc(-c3ccccc3)cc2-c2ccccc2)cc1 ; CC(C)(C)c1cc2c3c(c1)N(c1c(-c4ccccc4)cc(-c4ccccc4)cc1-c1ccccc1)c1cc(N4C5CC6CC(C5)CC4C6)ccc1B3c1ccc(-c3ccccc3)cc1N2c1c(-c2ccccc2)cc(-c2ccccc2)cc1-c1ccccc1] 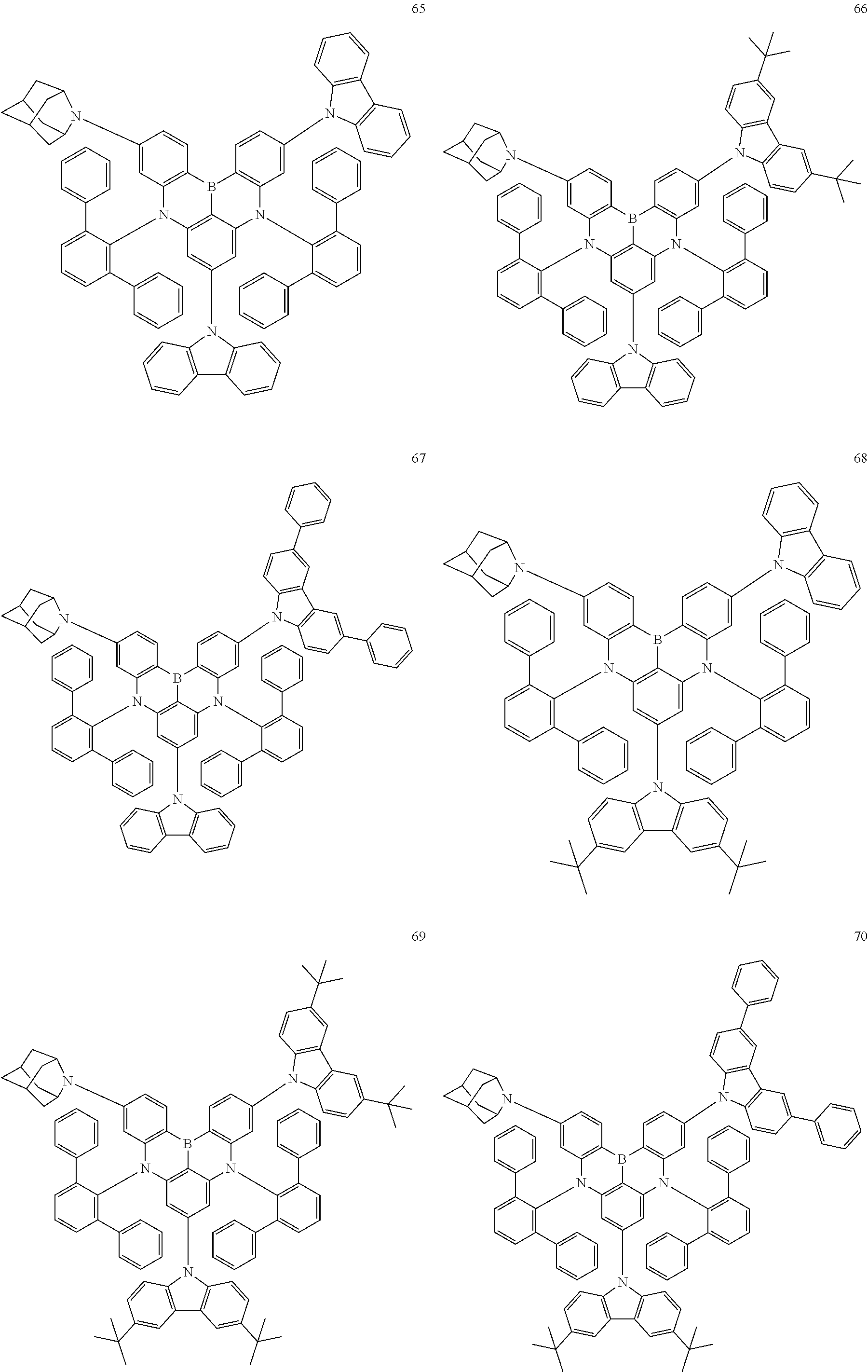 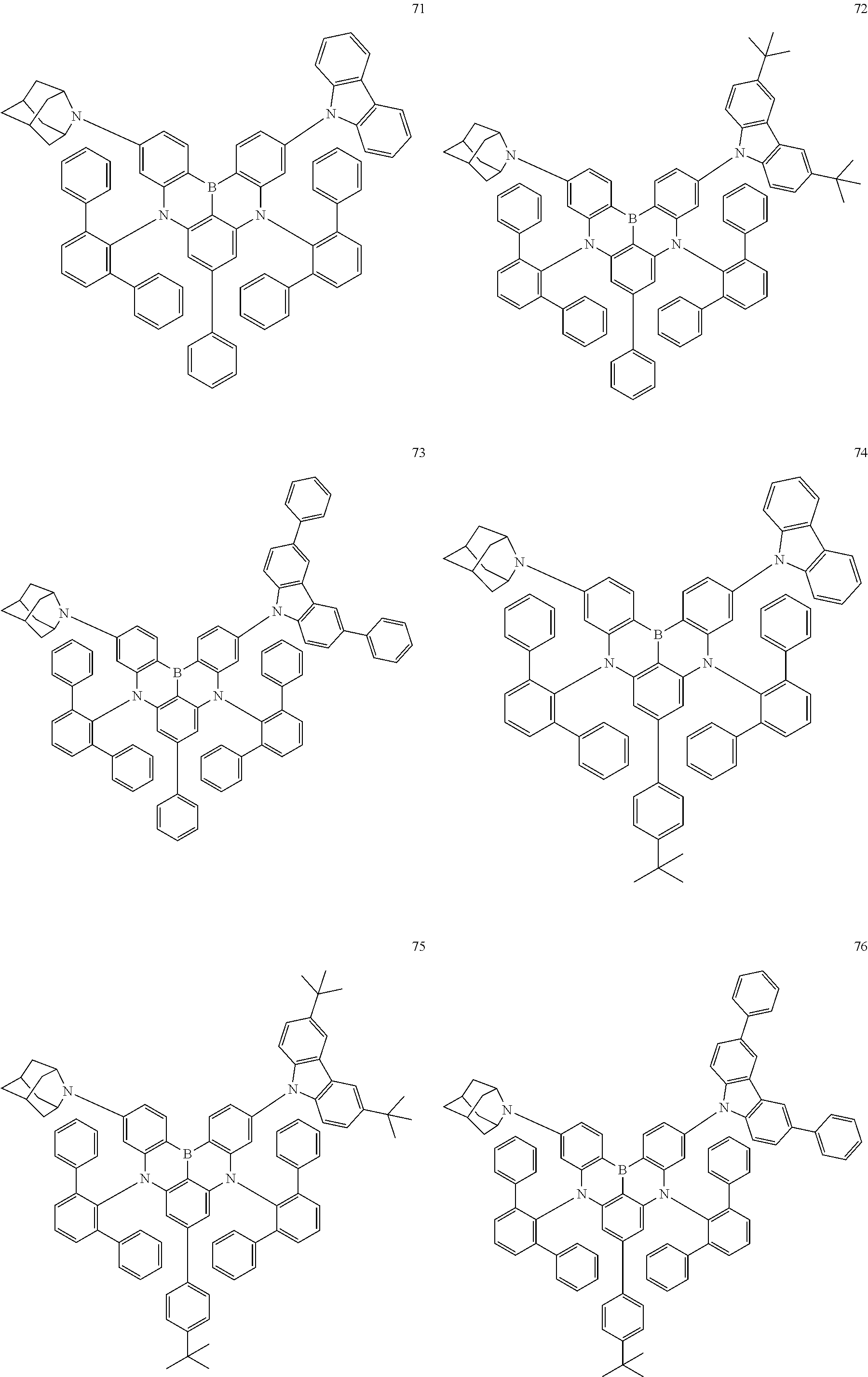 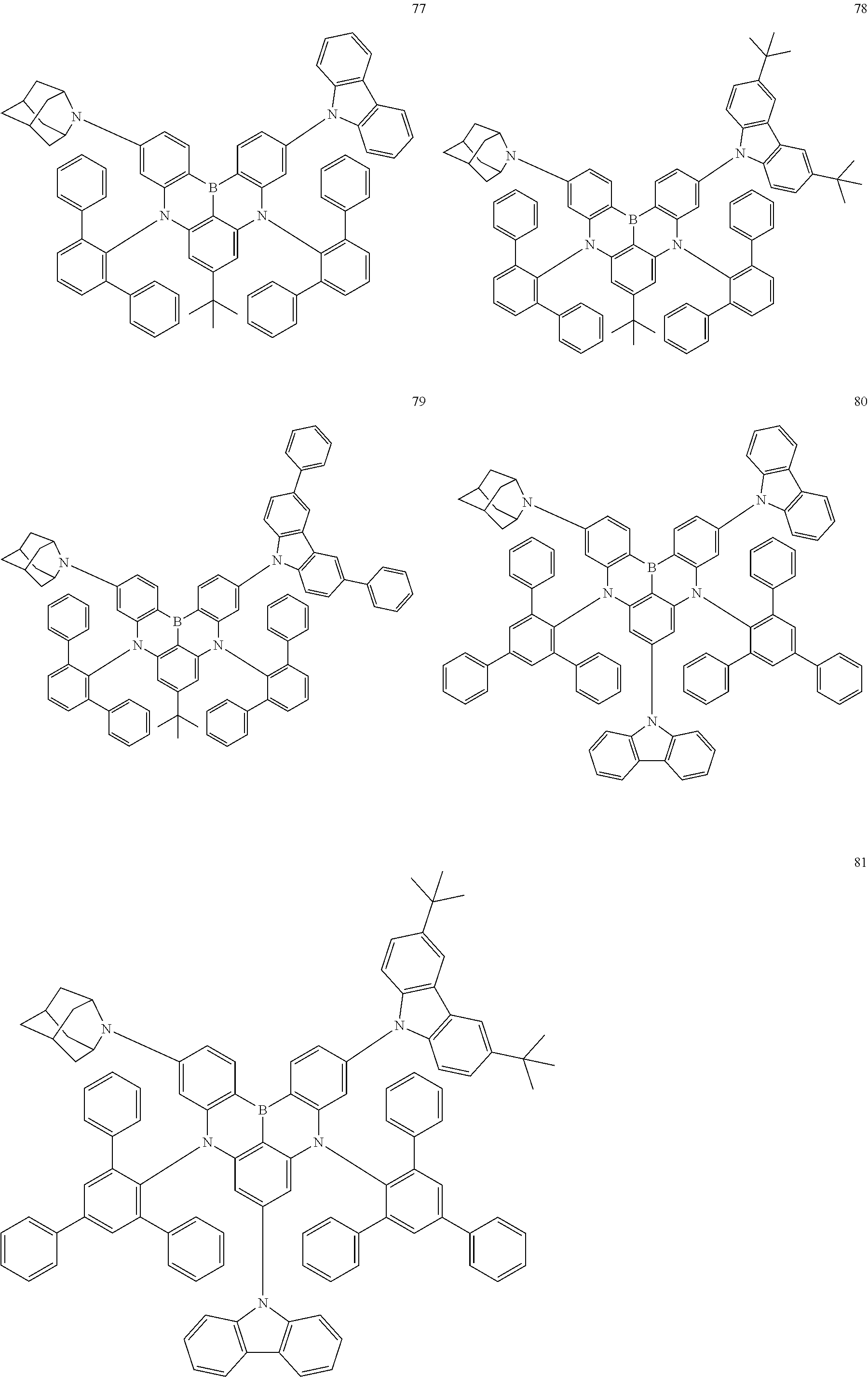 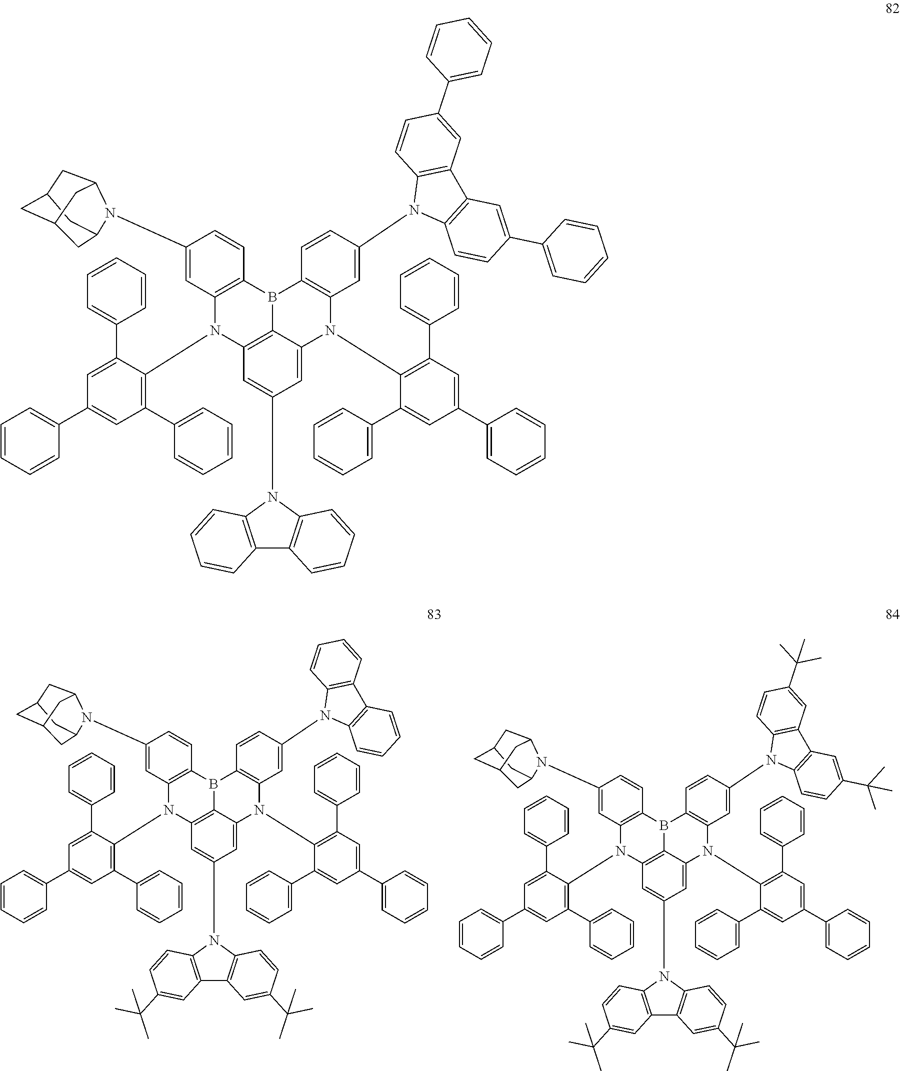 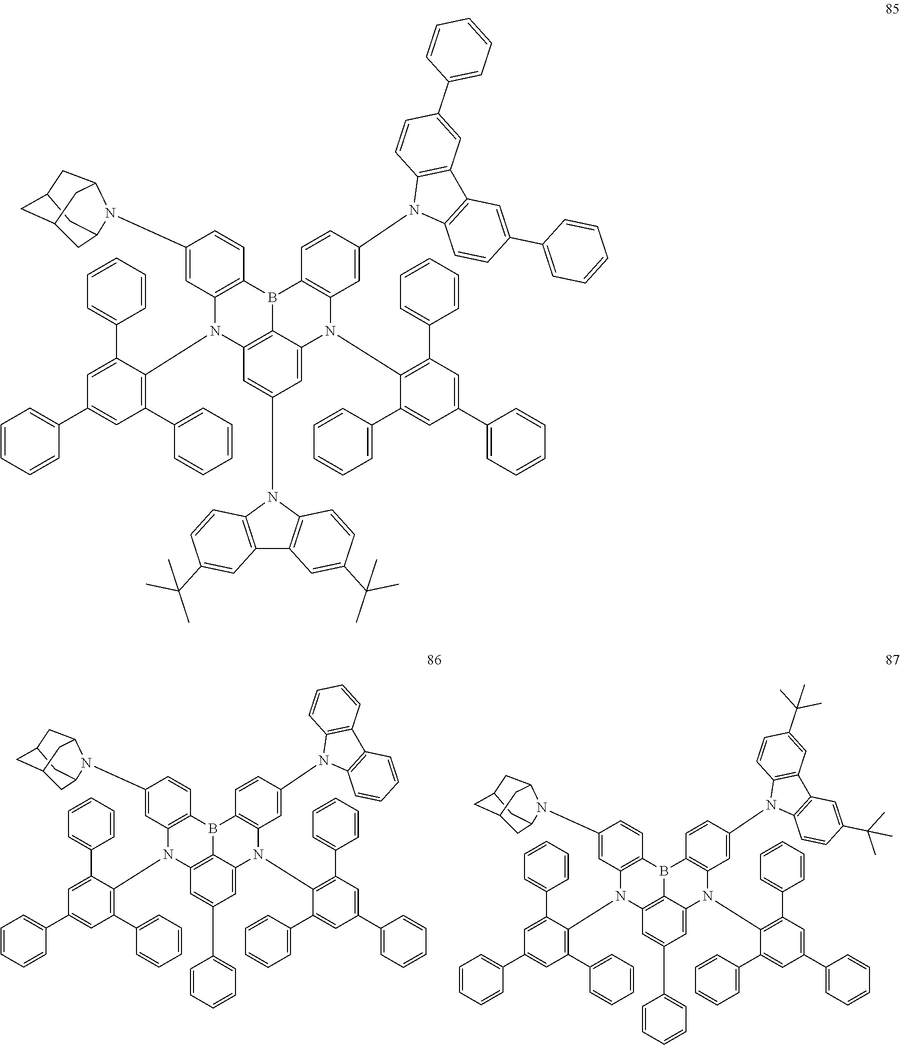 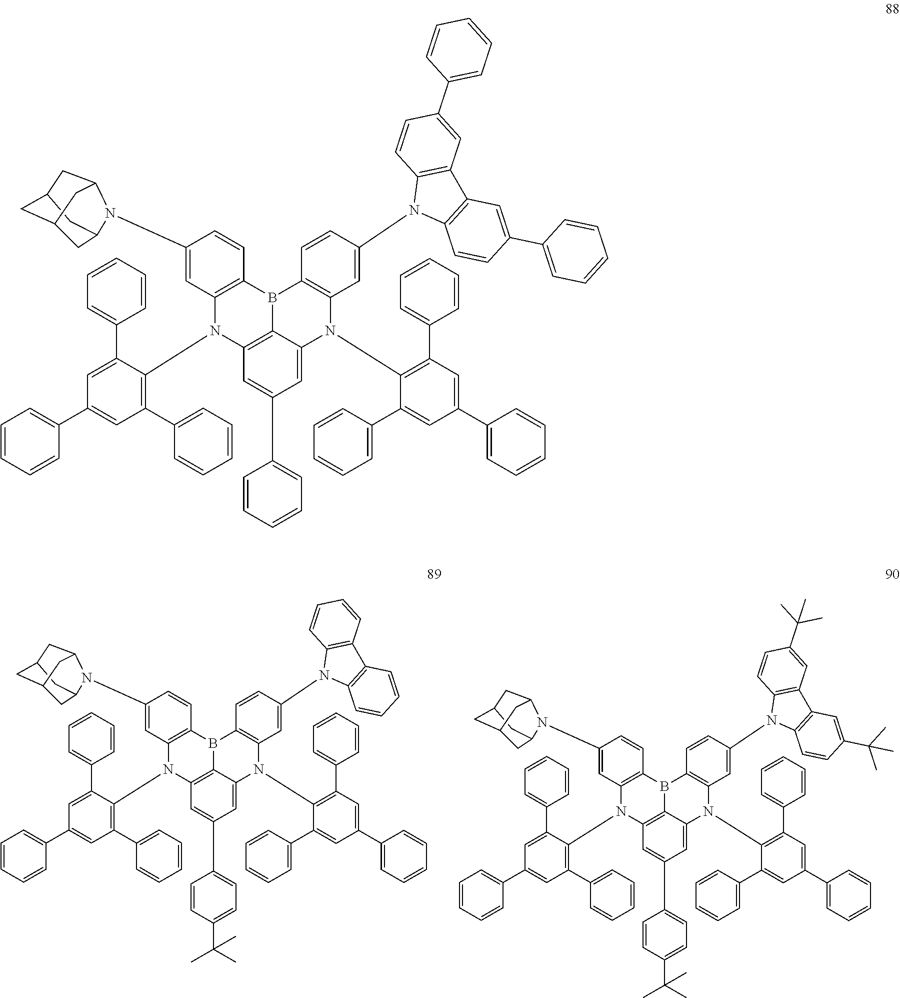 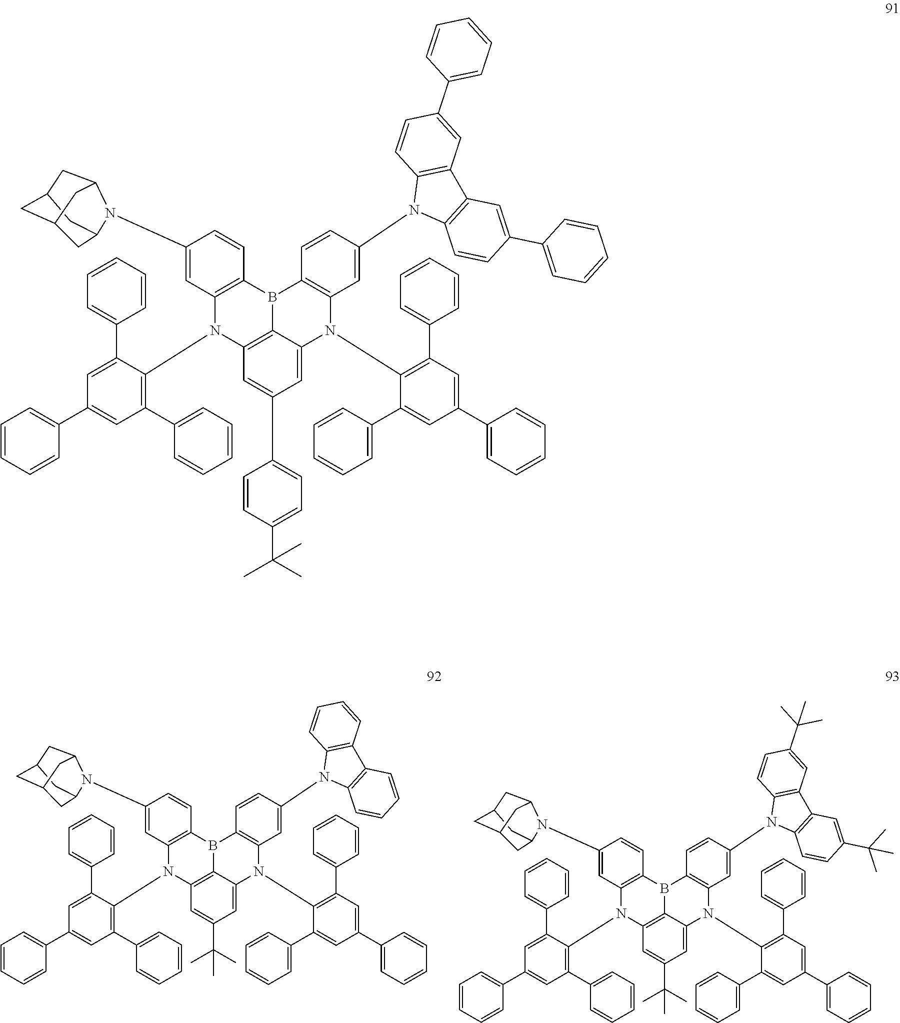 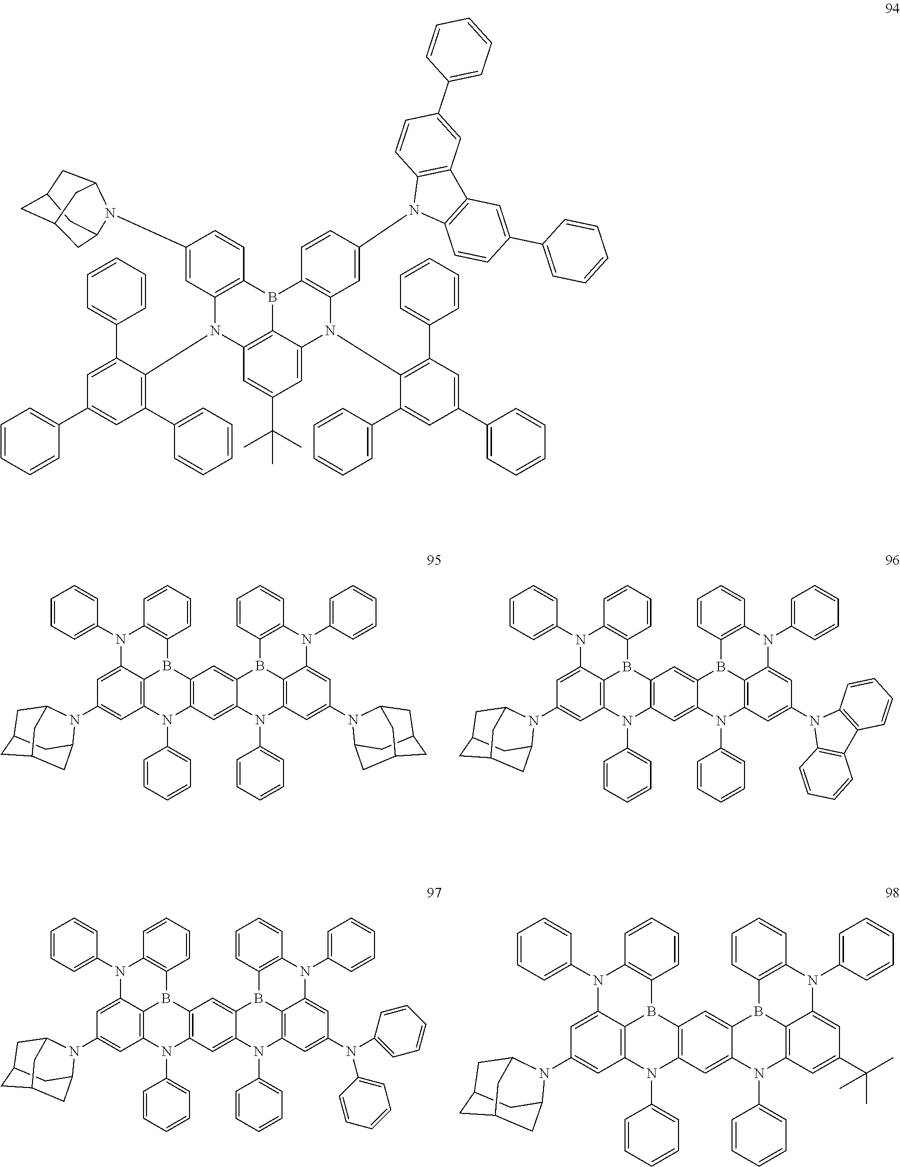 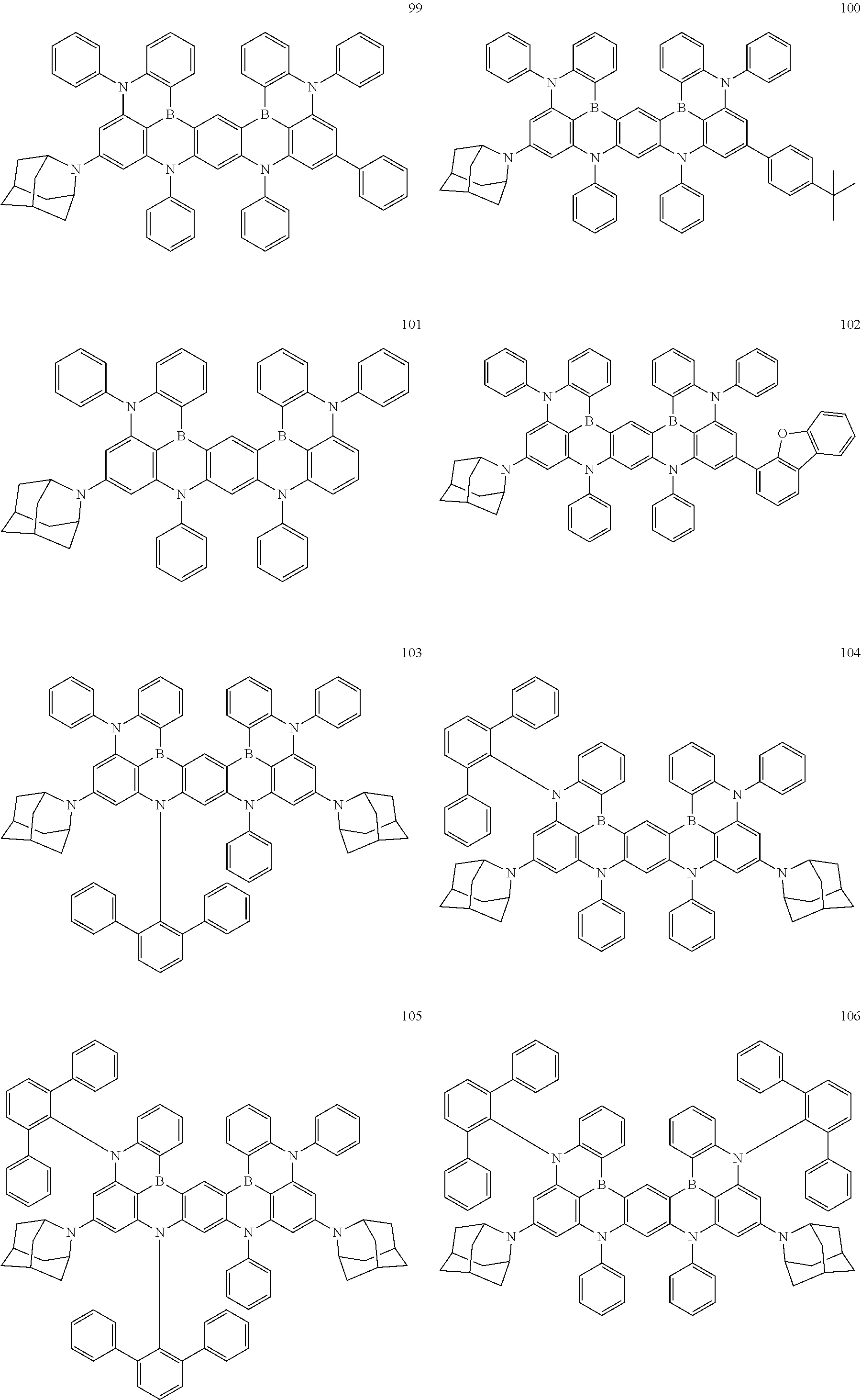 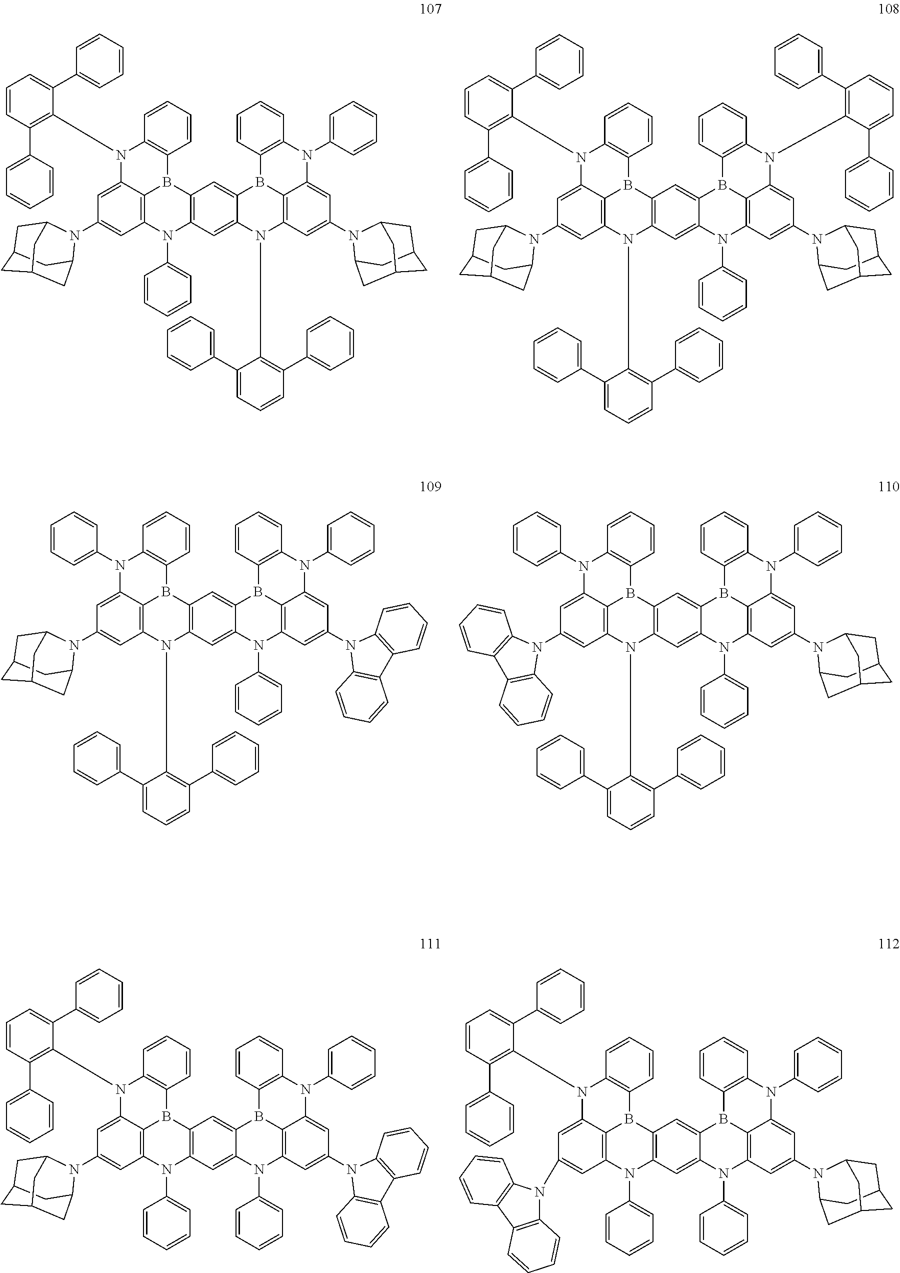 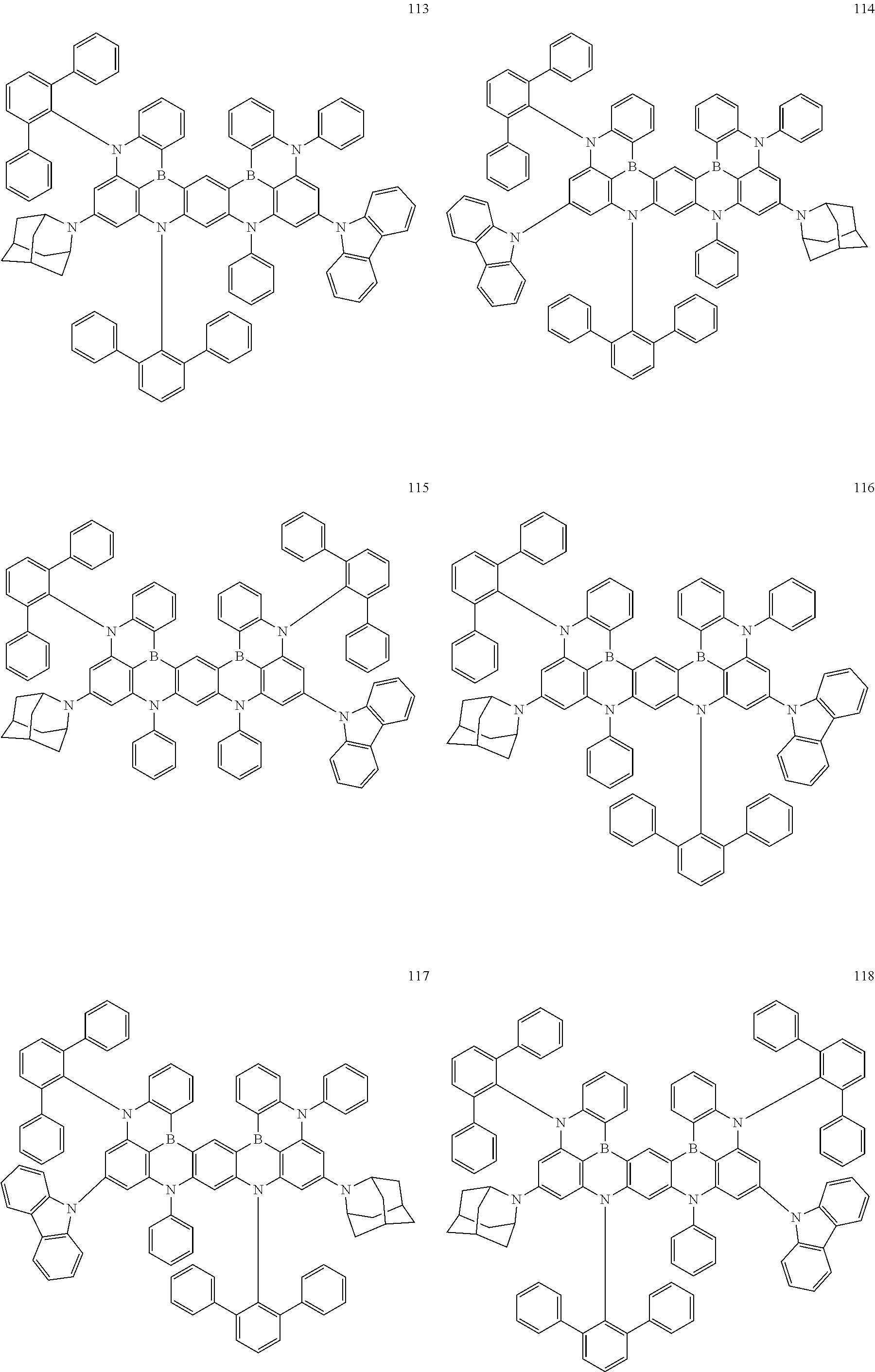 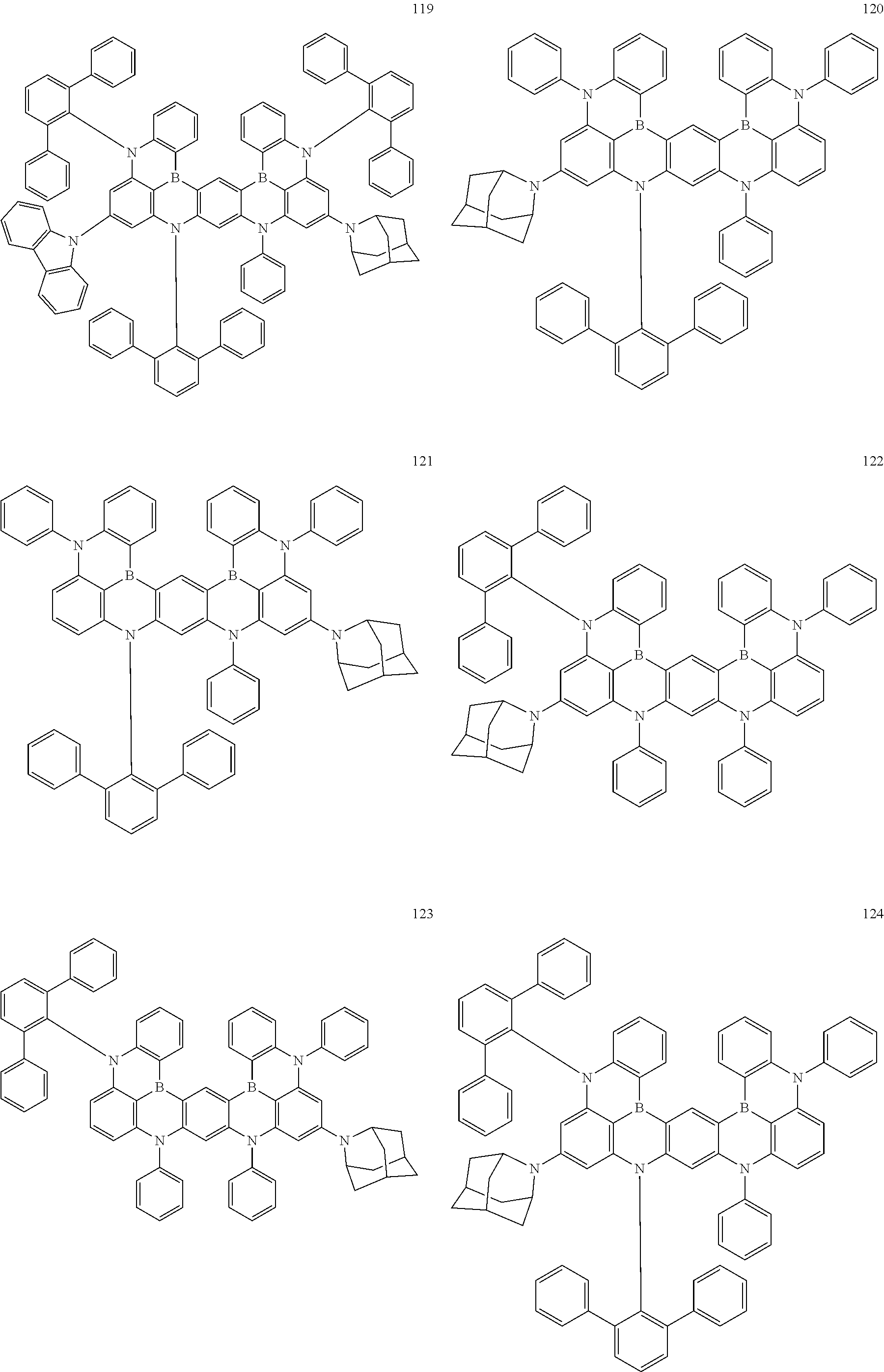 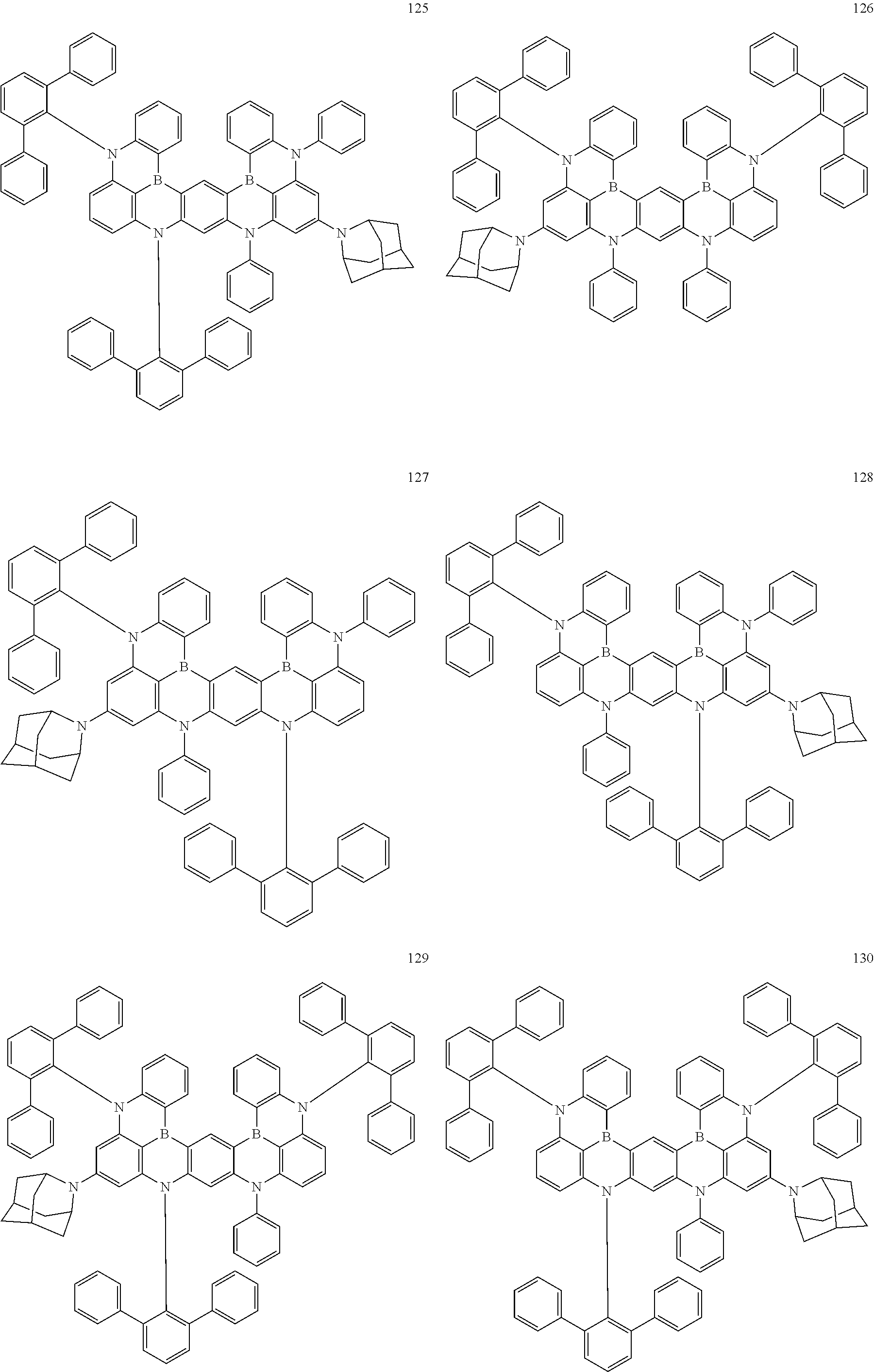 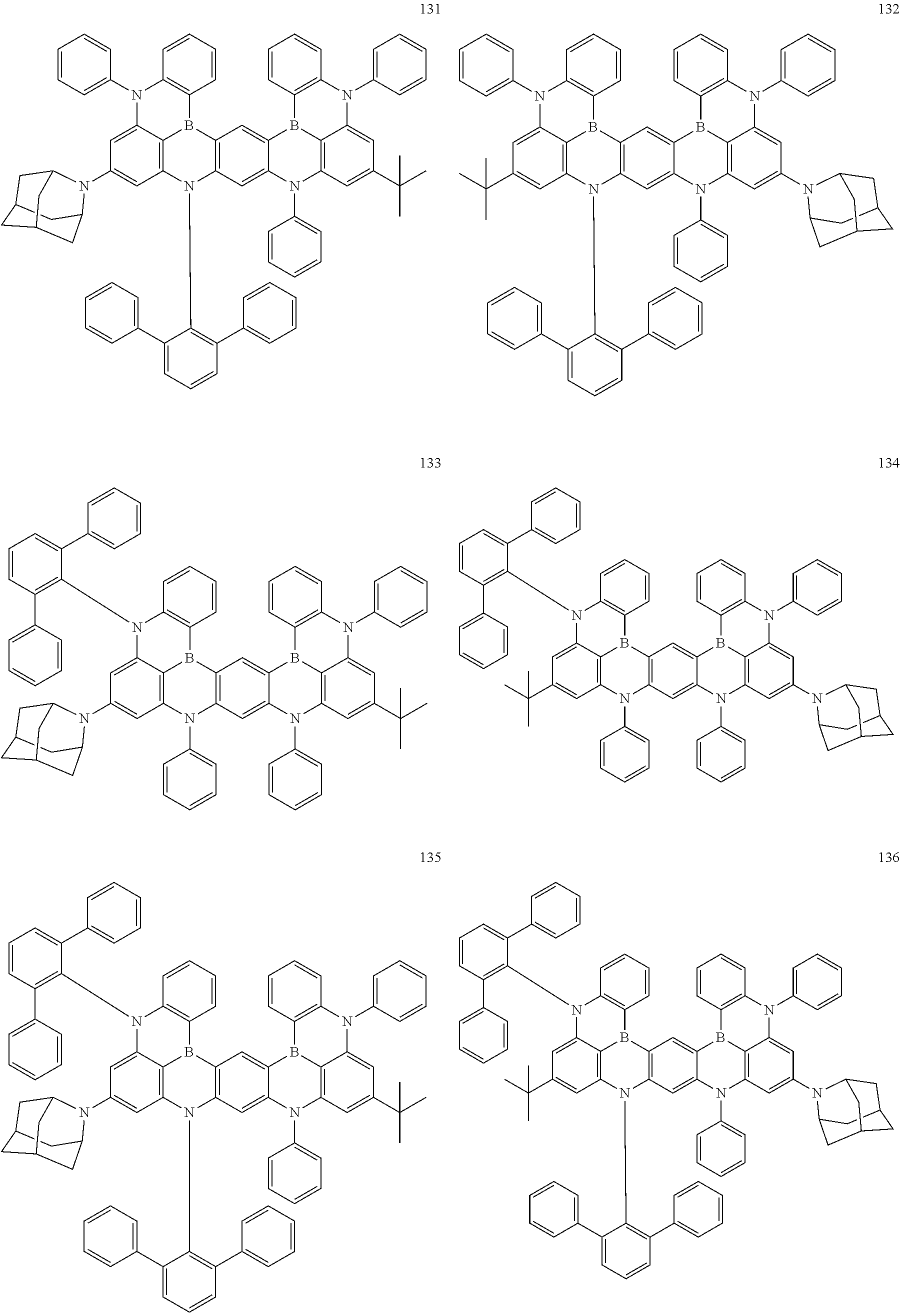 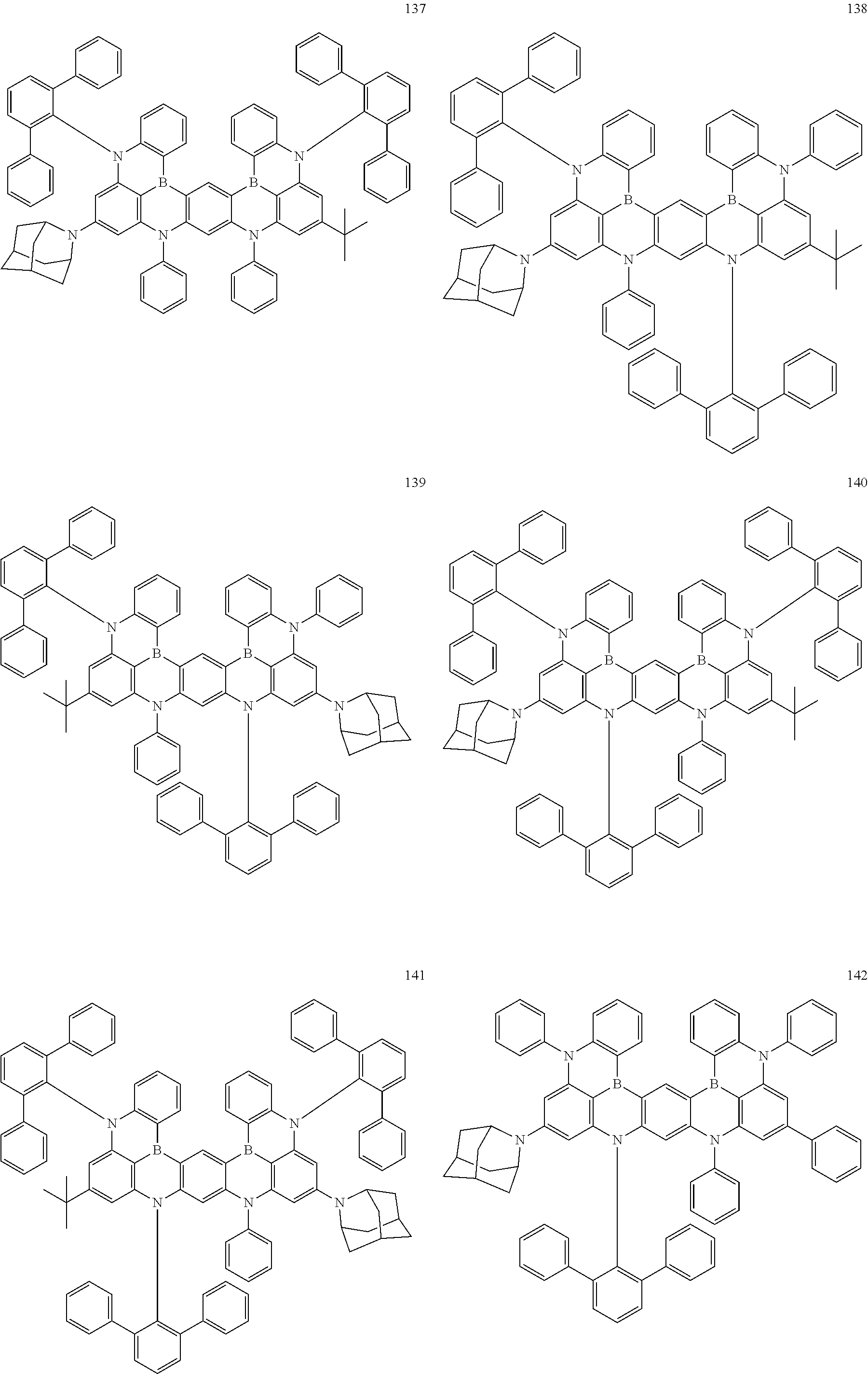 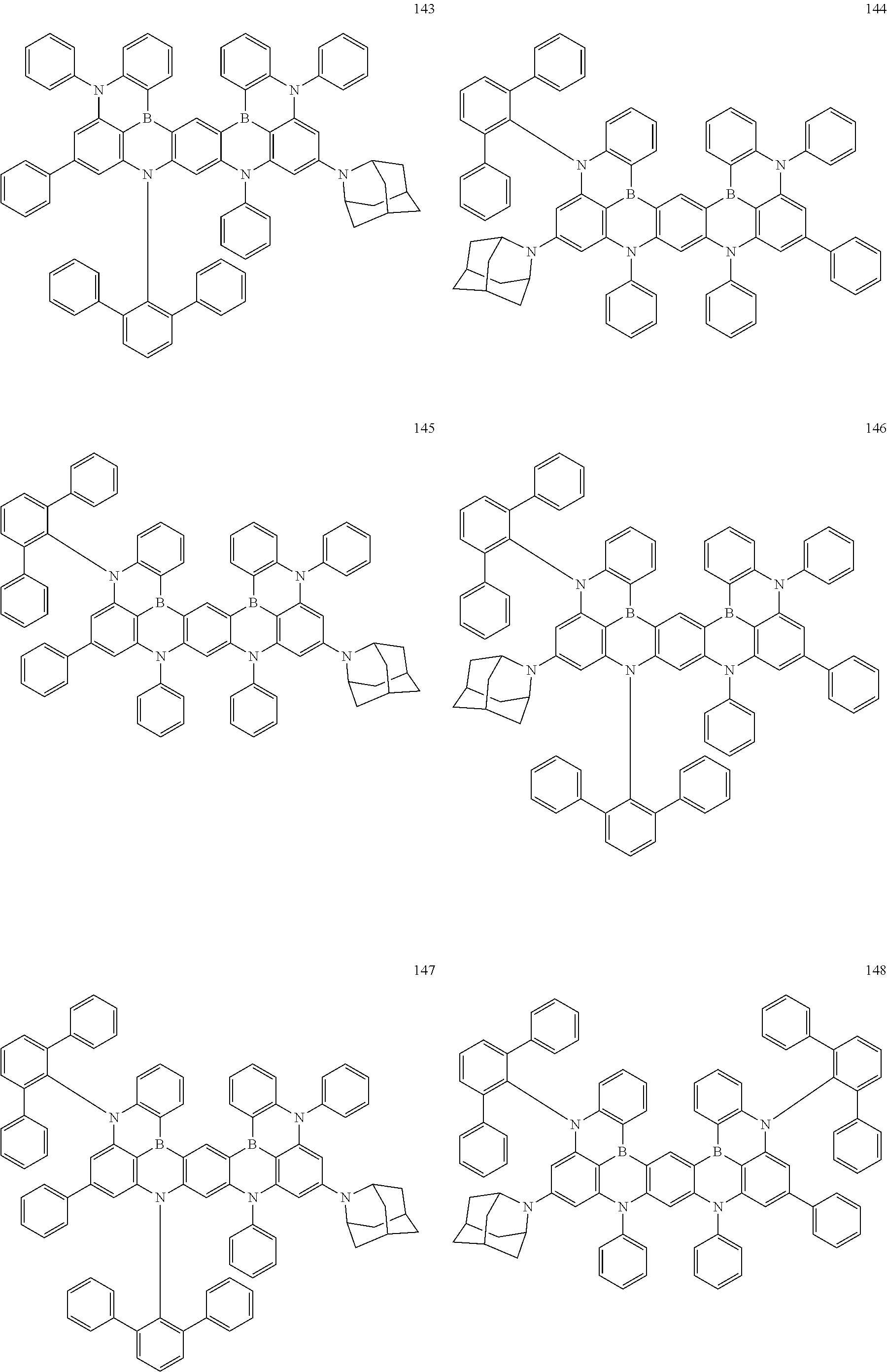 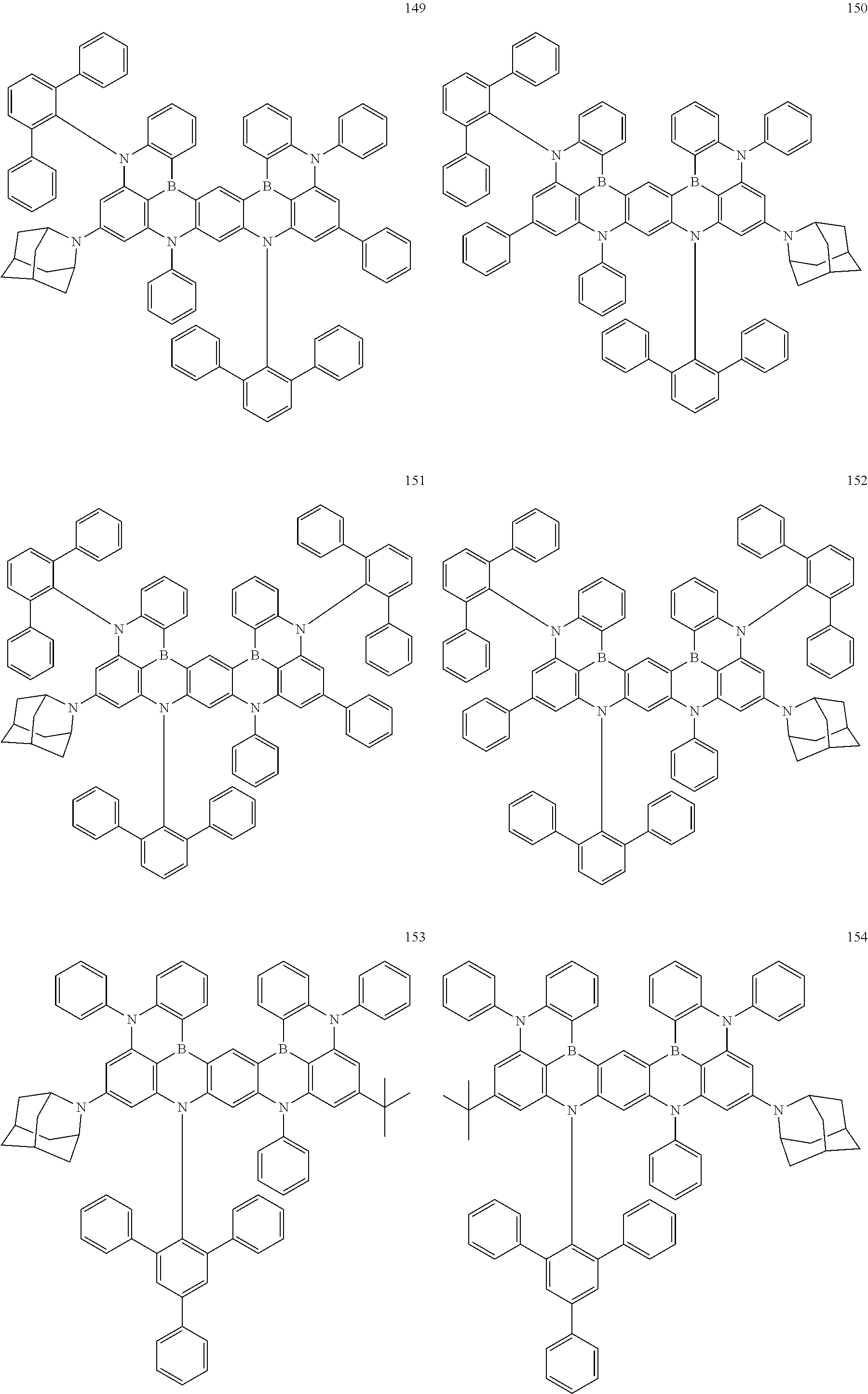 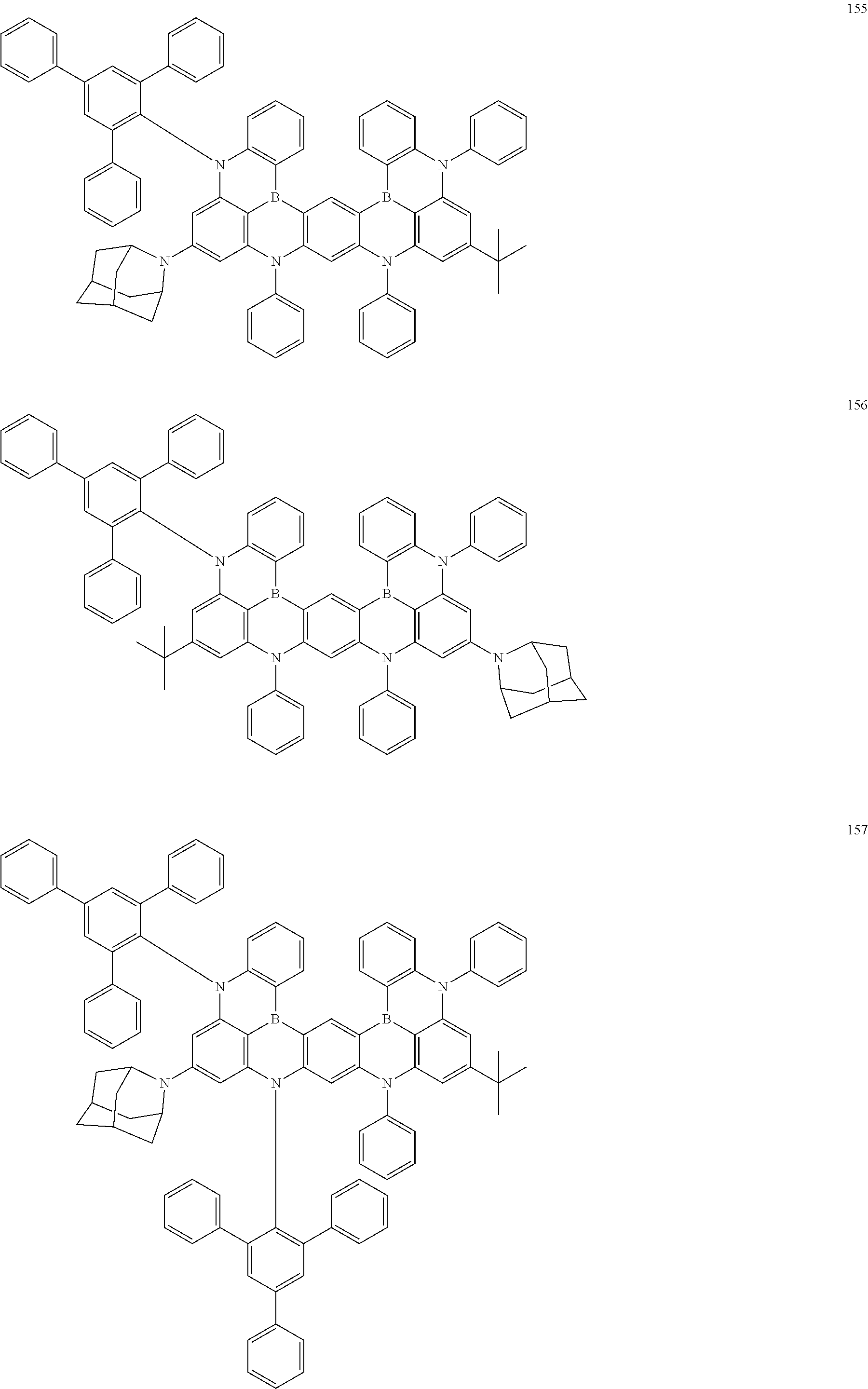 [SMILES: CC(C)(C)c1cc2c3c(c1)N(c1ccccc1)c1cc4c(cc1B3c1ccccc1N2c1ccccc1)B1c2ccccc2N(c2c(-c3ccccc3)cc(-c3ccccc3)cc2-c2ccccc2)c2cc(N3C5CC6CC(C5)CC3C6)cc(c21)N4c1ccccc1 ; CC(C)(C)c1cc2c3c(c1)N(c1c(-c4ccccc4)cc(-c4ccccc4)cc1-c1ccccc1)c1ccccc1B3c1cc3c(cc1N2c1ccccc1)N(c1ccccc1)c1cc(N2C4CC5CC(C4)CC2C5)cc2c1B3c1ccccc1N2c1ccccc1 ; CC(C)(C)c1cc2c3c(c1)N(c1ccccc1)c1cc4c(cc1B3c1ccccc1N2c1ccccc1)B1c2ccccc2N(c2c(-c3ccccc3)cc(-c3ccccc3)cc2-c2ccccc2)c2cc(N3C5CC6CC(C5)CC3C6)cc(c21)N4c1c(-c2ccccc2)cc(-c2ccccc2)cc1-c1ccccc1] 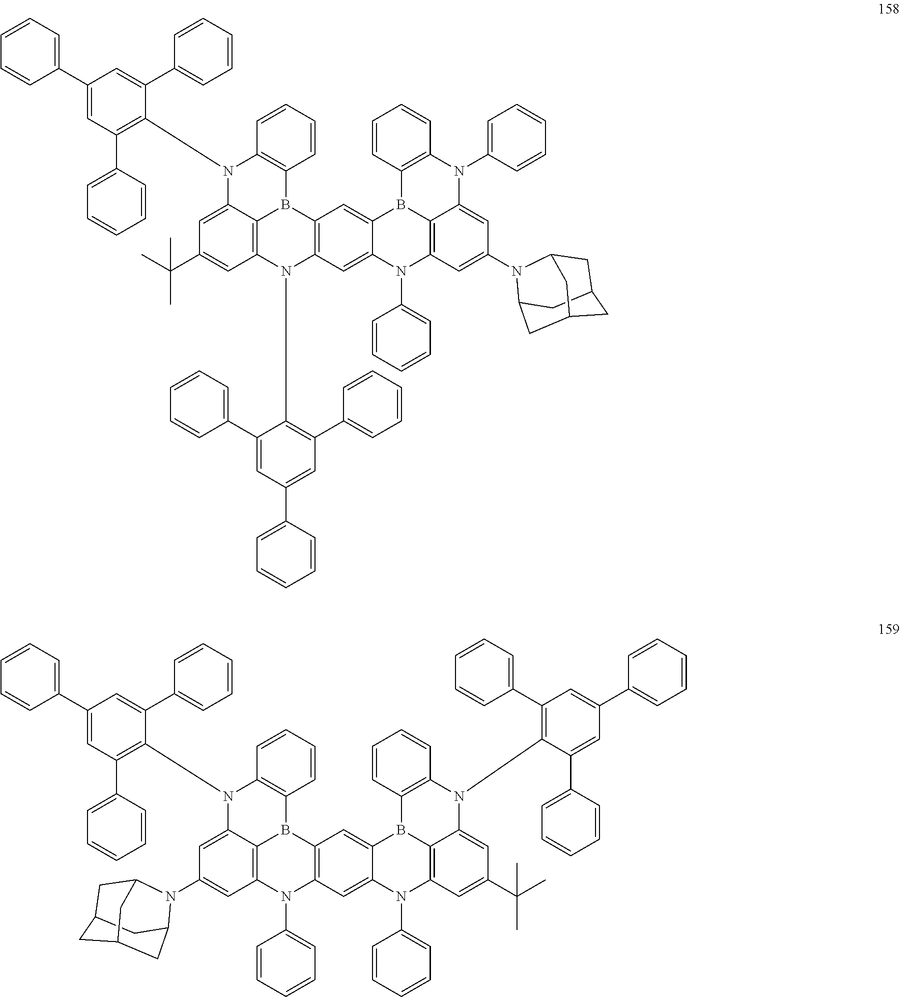 [SMILES: CC(C)(C)c1cc2c3c(c1)N(c1c(-c4ccccc4)cc(-c4ccccc4)cc1-c1ccccc1)c1cc4c(cc1B3c1ccccc1N2c1c(-c2ccccc2)cc(-c2ccccc2)cc1-c1ccccc1)B1c2ccccc2N(c2ccccc2)c2cc(N3C5CC6CC(C5)CC3C6)cc(c21)N4c1ccccc1 ; CC(C)(C)c1cc2c3c(c1)N(c1c(-c4ccccc4)cc(-c4ccccc4)cc1-c1ccccc1)c1ccccc1B3c1cc3c(cc1N2c1ccccc1)N(c1ccccc1)c1cc(N2C4CC5CC(C4)CC2C5)cc2c1B3c1ccccc1N2c1c(-c2ccccc2)cc(-c2ccccc2)cc1-c1ccccc1] 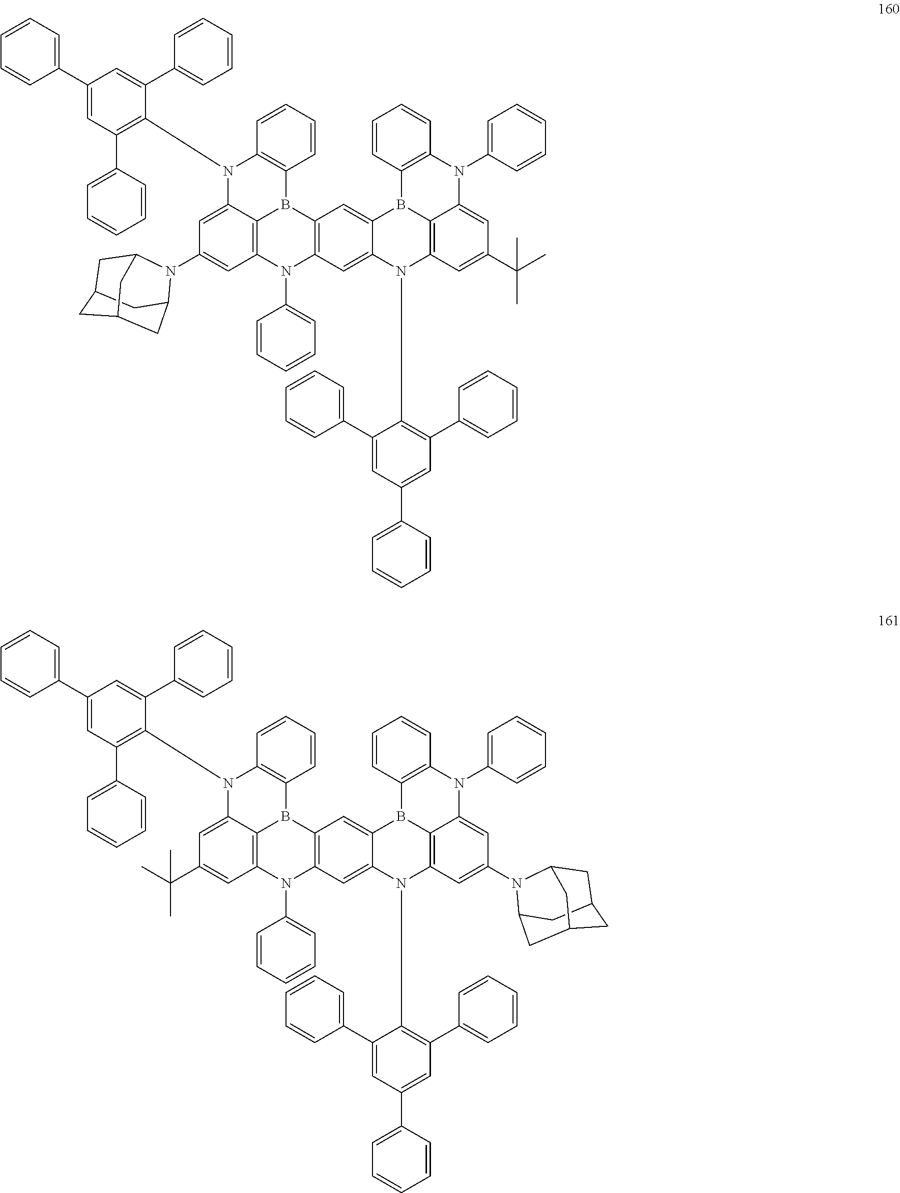 [SMILES: CC(C)(C)c1cc2c3c(c1)N(c1c(-c4ccccc4)cc(-c4ccccc4)cc1-c1ccccc1)c1cc4c(cc1B3c1ccccc1N2c1ccccc1)B1c2ccccc2N(c2c(-c3ccccc3)cc(-c3ccccc3)cc2-c2ccccc2)c2cc(N3C5CC6CC(C5)CC3C6)cc(c21)N4c1ccccc1 ; CC(C)(C)c1cc2c3c(c1)N(c1c(-c4ccccc4)cc(-c4ccccc4)cc1-c1ccccc1)c1ccccc1B3c1cc3c(cc1N2c1ccccc1)N(c1c(-c2ccccc2)cc(-c2ccccc2)cc1-c1ccccc1)c1cc(N2C4CC5CC(C4)CC2C5)cc2c1B3c1ccccc1N2c1ccccc1] 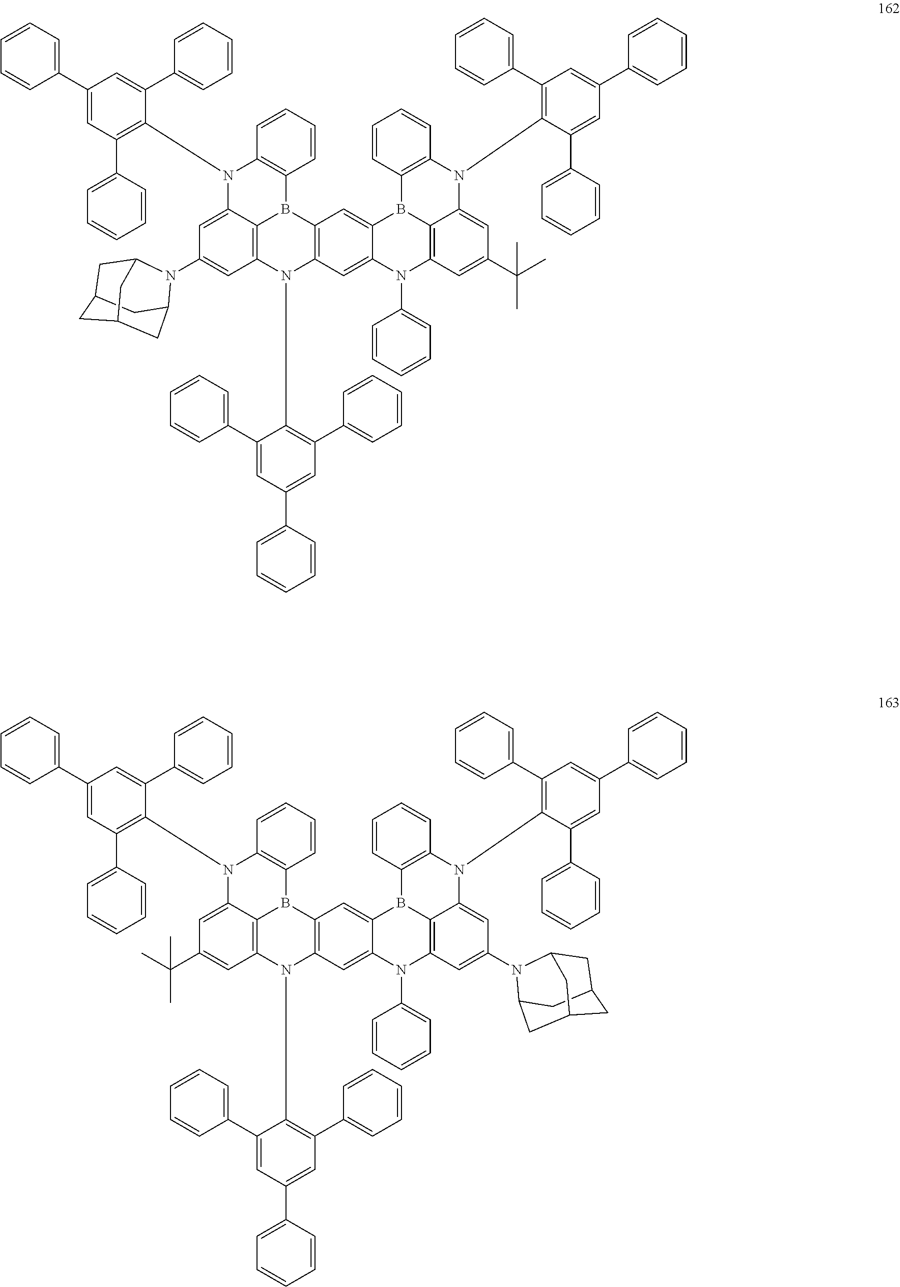 [SMILES: CC(C)(C)c1cc2c3c(c1)N(c1c(-c4ccccc4)cc(-c4ccccc4)cc1-c1ccccc1)c1ccccc1B3c1cc3c(cc1N2c1ccccc1)N(c1c(-c2ccccc2)cc(-c2ccccc2)cc1-c1ccccc1)c1cc(N2C4CC5CC(C4)CC2C5)cc2c1B3c1ccccc1N2c1c(-c2ccccc2)cc(-c2ccccc2)cc1-c1ccccc1 ; CC(C)(C)c1cc2c3c(c1)N(c1c(-c4ccccc4)cc(-c4ccccc4)cc1-c1ccccc1)c1cc4c(cc1B3c1ccccc1N2c1c(-c2ccccc2)cc(-c2ccccc2)cc1-c1ccccc1)B1c2ccccc2N(c2c(-c3ccccc3)cc(-c3ccccc3)cc2-c2ccccc2)c2cc(N3C5CC6CC(C5)CC3C6)cc(c21)N4c1ccccc1] 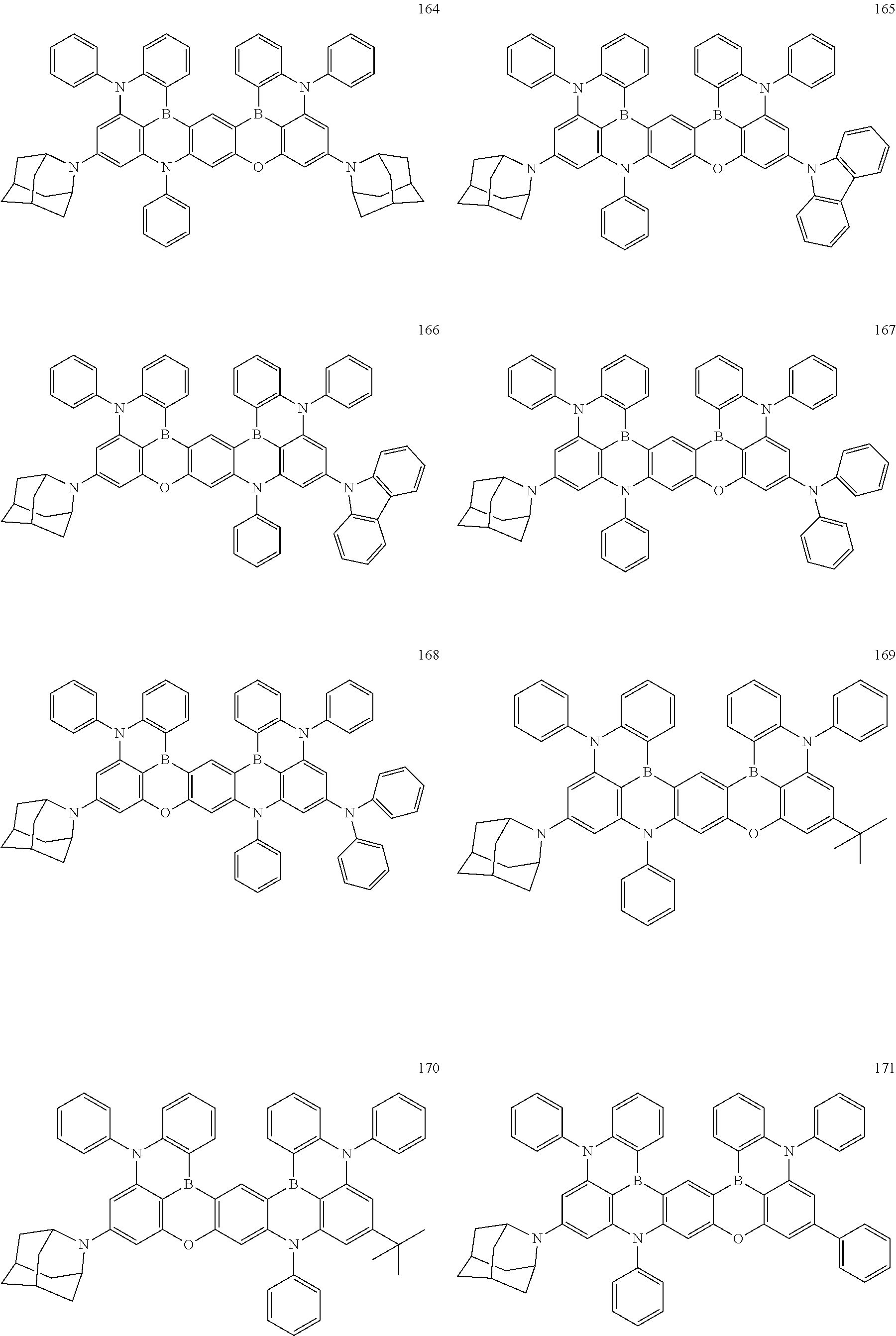 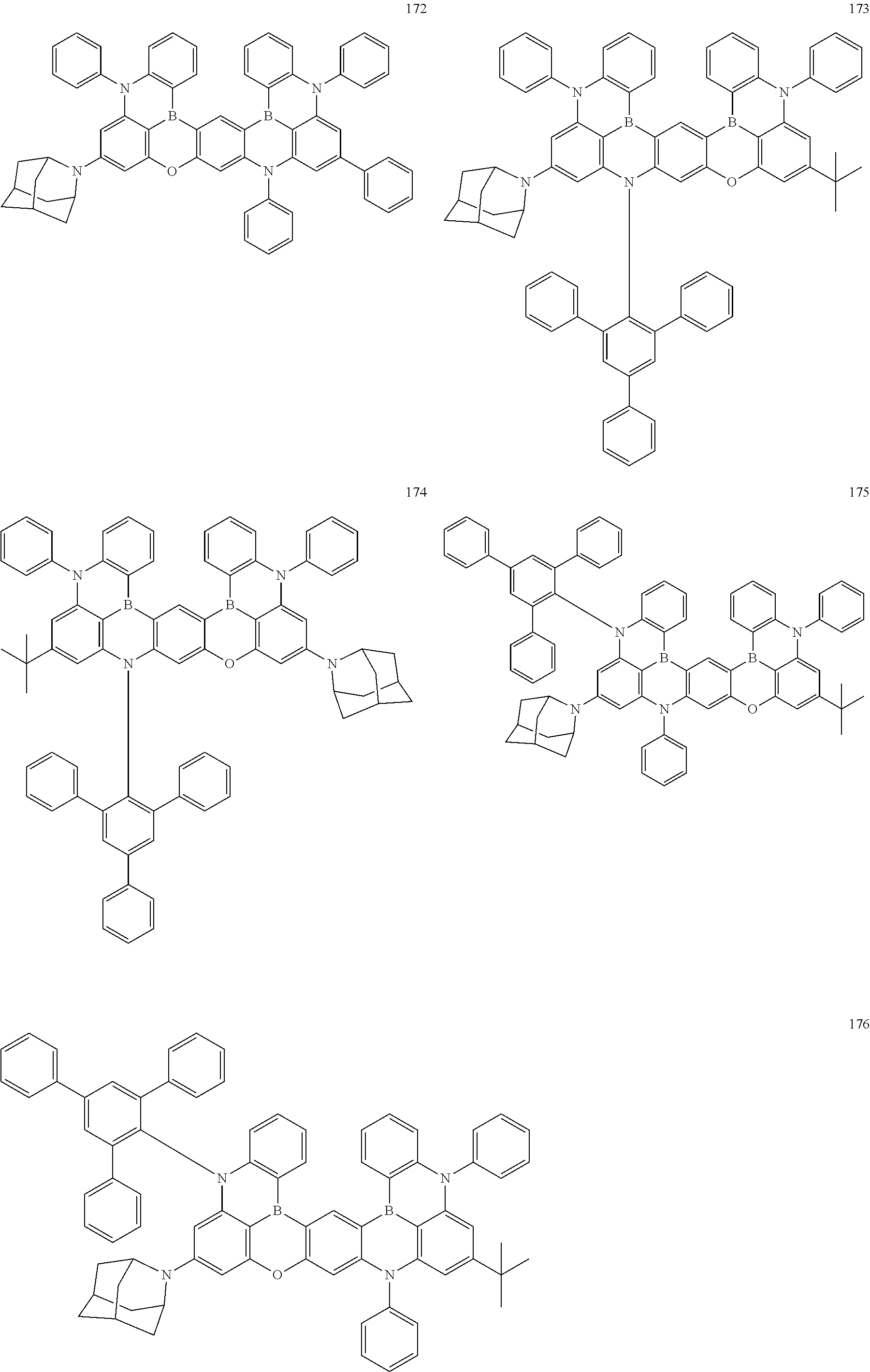 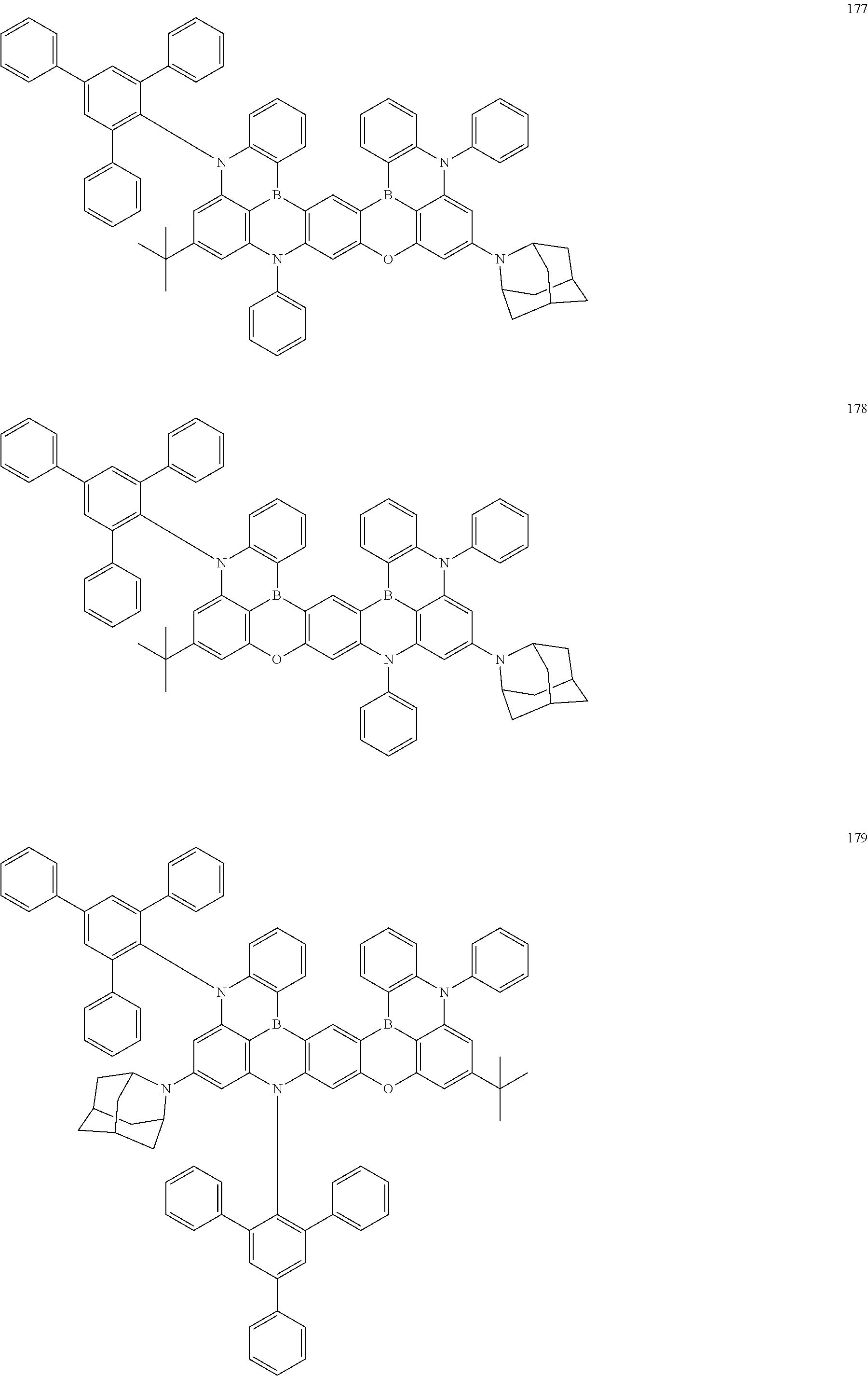 [SMILES: CC(C)(C)c1cc2c3c(c1)N(c1c(-c4ccccc4)cc(-c4ccccc4)cc1-c1ccccc1)c1ccccc1B3c1cc3c(cc1N2c1ccccc1)Oc1cc(N2C4CC5CC(C4)CC2C5)cc2c1B3c1ccccc1N2c1ccccc1 ; CC(C)(C)c1cc2c3c(c1)N(c1c(-c4ccccc4)cc(-c4ccccc4)cc1-c1ccccc1)c1ccccc1B3c1cc3c(cc1O2)N(c1ccccc1)c1cc(N2C4CC5CC(C4)CC2C5)cc2c1B3c1ccccc1N2c1ccccc1 ; CC(C)(C)c1cc2c3c(c1)N(c1ccccc1)c1ccccc1B3c1cc3c(cc1O2)N(c1c(-c2ccccc2)cc(-c2ccccc2)cc1-c1ccccc1)c1cc(N2C4CC5CC(C4)CC2C5)cc2c1B3c1ccccc1N2c1c(-c2ccccc2)cc(-c2ccccc2)cc1-c1ccccc1] 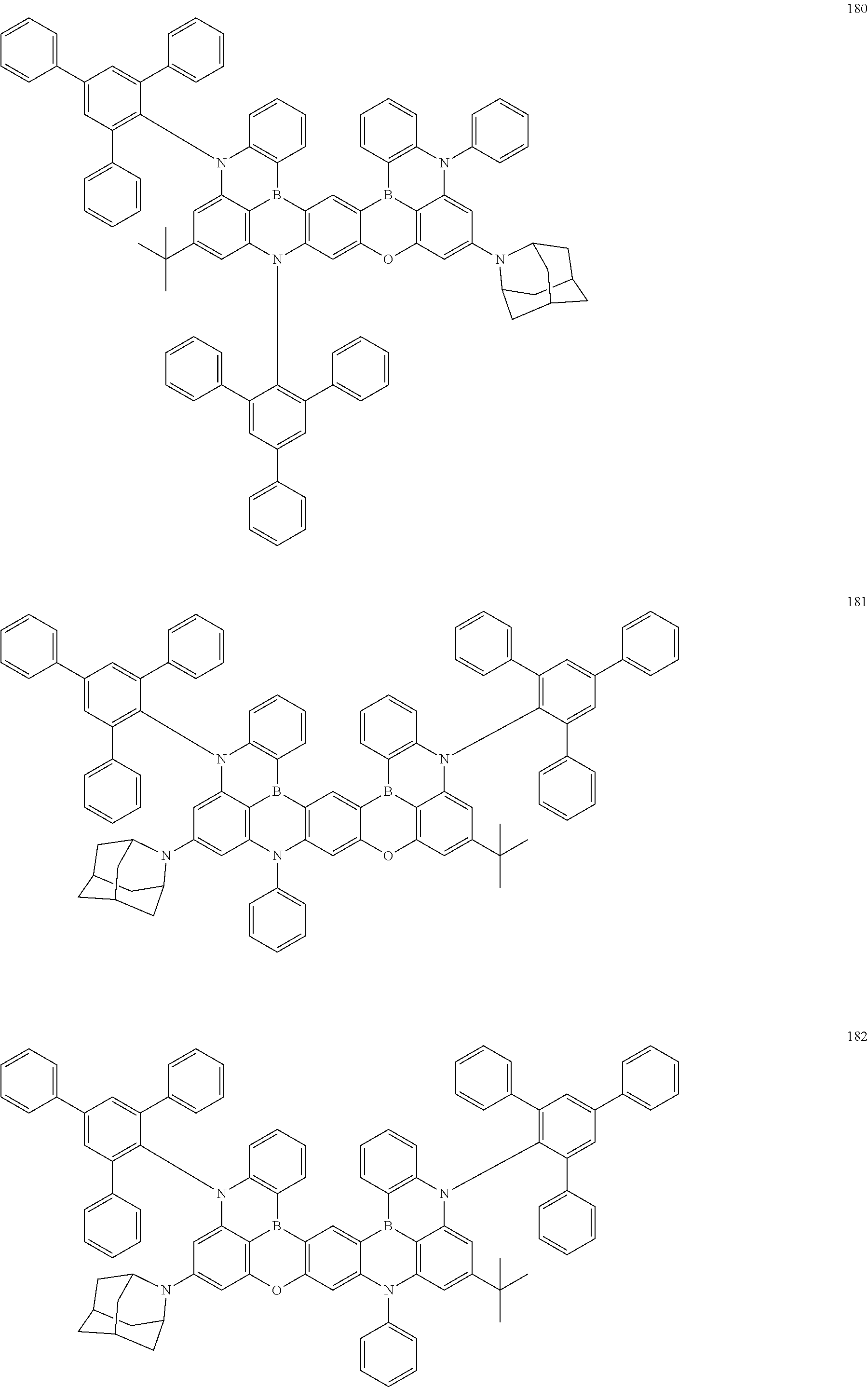 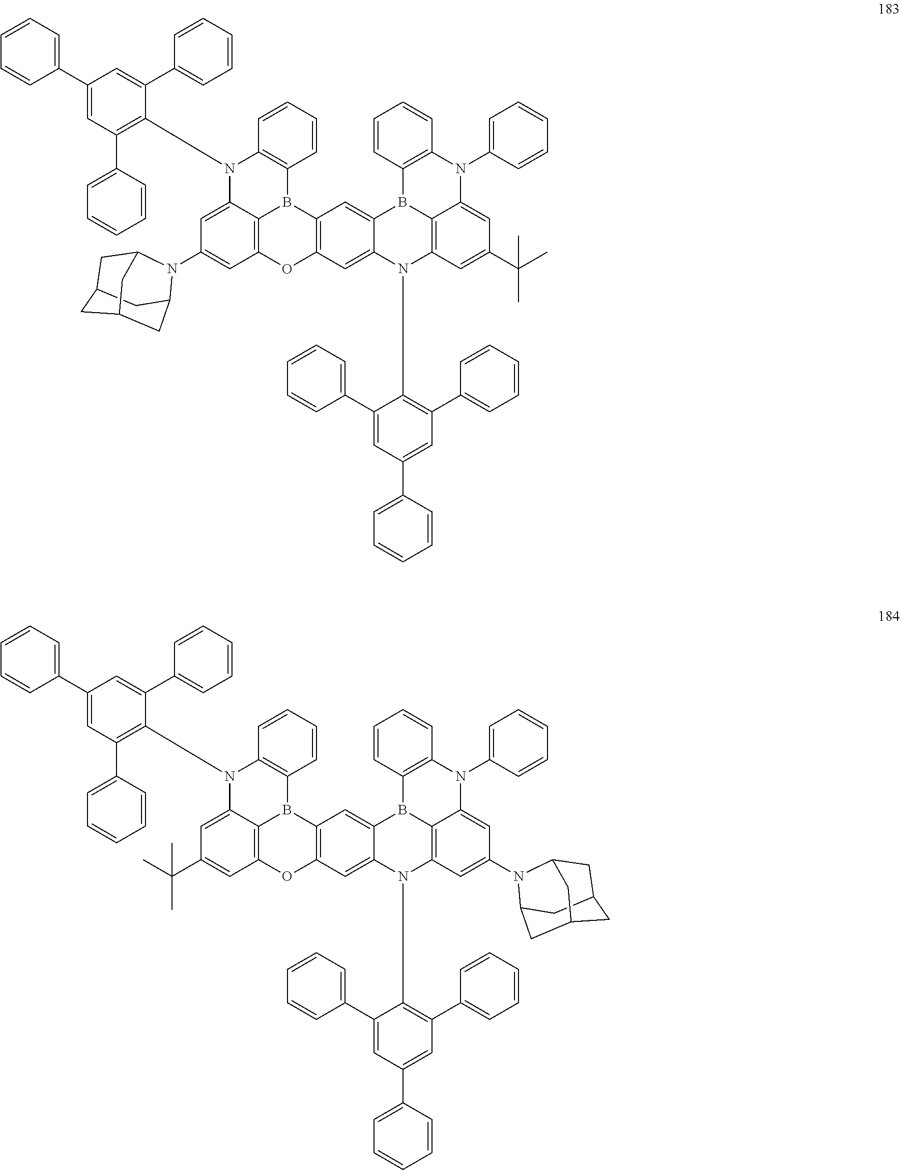 [SMILES: CC(C)(C)c1cc2c3c(c1)N(c1c(-c4ccccc4)cc(-c4ccccc4)cc1-c1ccccc1)c1cc4c(cc1B3c1ccccc1N2c1ccccc1)B1c2ccccc2N(c2c(-c3ccccc3)cc(-c3ccccc3)cc2-c2ccccc2)c2cc(N3C5CC6CC(C5)CC3C6)cc(c21)O4 ; CC(C)(C)c1cc2c3c(c1)N(c1c(-c4ccccc4)cc(-c4ccccc4)cc1-c1ccccc1)c1ccccc1B3c1cc3c(cc1O2)N(c1c(-c2ccccc2)cc(-c2ccccc2)cc1-c1ccccc1)c1cc(N2C4CC5CC(C4)CC2C5)cc2c1B3c1ccccc1N2c1ccccc1] 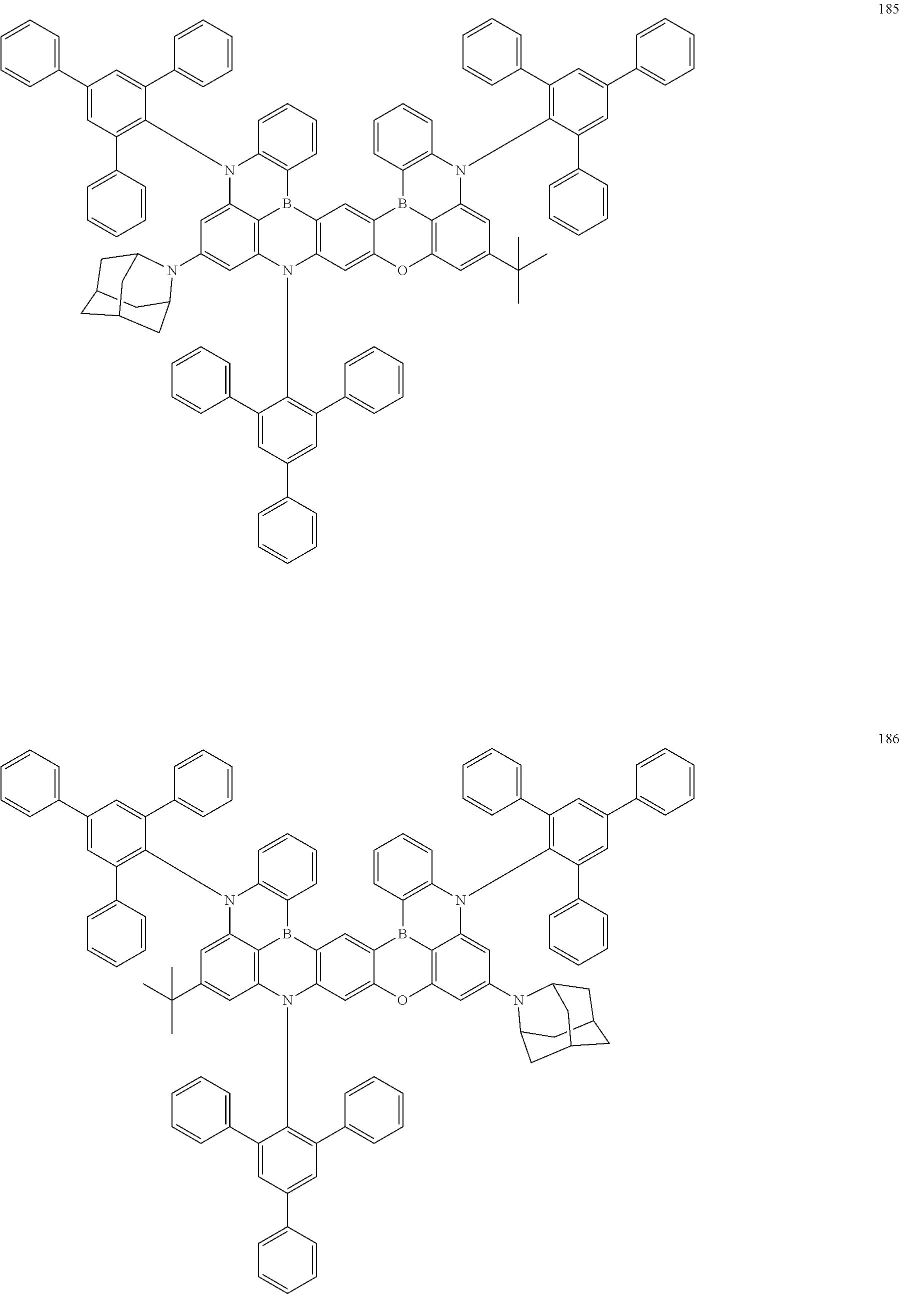 [SMILES: CC(C)(C)c1cc2c3c(c1)N(c1c(-c4ccccc4)cc(-c4ccccc4)cc1-c1ccccc1)c1ccccc1B3c1cc3c(cc1O2)N(c1c(-c2ccccc2)cc(-c2ccccc2)cc1-c1ccccc1)c1cc(N2C4CC5CC(C4)CC2C5)cc2c1B3c1ccccc1N2c1c(-c2ccccc2)cc(-c2ccccc2)cc1-c1ccccc1 ; CC(C)(C)c1cc2c3c(c1)N(c1c(-c4ccccc4)cc(-c4ccccc4)cc1-c1ccccc1)c1cc4c(cc1B3c1ccccc1N2c1c(-c2ccccc2)cc(-c2ccccc2)cc1-c1ccccc1)B1c2ccccc2N(c2c(-c3ccccc3)cc(-c3ccccc3)cc2-c2ccccc2)c2cc(N3C5CC6CC(C5)CC3C6)cc(c21)O4] 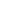 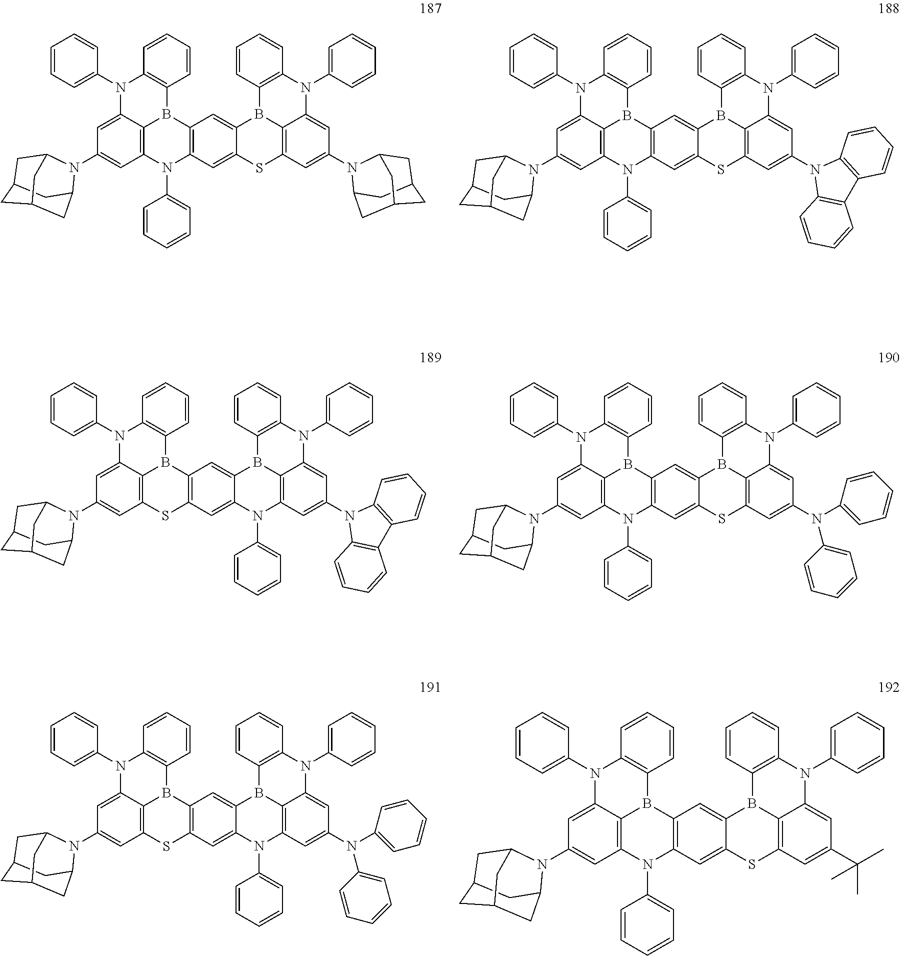 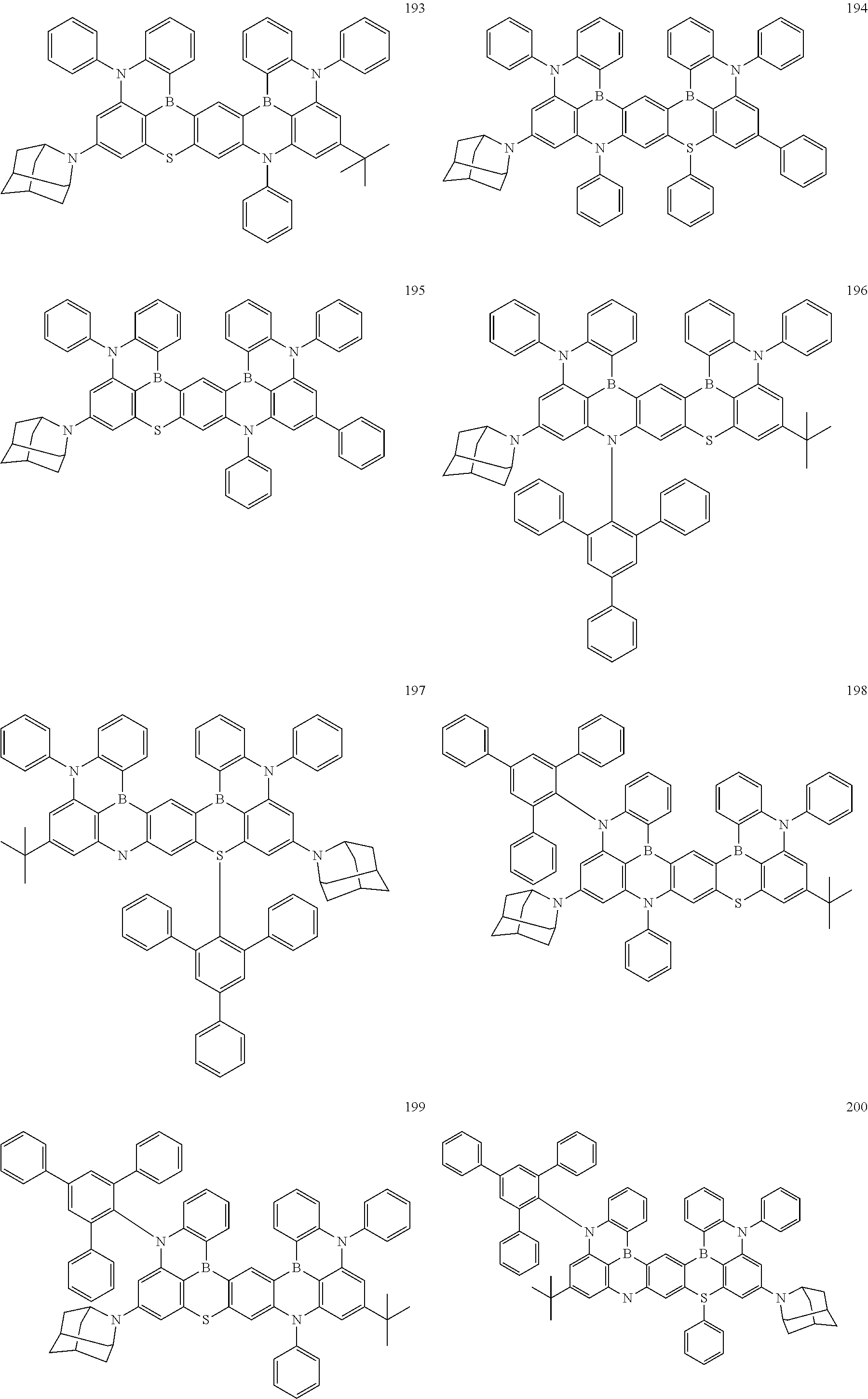 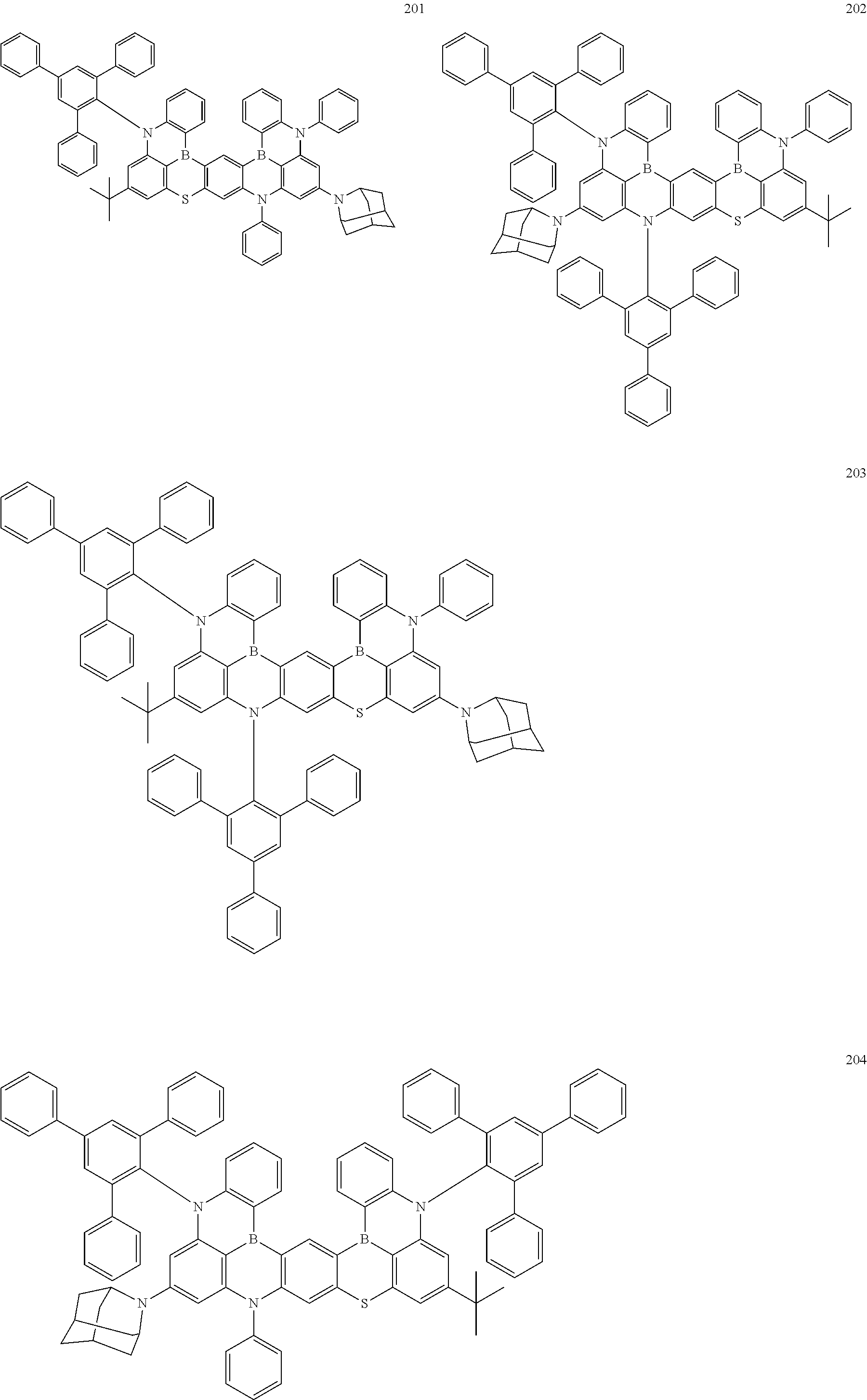 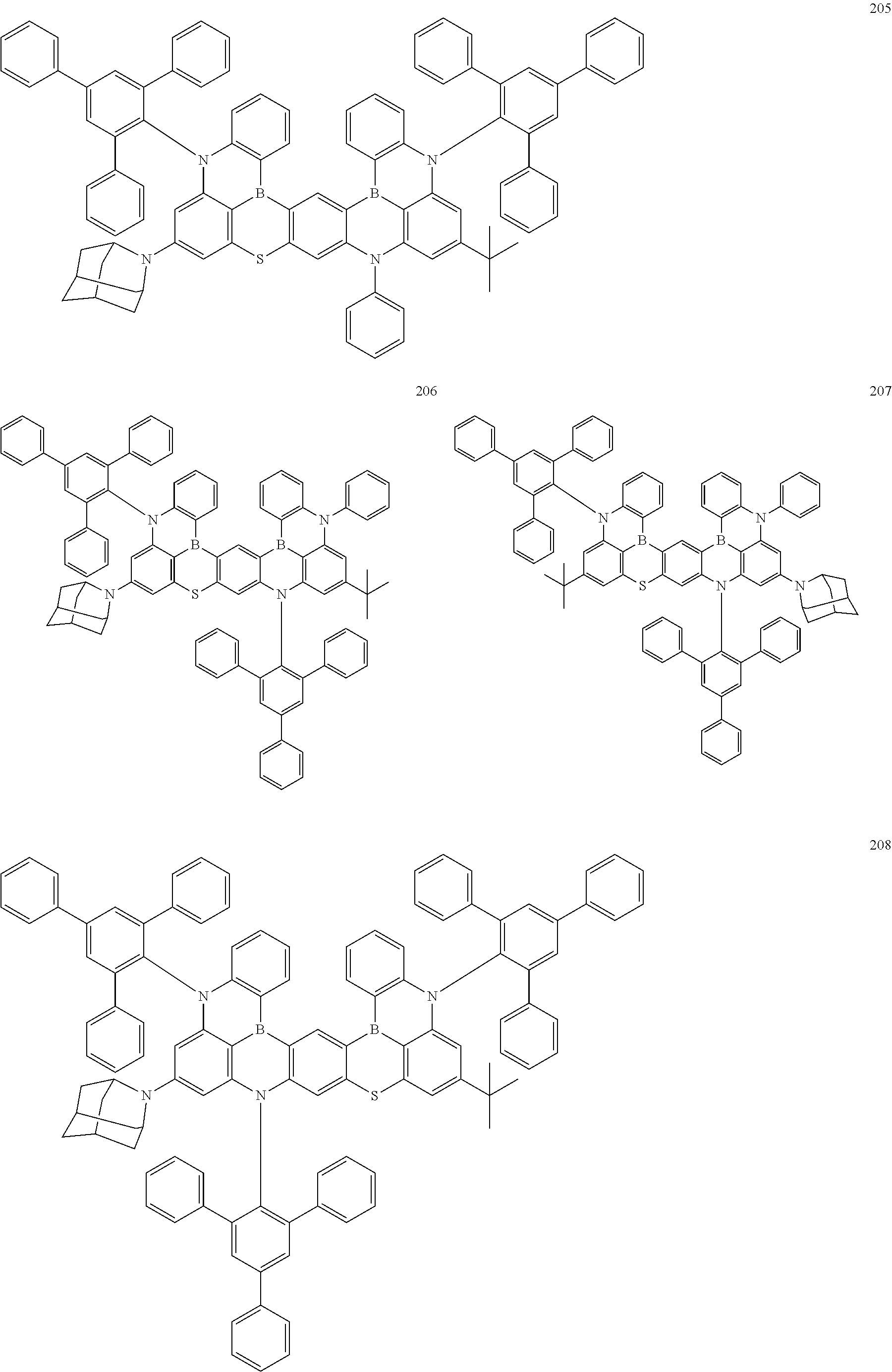 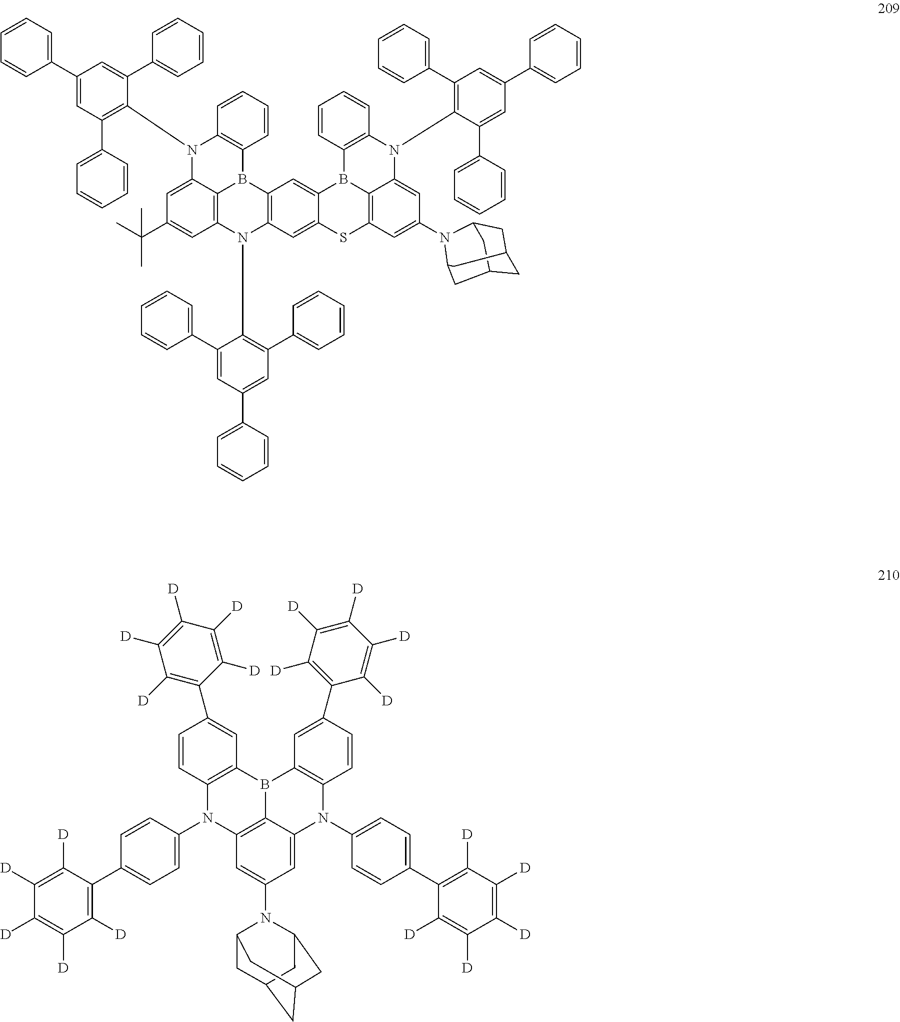 [SMILES: CC(C)(C)c1cc2c3c(c1)N(c1c(-c4ccccc4)cc(-c4ccccc4)cc1-c1ccccc1)c1cc4c(cc1B3c1ccccc1N2c1c(-c2ccccc2)cc(-c2ccccc2)cc1-c1ccccc1)B1c2ccccc2N(c2c(-c3ccccc3)cc(-c3ccccc3)cc2-c2ccccc2)c2cc(N3C5CC6CC(C5)CC3C6)cc(c21)S4 ; [2H]c1c([2H])c([2H])c(-c2ccc(N3c4ccc(-c5c([2H])c([2H])c([2H])c([2H])c5[2H])cc4B4c5cc(-c6c([2H])c([2H])c([2H])c([2H])c6[2H])ccc5N(c5ccc(-c6c([2H])c([2H])c([2H])c([2H])c6[2H])cc5)c5cc(N6C7CC8CC(C7)CC6C8)cc3c54)cc2)c([2H])c1[2H]] 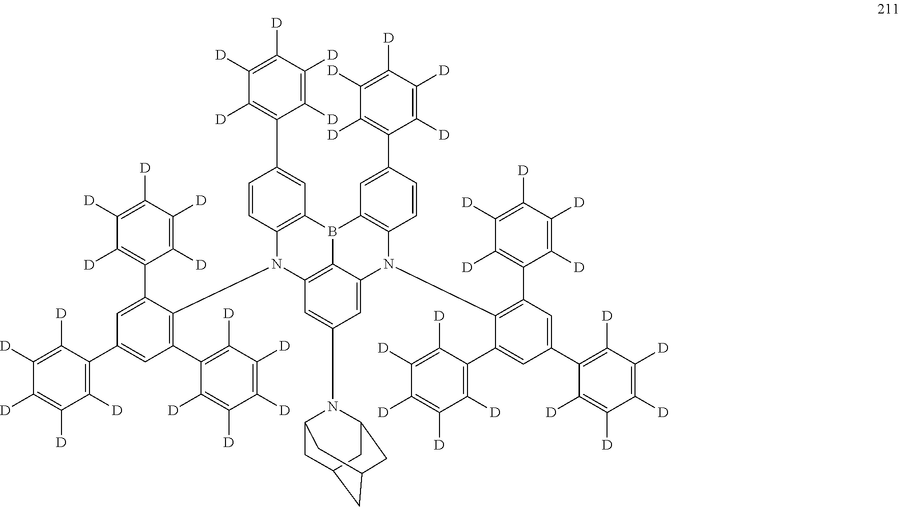 [SMILES: [2H]c1c([2H])c([2H])c(-c2ccc3c(c2)B2c4cc(-c5c([2H])c([2H])c([2H])c([2H])c5[2H])ccc4N(c4c(-c5c([2H])c([2H])c([2H])c([2H])c5[2H])cc(-c5c([2H])c([2H])c([2H])c([2H])c5[2H])cc4-c4c([2H])c([2H])c([2H])c([2H])c4[2H])c4cc(N5C6CC7CC(C6)CC5C7)cc(c42)N3c2c(-c3c([2H])c([2H])c([2H])c([2H])c3[2H])cc(-c3c([2H])c([2H])c([2H])c([2H])c3[2H])cc2-c2c([2H])c([2H])c([2H])c([2H])c2[2H])c([2H])c1[2H]] 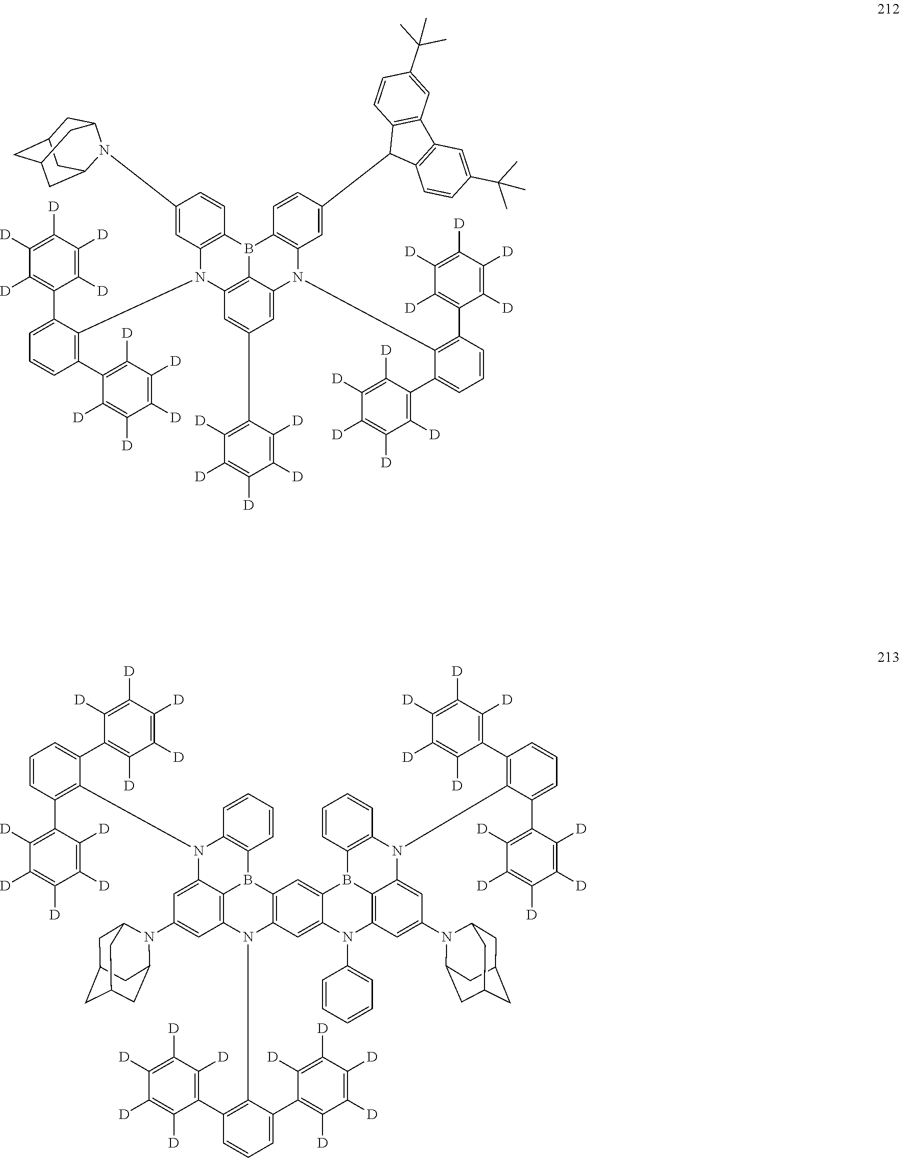 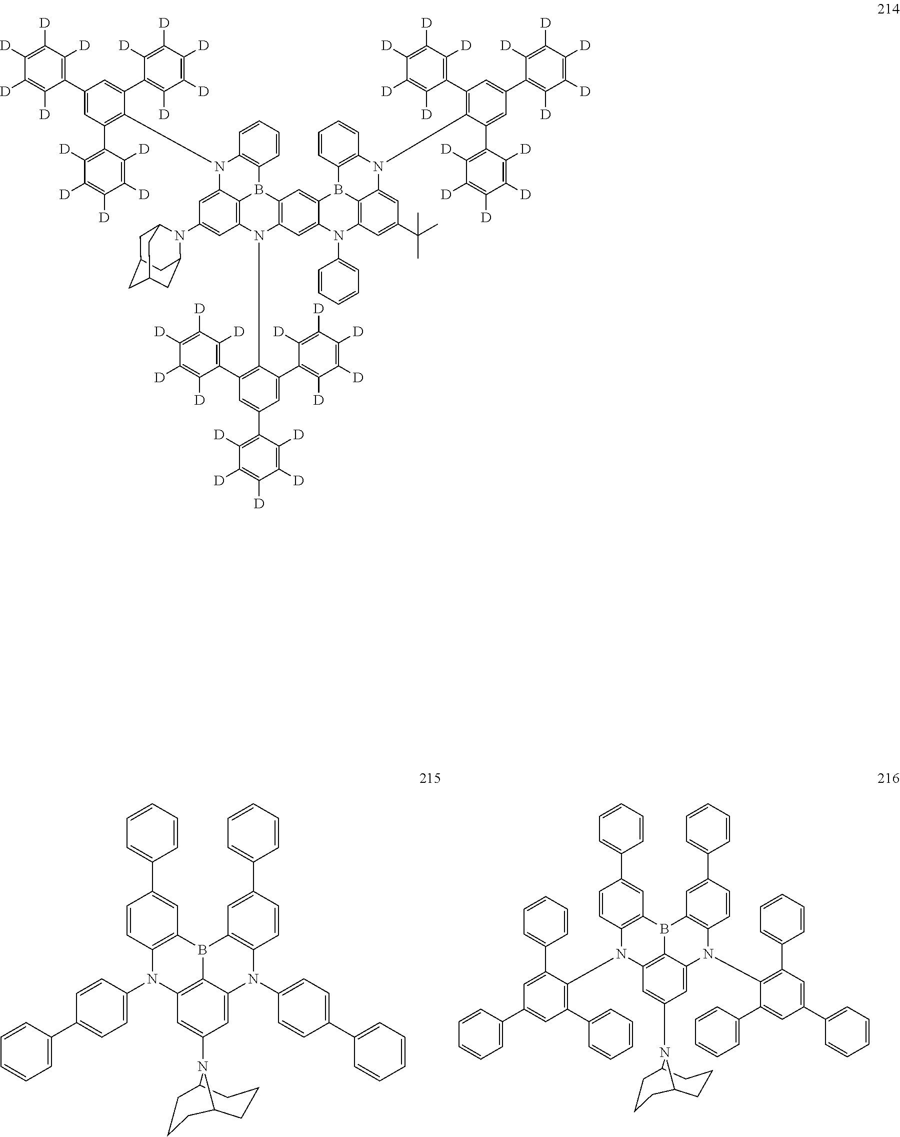 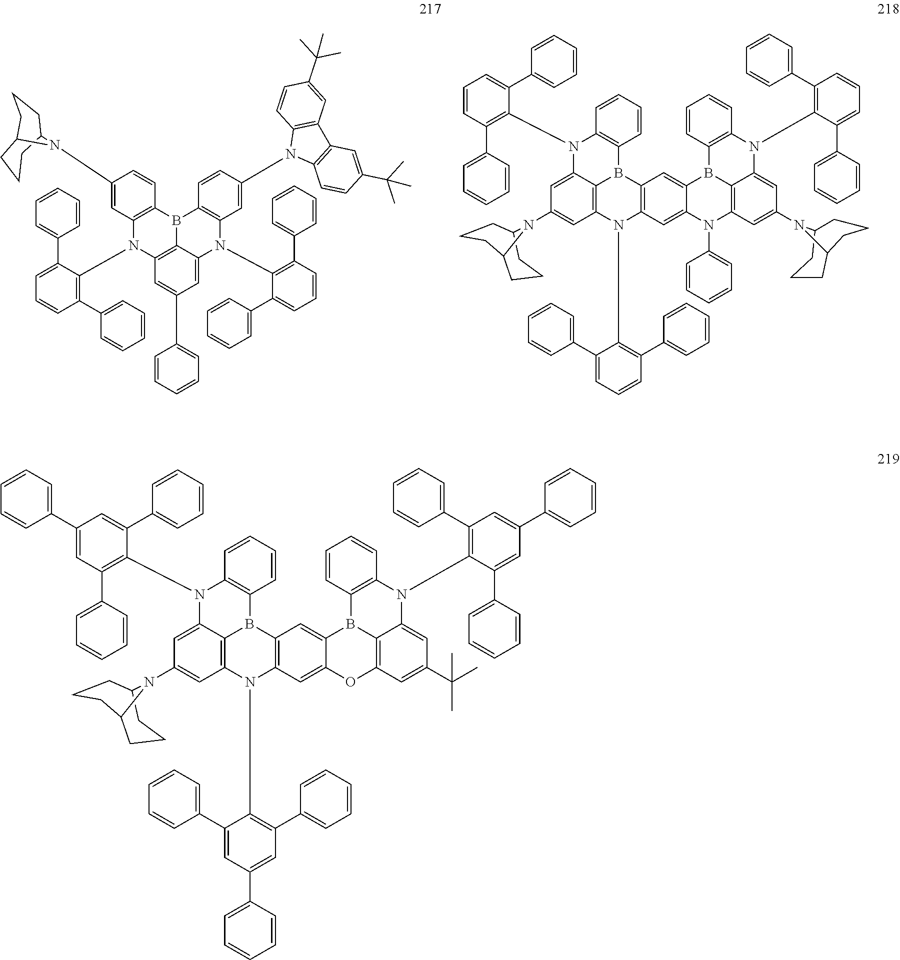 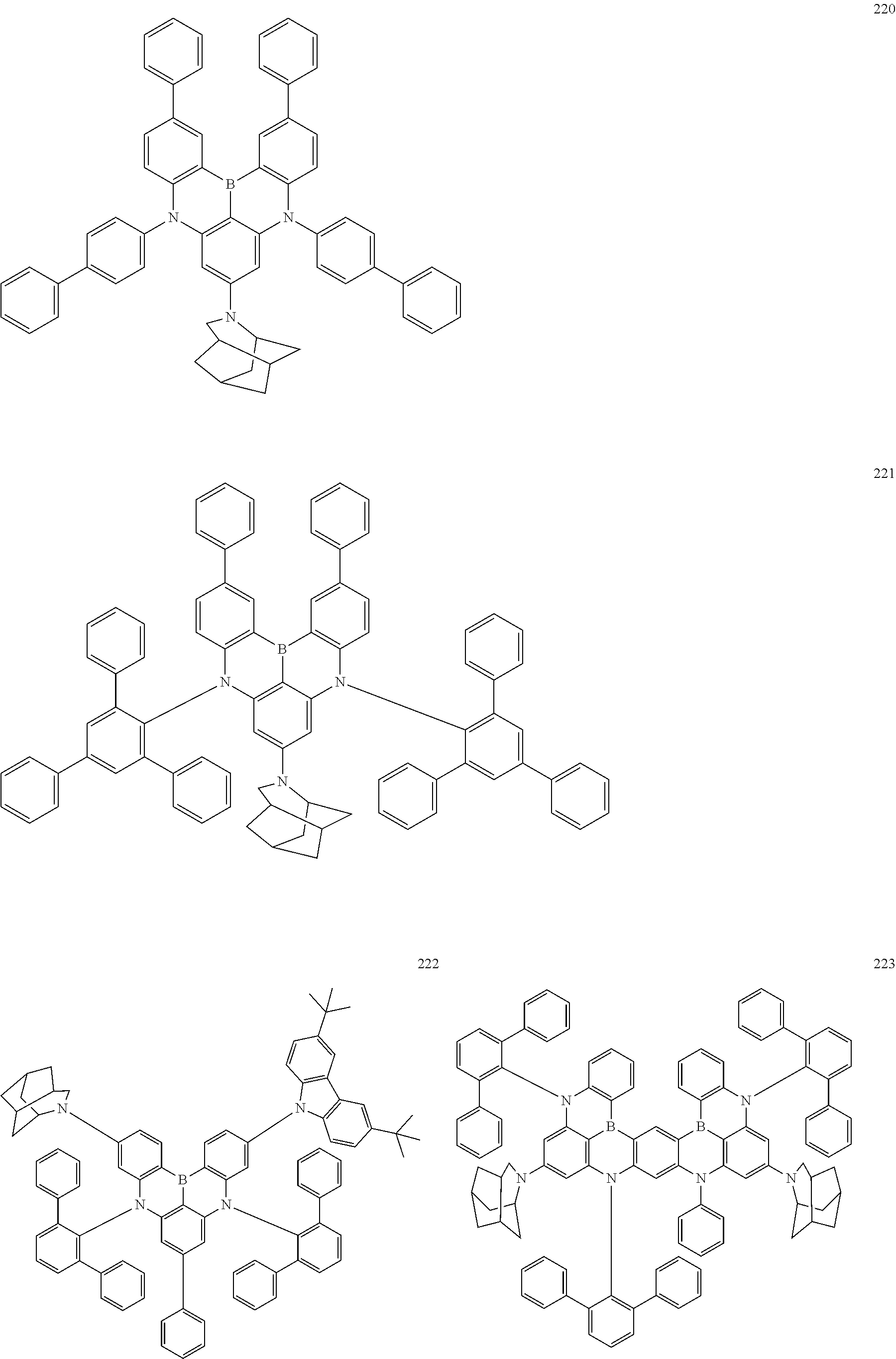 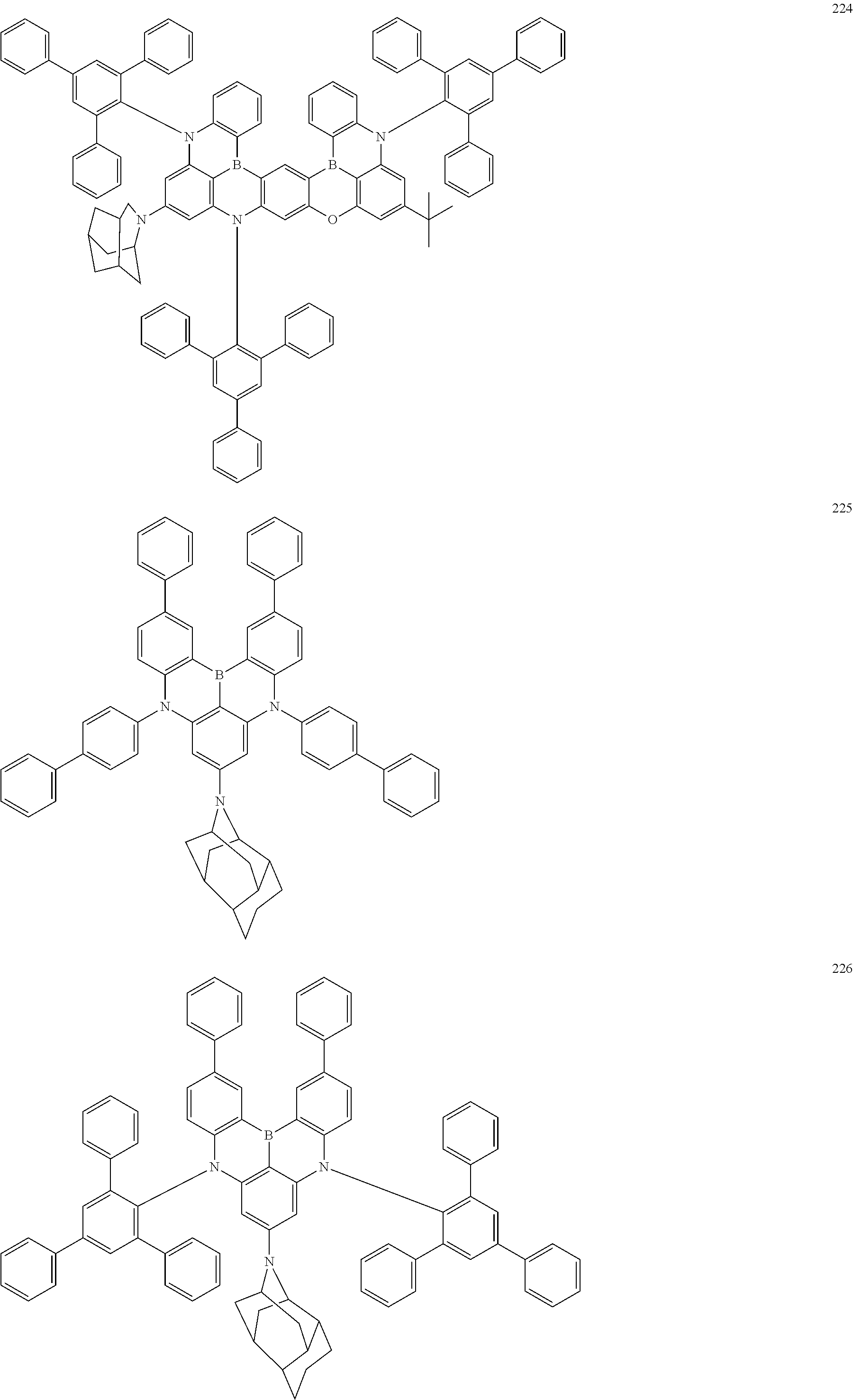 [SMILES: CC(C)(C)c1cc2c3c(c1)N(c1c(-c4ccccc4)cc(-c4ccccc4)cc1-c1ccccc1)c1ccccc1B3c1cc3c(cc1O2)N(c1c(-c2ccccc2)cc(-c2ccccc2)cc1-c1ccccc1)c1cc(N2CC4CC5CC4CC2C5)cc2c1B3c1ccccc1N2c1c(-c2ccccc2)cc(-c2ccccc2)cc1-c1ccccc1 ; c1ccc(-c2ccc(N3c4ccc(-c5ccccc5)cc4B4c5cc(-c6ccccc6)ccc5N(c5ccc(-c6ccccc6)cc5)c5cc(N6C7CC8CC6C6CCCC8C6C7)cc3c54)cc2)cc1 ; c1ccc(-c2ccc3c(c2)B2c4cc(-c5ccccc5)ccc4N(c4c(-c5ccccc5)cc(-c5ccccc5)cc4-c4ccccc4)c4cc(N5C6CC7CC5C5CCCC7C5C6)cc(c42)N3c2c(-c3ccccc3)cc(-c3ccccc3)cc2-c2ccccc2)cc1] 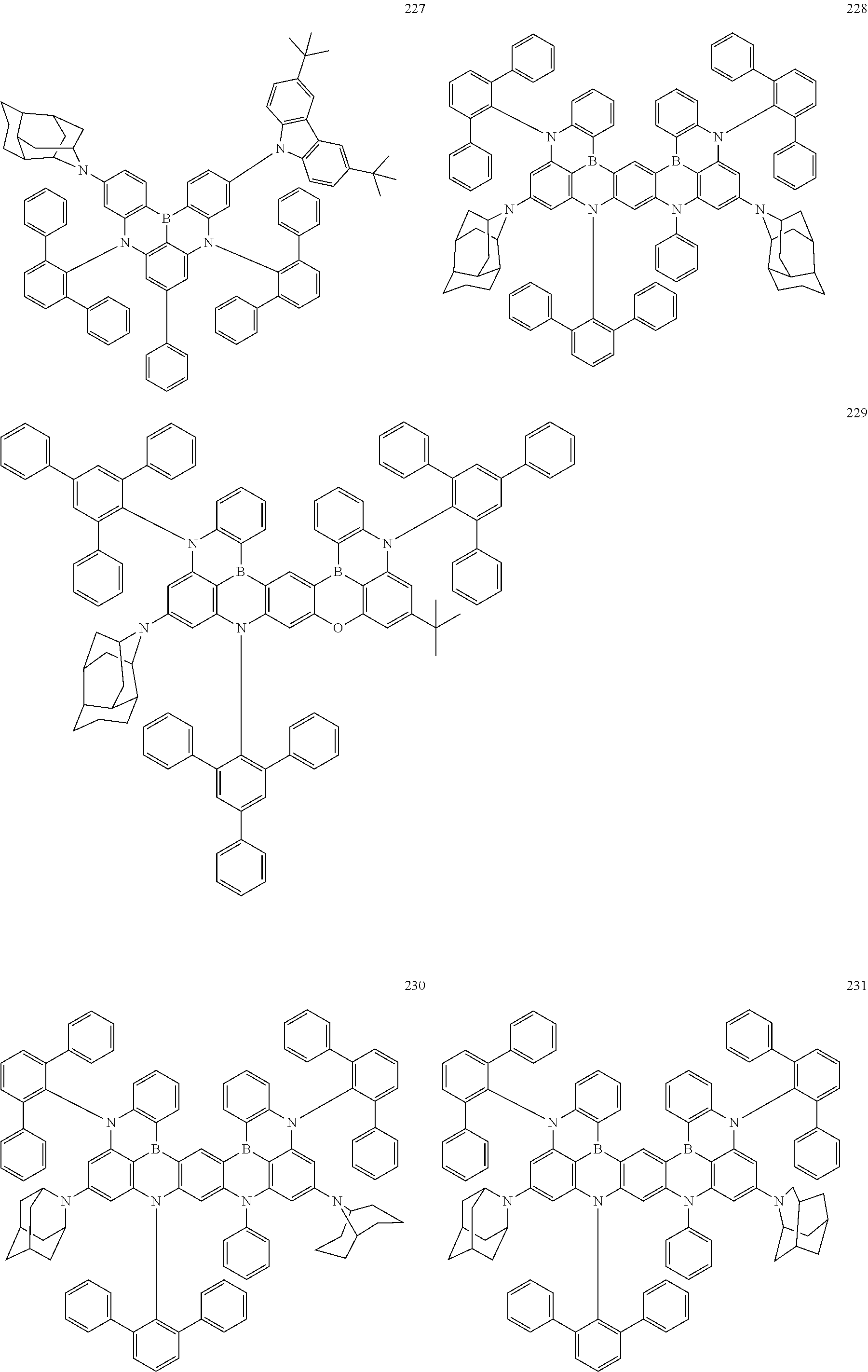 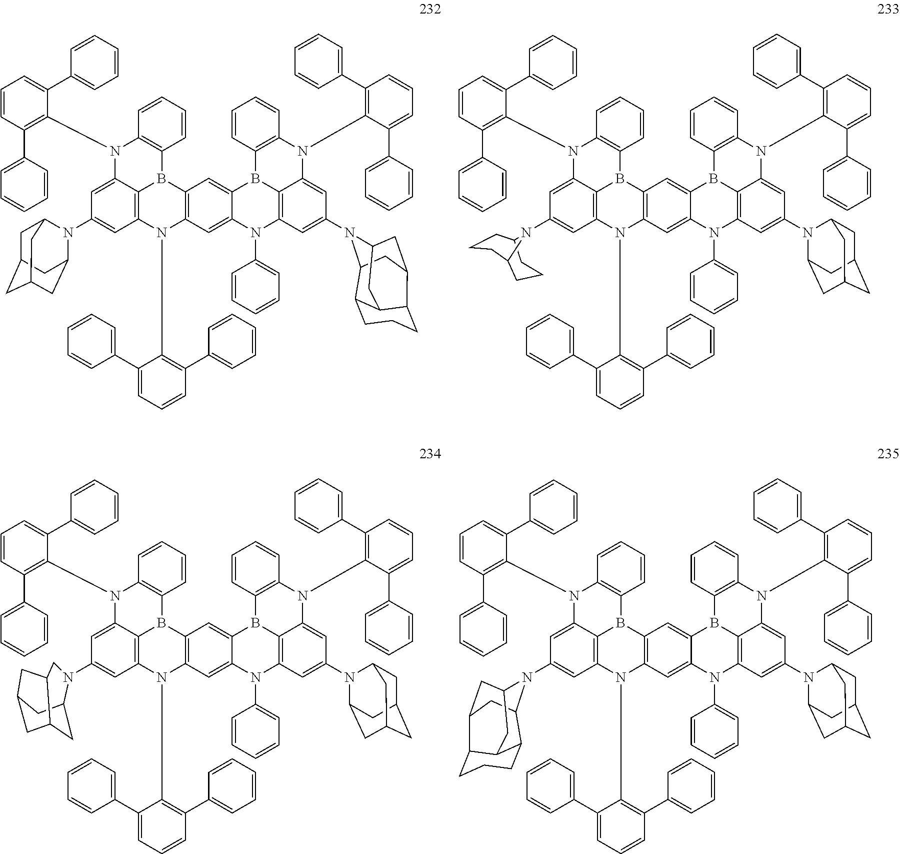
wherein D in Compound Group 1 is a deuterium atom.
